(19) United States
(12) Patent Application Publication
(10) Pub. No.: US 2025/0280650 A1
(43) Pub. Date: Sep. 4, 2025

(54) LIGHT EMITTING ELEMENT, FUSED POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: Hirokazu KUWABARA, Yokohama (JP); Keigo HOSHI, Yokohama (JP); Yoshiro SUGITA, Yokohama (JP)

(21) Appl. No.: 19/065,945

(22) Filed: Feb. 27, 2025

(30) Foreign Application Priority Data
Mar. 4, 2024 (KR) 10-2024-0030963

(51) Int. Cl. H10K 50/12; H10K 50/15; H10K 50/16; H10K 59/38; H10K 85/30; H10K 85/40; H10K 85/60; H10K 101/00

(52) U.S. Cl. CPC H10K 50/12; H10K 50/15; H10K 50/16; H10K 59/38; H10K 85/342; H10K 85/346; H10K 85/40; H10K 85/622; H10K 85/633; H10K 85/636; H10K 85/654; H10K 85/6572; H10K 85/6574; H10K 85/6576; H10K 85/658; H10K 2101/90

(57) ABSTRACT

A light emitting element includes a first electrode, a second electrode on the first electrode, and an emission layer that is between the first electrode and the second electrode and includes a first compound represented by Formula 1:

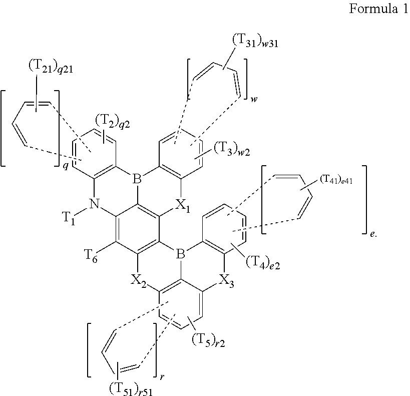

### CROSS-REFERENCE TO RELATED APPLICATION

The present application claims priority to and the benefit of Korean Patent Application No. 10-2024-0030963, filed on Mar. 4, 2024, in the Korean Intellectual Property Office, the entire disclosure of which is incorporated herein by reference.

### BACKGROUND

### 1. Field

One or more embodiments of the present disclosure relate to a light emitting element, a fused polycyclic compound used in the light emitting element, and a display device including the light emitting element.

### 2. Description of the Related Art

Recently, significant research and development efforts have been conducted on organic electroluminescence display devices as image display devices. Unlike liquid crystal display devices, organic electroluminescence display devices are self-luminescent (i.e., self-luminescent display device). In these devices, holes and electrons are injected from a first electrode and a second electrode, respectively. These holes and electrodes (charges) recombine in an emission layer of the organic electroluminescence display device, and the recombination enables a luminescent material including an organic compound in the emission layer to emit light, thereby implementing display of images.

In the application of an organic electroluminescence element to a display device, it is desirable that the organic electroluminescence element exhibits (has) low driving voltage, high luminous efficiency, and long service life. Consequently, ongoing research and development are focused on materials, for the organic electroluminescence elements that may stably achieve (attain) such desired characteristics.

In recent years, to achieve highly efficient organic electroluminescence elements, technologies related to phosphorescence emission using triplet state energy and/or fluorescence emission using triplet-triplet annihilation (TTA), where singlet excitons are generated by collision of triplet excitons, are being explored and developed. For example, thermally activated delayed fluorescence (TADF) materials, which utilize the delayed fluorescence phenomenon, are being actively investigated and developed.

### SUMMARY

One or more aspects of embodiments of the present disclosure are directed toward a light emitting element in which luminous efficiency and an element service life are improved.

One or more aspects of embodiments of the present disclosure are directed toward a fused polycyclic compound that is capable of improving luminous efficiency and an element service life of a light emitting element.

One or more aspects of embodiments of the present disclosure are directed toward a display device including the light emitting element in which the efficiency and service life are improved, thereby having excellent or suitable display quality.

Additional aspects will be set forth in part in the description which follows and, in part, will be apparent from the description, or may be learned by practice of the presented embodiments.

According to one or more embodiments of the present disclosure, a light emitting element includes a first electrode, a second electrode opposite to (e.g., facing) the first electrode, and an emission layer between the first electrode and the second electrode, wherein the emission layer includes a first compound represented by Formula 1:

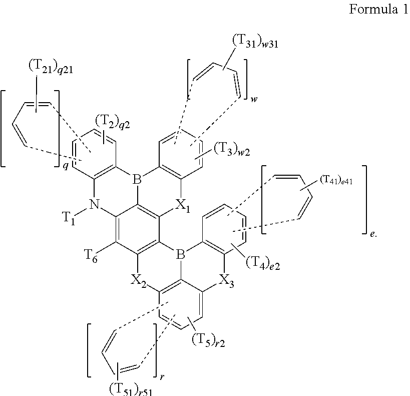

In Formula 1, q, w, and e may each independently be an integer of 0 to 3, r may be an integer of 0 to 2, q21, w31, e41, and r51 may each independently be an integer of 0 to 4, the sum of q, w, e, and r is 1 or more, q2 is an integer of 0 to 4 if (e.g., when) q is 0, q2 is an integer of 0 to 2 if (e.g., when) q is 1, and q2 is 0 if (e.g., when) q is 2 or 3, w2 is an integer of 0 to 4 if (e.g., when) w is 0, w2 is an integer of 0 to 2 if (e.g., when) w is 1, and w2 is 0 if (e.g., when) w is 2 or 3, e2 is an integer of 0 to 4 if (e.g., when) e is 0, e2 is an integer of 0 to 2 if (e.g., when) e is 1, and e2 is 0 if (e.g., when) e is 2 or 3, r2 is an integer of 0 to 3 if (e.g., when) r is 0, r2 is 0 or 1 if (e.g., when) r is 1, and r2 is 0 if (e.g., when) r is 2, X₁ may be O or S, X₂ may be O, S, or NT₂₀, and X₃ may be O, S, or NT₃₀, T₁ may be a substituted or unsubstituted aryl group having 6 to 30 ring-forming carbon atoms or a substituted or unsubstituted heteroaryl group having 2 to 30 ring-forming carbon atoms, T₂₀, T₃₀, T₂, T₃, T₄, T₅, and T₆ may each independently be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and T₂₁, T₃₁, T₄₁, and T₅₁ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be independently bonded to an adjacent group to form a ring.

In one or more embodiments, the first compound represented by Formula 1 may be represented by Formula 2-1 or Formula 2-2:

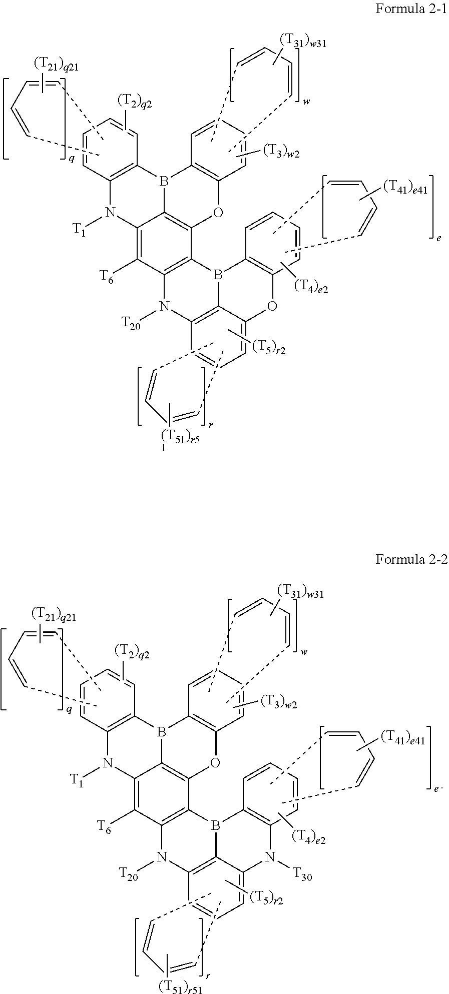

In Formula 2-1 and Formula 2-2, q, w, e, r, q21, w31, e41, r51, q2, w2, e2, r2, T₁, T₂₀, T₃₀, T₂, T₃, T₄, T₅, T₆, T₂₁, T₃₁, T₄₁, and T₅₁ may each independently be the same as defined in Formula 1.

In one or more embodiments, in Formula 1, T₁ may be a substituted or unsubstituted biphenyl group.

In one or more embodiments, in Formula 1, T₁ may be an unsubstituted o-biphenyl group (i.e., biphenyl-2-yl group).

In one or more embodiments, in Formula 1, each of T₂₀ and T₃₀ may be a substituted or unsubstituted terphenyl group.

In one or more embodiments, in Formula 1, each of T₂₀ and T₃₀ may be an unsubstituted m-terphenyl group.

In one or more embodiments, the first compound represented by Formula 1 above may be represented by any one selected from among Formula 3-1 to Formula 3-7:

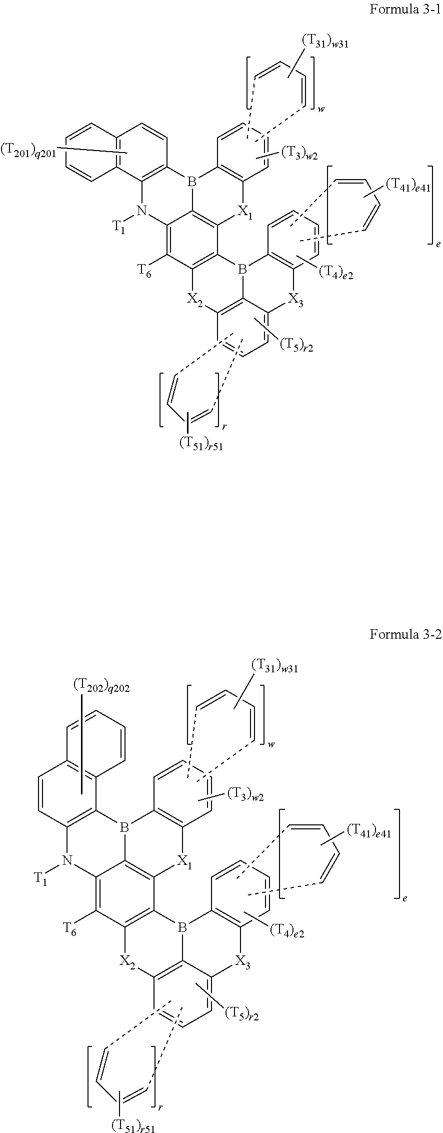

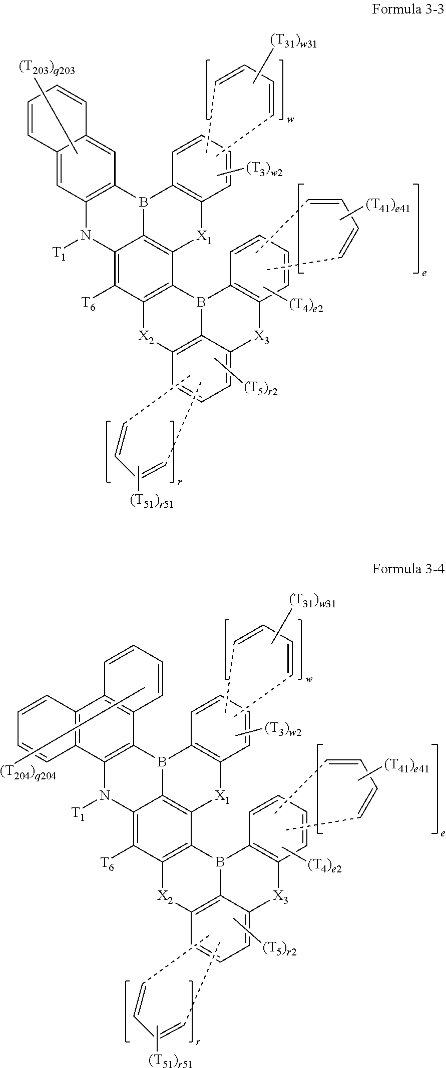

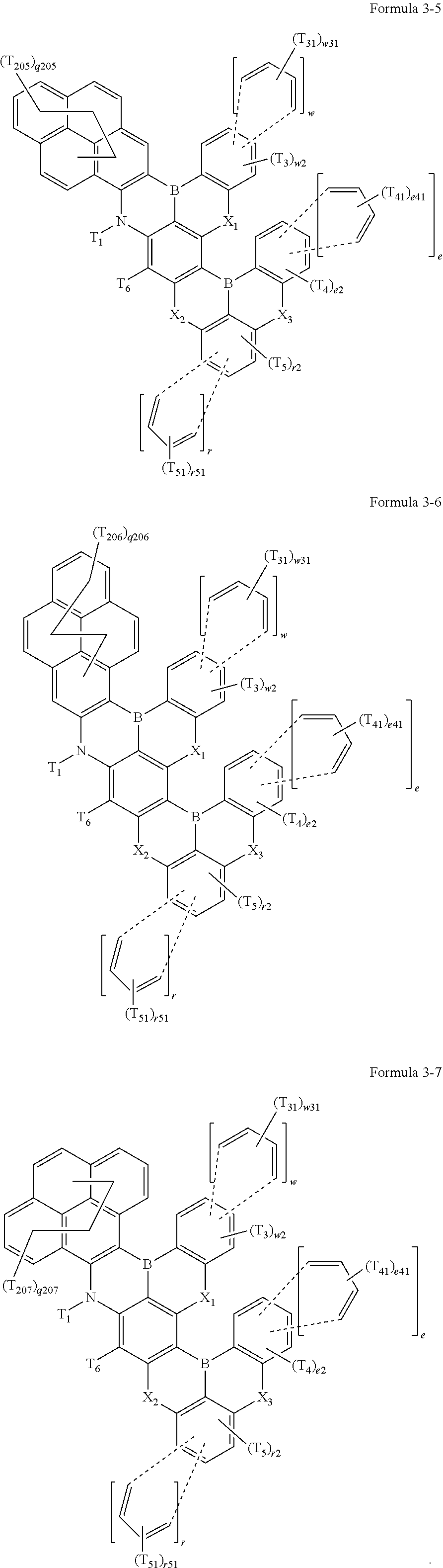

In Formula 3-1 to Formula 3-7, T₂₀₁, T₂₀₂, T₂₀₃, T₂₀₄, T₂₀₅, T₂₀₆, and T₂₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, q201, q202, and q203 may each independently be an integer of 0 to 6, q204, q205, q206, and q207 may each independently be an integer of 0 to 8, and w, e, r, w31, e41, r51, w2, e2, r2, X₁, X₂, X₃, T₁, T₂₀, T₃₀, T₃, T₄, T₅, T₆, T₃₁, T₄₁, and T₅₁ may each independently be the same as defined in Formula 1.

In one or more embodiments, the first compound represented by Formula 1 may be represented by any one selected from among Formula 4-1 to Formula 4-7:

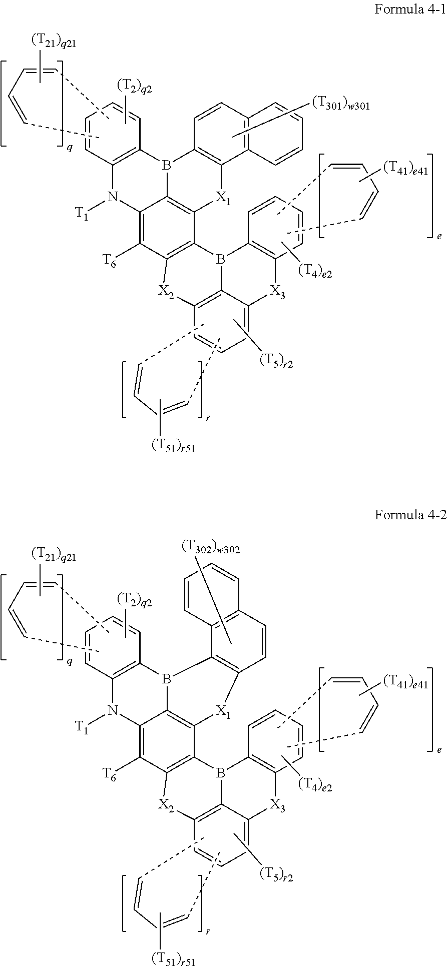

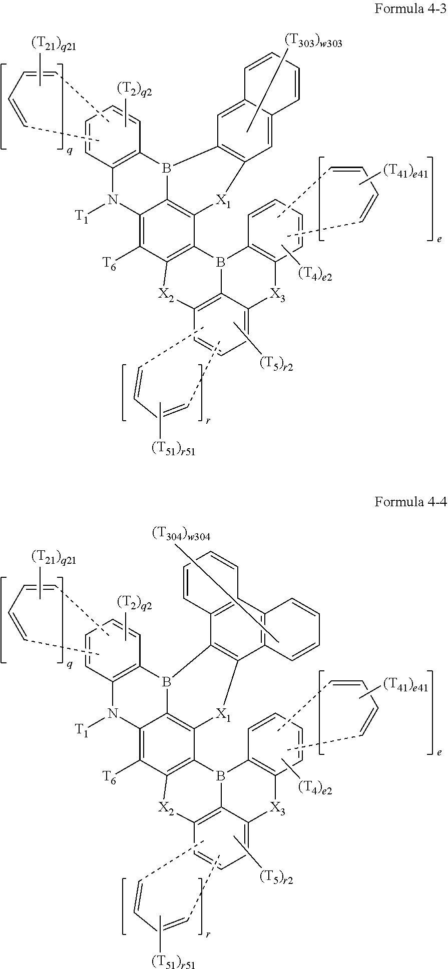

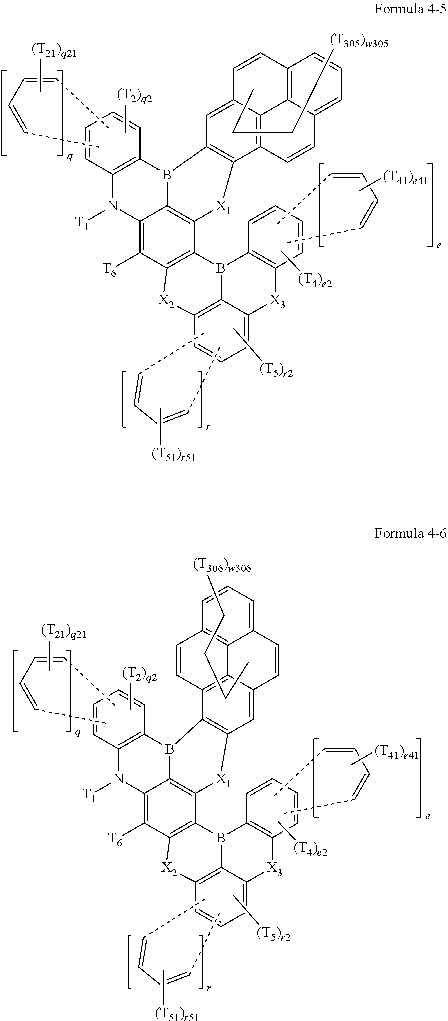

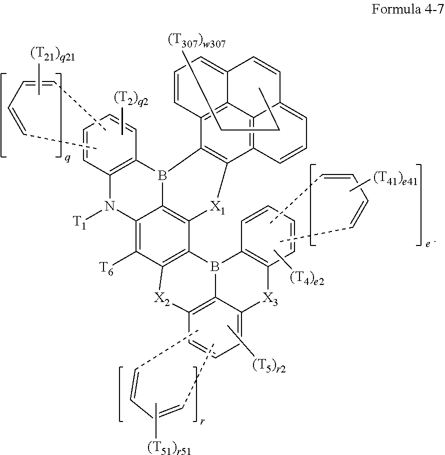

In Formula 4-1 to Formula 4-7, T₃₀₁, T₃₀₂, T₃₀₃, T₃₀₄, T₃₀₅, T₃₀₆, and T₃₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, w301, w302, and w303 may each independently be an integer of 0 to 6, w304, w305, w306, and w307 may each independently be an integer of 0 to 8, and q, e, r, q21, e41, r51, q2, e2, r2, X₁, X₂, X₃, T₁, T₂₀, T₃₀, T₂, T₄, T₅, T₆, T₂₁, T₄₁, and T₅₁ may each independently be the same as defined in Formula 1.

In one or more embodiments, the first compound represented by Formula 1 may be represented by any one selected from among Formula 5-1 to Formula 5-7:

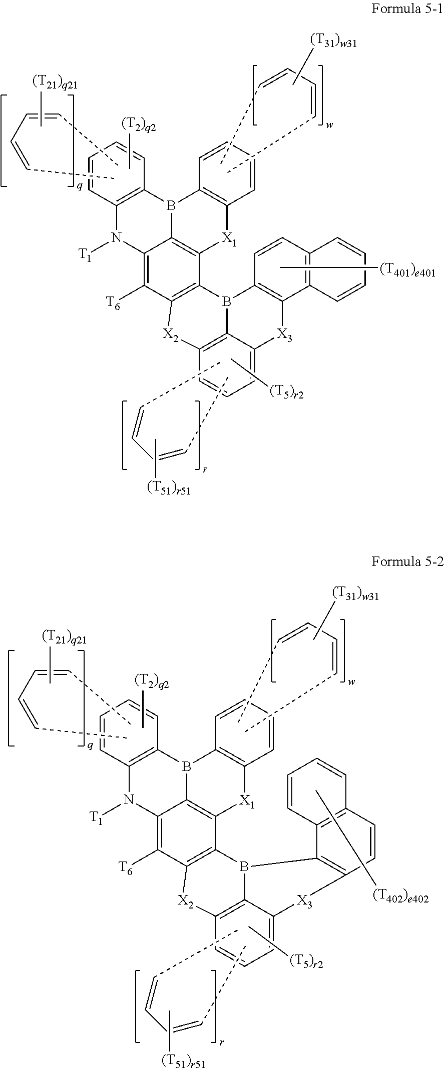

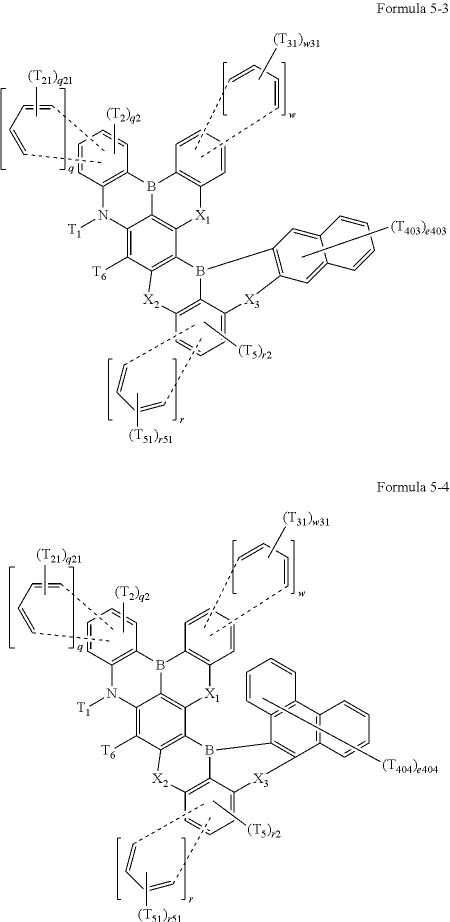

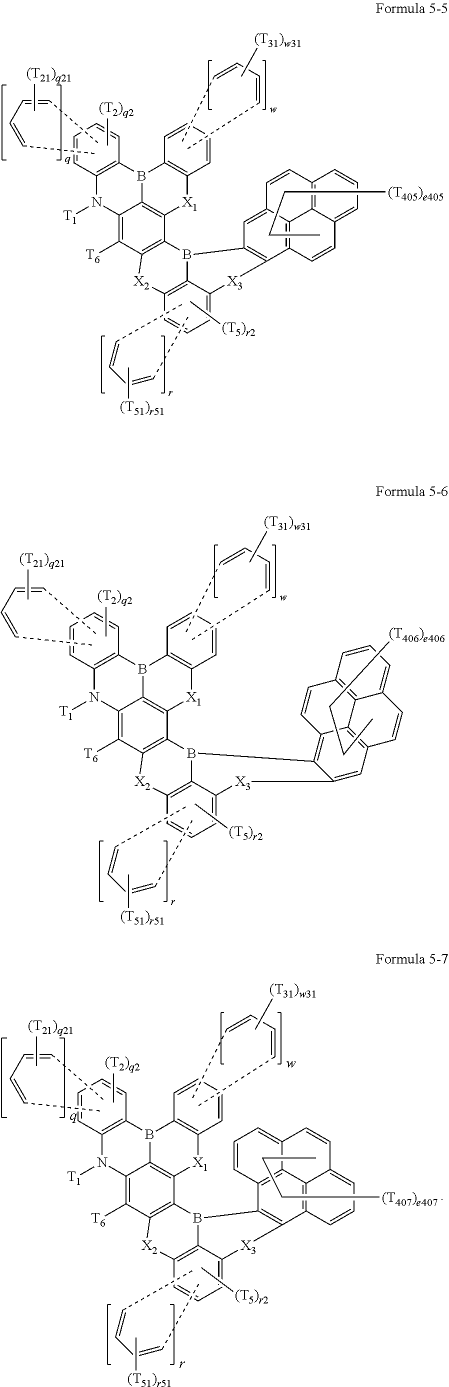

In Formula 5-1 to Formula 5-7, T₄₀₁, T₄₀₂, T₄₀₃, T₄₀₄, T₄₀₅, T₄₀₆, and T₄₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, e401, e402, and e403 may each independently be an integer of 0 to 6, e404, e405, e406, and e407 may each independently be an integer of 0 to 8, and q, w, r, q21, w31, r51, q2, w2, r2, X₁, X₂, X₃, T₁, T₂₀, T₃₀, T₂, T₃, T₅, T₆, T₂₁, T₃₁, and T₅₁ may each independently be the same as defined in Formula 1.

In one or more embodiments, the first compound represented by Formula 1 may be represented by any one selected from among Formula 6-1 to Formula 6-3:

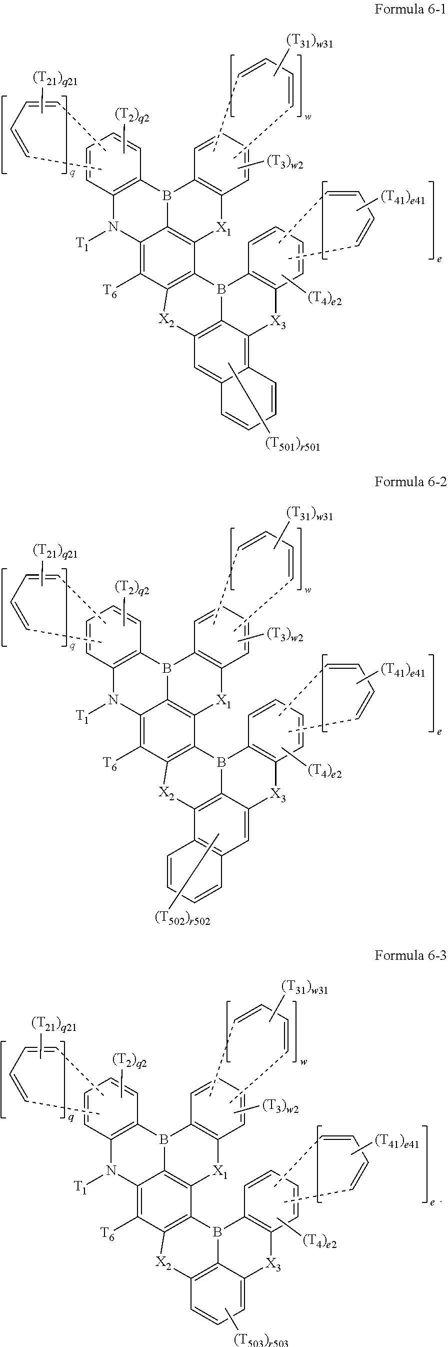

In Formula 6-1 to Formula 6-3 above, T₅₀₁ to T₅₀₃ may each independently be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, r501 and r502 may each independently be an integer of 0 to 5, r503 is an integer of 0 to 3, and q, w, e, q21, w31, e41, q2, w2, e2, X₁, X₂, X₃, T₁, T₂₀, T₃₀, T₂, T₃, T₄, T₆, T₂₁, T₃₁, and T₄₁ may each independently be the same as defined in Formula 1.

In one or more embodiments, the emission layer may further include at least one of a second compound represented by Formula HT-1, a third compound represented by Formula ET-1, or a fourth compound represented by Formula D-1:

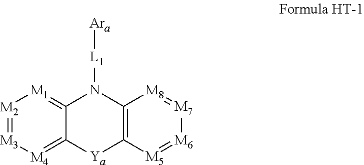

In Formula HT-1, M₁ to M₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Arₐ may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring.

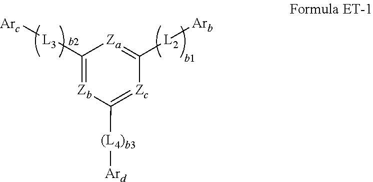

In Formula ET-1, at least one selected from among Zₐ to Z_{c} may be N, the rest are CR₅₆, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar_{b} to Ar_{d} may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

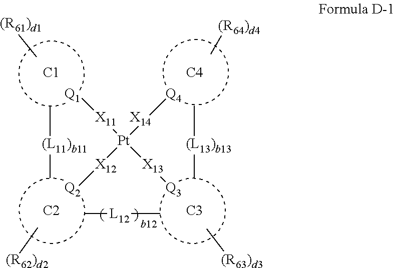

In Formula D-1, Q1 to Q4 may each independently be C or N, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms, X₁₁ to X₁₄ may each independently be a direct linkage or *—O—*, L₁₁ to L₁₃ may each independently be a direct linkage, *—O—*, *—S—*,

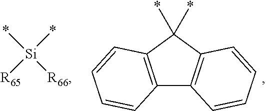

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the first compound represented by Formula 1 may be any one selected from among compounds represented by Compound Group 1.

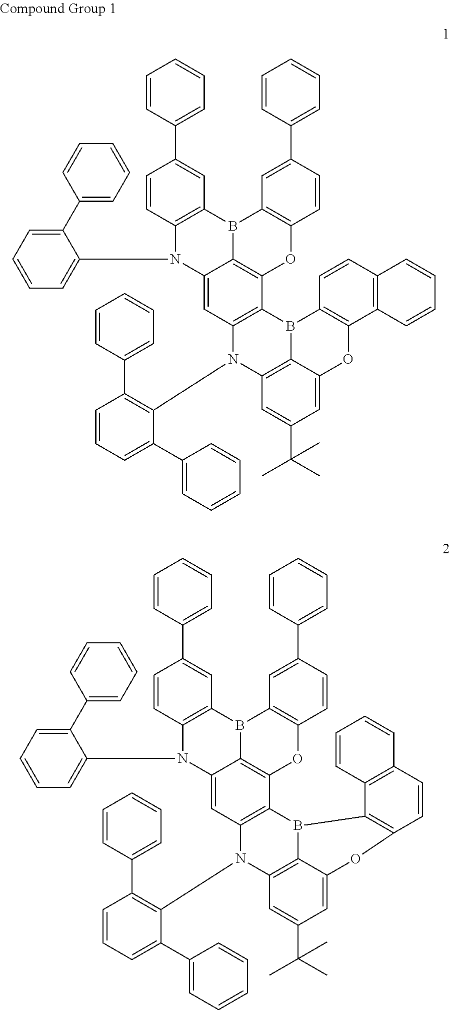 [SMILES: CC(C)(C)c1cc2c3c(c1)N(c1c(-c4ccccc4)cccc1-c1ccccc1)c1cc4c5c(c1B3c1ccc3ccccc3c1O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Oc1ccc(-c2ccccc2)cc1B5c1cc(-c2ccccc2)ccc1N4c1ccccc1-c1ccccc1]

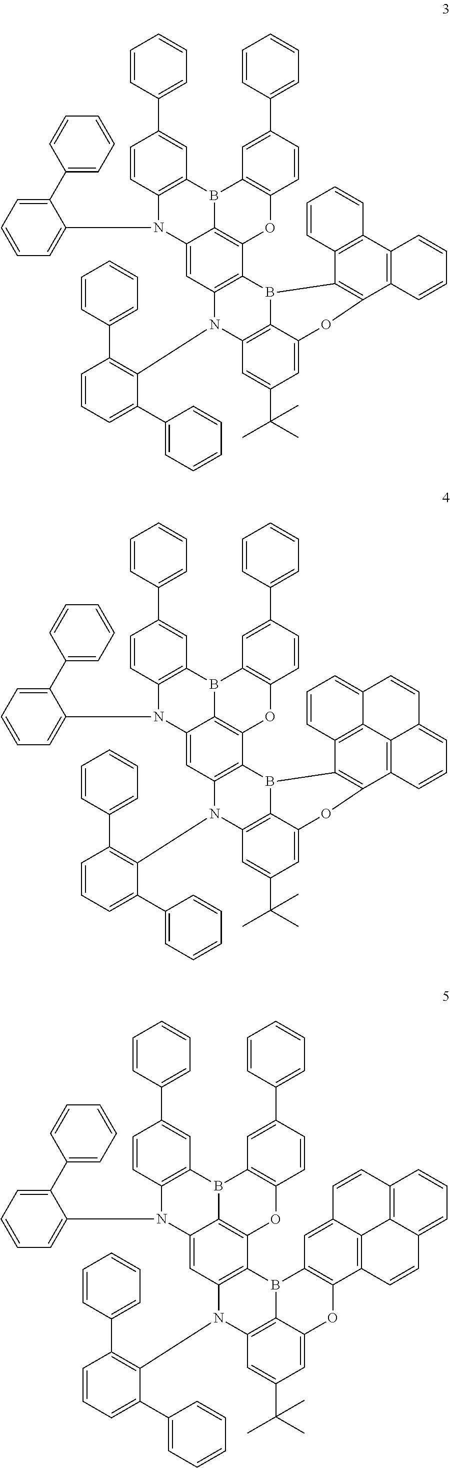 [SMILES: CC(C)(C)c1cc2c3c(c1)N(c1c(-c4ccccc4)cccc1-c1ccccc1)c1cc4c5c(c1B3c1c(c3ccccc3c3ccccc13)O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1ccc(-c2ccccc2)cc1B5c1cc(-c2ccccc2)ccc1N4c1ccccc1-c1ccccc1]

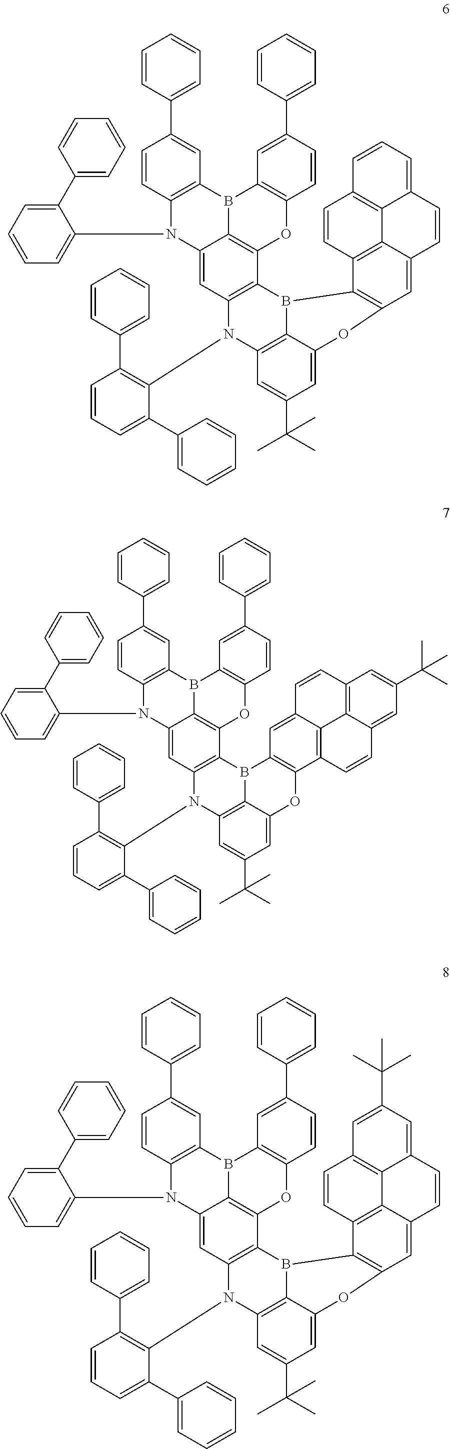 [SMILES: CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1O2)c3c67)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Oc1ccc(-c2ccccc2)cc1B5c1cc(-c2ccccc2)ccc1N4c1ccccc1-c1ccccc1]

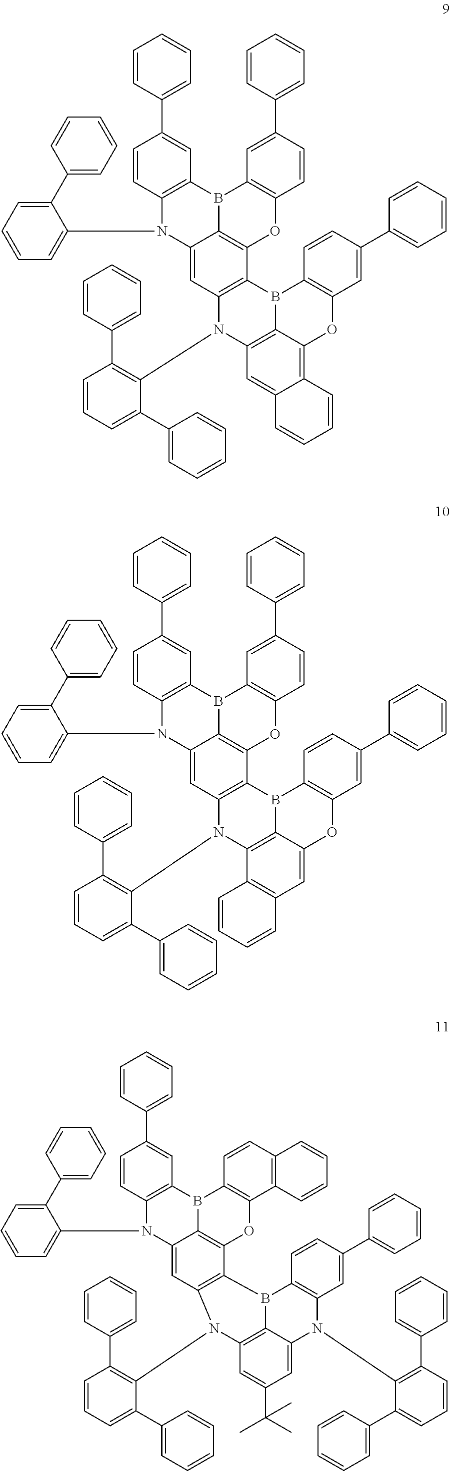 [SMILES: c1ccc(-c2ccc3c(c2)Oc2c4c(cc5ccccc25)N(c2c(-c5ccccc5)cccc2-c2ccccc2)c2cc5c6c(c2B34)Oc2ccc(-c3ccccc3)cc2B6c2cc(-c3ccccc3)ccc2N5c2ccccc2-c2ccccc2)cc1 ; c1ccc(-c2ccc3c(c2)Oc2cc4ccccc4c4c2B3c2c(cc3c5c2Oc2ccc(-c6ccccc6)cc2B5c2cc(-c5ccccc5)ccc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(ccc2ccccc12)B5c1cc(-c2ccccc2)ccc1N4c1ccccc1-c1ccccc1]

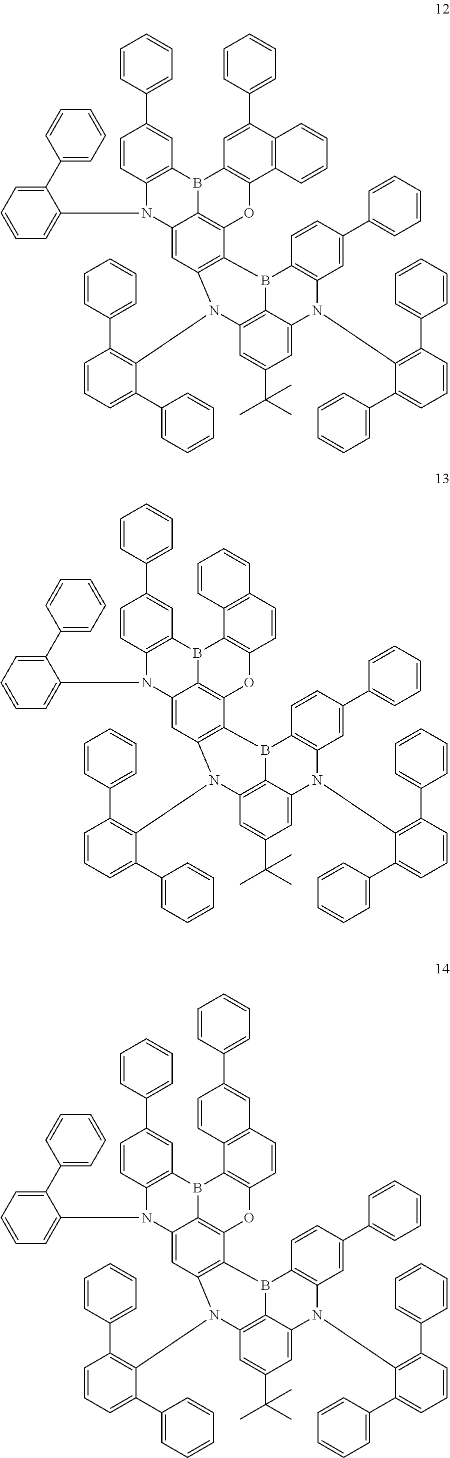

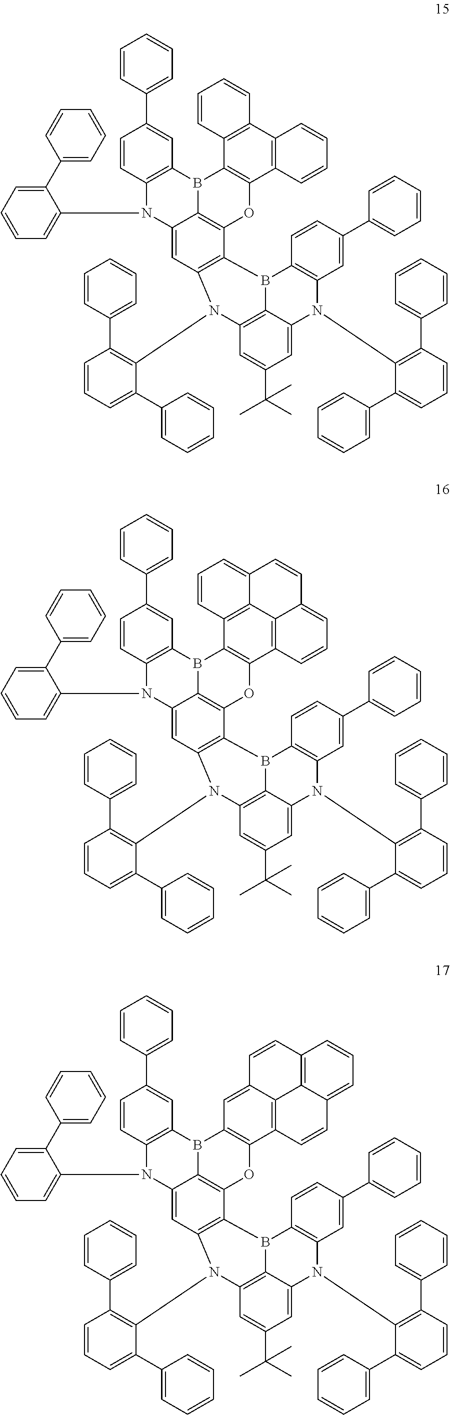

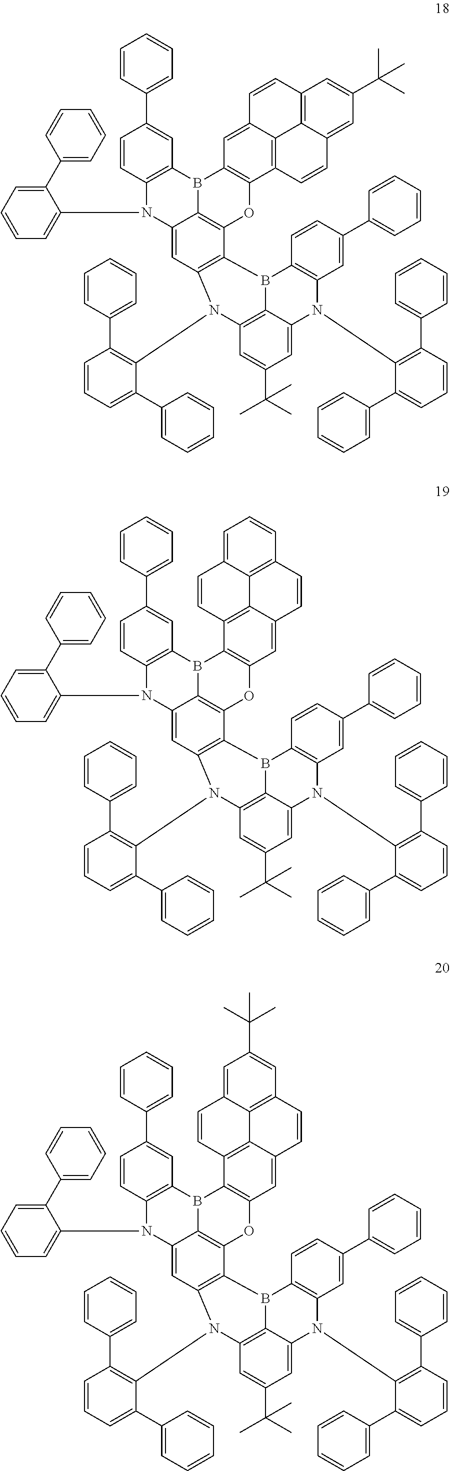

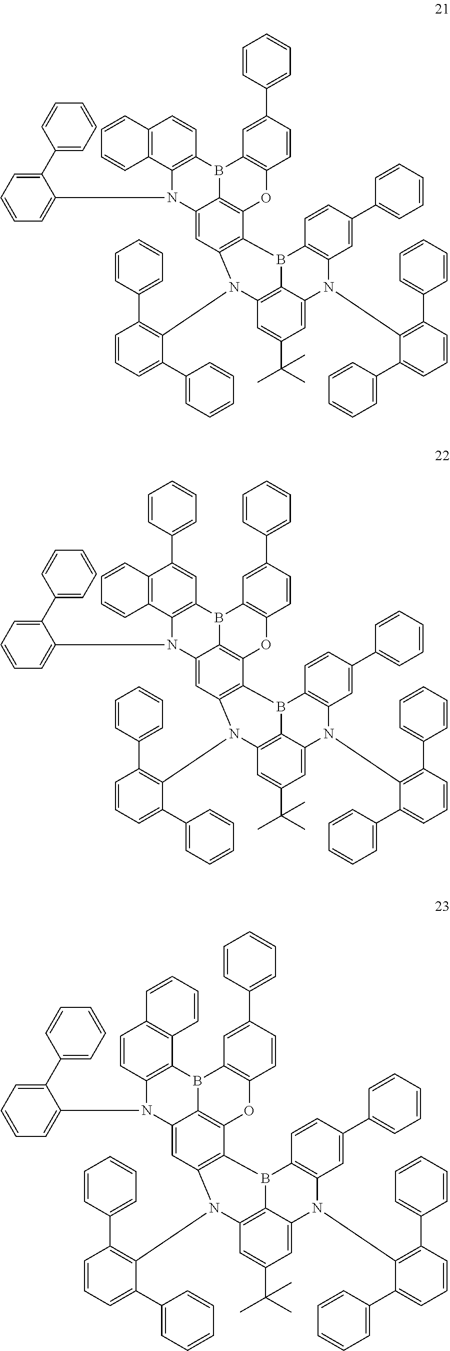

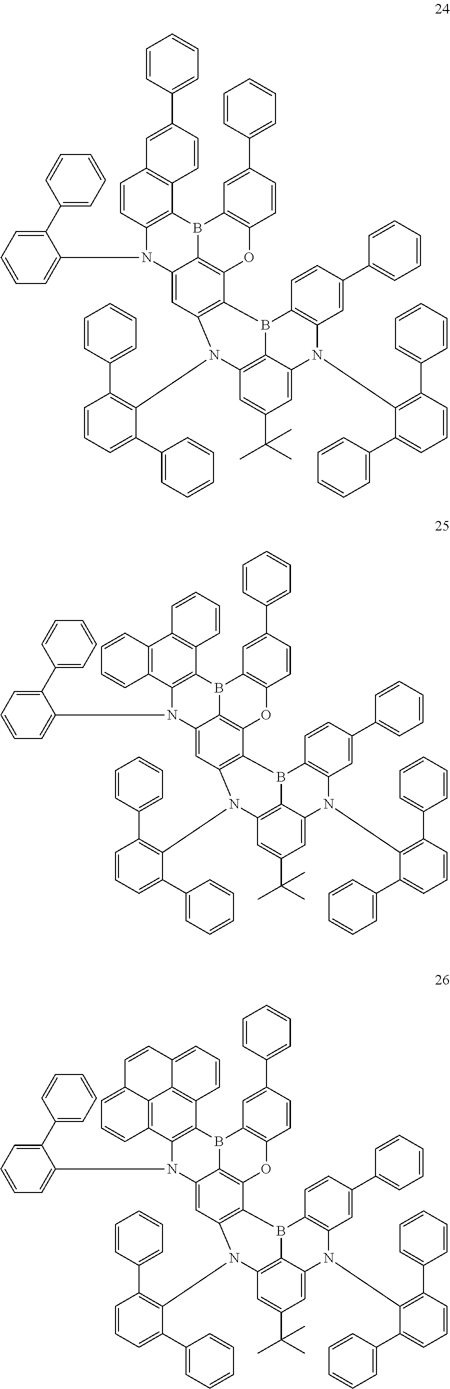

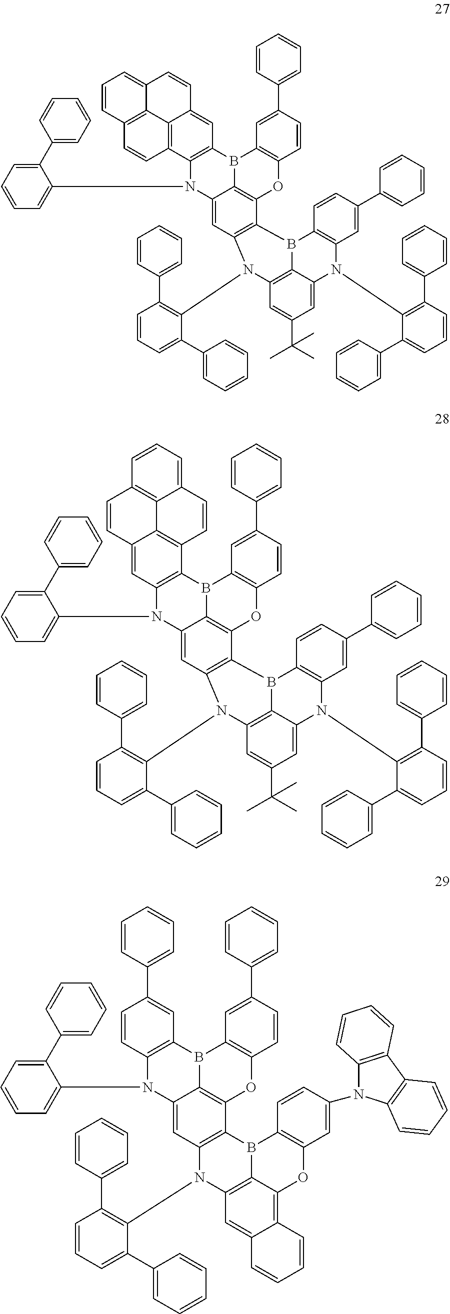

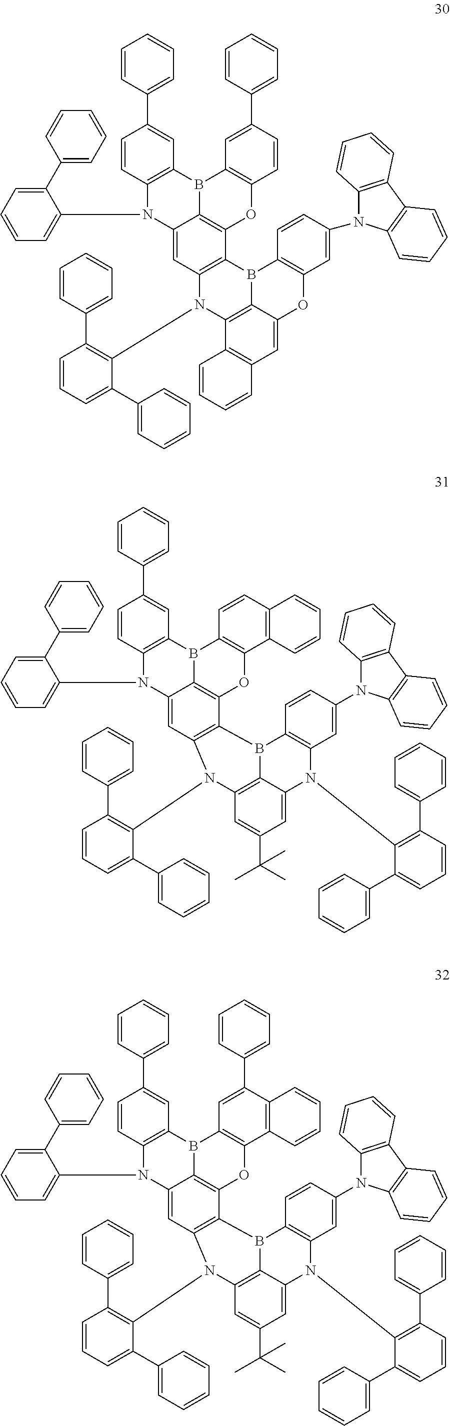

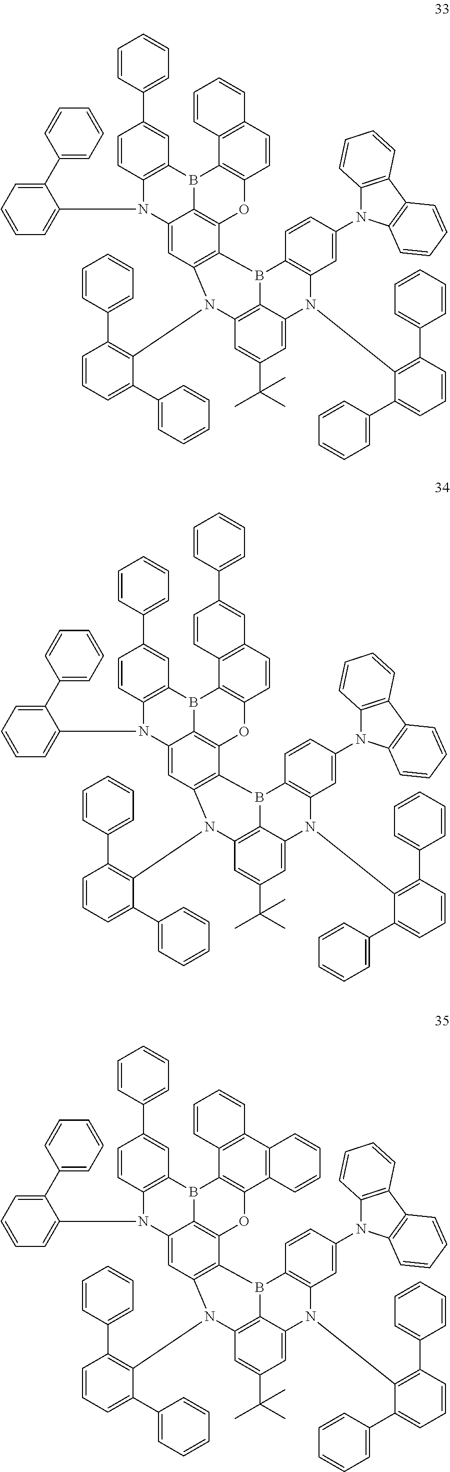

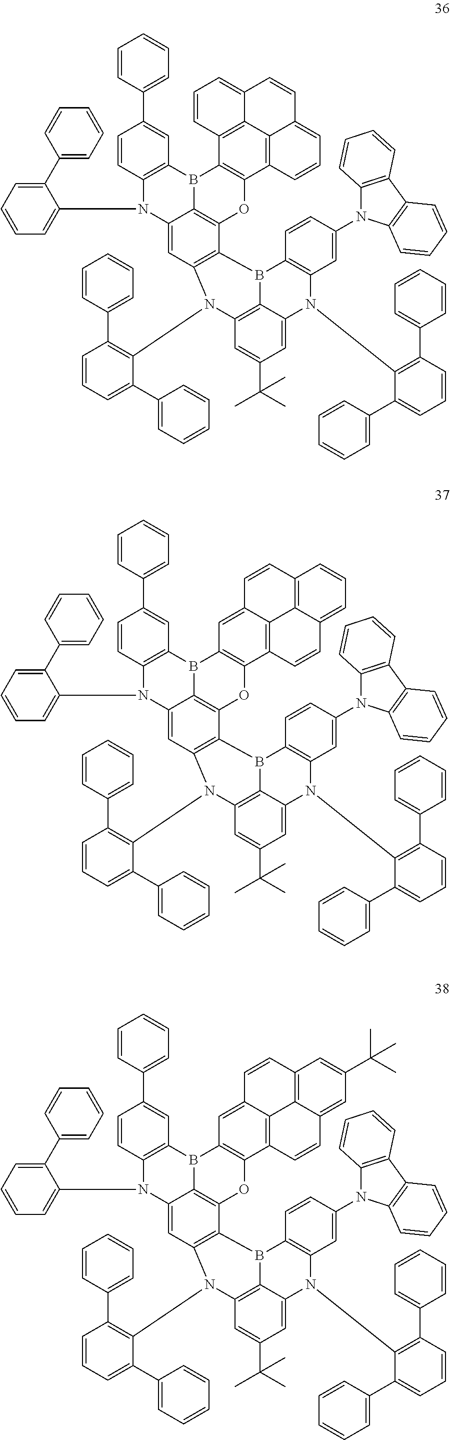

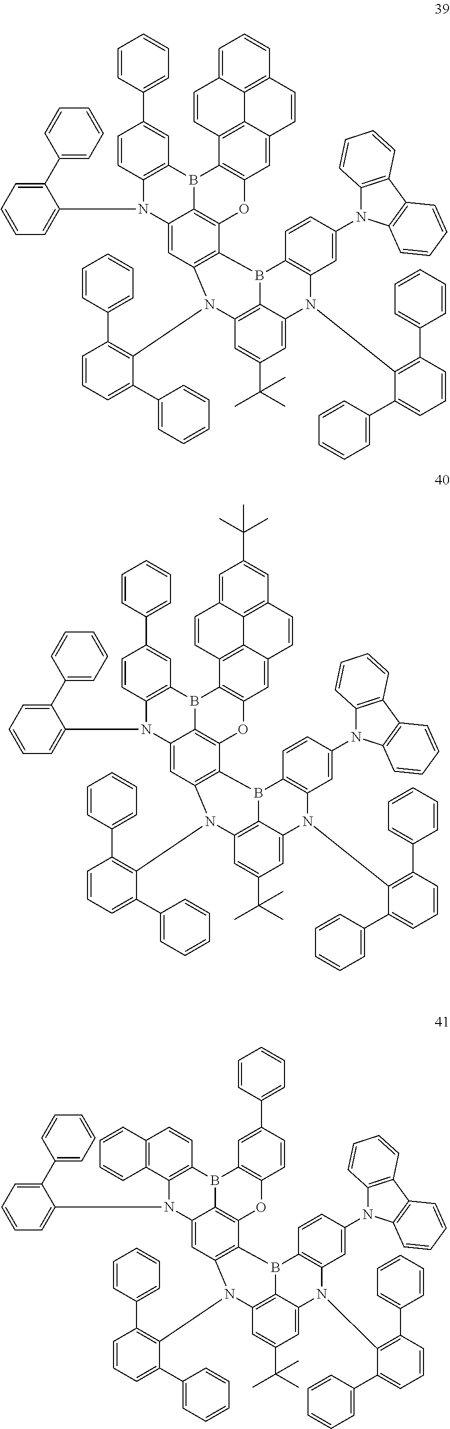

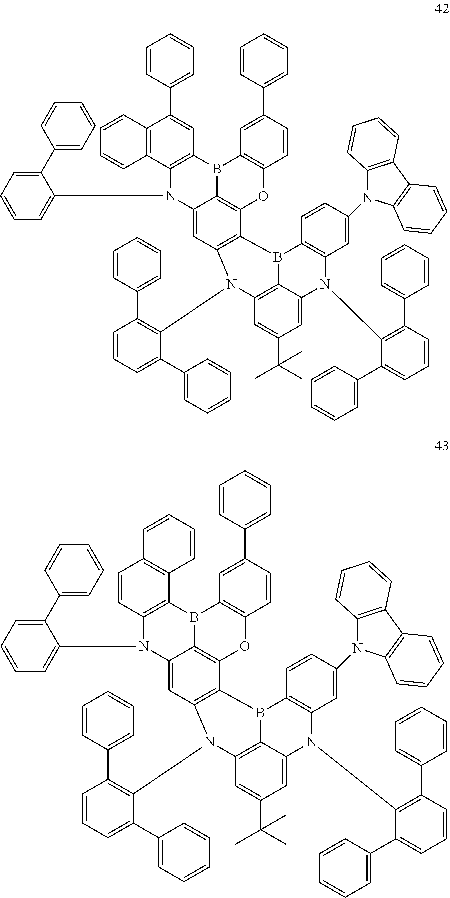 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccc(-c2ccccc2)cc1B5c1cc(-c2ccccc2)c2ccccc2c1N4c1ccccc1-c1ccccc1 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccc(-c2ccccc2)cc1B5c1c(ccc2ccccc12)N4c1ccccc1-c1ccccc1]

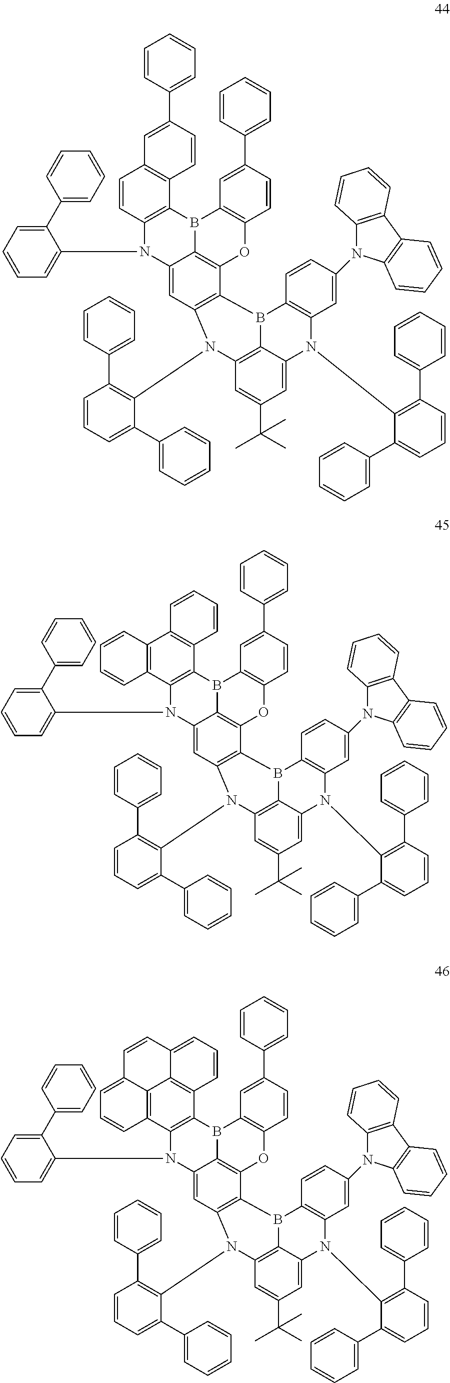

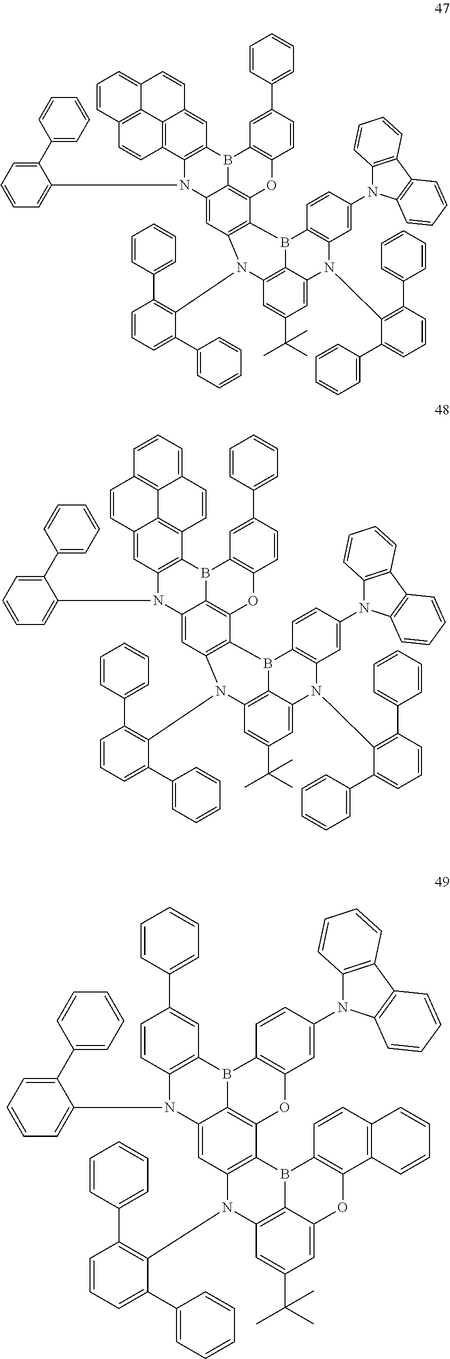

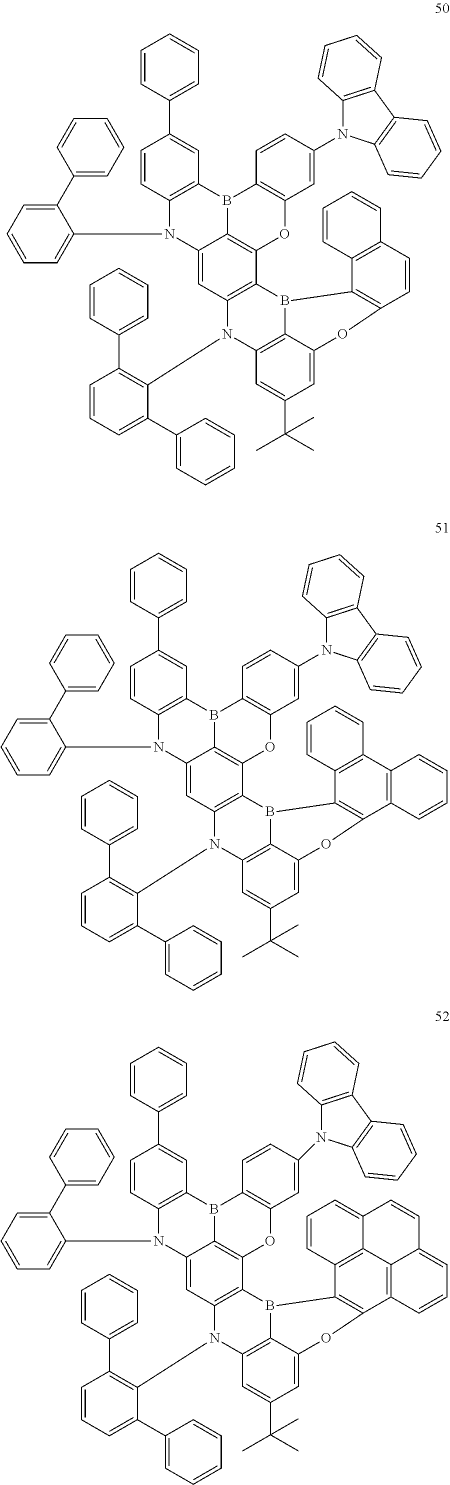 [SMILES: CC(C)(C)c1cc2c3c(c1)N(c1c(-c4ccccc4)cccc1-c1ccccc1)c1cc4c5c(c1B3c1c(ccc3ccccc13)O2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1cc(-n2c3ccccc3c3ccccc32)ccc1B5c1cc(-c2ccccc2)ccc1N4c1ccccc1-c1ccccc1]

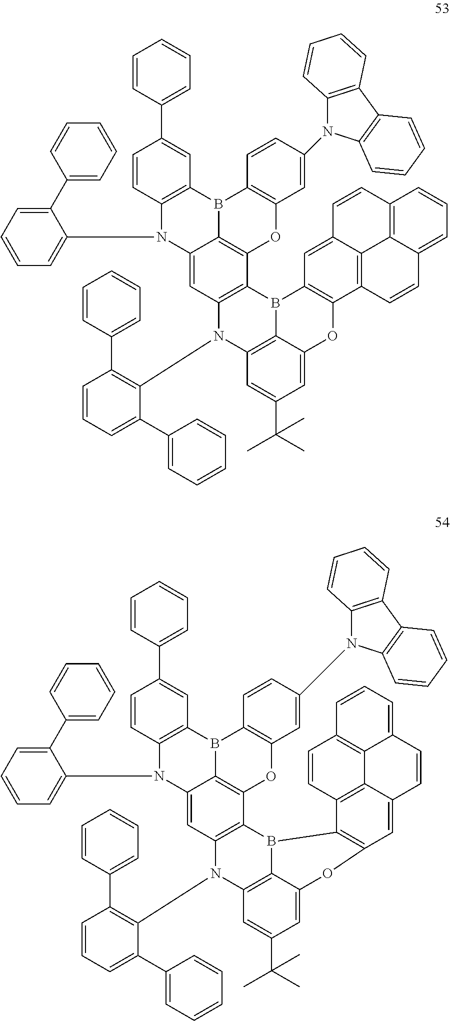 [SMILES: CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1cc(-n2c3ccccc3c3ccccc32)ccc1B5c1cc(-c2ccccc2)ccc1N4c1ccccc1-c1ccccc1]

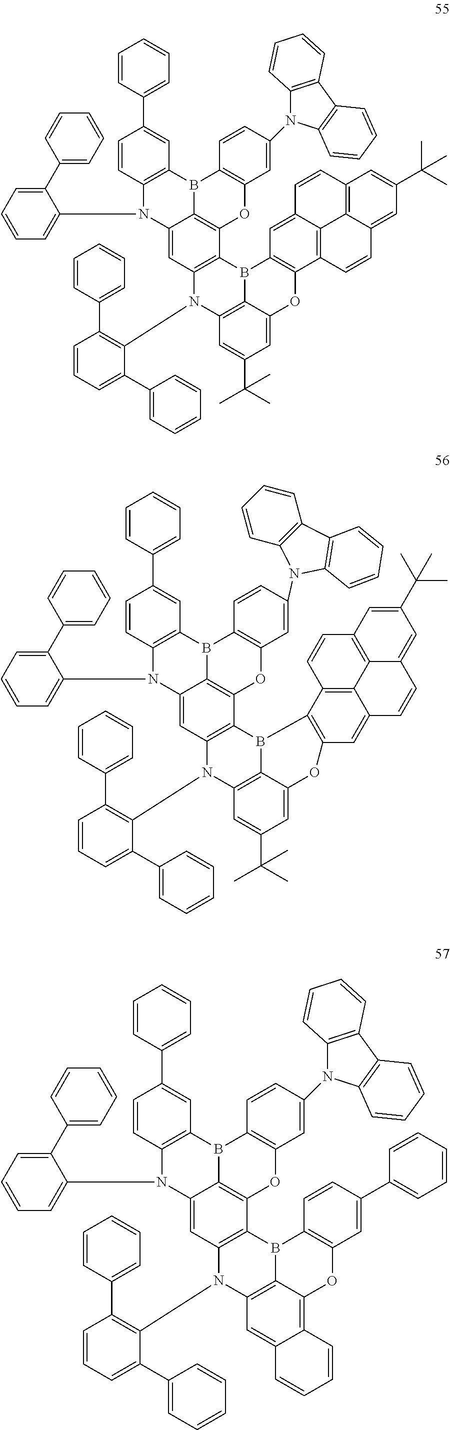

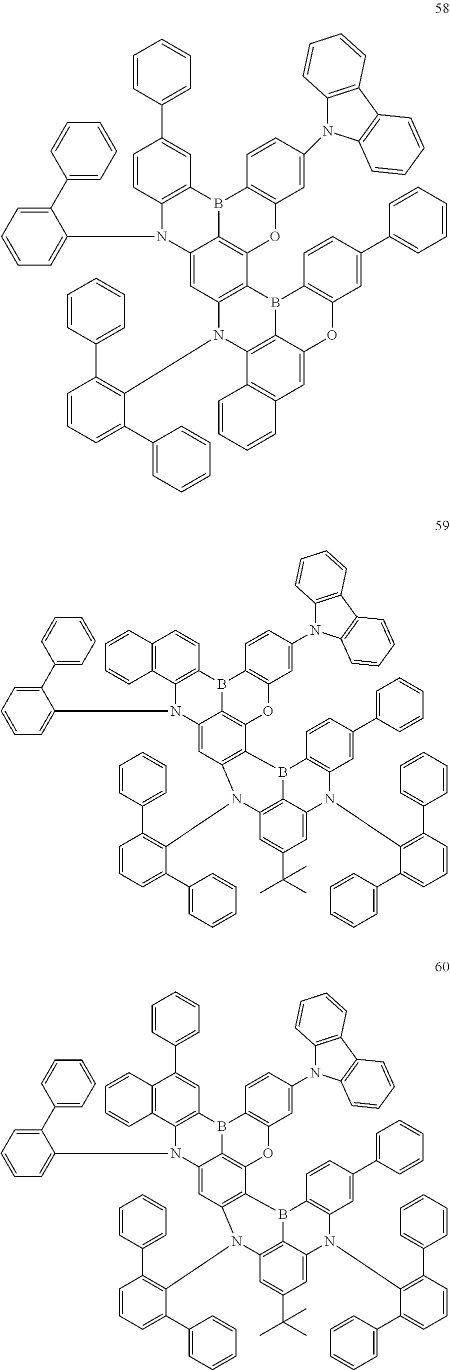

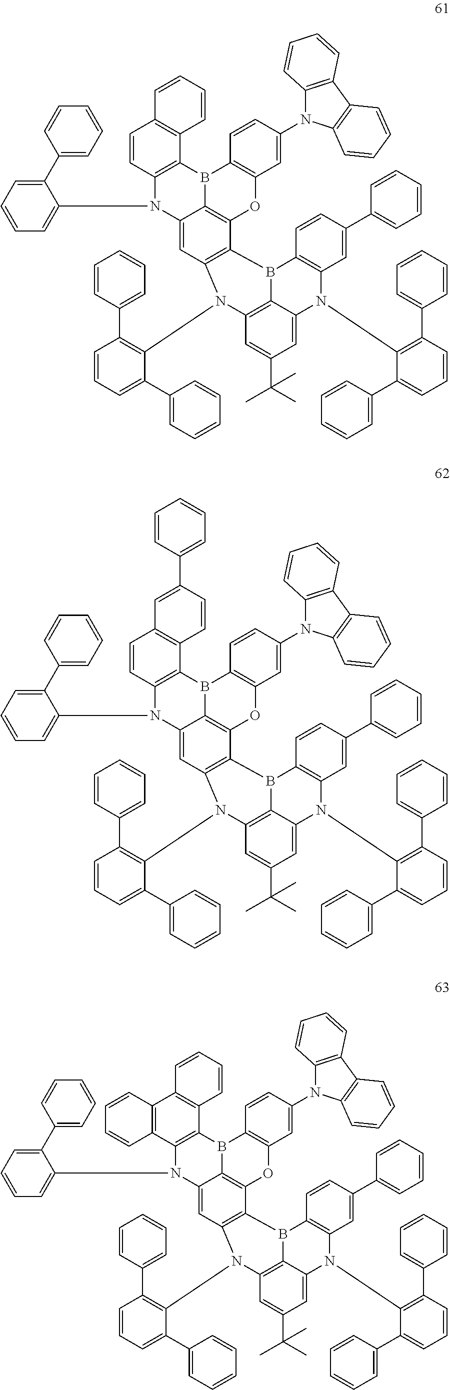

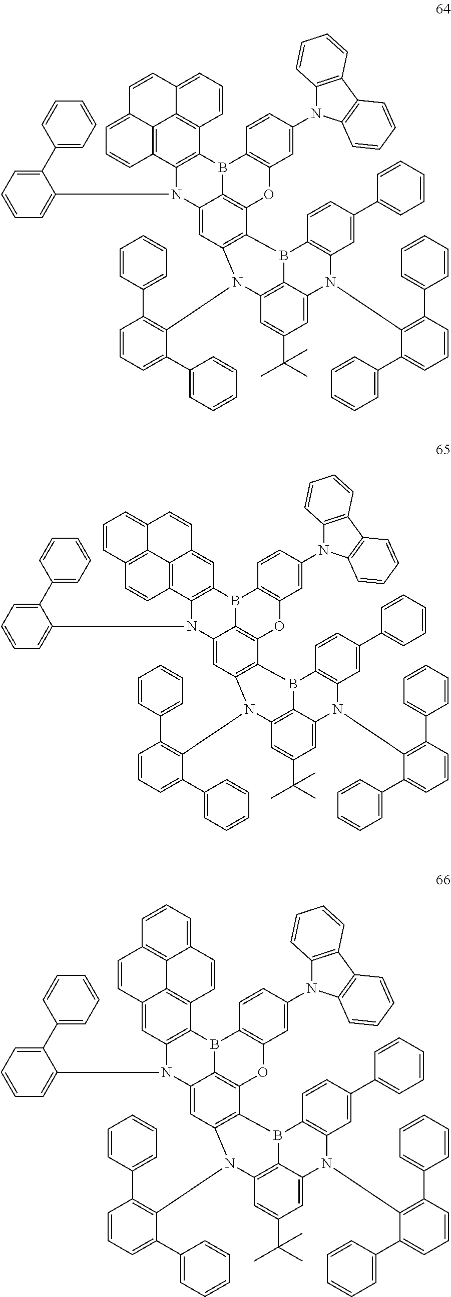

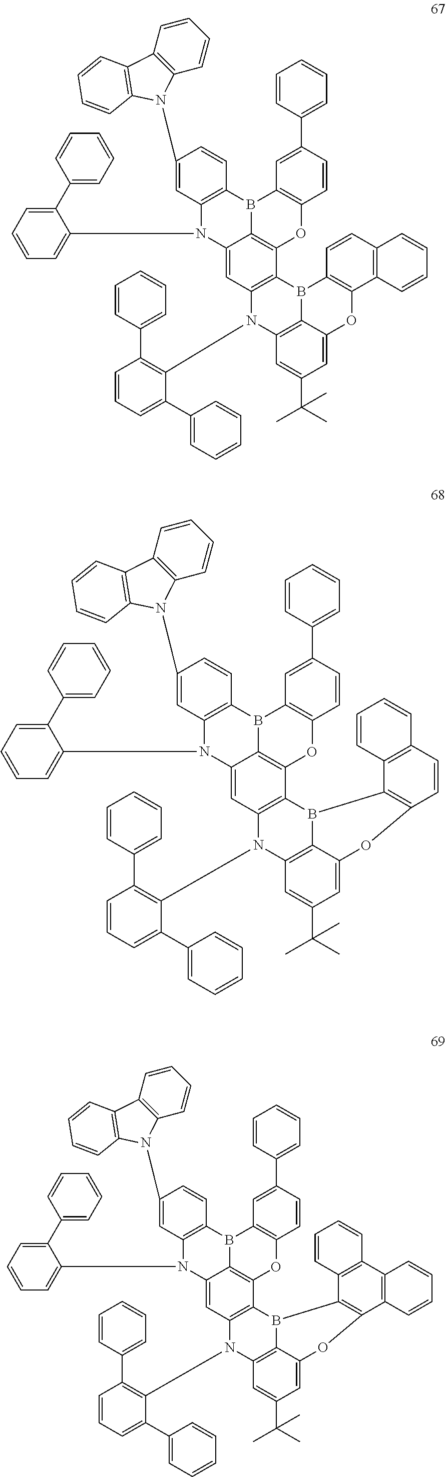 [SMILES: CC(C)(C)c1cc2c3c(c1)N(c1c(-c4ccccc4)cccc1-c1ccccc1)c1cc4c5c(c1B3c1ccc3ccccc3c1O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Oc1ccc(-c2ccccc2)cc1B5c1ccc(-n2c3ccccc3c3ccccc32)cc1N4c1ccccc1-c1ccccc1]

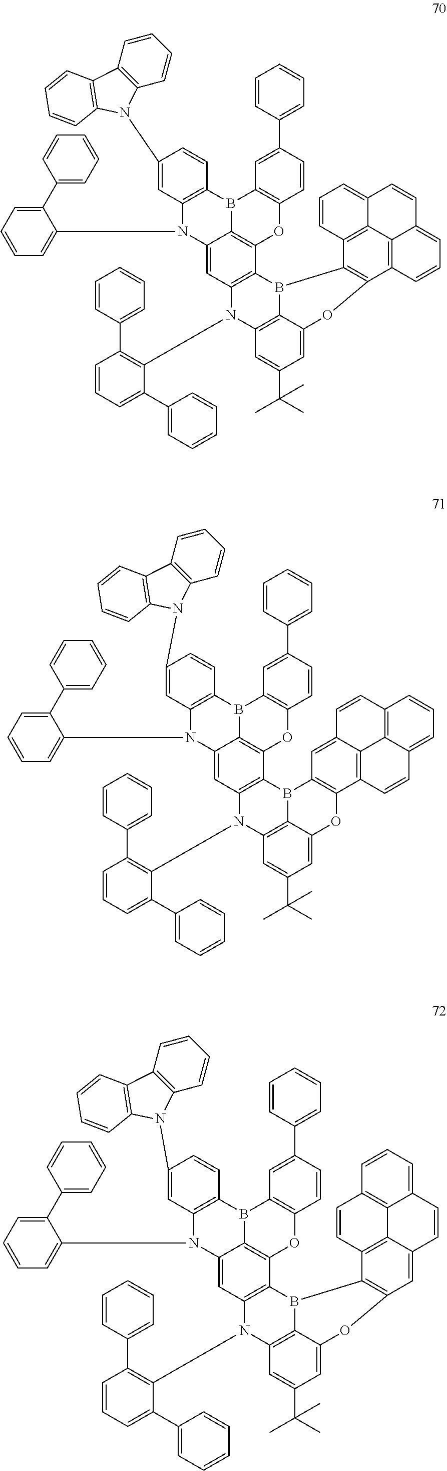 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1ccc(-c2ccccc2)cc1B5c1ccc(-n2c3ccccc3c3ccccc32)cc1N4c1ccccc1-c1ccccc1]

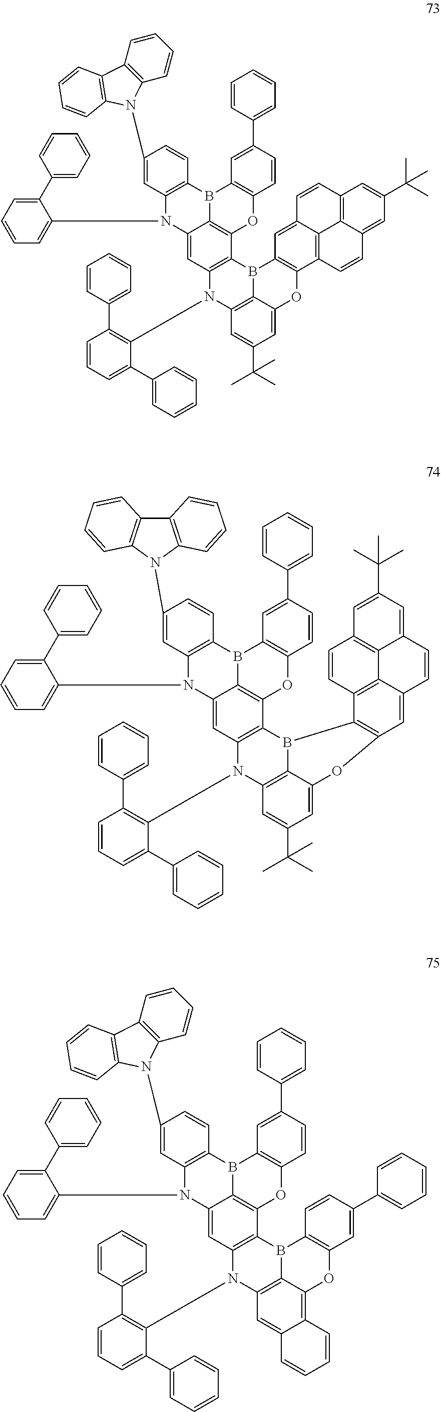

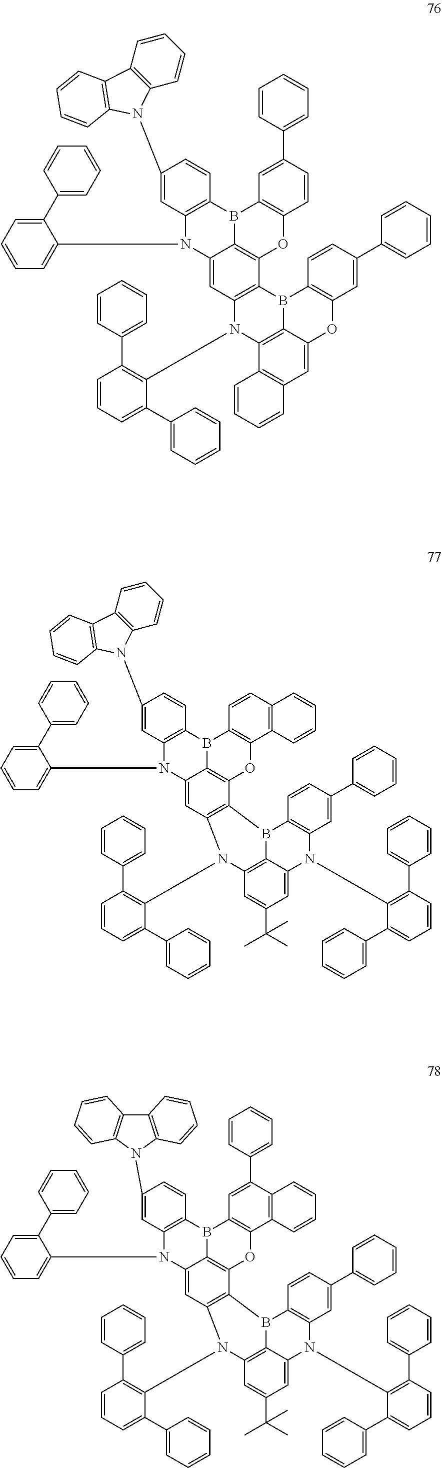

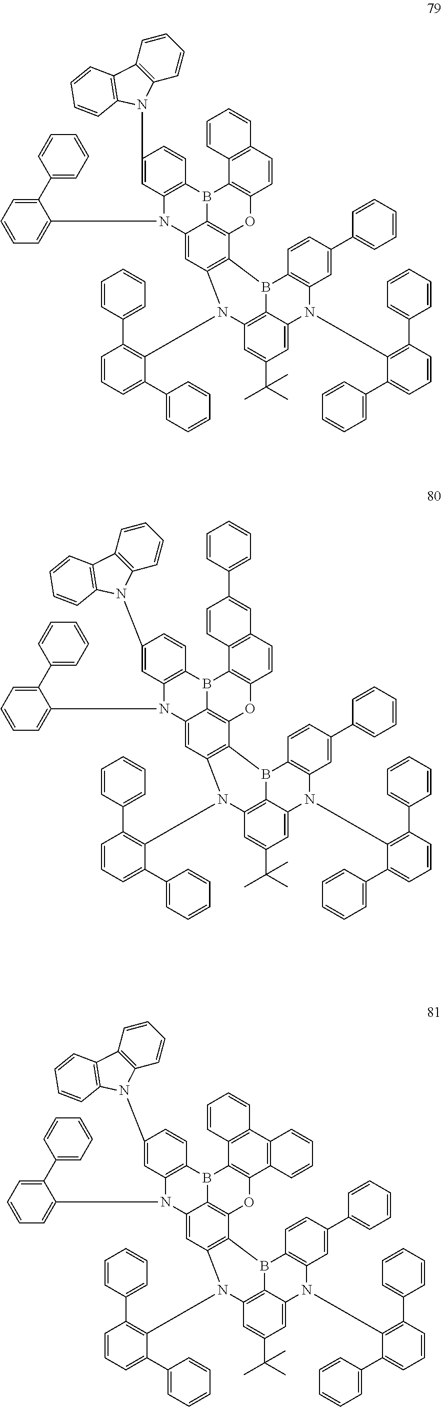

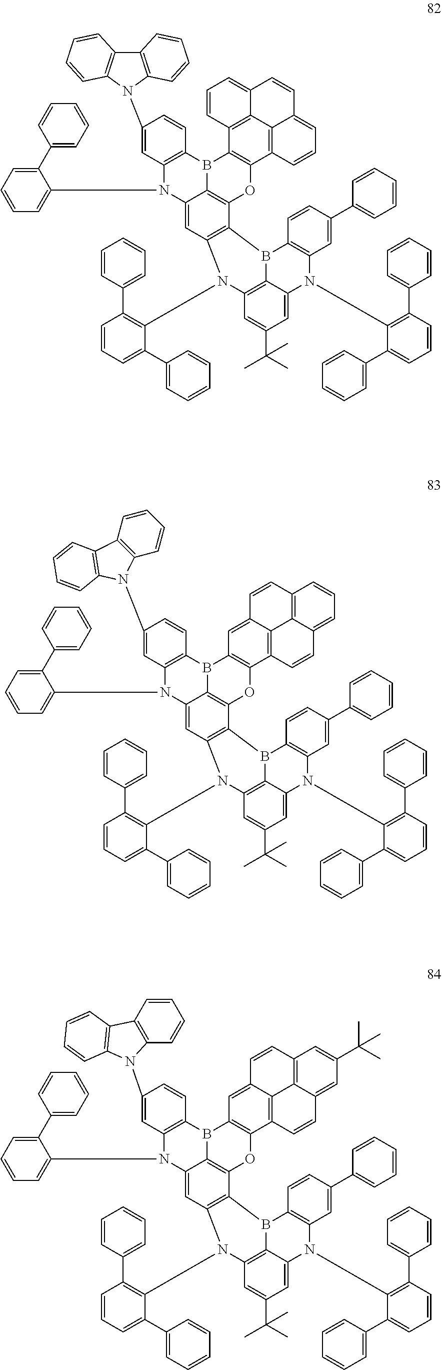

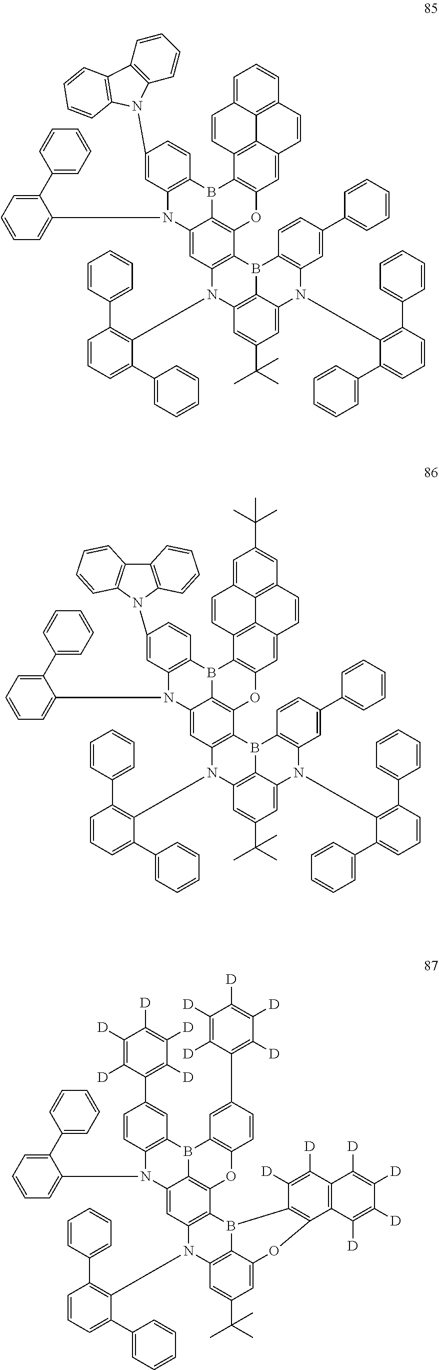

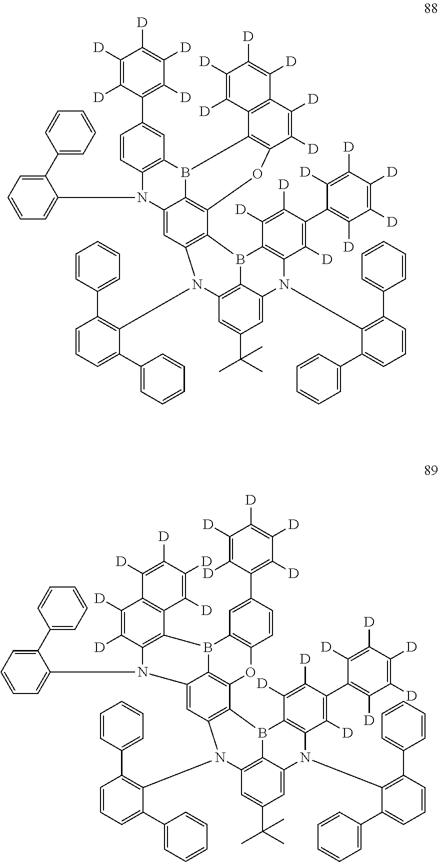

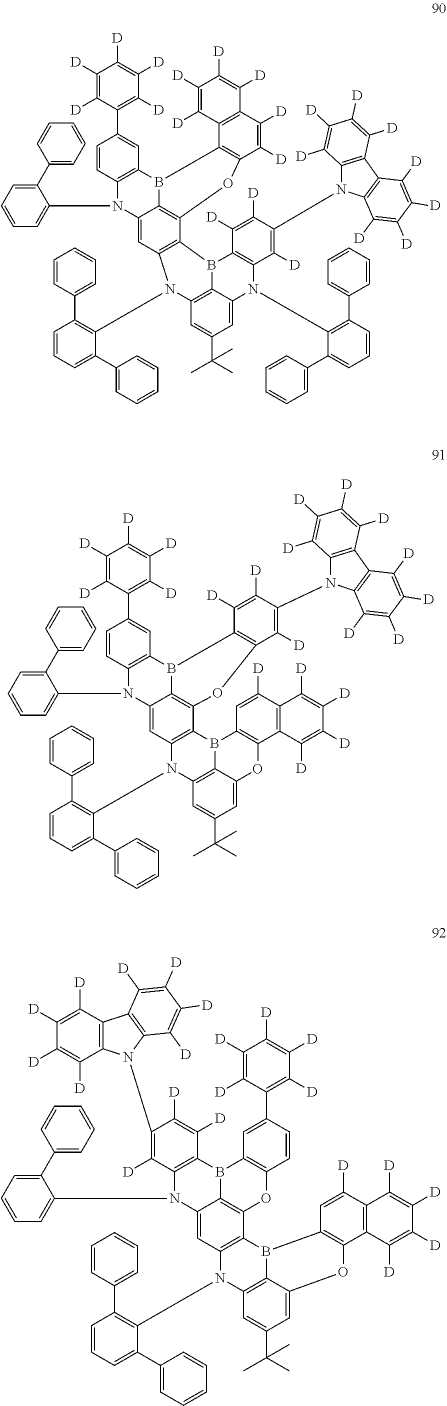

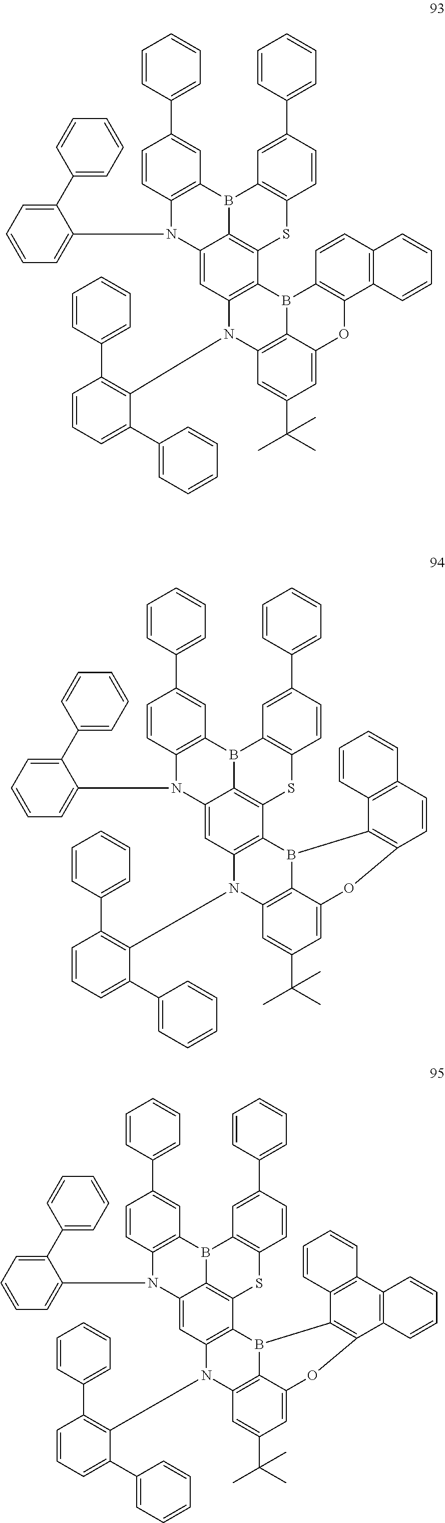 [SMILES: CC(C)(C)c1cc2c3c(c1)N(c1c(-c4ccccc4)cccc1-c1ccccc1)c1cc4c5c(c1B3c1ccc3ccccc3c1O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Sc1ccc(-c2ccccc2)cc1B5c1cc(-c2ccccc2)ccc1N4c1ccccc1-c1ccccc1]

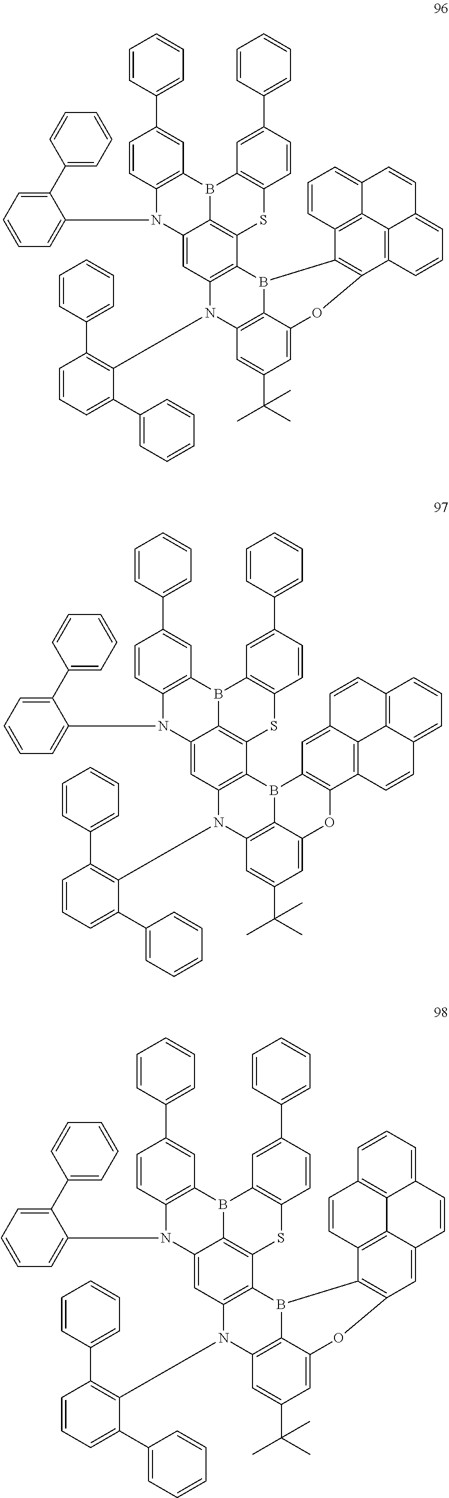 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Sc1ccc(-c2ccccc2)cc1B5c1cc(-c2ccccc2)ccc1N4c1ccccc1-c1ccccc1]

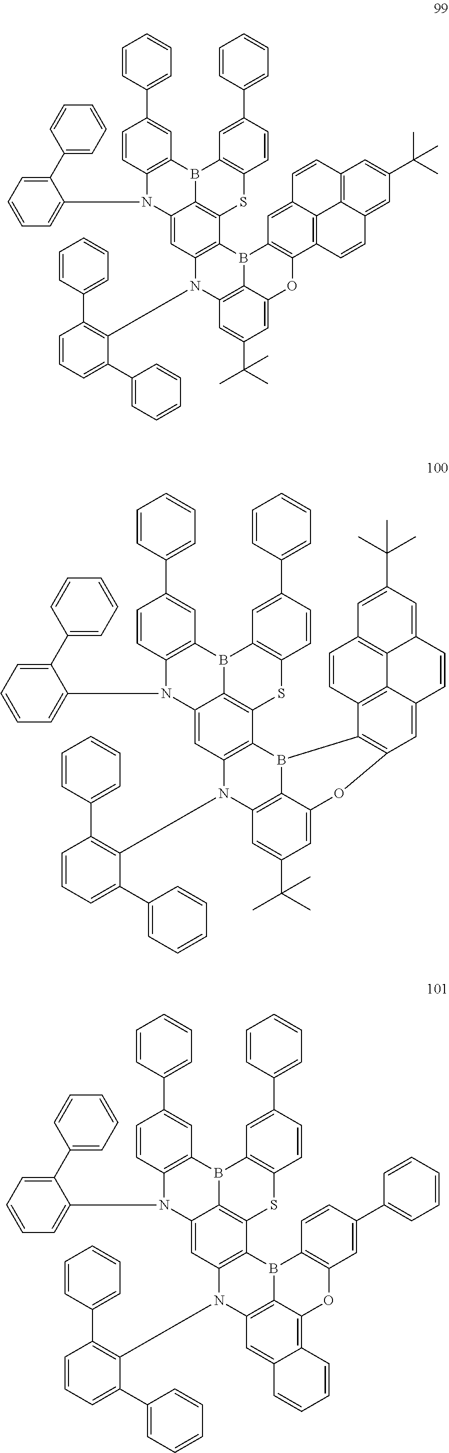 [SMILES: CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1O2)c3c67)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Sc1ccc(-c2ccccc2)cc1B5c1cc(-c2ccccc2)ccc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Sc2ccc(-c3ccccc3)cc2B6c2cc(-c3ccccc3)ccc2N5c2ccccc2-c2ccccc2)cc1]

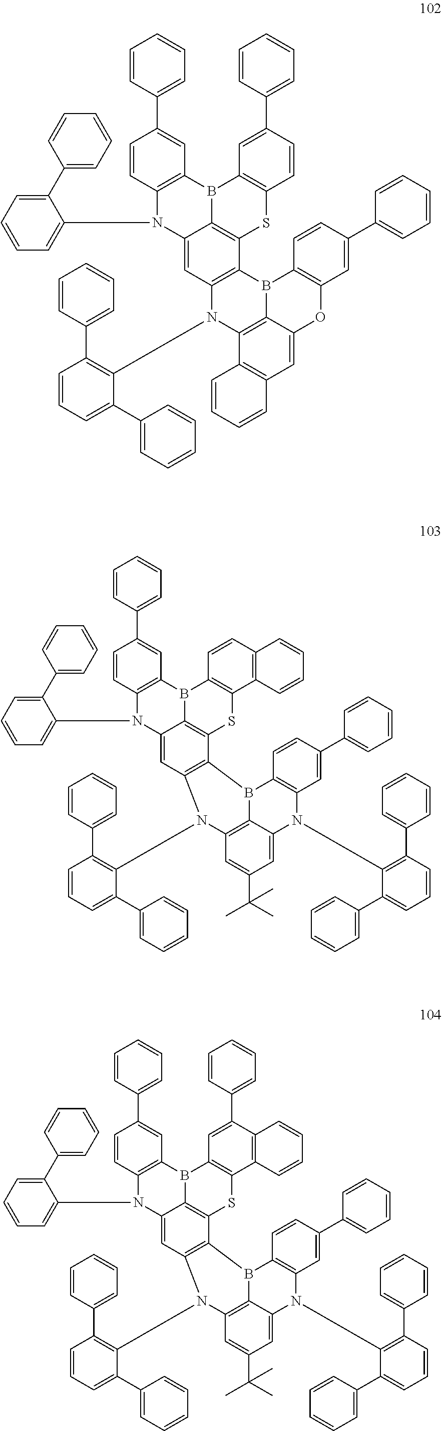

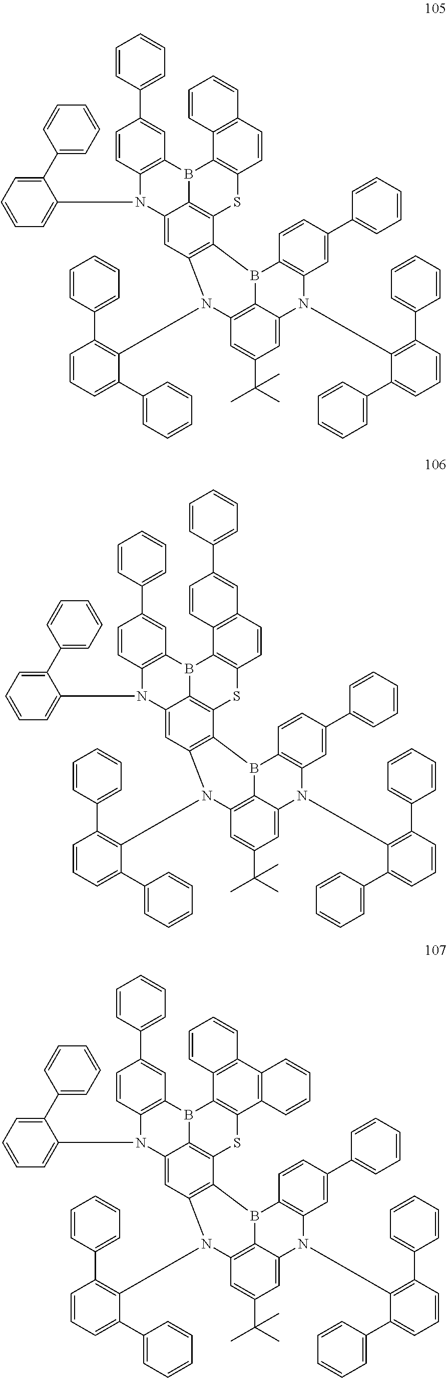

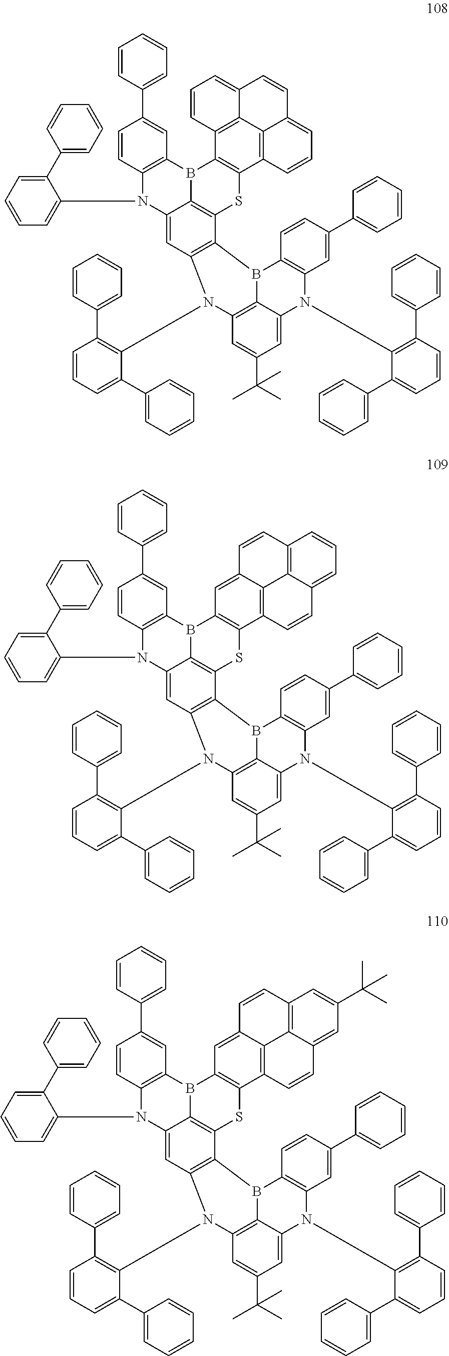

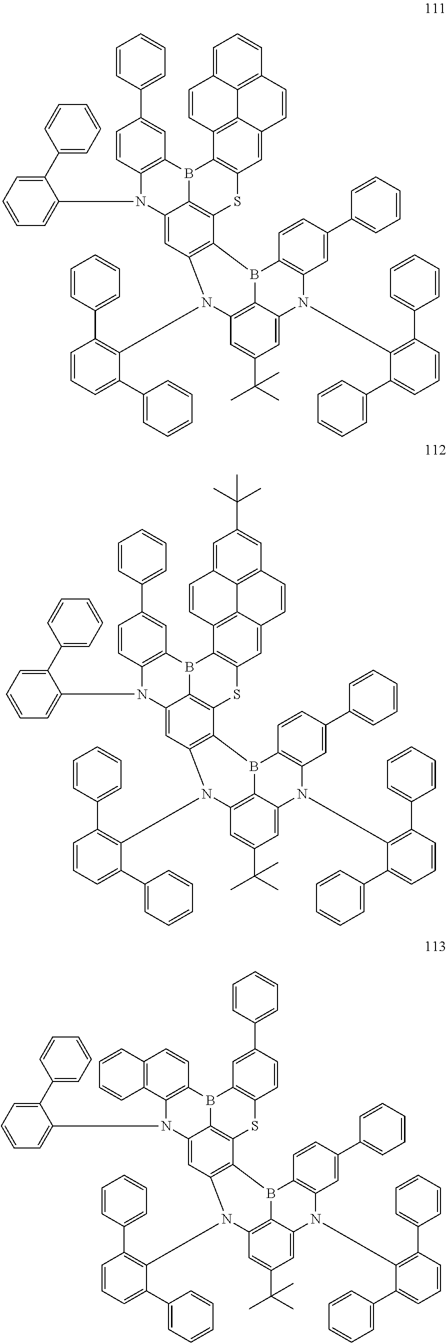

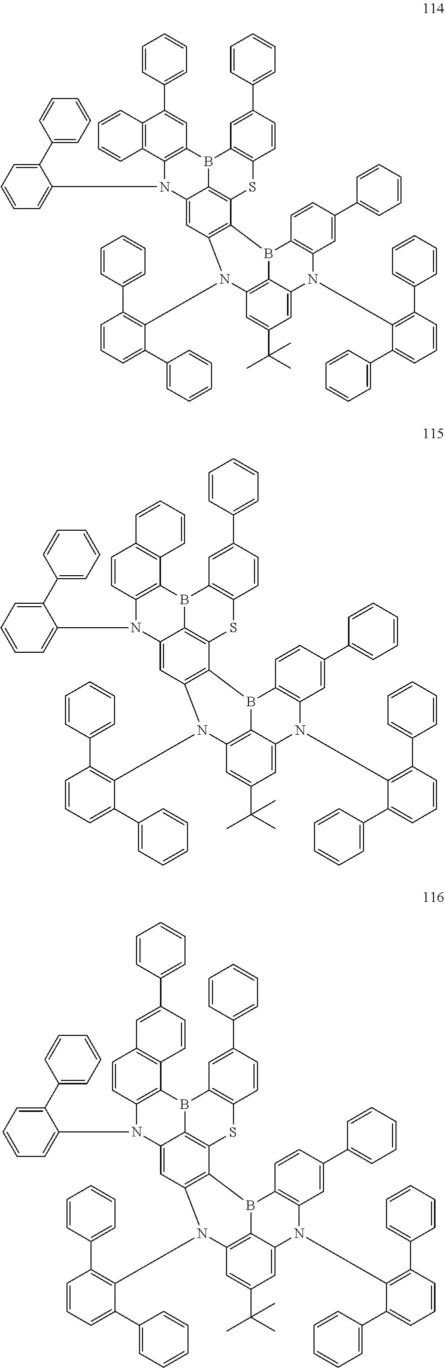

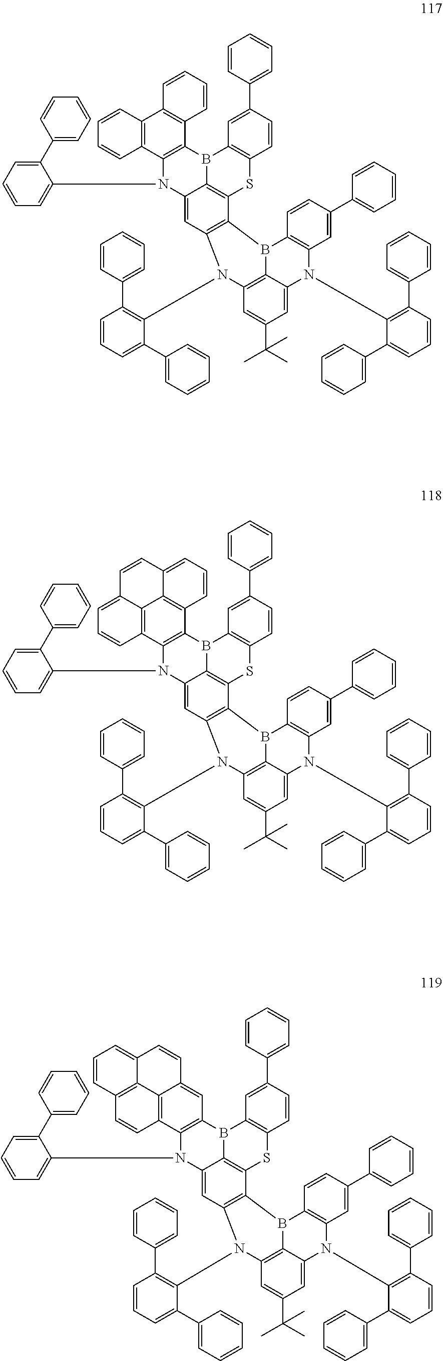

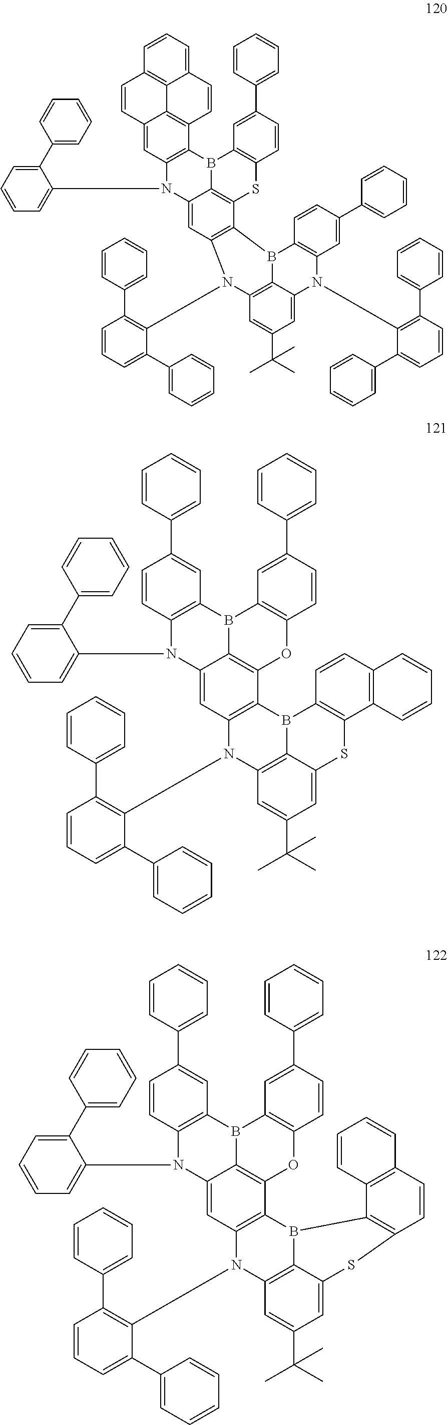 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1c(cc2ccc3cccc5ccc1c2c35)N4c1ccccc1-c1ccccc1 ; CC(C)(C)c1cc2c3c(c1)N(c1c(-c4ccccc4)cccc1-c1ccccc1)c1cc4c5c(c1B3c1ccc3ccccc3c1S2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)S2)Oc1ccc(-c2ccccc2)cc1B5c1cc(-c2ccccc2)ccc1N4c1ccccc1-c1ccccc1]

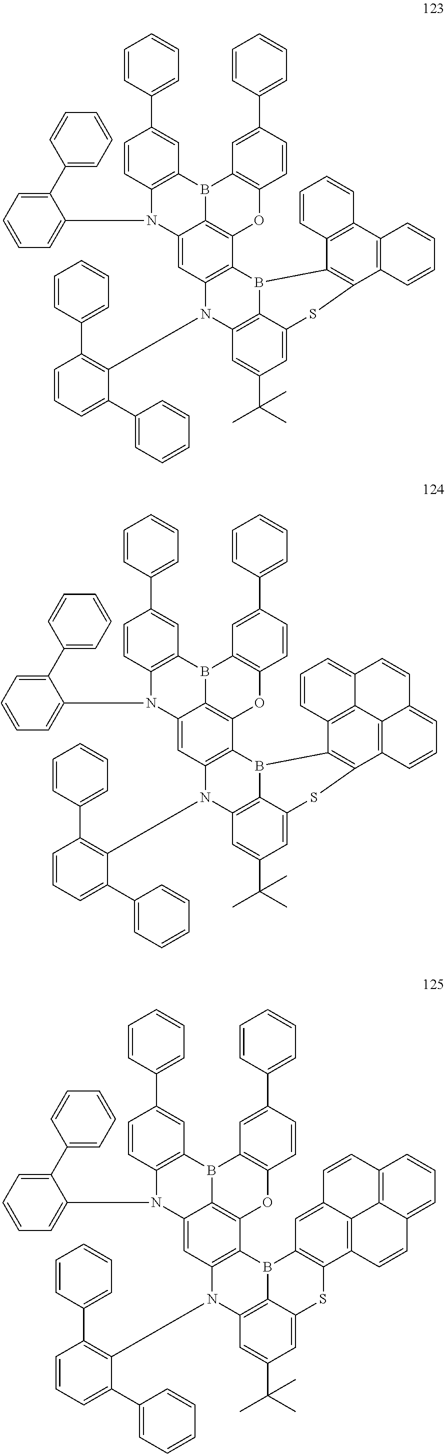 [SMILES: CC(C)(C)c1cc2c3c(c1)N(c1c(-c4ccccc4)cccc1-c1ccccc1)c1cc4c5c(c1B3c1c(c3ccccc3c3ccccc13)S2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)S2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1S2)c3c67)Oc1ccc(-c2ccccc2)cc1B5c1cc(-c2ccccc2)ccc1N4c1ccccc1-c1ccccc1]

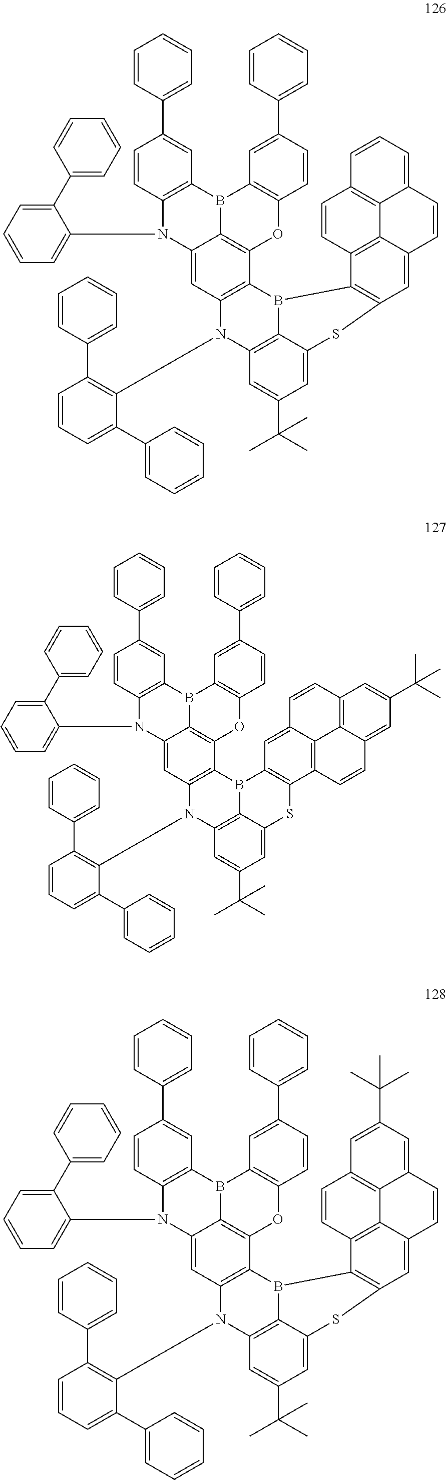 [SMILES: CC(C)(C)c1cc2c3c(c1)N(c1c(-c4ccccc4)cccc1-c1ccccc1)c1cc4c5c(c1B3c1c(cc3ccc6cccc7ccc1c3c67)S2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1S2)c3c67)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)S2)Oc1ccc(-c2ccccc2)cc1B5c1cc(-c2ccccc2)ccc1N4c1ccccc1-c1ccccc1]

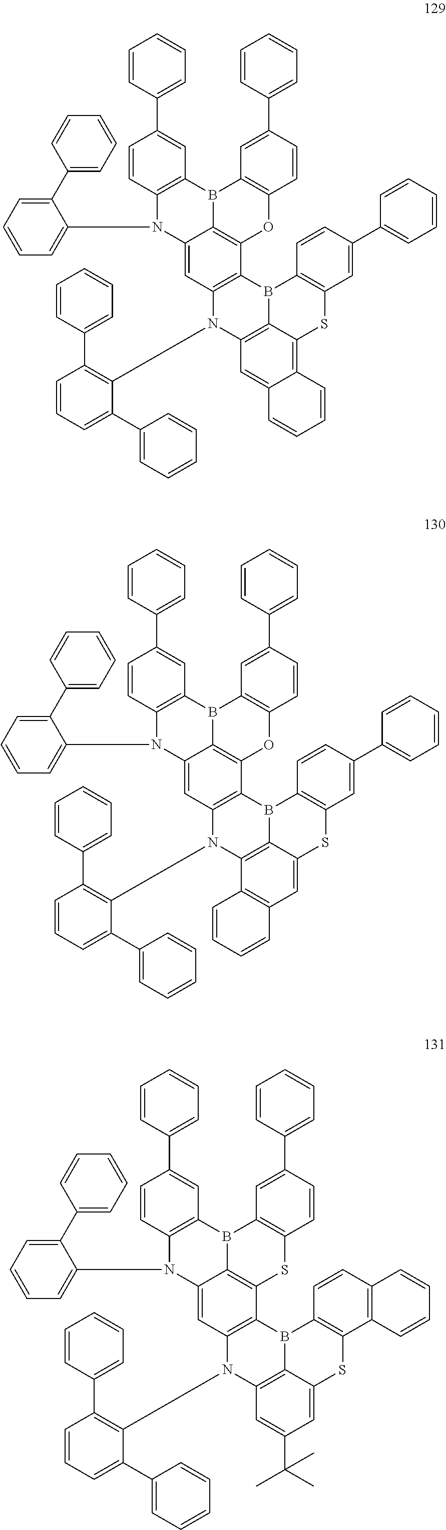 [SMILES: c1ccc(-c2ccc3c(c2)Sc2c4c(cc5ccccc25)N(c2c(-c5ccccc5)cccc2-c2ccccc2)c2cc5c6c(c2B34)Oc2ccc(-c3ccccc3)cc2B6c2cc(-c3ccccc3)ccc2N5c2ccccc2-c2ccccc2)cc1 ; c1ccc(-c2ccc3c(c2)Sc2cc4ccccc4c4c2B3c2c(cc3c5c2Oc2ccc(-c6ccccc6)cc2B5c2cc(-c5ccccc5)ccc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc3ccccc3c1S2)Sc1ccc(-c2ccccc2)cc1B5c1cc(-c2ccccc2)ccc1N4c1ccccc1-c1ccccc1]

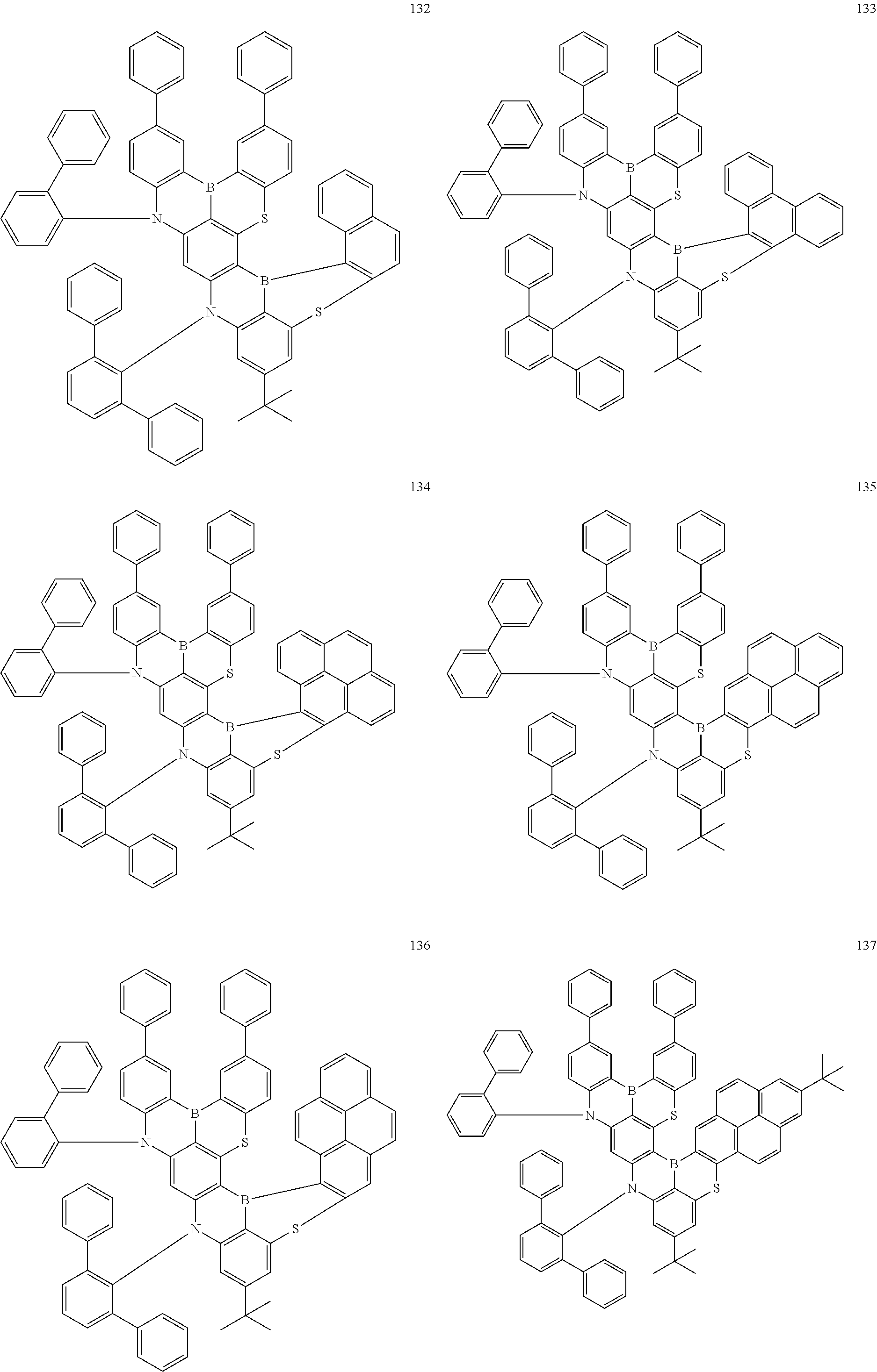

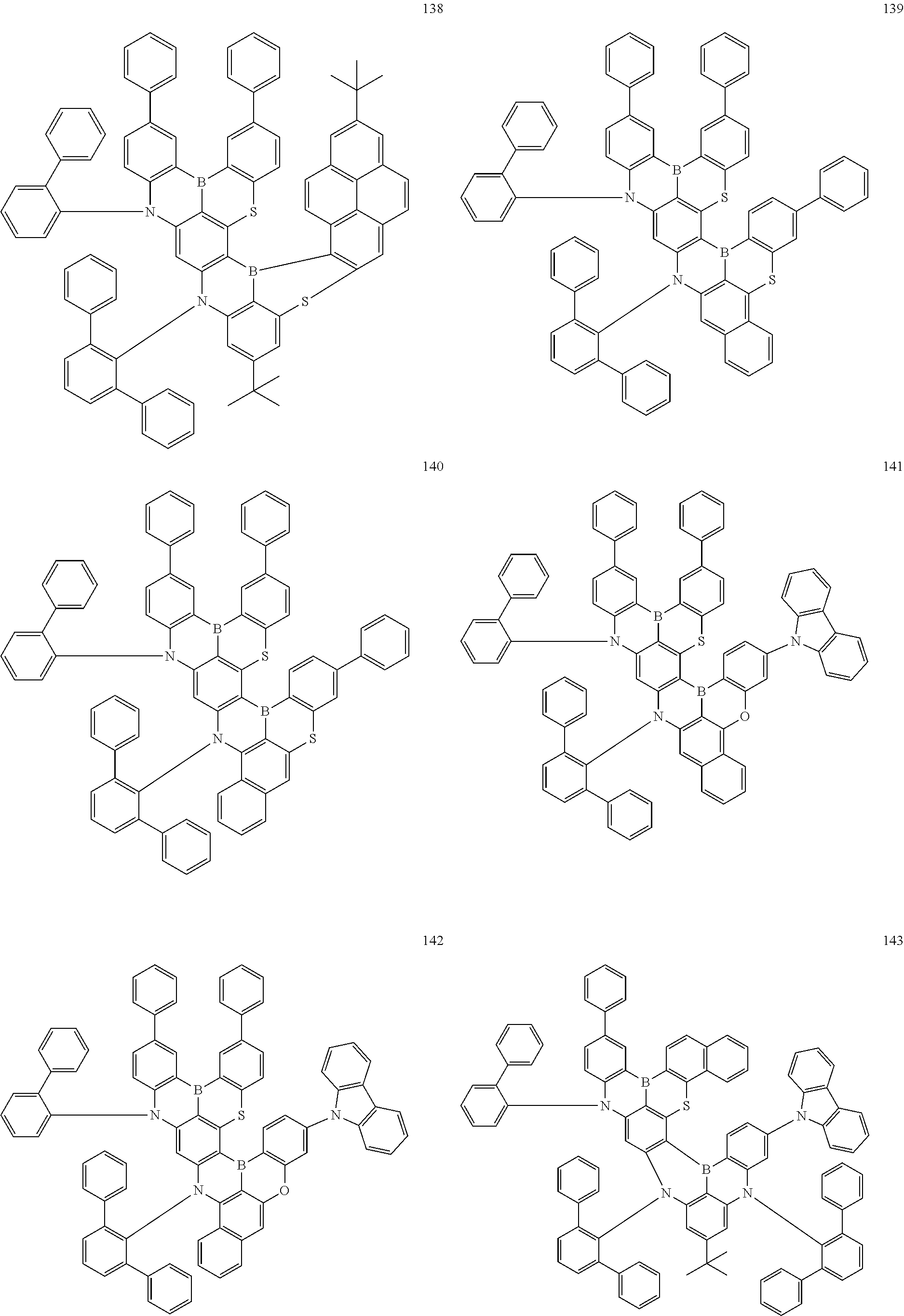

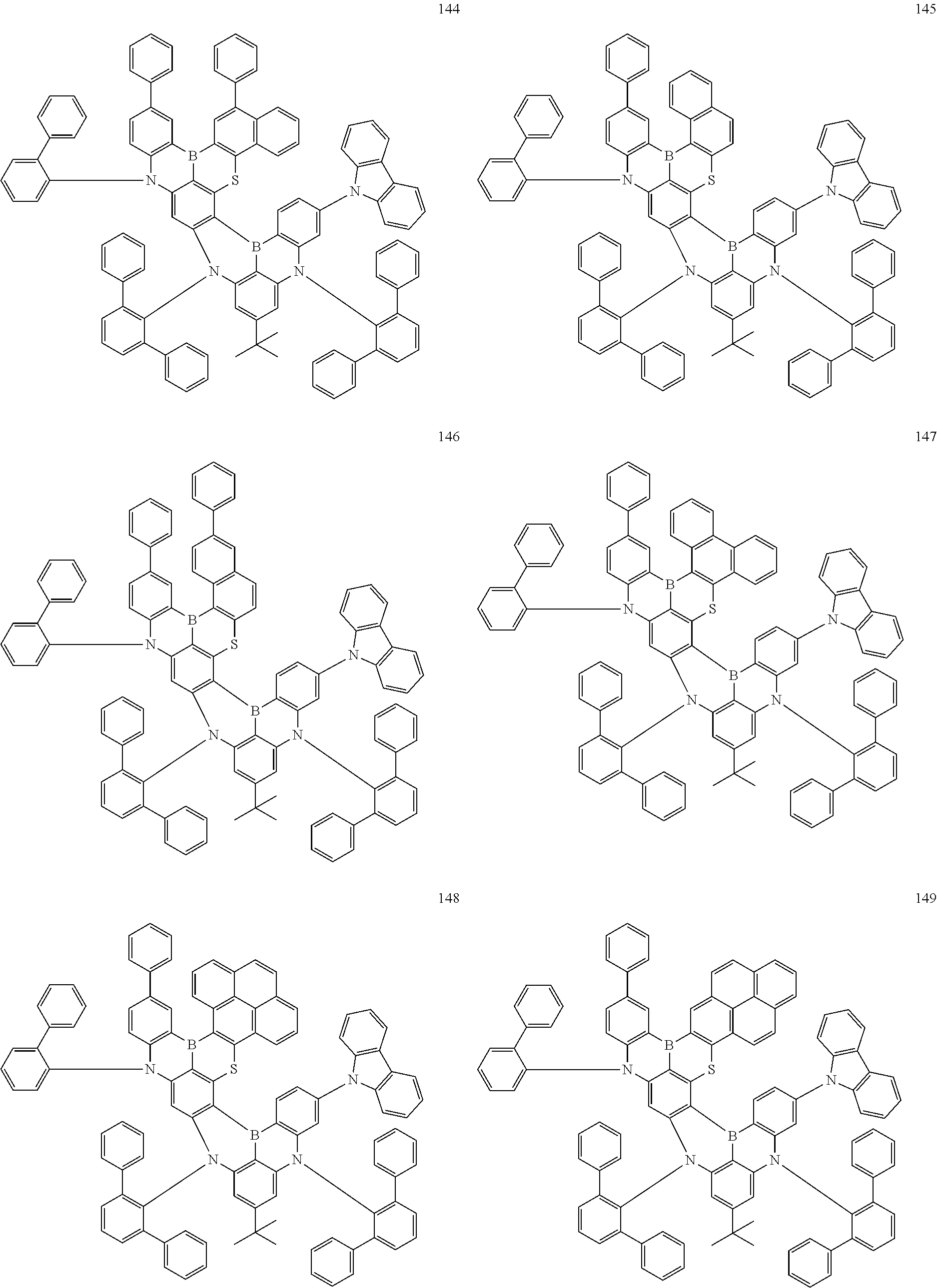

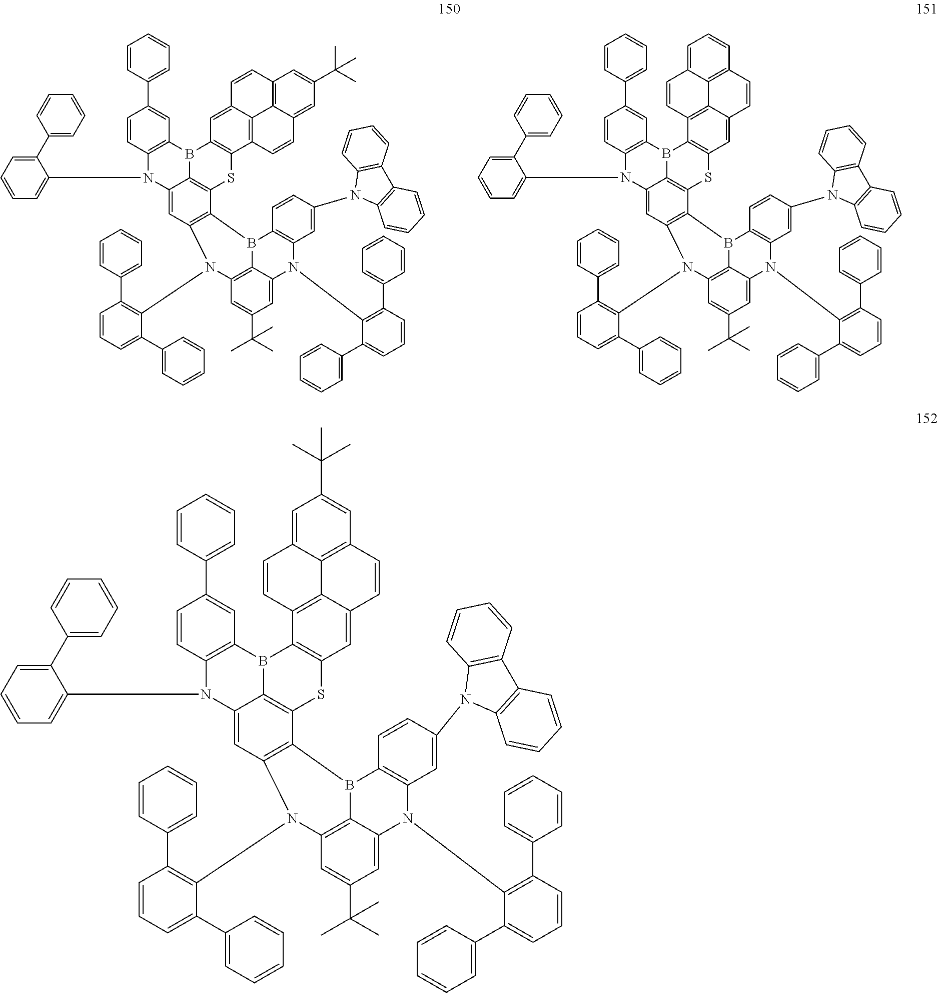

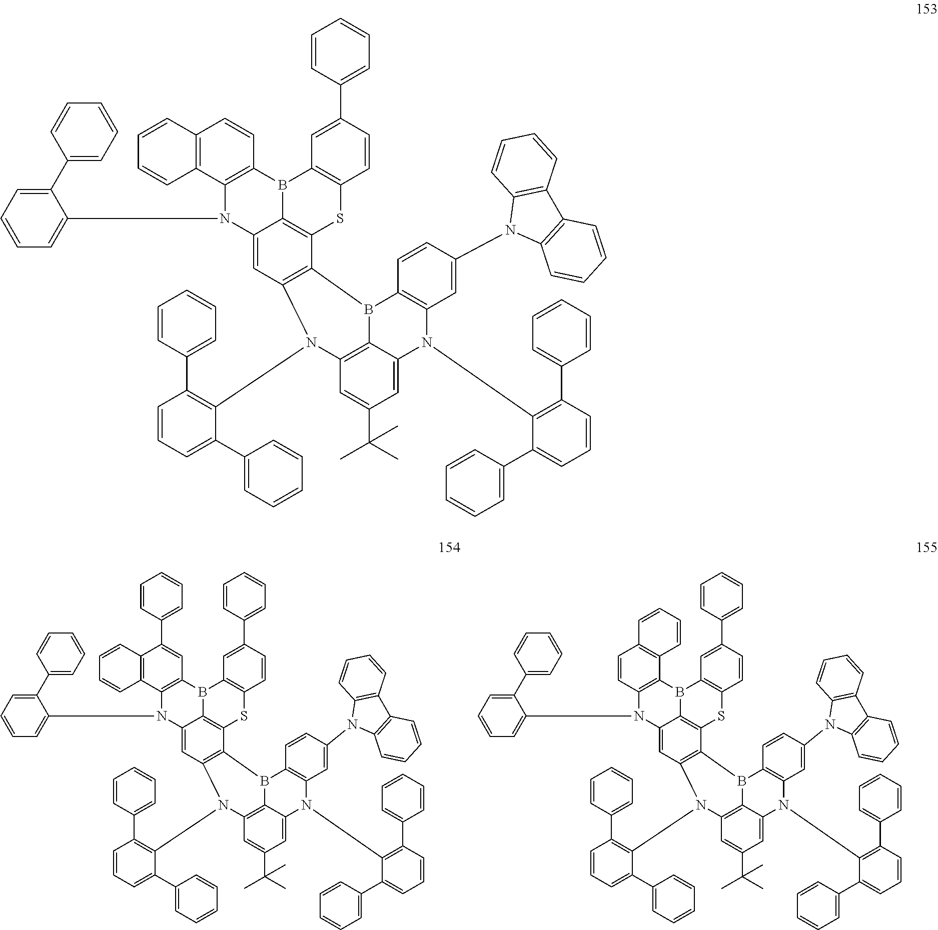

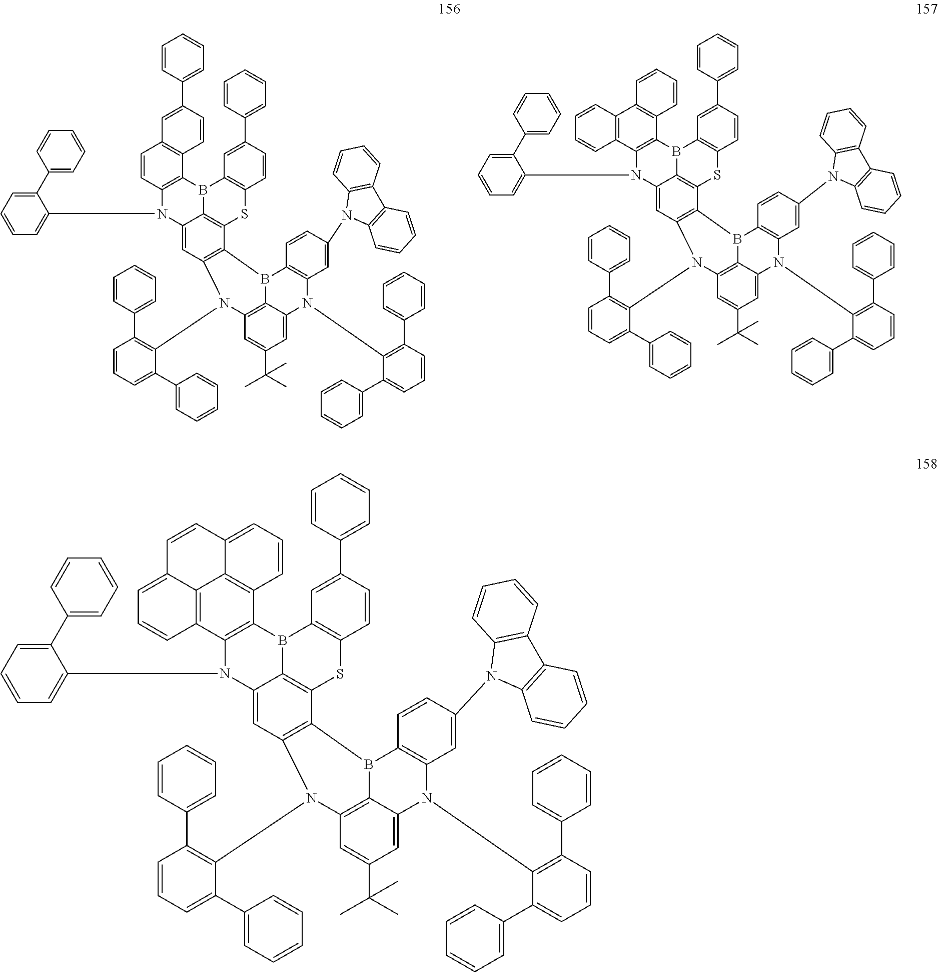

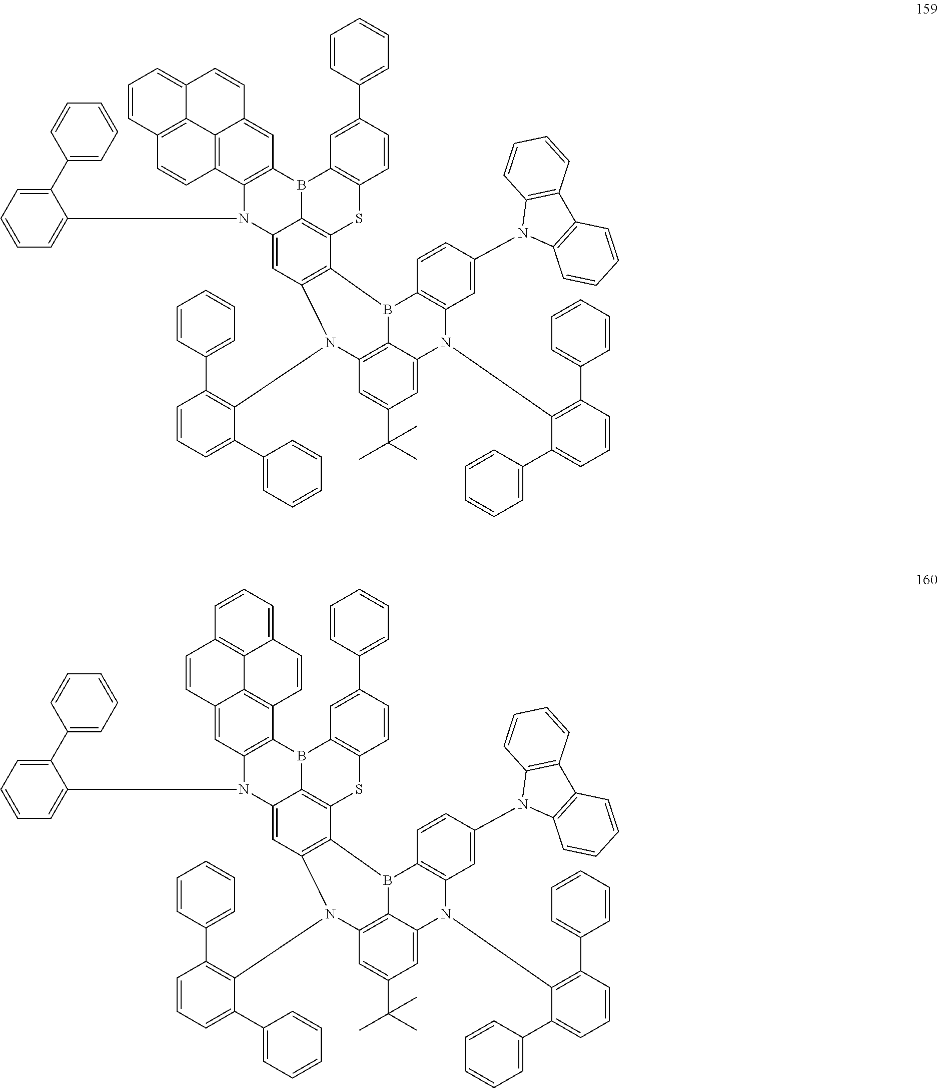 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Sc1ccc(-c2ccccc2)cc1B5c1cc2ccc3cccc5ccc(c1N4c1ccccc1-c1ccccc1)c2c35 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Sc1ccc(-c2ccccc2)cc1B5c1c(cc2ccc3cccc5ccc1c2c35)N4c1ccccc1-c1ccccc1]

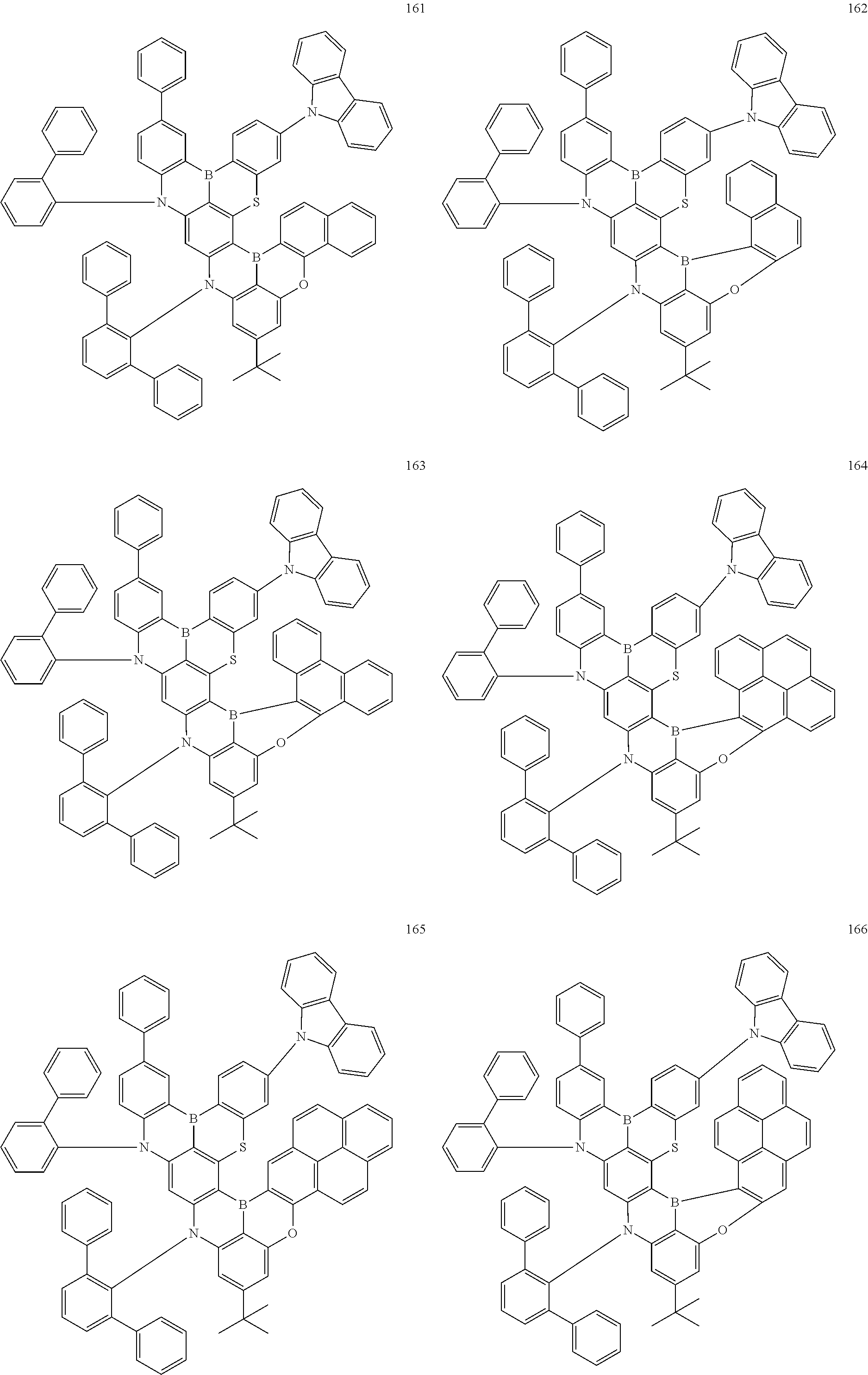

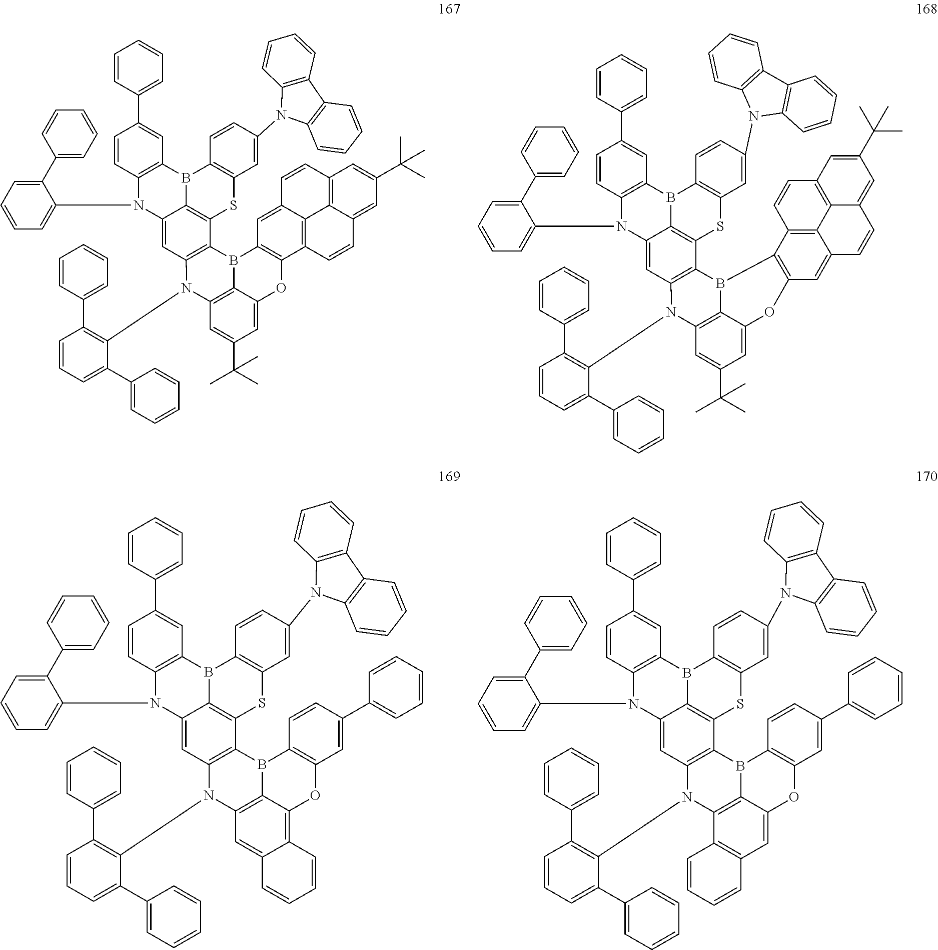

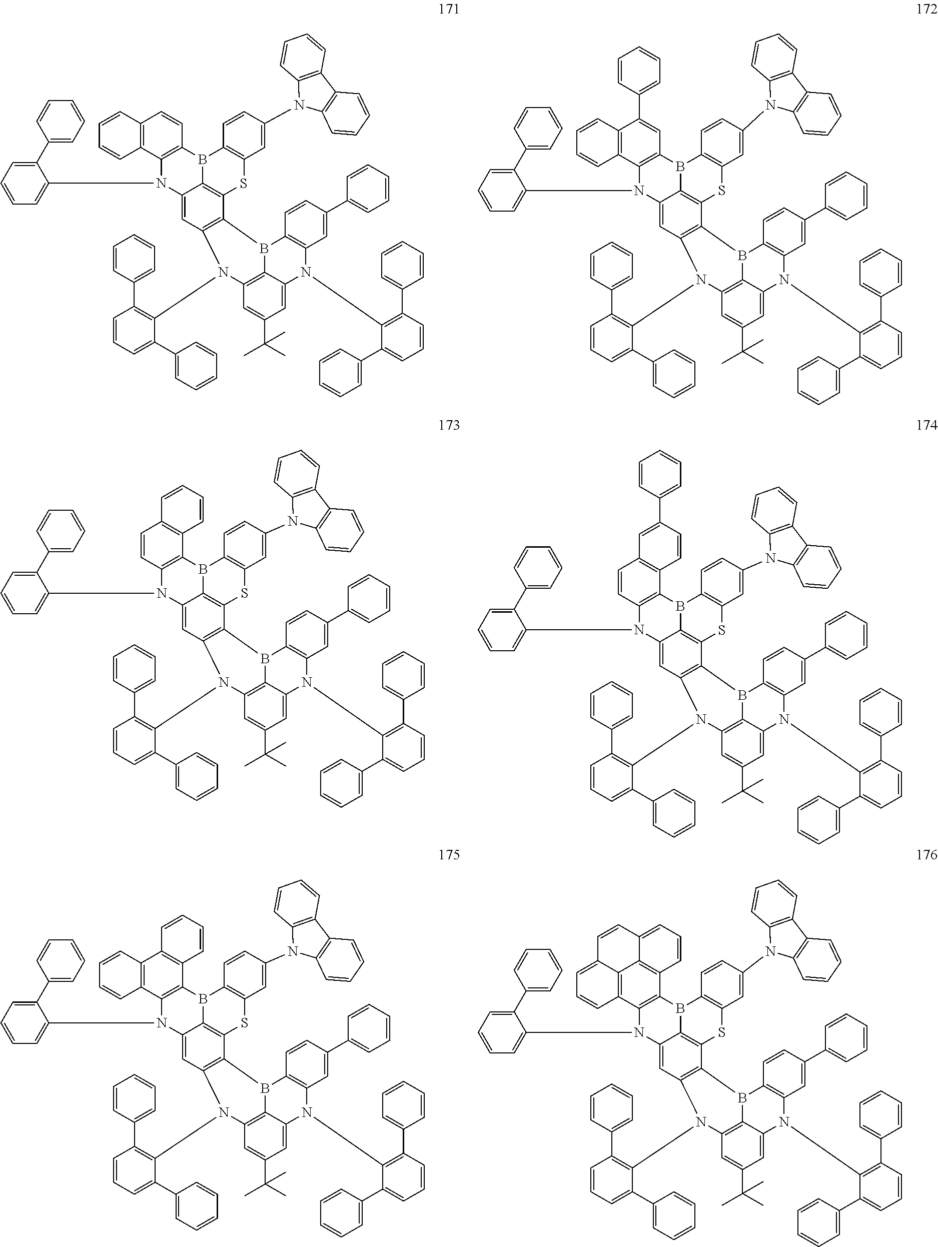

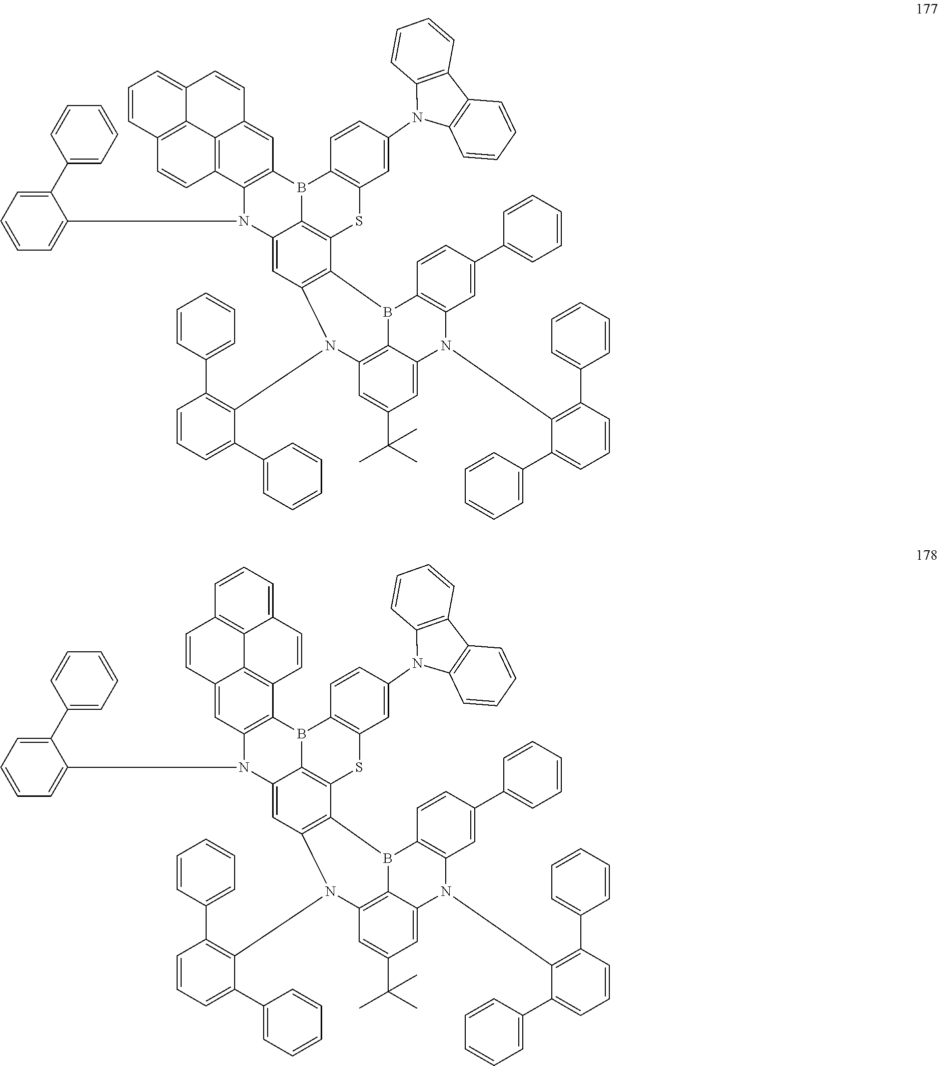 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1cc(-n2c3ccccc3c3ccccc32)ccc1B5c1cc2ccc3cccc5ccc(c1N4c1ccccc1-c1ccccc1)c2c35 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1cc(-n2c3ccccc3c3ccccc32)ccc1B5c1c(cc2ccc3cccc5ccc1c2c35)N4c1ccccc1-c1ccccc1]

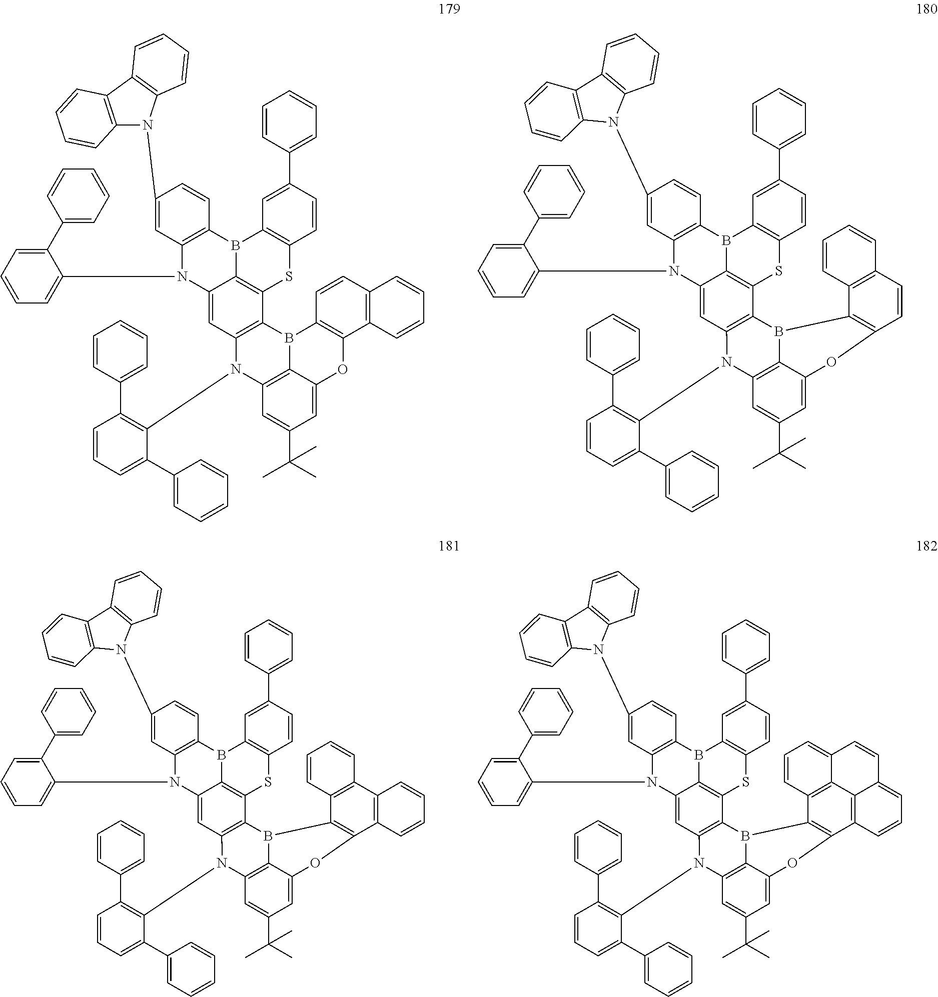

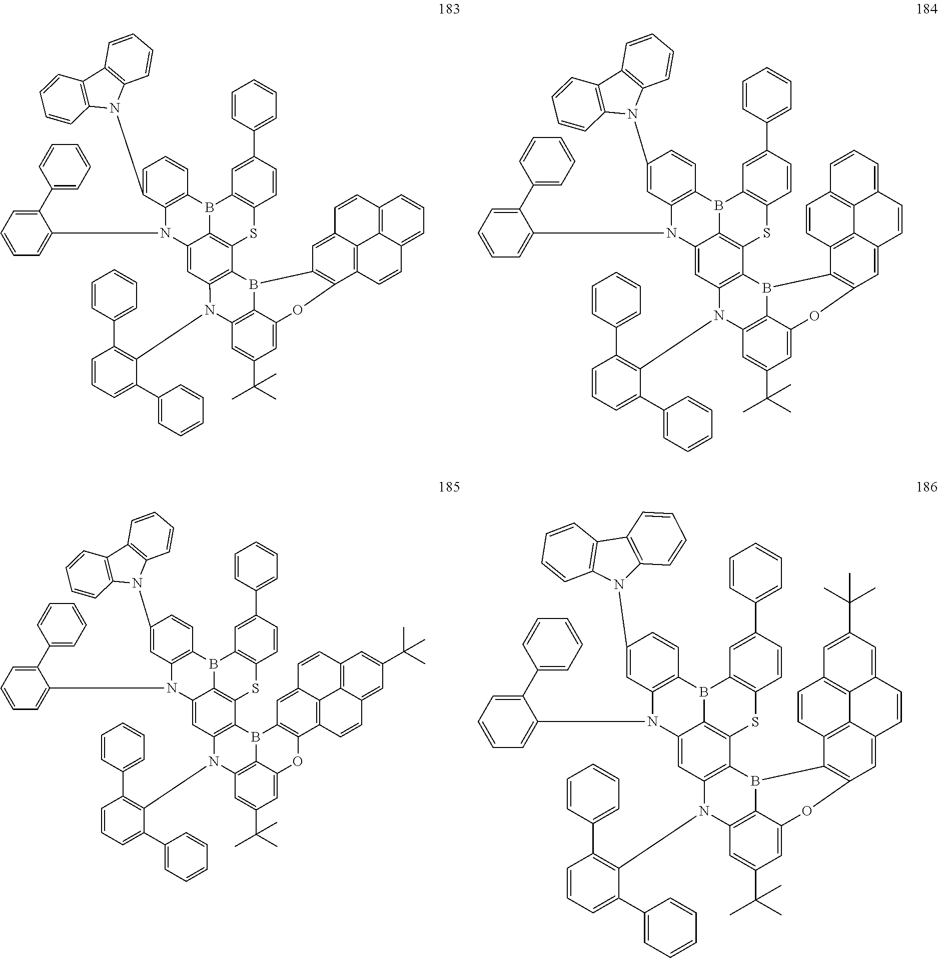

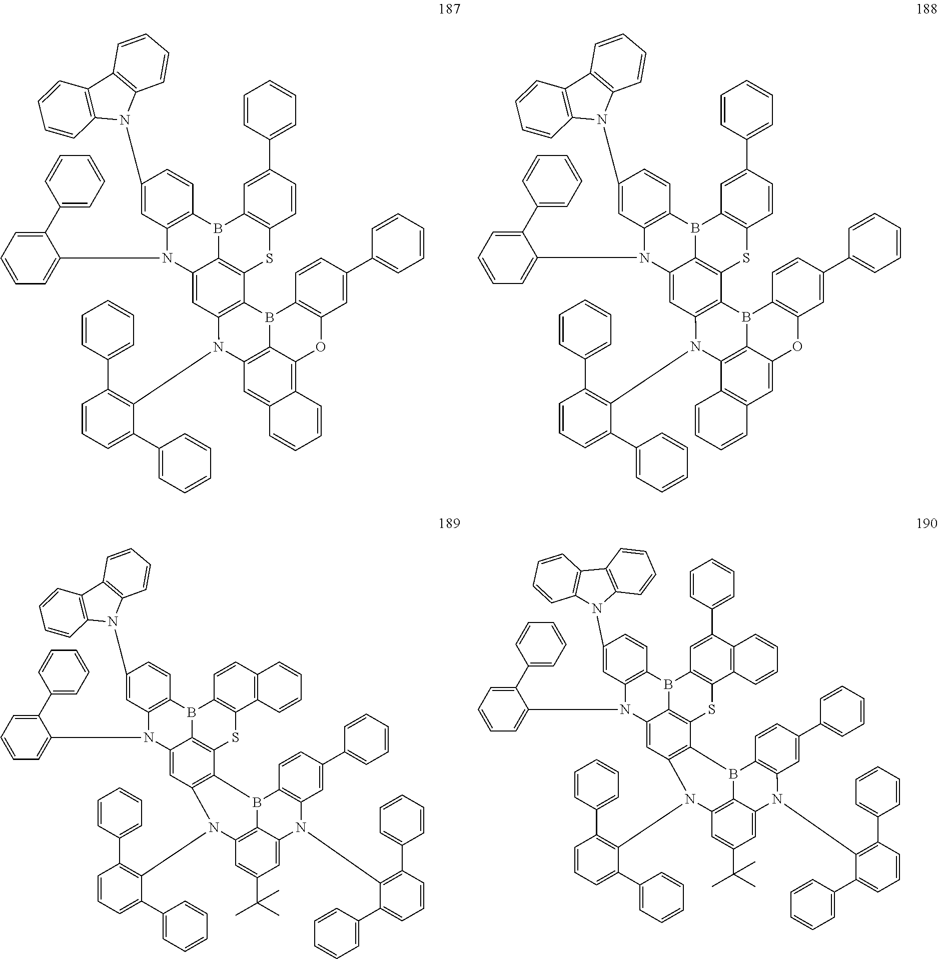

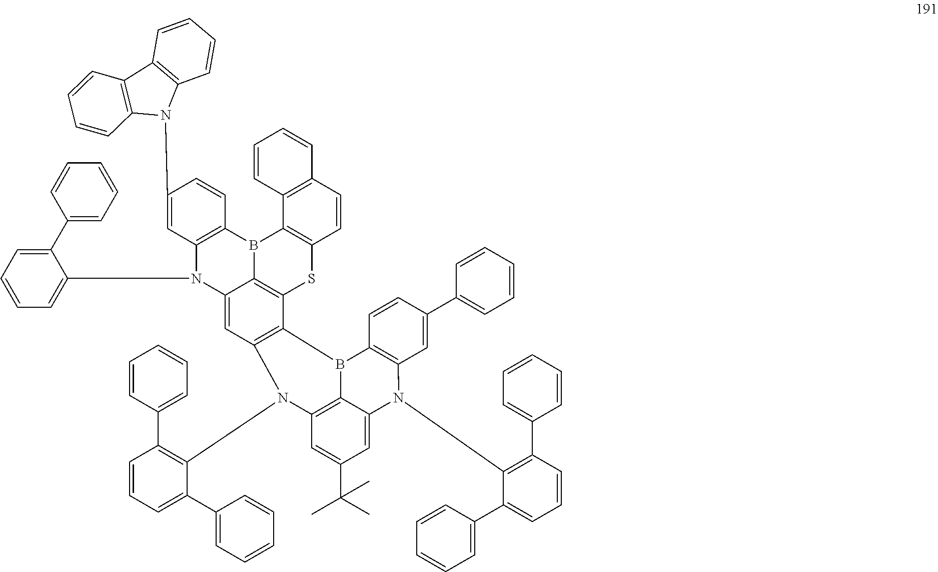 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc2ccccc2c1B5c1ccc(-n2c3ccccc3c3ccccc32)cc1N4c1ccccc1-c1ccccc1]

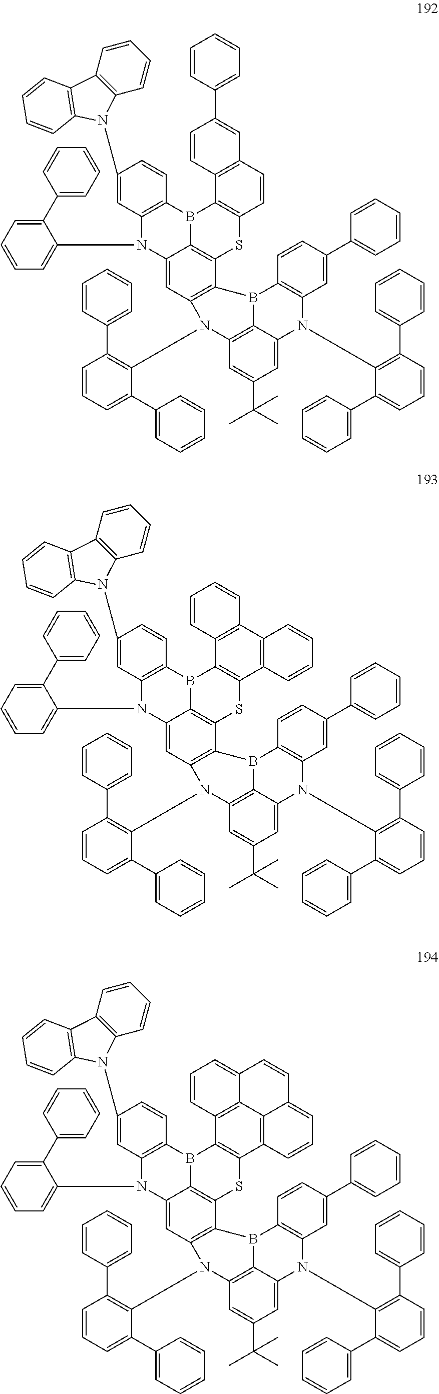

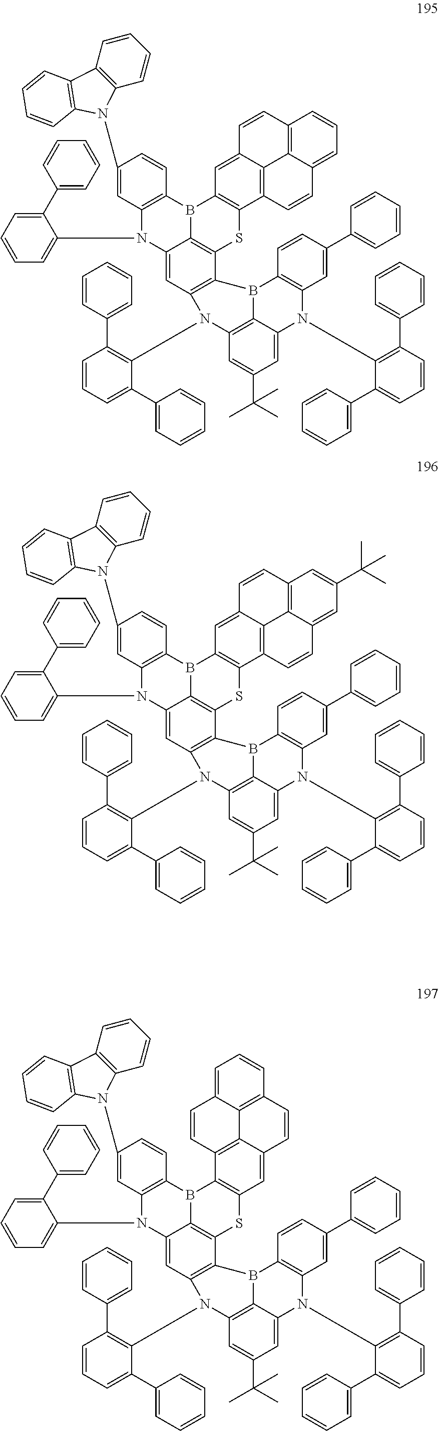

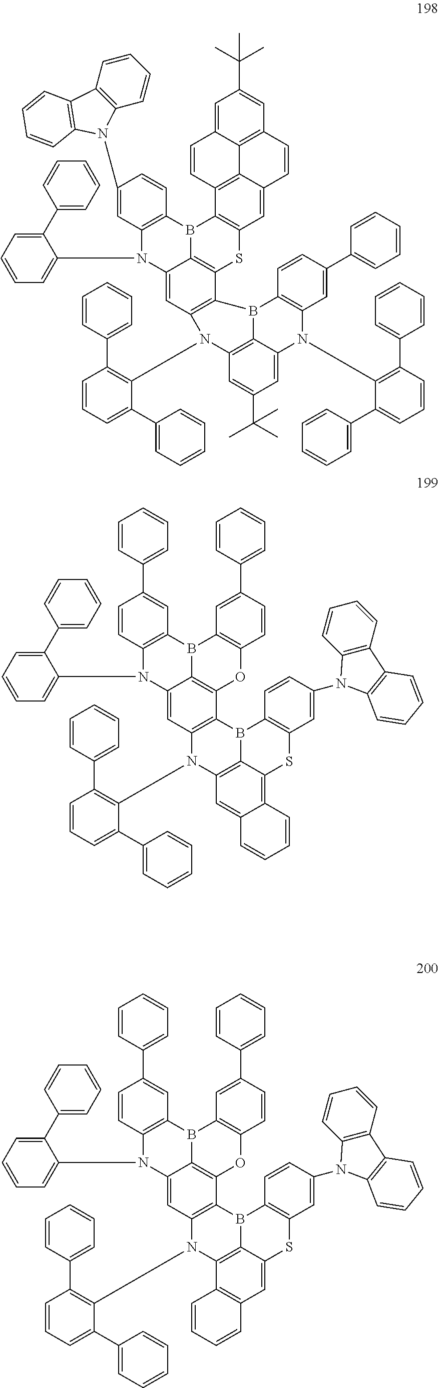

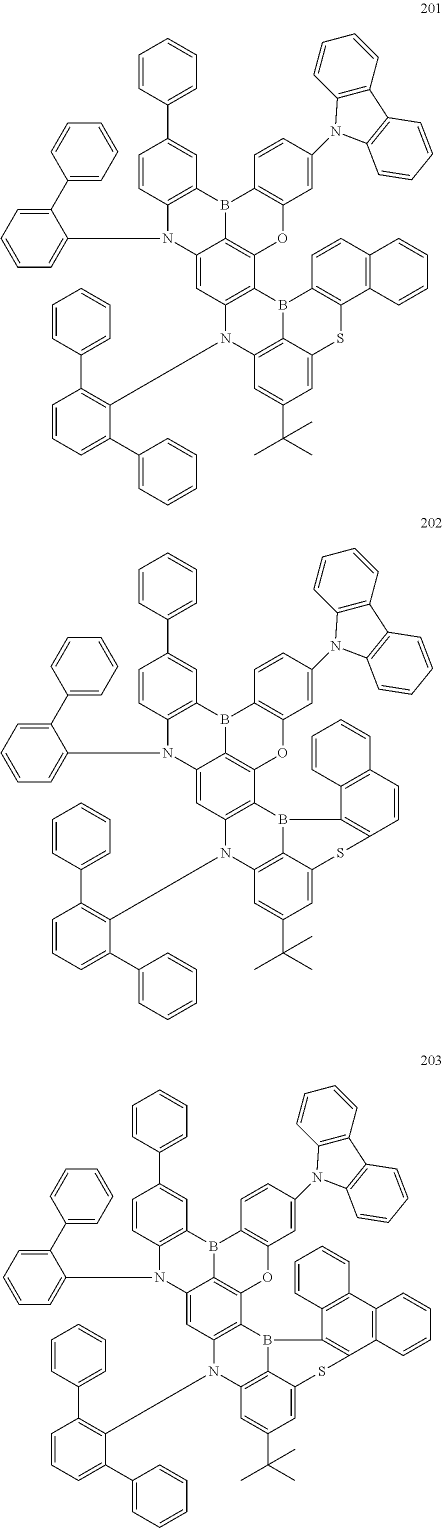 [SMILES: CC(C)(C)c1cc2c3c(c1)N(CCCc1c(-c4ccccc4)cccc1-c1ccccc1)c1cc4c5c(c1B3c1ccc3ccccc3c1S2)Oc1cc(-n2c3ccccc3c3ccccc32)ccc1B5c1cc(-c2ccccc2)ccc1N4CCc1ccccc1-c1ccccc1 ; CC(C)(C)c1cc2c3c(c1)N(CCCc1c(-c4ccccc4)cccc1-c1ccccc1)c1cc4c5c(c1B3c1c(ccc3ccccc13)S2)Oc1cc(-n2c3ccccc3c3ccccc32)ccc1B5c1cc(-c2ccccc2)ccc1N4CCc1ccccc1-c1ccccc1 ; CC(C)(C)c1cc2c3c(c1)N(CCCc1c(-c4ccccc4)cccc1-c1ccccc1)c1cc4c5c(c1B3c1c(c3ccccc3c3ccccc13)S2)Oc1cc(-n2c3ccccc3c3ccccc32)ccc1B5c1cc(-c2ccccc2)ccc1N4CCc1ccccc1-c1ccccc1]

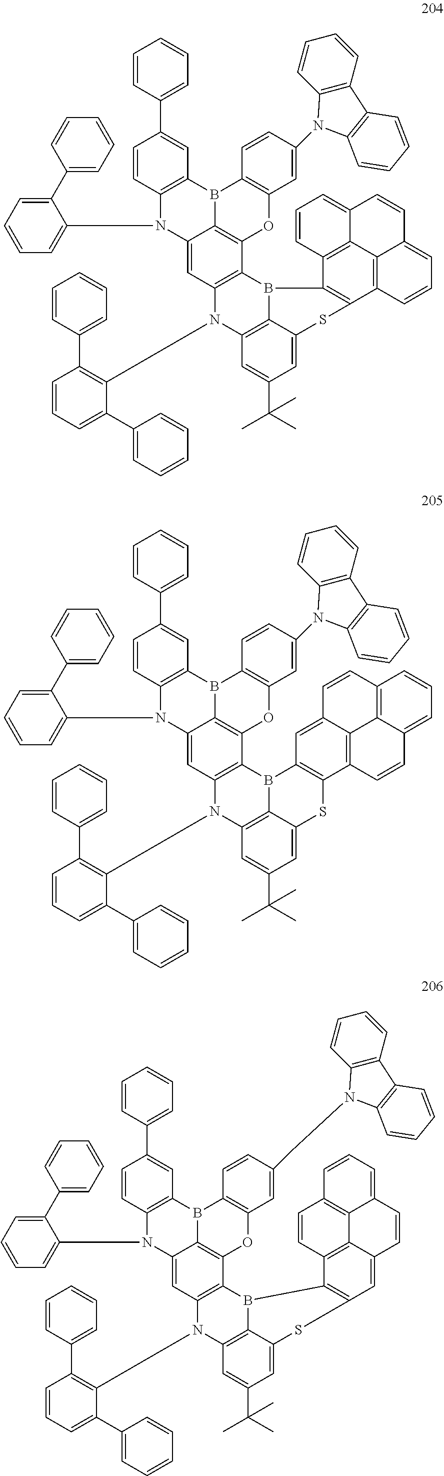

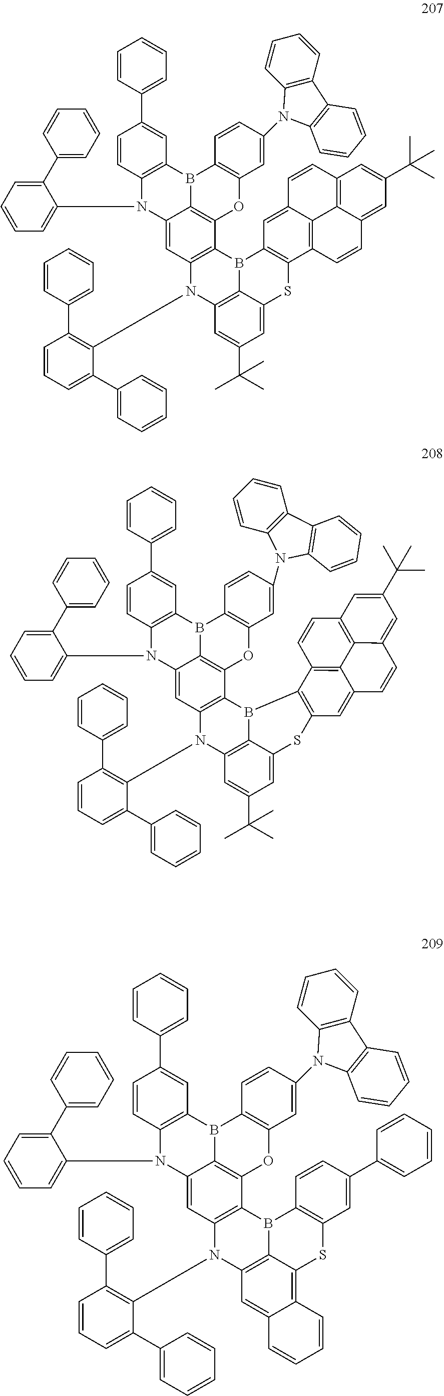

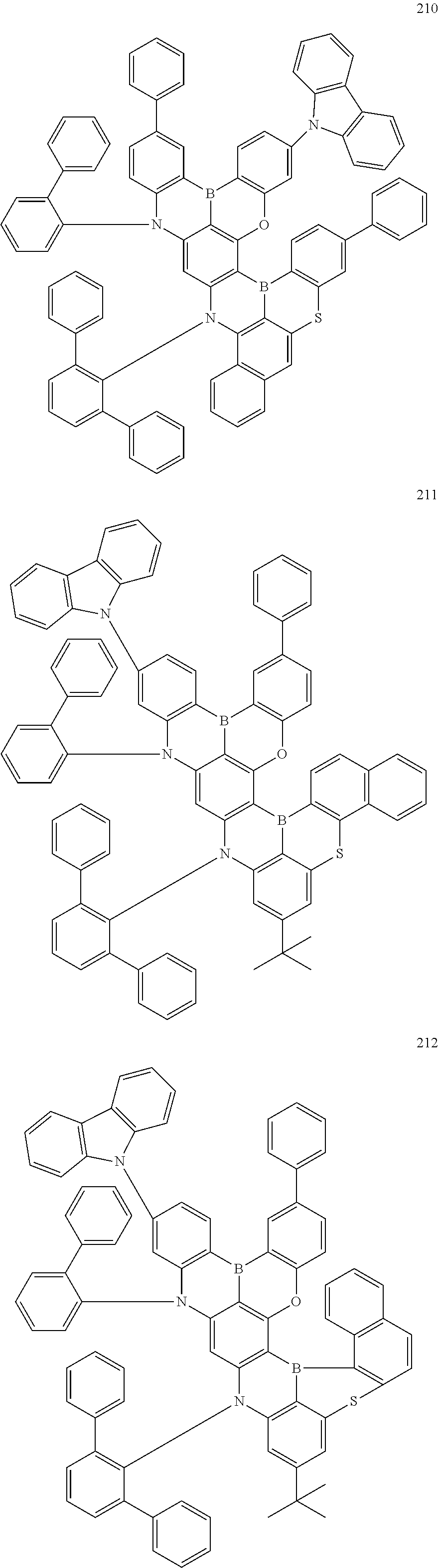 [SMILES: c1ccc(-c2ccc3c(c2)Sc2cc4ccccc4c4c2B3c2c(cc3c5c2Oc2cc(-n6c7ccccc7c7ccccc76)ccc2B5c2cc(-c5ccccc5)ccc2N3CCc2ccccc2-c2ccccc2)N4CCCc2c(-c3ccccc3)cccc2-c2ccccc2)cc1 ; CC(C)(C)c1cc2c3c(c1)N(CCCc1c(-c4ccccc4)cccc1-c1ccccc1)c1cc4c5c(c1B3c1ccc3ccccc3c1S2)Oc1ccc(-c2ccccc2)cc1B5c1ccc(Cn2c3ccccc3c3ccccc32)cc1N4CCc1ccccc1-c1ccccc1 ; CC(C)(C)c1cc2c3c(c1)N(CCCc1c(-c4ccccc4)cccc1-c1ccccc1)c1cc4c5c(c1B3c1c(ccc3ccccc13)S2)Oc1ccc(-c2ccccc2)cc1B5c1ccc(Cn2c3ccccc3c3ccccc32)cc1N4CCc1ccccc1-c1ccccc1]

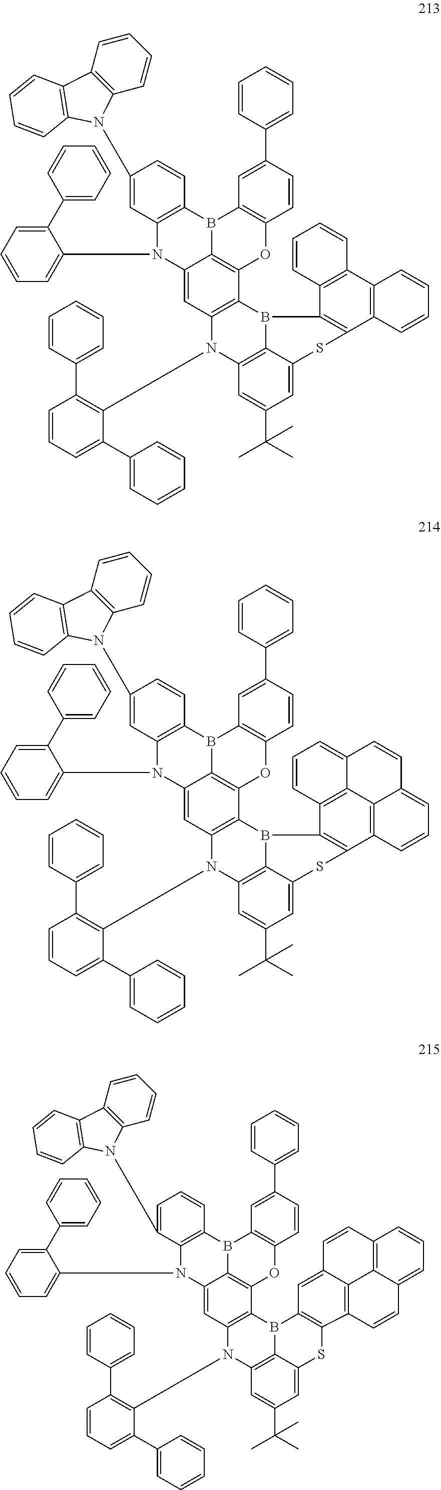

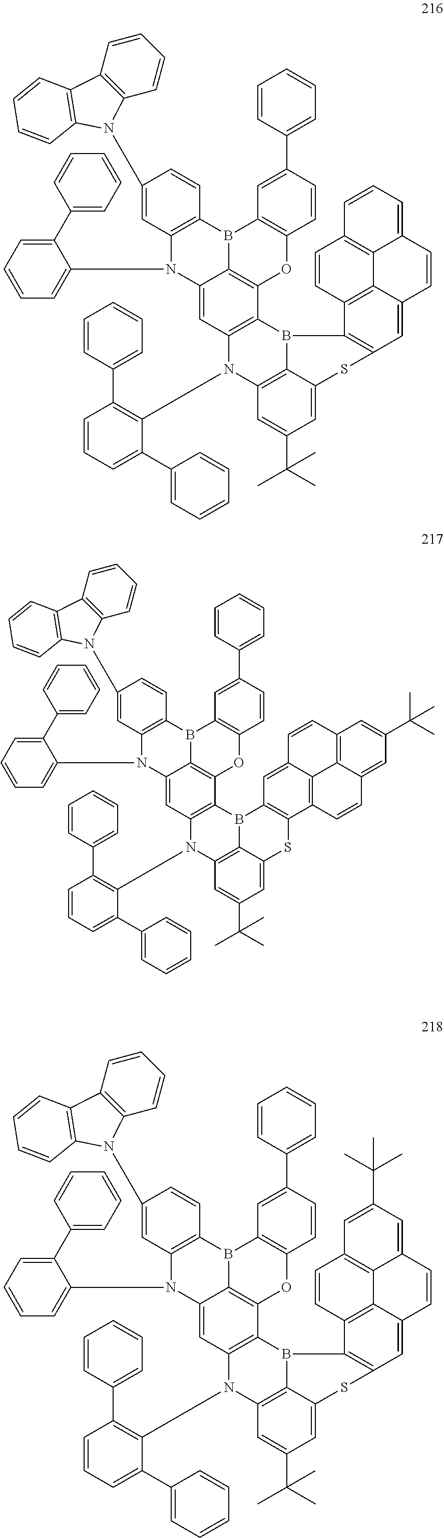

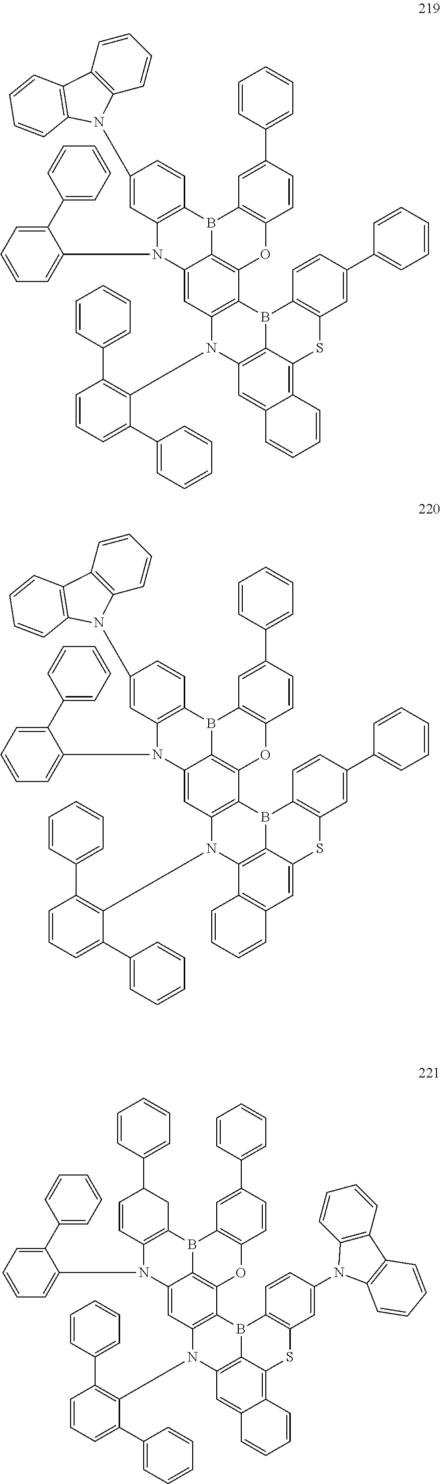 [SMILES: c1ccc(-c2ccc3c(c2)Sc2c4c(cc5ccccc25)N(CCc2c(-c5ccccc5)cccc2-c2ccccc2)c2cc5c6c(c2B34)Oc2ccc(-c3ccccc3)cc2B6c2ccc(Cn3c4ccccc4c4ccccc43)cc2N5CCc2ccccc2-c2ccccc2)cc1 ; c1ccc(-c2ccc3c(c2)Sc2cc4ccccc4c4c2B3c2c(cc3c5c2Oc2ccc(-c6ccccc6)cc2B5c2ccc(Cn5c6ccccc6c6ccccc65)cc2N3CCc2ccccc2-c2ccccc2)N4CCCc2c(-c3ccccc3)cccc2-c2ccccc2)cc1 ; C1=CC(c2ccccc2)CC2=C1N(CCc1ccccc1-c1ccccc1)c1cc3c(c4c1B2c1cc(-c2ccccc2)ccc1O4)B1c2ccc(-n4c5ccccc5c5ccccc54)cc2Sc2c1c(cc1ccccc21)N3CCc1c(-c2ccccc2)cccc1-c1ccccc1]

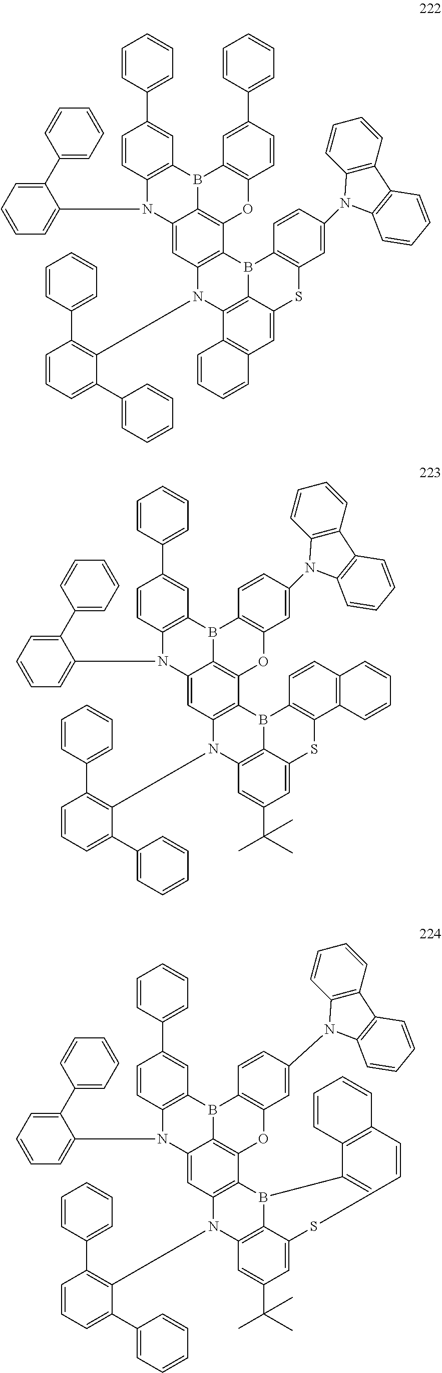 [SMILES: c1ccc(-c2ccc3c(c2)B2c4cc(-c5ccccc5)ccc4N(CCc4ccccc4-c4ccccc4)c4cc5c(c(c42)O3)B2c3ccc(-n4c6ccccc6c6ccccc64)cc3Sc3cc4ccccc4c(c32)N5CCCc2c(-c3ccccc3)cccc2-c2ccccc2)cc1 ; CC(C)(C)c1cc2c3c(c1)N(CCCc1c(-c4ccccc4)cccc1-c1ccccc1)c1cc4c5c(c1B3c1ccc3ccccc3c1S2)Oc1cc(-n2c3ccccc3c3ccccc32)ccc1B5c1cc(-c2ccccc2)ccc1N4CCc1ccccc1-c1ccccc1 ; CCSc1cc(C(C)(C)C)cc2c1B(c1cccc3ccccc13)c1c(cc3c4c1Oc1cc(-n5c6ccccc6c6ccccc65)ccc1B4c1cc(-c4ccccc4)ccc1N3CCc1ccccc1-c1ccccc1)N2CCCc1c(-c2ccccc2)cccc1-c1ccccc1]

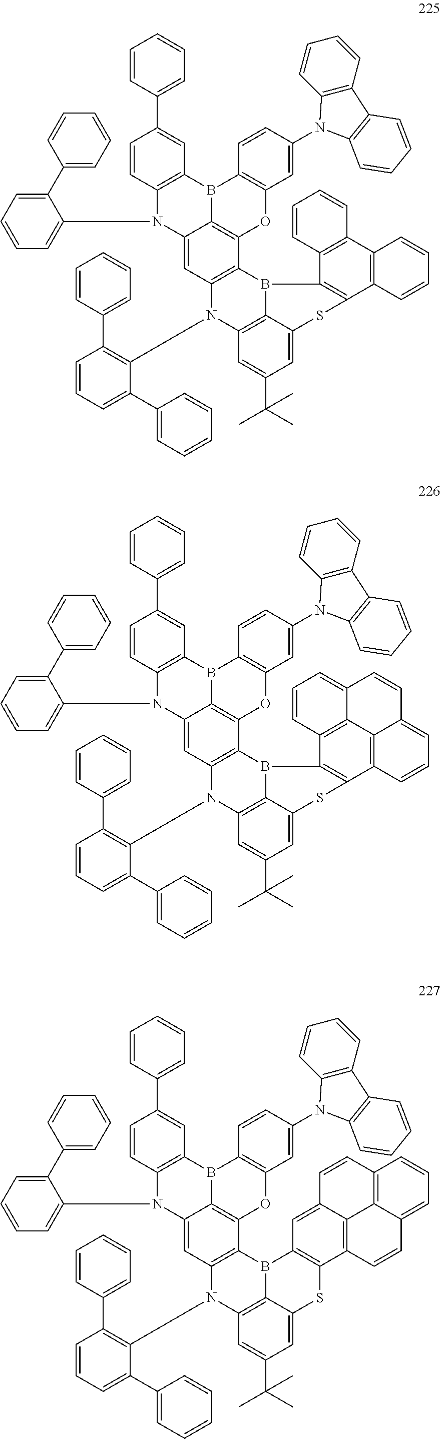

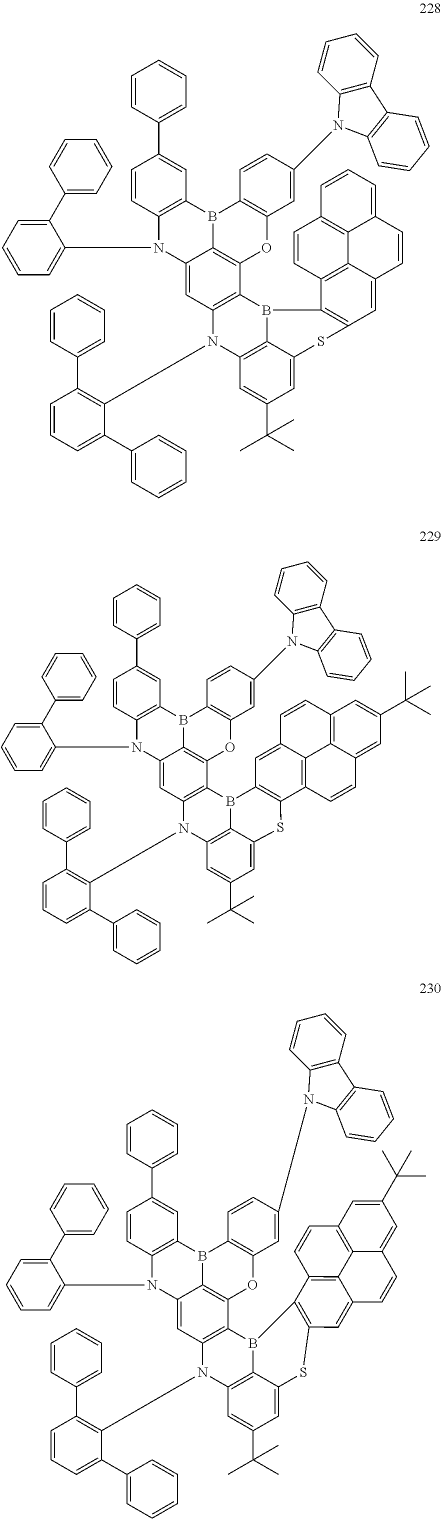

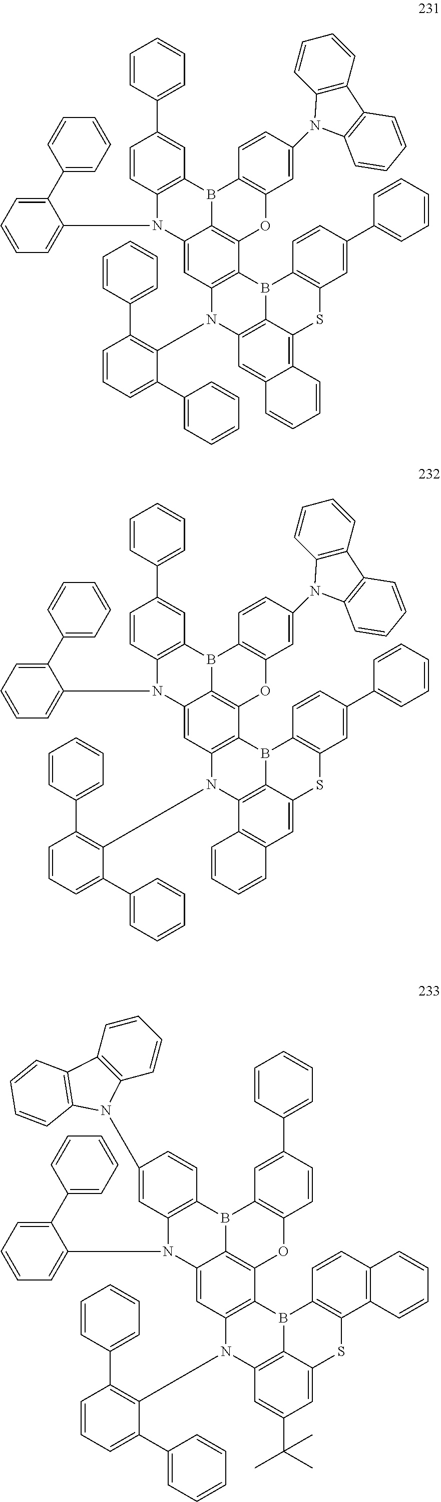 [SMILES: c1ccc(-c2ccc3c(c2)Sc2c4c(cc5ccccc25)N(Cc2c(-c5ccccc5)cccc2-c2ccccc2)c2cc5c6c(c2B34)Oc2cc(-n3c4ccccc4c4ccccc43)ccc2B6c2cc(-c3ccccc3)ccc2N5CCc2ccccc2-c2ccccc2)cc1 ; c1ccc(-c2ccc3c(c2)Sc2cc4ccccc4c4c2B3c2c(cc3c5c2Oc2cc(-n6c7ccccc7c7ccccc76)ccc2B5c2cc(-c5ccccc5)ccc2N3CCc2ccccc2-c2ccccc2)N4CCCc2c(-c3ccccc3)cccc2-c2ccccc2)cc1 ; CC(C)(C)c1cc2c3c(c1)N(CCc1c(-c4ccccc4)cccc1-c1ccccc1)c1cc4c5c(c1B3c1ccc3ccccc3c1S2)Oc1ccc(-c2ccccc2)cc1B5c1ccc(Cn2c3ccccc3c3ccccc32)cc1N4CCc1ccccc1-c1ccccc1]

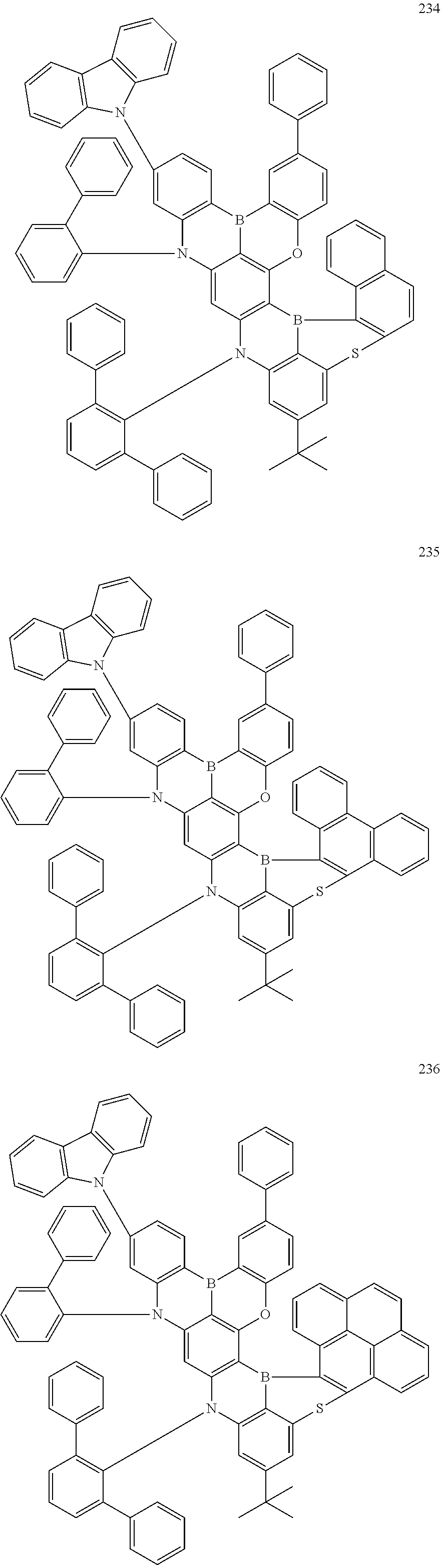 [SMILES: CC(C)(C)c1cc2c3c(c1)N(CCCc1c(-c4ccccc4)cccc1-c1ccccc1)c1cc4c5c(c1B3c1c(ccc3ccccc13)S2)Oc1ccc(-c2ccccc2)cc1B5c1ccc(Cn2c3ccccc3c3ccccc32)cc1N4CCc1ccccc1-c1ccccc1 ; CC(C)(C)c1cc2c3c(c1)N(CCCc1c(-c4ccccc4)cccc1-c1ccccc1)c1cc4c5c(c1B3c1c(c3ccccc3c3ccccc13)S2)Oc1ccc(-c2ccccc2)cc1B5c1ccc(Cn2c3ccccc3c3ccccc32)cc1N4CCc1ccccc1-c1ccccc1 ; CC(C)(C)c1cc2c3c(c1)N(CCCc1c(-c4ccccc4)cccc1-c1ccccc1)c1cc4c5c(c1B3c1c(c3cccc6ccc7cccc1c7c63)S2)Oc1ccc(-c2ccccc2)cc1B5c1ccc(Cn2c3ccccc3c3ccccc32)cc1N4CCc1ccccc1-c1ccccc1]

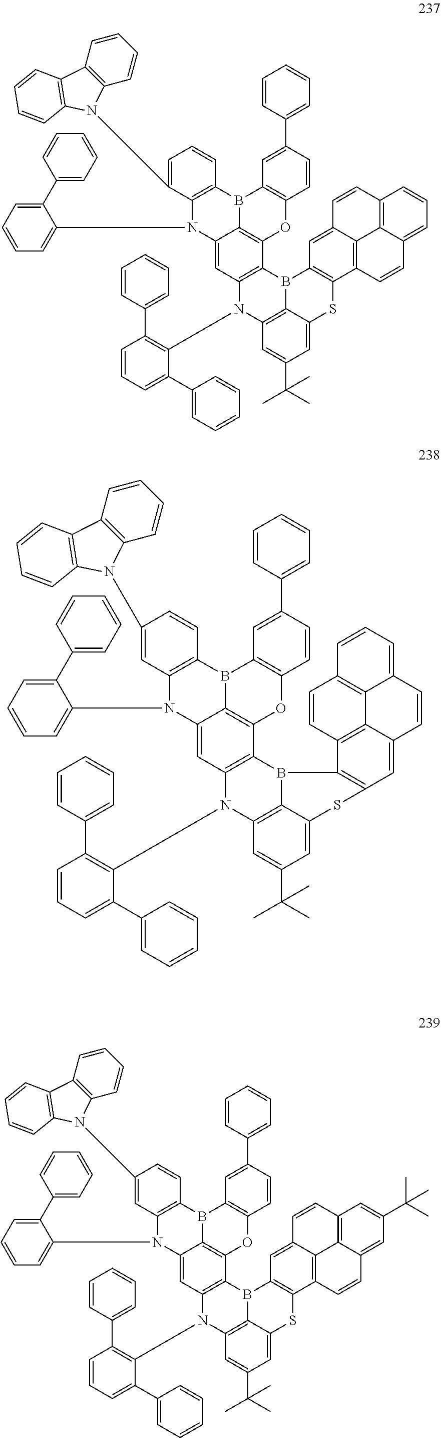

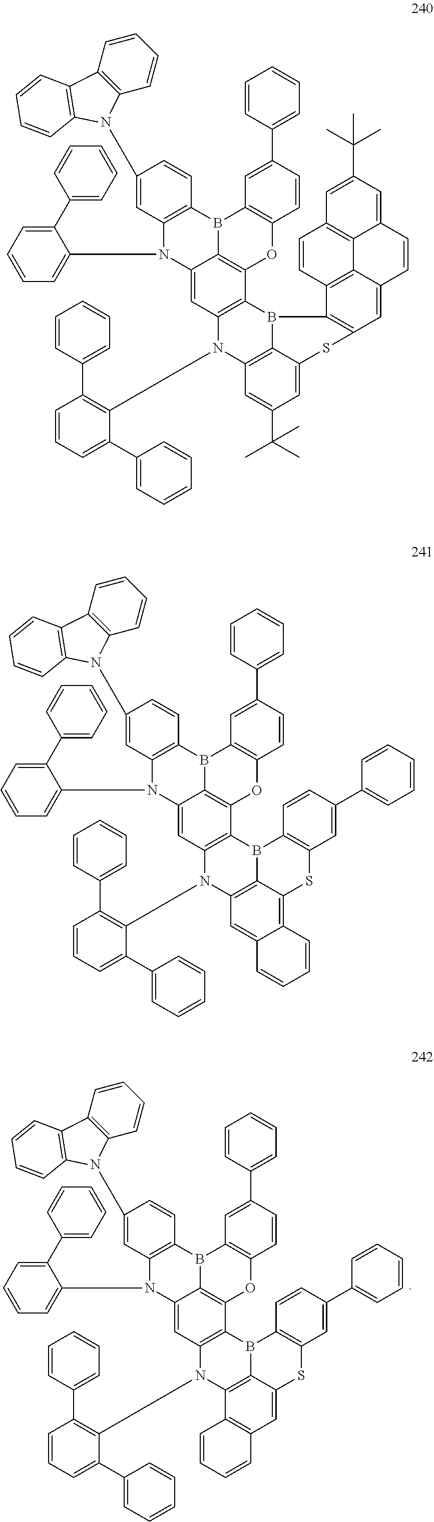

According to one or more embodiments of the present disclosure, a display device includes a base layer, a circuit layer on the base layer, and a display element layer which is arranged on the circuit layer and includes a light emitting element, wherein the light emitting element includes a first electrode, a second electrode on the first electrode, and an emission layer which is between the first electrode and the second electrode and includes a first compound represented by Formula 1.

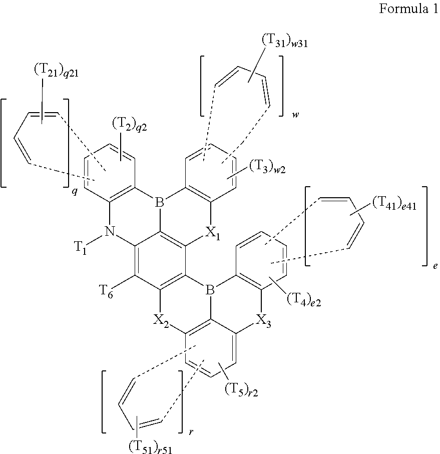

In Formula 1, q, w, and e may each independently be an integer of 0 to 3, r may be an integer of 0 to 2, q21, w31, e41, and r51 may each independently be an integer of 0 to 4, the sum of q, w, e, and r is 1 or more, q2 is an integer of 0 to 4 if (e.g., when) q is 0, q2 is an integer of 0 to 2 if (e.g., when) q is 1, and q2 is 0 if (e.g., when) q is 2 or 3, w2 is an integer of 0 to 4 if (e.g., when) w is 0, w2 is an integer of 0 to 2 if (e.g., when) w is 1, and w2 is 0 if (e.g., when) w is 2 or 3, e2 is an integer of 0 to 4 if (e.g., when) e is 0, e2 is an integer of 0 to 2 if (e.g., when) e is 1, and e2 is 0 if (e.g., when) e is 2 or 3, r2 is an integer of 0 to 3 if (e.g., when) r is 0, and r2 is 0 or 1 if (e.g., when) r is 1, and r2 is 0 if (e.g., when) r is 2, X₁ may be O or S, X₂ may be O, S, or NT₂₀, and X₃ may be O, S, or NT₃₀, T₁ may be a substituted or unsubstituted aryl group having 6 to 30 ring-forming carbon atoms or a substituted or unsubstituted heteroaryl group having 2 to 30 ring-forming carbon atoms, T₂₀, T₃₀, T₂, T₃, T₄, T₅, and T₆ may each independently be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and T₂₁, T₃₁, T₄₁, and T₅₁ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be independently bonded to an adjacent group to form a ring.

In one or more embodiments, the light emitting element may further include a capping layer on the second electrode, and the capping layer may have a refractive index of about 1.6 or more with respect to light in a wavelength range of about 550 nanometers (nm) to about 660 nm.

In one or more embodiments, the display device may further include a light control layer which is on the display element layer and includes a quantum dot, wherein the light emitting element may be to emit first color light, and the light control layer may include a first light control part including a first quantum dot configured to convert the first color light into second color light in a longer wavelength region than the first color light, a second light control part including a second quantum dot configured to convert the first color light into third color light in a longer wavelength region than each of the first color light and the second color light, and a third light control part configured to transmit the first color light.

In one or more embodiments, the display device may further include a color filter layer on the light control part, wherein the color filter layer may include a first filter configured to transmit the second color light, a second filter configured to transmit the third color light, and a third filter configured to transmit the first color light.

According to one or more embodiments of the present disclosure, provided is a fused polycyclic compound represented by Formula 1:

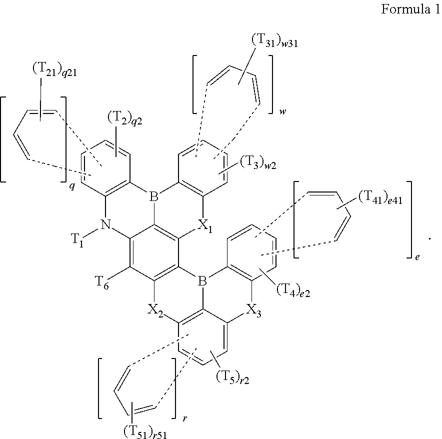

In Formula 1, q, w, and e may each independently be an integer of 0 to 3, r may an integer of 0 to 2, q21, w31, e41, and r51 may each independently be an integer of 0 to 4, the sum of q, w, e, and r is 1 or more, q2 is an integer of 0 to 4 if (e.g., when) q is 0, q2 is an integer of 0 to 2 if (e.g., when) q is 1, and q2 is 0 if (e.g., when) q is 2 or 3, w2 is an integer of 0 to 4 if (e.g., when) w is 0, w2 is an integer of 0 to 2 if (e.g., when) w is 1, and w2 is 0 if (e.g., when) w is 2 or 3, e2 is an integer of 0 to 4 if (e.g., when) e is 0, e2 is an integer of 0 to 2 if (e.g., when) e is 1, and e2 is 0 if (e.g., when) e is 2 or 3, r2 is an integer of 0 to 3 if (e.g., when) r is 0, and r2 is 0 or 1 if (e.g., when) r is 1, and r2 is 0 if (e.g., when) r is 2, X₁ may be O or S, X₂ may be O, S, or NT₂₀, and X₃ may be O, S, or NT₃₀, T₁ may be a substituted or unsubstituted aryl group having 6 to 30 ring-forming carbon atoms or a substituted or unsubstituted heteroaryl group having 2 to 30 ring-forming carbon atoms, T₂₀, T₃₀, T₂, T₃, T₄, T₅, and T₆ may each independently be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and T₂₁, T₃₁, T₄₁, and T₅₁ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be independently bonded to an adjacent group to form a ring.

In one or more embodiments, the fused polycyclic compound represented by Formula 1 may be represented by Formula 1-1:

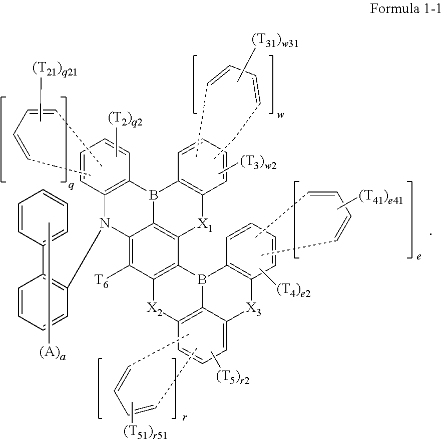

In Formula 1-1, A may be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, a may be an integer of 0 to 9, and q, w, e, r, q21, w31, e41, r51, q2, w2, e2, r2, X₁, X₂, X₃, T₂₀, T₃₀, T₂, T₃, T₄, T₅, T₆, T₂₁, T₃₁, T₄₁, and T₅₁ may each independently be the same as defined in Formula 1.

In one or more embodiments, the fused polycyclic compound represented by Formula 1 may be represented by Formula 2-1 or Formula 2-2:

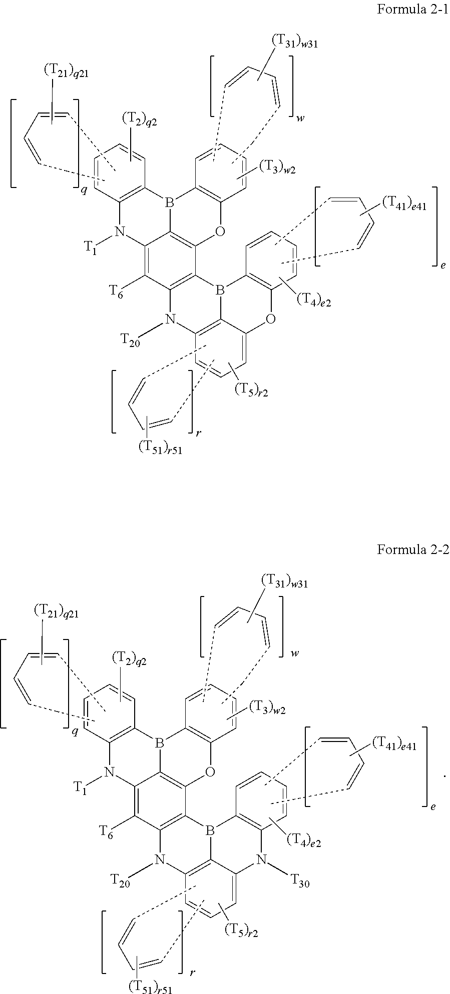

In Formula 2-1 and Formula 2-2, q, w, e, r, q21, w31, e41, r51, q2, w2, e2, r2, T₁, T₂₀, T₃₀, T₂, T₃, T₄, T₅, T₆, T₂₁, T₃₁, T₄₁, and T₅₁ may each independently be the same as defined in Formula 1.

In one or more embodiments, the fused polycyclic compound represented by Formula 1 may be represented by any one selected from among Formula 3-1 to Formula 3-7:

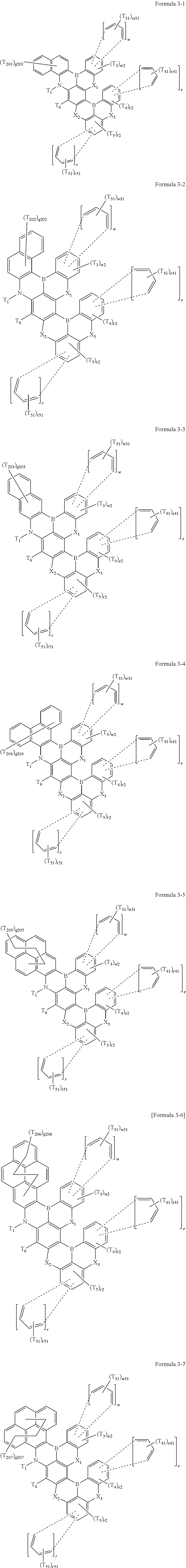

In Formula 3-1 to Formula 3-7, T₂₀₁, T₂₀₂, T₂₀₃, T₂₀₄, T₂₀₅, T₂₀₆, and T₂₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be independently bonded to an adjacent group to form a ring, q201, q202, and q203 may each independently be an integer of 0 to 6, q204, q205, q206, and q207 may each independently be an integer of 0 to 8, and w, e, r, w31, e41, r51, w2, e2, r2, X₁, X₂, X₃, T₁, T₂₀, T₃₀, T₃, T₄, T₅, T₆, T₃₁, T₄₁, and T₅₁ may each independently be the same as defined in Formula 1.

### BRIEF DESCRIPTION OF DRAWINGS

The accompanying drawings are included to provide a further understanding of the present disclosure, and are incorporated in and constitute a part of this disclosure. The drawings illustrate example embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically illustrating a light emitting element according to one or more embodiments of the present disclosure;

FIG. 4 is a cross-sectional view schematically illustrating a light emitting element according to one or more embodiments of the present disclosure;

FIG. 5 is a cross-sectional view schematically illustrating a light emitting element according to one or more embodiments of the present disclosure;

FIG. 6 is a cross-sectional view schematically illustrating a light emitting element according to one or more embodiments of the present disclosure;

FIG. 7 and FIG. 8 are each a cross-sectional view of a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure; and

FIG. 11 is a view illustrating a vehicle in which display devices are arranged according to one or more embodiments of the present disclosure.

### DETAILED DESCRIPTION

The disclosure may be modified in one or more suitable manners and have many forms, and thus specific/example embodiments will be exemplified in the drawings and described in more detail in the detailed description of present disclosure. It should be understood, however, that it is not intended to limit the disclosure to the particular forms disclosed, but rather, is intended to cover all modifications, equivalents, and alternatives falling within the spirit and scope of the disclosure.

When explaining each of drawings, like reference numbers are used for referring to like elements. In the accompanying drawings, the dimensions of each structure may be exaggeratingly illustrated for clarity of the present disclosure. It will be understood that, although the terms “first,” “second,” and/or the like, may be used herein to describe one or more suitable components, these components should not be limited by these terms. These terms are only used to distinguish one component from another. For example, a first component could be termed a second component, and, similarly, a second component could be termed a first component, without departing from the scope of example embodiments of the disclosure. As used herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

In the present disclosure, it will be understood that the terms “comprise(s)/comprising,” “include(s)/including,” “have(has)/having” and/or the like specify the presence of features, numbers, steps, operations, component, parts, and/or one or more (e.g., any suitable) combinations thereof disclosed in the disclosure, but do not exclude the possibility of presence or addition of one or more other features, numbers, steps, operations, component, parts, and/or one or more (e.g., any suitable) combinations thereof. As used herein, the terms “and,” “or,” and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, if (e.g., when) a layer, a film, a region, or a plate is referred to as being “on” or “in an upper portion of” another layer, film, region, or plate, it may be not only “directly on” the layer, film, region, or plate, but one or more intervening layers, films, regions, or plates may also be present therebetween. Opposite this, if (e.g., when) a layer, a film, a region, or a plate is referred to as being “below”, “in a lower portion of” another layer, film, region, or plate, it can be not only directly under the layer, film, region, or plate, but one or more intervening layers, films, regions, or plates may also be present therebetween. In addition, it will be understood that if (e.g., when) a part is referred to as being “on” another part, it may be arranged above the other part, or arranged under the other part as well. In contrast, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, the term “substituted or unsubstituted” may refer to substituted or unsubstituted with at least one substituent selected from the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may each be monocyclic or polycyclic. In addition, the rings formed by being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

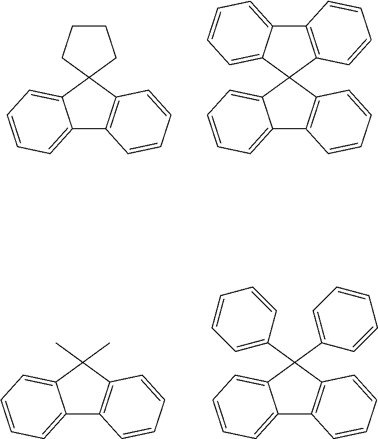

A heterocyclic group as used herein refers to any functional group or substituent derived from a ring containing at least one of B, O, N, P, Si, or Se as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the present disclosure, a heteroaryl group may contain at least one of B, O, N, P, Si, or S as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the present disclosure, the number of carbon atoms in a carbonyl group is not specifically limited, but may be 1 to 40, 1 to 30, or 1 to 20. For example, the carbonyl group may have the following structures, but embodiments of the present disclosure are not limited thereto.

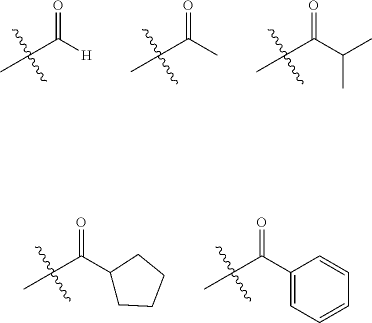

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

A boron group as used herein may refer to that a boron atom is bonded to the alkyl group or the aryl group defined above. The boron group includes an alkyl boron group and/or an aryl boron group. Examples of the boron group may include a dimethylboron group, a diethylboron group, a t-butyldimethylboron group, a diphenylboron group, a phenylboron group, and/or the like, but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto. In the present disclosure, the term “amine group” is used interchangeably with the term “amino group.”

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, and an arylamine group may be the same as the examples of the aryl group described above.

In the present disclosure, a direct linkage may refer to a single bond.

In the disclosure,

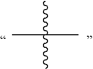

and [symbol] each refer to a position to be connected.

Hereinafter, example embodiments of the present disclosure will be described in more detail with reference to the accompanying drawings. In the present disclosure, the term “display device” may be used interchangeably with “display apparatus,” and the term “light emitting device” may be utilized interchangeably with the term “light emitting element.”

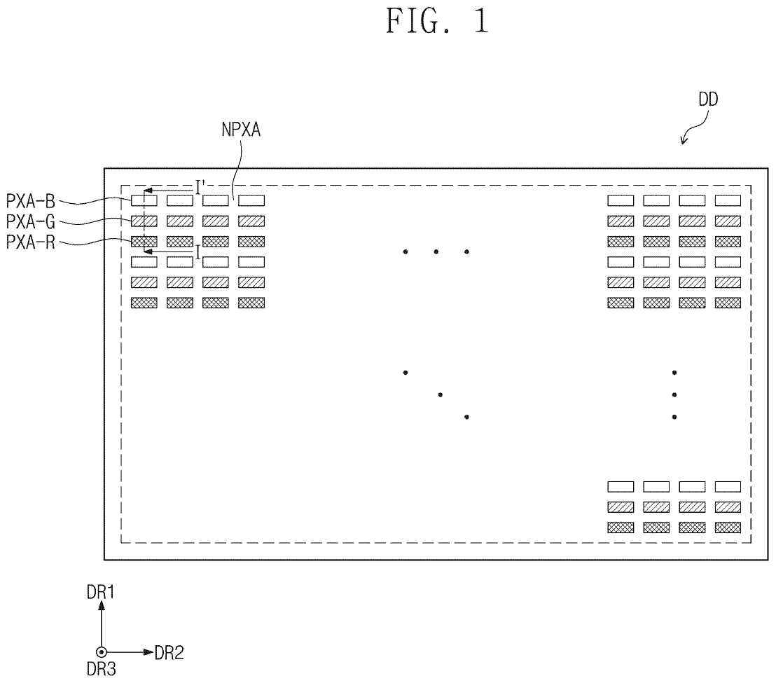

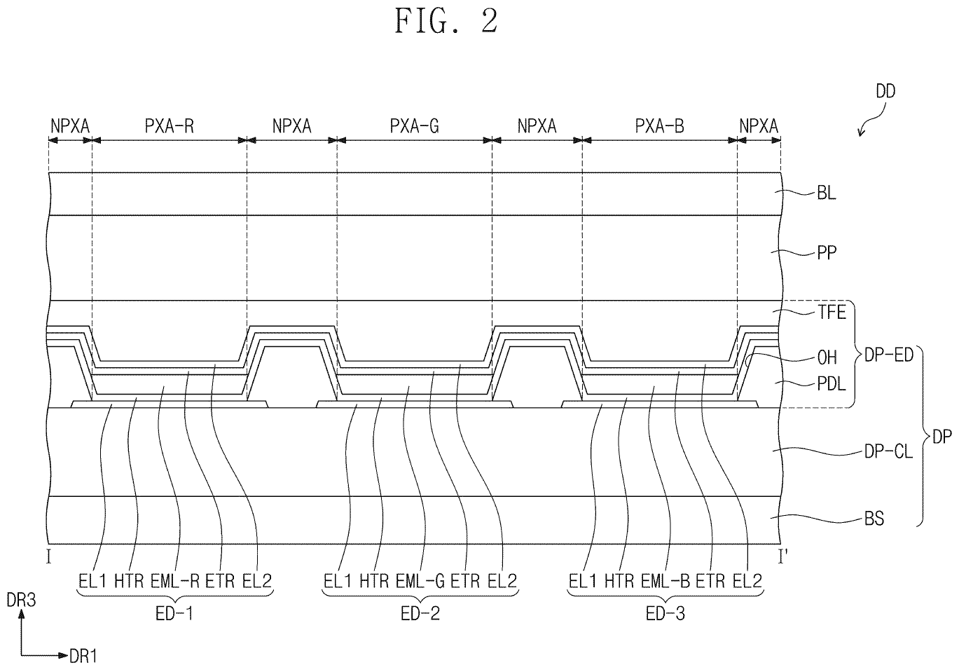

FIG. 1 is a plan view illustrating a display device DD according to one or more embodiments of the present disclosure. FIG. 2 is a cross-sectional view of the display device DD according to one or more embodiments. FIG. 2 is a cross-sectional view illustrating a part taken along the line I-I′ of the display device DD of FIG. 1.

The display device DD may include a display panel DP and an optical layer PP arranged on the display panel DP. The display panel DP may include light emitting devices ED-1, ED-2, and ED-3. The display device DD may include a plurality of light emitting devices ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED (also referred to as display element layer) may include a pixel defining film PDL, the light emitting devices ED-1, ED-2, and ED-3 arranged between respective portions of the pixel defining film PDL, and an encapsulation layer TFE arranged on the light emitting devices ED-1, ED-2, and ED-3.

The base layer BS may be a member which provides a base surface on which the display device layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. Each of the transistors may include a control electrode, an input electrode, and an output electrode. For example, in one or more embodiments, the circuit layer DP-CL may include switching transistor(s) and driving transistor(s) for driving the light emitting devices ED-1, ED-2, and ED-3 of the display device layer DP-ED.

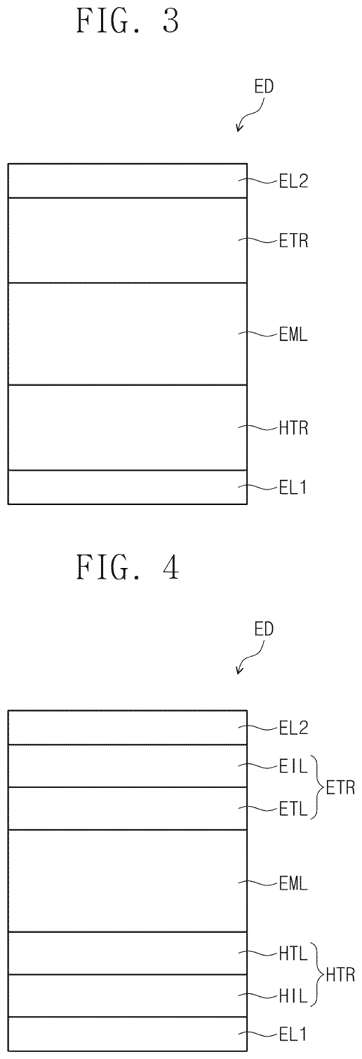

Each of the light emitting devices ED-1, ED-2, and ED-3 may have a structure of one of light emitting elements(devices) ED of embodiments according to FIGS. 3 to 6, which will be described in more detail later. Each of the light emitting devices ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates an embodiment in which the respective emission layers EML-R, EML-G, and EML-B of the light emitting devices ED-1, ED-2, and ED-3 are arranged in openings OH defined in the pixel defining film PDL, and the hole transport region HTR, the electron transport region ETR, and the second electrode EL2 are each provided as a common layer in the entire light emitting devices ED-1, ED-2, and ED-3. However, embodiments of the present disclosure are not limited thereto, for example, in one or more embodiments, the hole transport region HTR and the electron transport region ETR may each be provided by being patterned inside the openings OH defined in the pixel defining film PDL. For example, in one or more embodiments, the hole transport region HTR, the respective emission layers EML-R, EML-G, and EML-B, and the electron transport region ETR of the light emitting devices ED-1, ED-2, and ED-3 may be provided by being patterned in an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. In one or more embodiments, the encapsulation-organic film may include an acrylic-based compound, an epoxy-based compound, and/or the like. In one or more embodiments, the encapsulation-organic film may include a photopolymerizable organic material, but embodiments of the present disclosure are not particularly limited thereto.

The encapsulation layer TFE may be arranged on the second electrode EL2 and may be arranged filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced and/or apart (e.g., spaced apart or separated) from each other on a plane (e.g., in a plan view).

Each of the light emitting regions PXA-R, PXA-G, and PXA-B may be a region divided by the pixel defining film PDL. The non-light emitting area NPXA may be areas between adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting devices ED-1, ED-2, and ED-3. The respective emission layers EML-R, EML-G, and EML-B of the light emitting devices ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display device DD of one or more embodiments illustrated in FIG. 1 and FIG. 2, three light emitting regions PXA-R, PXA-G, and PXA-B, which emit red light, green light, and blue light, respectively, are exemplarily illustrated. For example, the display device DD of one or more embodiments may include a red light emitting region PXA-R, a green light emitting region PXA-G, and a blue light emitting region PXA-B that are separated from each other.

In the display device DD according to one or more embodiments, the plurality of light emitting devices ED-1, ED-2 and ED-3 may be to emit light beams having wavelengths different from each other. For example, in one or more embodiments, the display device DD may include a first light emitting device ED-1 that emits red light, a second light emitting device ED-2 that emits green light, and a third light emitting device ED-3 that emits blue light. For example, in one or more embodiments, the red light emitting region PXA-R, the green light emitting region PXA-G, and the blue light emitting region PXA-B of the display device DD may correspond to the first light emitting device ED-1, the second light emitting device ED-2, and the third light emitting device ED-3, respectively.

However, embodiments of the present disclosure are not limited thereto, and the first to third light emitting devices ED-1, ED-2, and ED-3 may be to emit light beams in substantially the same wavelength range or at least one light emitting device may be to emit a light beam in a wavelength range different from the others. For example, in one or more embodiments, the first to third light emitting devices ED-1, ED-2, and ED-3 may all emit blue light.

The light emitting regions PXA-R, PXA-G, and PXA-B in the display device DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In addition, the red light emitting region PXA-R, the green light emitting region PXA-G, and the blue light emitting region PXA-B may be alternately arranged in this order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. In this regard, the areas of the light emitting regions PXA-R, PXA-G, and PXA-B may refer to areas when viewed on a plane defined by the first direction axis DR1 and the second direction axis DR2 (e.g., the areas in a plan view).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, in one or more embodiments, the arrangement form of the light emitting regions PXA-R, PXA-G, and PXA-B may be a pentile (PENTILE©) arrangement form (for example, an RGBG matrix, an RGBG structure, or an RGBG matrix structure) or a diamond (Diamond Pixel™) arrangement form (e.g., a display (e.g., an OLED display) containing red, blue, and green (RGB) light-emitting regions arranged in the shape of diamonds). PENTILE© is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but embodiments of the present disclosure are not limited thereto.

Hereinafter, FIGS. 3 to 6 are each a cross-sectional view schematically illustrating a light emitting element according to one or more embodiments of the present disclosure. The light emitting elements ED according to one or more embodiments each may include a first electrode EL1, a second electrode EL2 opposite to (e.g., facing) the first electrode EL1, and at least one functional layer arranged between the first electrode EL1 and the second electrode EL2. The light emitting element ED of one or more embodiments may include a fused polycyclic compound of one or more embodiments, which will be described in more detail later, in at least one functional layer.

Each of the light emitting elements ED illustrated in FIGS. 3 to 6 may include, as at least one functional layer, a hole transport region HTR, an emission layer EML, and an electron transport region ETR that are sequentially stacked (e.g., in the stated order). For example, each of the light emitting elements ED of embodiments may include the first electrode EL1, the hole transport region HTR, the emission layer EML, the electron transport region ETR, and the second electrode EL2 that are sequentially stacked (e.g., in the stated order).

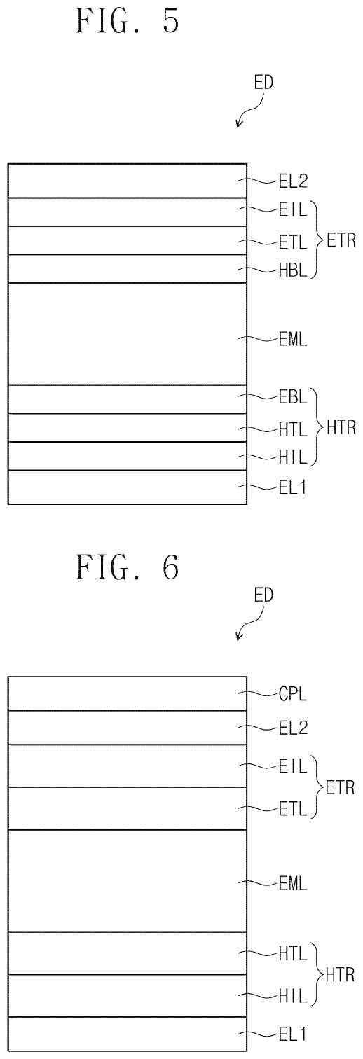

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of one or more embodiments including a capping layer CPL arranged on a second electrode EL2.

The light emitting element ED of one or more embodiments may include a fused polycyclic compound of one or more embodiments, which will be described in more detail later, in at least one functional layer included in the light emitting element ED. The light emitting element ED of one or more embodiments may include the fused polycyclic compound of one or more embodiments in at least one of the hole transport region HTR, the emission layer EML, or the electron transport region ETR. For example, the emission layer EML in the light emitting element ED of one or more embodiments may include the fused polycyclic compound of one or more embodiments.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, in one or more embodiments, the first electrode EL1 may have a three-layer structure of ITO/Ag/ITO, but embodiments of the present disclosure are not limited thereto. In one or more embodiments, the first electrode EL1 may include one of the above-described metal materials, one or more combinations of at least two metal materials of the above-described metal materials, any oxide of the above-described metal materials, and/or the like. A thickness of the first electrode EL1 may be from about 700 ångström (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and/or a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

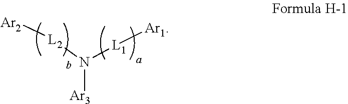

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a and/or b are each an integer of 2 or greater, a plurality of L₁'s and/or a plurality of L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

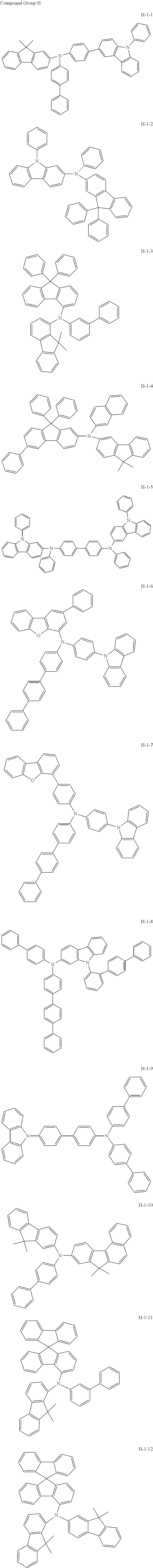

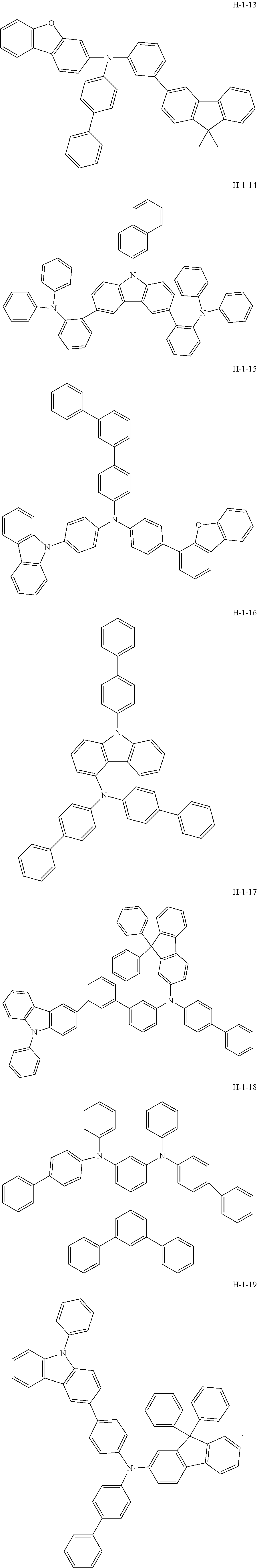

In one or more embodiments, the hole transport region HTR may include one or more selected from among a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In one or more embodiments, the hole transport region HTR may include one or more selected from among a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. If (e.g., when) the hole transport region HTR includes a hole injection layer HIL, the hole injection layer HIL may have, for example, a thickness of about 30 Å to about 1,000 Å. If (e.g., when) the hole transport region HTR includes a hole transport layer HTL, the hole transport layer HTL may have a thickness of about 250 Å to about 1,000 Å. For example, if (e.g., when) the hole transport region HTR includes an electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

In one or more embodiments, the hole transport region HTR may further include a charge generating material to increase conductivity (e.g., electric conductivity) in addition to the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in one or more embodiments, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce electron injection from the electron transport region ETR to the hole transport region HTR.

In one or more embodiments, the emission layer EML may be provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The light emitting element ED of one or more embodiments may include a fused polycyclic compound represented by Formula 1 in at least one functional layer arranged between the first electrode EL1 and the second electrode EL2. The emission layer EML in the light emitting element ED according to one or more embodiments may include a fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In the present disclosure, the fused polycyclic compound of one or more embodiments may be referred to as a first compound.

The fused polycyclic compound of one or more embodiments may include a core including a first fused ring structure and a second fused ring structure. The core may be represented by Formula x below. The first fused ring structure includes a structure in which first to third aromatic rings are fused via a first boron atom, a nitrogen atom, and a first heteroatom. The second fused ring structure includes a structure in which third to fifth aromatic rings are fused via a second boron atom, a second heteroatom, and a third heteroatom. The first fused ring structure and the second fused ring structure are linked and conjugated via a third aromatic ring.

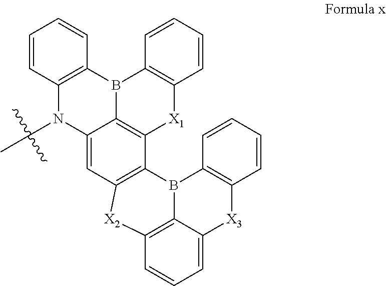

In the first fused ring structure, the first aromatic ring and the third aromatic ring are linked via the first boron atom and the nitrogen atom. The second aromatic ring and the third aromatic ring are linked via the first boron atom and the first heteroatom. The first aromatic ring and the second aromatic ring are linked via the first boron atom. The first boron atom is linked to all of the first to third aromatic rings.

In the second fused ring structure, the third aromatic ring and the fourth aromatic ring are linked via the second boron atom and the second heteroatom. The fourth aromatic ring and the fifth aromatic ring are linked via the second boron atom and the third heteroatom. The third aromatic ring and the fifth aromatic ring are linked via the second boron atom. The second boron atom is linked to all of the third to fifth aromatic rings. The third aromatic ring is concurrently (e.g., simultaneously) bonded to each of the first boron atom, the second boron atom, the nitrogen atom, the first heteroatom, and the second heteroatoms. The third aromatic ring may serve as a linker connecting the first fused ring structure and the second fused ring structure.

The fused polycyclic compound of one or more embodiments may be represented by Formula 1:

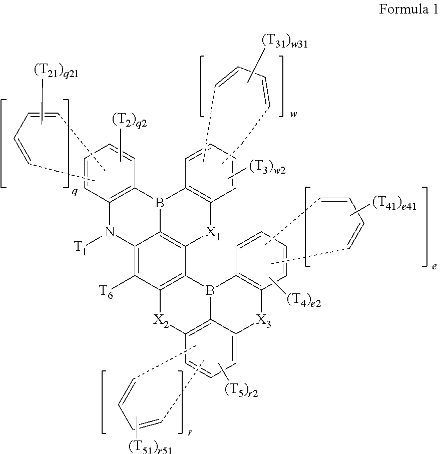

The fused polycyclic compound of one or more embodiments represented by Formula 1 includes the core represented by Formula x. In Formula 1, an aromatic ring substituted with T₂ is the first aromatic ring, an aromatic ring substituted with T₃ is the second aromatic ring, an aromatic ring substituted with T₆ is the third aromatic ring, an aromatic ring substituted with T₅ is the fourth aromatic ring, and an aromatic ring substituted with T₄ is the fifth aromatic ring.

In Formula 1, T₁ may be a substituted or unsubstituted aryl group having 6 to 30 ring-forming carbon atoms or a substituted or unsubstituted heteroaryl group having 2 to 30 ring-forming carbon atoms. In one or more embodiments, T₁ may be a substituted or unsubstituted aryl group having 6 to 30 ring-forming carbon atoms. In one or more embodiments, T₁ may be a substituted or unsubstituted biphenyl group. The fused polycyclic compound of one or more embodiments may be represented by Formula 1-1:

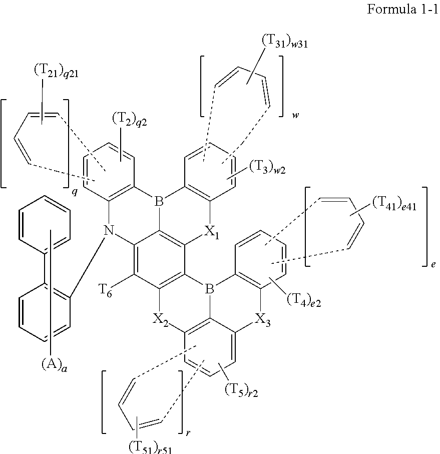

In Formula 1-1, A may be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, A may be hydrogen.

In Formula 1-1, a may be an integer of 0 to 9. In Formula 1-1, if a is 0, the fused polycyclic compound of one or more embodiments may not be substituted with A. The embodiment in which a is 9 and A's are all hydrogens may be the same as the embodiment in which a is 0. If (e.g., when) a is an integer of 2 or greater, a plurality of A's may be all the same or at least one selected from among the plurality of A's may be different from the others.

In Formula 1-1, descriptions of q, w, e, r, q21, w31, e41, r51, q2, w2, e2, r2, X₁, X₂, X₃, T₂₀, T₃₀, T₂, T₃, T₄, T₅, T₆, T₂₁, T₃₁, T₄₁, and T₅₁ may be the same as those described in Formula 1.

In Formula 1, X₁ may be O or S. For example, in one or more embodiments, X₁ may be O. X₂ may be O, S, or NT₂₀. For example, in one or more embodiments, X₂ may be NT₂₀. X₃ may be O, S, or NT₃₀. For example, in one or more embodiments, X₃ may be O. In Formula 1, if (e.g., when) X₁ is O, X₂ is NT₂₀, and X₃ is O, the fused polycyclic compound of one or more embodiments may be represented by Formula 2-1. In Formula 1, if (e.g., when) X₁ is O, X₂ is NT₂₀, and X₃ is NT₃₀, the fused polycyclic compound of one or more embodiments may be represented by Formula 2-2.

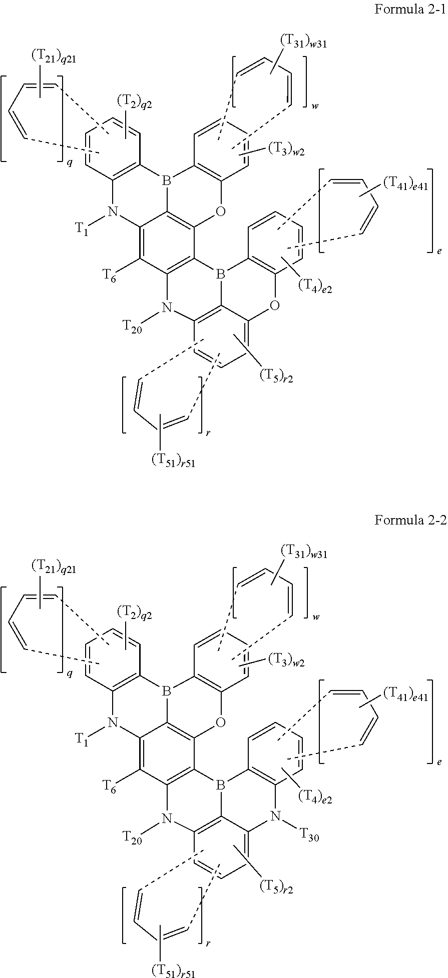

In Formula 2-1 and Formula 2-2, descriptions of q, w, e, r, q21, w31, e41, r51, q2, w2, e2, r2, T₁, T₂₀, T₃₀, T₂, T₃, T₄, T₅, T₆, T₂₁, T₃₁, T₄₁, and T₅₁ may be the same as those described in Formula 1.

In Formula 1, T₂₀, T₃₀, T₂, T₃, T₄, T₅, and T₆ may each independently be hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, each of T₂₀ and T₃₀ may be independently a substituted or unsubstituted terphenyl group. For example, in one or more embodiments, each of T₂₀ and T₃₀ may be independently an unsubstituted m-terphenyl group. In one or more embodiments, T₂, T₃, and T₄ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, T₂, T₃, and T₄ may each independently be an unsubstituted phenyl group or an unsubstituted carbazole group. In one or more embodiments, T₅ may be a substituted or unsubstituted alkyl group having 1 to 20 carbon atoms. For example, in one or more embodiments, T₅ may be a unsubstituted t-butyl group. In one or more embodiments, T₆ may be hydrogen.

In Formula 1, T₂₁, T₃₁, T₄₁, and T₅₁ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be independently bonded to an adjacent group to form a ring. In one or more embodiments, T₂₁, T₃₁, T₄₁, and T₅₁ may each independently be a substituted or unsubstituted alkyl group having 1 to 20 carbon atoms or a substituted or unsubstituted aryl group having 6 to 30 ring-forming carbon atoms. For example, in one or more embodiments, T₂₁, T₃₁, T₄₁, and T₅₁ may each independently be an unsubstituted t-butyl or an unsubstituted phenyl group.

In Formula 1, q21, w31, e41, and r51 may each independently be an integer of 0 to 4. In Formula 1, if (e.g., when) q21 is 0, the fused polycyclic compound of one or more embodiments may not be substituted with T₂₁. The embodiment in which q21 is 4 and T₂₁'s are all hydrogens may be the same as the embodiment in which q21 is 0. If (e.g., when) q21 is an integer of 2 or greater, a plurality of T₂₁'s may all be the same, or at least one selected from among the plurality of T₂₁'s may be different from the others. In Formula 1, if (e.g., when) w31 is 0, the fused polycyclic compound of one or more embodiments may not be substituted with T₃₁. The embodiment in which w31 is 4 and T₃₁'s are all hydrogens may be the same as the embodiment in which w31 is 0. If (e.g., when) w31 is an integer of 2 or greater, a plurality of T₃₁'s may all be the same, or at least one selected from among the plurality of T₃₁'s may be different from the others. In Formula 1, if (e.g., when) e41 is 0, the fused polycyclic compound of one or more embodiments may not be substituted with T₄₁. The embodiment in which e41 is 4 and T₄₁'s are all hydrogens may be the same as the embodiment in which e41 is 0. If (e.g., when) e41 is an integer of 2 or greater, a plurality of T₄₁'s may all be the same, or at least one selected from among the plurality of T₄₁'s may be different from the others. In Formula 1, if (e.g., when) r51 is 0, the fused polycyclic compound of one or more embodiments may not be substituted with T₅₁. The embodiment in which r51 is 4 and T₅₁'s are all hydrogens may be the same as the embodiment in which r51 is 0. If (e.g., when) r51 is an integer of 2 or greater, a plurality of T₅₁'s may all be the same, or at least one selected from among the plurality of T₅₁'s may be different from the others.

In Formula 1, q2 is an integer of 0 to 4 if (e.g., when) q is 0, q2 is an integer of 0 to 2 if (e.g., when) q is 1, and q2 is 0 if (e.g., when) q is 2 or 3. In Formula 1, if (e.g., when) q2 is 0, the fused polycyclic compound of one or more embodiments may not be substituted with T₂. If (e.g., when) q2 is an integer of 2 or greater, a plurality of T₂'s may all be the same, or at least one selected from among the plurality of T₂'s may be different from the others.

In Formula 1, w2 is an integer of 0 to 4 if (e.g., when) w is 0, w2 is an integer of 0 to 2 if (e.g., when) w is 1, and w2 is 0 if (e.g., when) w is 2 or 3. In Formula 1, if (e.g., when) w2 is 0, the fused polycyclic compound of one or more embodiments may not be substituted with T₃. If (e.g., when) w2 is an integer of 2 or greater, a plurality of T₃'s may all be the same, or at least one among the plurality of T₃'s may be different from the others.

In Formula 1, e2 is an integer of 0 to 4 if (e.g., when) e is 0, e2 is an integer of 0 to 2 if (e.g., when) e is 1, and e2 is 0 if (e.g., when) e is 2 or 3. In Formula 1, if (e.g., when) e2 is 0, the fused polycyclic compound of one or more embodiments may not be substituted with T₄. If (e.g., when) e2 is an integer of 2 or greater, a plurality of T₄'s may all be the same, or at least one among the plurality of T₄'s may be different from the others.

In Formula 1, r2 is an integer of 0 to 3 if (e.g., when) r is 0, and r2 is 0 or 1 if (e.g., when) r is 1. In Formula 1, if (e.g., when) r2 is 0, the fused polycyclic compound of one or more embodiments may not be substituted with T₅. If (e.g., when) r2 is an integer of 2 or greater, a plurality of T₅'s may all be the same, or at least one among the plurality of T₅'s may be different from the others.

In Formula 1, q, w, and e may each independently be an integer of 0 to 3. r may be an integer of 0 to 2. The sum of q, w, e, and r is 1 or greater. For example, at least one of q, w, e, or r is not zero. For example, in one or more embodiments, q may be 1 and each of w, e, and r may be 0.

In Formula 1, if (e.g., when) q is 1, the fused polycyclic compound of one or more embodiments may be represented by any one selected from among Formula 3-1 to Formula 3-3:

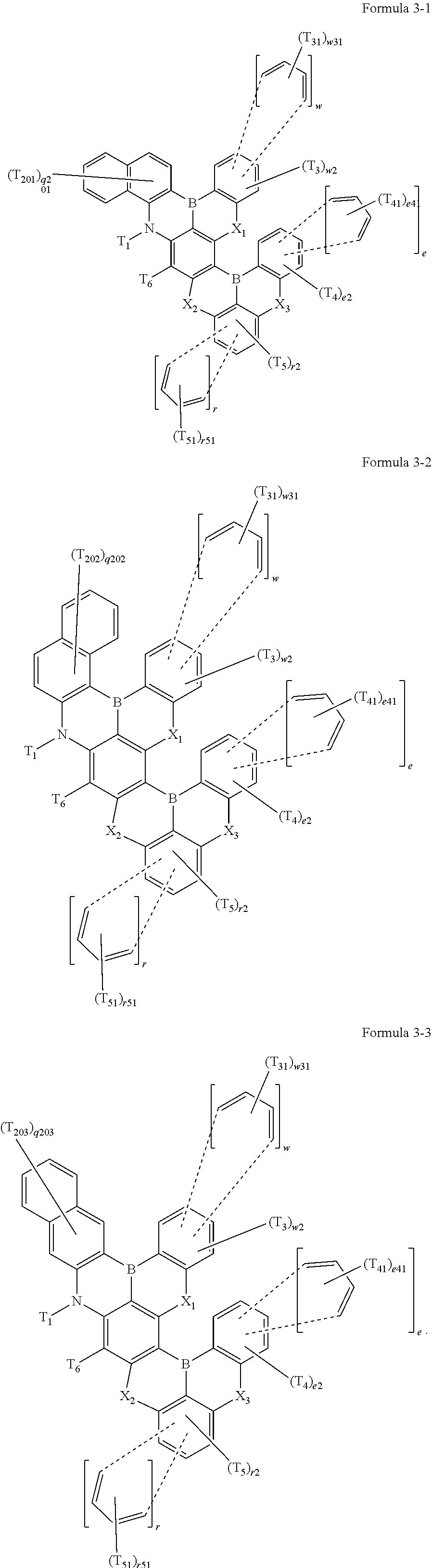

In Formula 1, if (e.g., when) q is 2, the fused polycyclic compound of one or more embodiments may be represented by any one selected from among Formula 3-4 to Formula 3-6:

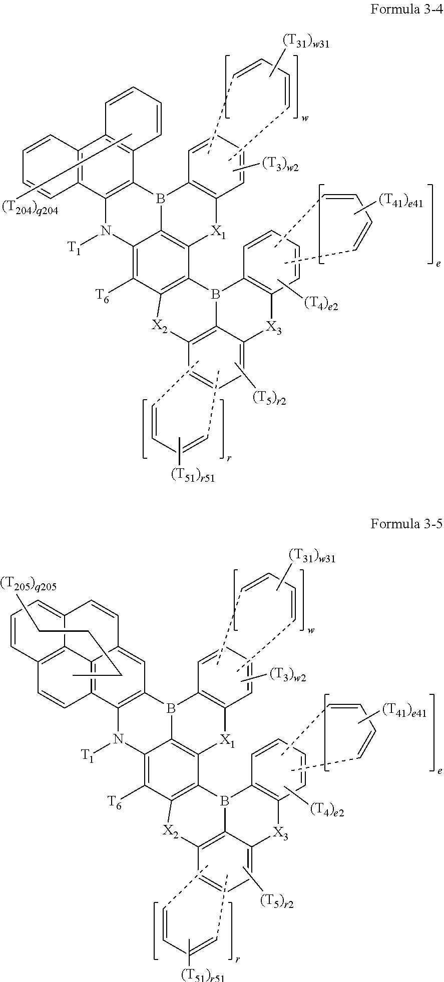

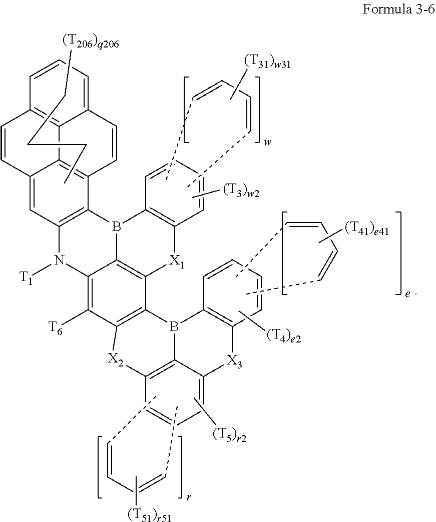

In Formula 1, if (e.g., when) q is 3, the fused polycyclic compound of one or more embodiments may be represented by Formula 3-7:

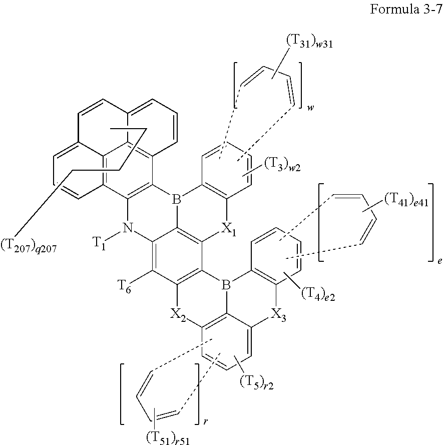

In Formula 3-1 to Formula 3-7, T₂₀₁, T₂₀₂, T₂₀₃, T₂₀₄, T₂₀₅, T₂₀₆, and T₂₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, T₂₀₁, T₂₀₂, T₂₀₃, T₂₀₄, T₂₀₅, T₂₀₆, and T₂₀₇ may each independently be a substituted or unsubstituted aryl group having 6 to 30 ring-forming carbon atoms. For example, in one or more embodiments, T₂₀₁, T₂₀₂, T₂₀₃, T₂₀₄, T₂₀₅, T₂₀₆, and T₂₀₇ may each independently be an unsubstituted phenyl group.

In Formula 3-1 to Formula 3-7, q201, q202, and q203 may each independently be an integer of 0 to 6, q204, q205, q206, and q207 may each independently be an integer of 0 to 8.

In Formula 3-1, if (e.g., when) q201 is 0, the fused polycyclic compound of one or more embodiments may not be substituted with T₂₀₁. The embodiment in which q201 is 6 and T₂₀₁'s are all hydrogens may be the same as the embodiment in which q201 is 0. If (e.g., when) q201 is an integer of 2 or greater, a plurality of T₂₀₁'s may all be the same, or at least one selected from among the plurality of T₂₀₁'s may be different from the others.

In Formula 3-2, if (e.g., when) q202 is 0, the fused polycyclic compound of one or more embodiments may not be substituted with T₂₀₂. The embodiment in which q202 is 6 and T₂₀₂'s are all hydrogens may be the same as the embodiment in which q202 is 0. If (e.g., when) q202 is an integer of 2 or greater, a plurality of T₂₀₂'s may all be the same, or at least one selected from among the plurality of T₂₀₂'s may be different from the others.

In Formula 3-3, if (e.g., when) q203 is 0, the fused polycyclic compound of one or more embodiments may not be substituted with T₂₀₃. The embodiment in which q203 is 6 and T₂₀₃'s are all hydrogens may be the same as the embodiment in which q203 is 0. If (e.g., when) q203 is an integer of 2 or greater, a plurality of T₂₀₃'s may all be the same, or at least one selected from among the plurality of T₂₀₃'s may be different from the others.

In Formula 3-4, if (e.g., when) q204 is 0, the fused polycyclic compound of one or more embodiments may not be substituted with T₂₀₄. The embodiment in which q204 is 8 and T₂₀₄'s are all hydrogens may be the same as the embodiment in which q204 is 0. If (e.g., when) q204 is an integer of 2 or greater, a plurality of T₂₀₄'s may all be the same, or at least one selected from among the plurality of T₂₀₄'s may be different from the others.

In Formula 3-5, if (e.g., when) q205 is 0, the fused polycyclic compound of one or more embodiments may not be substituted with T₂₀₅. The embodiment in which q205 is 8 and T₂₀₅'s are all hydrogens may be the same as the embodiment in which q205 is 0. If (e.g., when) q205 is an integer of 2 or greater, a plurality of T₂₀₅'s may all be the same, or at least one selected from among the plurality of T₂₀₅'s may be different from the others.

In Formula 3-6, if (e.g., when) q206 is 0, the fused polycyclic compound of one or more embodiments may not be substituted with T₂₀₆. The embodiment in which q206 is 8 and T₂₀₆'s are all hydrogens may be the same as the embodiment in which q206 is 0. If (e.g., when) q206 is an integer of 2 or greater, a plurality of T₂₀₆'s may all be the same, or at least one selected from among the plurality of T₂₀₆'s may be different from the others.

In Formula 3-7, if (e.g., when) q207 is 0, the fused polycyclic compound of one or more embodiments may not be substituted with T₂₀₇. The embodiment in which q207 is 8 and T₂₀₇'s are all hydrogens may be the same as the embodiment in which q207 is 0. If (e.g., when) q207 is an integer of 2 or greater, a plurality of T₂₀₇'s may all be the same, or at least one selected from among the plurality of T₂₀₇'s may be different from the others.

In Formula 3-1 to Formula 3-7, descriptions of w, e, r, w31, e41, r51, w2, e2, r2, X₁, X₂, X₃, T₁, T₂₀, T₃₀, T₃, T₄, T₅, T₆, T₃₁, T₄₁, and T₅₁ may be the same as those described in Formula 1.

In Formula 1, if (e.g., when) w is 1, the fused polycyclic compound of one or more embodiments may be represented by any one selected from among Formulae 4-1 to 4-3:

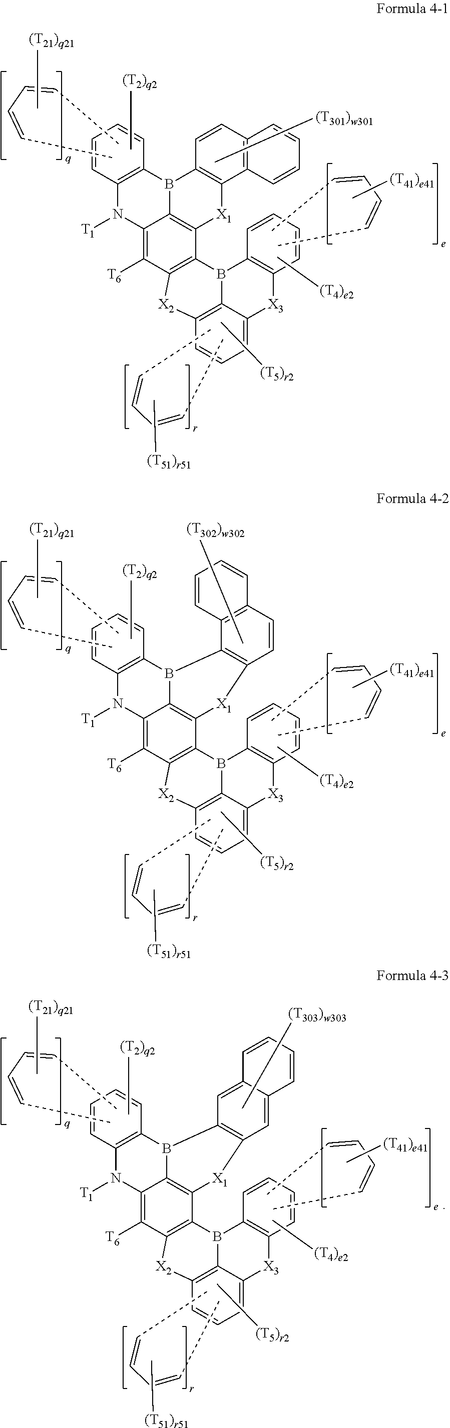

In Formula 1, if (e.g., when) w is 2, the fused polycyclic compound of one or more embodiments may be represented by any one selected from among Formula 4-4 to 4-6:

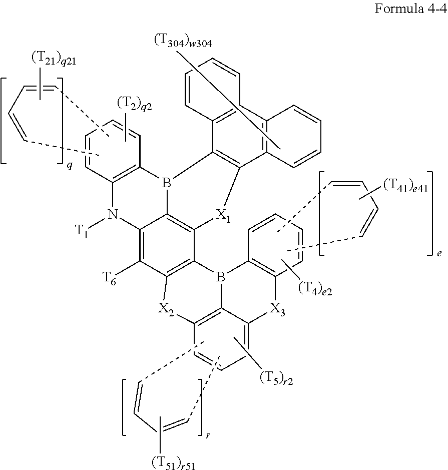

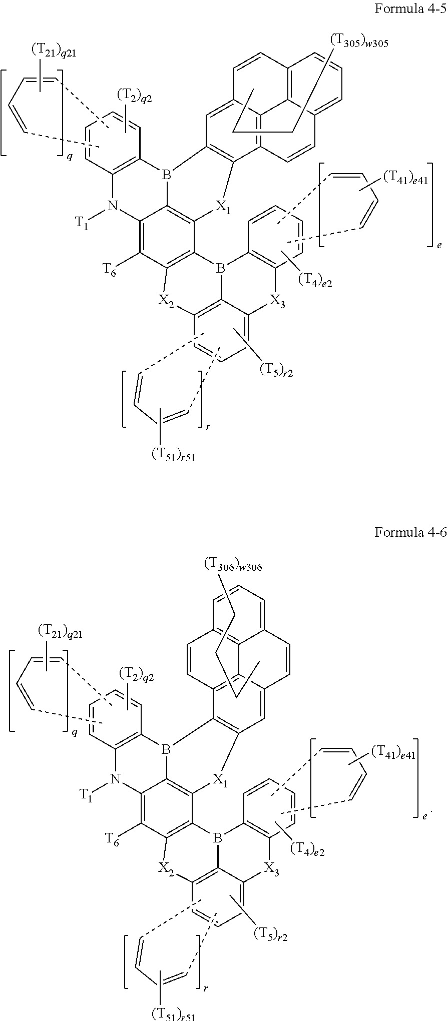

In Formula 1, if (e.g., when) w is 3, the fused polycyclic compound of one or more embodiments may be represented by Formula 4-7:

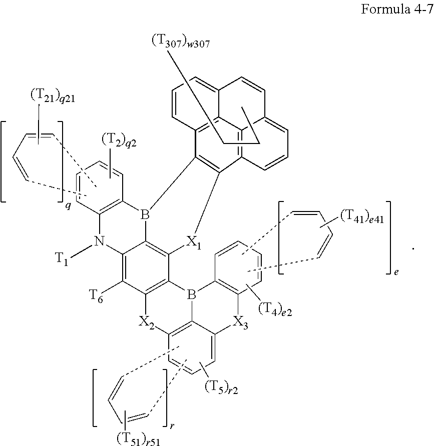

In Formula 4-1 to Formula 4-7, T₃₀₁, T₃₀₂, T₃₀₃, T₃₀₄, T₃₀₅, T₃₀₆, and T₃₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, T₃₀₁, T₃₀₂, T₃₀₅, T₃₀₄, T₃₀₅, T₃₀₆, and T₃₀₇ may each independently be a substituted or unsubstituted alkyl group having 1 to 20 carbon atoms or a substituted or unsubstituted aryl group having 6 to 30 ring-forming carbon atoms. For example, in one or more embodiments, T₃₀₁, T₃₀₂, T₃₀₃, T₃₀₄, T₃₀₅, T₃₀₆, and T₃₀₇ may each independently be an unsubstituted t-butyl group or an unsubstituted phenyl group.

In Formula 4-1 to Formula 4-7, w301, w302, and w303 may each independently be an integer of 0 to 6, w304, w305, w306, and w307 may each independently be an integer of 0 to 8.

In Formula 4-1, if (e.g., when) w301 is 0, the fused polycyclic compound of one or more embodiments may not be substituted with T₃₀₁. The embodiment in which w301 is 6 and T₃₀₁'s are all hydrogens may be the same as the embodiment in which w301 is 0. If (e.g., when) w301 is an integer of 2 or greater, a plurality of T₃₀₁'s may all be the same, or at least one selected from among the plurality of T₃₀₁'s may be different from the others.

In Formula 4-2, (e.g., when) if w302 is 0, the fused polycyclic compound of one or more embodiments may not be substituted with T₃₀₂. The embodiment in which w302 is 6 and T₃₀₂'s are all hydrogens may be the same as the embodiment in which w302 is 0. If (e.g., when) w302 is an integer of 2 or greater, a plurality of T₃₀₂'s may all be the same, or at least one selected from among the plurality of T₃₀₂'s may be different from the others.

In Formula 4-3, if (e.g., when) w303 is 0, the fused polycyclic compound of one or more embodiments may not be substituted with T₃₀₃. The embodiment in which w303 is 6 and T₃₀₃'s are all hydrogens may be the same as the embodiment in which w303 is 0. If (e.g., when) w303 is an integer of 2 or greater, a plurality of T₃₀₃'s may all be the same, or at least one selected from among the plurality of T₃₀₃'s may be different from the others.

In Formula 4-4, if (e.g., when) w304 is 0, the fused polycyclic compound of one or more embodiments may not be substituted with T₃₀₄. The embodiment in which w304 is 8 and T₃₀₄'s are all hydrogens may be the same as the embodiment in which w304 is 0. If (e.g., when) w304 is an integer of 2 or greater, a plurality of T₃₀₄'s may all be the same, or at least one selected from among the plurality of T₃₀₄'s may be different from the others.

In Formula 4-5, if (e.g., when) w305 is 0, the fused polycyclic compound of one or more embodiments may not be substituted with T₃₀₅. The embodiment in which w305 is 8 and T₃₀₅'s are all hydrogens may be the same as the embodiment in which w305 is 0. If (e.g., when) w305 is an integer of 2 or greater, a plurality of T₃₀₅'s may all be the same, or at least one selected from among the plurality of T₃₀₅'s may be different from the others.

In Formula 4-6, if (e.g., when) w306 is 0, the fused polycyclic compound of one or more embodiments may not be substituted with T₃₀₆. The embodiment in which w306 is 8 and T₃₀₆'s are all hydrogens may be the same as the embodiment in which w306 is 0. If (e.g., when) w306 is an integer of 2 or greater, a plurality of T₃₀₆'s may all be the same, or at least one selected from among the plurality of T₃₀₆'s may be different from the others.

In Formula 4-7, if (e.g., when) w307 is 0, the fused polycyclic compound of one or more embodiments may not be substituted with T₃₀₇. The embodiment in which w307 is 8 and T₃₀₇'s are all hydrogens may be the same as the embodiment in which w307 is 0. If (e.g., when) w307 is an integer of 2 or greater, a plurality of T₃₀₇'s may all be the same, or at least one selected from among the plurality of T₃₀₇'s may be different from the others.

In Formula 4-1 to Formula 4-7, descriptions of q, e, r, q21, e41, r51, q2, e2, r2, X₁, X₂, X₃, T₁, T₂₀, T₃₀, T₂, T₄, T₅, T₆, T₂₁, T₄₁, and T₅₁ may be the same as those described in Formula 1.

In Formula 1, if (e.g., when) e is 1, the fused polycyclic compound of one or more embodiments may be represented by any one selected from among Formula 5-1 to Formula 5-3:

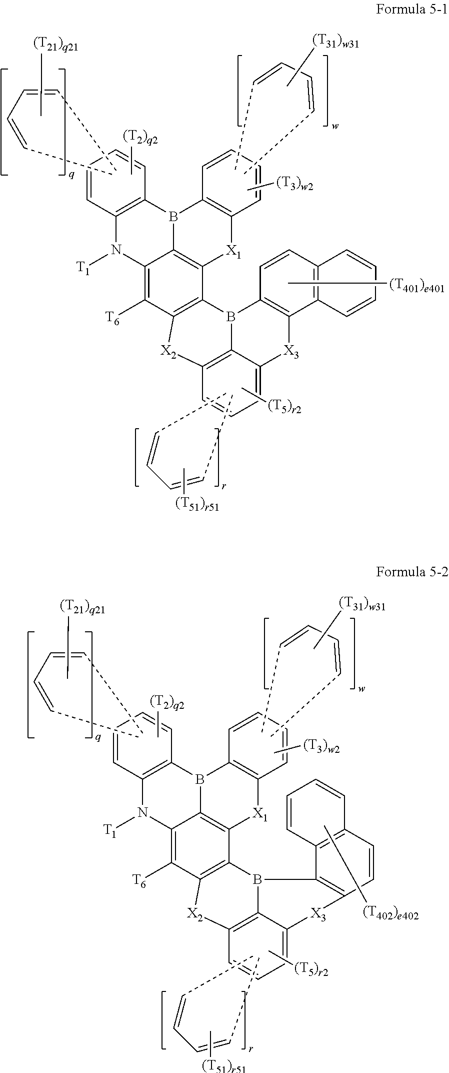

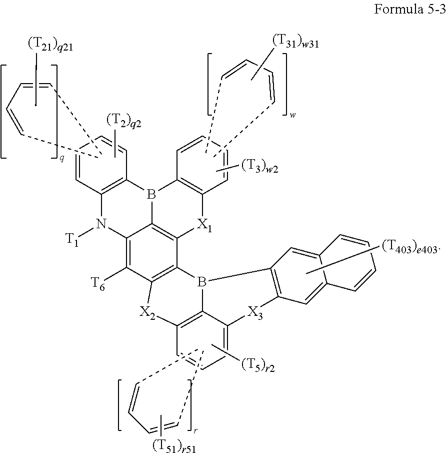

In Formula 1, if (e.g., when) e is 2, the fused polycyclic compound of one or more embodiments may be represented by any one selected from among Formula 5-4 to Formula 5-6:

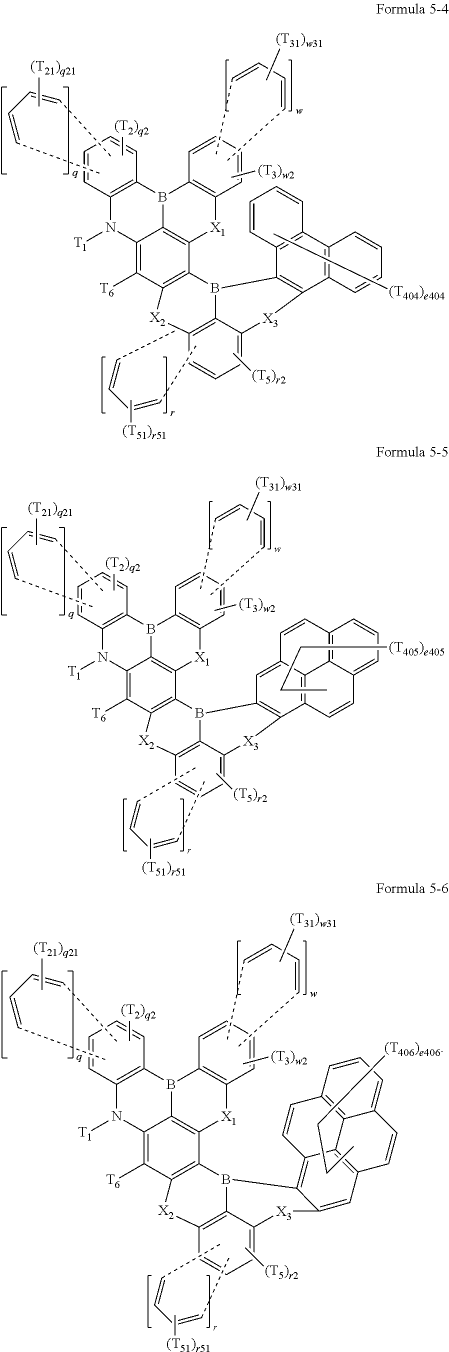

In Formula 1, if (e.g., when) e is 3, the fused polycyclic compound of one or more embodiments may be represented by Formula 5-7:

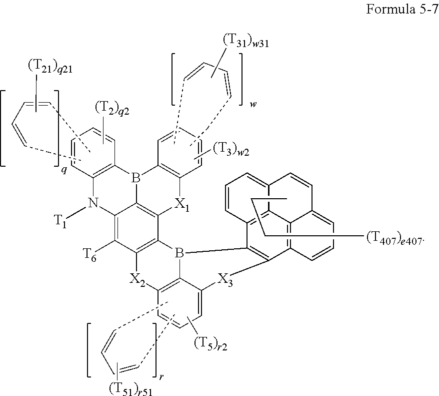

In Formula 5-1 to Formula 5-7, T₄₀₁, T₄₀₂, T₄₀₃, T₄₀₄, T₄₀₅, T₄₀₆, and T₄₀₇ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, T₄₀₁, T₄₀₂, T₄₀₃, T₄₀₄, T₄₀₅, T₄₀₆, and T₄₀₇ may each independently be a substituted or unsubstituted alkyl group having 1 to 20 carbon atoms. For example, in one or more embodiments, T₄₀₁, T₄₀₂, T₄₀₃, T₄₀₄, T₄₀₅, T₄₀₆, and T₄₀₇ may each independently be an unsubstituted t-butyl group.

In Formula 5-1 to Formula 5-7, e401, e402, and e403 may each independently be an integer of 0 to 6, e404, e405, e406, and e407 may each independently be an integer of 0 to 8.

In Formula 5-1, if (e.g., when) e401 is 0, the fused polycyclic compound of one or more embodiments may not be substituted with T₄₀₁. The embodiment in which e401 is 6 and T₄₀₁'s are all hydrogens may be the same as the embodiment in which e401 is 0. If (e.g., when) e401 is an integer of 2 or greater, a plurality of T₄₀₁'s may all be the same, or at least one selected from among the plurality of T₄₀₁'s may be different from the others.

In Formula 5-2, if (e.g., when) e402 is 0, the fused polycyclic compound of one or more embodiments may not be substituted with T₄₀₂. The embodiment in which e402 is 6 and T₄₀₂'s are all hydrogens may be the same as the embodiment in which e402 is 0. If (e.g., when) e402 is an integer of 2 or greater, a plurality of T₄₀₂'s may all be the same, or at least one selected from among the plurality of T₄₀₂'s may be different from the others.

In Formula 5-3, if (e.g., when) e403 is 0, the fused polycyclic compound of one or more embodiments may not be substituted with T₄₀₃. The embodiment in which e403 is 6 and T₄₀₃'s are all hydrogens may be the same as the embodiment in which e403 is 0. If (e.g., when) e403 is an integer of 2 or greater, a plurality of T₄₀₃'s may all be the same, or at least one selected from among the plurality of T₄₀₃'s may be different from the others.

In Formula 5-4, if (e.g., when) e404 is 0, the fused polycyclic compound of one or more embodiments may not be substituted with T₄₀₄. The embodiment in which e404 is 8 and T₄₀₄'s are all hydrogens may be the same as the embodiment in which e404 is 0. If (e.g., when) e404 is an integer of 2 or greater, a plurality of T₄₀₄'s may all be the same, or at least one selected from among the plurality of T₄₀₄'s may be different from the others.

In Formula 5-5, if (e.g., when) e405 is 0, the fused polycyclic compound of one or more embodiments may not be substituted with T₄₀₅. The embodiment in which e405 is 8 and T₄₀₅'s are all hydrogens may be the same as the embodiment in which e405 is 0. If (e.g., when) e405 is an integer of 2 or greater, a plurality of T₄₀₅'s may all be the same, or at least one selected from among the plurality of T₄₀₅'s may be different from the others.

In Formula 5-6, if (e.g., when) e406 is 0, the fused polycyclic compound of one or more embodiments may not be substituted with T₄₀₆. The embodiment in which e406 is 8 and T₄₀₆'s are all hydrogens may be the same as the embodiment in which e406 is 0. If (e.g., when) e406 is an integer of 2 or greater, a plurality of T₄₀₆'s may all be the same, or at least one selected from among the plurality of T₄₀₆'s may be different from the others.

In Formula 5-7, if (e.g., when) e407 is 0, the fused polycyclic compound of one or more embodiments may not be substituted with T₄₀₇. The embodiment in which e407 is 8 and T₄₀₇'s are all hydrogens may be the same as the embodiment in which e407 is 0. If (e.g., when) e407 is an integer of 2 or greater, a plurality of T₄₀₇'s may all be the same, or at least one selected from among the plurality of T₄₀₇'s may be different from the others.

In Formula 5-1 to Formula 5-7 above, descriptions of q, w, r, q21, w31, r51, q2, w2, r2, X₁, X₂, X₃, T₁, T₂₀, T₃₀, T₂, T₃, T₅, T₆, T₂₁, T₃₁, and T₅₁ may be the same as those described in Formula 1.

In Formula 1, if (e.g., when) r is 1, the fused polycyclic compound of one or more embodiments may be represented by Formula 6-1 or Formula 6-2:

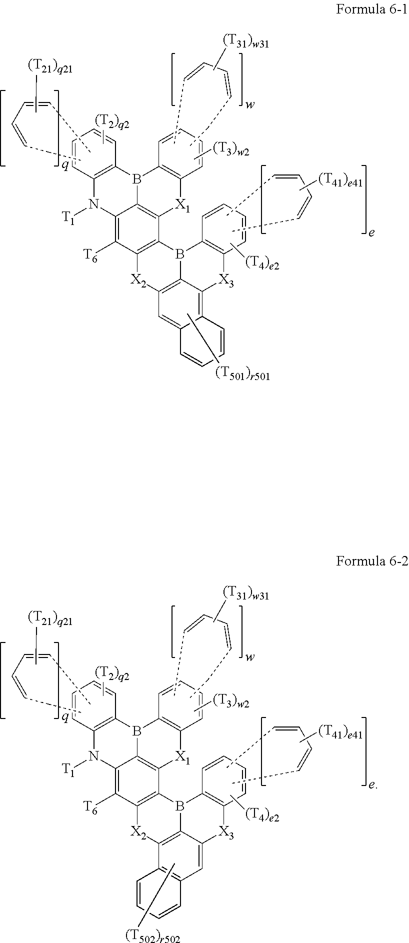

In Formula 1, if (e.g., when) r is 0, the fused polycyclic compound of one or more embodiments may be represented by Formula 6-3:

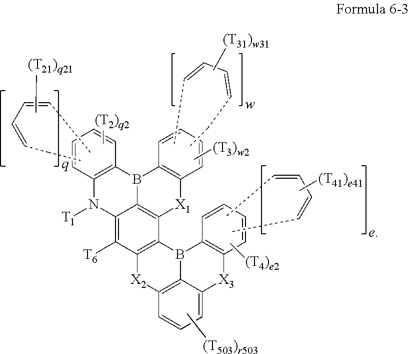

In Formula 6-1 to Formula 6-3, T₅₀₁ to T₅₀₃ may each independently be hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. For example, in one or more embodiments, T₅₀₁ and T₅₀₂ may each independently be hydrogen, and T₅₀₃ may be an unsubstituted t-butyl group.

In Formula 6-1 to Formula 6-3, r501 and r502 may each independently be an integer of 0 to 5, and r503 may be an integer of 0 to 3.

In Formula 6-1, if (e.g., when) r501 is 0, the fused polycyclic compound of one or more embodiments may not be substituted with T₅₀₁. The embodiment in which r501 is 5 and T₅₀₁'s are all hydrogens may be the same as the embodiment in which r501 is 0. If (e.g., when) r501 is an integer of 2 or greater, a plurality of T₅₀₁'s may all be the same, or at least one selected from among the plurality of T₅₀₁'s may be different from the others.

In Formula 6-2, if (e.g., when) r502 is 0, the fused polycyclic compound of one or more embodiments may not be substituted with T₅₀₂. The embodiment in which r502 is 5 and T₅₀₂'s are all hydrogens may be the same as the embodiment in which r502 is 0. If (e.g., when) r502 is an integer of 2 or greater, a plurality of T₅₀₂'s may all be the same, or at least one selected from among the plurality of T₅₀₂'s may be different from the others.

In Formula 6-3, if (e.g., when) r503 is 0, the fused polycyclic compound of one or more embodiments may not be substituted with T₅₀₃. The embodiment in which r503 is 3 and T₅₀₃'s are all hydrogens may be the same as the embodiment in which r503 is 0. If (e.g., when) r503 is an integer of 2 or greater, a plurality of T₅₀₃'s may all be the same, or at least one selected from among the plurality of T₅₀₃'s may be different from the others.

In Formula 6-1 to Formula 6-3, descriptions of q, w, e, q21, w31, e41, q2, w2, e2, X₁, X₂, X₃, T₁, T₂₀, T₃₀, T₂, T₃, T₄, T₆, T₂₁, T₃₁, and T₄₁ may be the same as those described in Formula 1.

In one or more embodiments, the fused polycyclic compound of one or more embodiments represented by any one selected from among Formula 1, Formula 2-1, Formula 2-1, Formula 3-1 to Formula 3-7, Formula 4-1 to Formula 4-7, Formula 5-1 to Formula 5-7, and Formula 6-1 to Formula 6-3 may include at least one deuterium as a substituent.

The fused polycyclic compound of one or more embodiments may be any one selected from among the compounds represented by Compound Group 1. At least one functional layer included in the light emitting element ED of one or more embodiments may include at least one fused polycyclic compound selected from among the compounds represented by Compound Group 1. The light emitting element ED of one or more embodiments may include at least one fused polycyclic compound selected from among the compounds represented by Compound Group 1 in the emission layer EML.

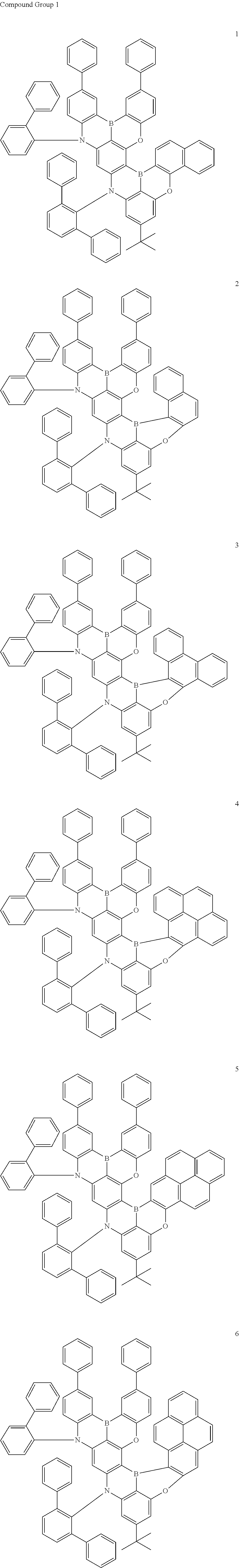

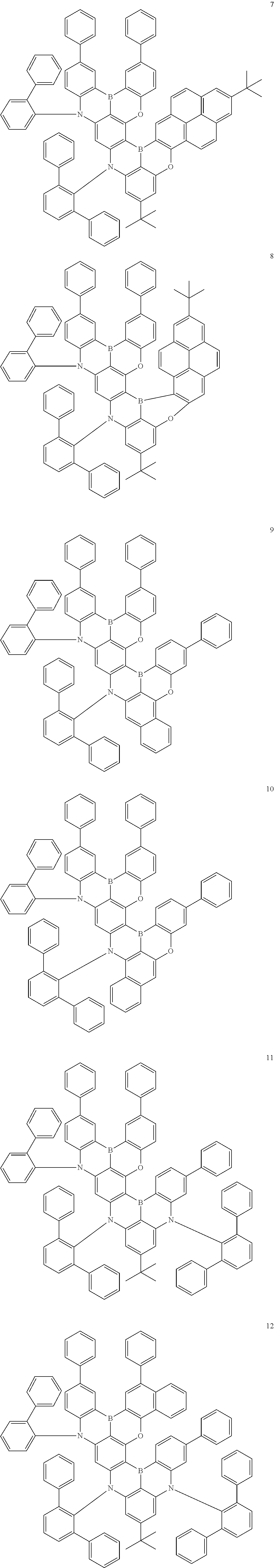

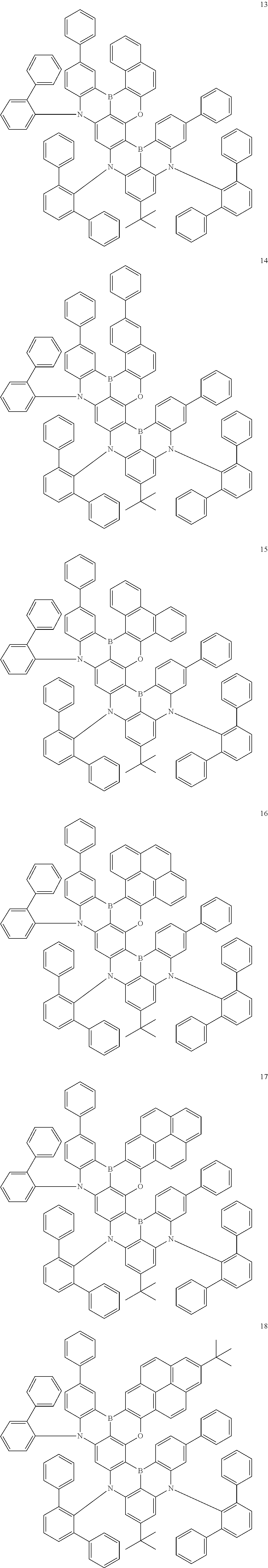

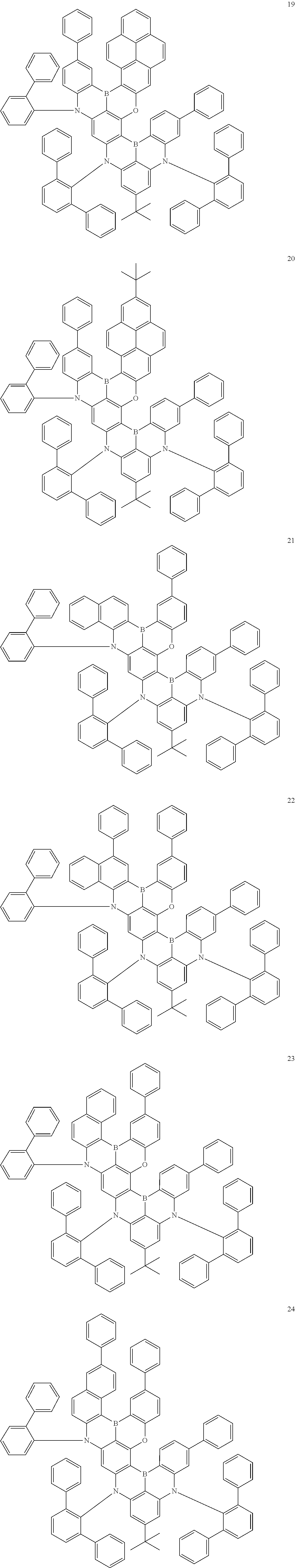

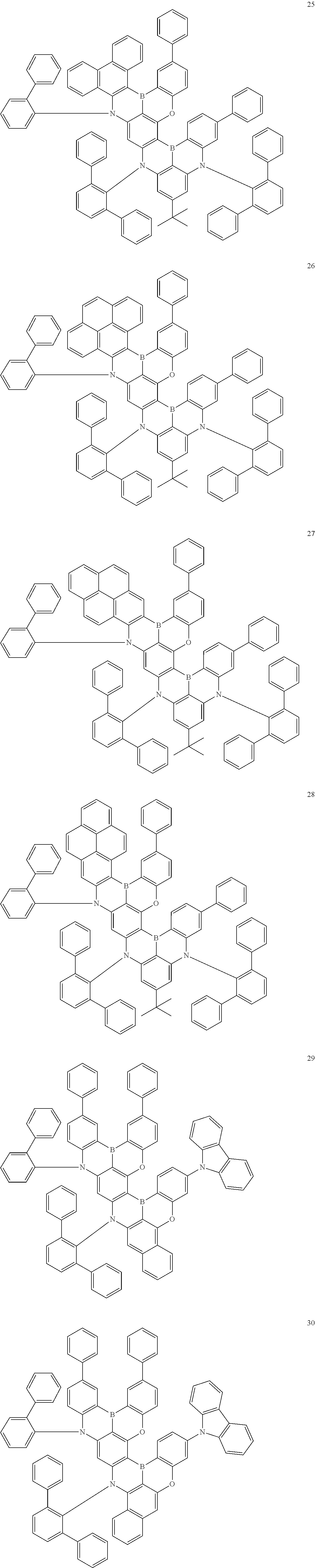

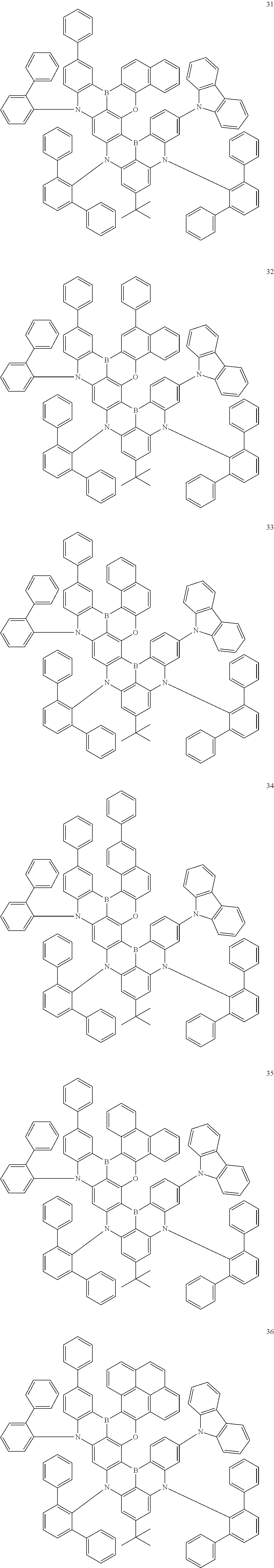

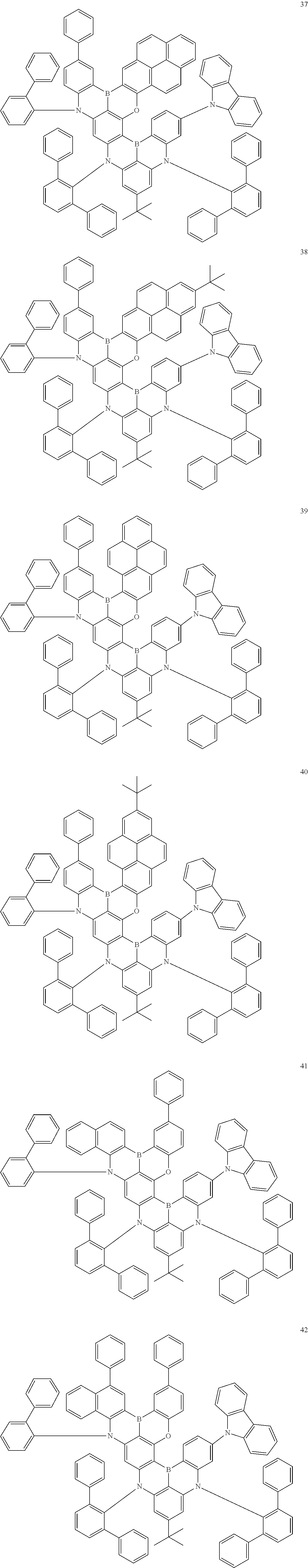

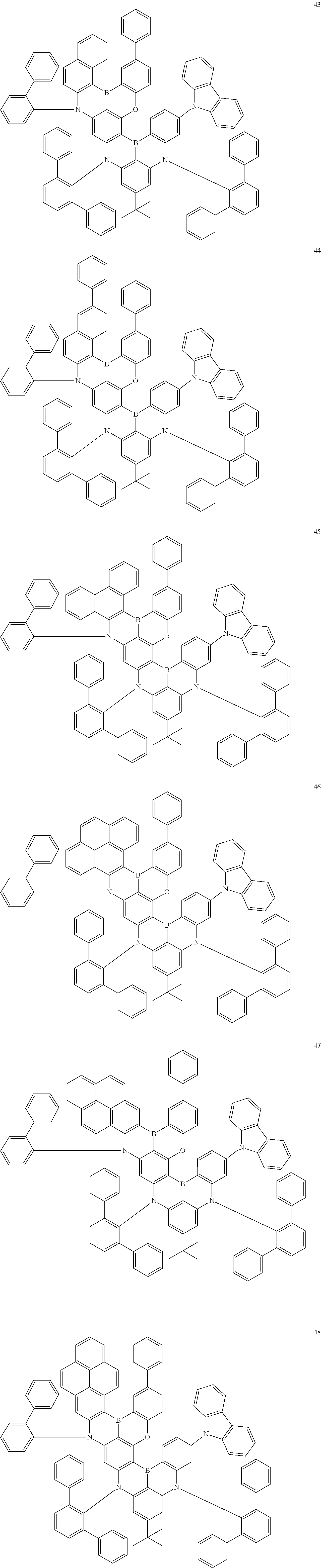

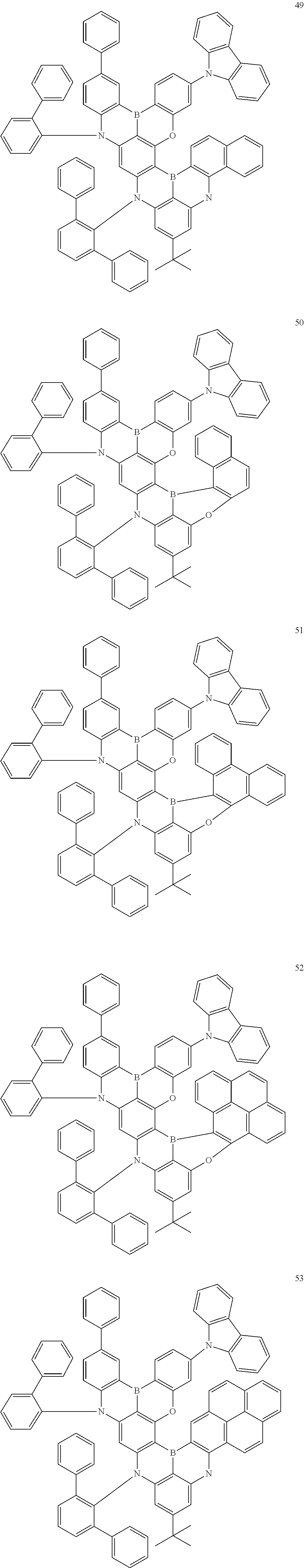

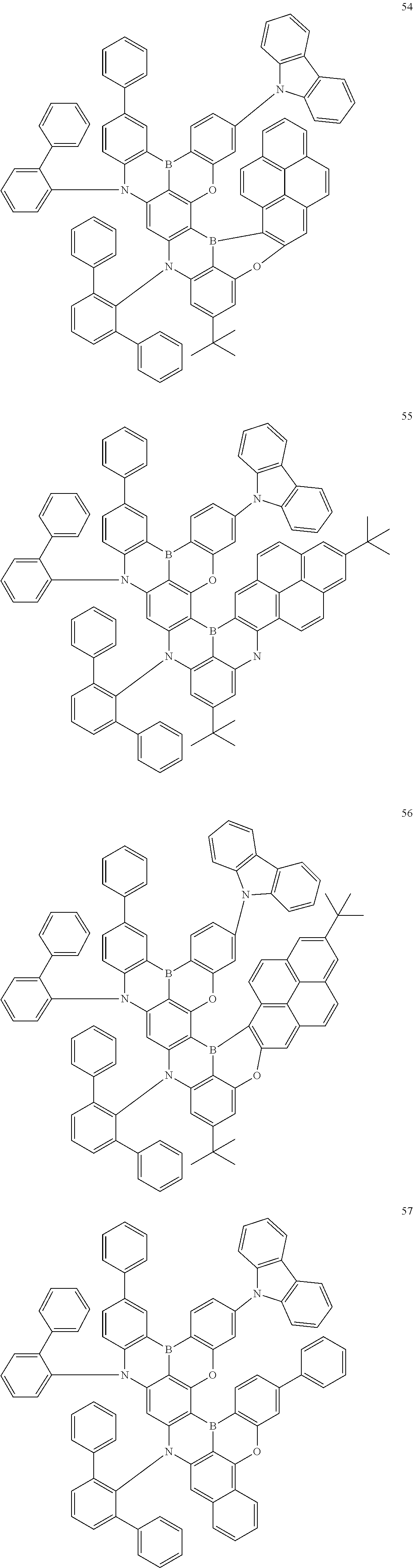

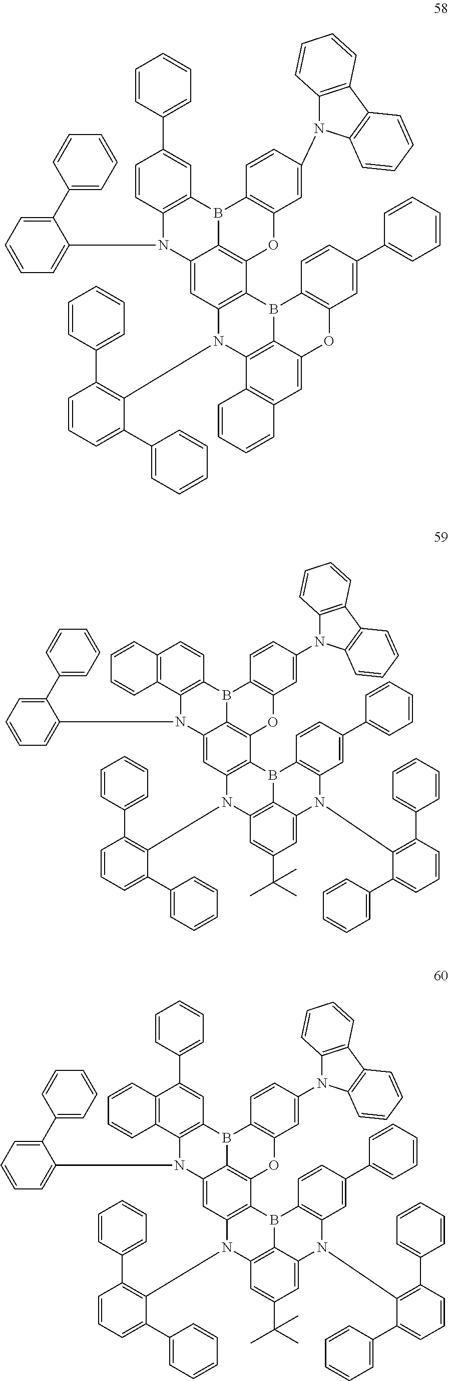

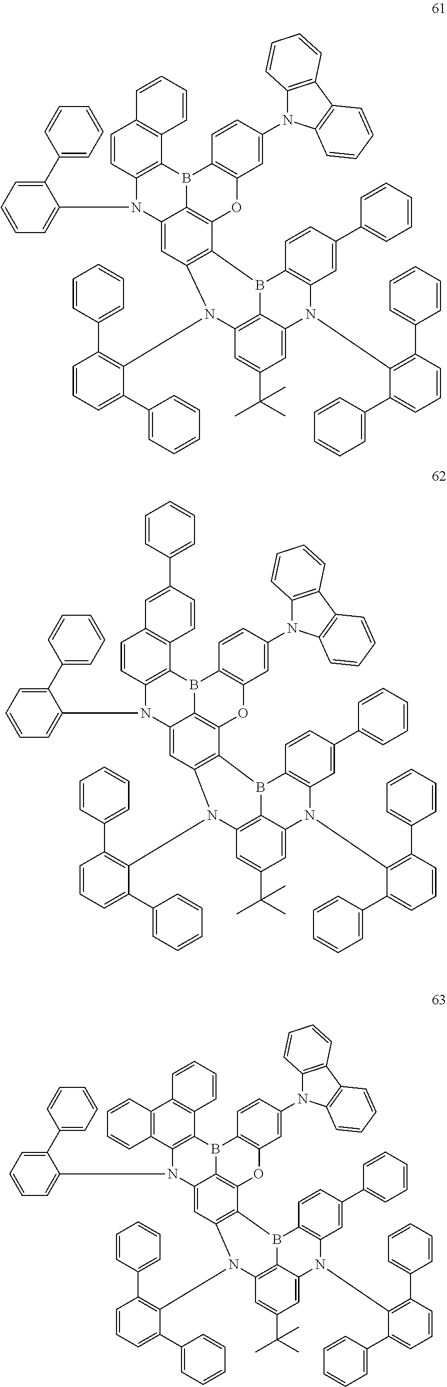

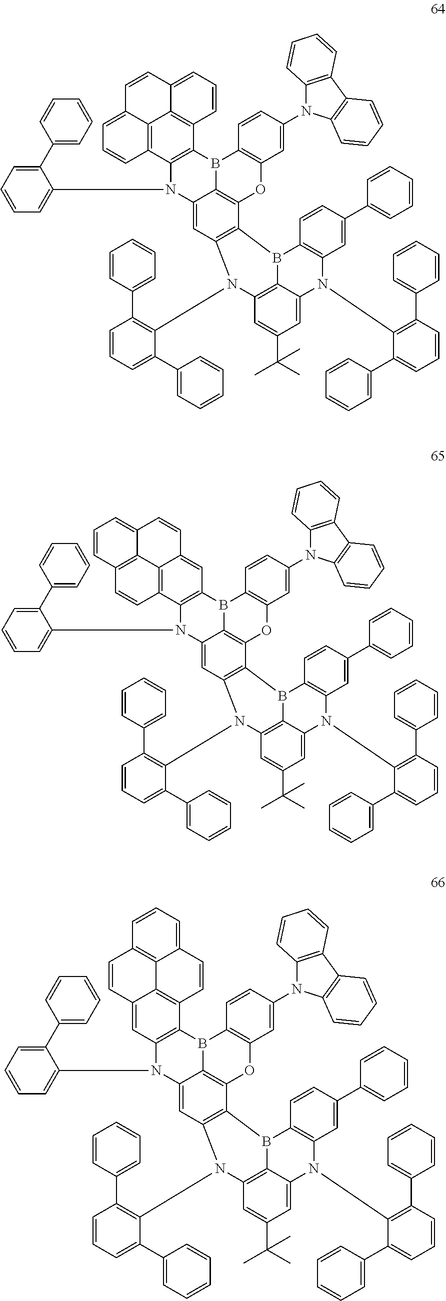

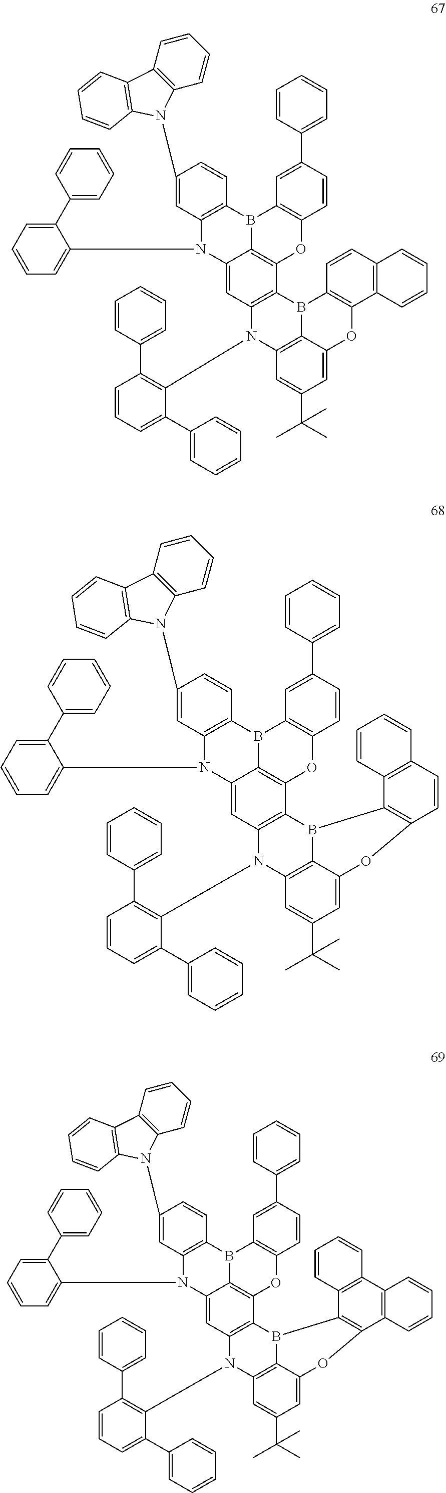 [SMILES: CC(C)(C)c1cc2c3c(c1)N(c1c(-c4ccccc4)cccc1-c1ccccc1)c1cc4c5c(c1B3c1ccc3ccccc3c1O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Oc1ccc(-c2ccccc2)cc1B5c1ccc(-n2c3ccccc3c3ccccc32)cc1N4c1ccccc1-c1ccccc1]

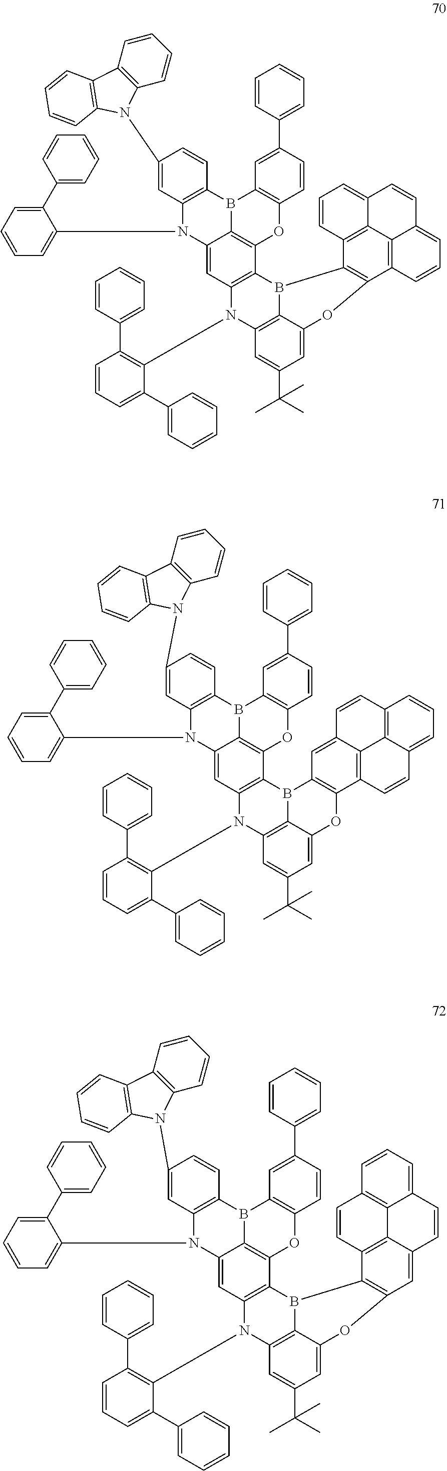 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1ccc(-c2ccccc2)cc1B5c1ccc(-n2c3ccccc3c3ccccc32)cc1N4c1ccccc1-c1ccccc1]

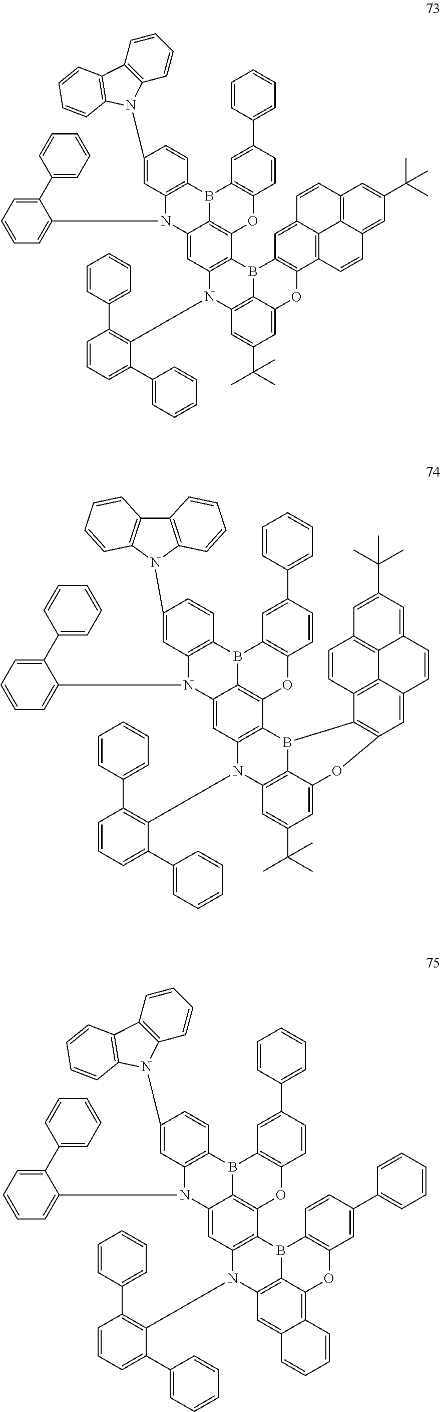

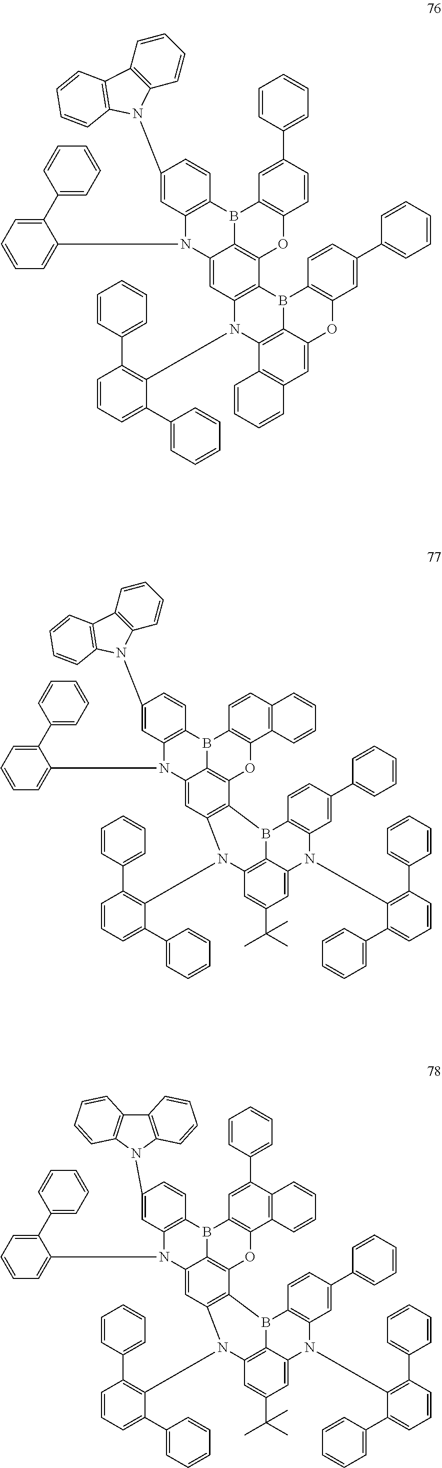

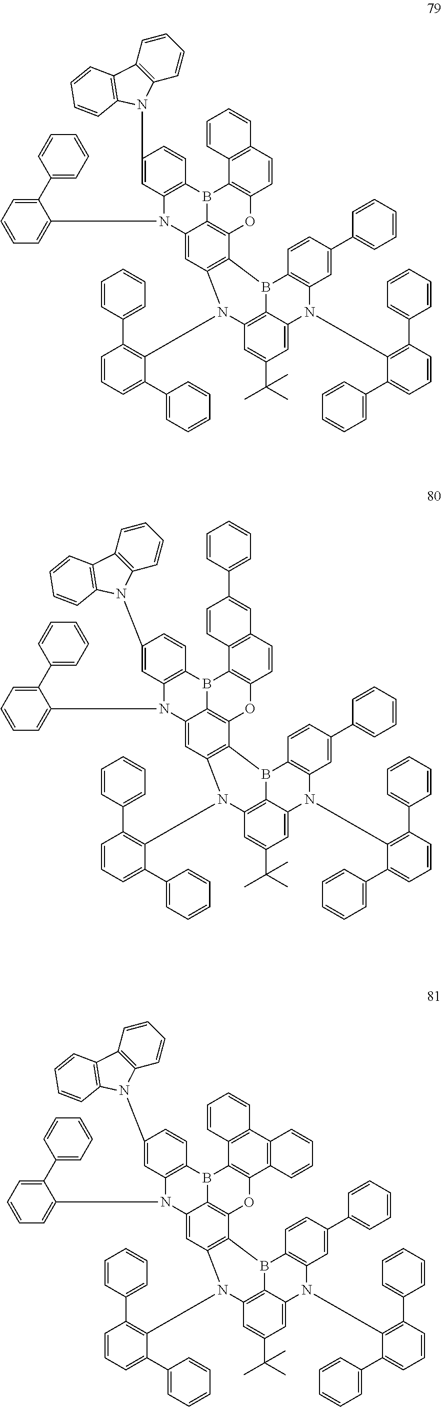

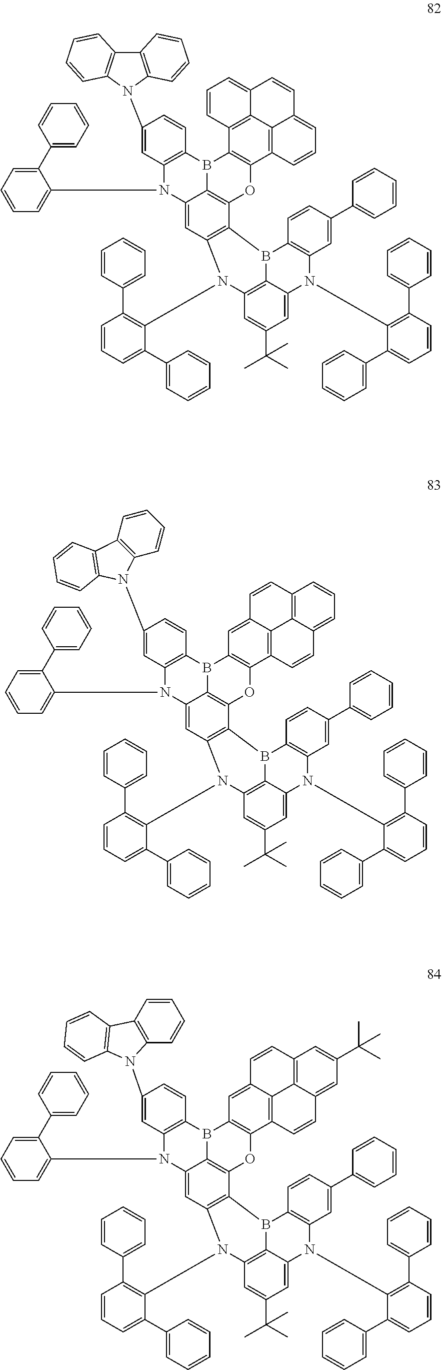

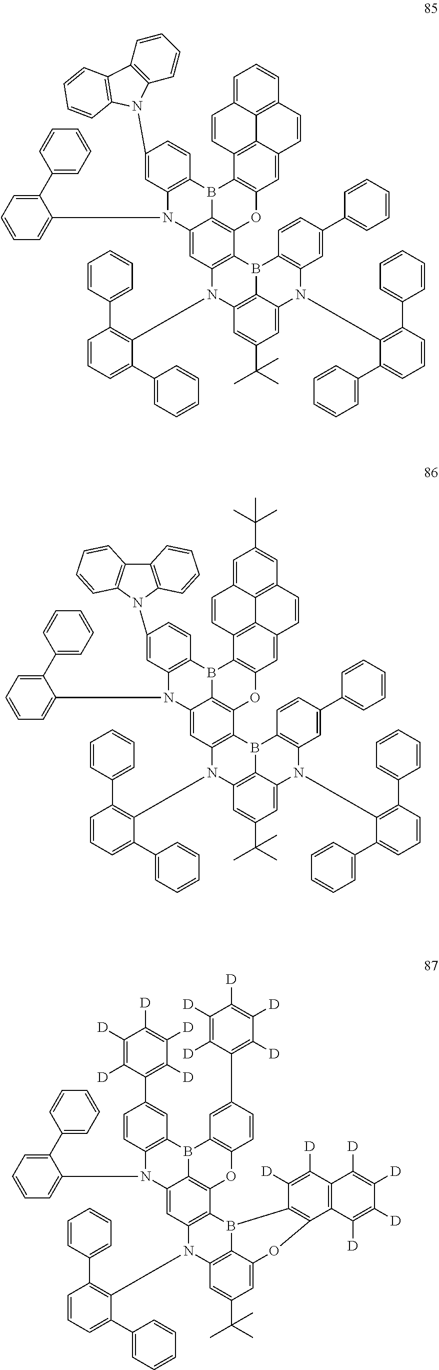

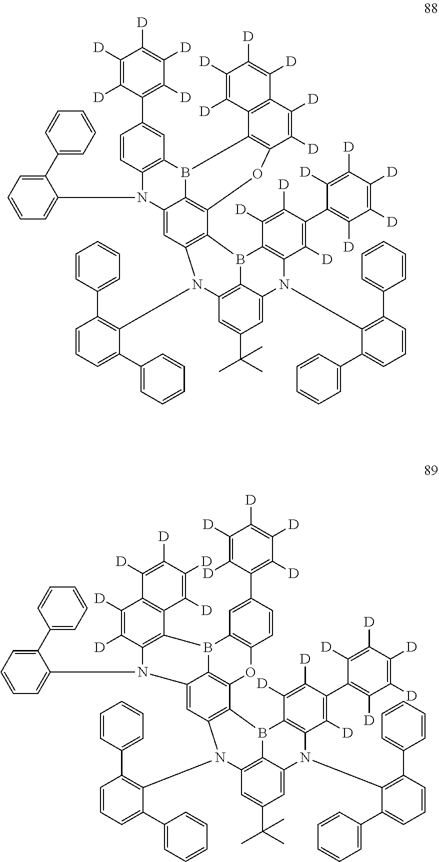

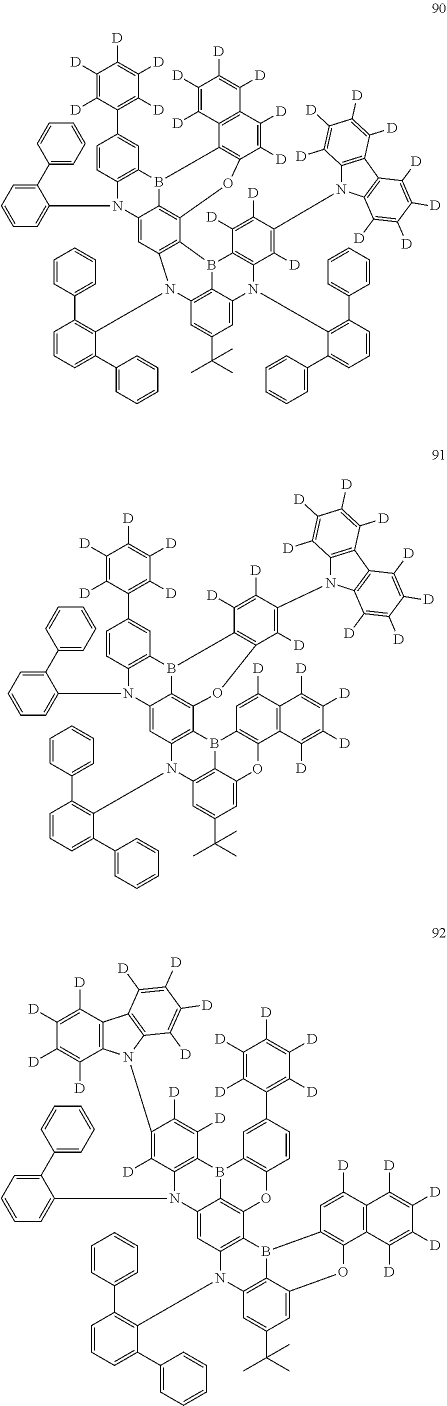

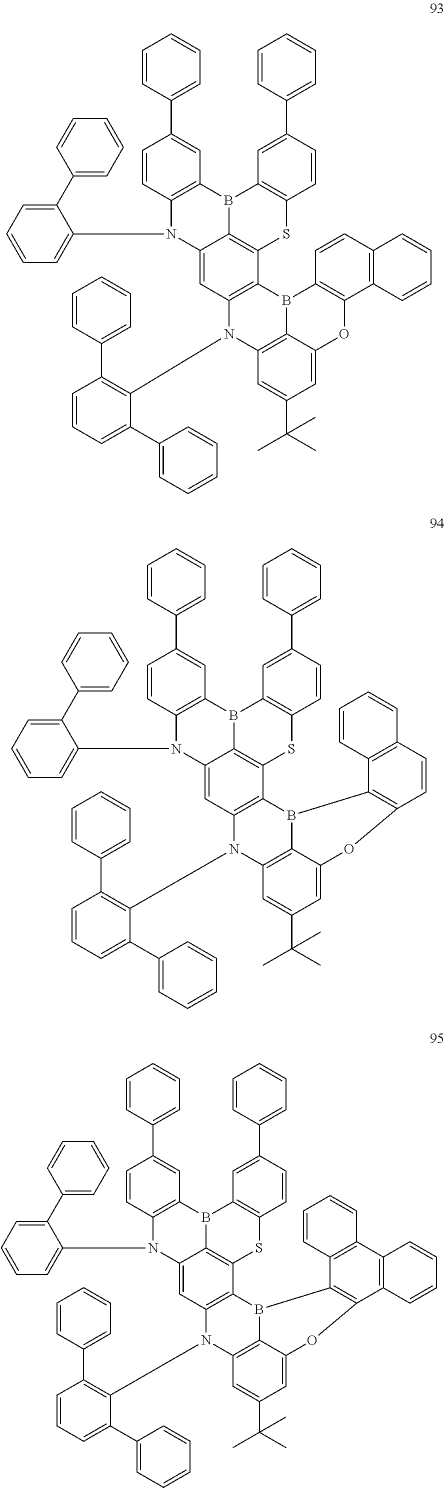 [SMILES: CC(C)(C)c1cc2c3c(c1)N(c1c(-c4ccccc4)cccc1-c1ccccc1)c1cc4c5c(c1B3c1ccc3ccccc3c1O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Sc1ccc(-c2ccccc2)cc1B5c1cc(-c2ccccc2)ccc1N4c1ccccc1-c1ccccc1]

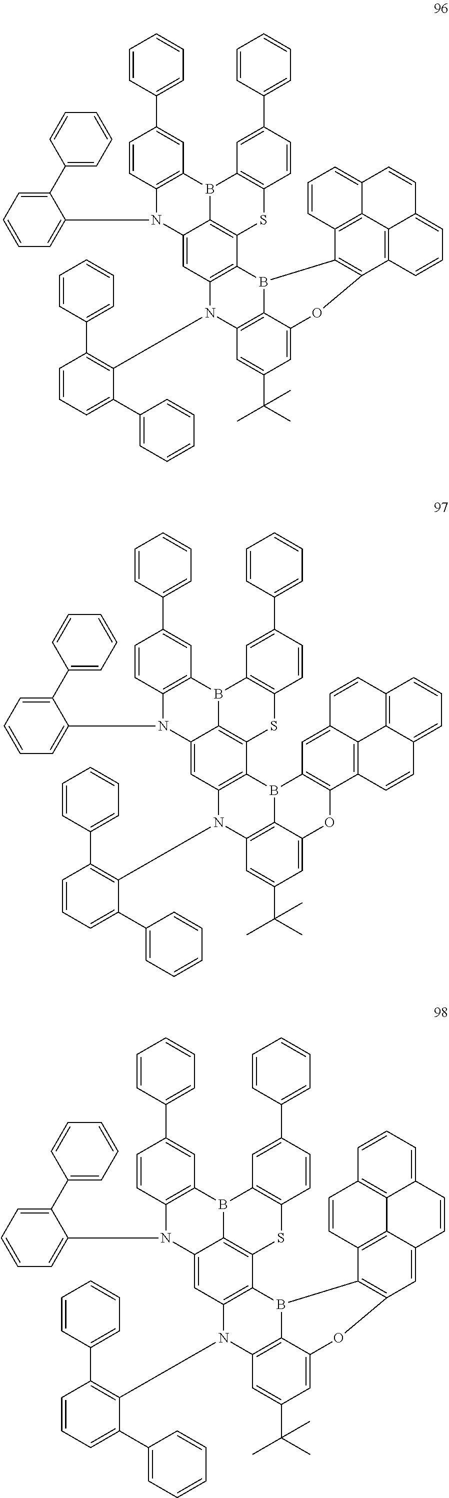 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Sc1ccc(-c2ccccc2)cc1B5c1cc(-c2ccccc2)ccc1N4c1ccccc1-c1ccccc1]

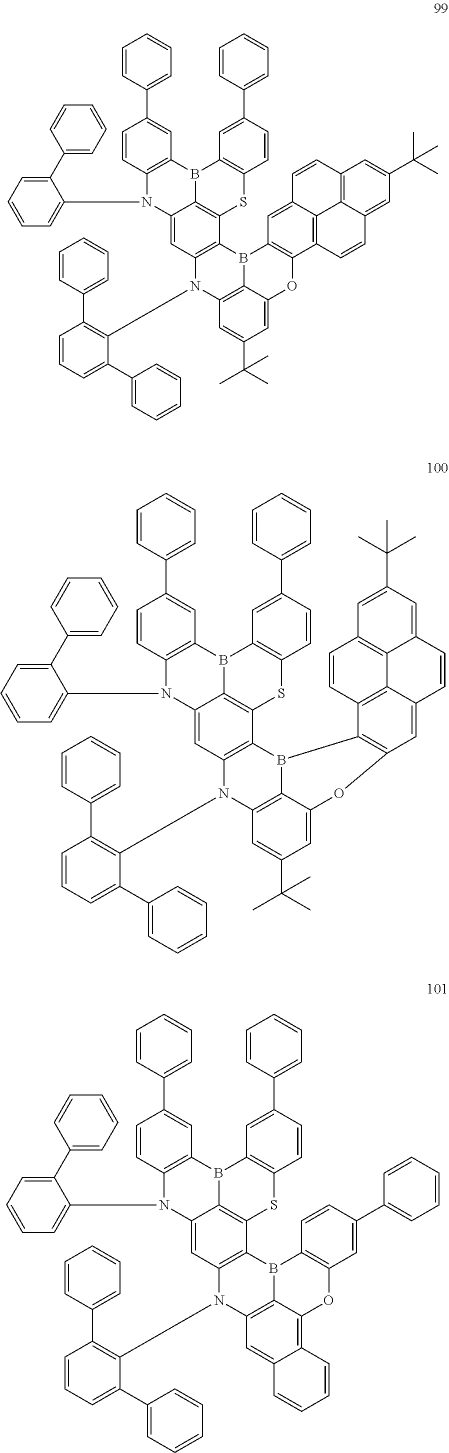 [SMILES: CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1O2)c3c67)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Sc1ccc(-c2ccccc2)cc1B5c1cc(-c2ccccc2)ccc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Sc2ccc(-c3ccccc3)cc2B6c2cc(-c3ccccc3)ccc2N5c2ccccc2-c2ccccc2)cc1]

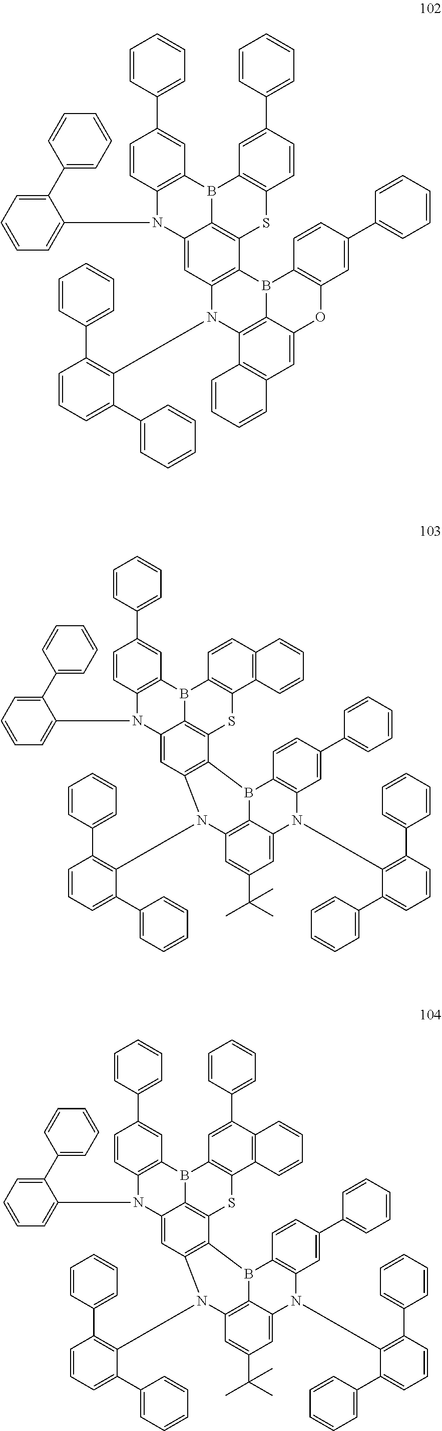

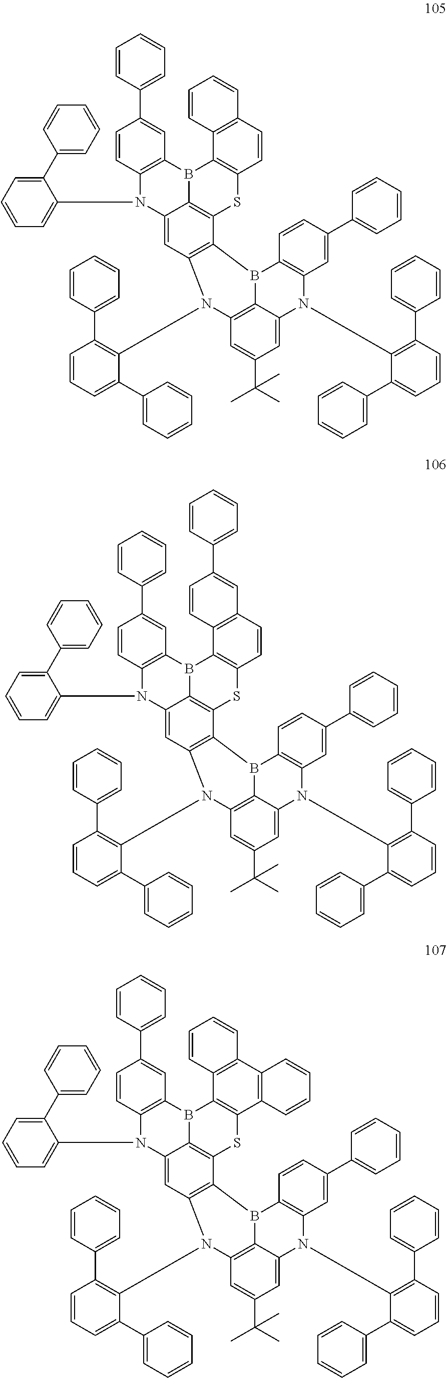

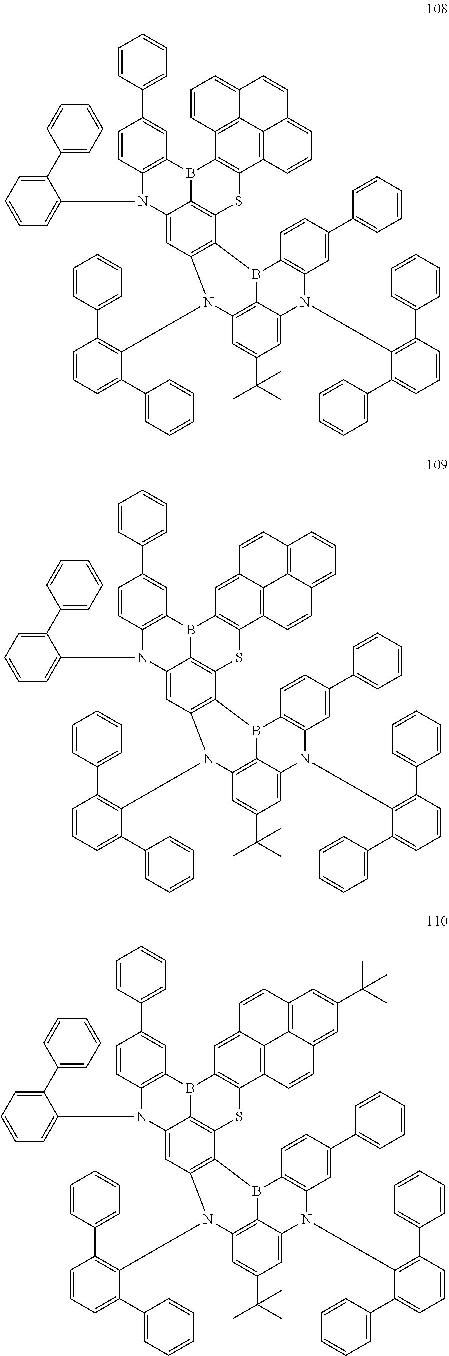

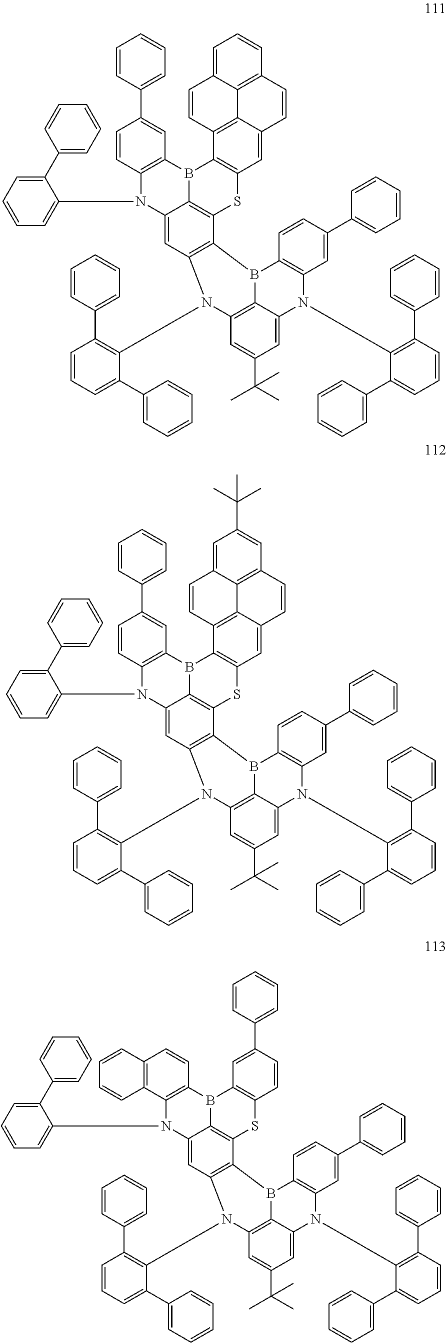

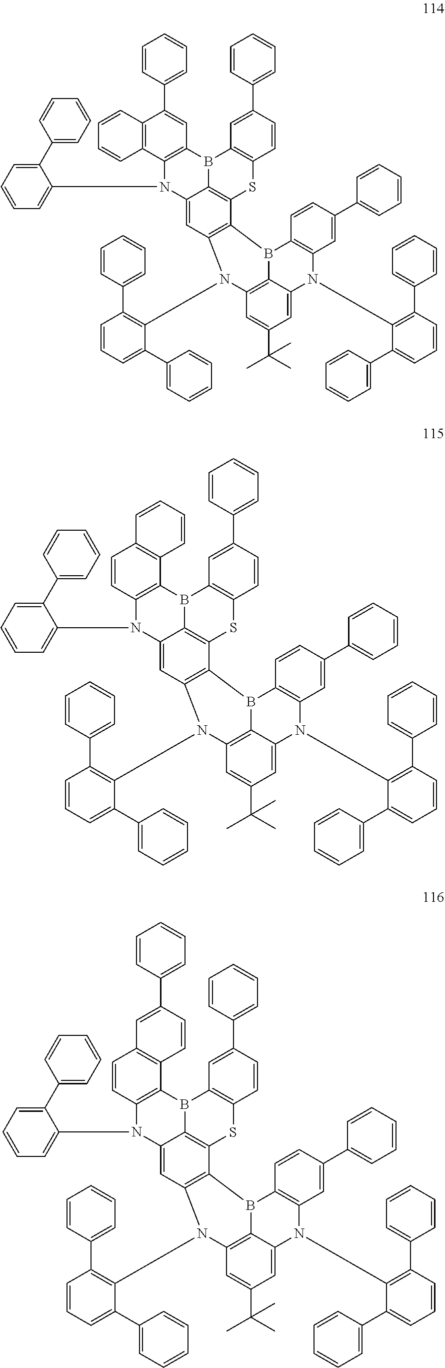

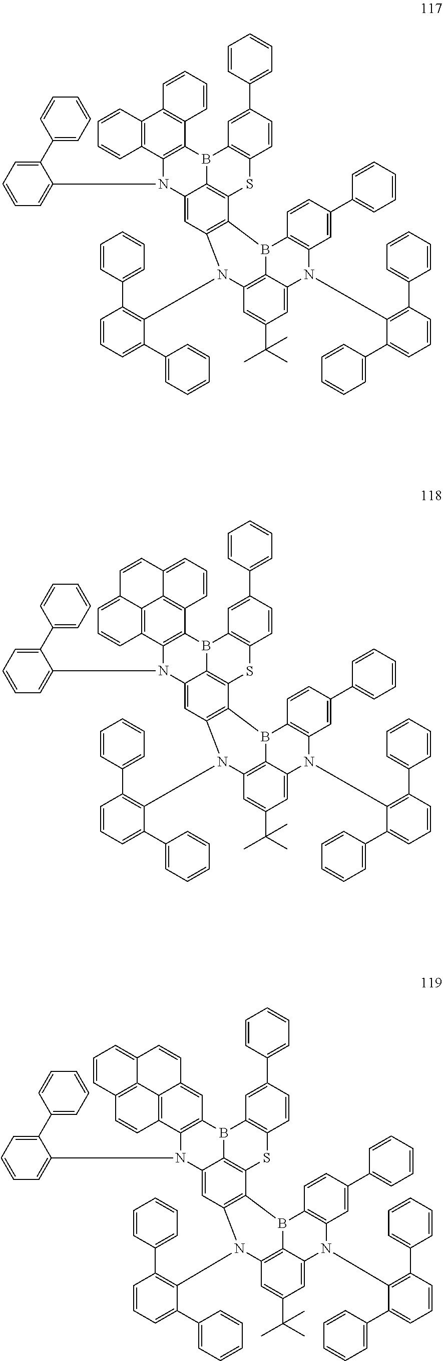

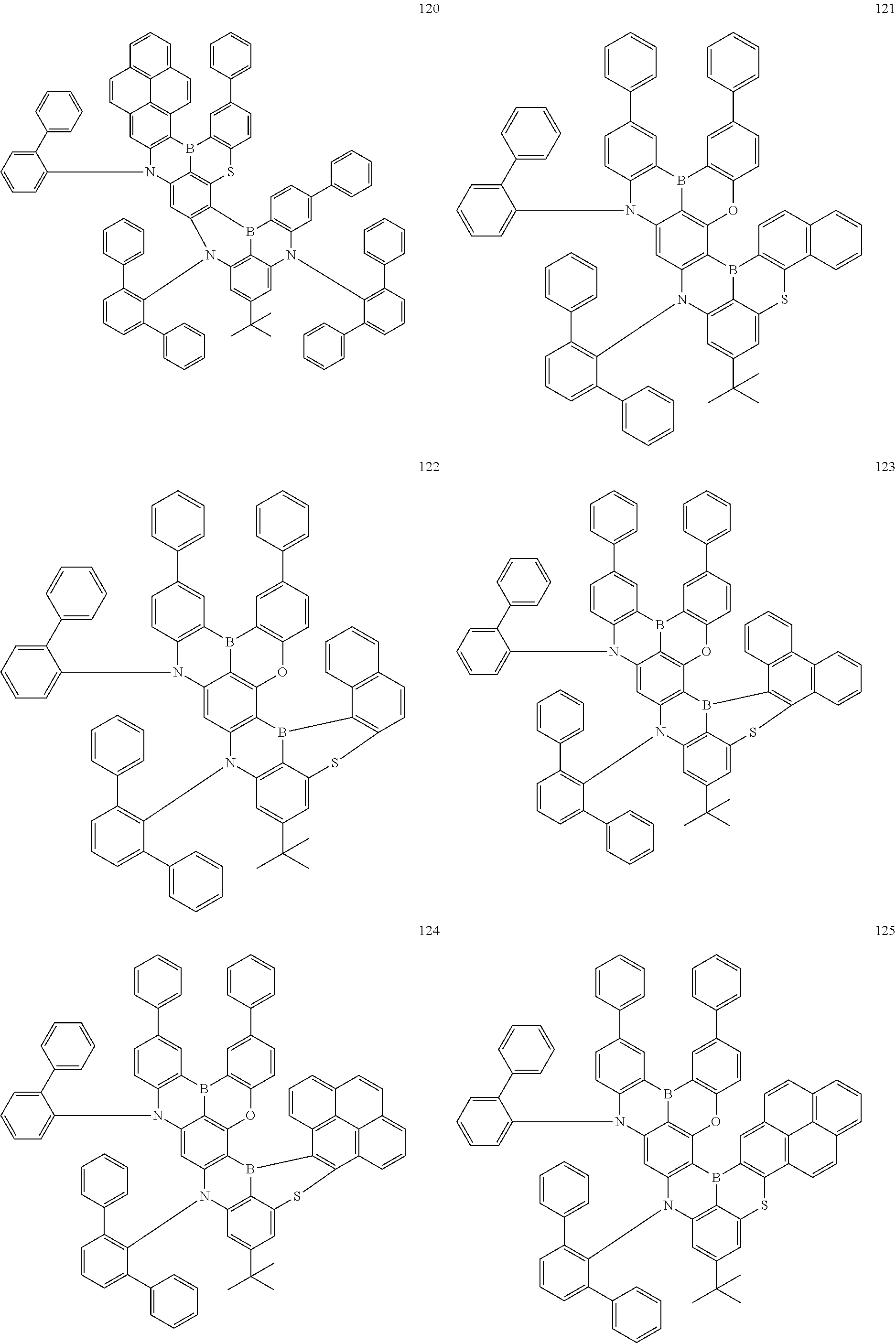

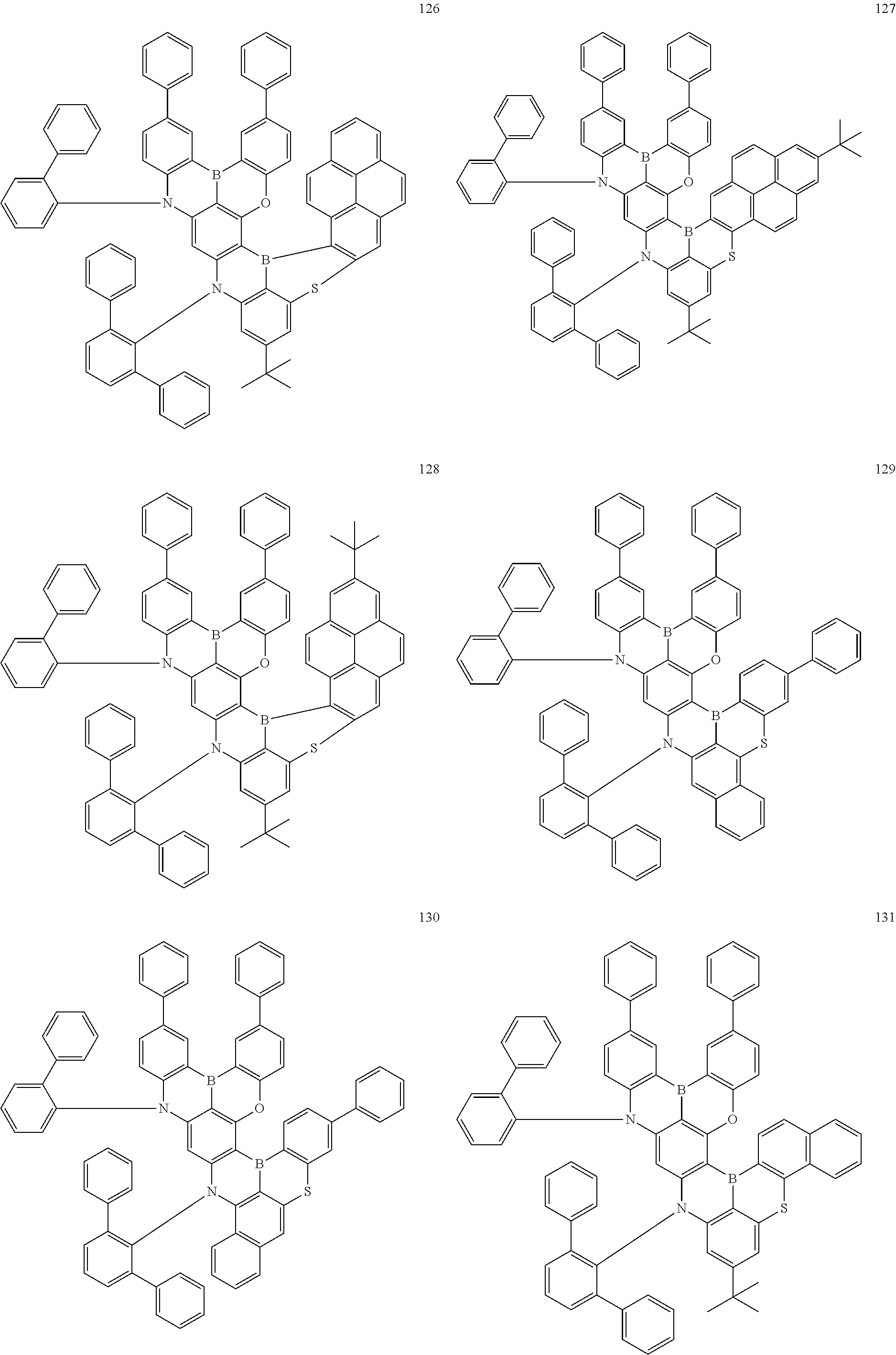

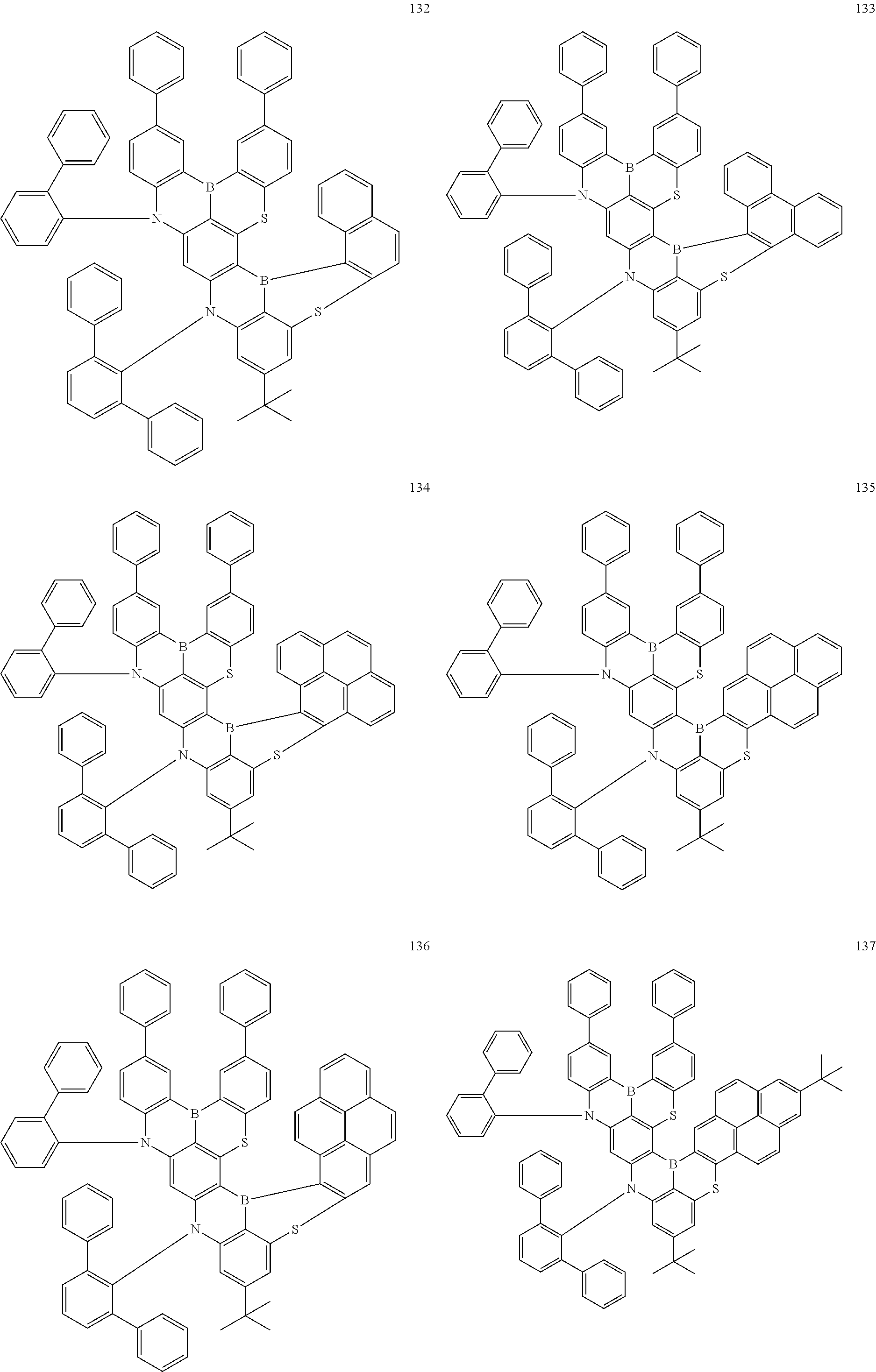

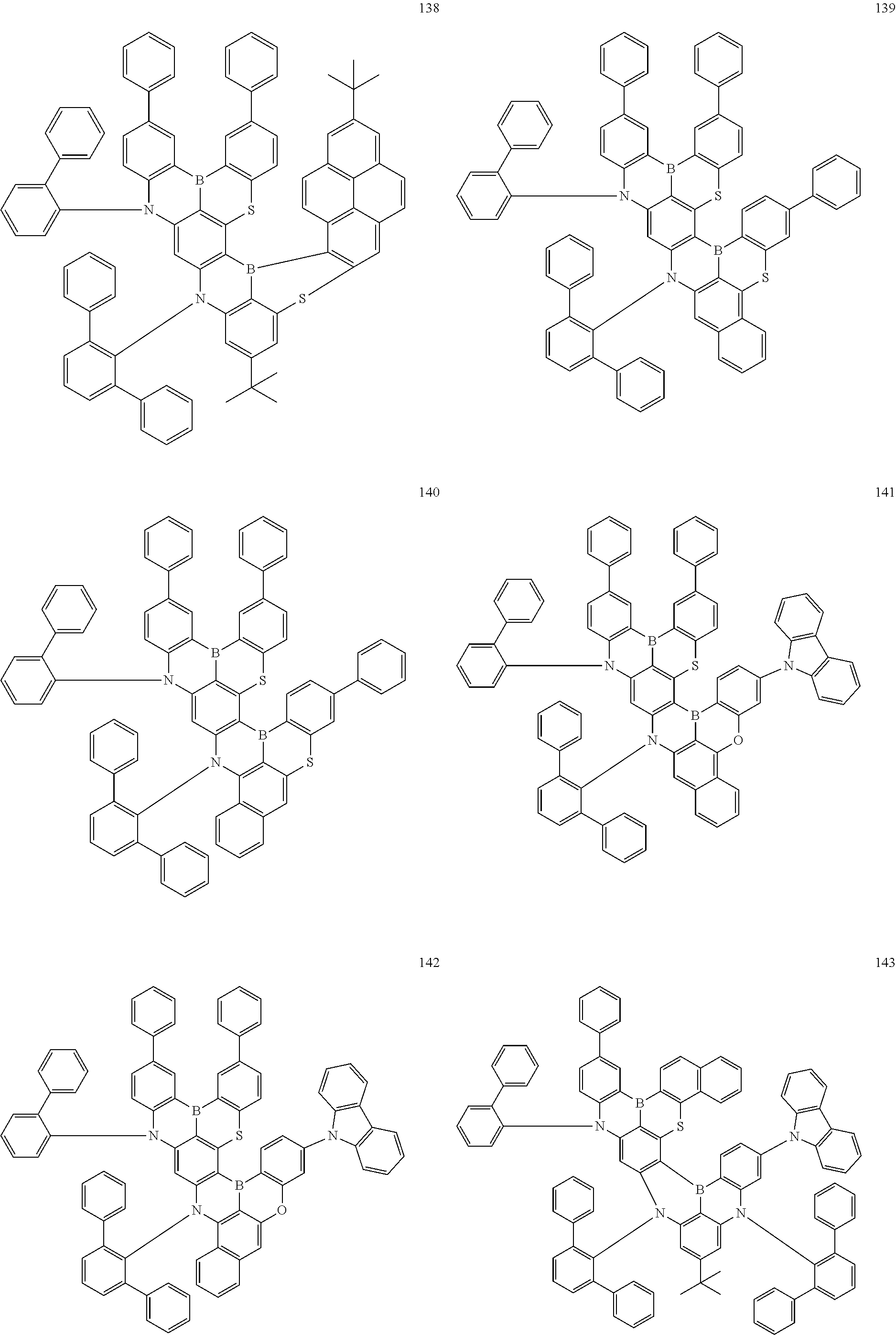

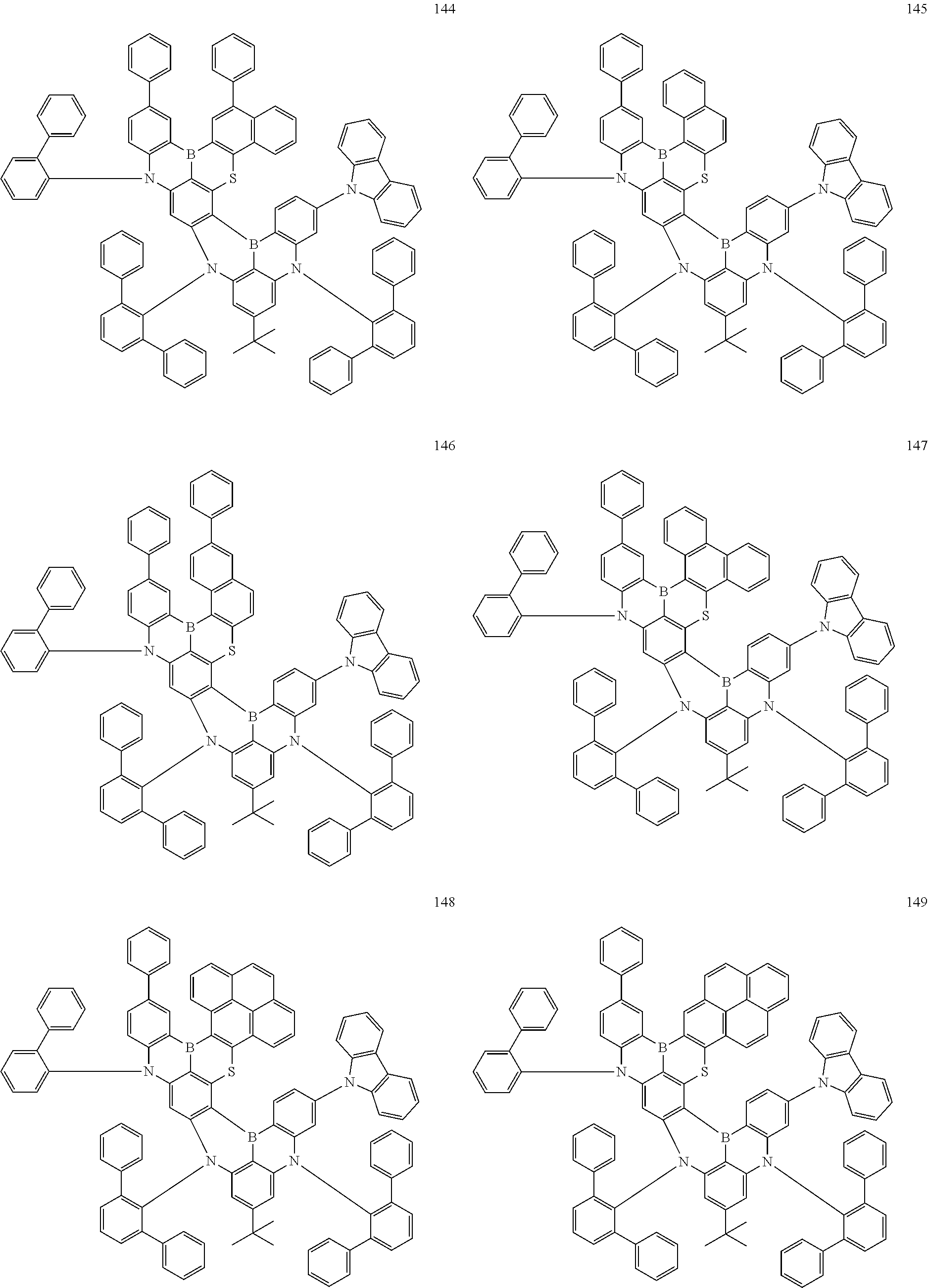

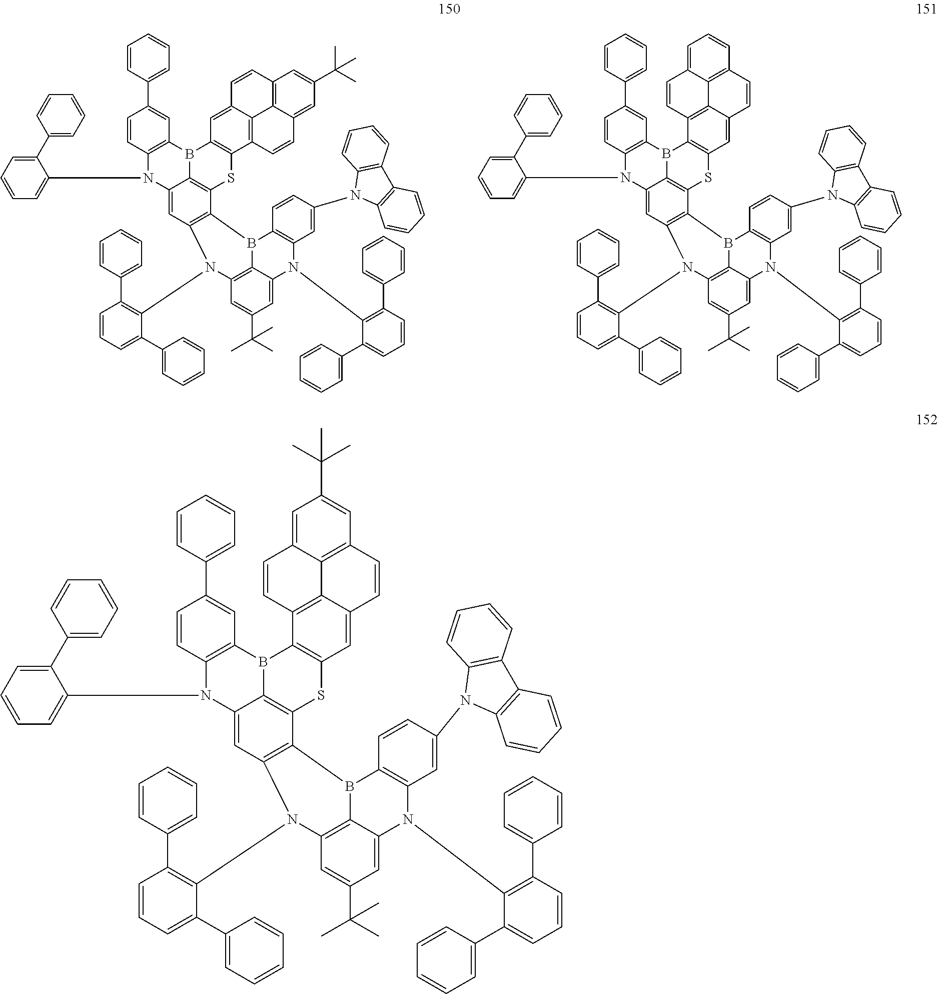

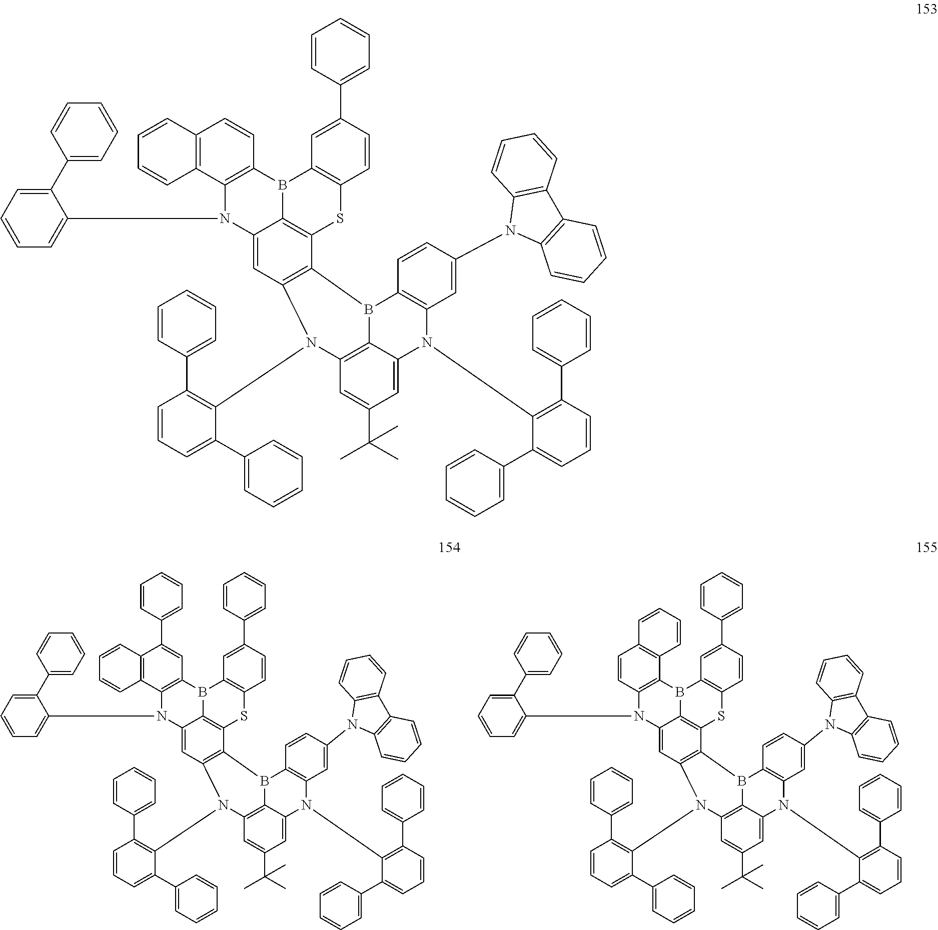

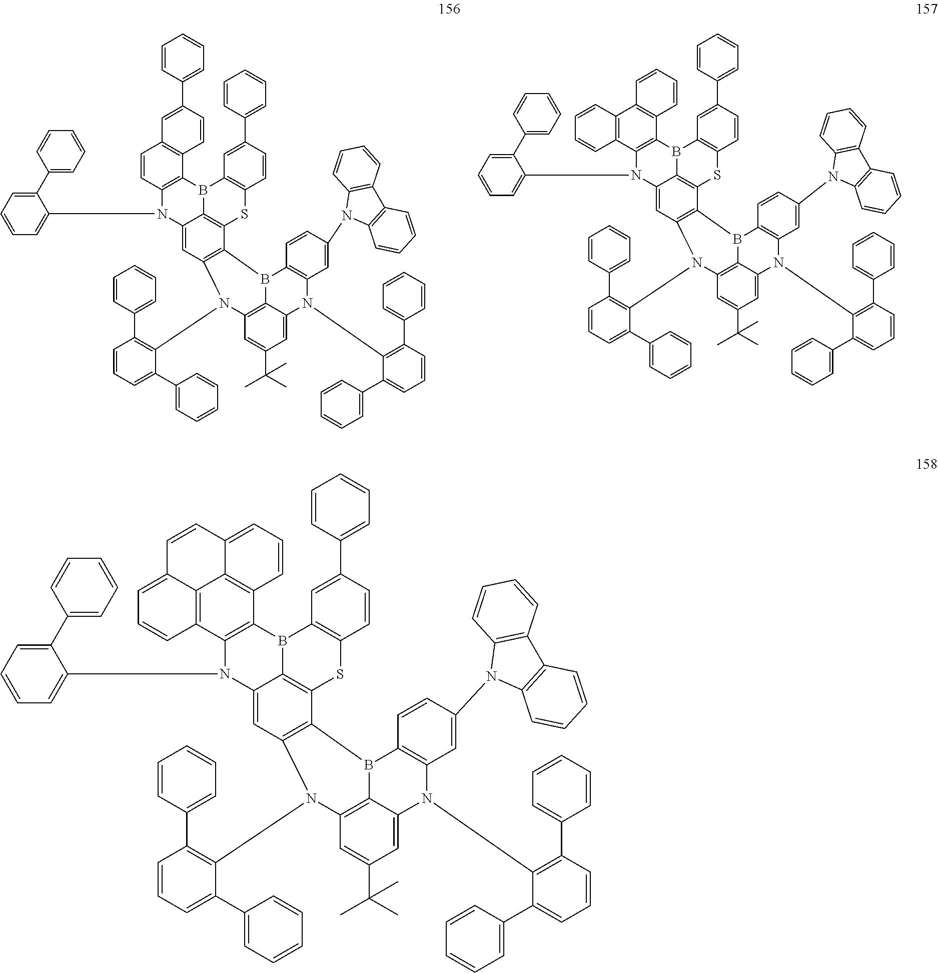

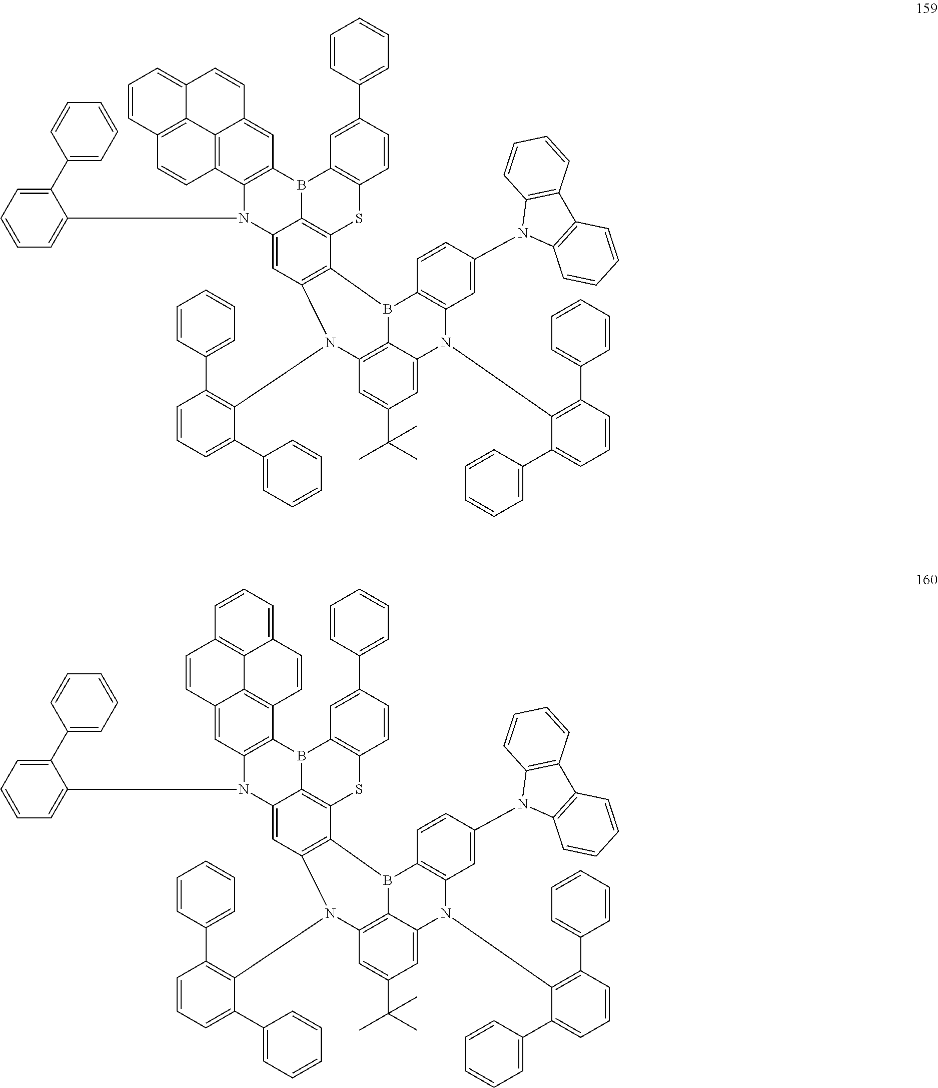 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Sc1ccc(-c2ccccc2)cc1B5c1cc2ccc3cccc5ccc(c1N4c1ccccc1-c1ccccc1)c2c35 ; CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Sc1ccc(-c2ccccc2)cc1B5c1c(cc2ccc3cccc5ccc1c2c35)N4c1ccccc1-c1ccccc1]

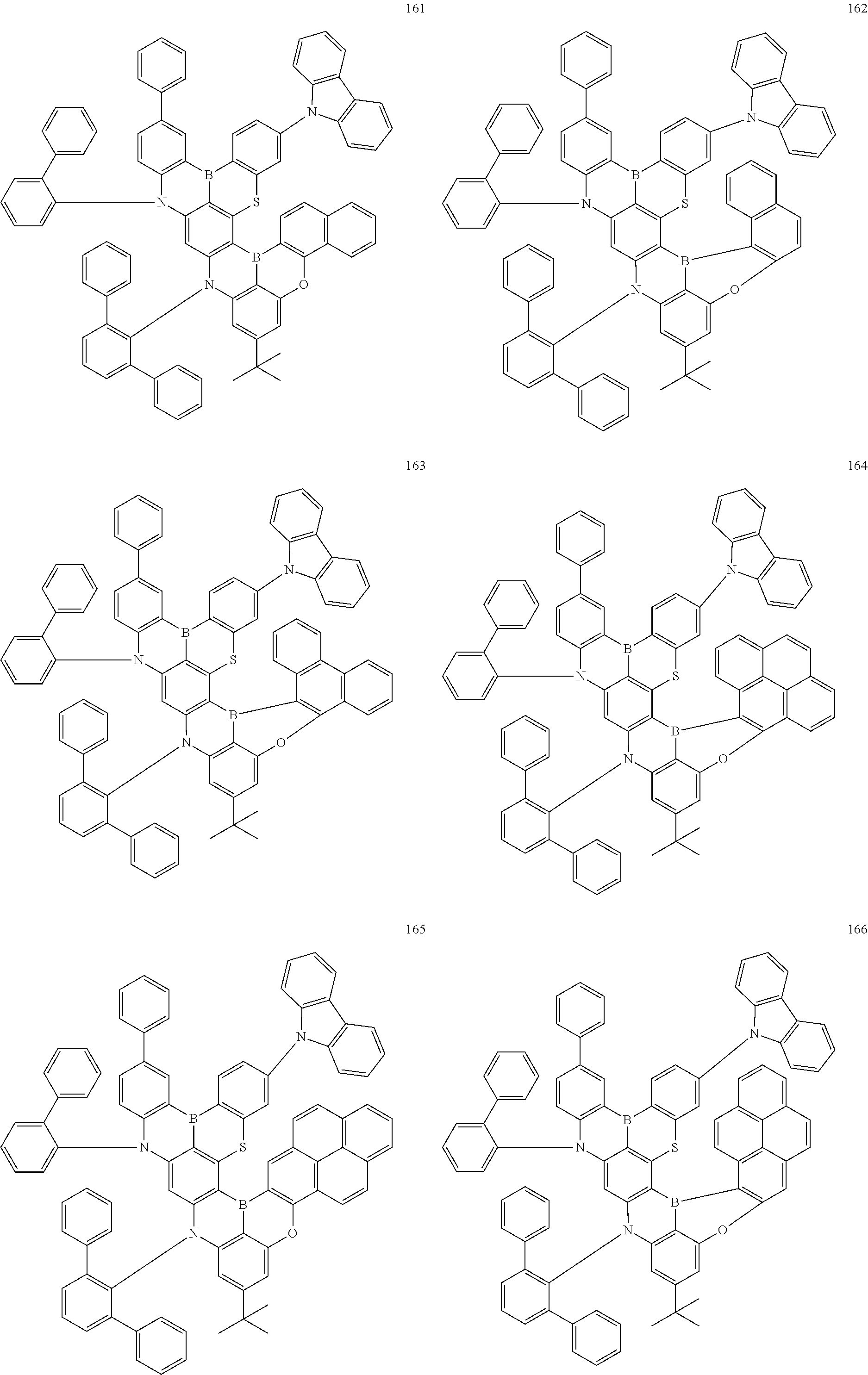

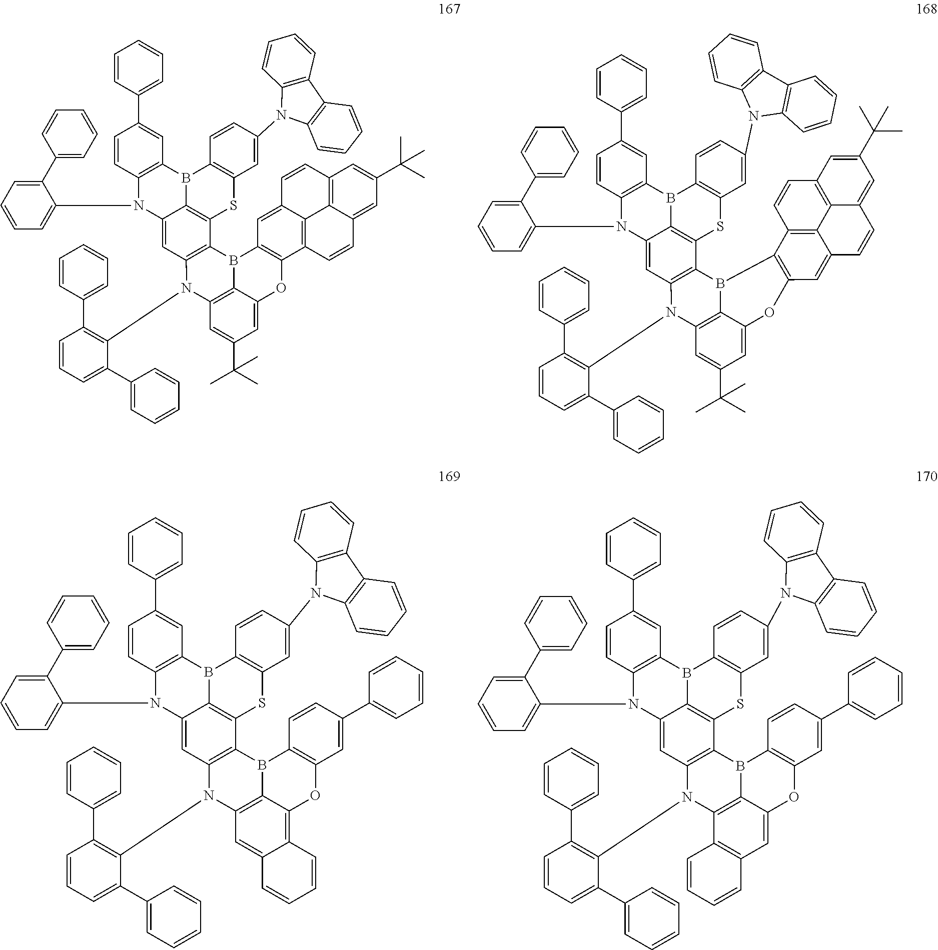

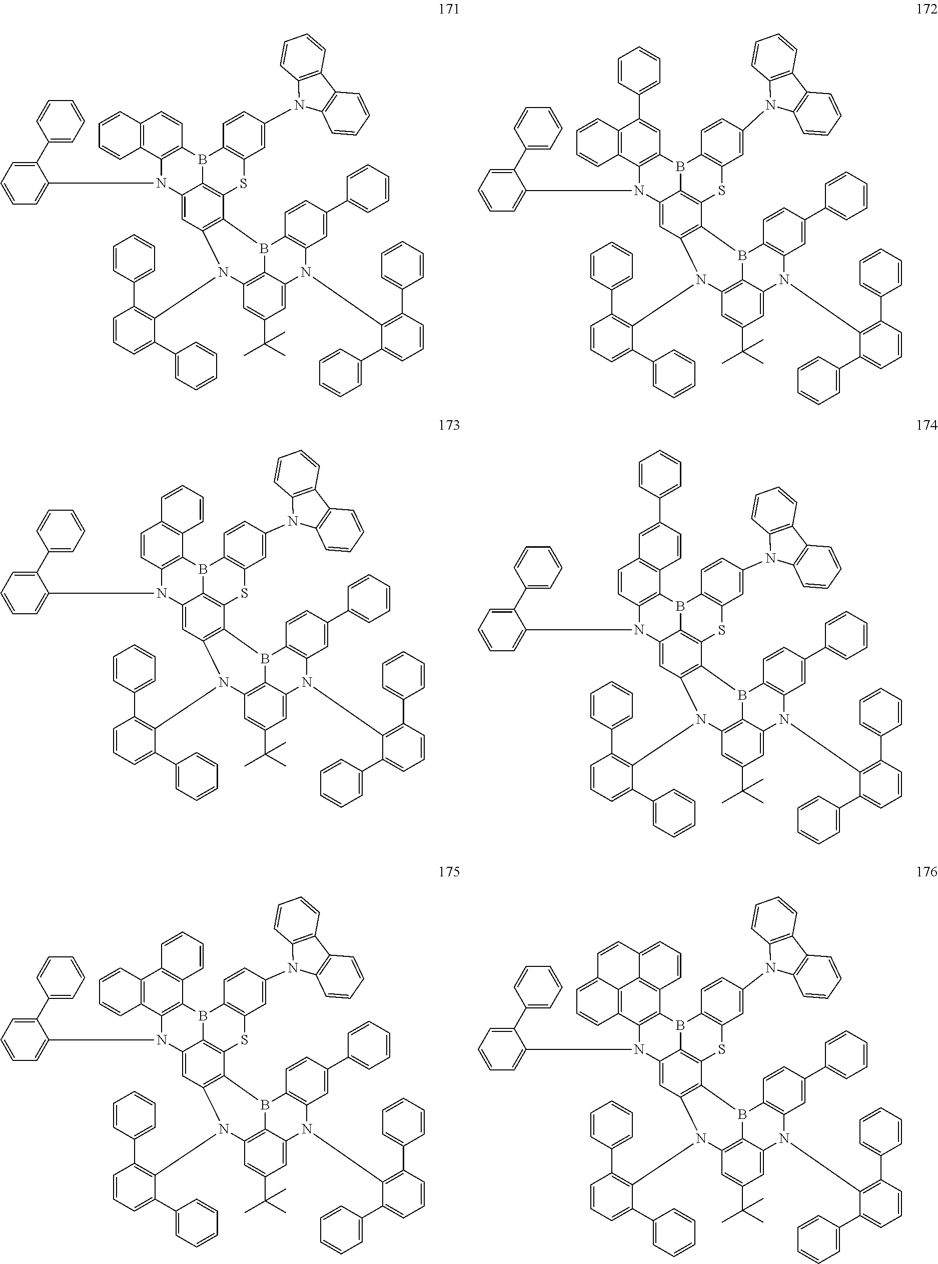

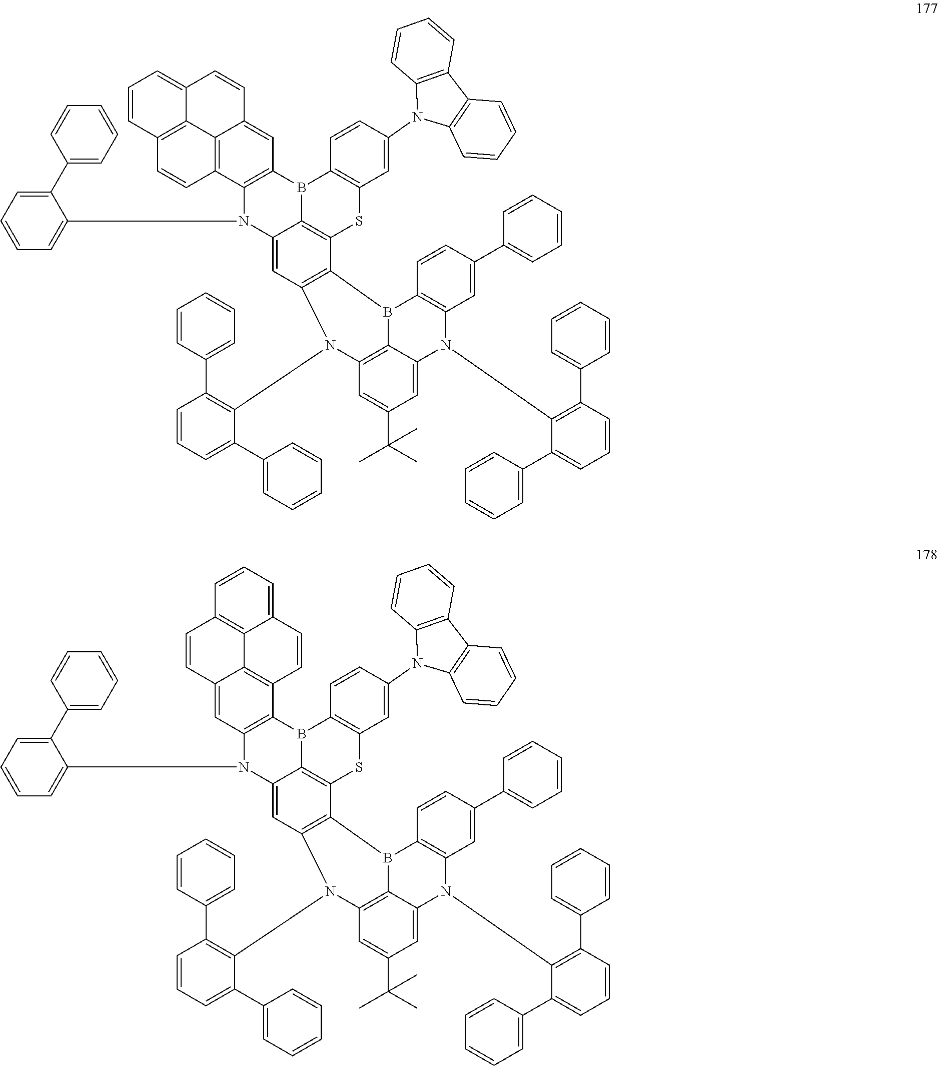 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1cc(-n2c3ccccc3c3ccccc32)ccc1B5c1cc2ccc3cccc5ccc(c1N4c1ccccc1-c1ccccc1)c2c35 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1cc(-n2c3ccccc3c3ccccc32)ccc1B5c1c(cc2ccc3cccc5ccc1c2c35)N4c1ccccc1-c1ccccc1]

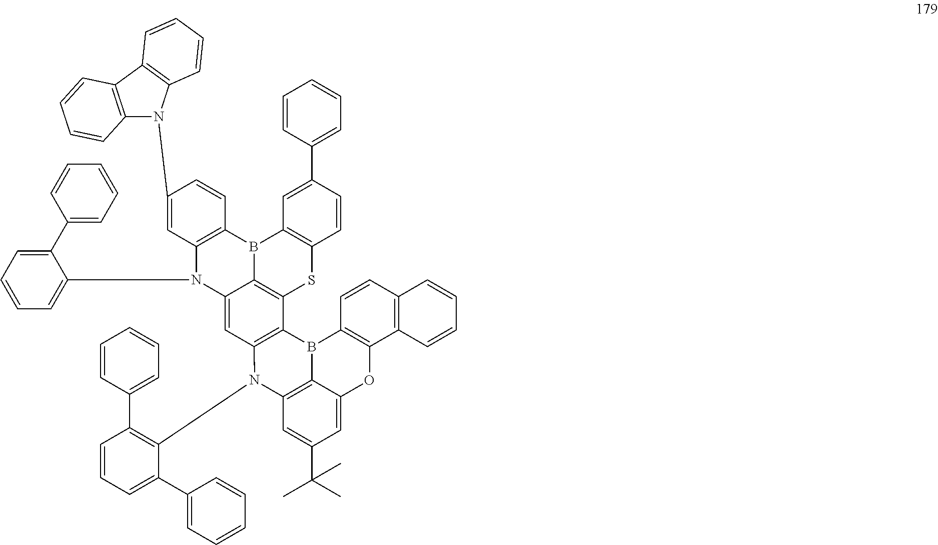 [SMILES: CC(C)(C)c1cc2c3c(c1)N(c1c(-c4ccccc4)cccc1-c1ccccc1)c1cc4c5c(c1B3c1ccc3ccccc3c1O2)Sc1ccc(-c2ccccc2)cc1B5c1ccc(-n2c3ccccc3c3ccccc32)cc1N4c1ccccc1-c1ccccc1]

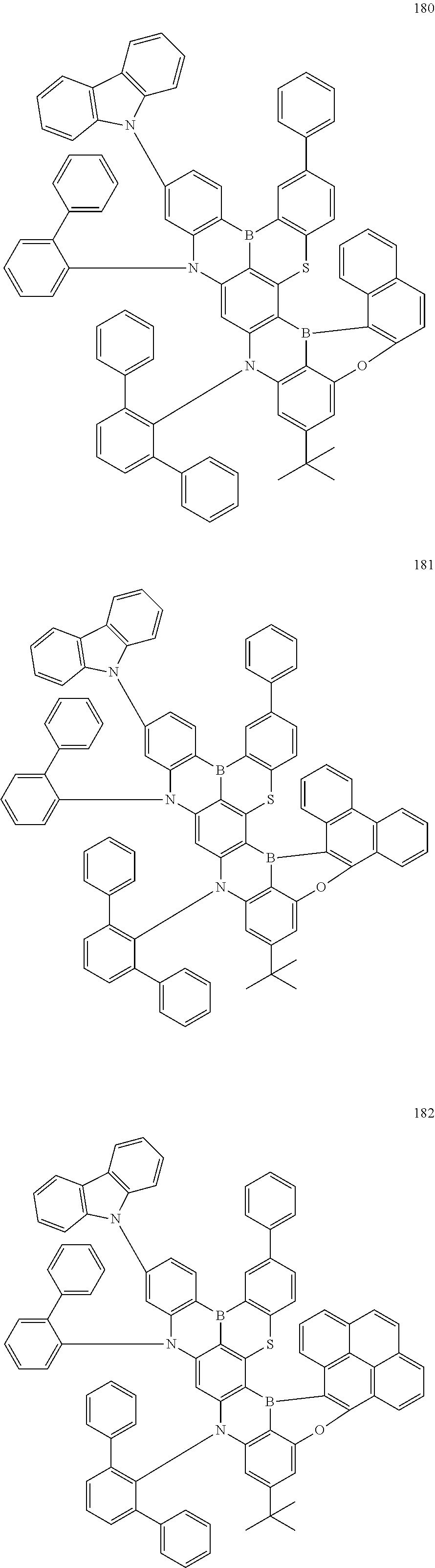 [SMILES: CC(C)(C)c1cc2c3c(c1)N(c1c(-c4ccccc4)cccc1-c1ccccc1)c1cc4c5c(c1B3c1c(ccc3ccccc13)O2)Sc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Sc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)O2)Sc1ccc(-c2ccccc2)cc1B5c1ccc(-n2c3ccccc3c3ccccc32)cc1N4c1ccccc1-c1ccccc1]

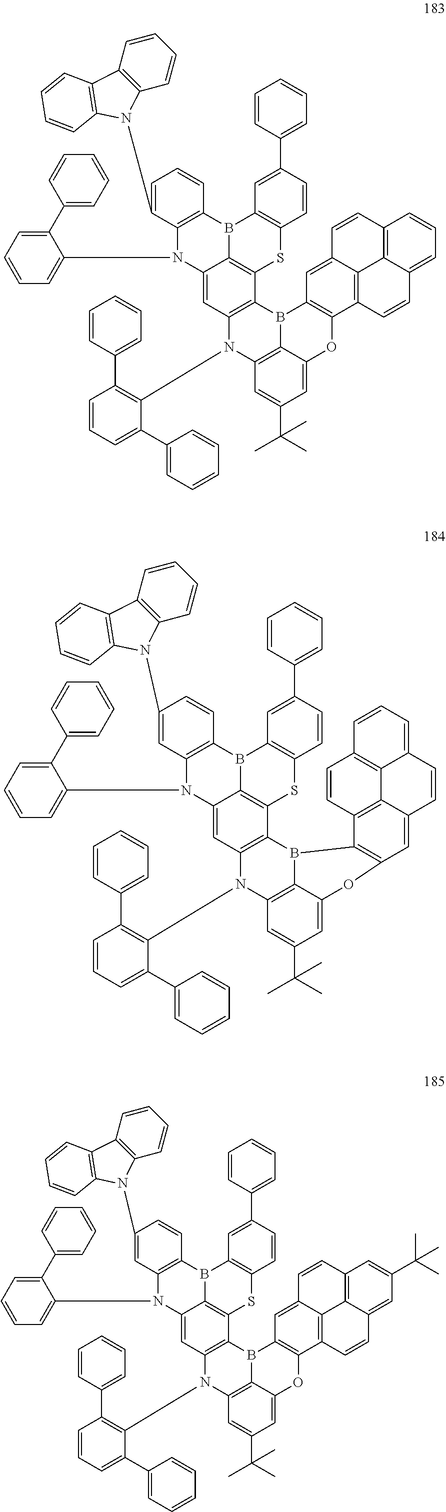

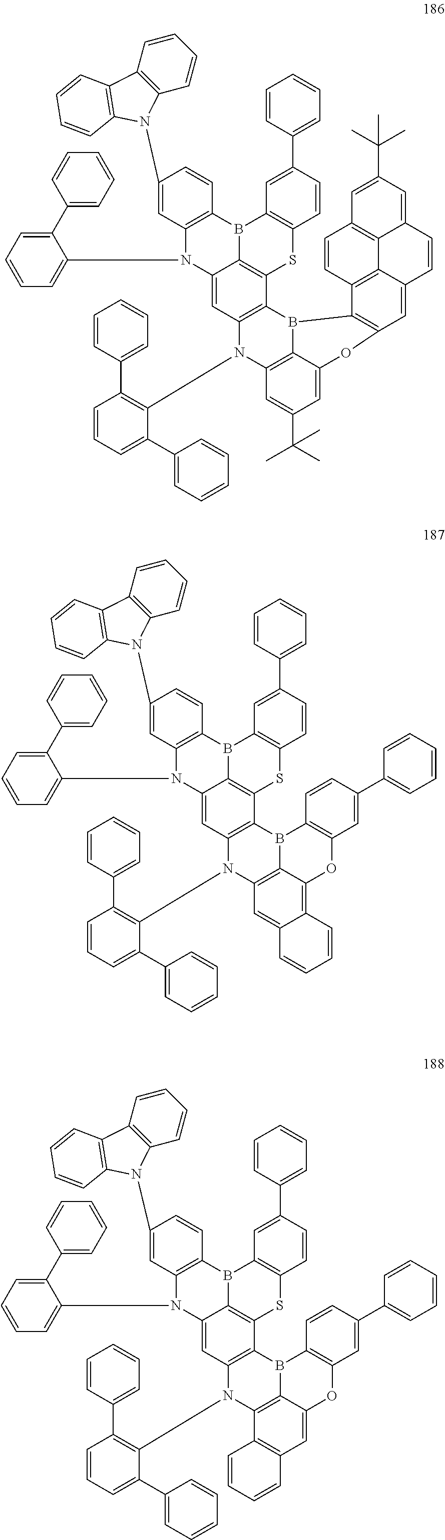 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Sc1ccc(-c2ccccc2)cc1B5c1ccc(-n2c3ccccc3c3ccccc32)cc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Sc2ccc(-c3ccccc3)cc2B6c2ccc(-n3c4ccccc4c4ccccc43)cc2N5c2ccccc2-c2ccccc2)cc1 ; c1ccc(-c2ccc3c(c2)Oc2cc4ccccc4c4c2B3c2c(cc3c5c2Sc2ccc(-c6ccccc6)cc2B5c2ccc(-n5c6ccccc6c6ccccc65)cc2N3c2ccccc2-c2ccccc2)N4c2c(-c3ccccc3)cccc2-c2ccccc2)cc1]

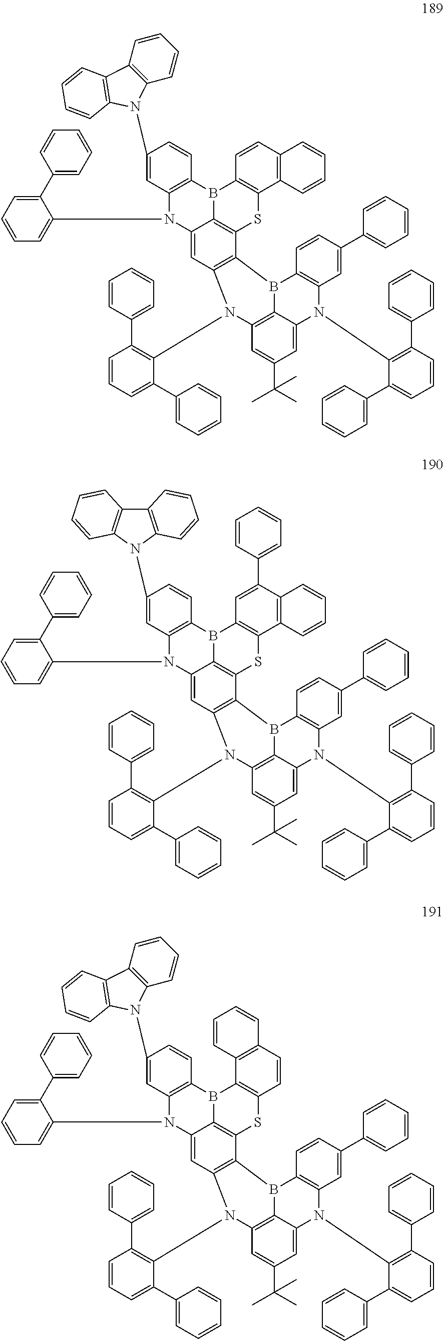

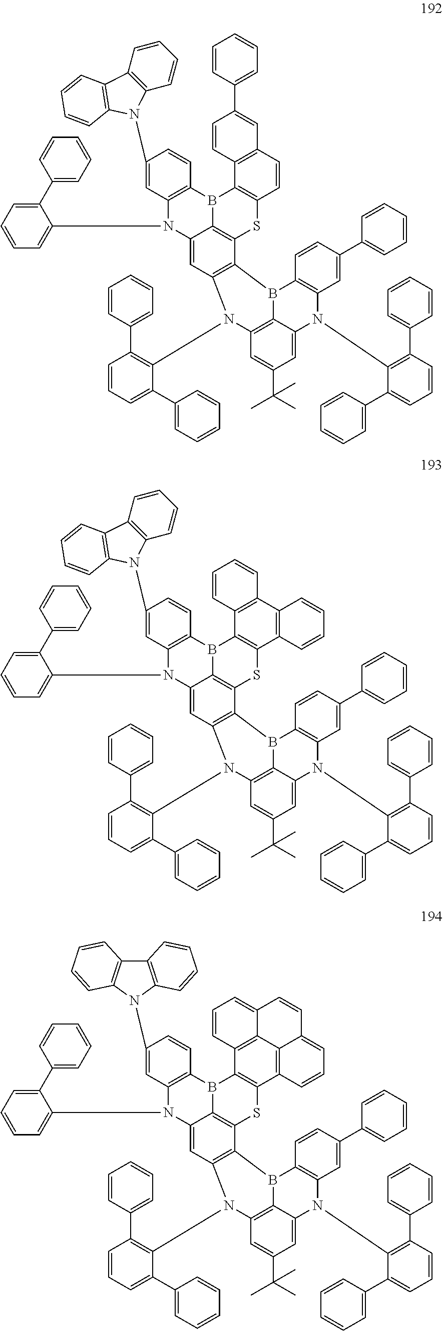

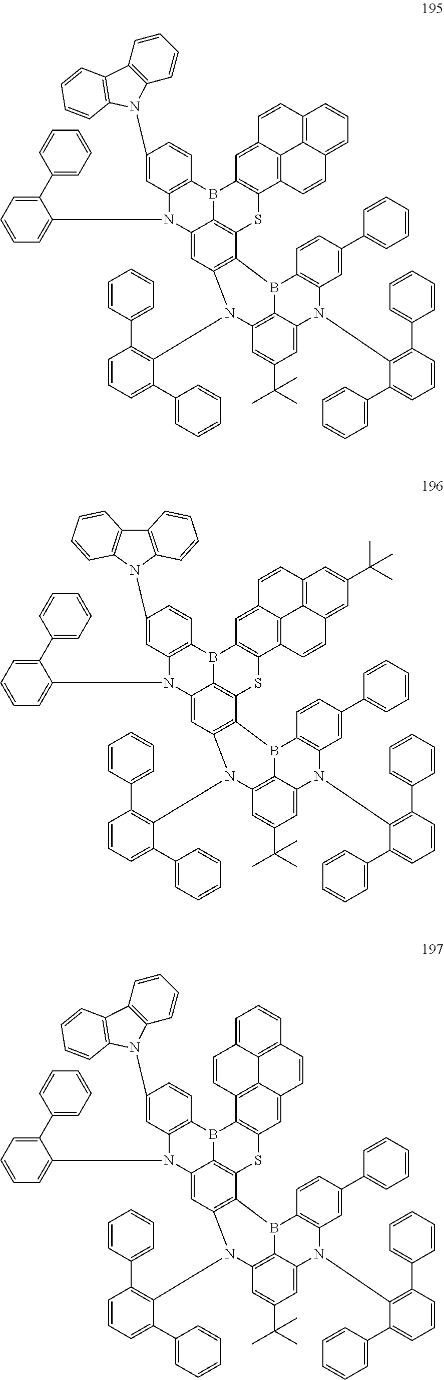

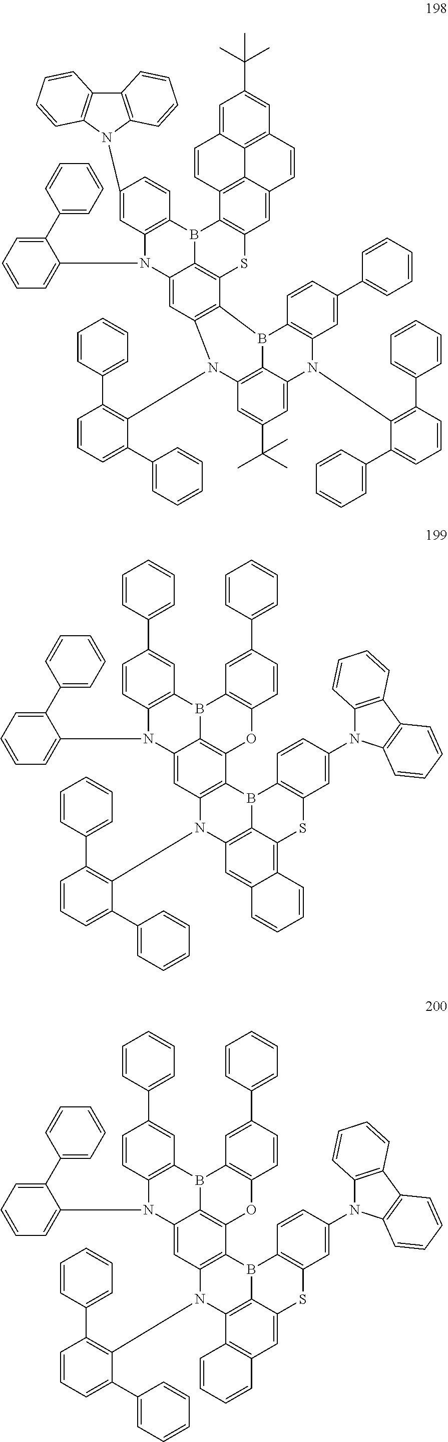

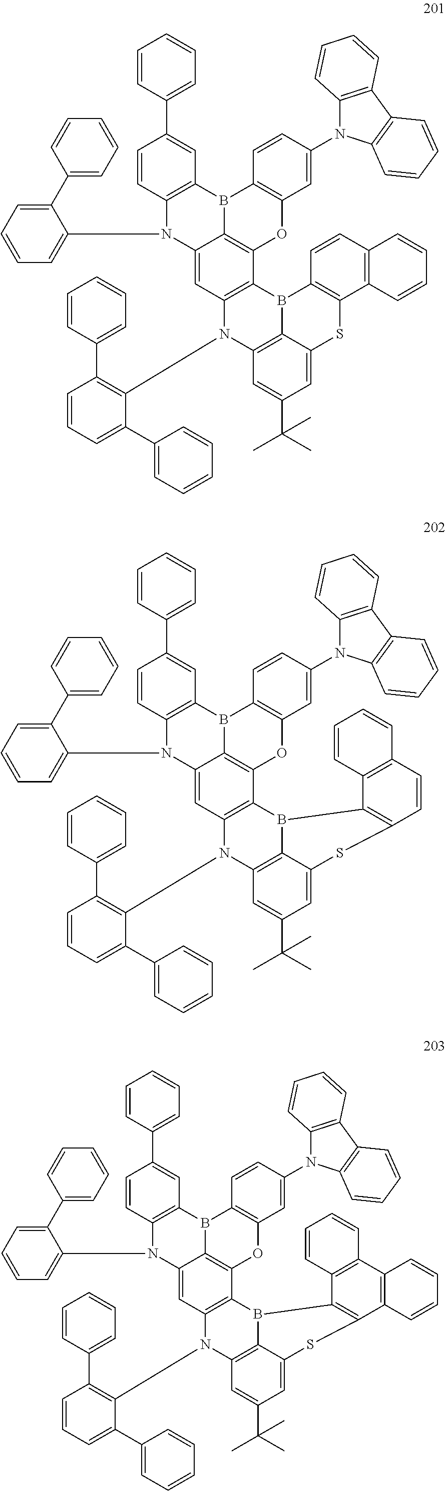 [SMILES: CC(C)(C)c1cc2c3c(c1)N(c1c(-c4ccccc4)cccc1-c1ccccc1)c1cc4c5c(c1B3c1ccc3ccccc3c1S2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)S2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)S2)Oc1cc(-n2c3ccccc3c3ccccc32)ccc1B5c1cc(-c2ccccc2)ccc1N4c1ccccc1-c1ccccc1]

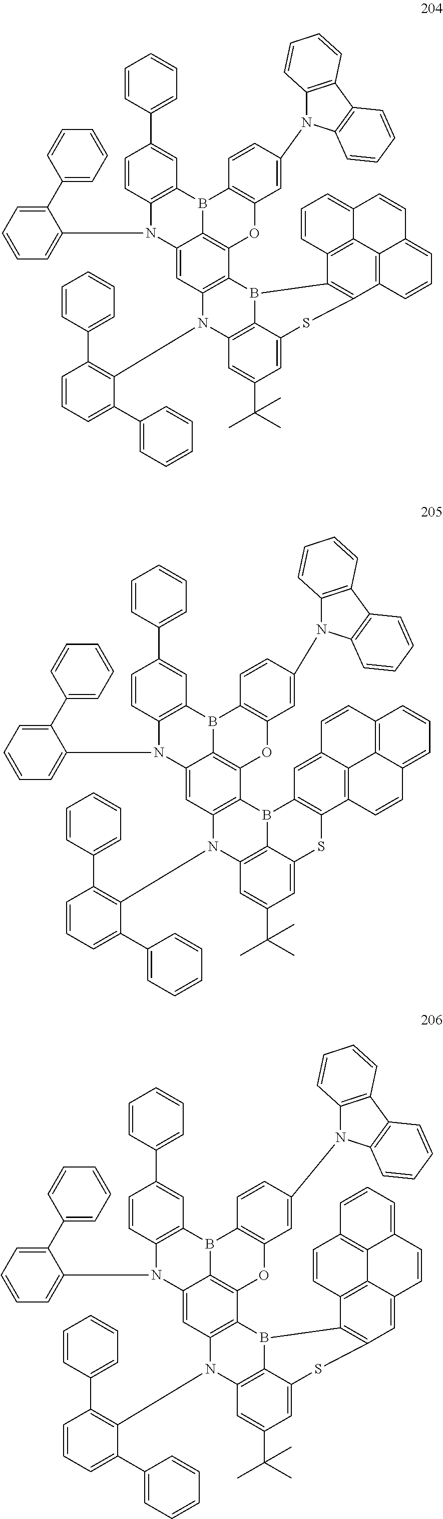 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)S2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1S2)c3c67)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)S2)Oc1cc(-n2c3ccccc3c3ccccc32)ccc1B5c1cc(-c2ccccc2)ccc1N4c1ccccc1-c1ccccc1]

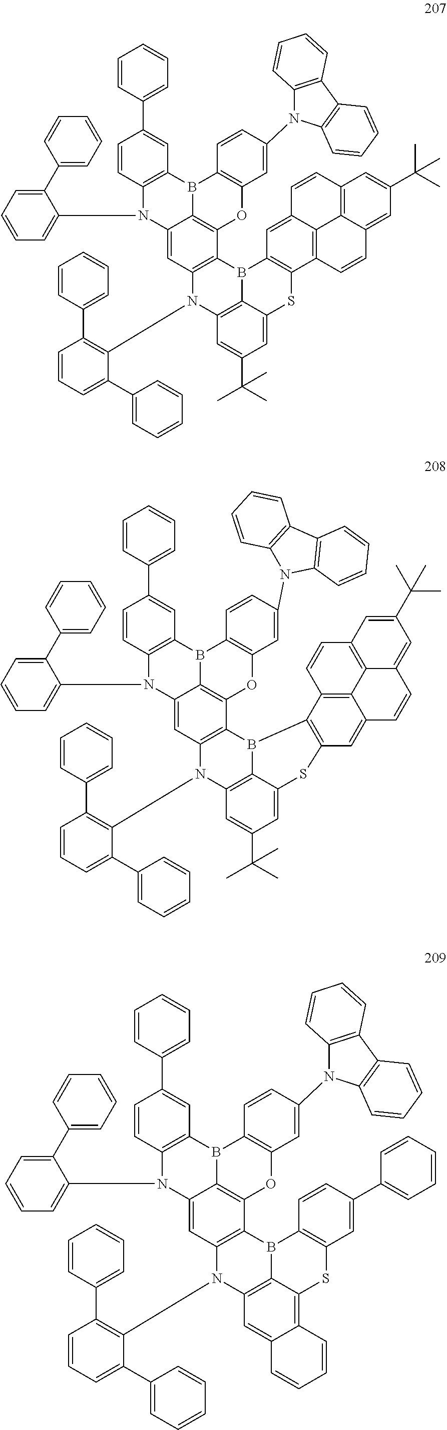

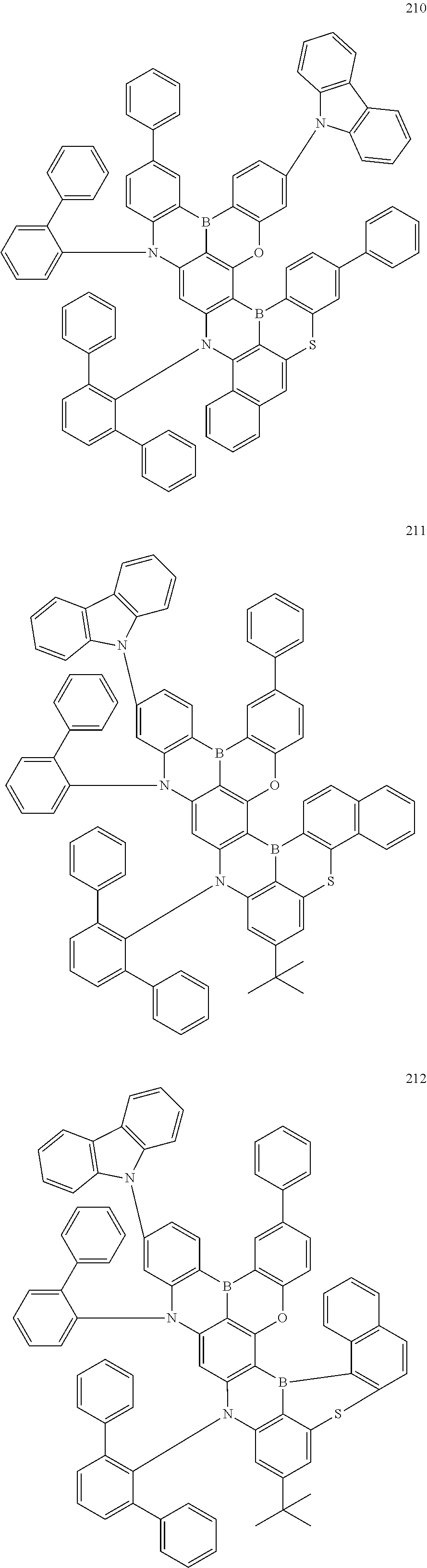 [SMILES: c1ccc(-c2ccc3c(c2)Sc2cc4ccccc4c4c2B3c2c(cc3c5c2Oc2cc(-n6c7ccccc7c7ccccc76)ccc2B5c2cc(-c5ccccc5)ccc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc3ccccc3c1S2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)S2)Oc1ccc(-c2ccccc2)cc1B5c1ccc(-n2c3ccccc3c3ccccc32)cc1N4c1ccccc1-c1ccccc1]

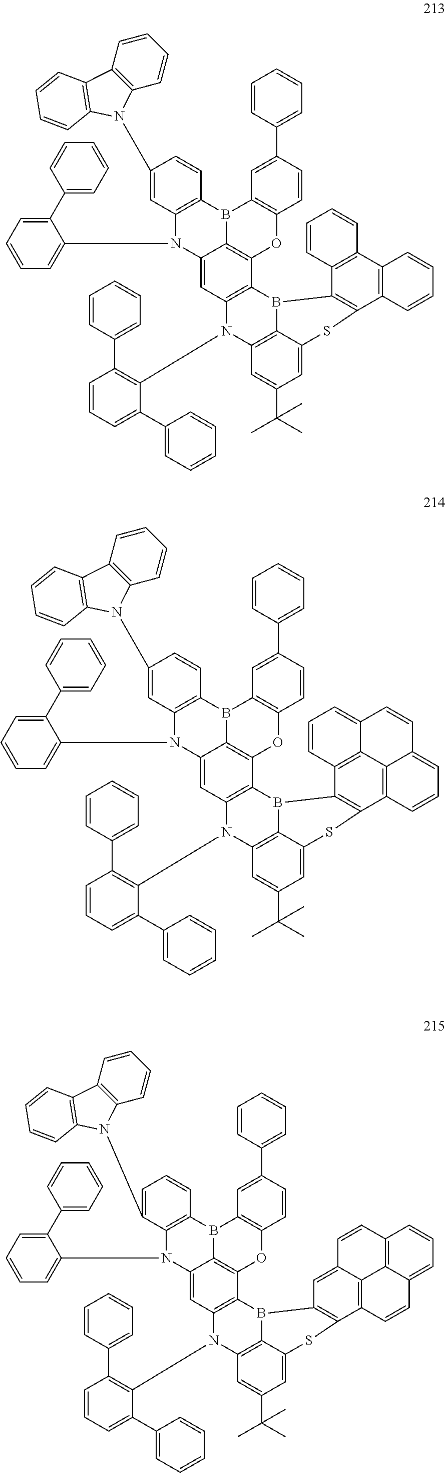 [SMILES: CC(C)(C)c1cc2c3c(c1)N(c1c(-c4ccccc4)cccc1-c1ccccc1)c1cc4c5c(c1B3c1c(c3ccccc3c3ccccc13)S2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)S2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1S2)c3c67)Oc1ccc(-c2ccccc2)cc1B5c1cccc(-n2c3ccccc3c3ccccc32)c1N4c1ccccc1-c1ccccc1]

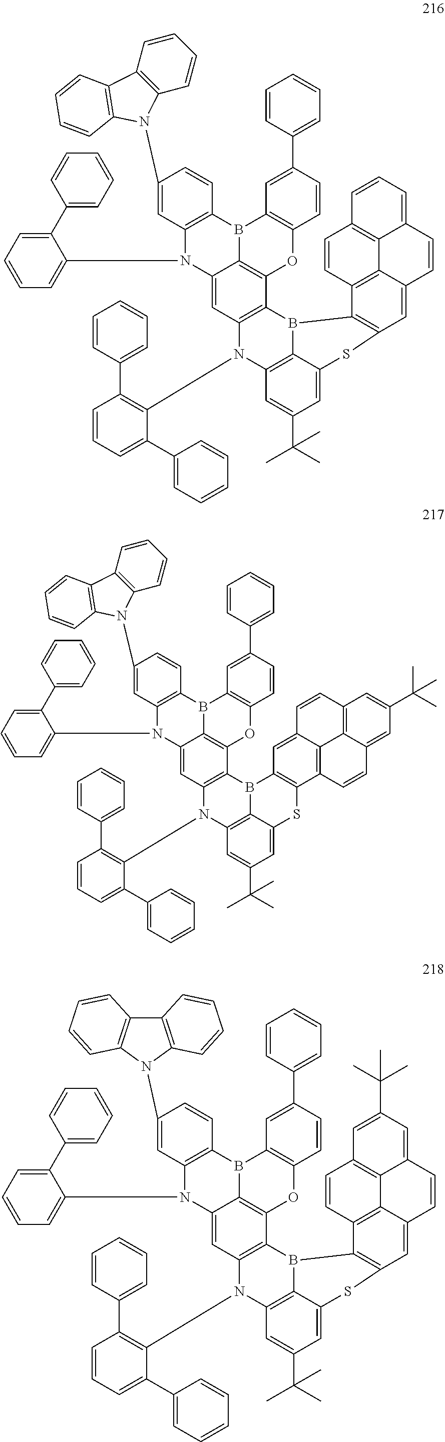

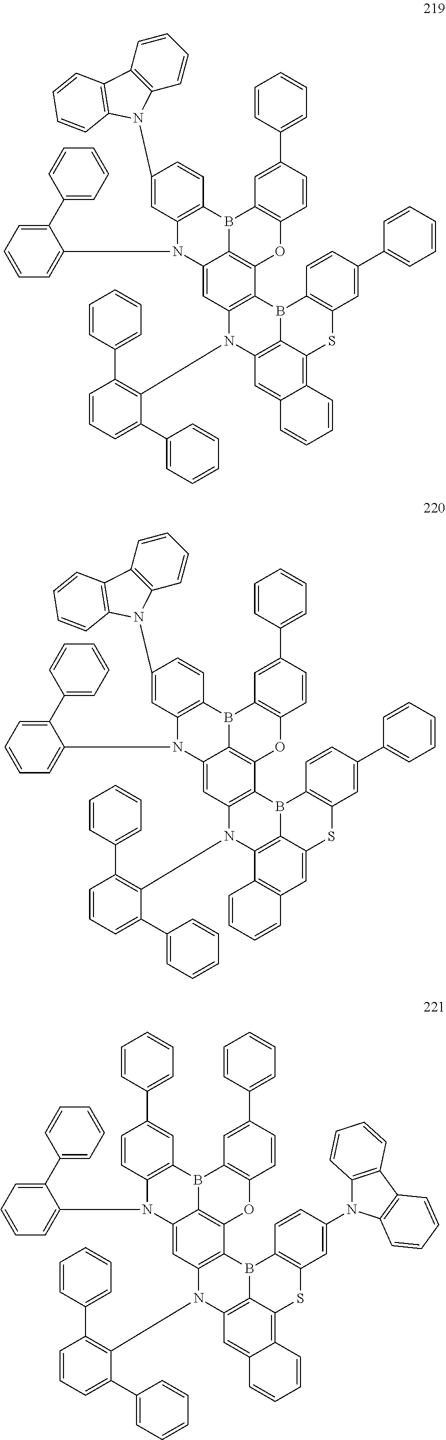 [SMILES: c1ccc(-c2ccc3c(c2)Sc2c4c(cc5ccccc25)N(c2c(-c5ccccc5)cccc2-c2ccccc2)c2cc5c6c(c2B34)Oc2ccc(-c3ccccc3)cc2B6c2ccc(-n3c4ccccc4c4ccccc43)cc2N5c2ccccc2-c2ccccc2)cc1 ; c1ccc(-c2ccc3c(c2)Sc2cc4ccccc4c4c2B3c2c(cc3c5c2Oc2ccc(-c6ccccc6)cc2B5c2ccc(-n5c6ccccc6c6ccccc65)cc2N3c2ccccc2-c2ccccc2)N4c2c(-c3ccccc3)cccc2-c2ccccc2)cc1 ; c1ccc(-c2ccc3c(c2)B2c4cc(-c5ccccc5)ccc4N(c4ccccc4-c4ccccc4)c4cc5c(c(c42)O3)B2c3ccc(-n4c6ccccc6c6ccccc64)cc3Sc3c2c(cc2ccccc32)N5c2c(-c3ccccc3)cccc2-c2ccccc2)cc1]

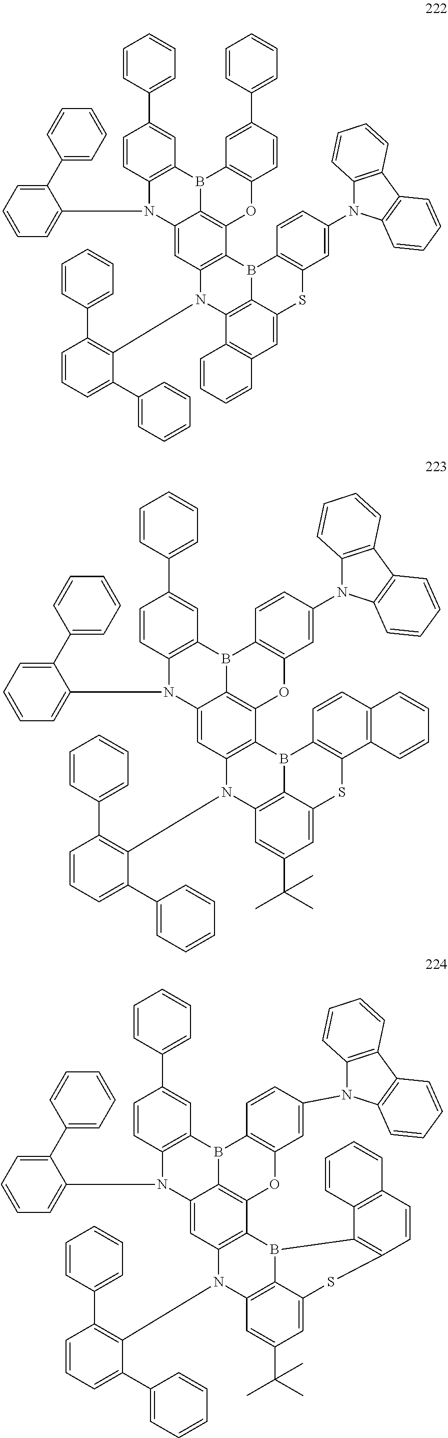

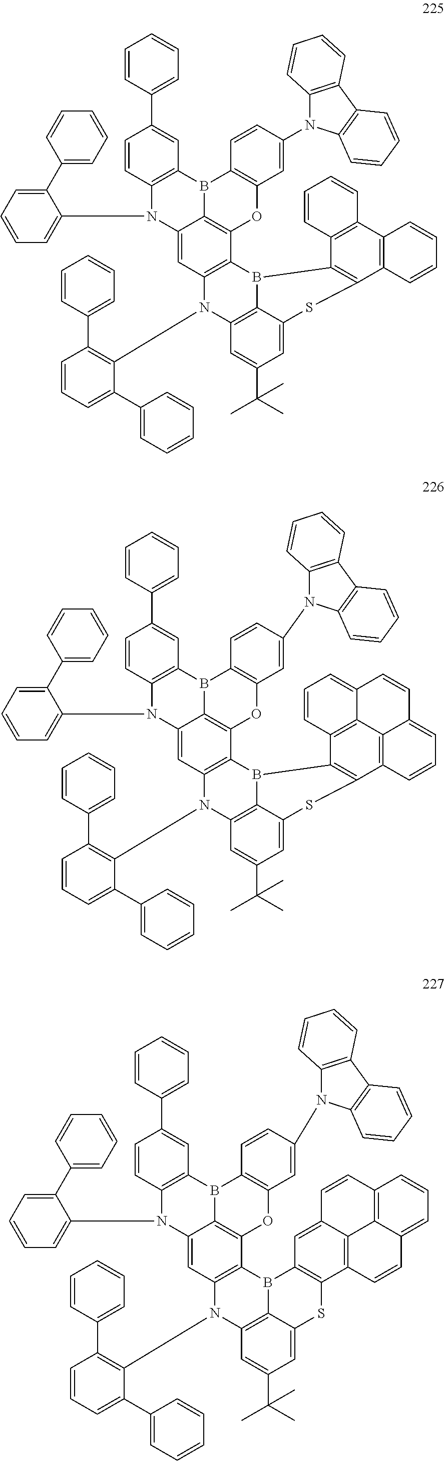 [SMILES: CC(C)(C)c1cc2c3c(c1)N(c1c(-c4ccccc4)cccc1-c1ccccc1)c1cc4c5c(c1B3c1c(c3ccccc3c3ccccc13)S2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)S2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1S2)c3c67)Oc1cc(-n2c3ccccc3c3ccccc32)ccc1B5c1cc(-c2ccccc2)ccc1N4c1ccccc1-c1ccccc1]

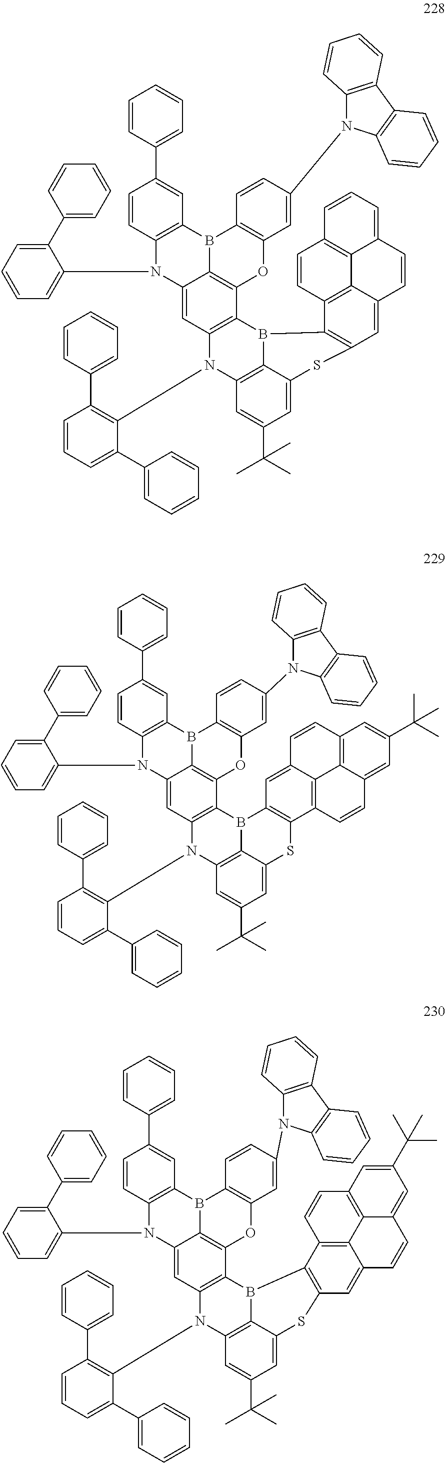

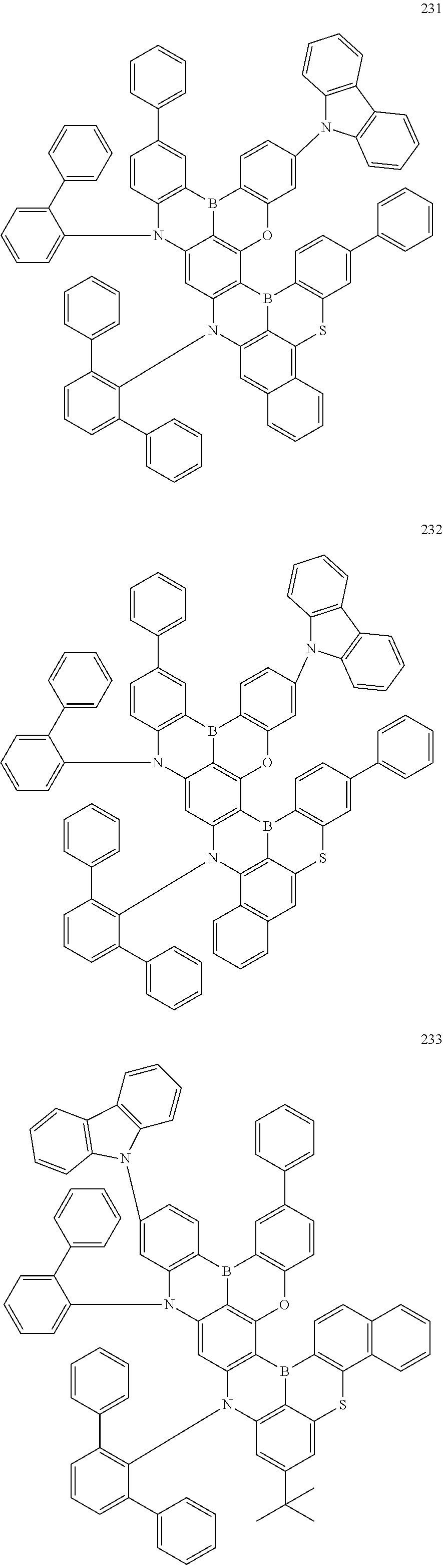 [SMILES: c1ccc(-c2ccc3c(c2)Sc2c4c(cc5ccccc25)N(c2c(-c5ccccc5)cccc2-c2ccccc2)c2cc5c6c(c2B34)Oc2cc(-n3c4ccccc4c4ccccc43)ccc2B6c2cc(-c3ccccc3)ccc2N5c2ccccc2-c2ccccc2)cc1 ; c1ccc(-c2ccc3c(c2)Sc2cc4ccccc4c4c2B3c2c(cc3c5c2Oc2cc(-n6c7ccccc7c7ccccc76)ccc2B5c2cc(-c5ccccc5)ccc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc3ccccc3c1S2)Oc1ccc(-c2ccccc2)cc1B5c1ccc(-n2c3ccccc3c3ccccc32)cc1N4c1ccccc1-c1ccccc1]

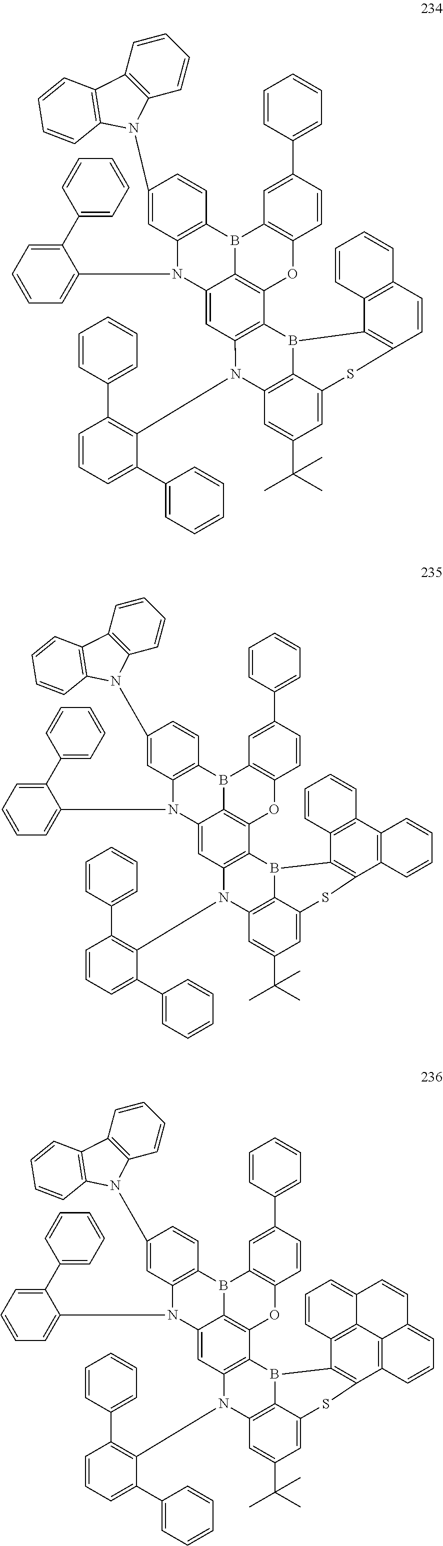 [SMILES: CC(C)(C)c1cc2c3c(c1)N(c1c(-c4ccccc4)cccc1-c1ccccc1)c1cc4c5c(c1B3c1c(ccc3ccccc13)S2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)S2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)S2)Oc1ccc(-c2ccccc2)cc1B5c1ccc(-n2c3ccccc3c3ccccc32)cc1N4c1ccccc1-c1ccccc1]

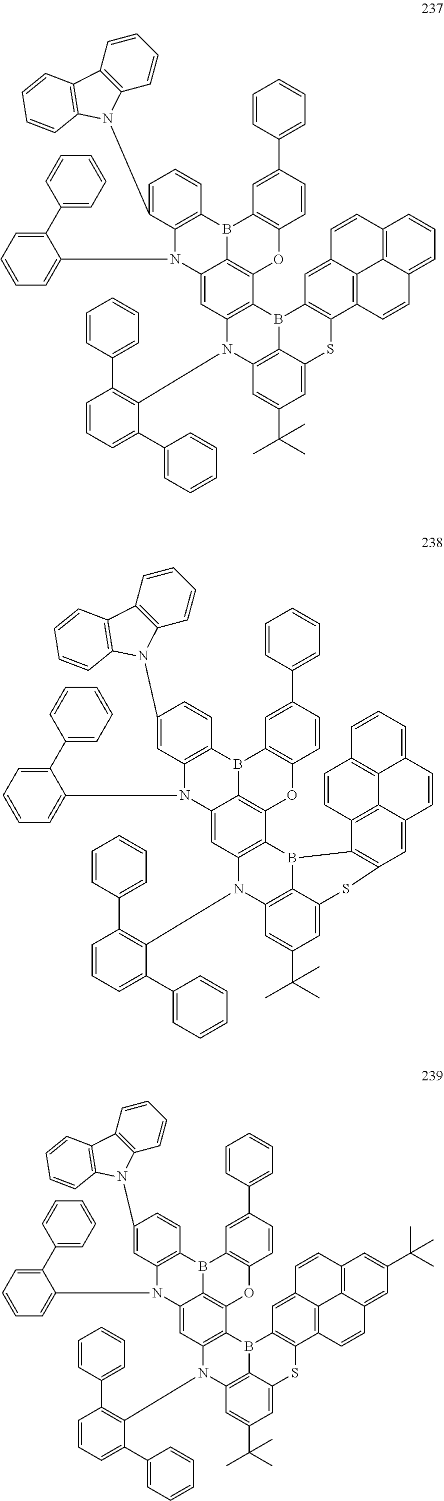

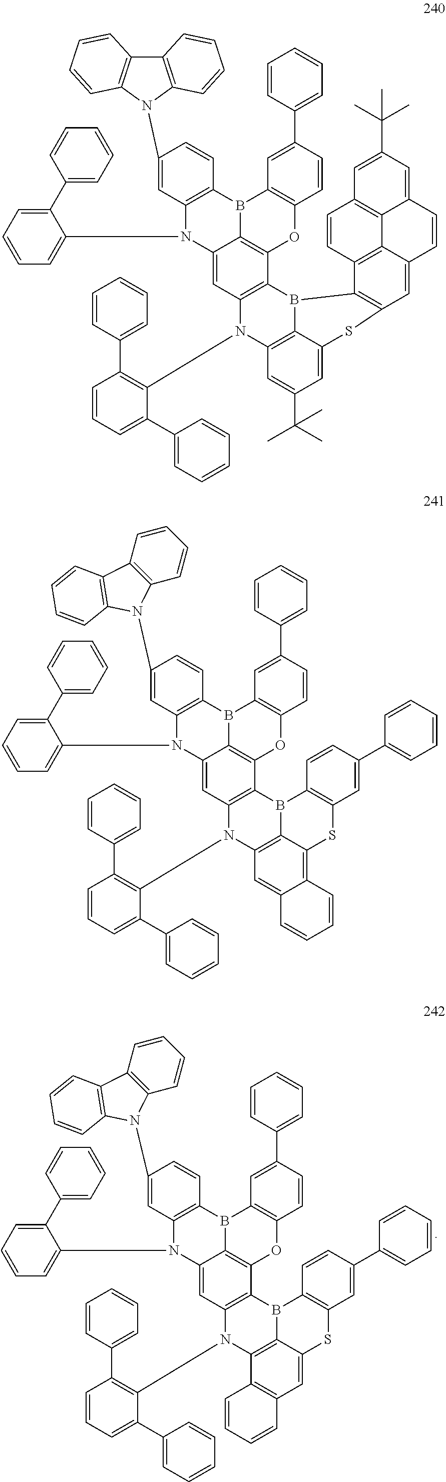 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)S2)Oc1ccc(-c2ccccc2)cc1B5c1ccc(-n2c3ccccc3c3ccccc32)cc1N4c1ccccc1-c1ccccc1 ; c1ccc(-c2ccc3c(c2)Sc2c4c(cc5ccccc25)N(c2c(-c5ccccc5)cccc2-c2ccccc2)c2cc5c6c(c2B34)Oc2ccc(-c3ccccc3)cc2B6c2ccc(-n3c4ccccc4c4ccccc43)cc2N5c2ccccc2-c2ccccc2)cc1 ; c1ccc(-c2ccc3c(c2)Sc2cc4ccccc4c4c2B3c2c(cc3c5c2Oc2ccc(-c6ccccc6)cc2B5c2ccc(-n5c6ccccc6c6ccccc65)cc2N3c2ccccc2-c2ccccc2)N4c2c(-c3ccccc3)cccc2-c2ccccc2)cc1]

In the embodiment compounds presented in Compound Group 1, “D” refers to deuterium.

A fused polycyclic compound generally included in the emission layer of an organic electroluminescent element has high planarity and thus has strong intermolecular interaction, which deteriorates the stability of fused polycyclic compound, and if (e.g., when) the fused polycyclic compound has a structure in which two oxygen atoms are concurrently (e.g., simultaneously) linked to the boron atom, there is a limitation and issue in that the fused polycyclic compound is easily decomposed in a post-synthesis purification process.

The fused polycyclic compound of one or more embodiments includes the core including the first fused ring structure and the second fused ring structure described above, thereby achieving high efficiency and long service life. For example, there is the effect of improving the stability of a fused polycyclic compound by increasing the steric properties of the fused polycyclic compound by including a first fused ring structure including a boron atom, one nitrogen atom, and one heteroatom instead of a structure in which a boron atom and two oxygen atoms of a fused polycyclic compound included in the emission layer of a general organic electroluminescent element are concurrently (e.g., simultaneously) fused, thereby reducing the intermolecular interaction between fused polycyclic compound molecules. In addition, in the fused polycyclic compound of one or more embodiments, a biphenyl group and/or a terphenyl group substituted at the nitrogen atom are located on different planes, due to steric hindrance, with the first fused ring structure and the second fused ring structure, and thus there is the effect of further enhancing the steric properties of the fused polycyclic compound. Furthermore, the first fused ring structure or the second fused ring structure may include at least one of naphthalene, phenanthrene, or pyrene to lower the lowest triplet excitation energy level (T1) of the fused polycyclic compound, and thus the fused polycyclic compound may exhibit high thermal and chemical stability.

The fused polycyclic compound represented by Formula 1 of one or more embodiments may be a luminescent material having a luminescence center wavelength in a wavelength region of about 430 nm to about 490 nm. For example, the fused polycyclic compound represented by Formula 1 of one or more embodiments may be a blue thermally activated delayed fluorescence (TADF) dopant. However, embodiments of the present disclosure are not limited thereto, if (e.g., when) the fused polycyclic compound of one or more embodiments is used as a luminescent material, the first compound/dopant may be used as a dopant material that emits light in one or more suitable wavelength regions, such as a red emitting dopant or a green emitting dopant.

The emission layer EML in the light emitting element ED of one or more embodiments may be to emit delayed fluorescence. For example, the emission layer EML may be to emit thermally activated delayed fluorescence (TADF).

In one or more embodiments, the emission layer EML of the light emitting element ED may be to emit blue light. For example, the emission layer EML of the light emitting element ED (e.g., organic electroluminescence element ED) of one or more embodiments may be to emit blue light in the wavelength range of about 490 nm or less. However, embodiments of the present disclosure are not limited thereto, and the emission layer EML may be to emit green light or red light.

In one or more embodiments, the fused polycyclic compound of one or more embodiments may be included in the emission layer EML. The fused polycyclic compound of one or more embodiments may be included as a dopant material in the emission layer EML. The fused polycyclic compound of one or more embodiments may be a thermally activated delayed fluorescence material. The fused polycyclic compound of one or more embodiments may be used as a thermally activated delayed fluorescence dopant. For example, in the light emitting element ED of one or more embodiments, the emission layer EML may include, as a thermally activated delayed fluorescence dopant, at least one selected from among the fused polycyclic compounds represented by Compound Group 1 described above. However, an application of the fused polycyclic compound of one or more embodiments is not limited thereto.

In one or more embodiments, the emission layer EML may include the first compound which is the fused polycyclic compound represented by Formula 1, and may further include at least one of the second compound represented by Formula HT-1, the third compound represented by Formula ET-1, or the fourth compound represented by Formula D-1.

In one or more embodiments, the emission layer EML may include the first compound represented by Formula 1, and may further include at least one of the second compound represented by Formula HT-1 or the third compound represented by Formula ET-1.

In one or more embodiments, the emission layer EML may include the second compound represented by Formula HT-1. In one or more embodiments, the second compound may be used as a hole transporting host material of the emission layer EML.

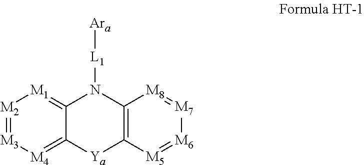

In Formula HT-1, M₁ to M₈ may each independently be N or CR₅₁. For example, in one or more embodiments, all of M₁ to M₈ may be CR₅₁. In one or more embodiments, any one selected from among M₁ to M₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that two six-membered rings (e.g., two benzene rings) linked to the nitrogen atom in Formula HT-1 are linked via a direct linkage,

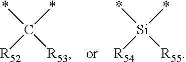

In Formula HT-1, if (e.g., when) Yₐ is a direct linkage, the second compound represented by Formula HT-1 may include a carbazole moiety.

In Formula HT-1, Arₐ may be a substituted or unsubstituted aryl group having 6 to 30 ring-forming carbon atoms or a substituted or unsubstituted heteroaryl group having 2 to 30 ring-forming carbon atoms. For example, in one or more embodiments, Arₐ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₅₁ to R₅₅ may be each independently bonded to an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds represented by Compound Group 2. The emission layer EML may include at least one selected from among the compounds represented by Compound Group 2 as a hole transporting host material.

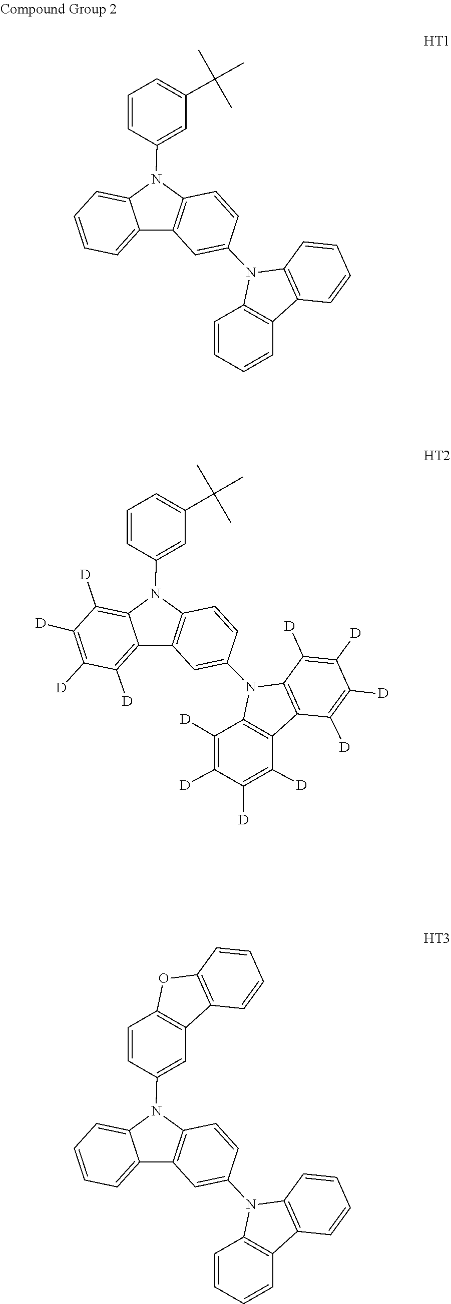 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

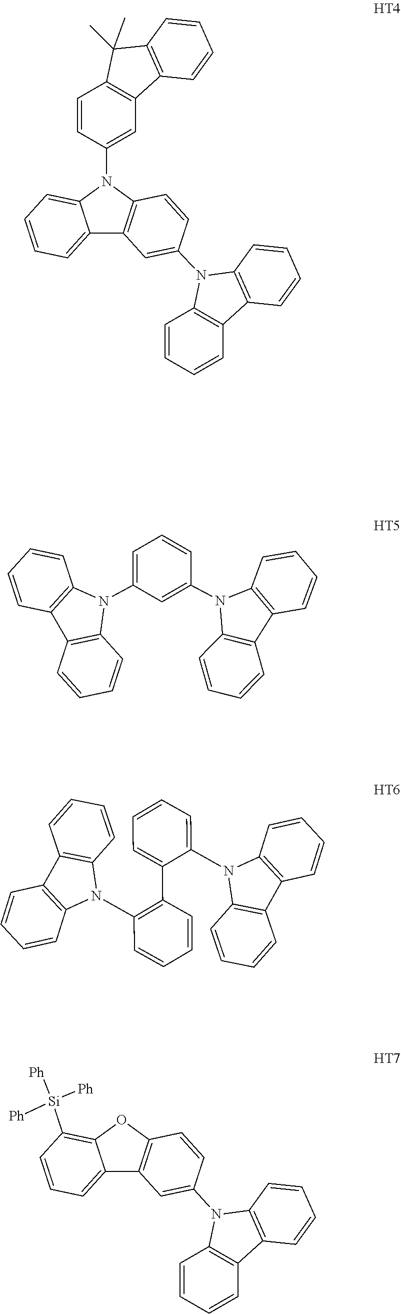 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

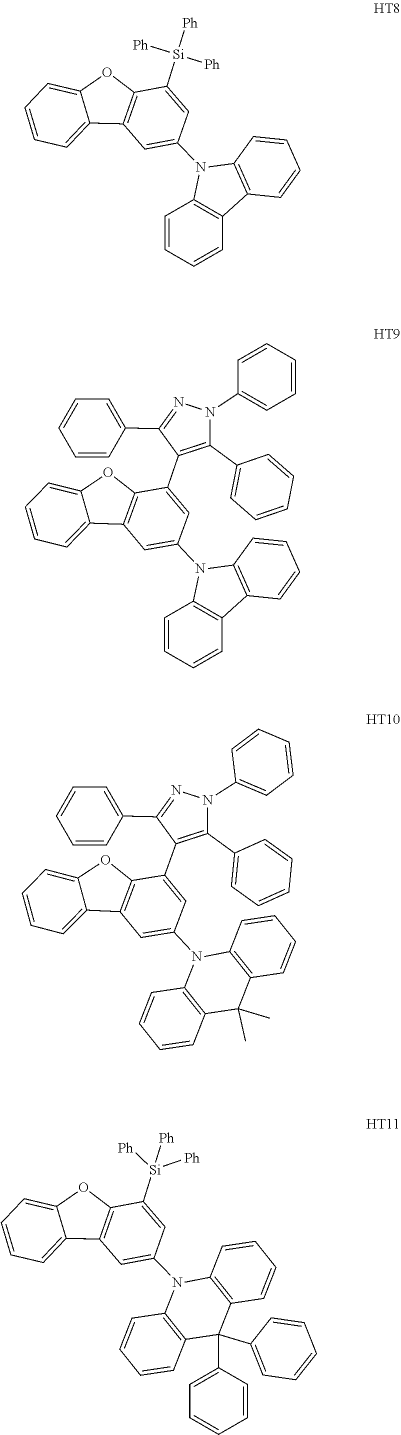 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

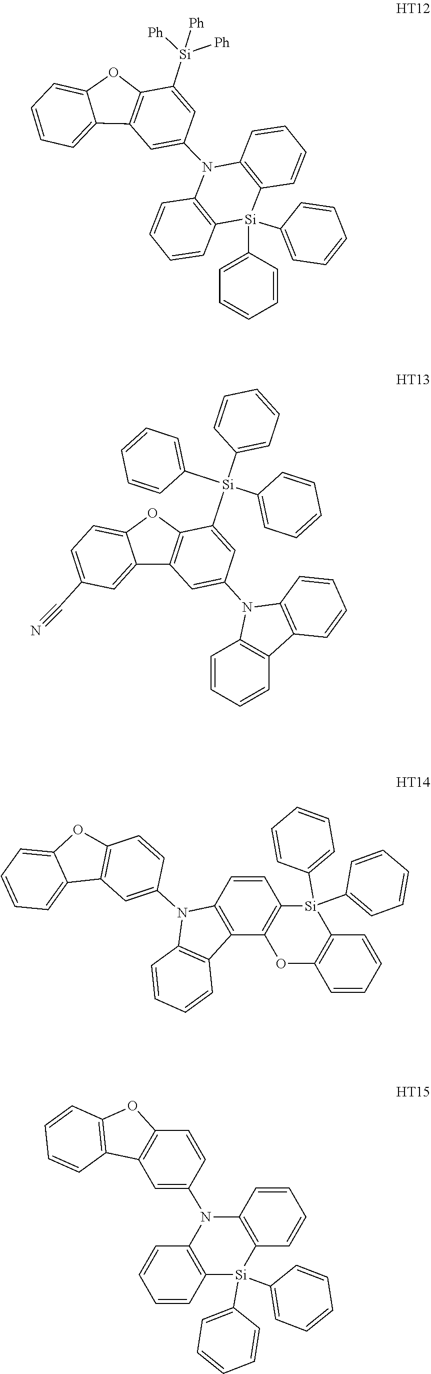 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

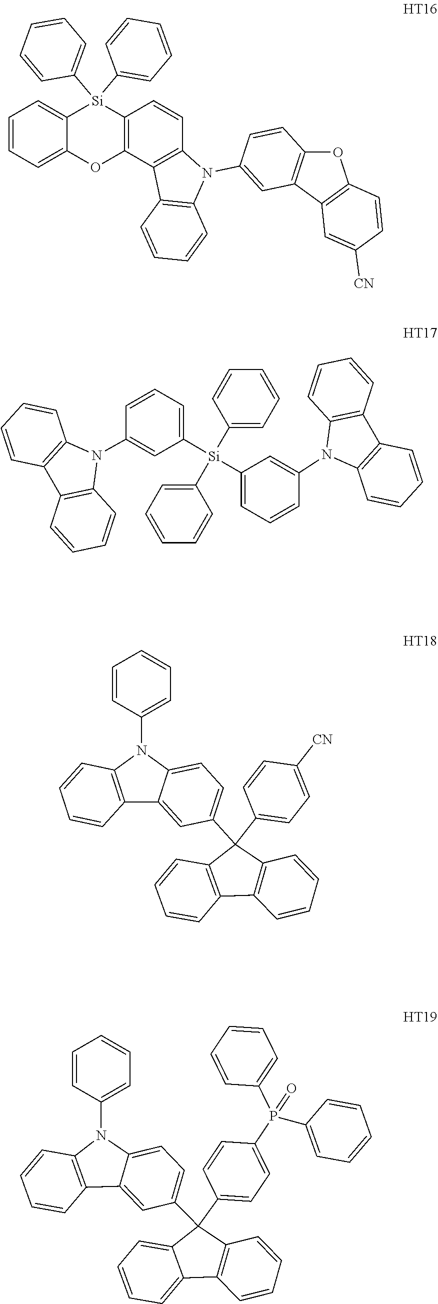 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

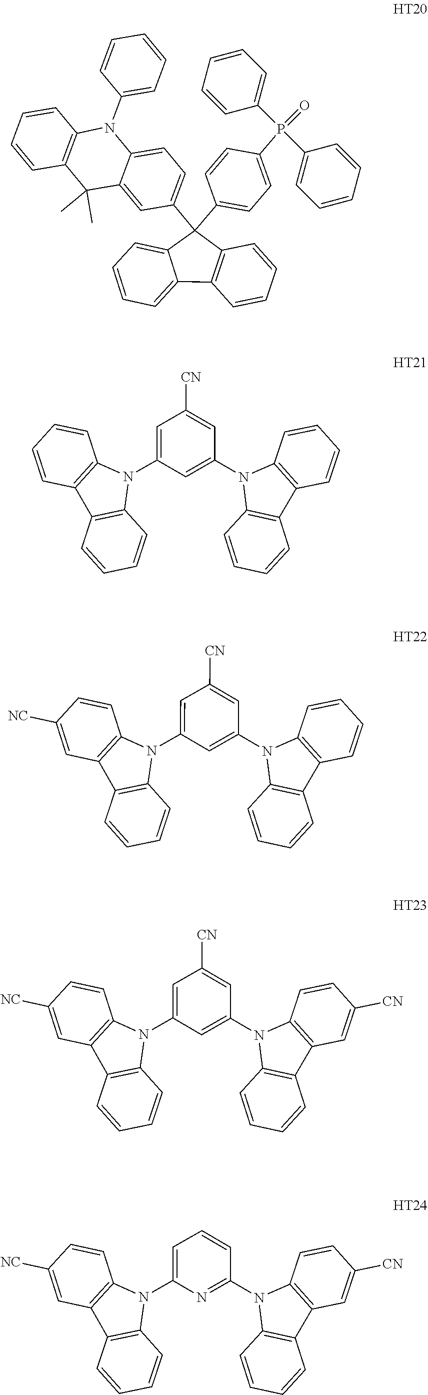 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

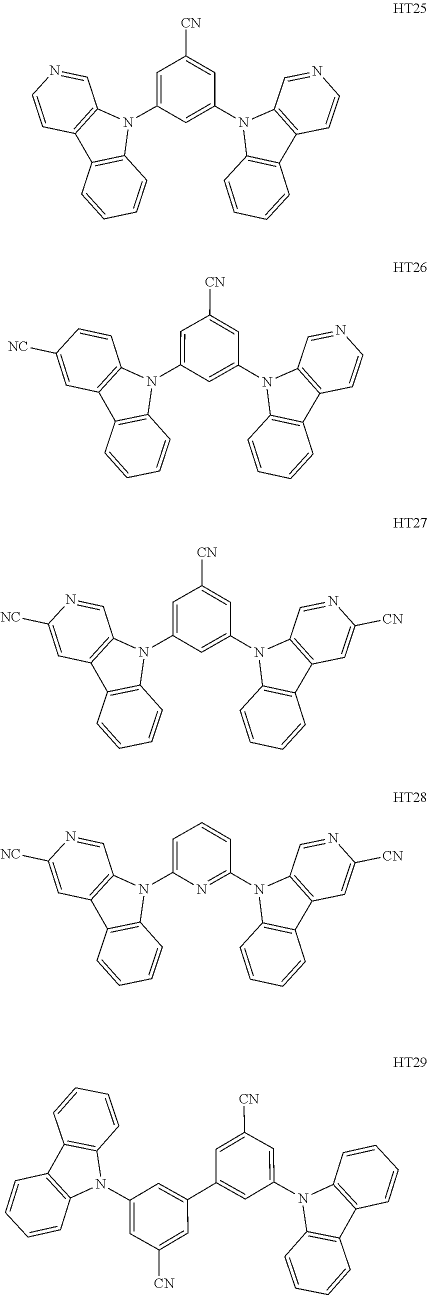 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

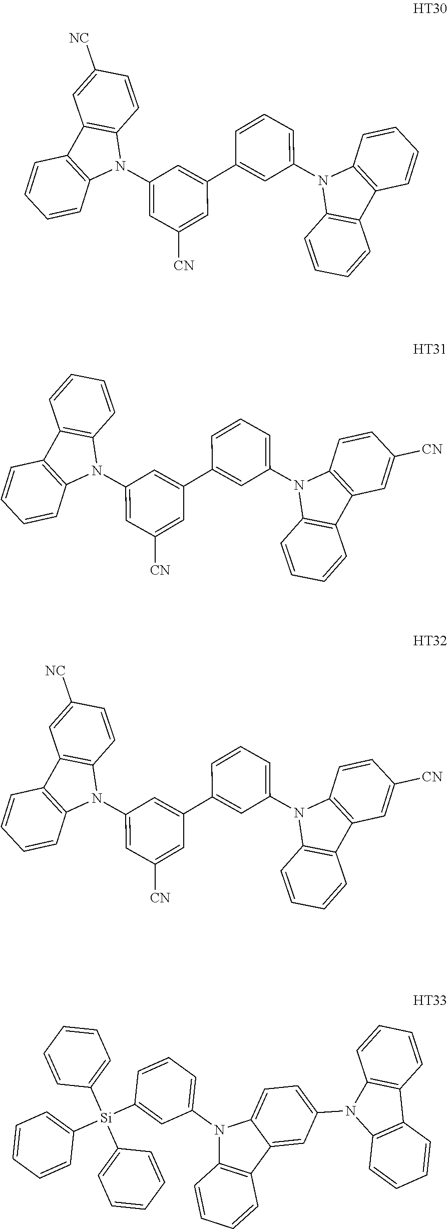 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

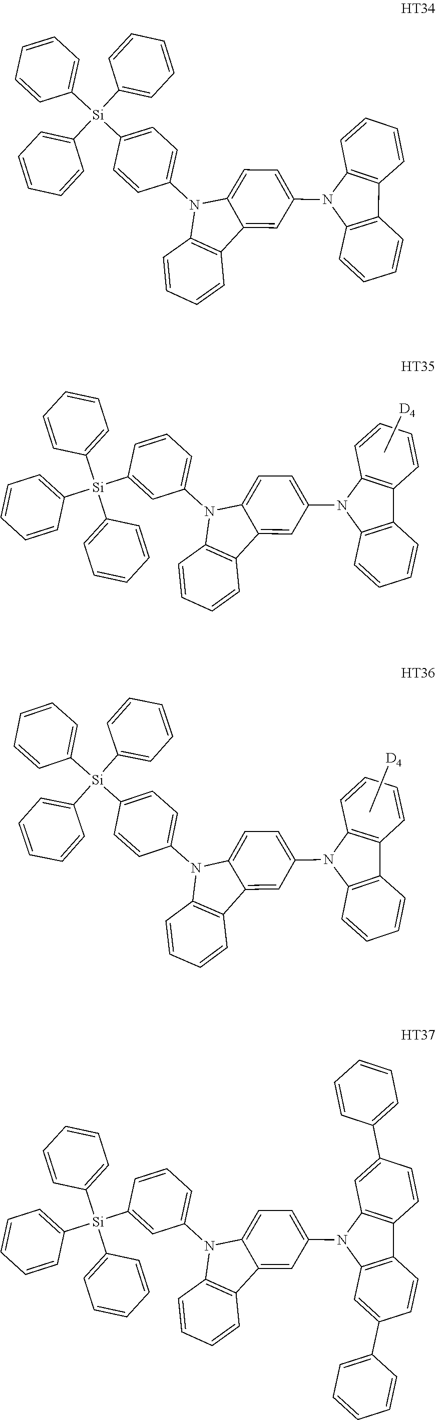

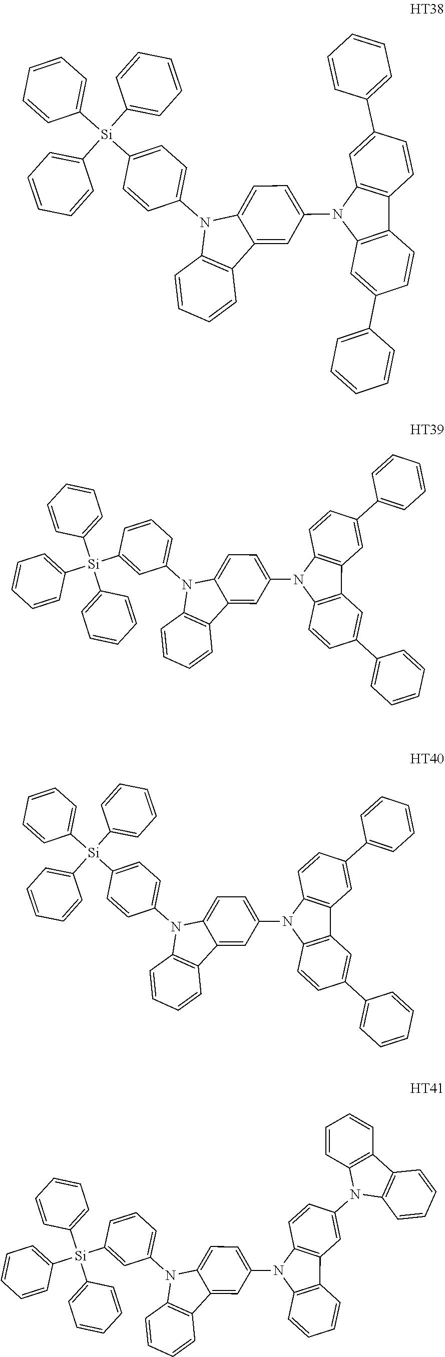 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

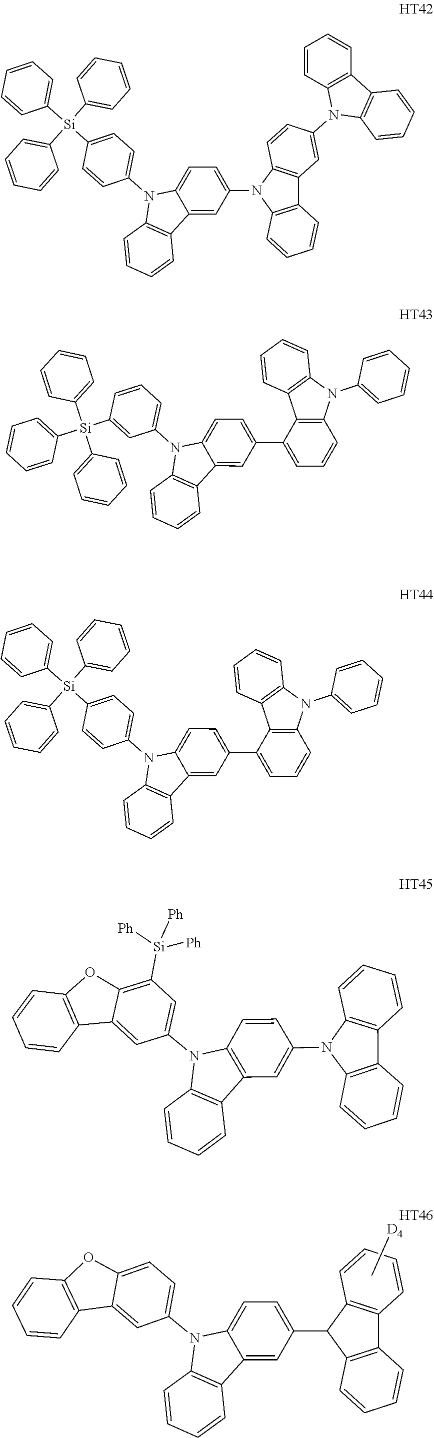

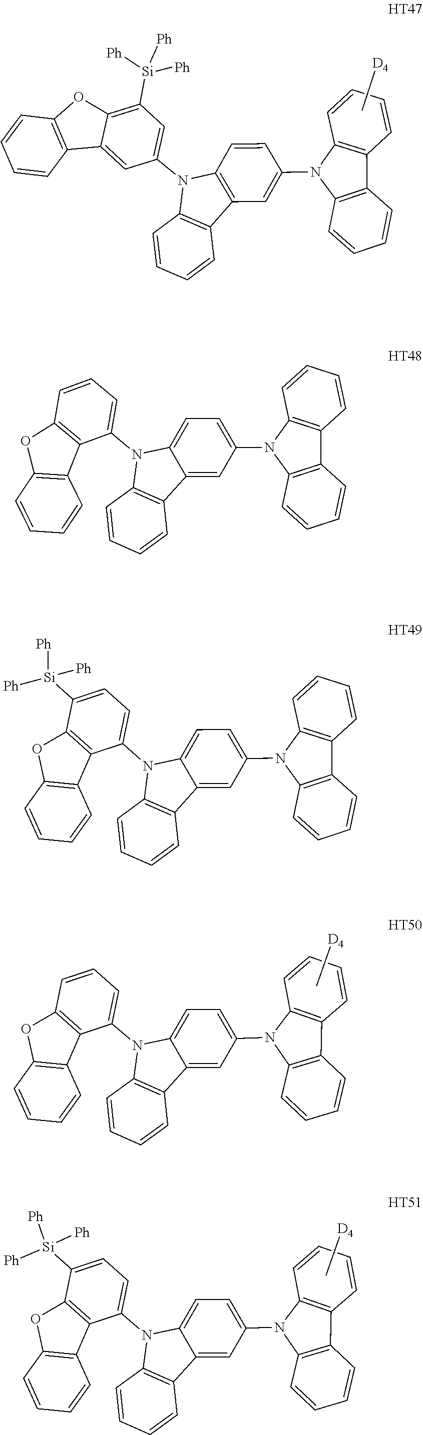

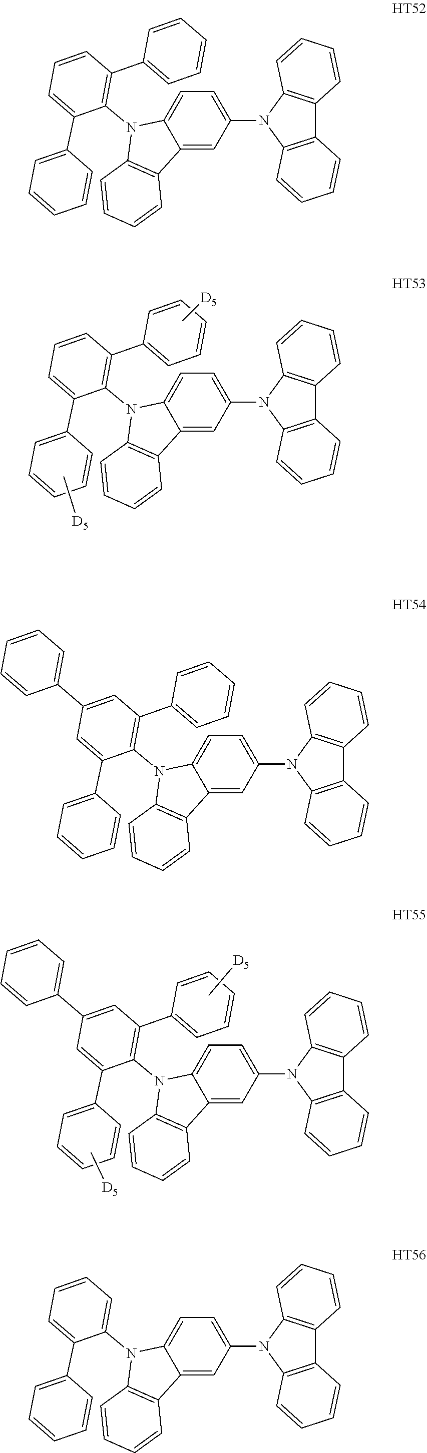

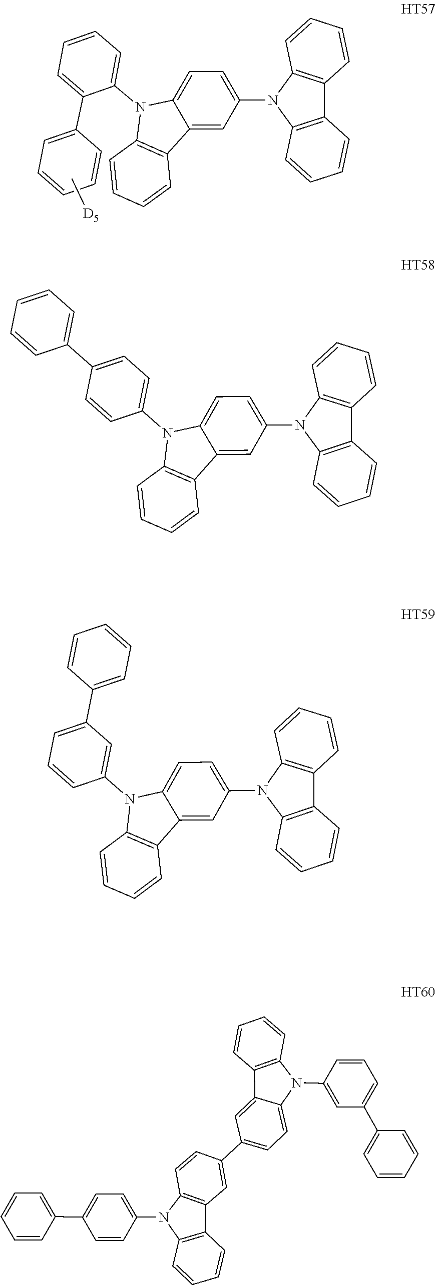

In embodiment compounds presented in Compound Group 2, “D” may refer to deuterium, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transporting host material for the emission layer EML.

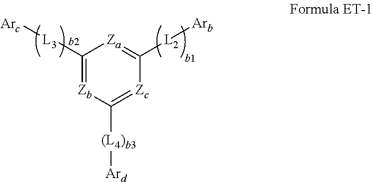

In Formula ET-1, at least one selected from among Zₐ to Z_{c} may be N, and the rest are CR₅₆. For example, in one or more embodiments, any one selected from among Zₐ to Z_{c} may be N, and the rest may each independently be CR₅₆. In these embodiments, the third compound represented by Formula ET-1 may include a pyridine moiety. In one or more embodiments, two selected from among Zₐ to Z_{c} may be N, and the rest may be CR₅₆. In these embodiments, the third compound represented by Formula ET-1 may include a pyrimidine moiety. In one or more embodiments, Zₐ to Z_{c} may all be N. In these embodiments, the third compound represented by Formula ET-1 may include a triazine moiety.

In Formula ET-1, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar_{b} to Ar_{d} may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Ar_{b} to Ar_{d} may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are integers of 2 or greater, L₂'s to L₄'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light emitting element ED of one or more embodiments may include any one selected from among the compounds in Compound Group 3.

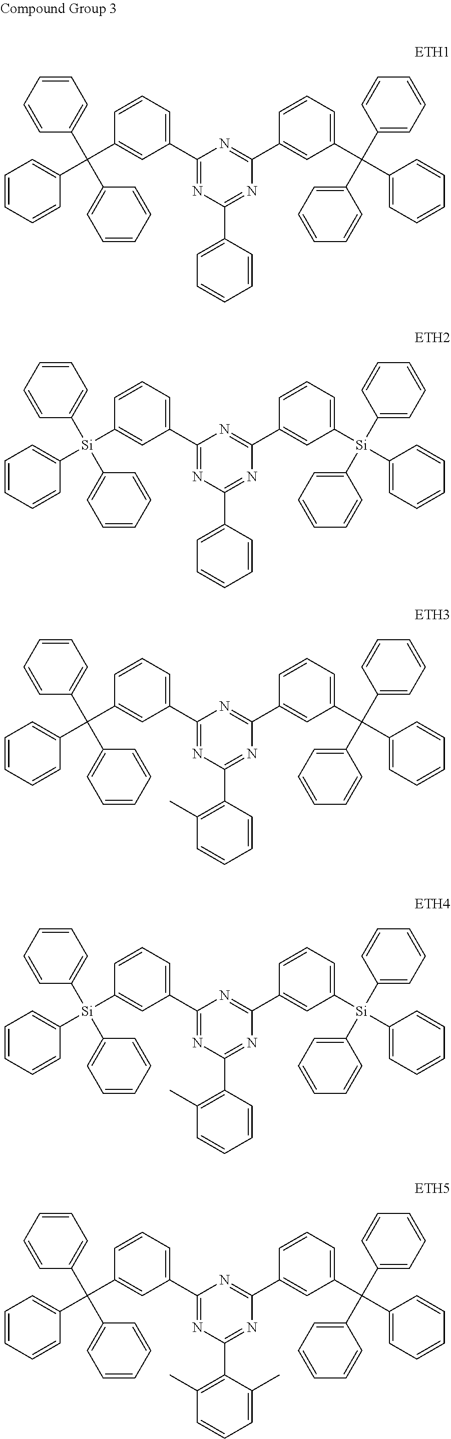

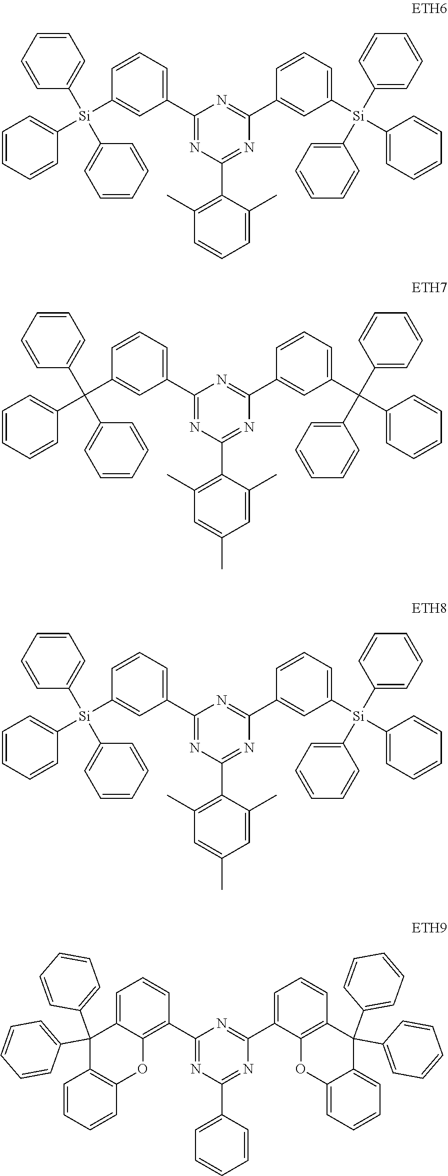 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

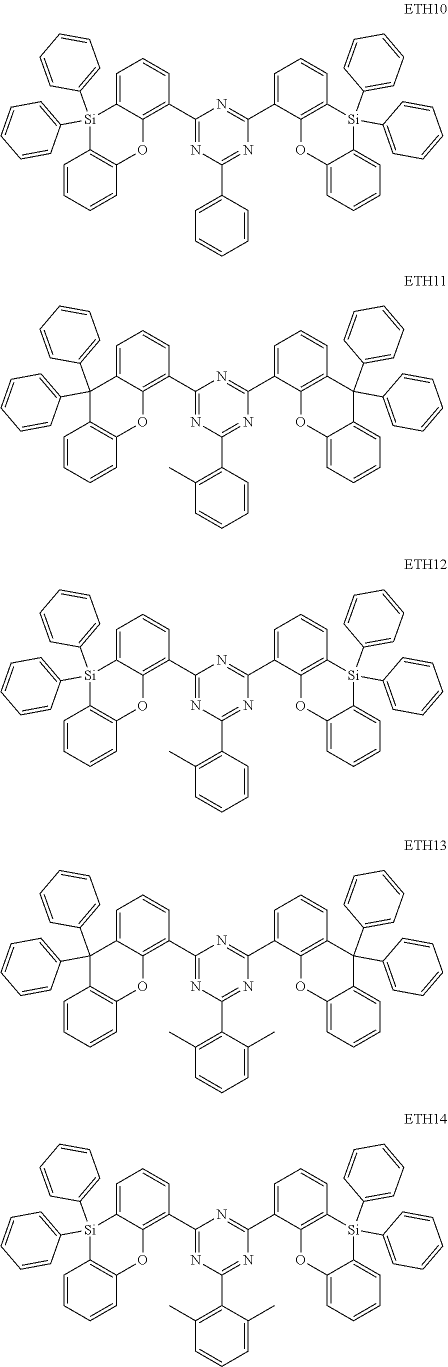

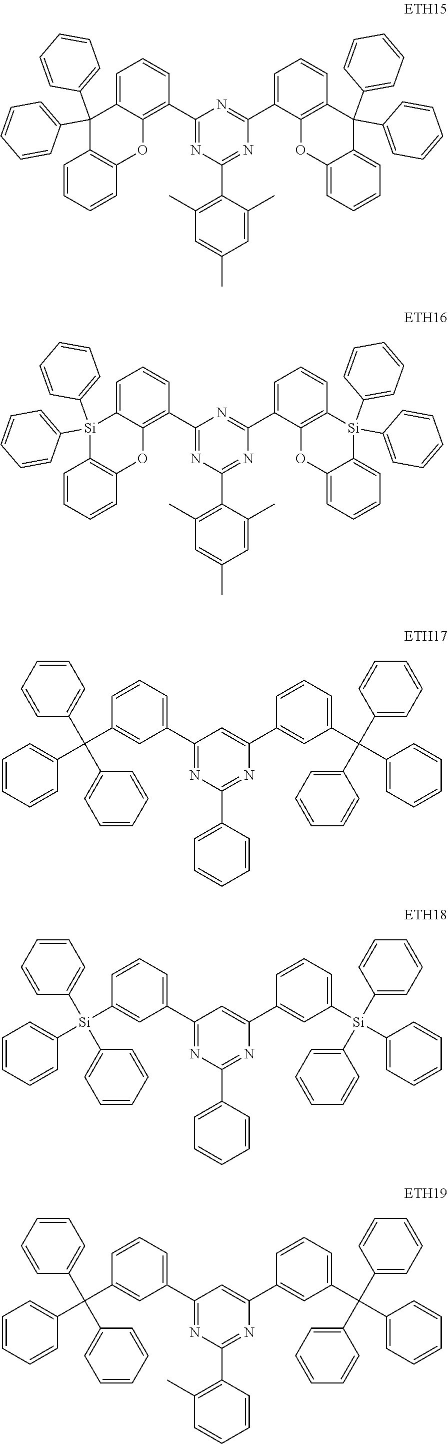

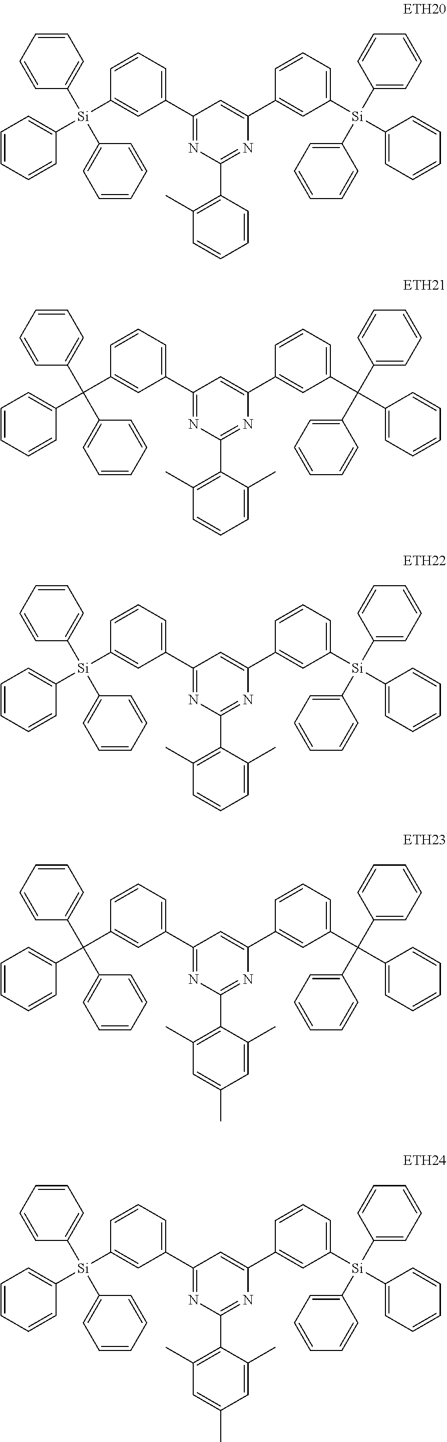

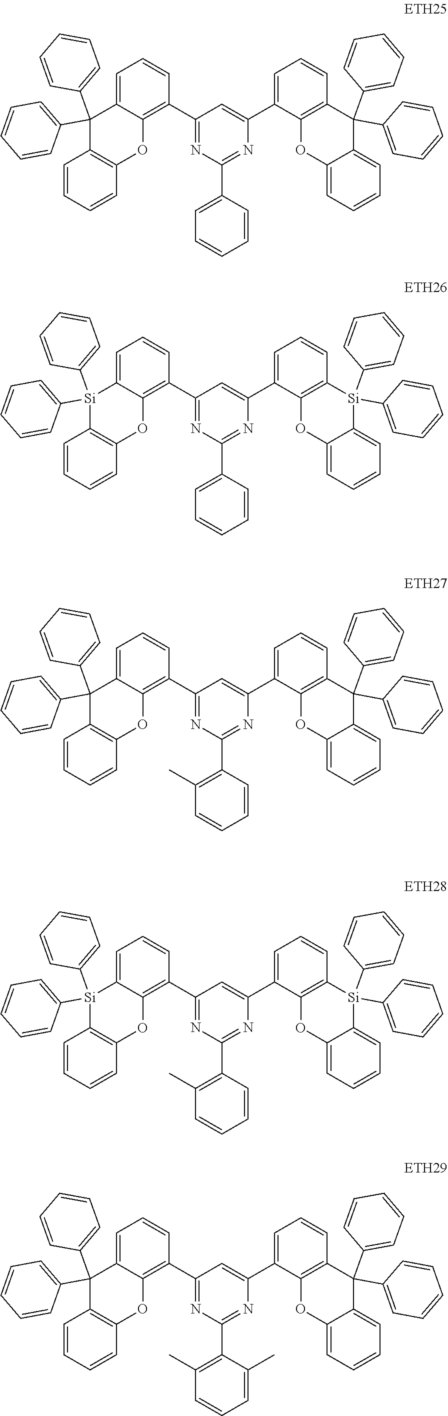

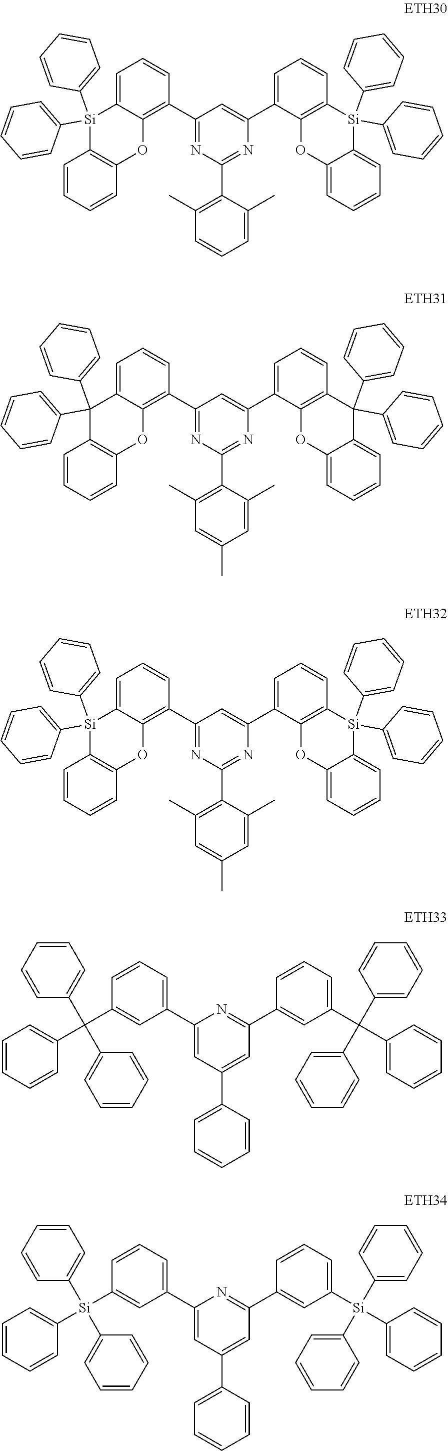

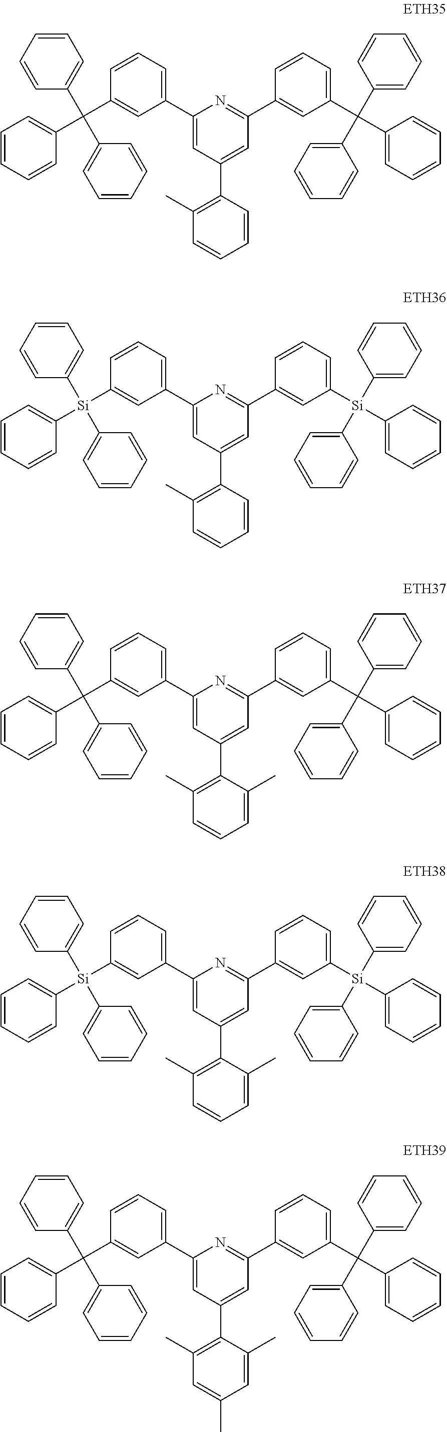

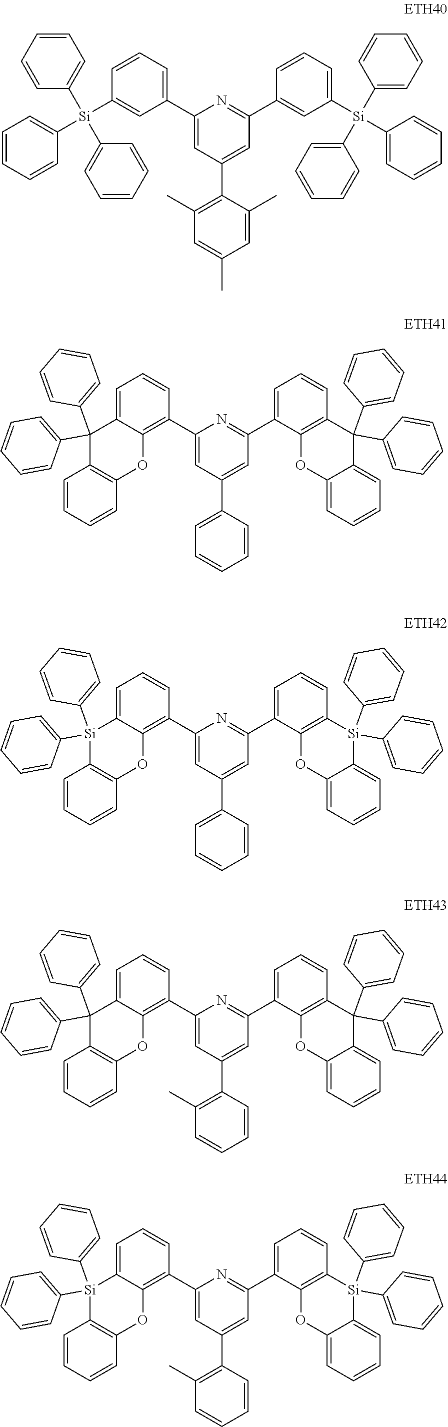

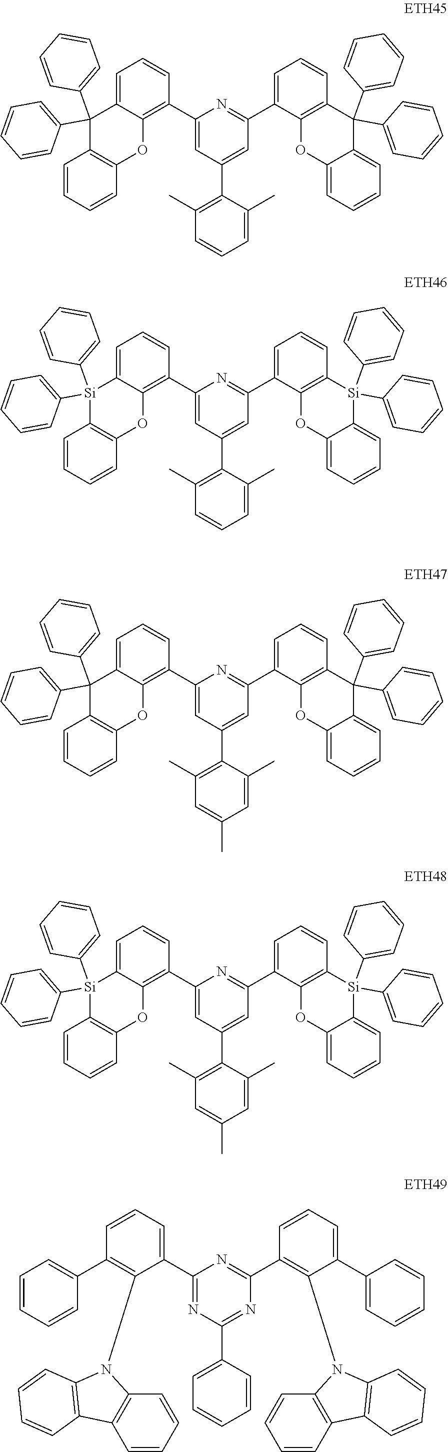

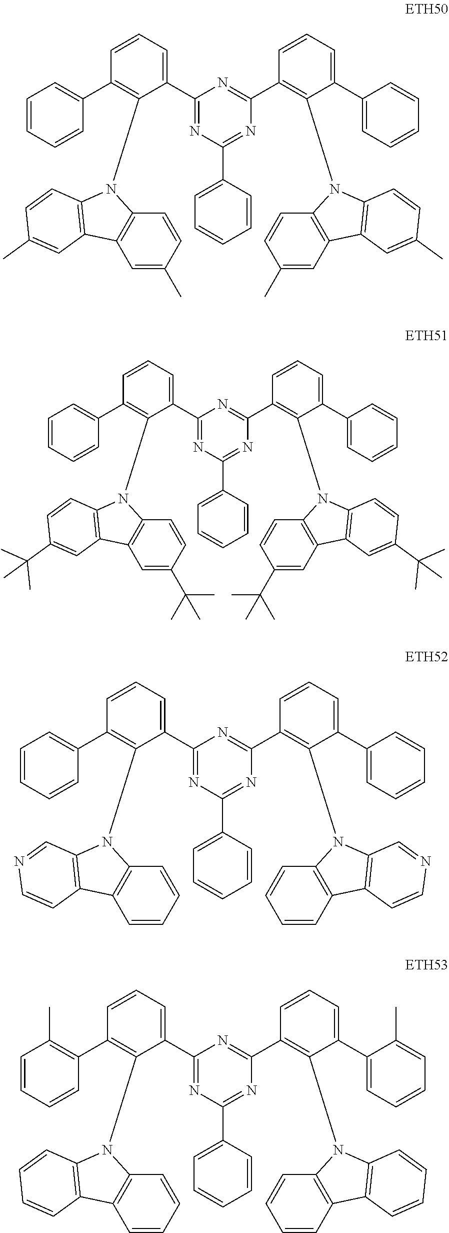

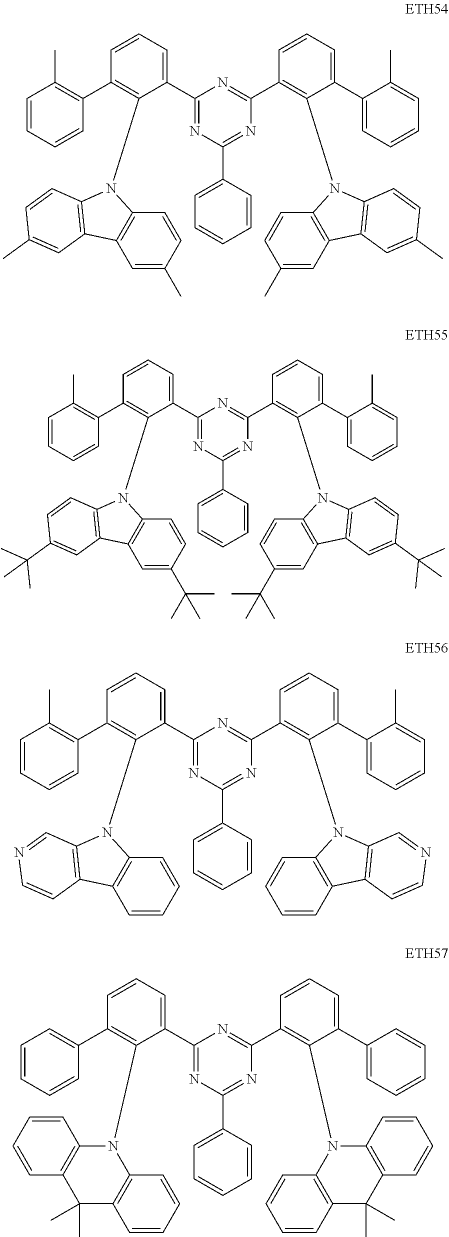

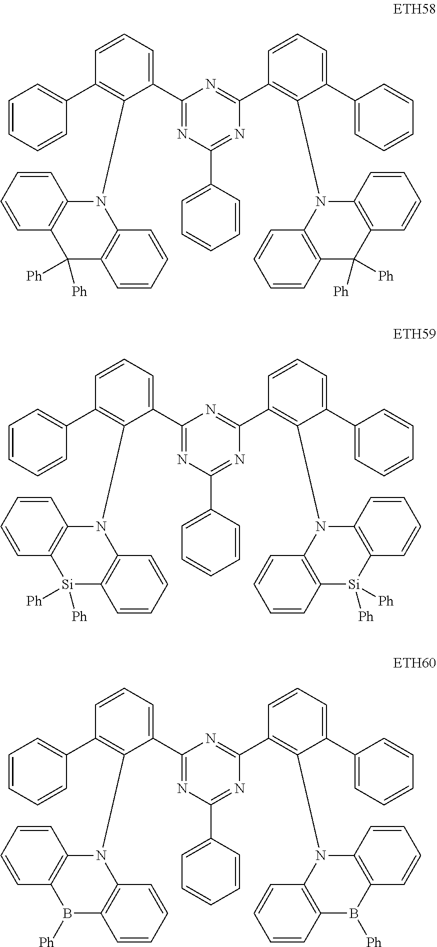 [SMILES: c1ccc(-c2nc(-c3cccc(-c4ccccc4)c3N3c4ccccc4C(c4ccccc4)(c4ccccc4)c4ccccc43)nc(-c3cccc(-c4ccccc4)c3N3c4ccccc4C(c4ccccc4)(c4ccccc4)c4ccccc43)n2)cc1 ; c1ccc(-c2nc(-c3cccc(-c4ccccc4)c3N3c4ccccc4[Si](c4ccccc4)(c4ccccc4)c4ccccc43)nc(-c3cccc(-c4ccccc4)c3N3c4ccccc4[Si](c4ccccc4)(c4ccccc4)c4ccccc43)n2)cc1 ; c1ccc(B2c3ccccc3N(c3c(-c4ccccc4)cccc3-c3nc(-c4ccccc4)nc(-c4cccc(-c5ccccc5)c4N4c5ccccc5B(c5ccccc5)c5ccccc54)n3)c3ccccc32)cc1]

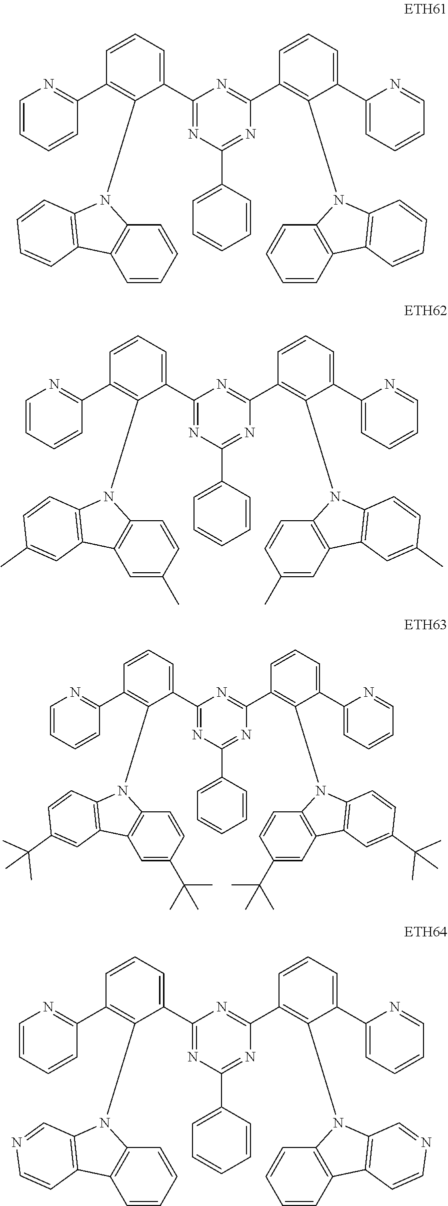

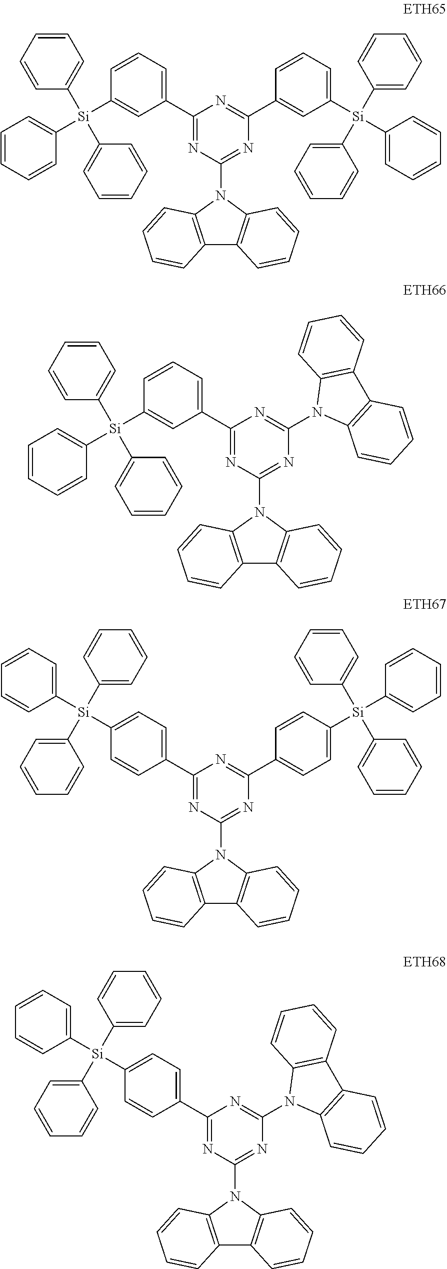

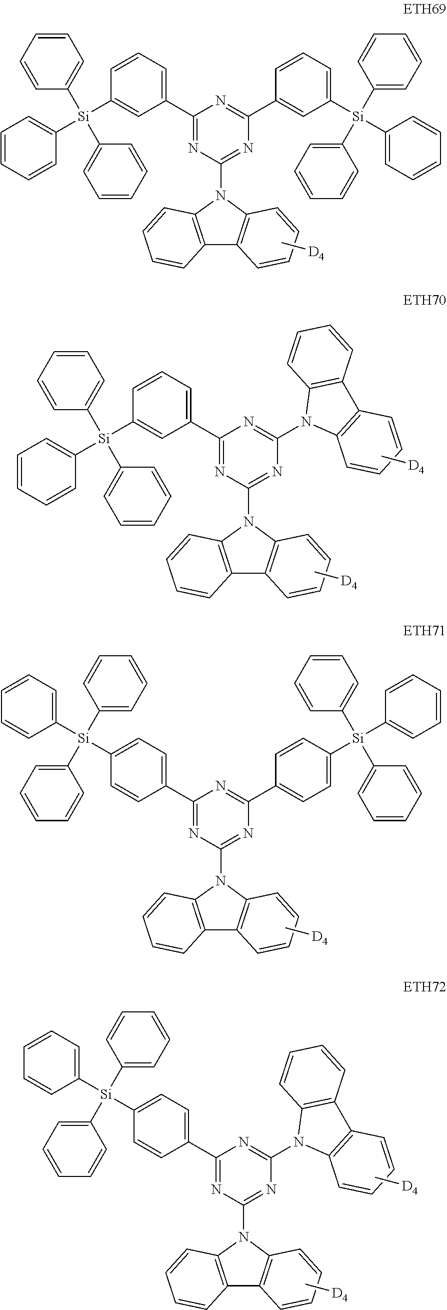

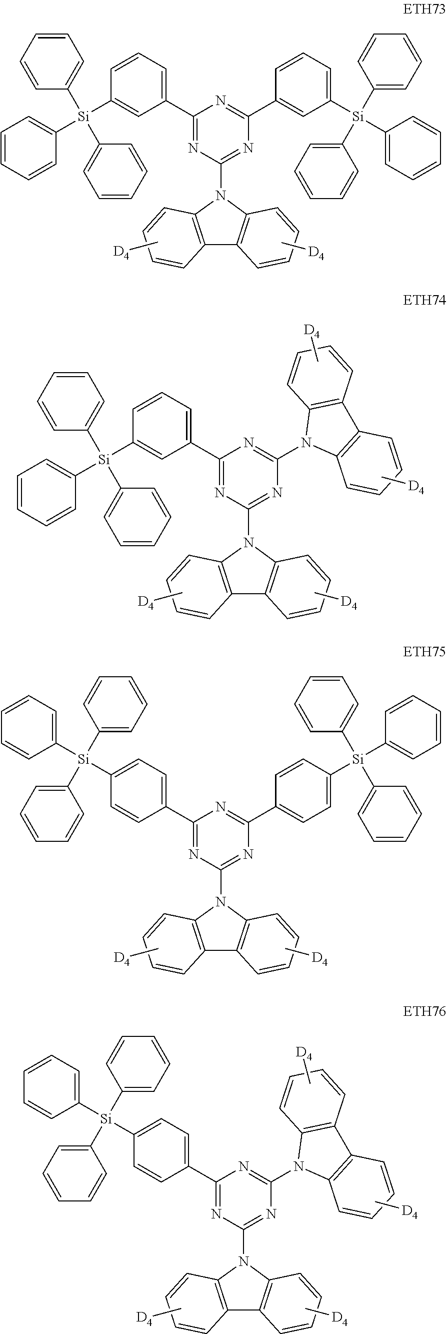

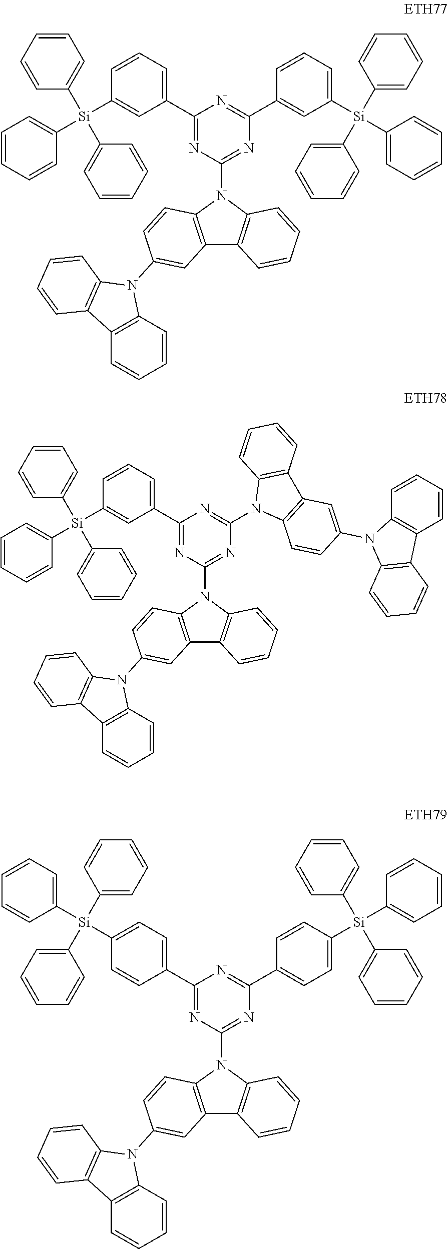 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

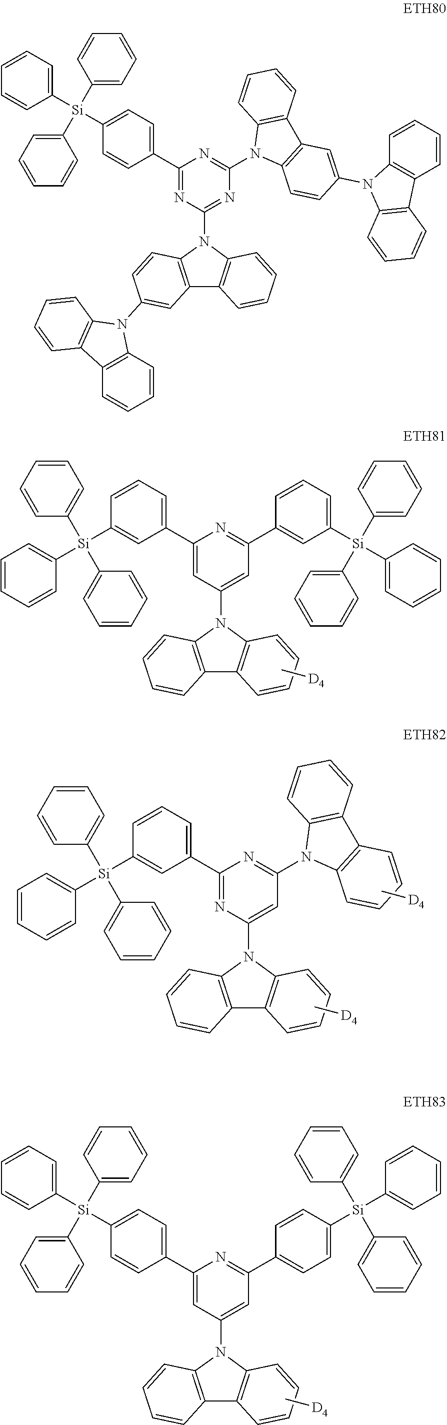

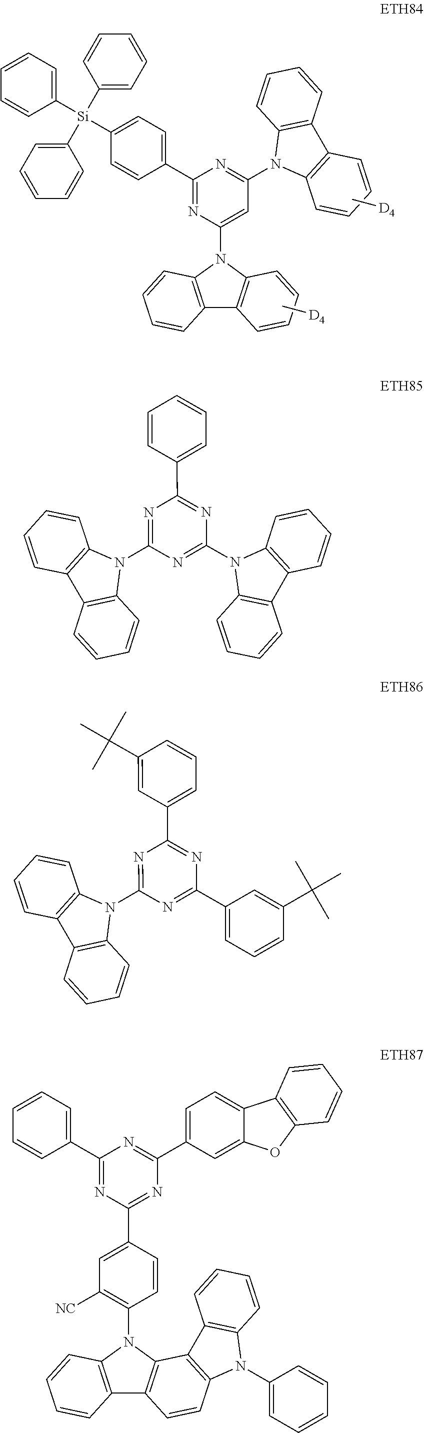

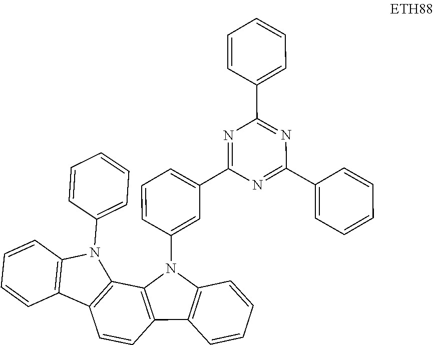 [SMILES: c1ccc(-c2nc(-c3ccccc3)nc(-c3cccc(-n4c5ccccc5c5ccc6c7ccccc7n(-c7ccccc7)c6c54)c3)n2)cc1]

In the embodiments compounds presented in Compound Group 3, “D” refers to deuterium, and “Ph” refers to an unsubstituted phenyl group.

In one or more embodiments, the emission layer EML may include the second compound and the third compound, and the second compound and the third compound may form an exciplex. In the emission layer EML, an exciplex may be formed by the hole transporting host and the electron transporting host. In this regard, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, in one or more embodiments, an absolute value of the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described above. The fourth compound may be used as a phosphorescent sensitizer of the emission layer EML. The energy may be transferred from the fourth compound to the first compound, thereby emitting light.

For example, in one or more embodiments, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

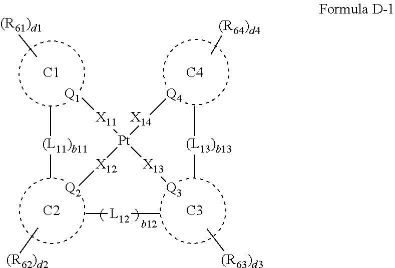

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, X₁₁ to X₁₄ may each independently be a direct linkage or *—O—*. For example, in one or more embodiments, one selected from among X₁₁ to X₁₄ may be *—O—* and each of the others may be a direct linkage.

In Formula D-1, L₁₁ to L₁₃ may each independently be a direct linkage, *—O—*, *—S—*,

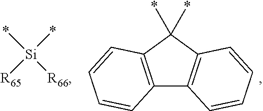

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” refers to a part linked to C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₆₁ to R₆₆ may be independently bonded to an adjacent group to form a ring. In one or more embodiments, R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with each of R₆₁ to R₆₄. The embodiment in which each of d1 to d4 is 4 and R₆₁'s to R₆₄′ are each hydrogen may be the same as the embodiment in which each of d1 to d4 is 0. When each of d1 to d4 is an integer of 2 or greater, a plurality of R₆₁'s to R₆₄'s may each be the same, or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one among C-1 to C-4:

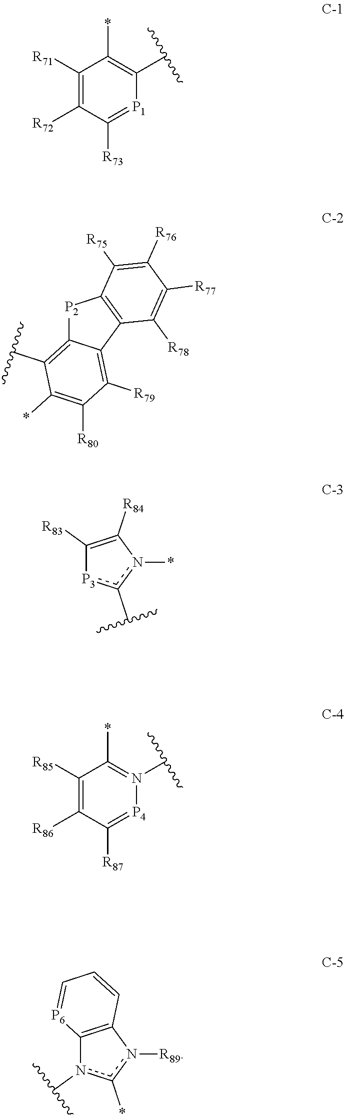

In C-1 to C-5, P₁ may be C—* or CR₇₄, P₂ may be N—* or NR₈₁, P₃ may be N—* or NR₈₂, P₄ may be C—* or CR₈₈, and P₆ may be C—* or CR₉₀. R₇₁ to R₉₀ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In addition, in C-1 to C-5,

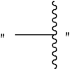

corresponds to a part linked to Pt that is a central metal atom, and “ [symbol] ” corresponds to a part linked to a neighboring cyclic group (C1 to C4) or an adjacent linker (L₁₁ to L₁₃).

The emission layer EML of one or more embodiments may include the first compound, which is a fused polycyclic compound represented by Formula 1, and at least one selected from among the second to fourth compounds. For example, in one or more embodiments, the emission layer EML may include the first compound, the second compound, and the third compound. In the emission layer EML, the second compound and the third compound may form an exciplex, and the energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, in one or more embodiments, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In addition, if (e.g., when) the energy delivery to the first compound is increased, an exciton formed in the emission layer EML is not accumulated inside the emission layer EML and instead emits light rapidly, and thus deterioration of the element may be reduced. Therefore, the service life of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be any one selected from among compounds represented in Compound Group 4. The emission layer EML may include at least one selected from among the compounds represented in Compound Group 4 as a sensitizer material.

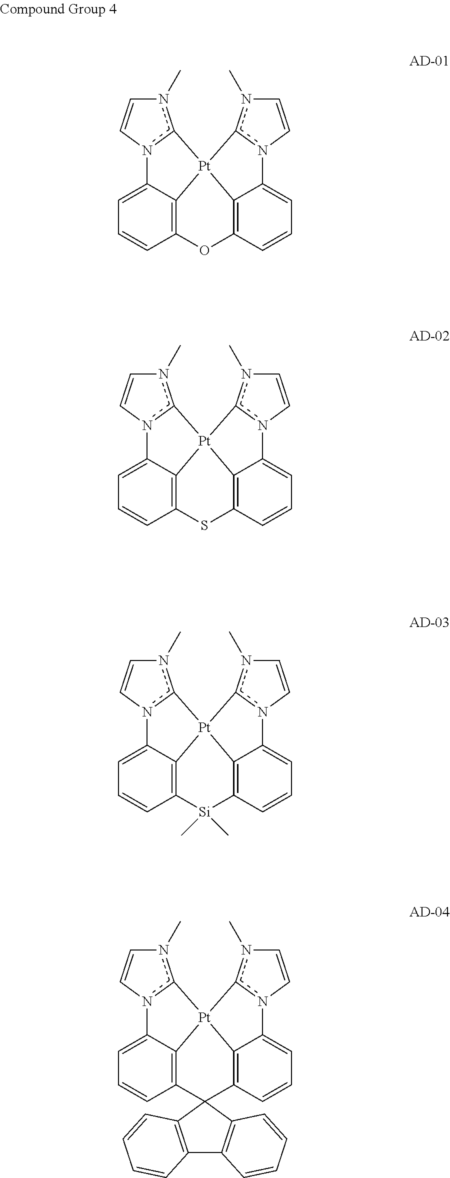

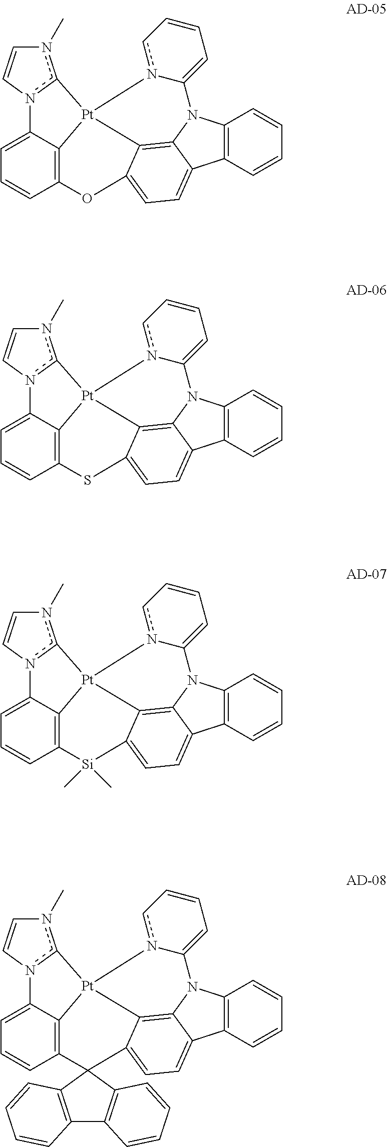

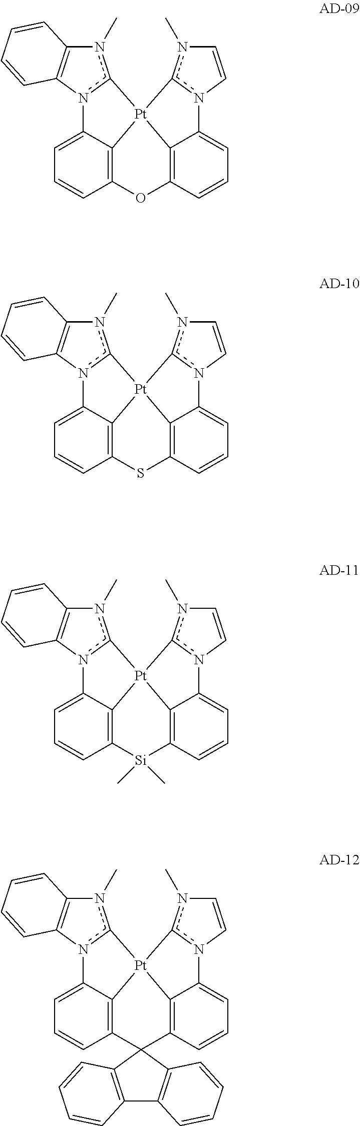

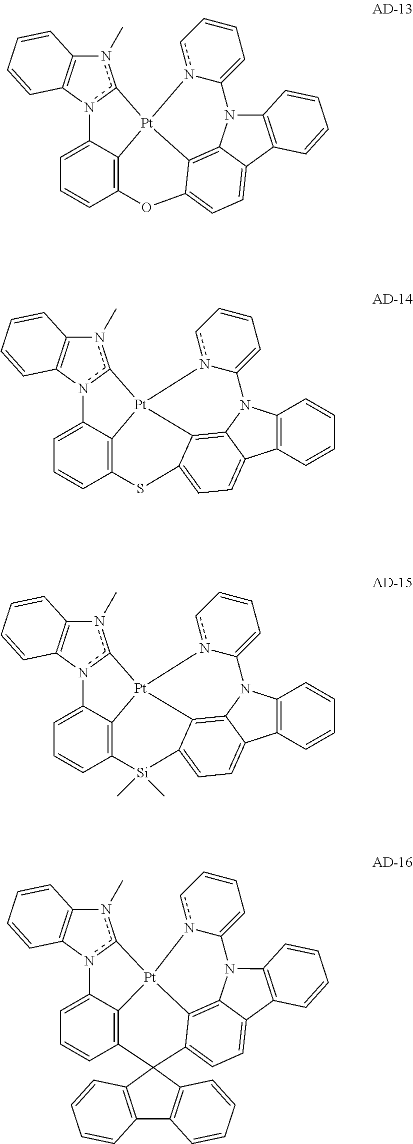

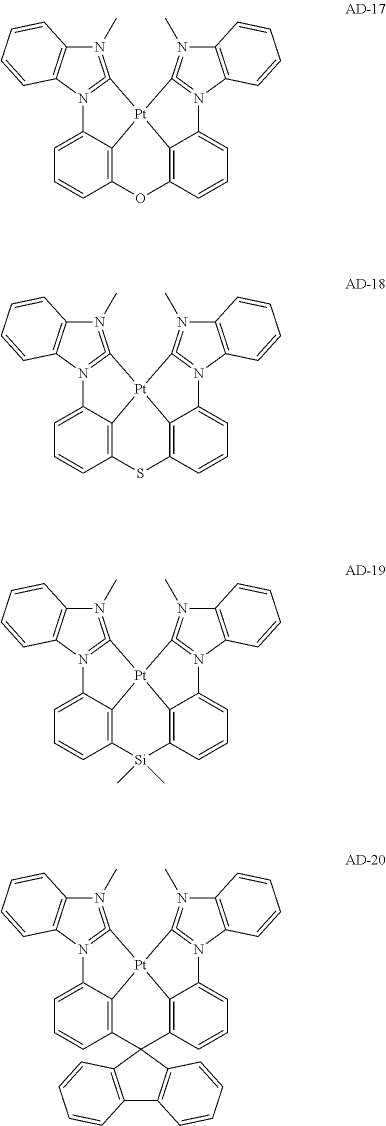

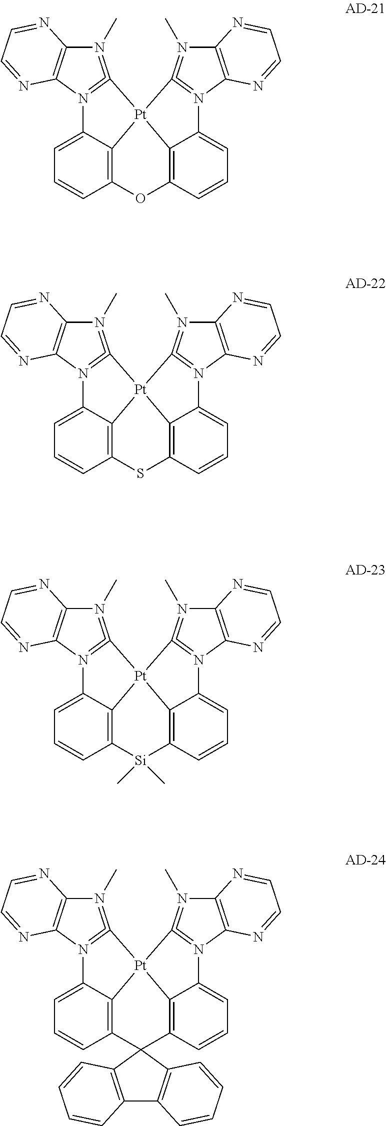

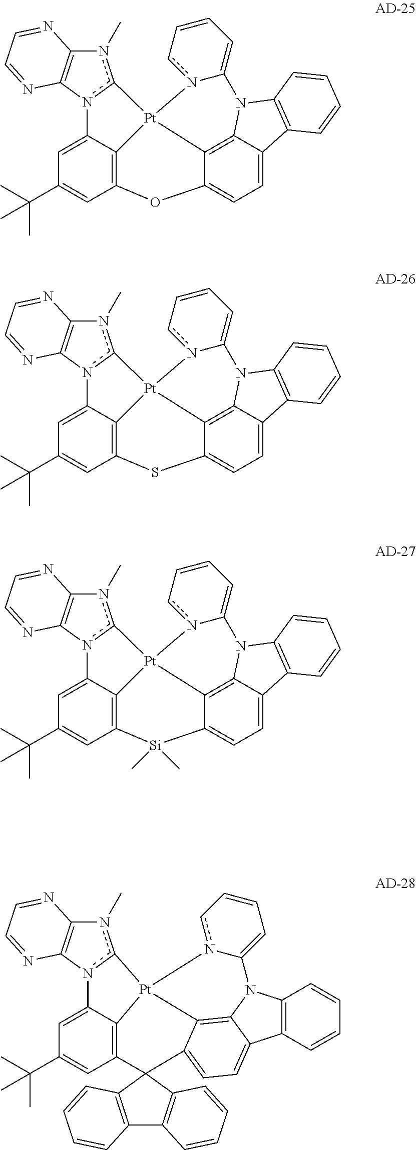

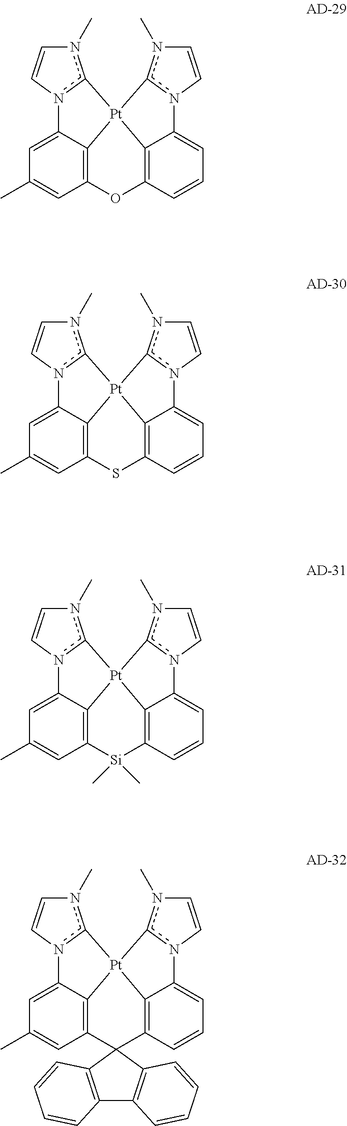

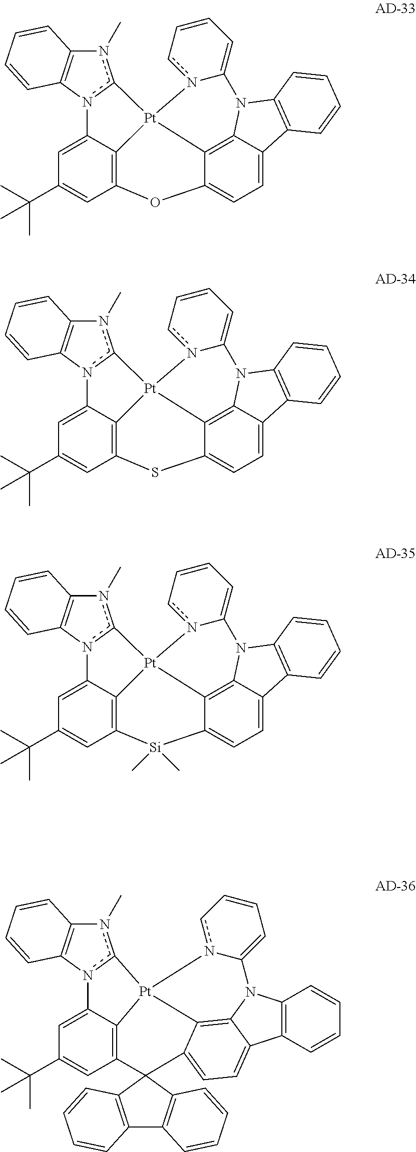

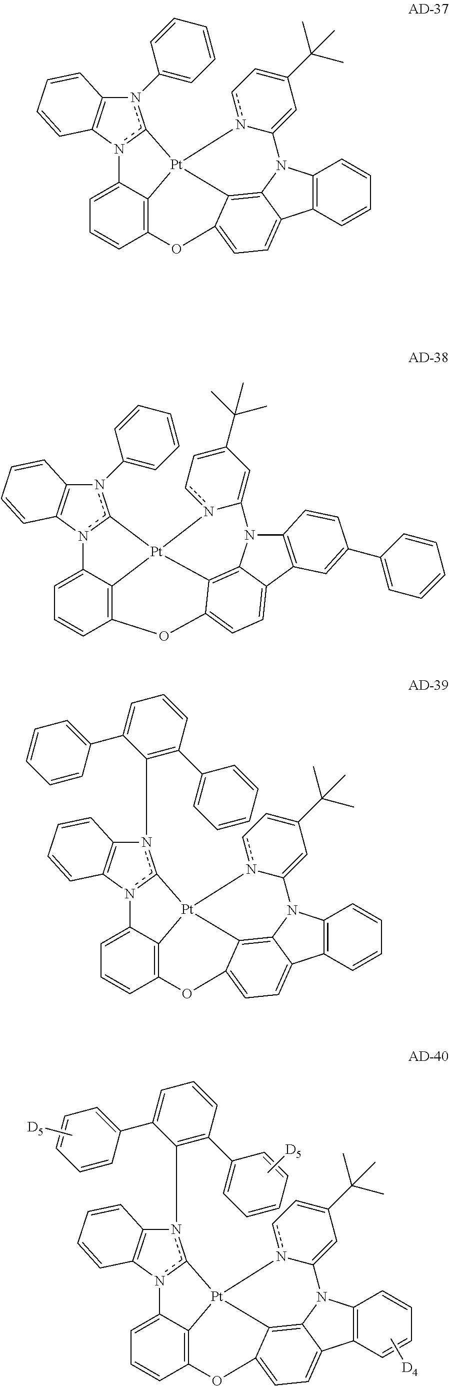

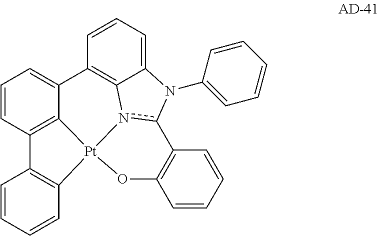

In the embodiment compounds presented in Compound Group 4, “D” refers to deuterium.

In one or more embodiments, the light emitting element ED may include a plurality of emission layers. The plurality of emission layers may be provided by being sequentially stacked. For example, in one or more embodiments, a light emitting element (ED) including a plurality of emission layers may be to emit white light (e.g., combined white light). The light emitting element including a plurality of emission layers may be a light emitting element with a tandem structure. When the light emitting element ED includes a plurality of emission layers, at least one emission layer EML may include the first compound represented by Formula 1. Additionally, if (e.g., when) the light emitting element ED includes a plurality of emission layers, at least one emission layer EML may include all of the first compound, second compound, third compound, and fourth compound as described above.

When the emission layer EML in the light emitting element ED of one or more embodiments includes all of the first compound, the second compound, and the third compound, with respect to a total weight of the first compound, the second compound, and the third compound, the content (e.g., amount) of the first compound may be about 0.1 wt % to about 5 wt %. However, embodiments of the present disclosure are not limited thereto. When the content (e.g., amount) of the first compound satisfy the above-described proportion, the energy transfer from the second compound and the third compound to the first compound may increase, and thus the luminous efficiency and element service life may increase.

The contents (e.g., amounts) of the second compound and the third compound in the emission layer EML may be the rest excluding the weight of the first compound. For example, in one or more embodiments, the contents (e.g., amounts) of the second compound and the third compound in the emission layer EML may be about 65 wt % to about 95 wt % with respect to the total weight of the first compound, the second compound, and the third compound.

In the total weight of the second compound and the third compound, a weight ratio of the second compound to the third compound may be about 3:7 to about 7:3.

When the contents (e.g., amounts) of the second compound and the third compound satisfy the above-described ratio, a charge balance characteristic in the emission layer EML are improved, and thus the luminous efficiency and element service life may increase. When the contents (e.g., amounts) of the second compound and the third compound deviate from the above-described ratio range, a charge balance in the emission layer EML is broken, and thus the luminous efficiency may be reduced and the element may be easily deteriorated.

In one or more embodiments, when the emission layer EML includes the fourth compound, the content (e.g., amount) of the fourth compound in the emission layer EML may be about 10 wt % to about 30 wt % with respect to a total weight of the first compound, the second compound, the third compound, and the fourth compound. However, embodiments of the present disclosure are not limited thereto. When the content (e.g., amount) of the fourth compound satisfies the above-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life of the light emitting element may be achieved.

In the light emitting element ED of one or more embodiments, the emission layer EML may include at least one of an anthracene derivative, a pyrene derivative, a fluoranthene derivative, a chrysene derivative, a dihydrobenzanthracene derivative, or a triphenylene derivative. For example, in one or more embodiments, the emission layer EML may include the anthracene derivative and/or the pyrene derivative.

In each light emitting element ED of embodiments illustrated in FIGS. 3 to 6, the emission layer EML may further include a suitable host and/or dopant besides the above-described host and dopant, and for example, in one or more embodiments, the emission layer EML may include a compound represented by Formula E-1. The compound represented by Formula E-1 may be used as a fluorescent host material.

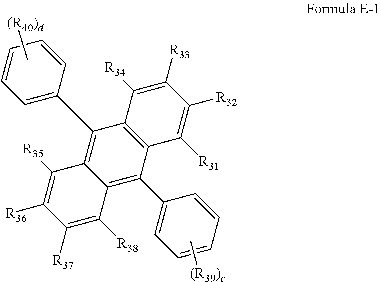

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among R₃₁ to R₄₀ may be each independently bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among Compound E1 to Compound E19:

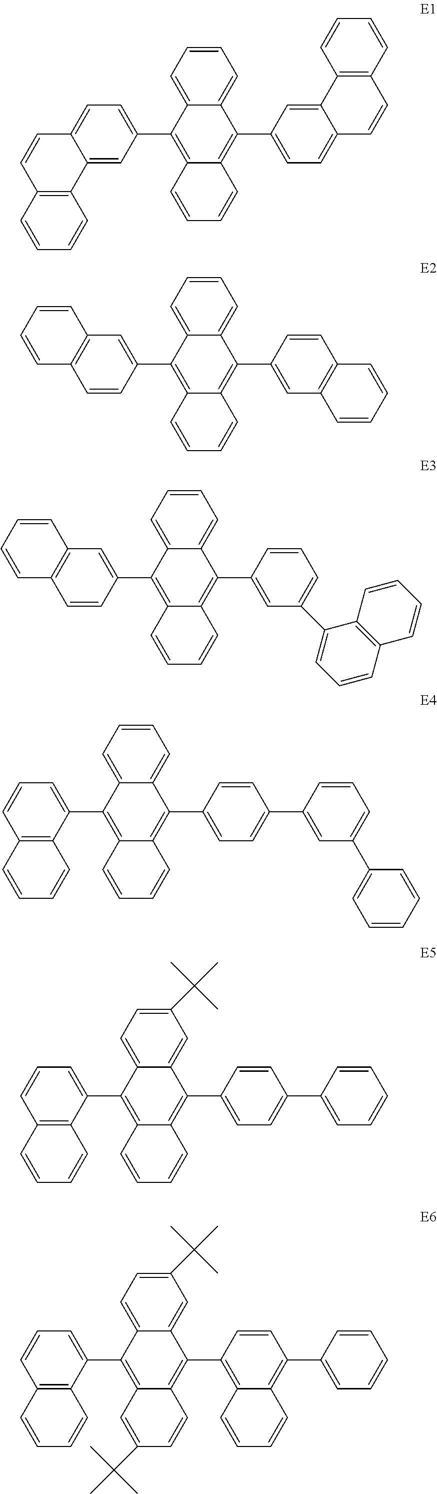

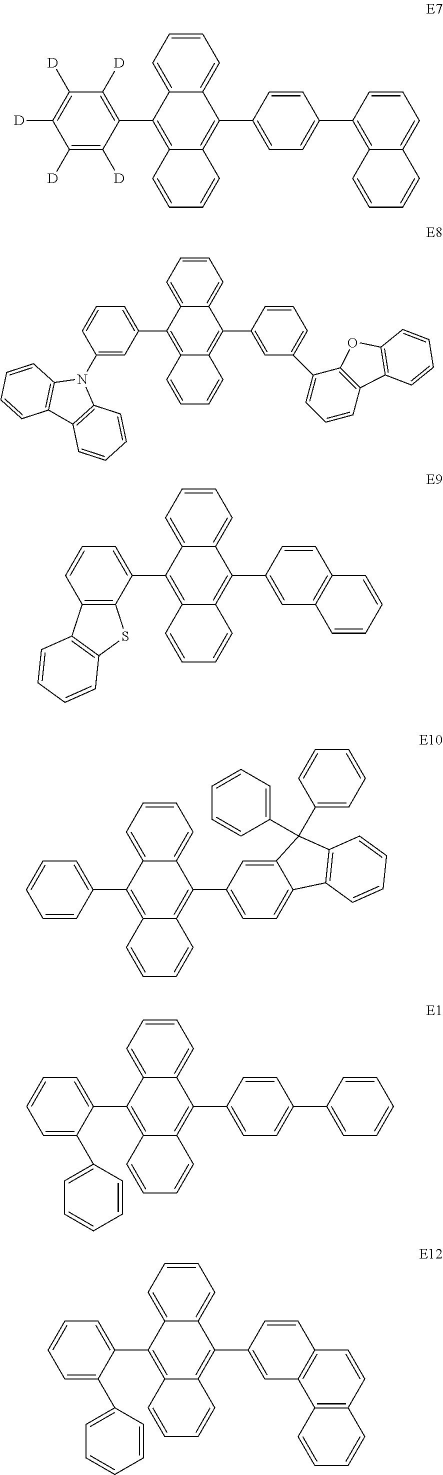

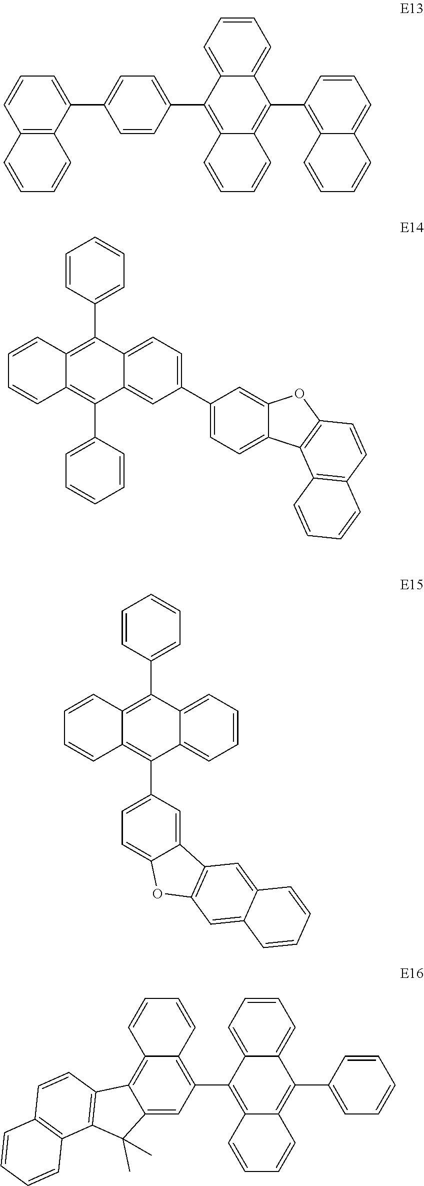

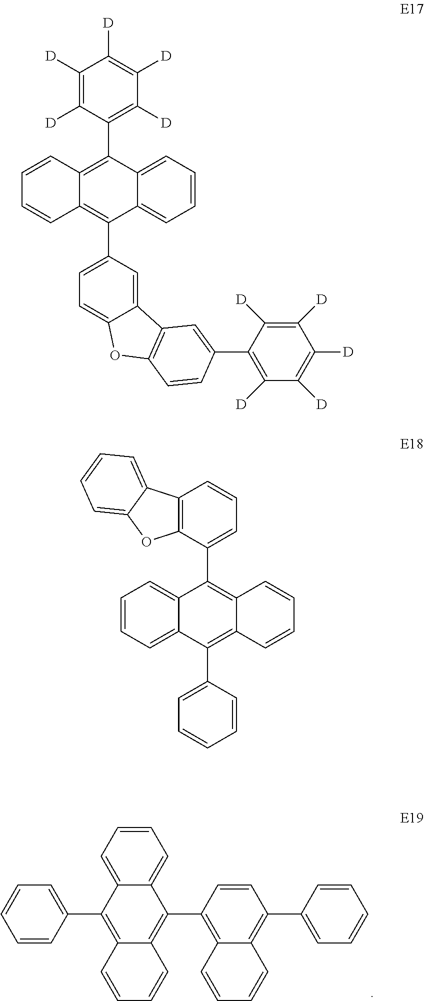

In one or more embodiments, the emission layer EML may include a compound represented by Formula E-2a or Formula E-2b. The compound represented by Formula E-2a or Formula E-2b may be used as a phosphorescent host material.

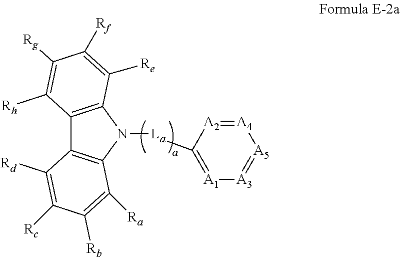

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of La's may each independently be a substituted or unsubstituted arylene group having 6 to 30 ring-forming carbon atoms or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

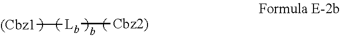

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, b may be an integer of 0 to 10, and if (e.g., when) b is an integer of 2 or greater, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are mere examples, and the compound represented by Formula E-2a or Formula E-2b is not limited to those represented in Compound Group E-2.

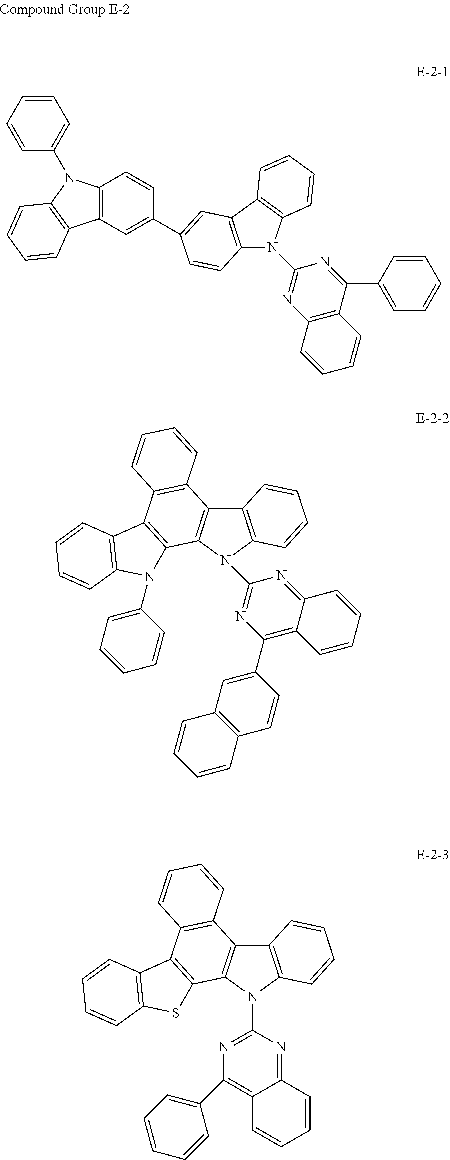 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

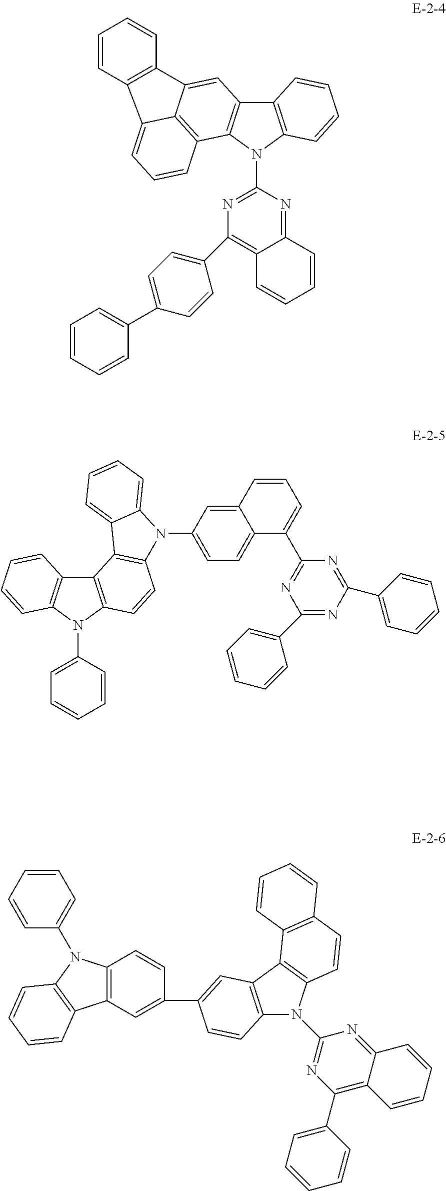 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

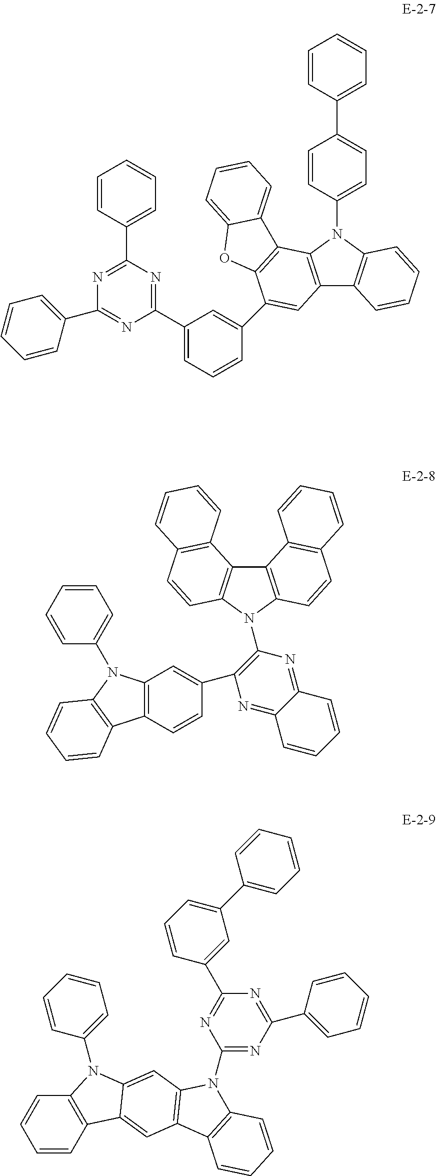 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

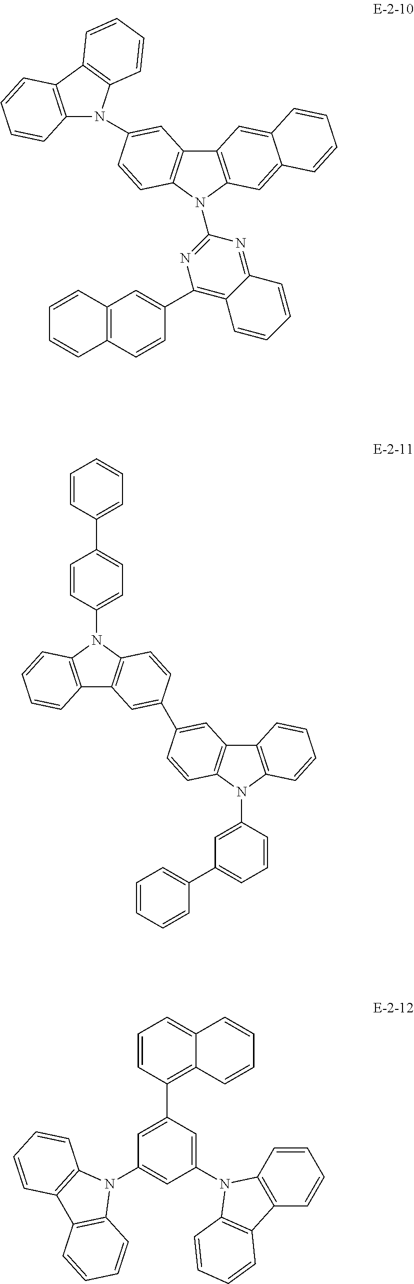 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

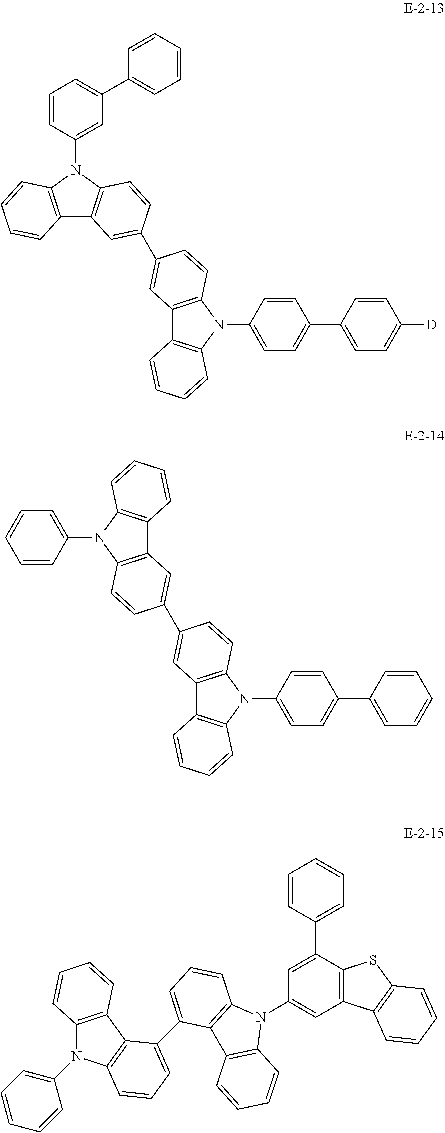 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

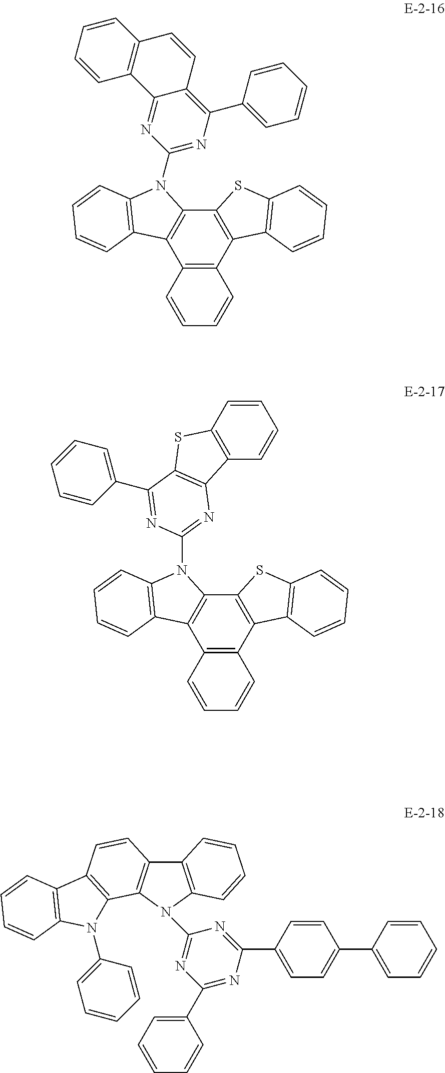 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

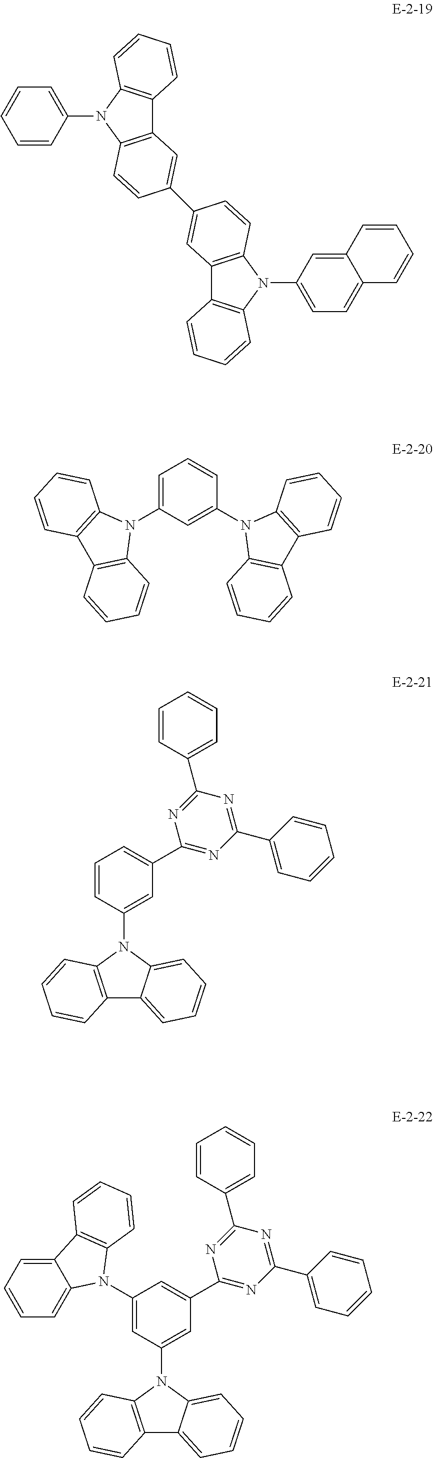 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

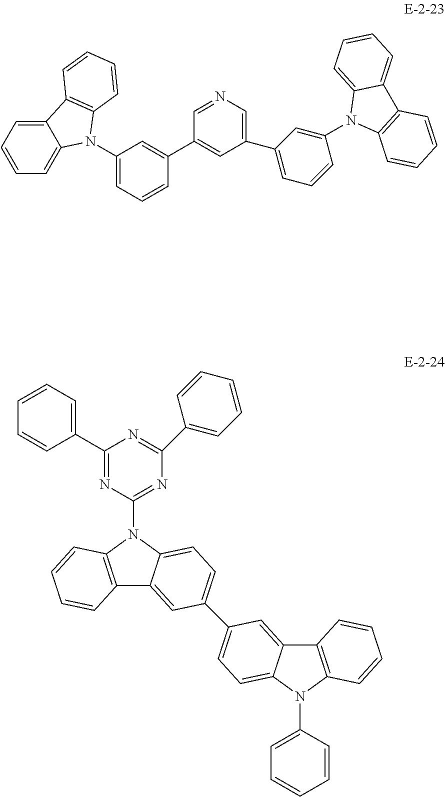 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto, for example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like, may be used as a host material.

In one or more embodiments, the emission layer EML may include a compound represented by Formula M-a. The compound represented by Formula M-a may be used as a phosphorescent dopant material.

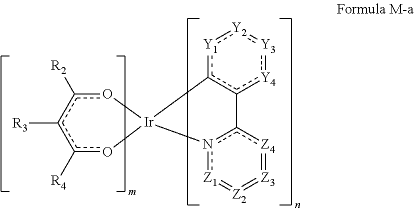

In Formula M-a, Y₁ to Y₄ and Z₁ to Z₄ may each independently be CR₁ or N, R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25.

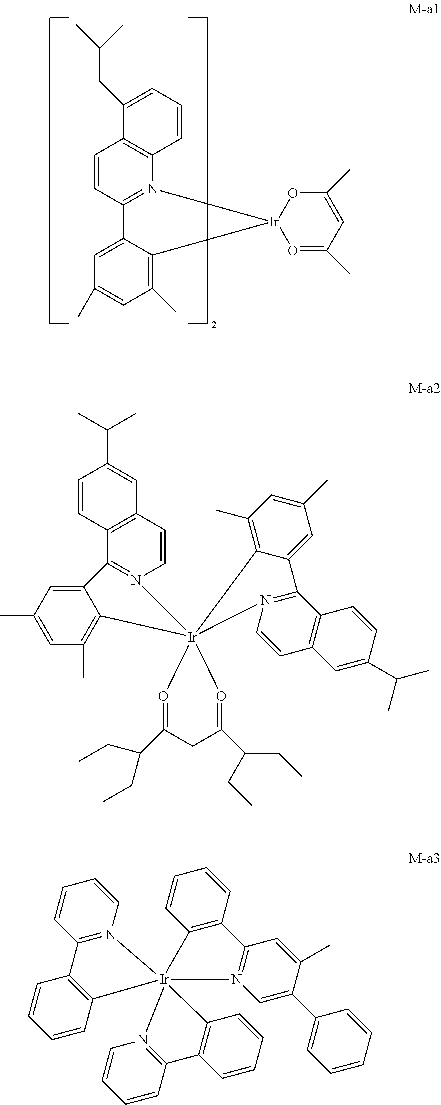

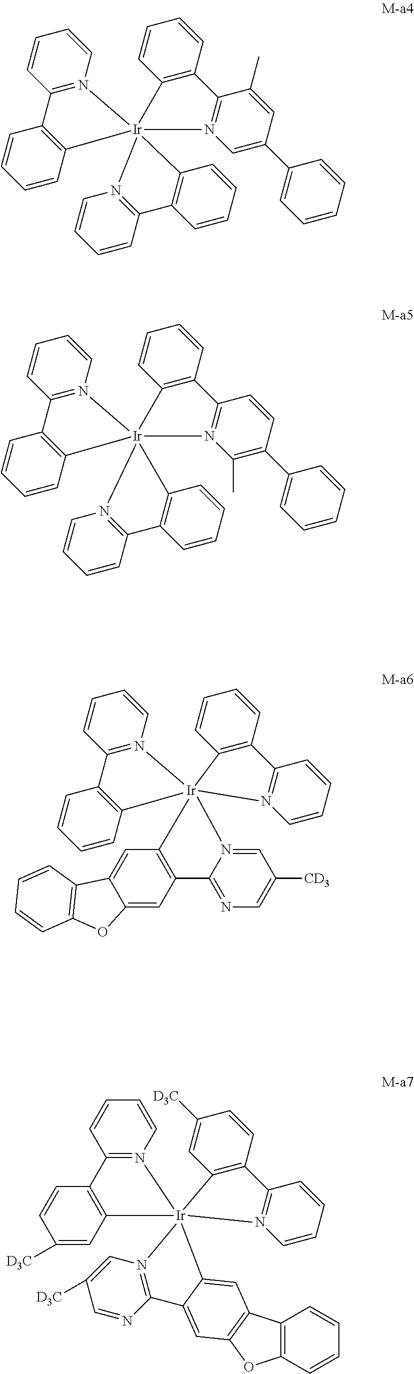

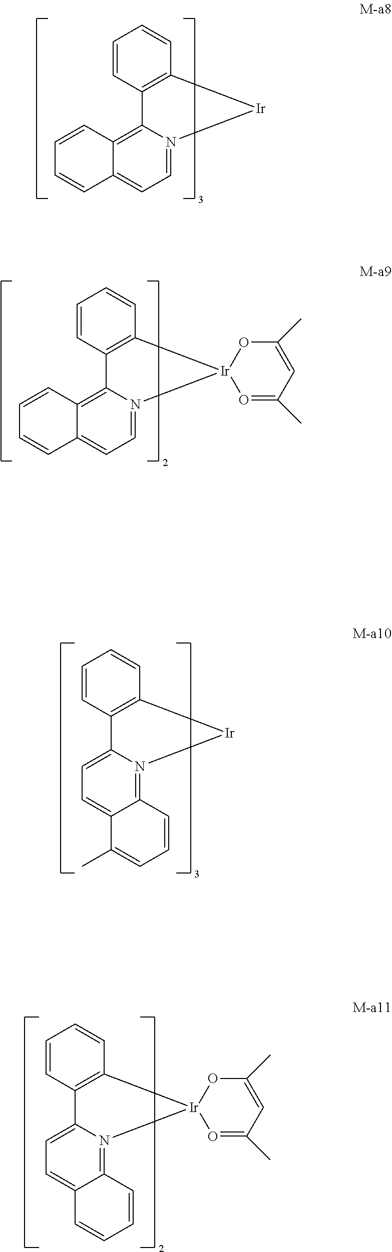

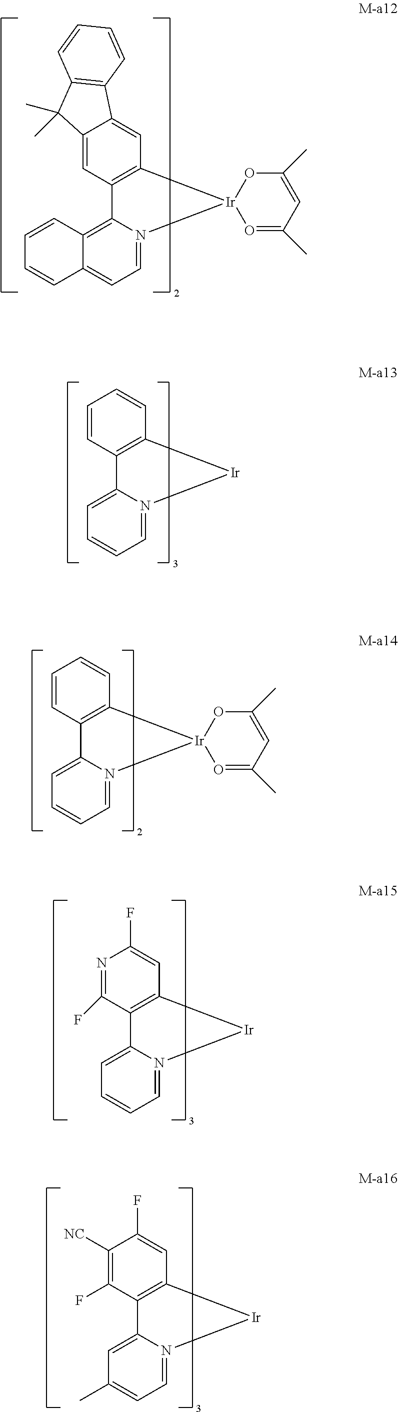

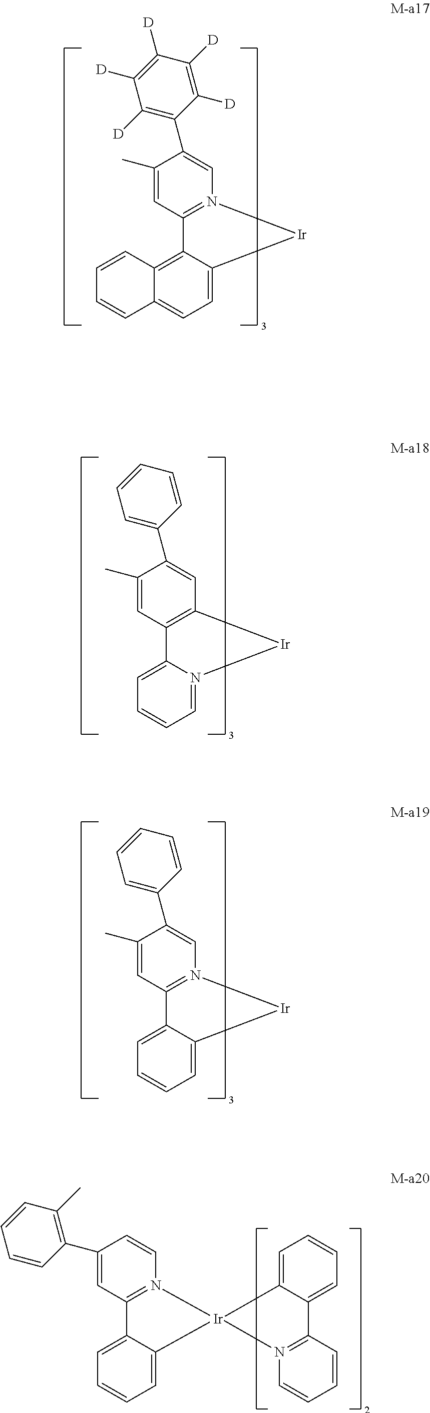

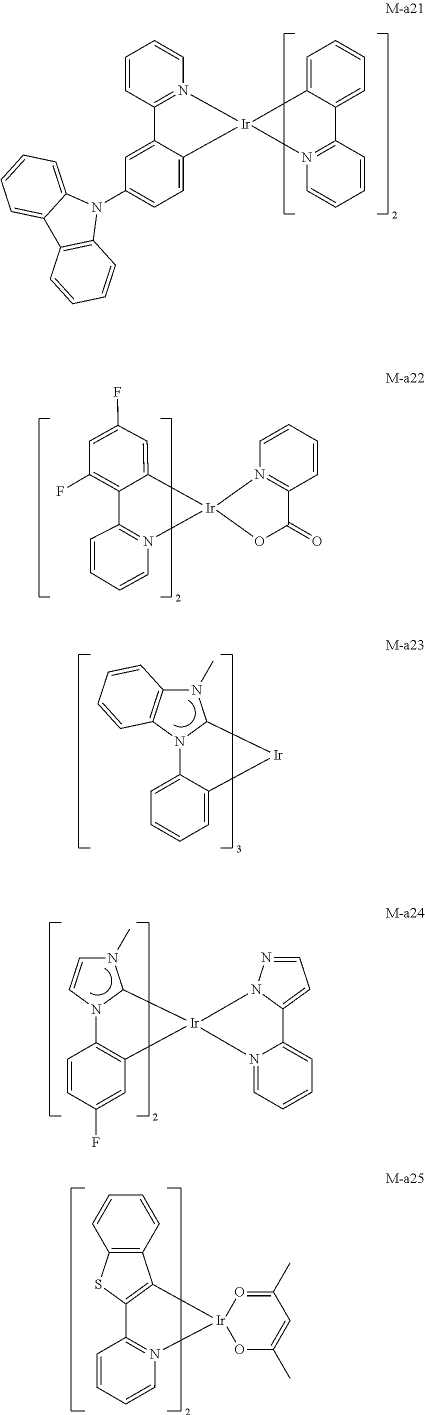

In one or more embodiments, the emission layer EML may include a compound represented by any one selected from among Formula F-a to Formula F-c. The compound represented by Formula F-a to Formula F-c may be used as a fluorescence dopant material.

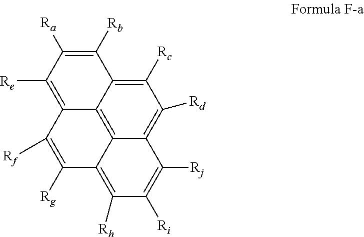

In Formula F-a, two selected from among Rₐ to Rⱼ may each independently be substituted with *—NAr₁Ar₂. The others, which are not substituted with *—NAr₁Ar₂, among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, at least one of Ar₁ or Ar₂ may be a heteroaryl group containing O or S as a ring-forming atom.

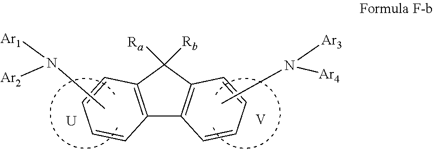

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a part of a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

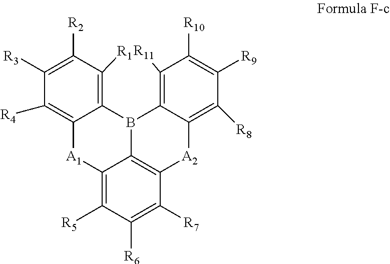

In Formula F-c, A₁ and A₂ may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, in Formula F-c, A₁ and A₂ may each independently be bonded to substituents of an adjacent ring to form a fused ring. For example, if (e.g., when) A₁ and A₂ may each independently be NRₘ, in one or more embodiments, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, one or more selected from among styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and/or the like.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (Flrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments of the present disclosure are not limited thereto.

In one or more embodiments, the emission layer may include quantum dots.

In the present disclosure, the quantum dot refers to a crystal of a semiconductor compound. The quantum dot may be to emit light having one or more suitable emission wavelengths depending on the size of crystal. The quantum dot may be to emit light having one or more suitable emission wavelengths as the elemental ratio in the quantum dot compound is adjusted.

The quantum dot may have a diameter of, for example, about 1 nm to about 10 nm. In the present disclosure, when dot, dots, or dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, a similar process thereto, and/or the like.

The wet chemical process is a method in which a precursor material of a quantum dot is mixed with an organic solvent to grow quantum dot particle crystals. When the crystals grow, the organic solvent naturally may act as a dispersant coordinated on the surface of the quantum dot crystals and control the growth of the crystals. Thus, the wet chemical process may control the growth of quantum dot particles through a process which is more easily performed than vapor deposition methods, such as metal organic chemical vapor deposition (MOCVD) or molecular beam epitaxy (MBE), and which is also performed at low costs.

In one or more embodiments, the emission layer EML may include a quantum dot material. In one or more embodiments, the quantum dot may have a core/shell structure. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and/or a (e.g., any suitable) combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a (e.g., any suitable) mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a (e.g., any suitable) mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a (e.g., any suitable) mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and a (e.g., any suitable) mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a (e.g., any suitable) mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a (e.g., any suitable) mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a (e.g., any suitable) mixture thereof. In one or more embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a (e.g., any suitable) mixture thereof, a ternary compound selected from the group consisting of SnSeS, SnSeTe, SnSTe, PbSeS, PbSeTe, PbSTe, SnPbS, SnPbSe, SnPbTe, and a (e.g., any suitable) mixture thereof, and a quaternary compound selected from the group consisting of SnPbSSe, SnPbSeTe, SnPbSTe, and a (e.g., any suitable) mixture thereof. The Group IV element may be selected from the group consisting of Si, Ge, and a (e.g., any suitable) mixture thereof. The Group IV compound may be a binary compound selected from the group consisting of SiC, SiGe, and a (e.g., any suitable) mixture thereof.

Each element included in a polynary compound such as the binary compound, the ternary compound, or the quaternary compound may be present in a particle with a substantially uniform or non-uniform concentration distribution. For example, the above formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In one or more embodiments, the quantum dot may have a single structure in which the concentration of each element included in the quantum dot is substantially uniform or a double structure of core-shell. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

In one or more embodiments, the quantum dot may have the above-described core/shell structure including a core containing nanocrystals and a shell around (e.g., surrounding) the core. An example of the shell of the quantum dot may include a metal or non-metal oxide, a semiconductor compound, and/or a (e.g., any suitable) combination thereof.

For example, the metal or non-metal oxide for the shell may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but embodiments of the present disclosure are not limited thereto.

Also, examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

Each element included in a polynary compound such as the binary compound, or the ternary compound may be present in a particle with a substantially uniform or non-uniform concentration distribution. For example, the formulae may refer to the types (kinds) of elements included in the compounds, but the elemental ratio in the compound may be different.

The quantum dot may have a full width of half maximum (FWHM) of an emission spectrum of about 45 nm or less, about 40 nm or less, or about 30 nm or less, and color purity or color reproducibility of the quantum dot may be improved in the above range. In addition, light emitted through such quantum dots is emitted in all directions so that a wide viewing angle may be improved.

In addition, although the form of the quantum dot is not particularly limited as long as it is a form commonly used in the art, for example, the quantum dot in the form of spherical nanoparticles, pyramidal nanoparticles, multi-arm nanoparticles, cubic nanoparticles, nanotubes, nanowires, nanofibers, nanoplate particles, and/or the like. may be used.

As the size of the quantum dot is adjusted or the elemental ratio in the quantum dot compound is adjusted, it may control the energy band gap of the quantum dot, and thus light in one or more suitable wavelength ranges may be obtained in a quantum dot emission layer. Therefore, when the quantum dot as above (e.g., using different sizes of quantum dots or different elemental ratios in the quantum dot compound) is used, the light emitting element, which emits light in one or more suitable wavelengths, may be implemented. For example, the adjustment of the size of the quantum dot or the elemental ratio in the quantum dot compound may be selected to enable the quantum dots to emit red, green, and/or blue light. In one or more embodiments, the quantum dots may be configured to emit white light by combining one or more suitable colors of light.

In each of the light emitting elements ED of embodiments illustrated in FIGS. 3 to 6, the electron transport region ETR may be provided on the emission layer EML. The electron transport region ETR may include at least one of a hole blocking layer HBL, an electron transport layer ETL, or an electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of an electron injection layer EIL or an electron transport layer ETL, or may have a single layer structure formed of an electron injection material and/or an electron transport material. In one or more embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order (e.g., in the stated order) from the emission layer EML, but embodiments of the present disclosure are not limited thereto. The electron transport region ETR may have a thickness, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2:

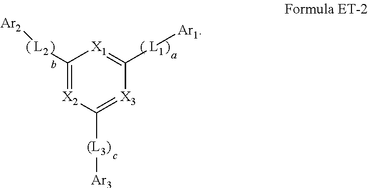

In Formula ET-2, at least one selected from among X₁ to X₃ may be N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c are each independently an integer of 2 or greater, L₁'s to L₃'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), and/or a (e.g., any suitable) mixture thereof.

In one or more embodiments, the electron transport region ETR may include at least one selected from among Compound ET1 to Compound ET36:

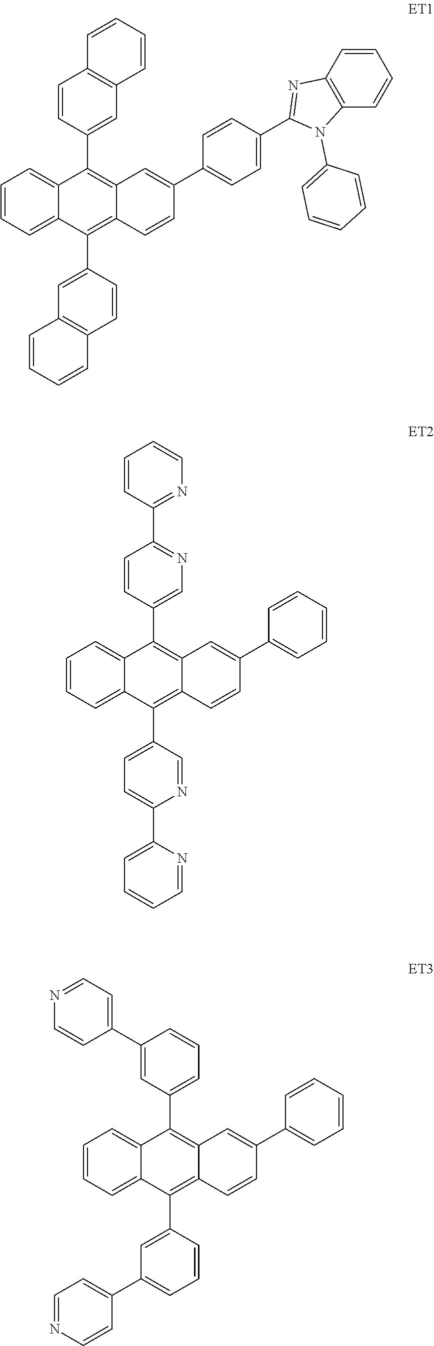 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

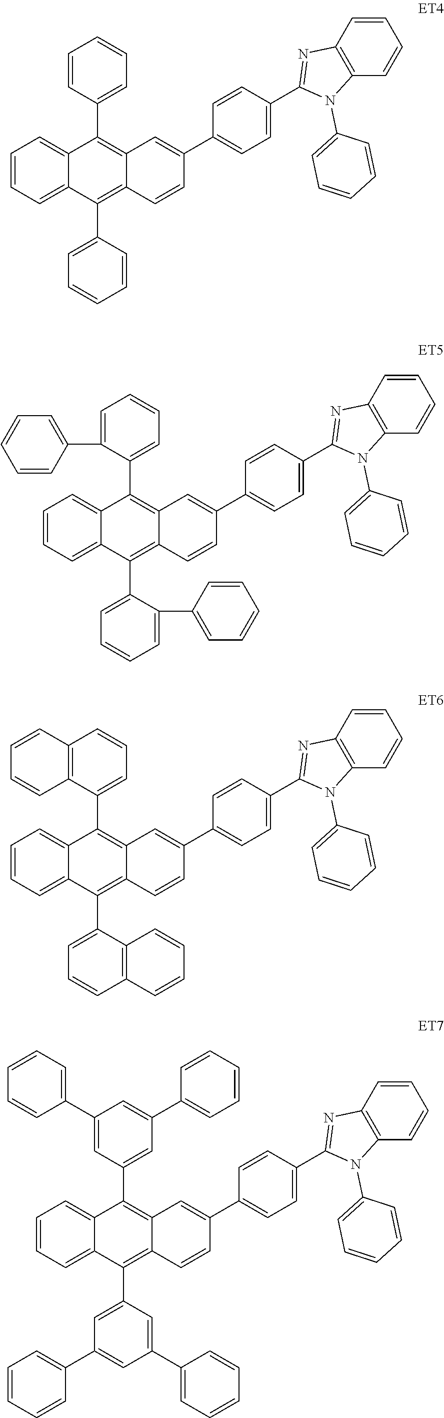 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

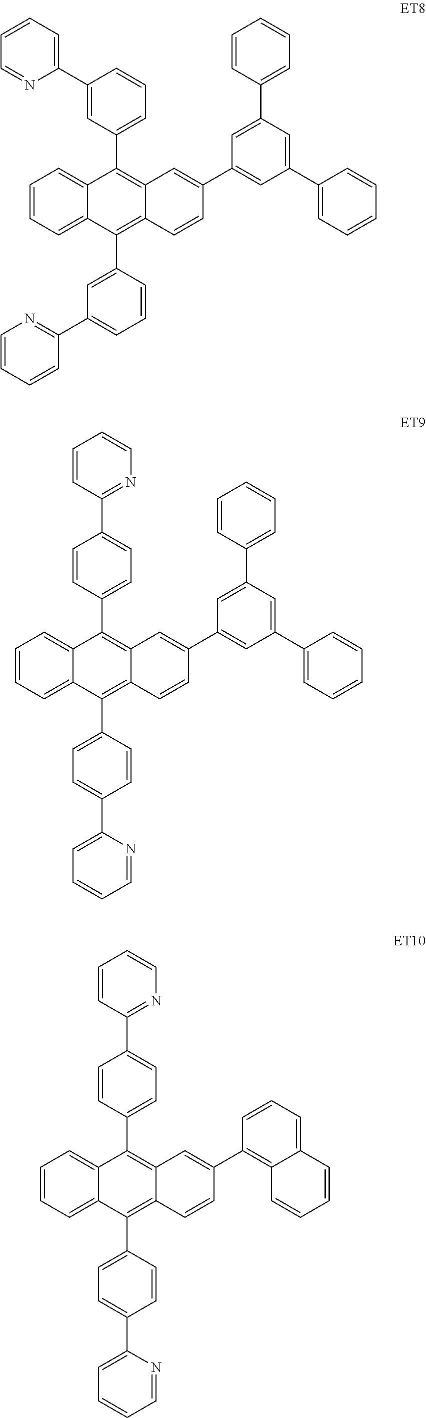 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

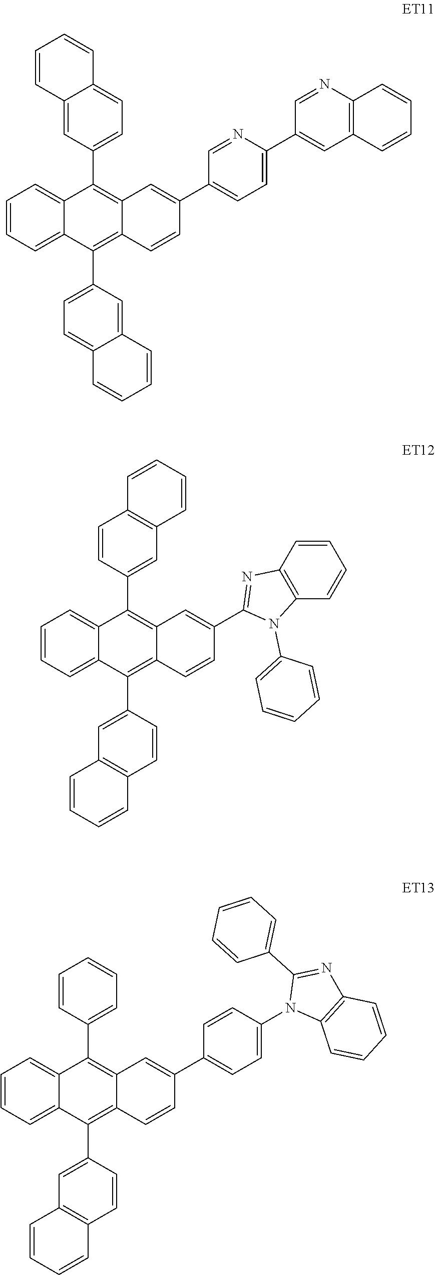 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

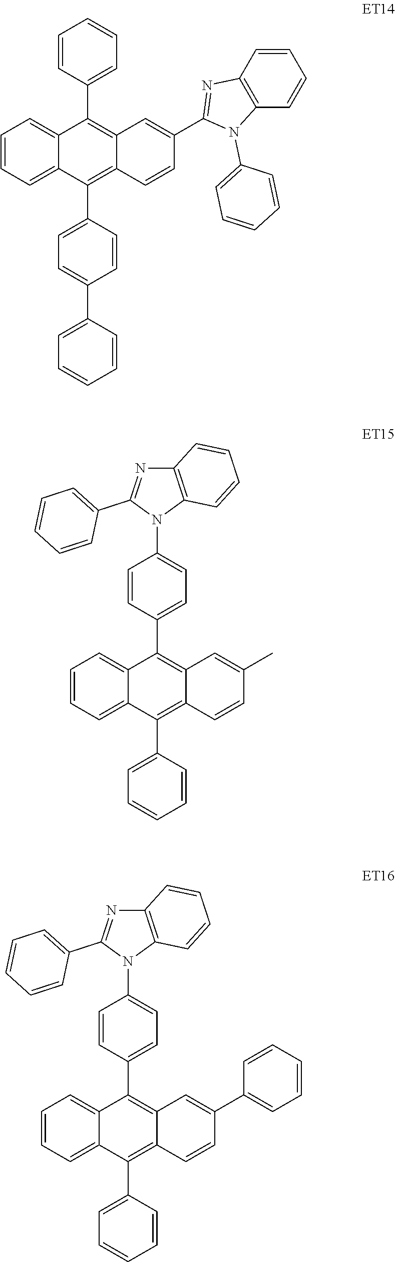 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

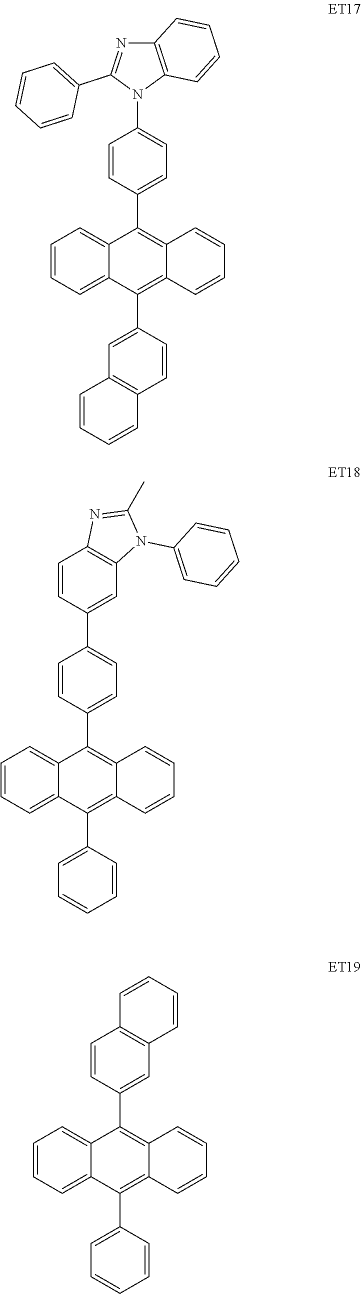

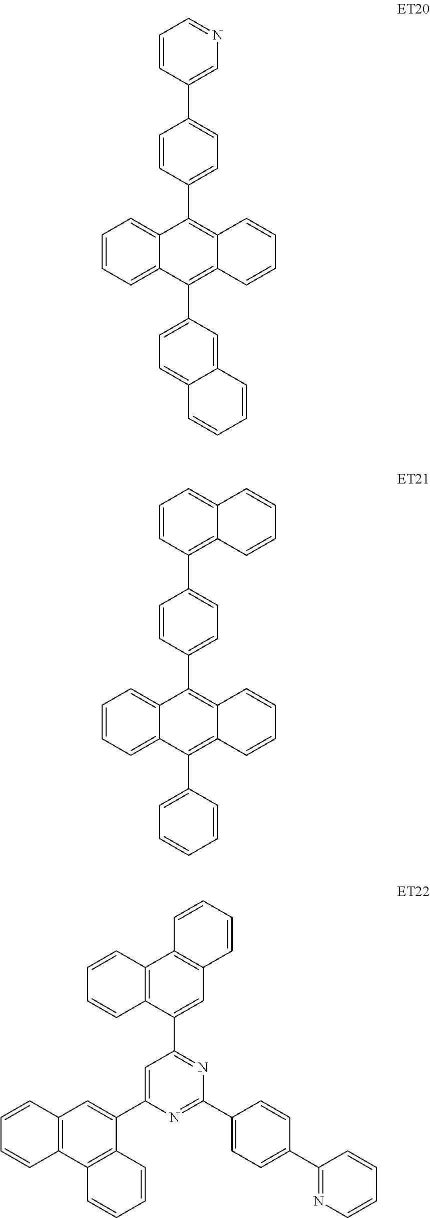

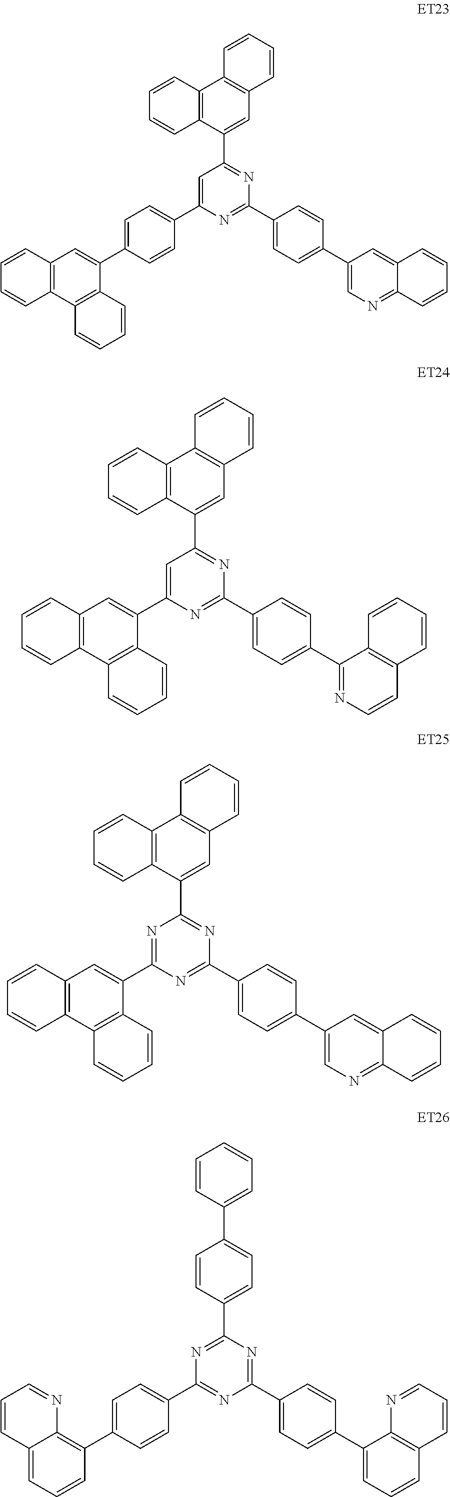 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

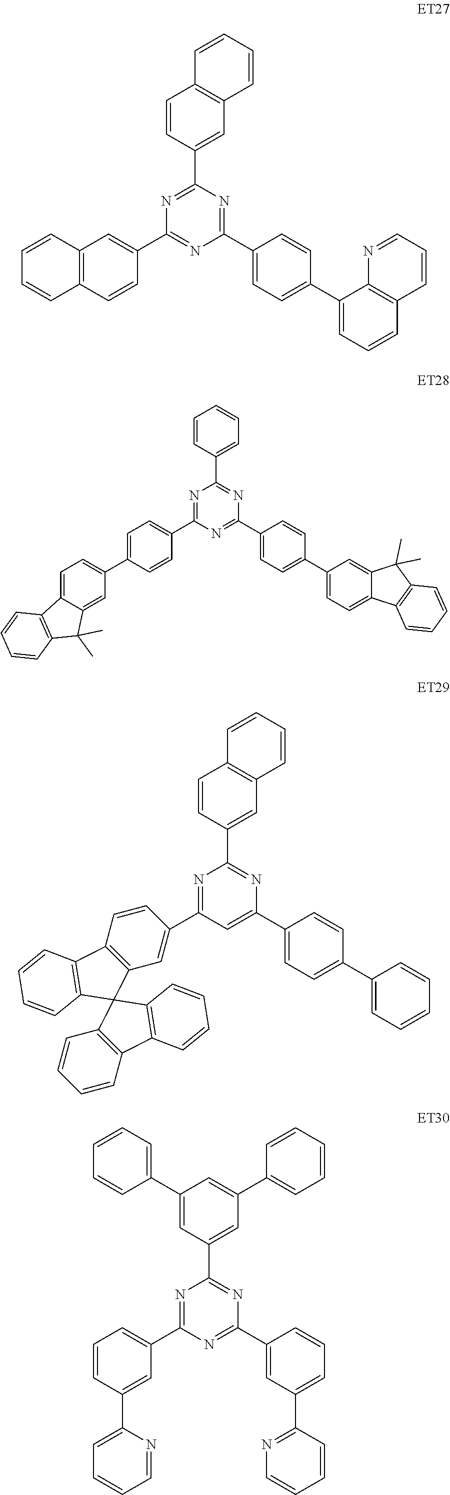

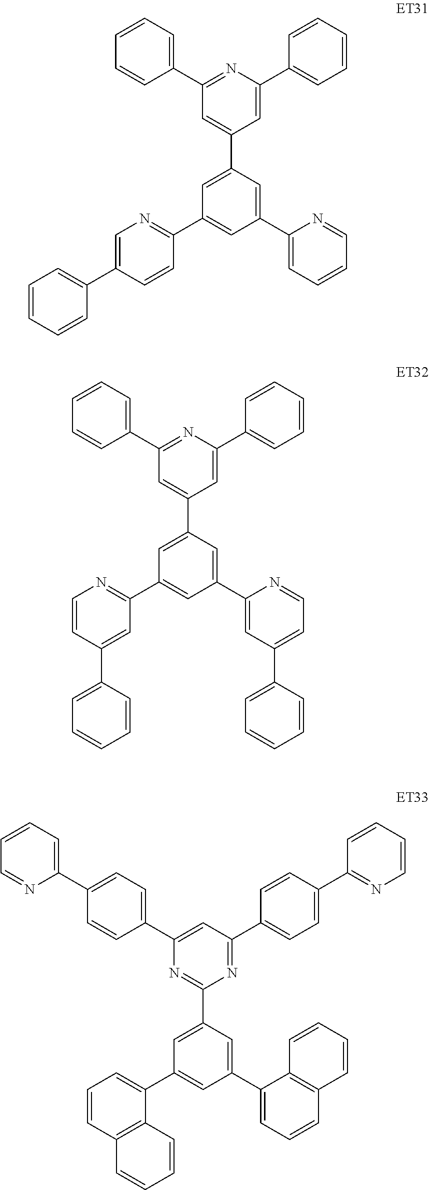 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

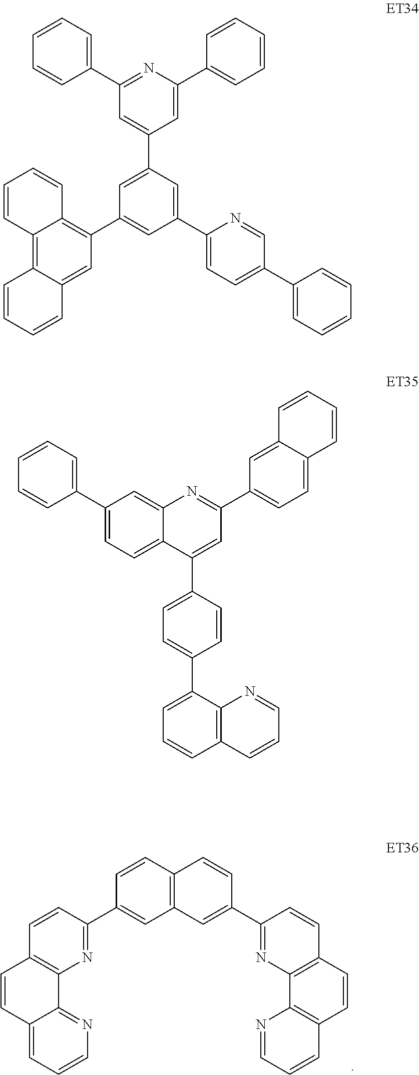 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCl, RbI, CuI, and/or KI, a lanthanide metal such as Yb, or a co-deposited material of the metal halide and the lanthanide metal. For example, in one or more embodiments, the electron transport region ETR may include KI:Yb, RbI:Yb, LiF:Yb, and/or the like, as a co-deposited material. In one or more embodiments, the electron transport region ETR may be formed using a metal oxide such as Li₂O and/or BaO, or 8-hydroxyl-lithium quinolate (Liq), and/or the like, but embodiments of the present disclosure are not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, one or more of a metal acetate, a metal benzoate, a metal acetoacetate, a metal acetylacetonate, or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the above-described materials, but embodiments of the present disclosure are not limited thereto.

The electron transport region ETR may include one or more of the above-described compounds of the hole transport region in at least one of an electron injection layer EIL, an electron transport layer ETL, or a hole blocking layer HBL.

If (e.g., when) the electron transport region ETR includes an electron transport layer ETL, the electron transport layer ETL may have a thickness of about 100 Å to about 1,000 Å, for example, about 150 Å to about 500 Å. If (e.g., when) the thickness of the electron transport layer ETL satisfies the aforementioned range, satisfactory electron transport characteristics may be obtained without a substantial increase in driving voltage. If (e.g., when) the electron transport region ETR includes an electron injection layer EIL, the electron injection layer EIL may have a thickness of about 1 Å to about 100 Å, for example, about 3 Å to about 90 Å. If (e.g., when) the thickness of the electron injection layer EIL satisfies the above-described range, satisfactory electron injection characteristics may be obtained without a substantial increase in driving voltage.

The second electrode EL2 may be provided on the electron transport region ETR. In one or more embodiments, the second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

If (e.g., when) the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In one or more embodiments, the second electrode EL2 may have a multilayer structure including a reflective film or a transflective film formed of one or more of the above-described materials, and a transparent conductive film formed of ITO, IZO, ZnO, ITZO, and/or the like. For example, in one or more embodiments, the second electrode EL2 may include one of the above-described metal materials, a (e.g., any suitable) combination of at least two metal materials of the above-described metal materials, an oxide of the above-described metal materials, and/or the like.

In one or more embodiments, the second electrode EL2 may be connected with an auxiliary electrode. If (e.g., when) the second electrode EL2 is connected with the auxiliary electrode, the resistance of the second electrode EL2 may be decreased.

In one or more embodiments, a capping layer CPL may further be arranged on the second electrode EL2 of the light emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ, SiO_{y}, and/or the like.

For example, in one or more embodiments, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, embodiments of the present disclosure are not limited thereto, for example, the capping layer CPL may include at least one selected from among Compounds P1 to P5:

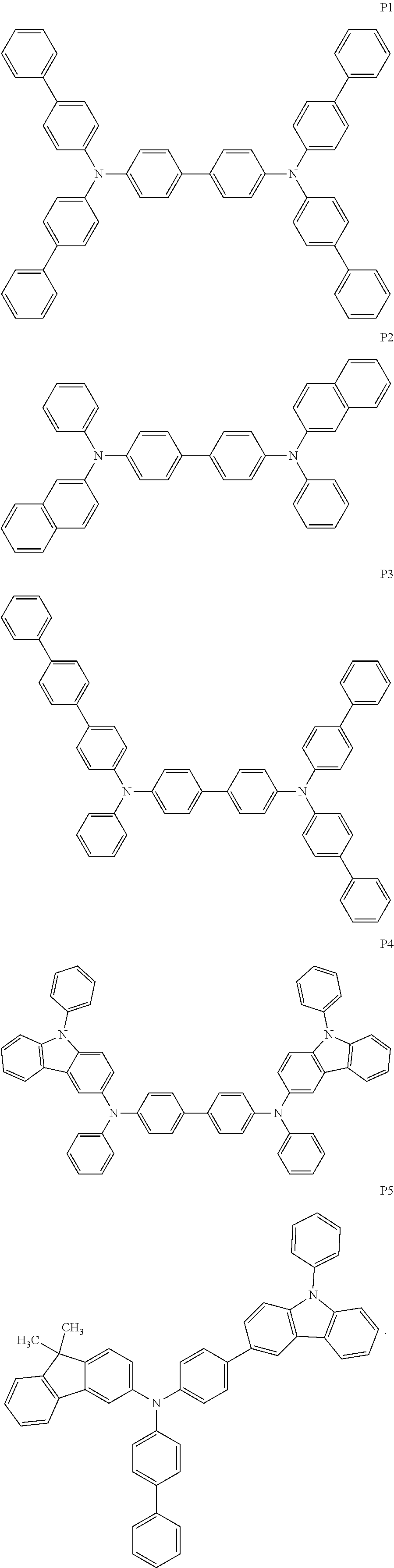 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, in one or more embodiments, the refractive index of the capping layer CPL may be about 1.6 or more with respect to light in a wavelength range of about 550 nm to about 660 nm.

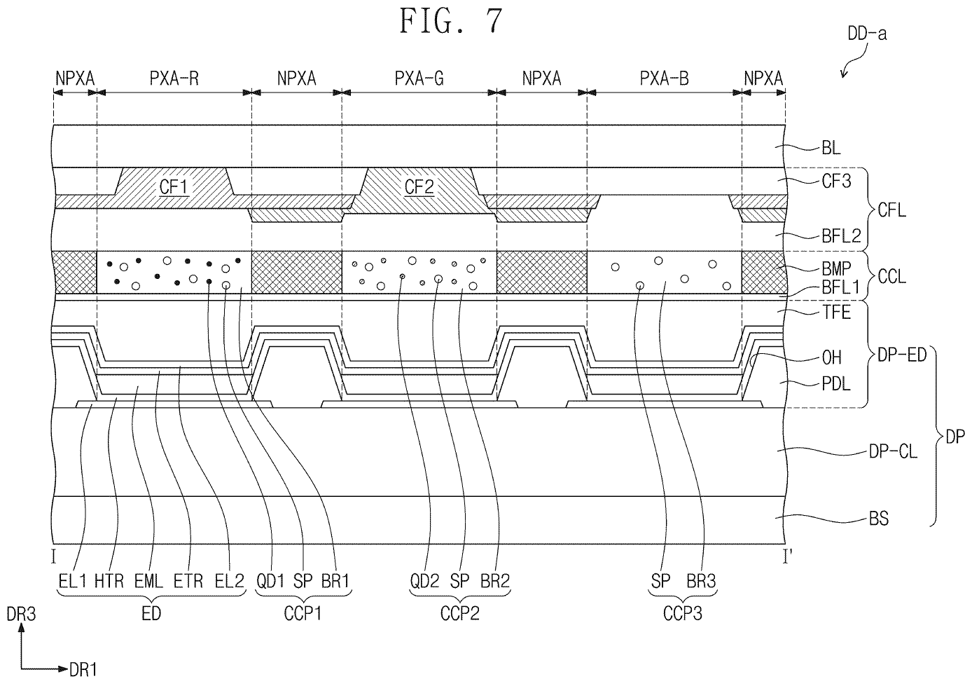

Each of FIGS. 7 to 10 is a cross-sectional view of a display device according to one or more embodiments of the present disclosure. Hereinafter, in describing the display devices of embodiments with reference to FIGS. 7 to 10, the duplicated features which have been described in FIGS. 1 to 6 are not described again for conciseness, instead only their differences will be mainly described.

Referring to FIG. 7, the display device DD-a according to one or more embodiments may include a display panel DP including a display device layer DP-ED (also referred as display element layer), a light control layer CCL arranged on the display panel DP, and a color filter layer CFL. In one or more embodiments illustrated in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the structure of any one of the light emitting elements of FIGS. 3 to 6 described above may be equally applied to the structure of the light emitting element ED illustrated in FIG. 7.

The emission layer EML of the light emitting element ED included in the display device DD-a according to one or more embodiments may include the above-described fused polycyclic compound of one or more embodiments.

Referring to FIG. 7, the emission layer EML may be arranged in an opening OH defined in a pixel defining film PDL. For example, the emission layer EML which is divided by the pixel defining film PDL and provided corresponding to each of light emitting regions PXA-R, PXA-G, and PXA-B may be to emit light in substantially the same wavelength range. In the display device DD-a of one or more embodiments, the emission layer EML may be to emit blue light. In one or more embodiments, the emission layer EML may be provided as a common layer across the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing a quantum dot or a layer containing a phosphor.

The light control layer CCL may include a plurality of light control parts CCP1, CCP2, and CCP3. The light control parts CCP1, CCP2, and CCP3 may be spaced and/or apart (e.g., spaced apart or separated) from one another.

Referring to FIG. 7, divided patterns BMP may be arranged between the light control parts CCP1, CCP2, and CCP3 which are spaced and/or apart (e.g., spaced apart or separated) from one another, but embodiments of the present disclosure are not limited thereto. FIG. 7 illustrates that the divided patterns BMP do not overlap the light control parts CCP1, CCP2, and CCP3, but, in one or more embodiments, at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, in one or more embodiments, the first quantum dot QD1 may be a red quantum dot to emit red light, and the second quantum dot QD2 may be a green quantum dot to emit green light. The same as described above on quantum dots may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. In one or more embodiments, the scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed accordingly. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed accordingly, and may be formed of one or more suitable resin compositions, which may be generally referred to as a binder. For example, the base resins BR1, BR2, and BR3 may each independently be an acrylic-based resin, a urethane-based resin, a silicone-based resin, an epoxy-based resin, and/or the like. The base resins BR1, BR2, and BR3 may each be transparent resins. In one or more embodiments, the first base resin BR1, the second base resin BR2, and the third base resin BR3 may be the same as or different from one another.

In one or more embodiments, the light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2, and CCP3 from being exposed to moisture/oxygen. In one or more embodiments, the barrier layer BFL1 may cover the light control parts CCP1, CCP2, and CCP3. In one or more embodiments, the barrier layer BFL2 may be provided between the light control parts CCP1, CCP2, and CCP3 and the color filter layer CFL.

The barrier layers BFL1 and BFL2 may each include at least one inorganic layer. For example, in one or more embodiments, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may each independently further include an organic film. The barrier layers BFL1 and BFL2 may be formed of a single layer or a plurality of layers.

In the display device DD-a of one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, in one or more embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. The first filter CF1 may include a red pigment and/or a red dye, the second filter CF2 may include a green pigment and/or a green dye, and the third filter CF3 may include a blue pigment and/or a blue dye.

In one or more embodiments, the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in one or more embodiments, the first filter CF1 and the second filter CF2 may each be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment and/or a black dye. The light shielding part may prevent or reduce light leakage, and may separate boundaries between adjacent filters CF1, CF2, and CF3.

The first to third filters CF1, CF2, and CF3 may be arranged corresponding to the red light emitting region PXA-R, the green light emitting region PXA-G, and the blue light emitting region PXA-B, respectively.

In one or more embodiments, a base substrate BL may be arranged on the color filter layer CFL. The base substrate BL may be a member which provides a base surface on which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

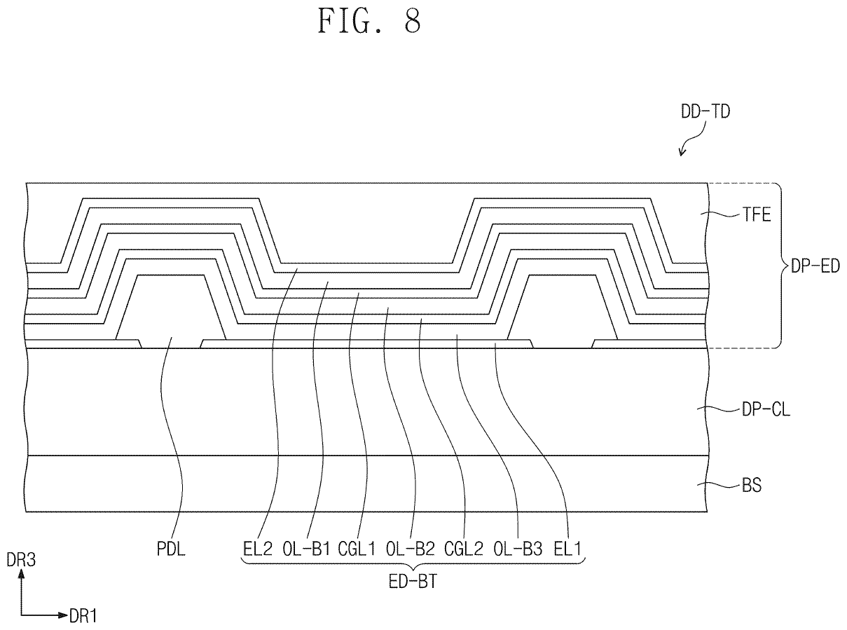

FIG. 8 is a cross-sectional view illustrating a portion of a display device according to one or more embodiments. In a display device DD-TD of one or more embodiments, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in a thickness direction between the first electrode EL1 and the second electrode EL2. The light emitting structures OL-B1, OL-B2, and OL-B3 each may include an emission layer EML (FIG. 7) and a hole transport region HTR and an electron transport region ETR arranged with the emission layer EML (FIG. 7) located therebetween.

For example, the light emitting element ED-BT included in the display device DD-TD of one or more embodiments may be a light emitting element having a tandem structure and including a plurality of emission layers.

In one or more embodiments illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from one another. For example, in one or more embodiments, the light emitting element ED-BT including the plurality of light emitting structures OL-B1, OL-B2, and OL-B3 which emit light beams having wavelength ranges different from one another may be to emit white light (e.g., combined white light).

Charge generation layers CGL1 and CGL2 may be respectively arranged between two of the neighboring light emitting structures OL-B1, OL-B2, and OL-B3. The charge generation layers CGL1 and CGL2 may each independently include a p-type (kind) charge (e.g., P-charge) generation layer and/or an n-type (kind) charge (e.g., N-charge) generation layer.

At least one selected from among the light emitting structures OL-B1, OL-B2, and OL-B3 included in the display device DD-TD of one or more embodiments may include the above-described fused polycyclic compound of one or more embodiments. For example, at least one selected from among the plurality of emission layers included in the light emitting element ED-BT may include the fused polycyclic compound of one or more embodiments.

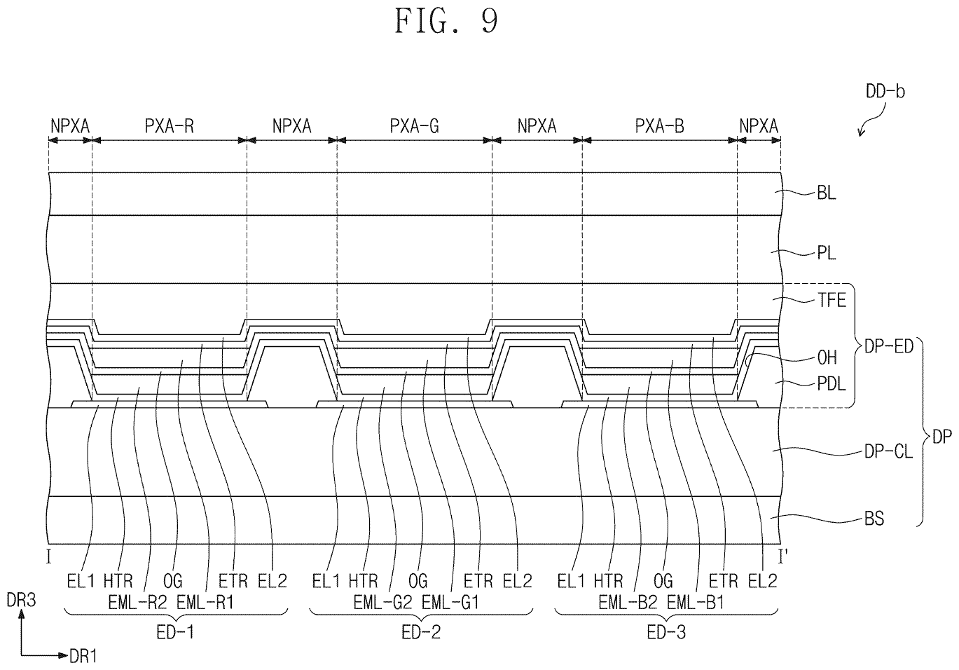

Referring to FIG. 9, a display device DD-b according to one or more embodiments may include light emitting elements ED-1, ED-2, and ED-3 in each of which two emission layers are stacked. Compared with the display device DD of one or more embodiments illustrated in FIG. 2, the display device DD-b illustrated in FIG. 9 has a difference in that the first to third light emitting elements ED-1, ED-2, and ED-3 each include two emission layers stacked in a thickness direction. In each of the first to third light emitting elements ED-1, ED-2, and ED-3, the two emission layers may be to emit light in substantially the same wavelength region.

In one or more embodiments, the first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. An emission auxiliary part OG may be separately arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In one or more embodiments, the emission auxiliary part OG may include an electron transport region, a charge generation layer, and a hole transport region that are sequentially stacked (e.g., in the stated order). The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be arranged between the emission auxiliary part OG and the electron transport region ETR. The second red emission layer EML-R2, the second green emission layer EML-G2, and the second blue emission layer EML-B2 may each be arranged between the hole transport region HTR and the emission auxiliary part OG.

For example, in one or more embodiments, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2 that are sequentially stacked (e.g., in the stated order). The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2 that are sequentially stacked (e.g., in the stated order). The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2 that are sequentially stacked (e.g., in the stated order).

In one or more embodiments, an optical auxiliary layer PL may be arranged on the display device layer DP-ED. The optical auxiliary layer PL may include a polarizing layer. The optical auxiliary layer PL may be arranged on the display panel DP and control reflected light in the display panel DP due to external light. In one or more embodiments, the optical auxiliary layer PL may not be provided in the display device.

At least one emission layer included in the display device DD-b of one or more embodiments illustrated in FIG. 9 may include the above-described fused polycyclic compound of one or more embodiments. For example, in one or more embodiments, at least one of the first blue emission layer EML-B1 or the second blue emission layer may include the fused polycyclic compound of one or more embodiments.

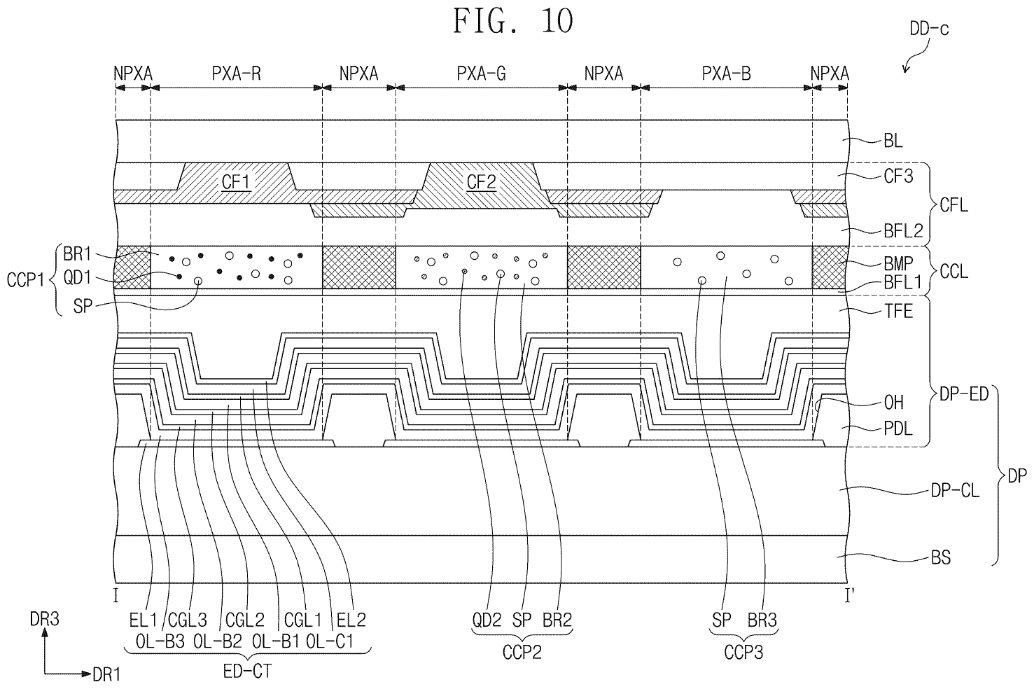

Unlike FIG. 8 and FIG. 9, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be separately arranged between the first to fourth light emitting structures OL-B1, OL-B2, OL-B3, and OL-C1, accordingly. In one or more embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light beams in different wavelength regions.

The charge generation layers CGL1, CGL2, and CGL3 arranged between adjacent light emitting structures OL-B1, OL-B2, OL-B3, and OL-C1 may each independently include a p-type (kind) charge (e.g., P-charge) generation layer and/or an n-type (kind) charge (e.g., N-charge) generation layer.

At least one selected from among the light emitting structures OL-B1, OL-B2, OL-B3, and OL-C1 included in the display device DD-c of one or more embodiments may include the above-described fused polycyclic compound of one or more embodiments. For example, in one or more embodiments, at least one selected from among the first to third light emitting structures OL-B1, OL-B2, and OL-B3 may include the described-above fused polycyclic compound of one or more embodiments.

The light emitting element ED according to one or more embodiments of the present disclosure may include the above-described polycyclic compound represented by Formula 1 of one or more embodiments in at least one functional layer arranged between the first electrode EL1 and the second electrode EL2, thereby exhibiting excellent or suitable luminous efficiency and improved service life characteristics. For example, the fused polycyclic compound according to one or more embodiments may be included in the emission layer EML of the light emitting element ED of one or more embodiments, and the light emitting element of one or more embodiments may exhibit a long service life characteristic.

In one or more embodiments, an electronic apparatus may include a display device including a plurality of light emitting elements, and a control part which controls the display device. The electronic apparatus of one or more embodiments may be a device that is activated according to an electrical signal. The electronic apparatus may include display devices of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

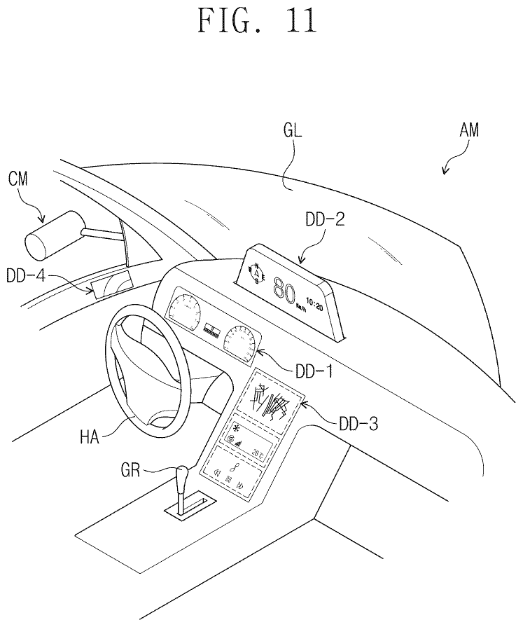

FIG. 11 is a view illustrating a vehicle AM in which first to fourth display devices DD-1, DD-2, DD-3, and DD-4 are arranged. At least one selected from among the first to fourth display devices DD-1, DD-2, DD-3, and DD-4 may include the same configuration as one of the display devices DD, DD-TD, DD-a, DD-b, and DD-c described with reference to FIGS. 1, and 2, and 7 to 10.

FIG. 11 illustrates a vehicle AM, but this is a mere example, and the first to fourth display devices DD-1, DD-2, DD-3, and DD-4 may be arranged in other transportation apparatuses such as bicycles, motorcycles, trains, ships, and/or airplanes. In one or more embodiments, at least one selected from among the first to fourth display devices DD-1, DD-2, DD-3, and DD-4 including the same configuration as one of the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. These are merely provided as example embodiments, and thus the display device may be employed in other electronic apparatuses unless departing from the disclosure.

At least one selected from among the first to fourth display devices DD-1, DD-2, DD-3, and DD-4 may include the light emitting element ED of one or more embodiments described with reference to FIGS. 3 to 6.

The light emitting element ED of one or more embodiments may include a fused polycyclic compound of one or more embodiments. At least one selected from among the first to fourth display devices DD-1, DD-2, DD-3, and DD-4 may include the light emitting element ED including the fused polycyclic compound of one or more embodiments, thereby improving a display service life.

Referring to FIG. 11, the vehicle AM may include a steering wheel HA and a gear GR for driving the vehicle AM. In addition, the vehicle AM may include a front window GL arranged so as to face a driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. The first scale and the second scale may be each indicated as a digital image.

The second display device DD-2 may be arranged in a second region opposite to (e.g., facing) a driver seat and overlapping the front window GL. The driver seat may be a seat in which the steering wheel HA faces. For example, the second display device DD-2 may be a head up display (HUD) which displays second information of the vehicle AM. The second display device DD-2 may be optically transparent. The second information may include digital numbers which indicate a driving speed, and may further include information such as the current time. In one or more embodiments, the second information of the second display device DD-2 may be projected to the front window GL to be displayed.

The third display device DD-3 may be arranged in a third region adjacent to the gear GR. For example, the third display device DD-3 may be arranged between the driver seat and a passenger seat and may be a center information display (CID) for the vehicle for displaying third information. The passenger seat may be a seat spaced and/or apart (e.g., spaced apart or separated) from the driver seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR, and may be arranged in a fourth region adjacent to a side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may each include different information. However, embodiments of the present disclosure are not limited thereto, and a part of the first to fourth information may include the same information as one another.

Hereinafter, with reference to Examples and Comparative Examples, a fused polycyclic compound according to one or more embodiments of the present disclosure and a light emitting element of one or more embodiments will be described in more detail. In addition, Examples described herein are mere illustrations to assist the understanding of the disclosure, and the scope of the disclosure is not limited thereto.

### EXAMPLE

### 1. Synthesis of Fused Polycyclic Compounds of Examples

First, a synthetic method of the fused polycyclic compound according to the example embodiments will be described in more detail by illustrating synthetic methods of Compounds 1, 3, 4, 9, 13, 23, 33, 49, 67, 93, and 131. In addition, the synthetic methods of the fused polycyclic compounds as described herein are mere examples, and the synthetic method of the fused polycyclic compound according to one or more embodiments of the present disclosure is not limited to the following examples.

### (1) Synthesis of Fused Polycyclic Compound 1

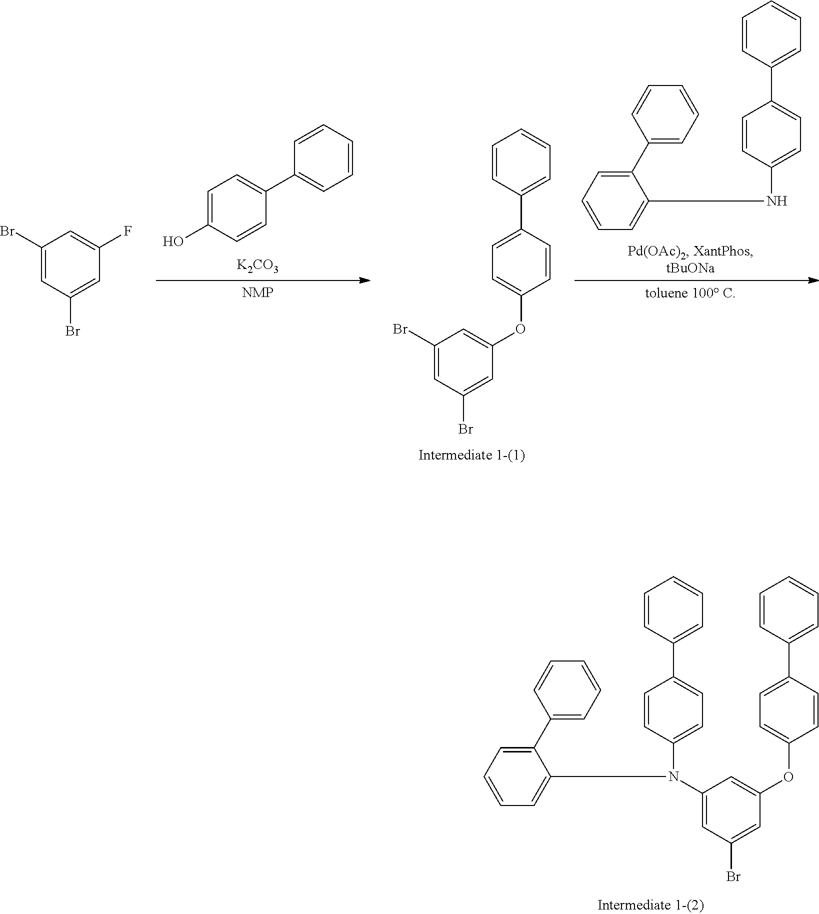

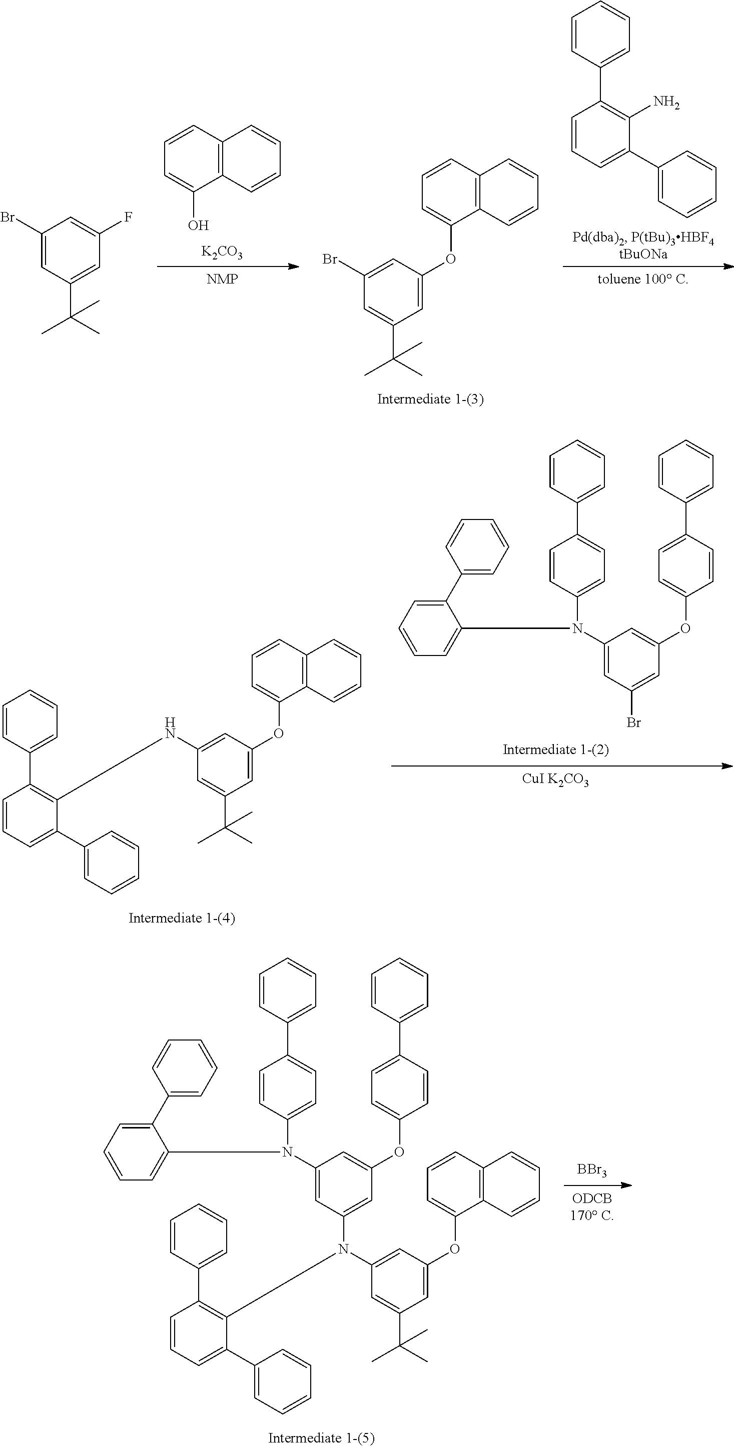

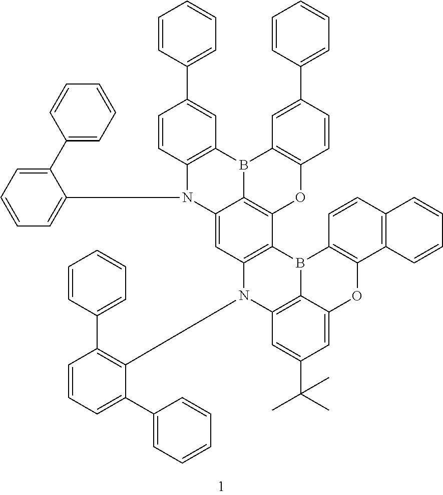 [SMILES: CC(C)(C)c1cc2c3c(c1)N(c1c(-c4ccccc4)cccc1-c1ccccc1)c1cc4c5c(c1B3c1ccc3ccccc3c1O2)Oc1ccc(-c2ccccc2)cc1B5c1cc(-c2ccccc2)ccc1N4c1ccccc1-c1ccccc1]

### Synthesis of Intermediate Compound 1-(1)

In an Ar atmosphere, 1,3-dibromo-5-fluorobenzene (6.42 g, 25.29 mmol) and [1,1′-biphenyl]-4-ol (5.16 g, 30.34 mmol), K₂CO₃ (15.73 g, 113.78 mmol), and N-methylpyrrolidone (NMP) (64 mL) were added and mixed, and the resulting mixture was heated for about 24 hours while maintaining the ambient temperature at about 140° C. The mixture was then cooled and diluted with CH₂Cl₂, water was added thereto, and the resultant mixture was filtered through Celite and then subjected to liquid separation to concentrate an organic layer. The organic layer was purified by silica gel column chromatography to afford Intermediate Compound 1-(1) (8.58 g, yield: 84%). The molecular weight of Intermediate Compound 1-(1) was about 404 as measured by fast atom bombardment mass spectrometry (FAB MS).

### Synthesis of Intermediate Compound 1-(2)

In an Ar atmosphere, Intermediate Compound 1-(1) (8.33 g, 20.61 mmol), N-([1,1′-biphenyl]-4-yl)-[1,1′-biphenyl]-2-amine (7.29 g, 22.68 mmol), Pd(OAc)₂ (0.14 g, 0.62 mmol), (9,9-dimethyl-9H-xanthene-4,5-diyl)bis(diphenylphosphane) (XantPhos) (0.72 g, 1.24 mmol), and tBuONa (2.38 g, 24.74 mmol) were added to 103 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 1-(2) (11.69 g, yield: 88%). The molecular weight of Intermediate Compound 1-(2) was about 645 as measured by FAB MS.

### Synthesis of Intermediate Compound 1-(3)

In an Ar atmosphere, 1-bromo-3-(tert-butyl)-5-fluorobenzene (6.23 g, 26.96 mmol), naphthalen-1-ol (4.66 g, 32.35 mmol), and K₂CO₃ (16.77 g, 121.31 mmol) were added to 62 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and then subjected to liquid separation to concentrate an organic layer. The organic layer was purified by silica gel column chromatography to afford Intermediate Compound 1-(3) (8.62 g, yield: 90%). The molecular weight of Intermediate Compound 1-(3) was about 355 as measured by FAB MS.

### Synthesis of Intermediate Compound 1-(4)

In an Ar atmosphere, Intermediate Compound 1-(3) (8.51 g, 23.95 mmol), [1,1′:3′,1″-terphenyl]-2′-amine (7.05 g, 28.74 mmol), bis(dibenzylideneacetone)palladium(0) (Pd(dba)₂) (1.38 g, 2.4 mmol), P(tBu)₃·HBF₄ (1.39 g, 4.79 mmol), and tBuONa (5.29 g, 55.09 mmol) were added to 119 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 1-(4) (10.95 g, yield: 88%). The molecular weight of Intermediate Compound 1-(4) was about 520 as measured by FAB MS.

### Synthesis of Intermediate Compound 1-(5)

A small amount of toluene (about 10 mL) was added to Intermediate Compound 1-(4) (1.80 g, 3.46 mmol), Intermediate Compound 1-(2) (11.16 g, 17.32 mmol), CuI (1.39 g, 7.27 mmol), and K₂CO₃ (4.79 g, 34.64 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 1-(5) (2.78 g, yield: 74%). The molecular weight of Intermediate Compound 1-(5) was about 1083 as measured by FAB MS.

### Synthesis of Compound 1

In an Ar atmosphere, Intermediate Compound 1-(5) (2.62 g, 2.42 mmol) was dissolved in ortho dichlorobenzene (ODCB) (24 mL), BBr₃ (1.21 g, 4.84 mmol) was added thereto, and the resulting mixture was heated and stirred at about 170° C. for about 10 hours. The mixture was then cooled to room temperature, N,N-diisopropylethylamine (DIPEA) (3.74 g, 29.02 mmol) was added thereto, water was added thereto, and the resulting mixture was filtered through Celite and subjected to liquid separation to concentrate an organic layer. The organic layer was purified by silica gel column chromatography to afford Compound 1 (0.88 g, yield: 33%). The molecular weight of Compound 1 was about 1099 as measured by FAB MS measurement.

The purification by sublimation was further performed (350° C., 2.7×10⁻³ Pa) for device evaluation.

### (2) Synthesis of Fused Polycyclic Compound 3

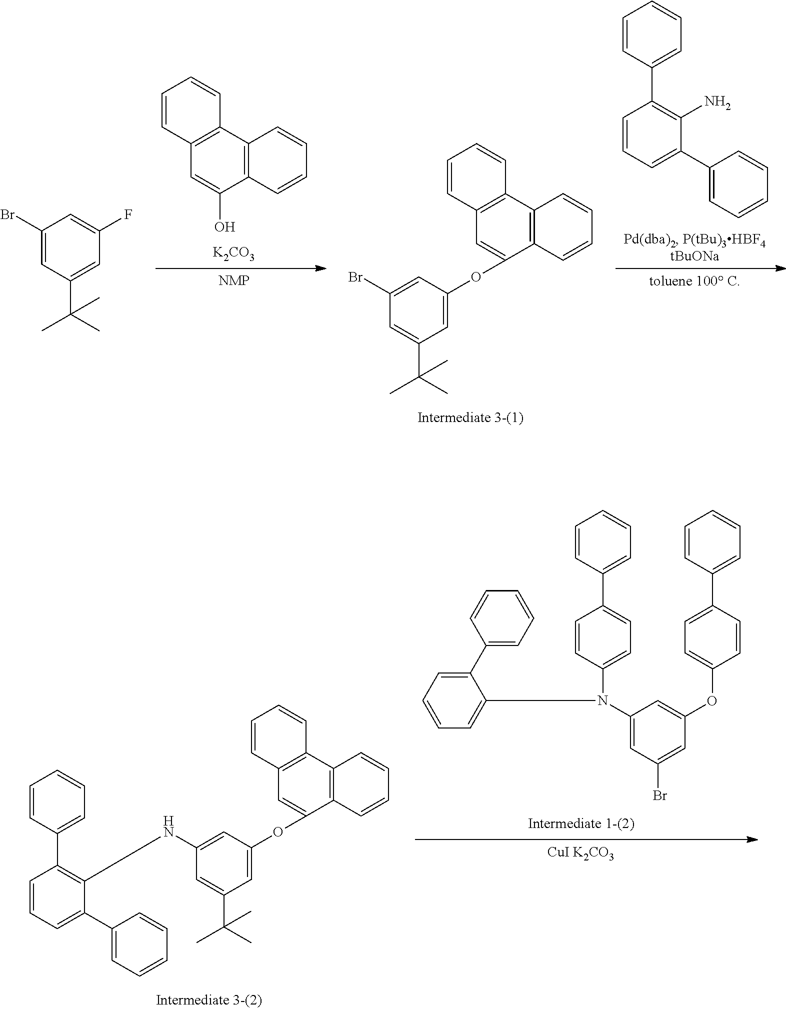

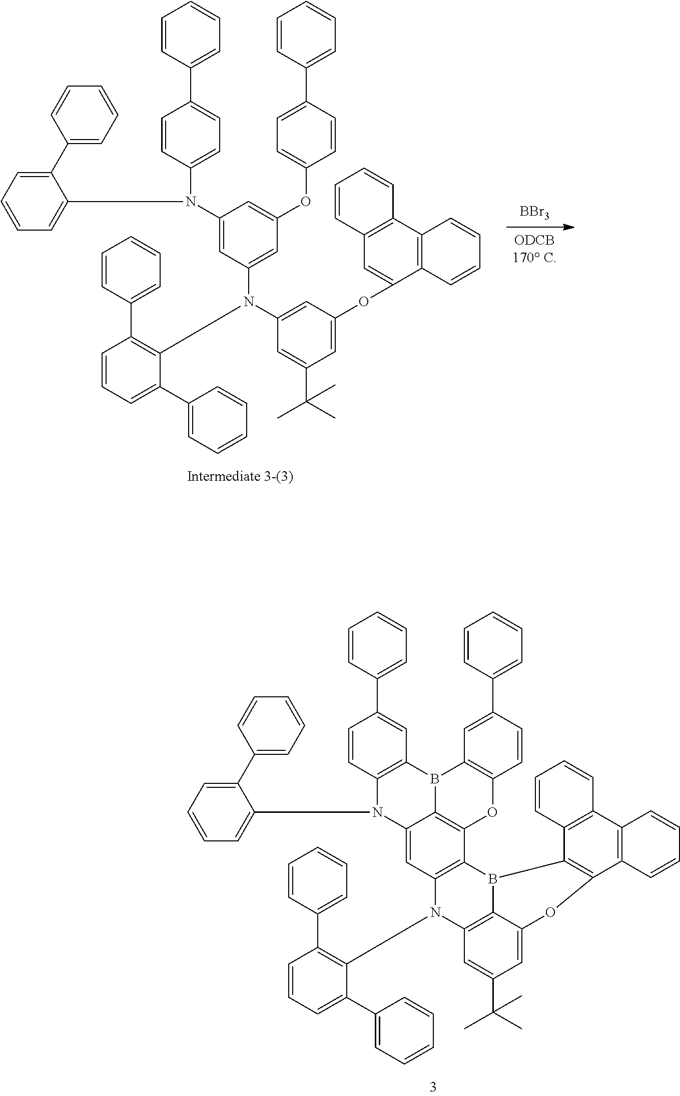 [SMILES: CC(C)(C)c1cc(Oc2cc3ccccc3c3ccccc23)cc(N(c2cc(Oc3ccc(-c4ccccc4)cc3)cc(N(c3ccc(-c4ccccc4)cc3)c3ccccc3-c3ccccc3)c2)c2c(-c3ccccc3)cccc2-c2ccccc2)c1 ; "BBr3" ; "ODCB170° C." ; CC(C)(C)c1cc2c3c(c1)N(c1c(-c4ccccc4)cccc1-c1ccccc1)c1cc4c5c(c1B3c1c(c3ccccc3c3ccccc13)O2)Oc1ccc(-c2ccccc2)cc1B5c1cc(-c2ccccc2)ccc1N4c1ccccc1-c1ccccc1]

### Synthesis of Intermediate Compound 3-(1)

In an Ar atmosphere, 1-bromo-3-(tert-butyl)-5-fluorobenzene (5.32 g, 23.02 mmol), phenanthren-9-ol (5.37 g, 27.62 mmol), and K₂CO₃ (14.32 g, 103.59 mmol) were added to 53 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 3-(1) (8.12 g, yield: 87%). The molecular weight of Intermediate Compound 3-(1) was about 405 as measured by FAB MS.

### Synthesis of Intermediate Compound 3-(2)

In an Ar atmosphere, Intermediate Compound 3-(1) (7.75 g, 19.12 mmol), [1,1′:3′,1″-terphenyl]-2′-amine (5.63 g, 22.94 mmol), Pd(dba)₂ (1.1 g, 1.91 mmol), P(tBu)₃·HBF₄ (1.11 g, 3.82 mmol), and tBuONa (4.23 g, 43.98 mmol) were added to 95 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 3-(2) (9.15 g, yield: 84%). The molecular weight of Intermediate Compound 3-(2) was about 570 as measured by FAB MS.

### Synthesis of Intermediate Compound 3-(3)

A small amount of toluene (about 10 mL) was added to Intermediate Compound 3-(2) (2.3 g, 4.04 mmol), Intermediate Compound 1-(2) (13.01 g, 20.18 mmol), CuI (1.61 g, 8.48 mmol), and K₂CO₃ (5.58 g, 40.37 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 3-(3) (3.57 g: 78%). The molecular weight of Intermediate Compound 3-(3) was about 1133 as measured by FAB MS.

### Synthesis of Synthesis of Compound 3

In an Ar atmosphere, Intermediate Compound 3-(3) (3.22 g, 2.84 mmol) was dissolved in ODCB (28 mL), BBr₃ (1.42 g, 5.68 mmol) was added thereto, and the resulting mixture was heated and stirred at about 170° C. for about 10 hours. The mixture was then cooled to room temperature, DIPEA (4.4 g, 34.09 mmol) was added thereto, water was added thereto, and the resulting mixture was filtered through Celite and subjected to liquid separation to concentrate an organic layer. The organic layer was purified by silica gel column chromatography to afford Compound 3 (1.24 g, yield: 38%). The molecular weight of Compound 3 was about 1149 as measured by FAB MS measurement.

The purification by sublimation was further performed (370° C., 2.8×10⁻³ Pa) for device evaluation.

### (3) Synthesis of Fused Polycyclic Compound 4

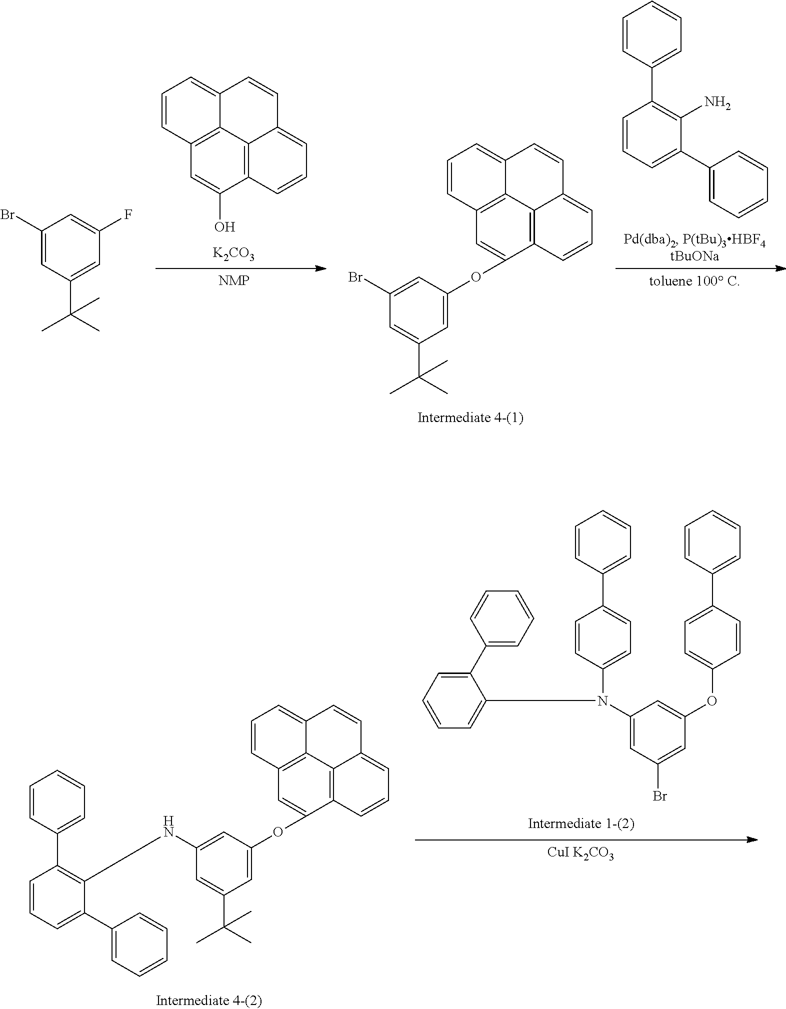

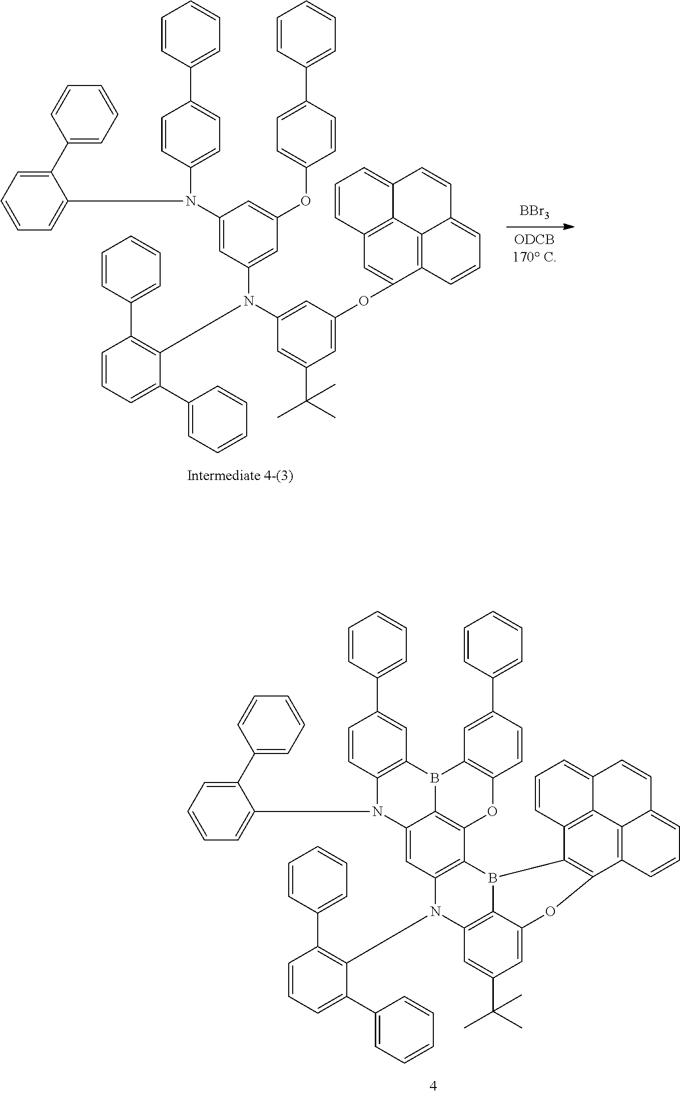 [SMILES: CC(C)(C)c1cc(Oc2cc3cccc4ccc5cccc2c5c43)cc(N(c2cc(Oc3ccc(-c4ccccc4)cc3)cc(N(c3ccc(-c4ccccc4)cc3)c3ccccc3-c3ccccc3)c2)c2c(-c3ccccc3)cccc2-c2ccccc2)c1 ; "BBr3" ; "ODCB170° C." ; CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1ccc(-c2ccccc2)cc1B5c1cc(-c2ccccc2)ccc1N4c1ccccc1-c1ccccc1]

### Synthesis of Intermediate Compound 4-(1)

In an Ar atmosphere, 1-bromo-3-(tert-butyl)-5-fluorobenzene (4.11 g, 17.78 mmol), pyren-4-ol (4.66 g, 21.34 mmol), and K₂CO₃ (11.06 g, 80.03 mmol) were added to 41 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 4-(1) (6.18 g, yield: 81%). The molecular weight of Intermediate Compound 4-(1) was about 429 as measured by FAB MS.

### Synthesis of Intermediate Compound 4-(2)

In an Ar atmosphere, Intermediate Compound 4-(1) (5.95 g, 13.86 mmol), [1,1′:3′,1″-terphenyl]-2′-amine (4.08 g, 16.63 mmol), Pd(dba)₂ (0.8 g, 1.39 mmol), P(tBu)₃·HBF₄ (0.8 g, 2.77 mmol), and tBuONa (3.06 g, 31.87 mmol) were added to 69 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 4-(2) (7.32 g, yield: 89%). The molecular weight of Intermediate Compound 4-(2) was about 594 as measured by FAB MS.

### Synthesis of Intermediate Compound 4-(3)

A small amount of toluene (about 10 mL) was added to Intermediate Compound 4-(2) (3.14 g, 5.29 mmol), Intermediate Compound 1-(2) (17.04 g, 26.44 mmol), CuI (2.12 g, 11.11 mmol), and K₂CO₃ (7.31 g, 52.88 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 4-(3) (4.47 g, yield: 73%). The molecular weight of Intermediate Compound 4-(3) was about 1157 as measured by FAB MS.

### Synthesis of Compound 4

In an Ar atmosphere, Intermediate Compound 4-(3) (4.13 g, 3.64 mmol) was dissolved in ODCB (36 mL), BBr₃ (1.83 g, 7.29 mmol) was added thereto, and the resulting mixture was heated and stirred at about 170° C. for about 10 hours. The mixture was then cooled to room temperature, DIPEA (5.64 g, 43.72 mmol) was added thereto, water was added thereto, and the resulting mixture was filtered through Celite and subjected to liquid separation to concentrate an organic layer. The organic layer was purified by silica gel column chromatography to afford Compound 4 (1.21 g, yield: 29%). The molecular weight of Compound 4 was about 1149 as measured by FAB MS measurement.

The purification by sublimation was further performed (370° C., 2.6×10⁻³ Pa) for device evaluation.

### (4) Synthesis of Fused Polycyclic Compound 9

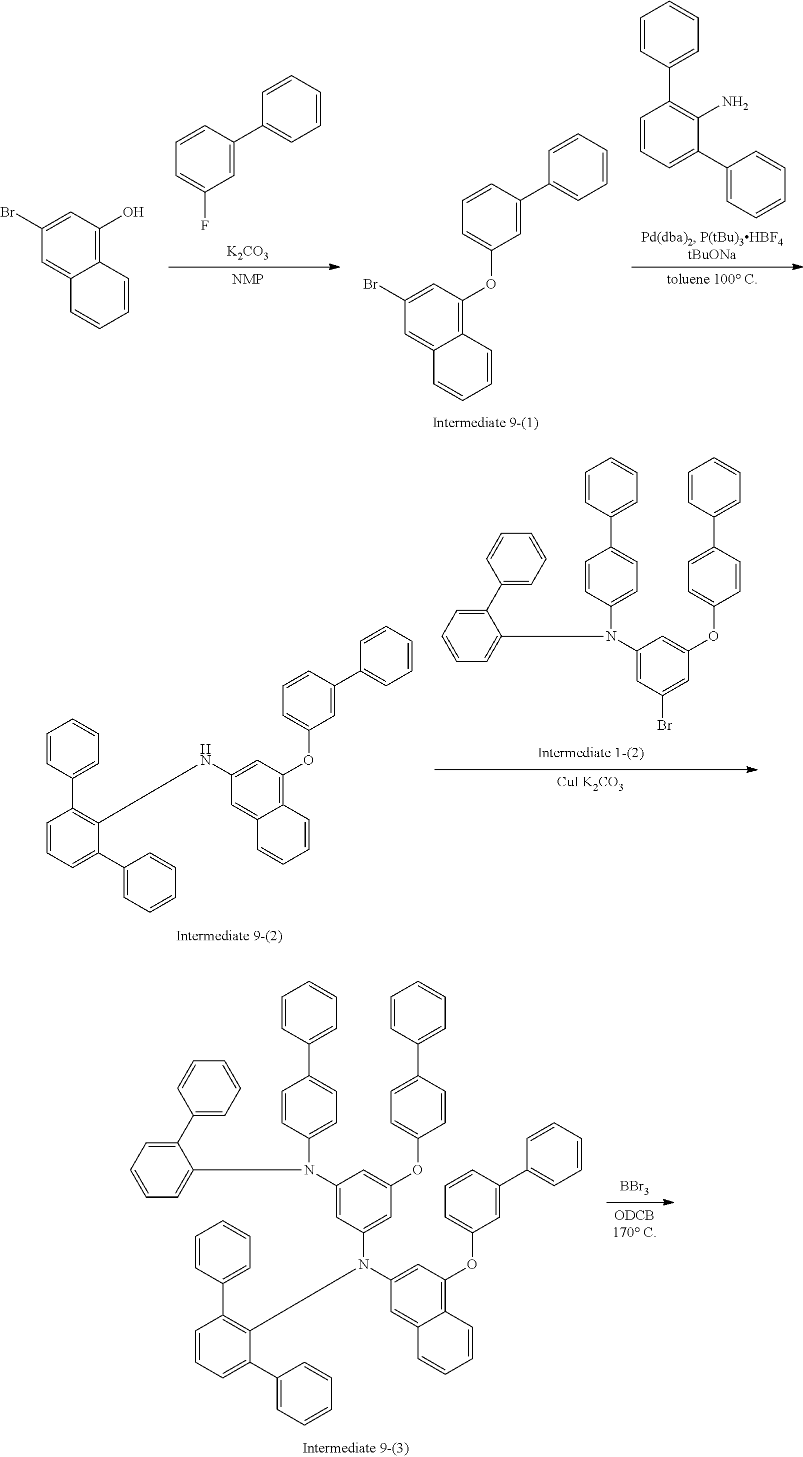

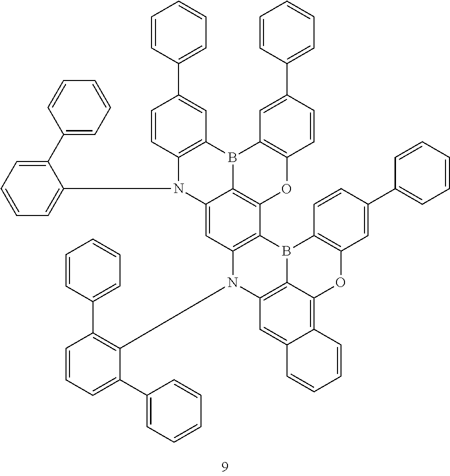 [SMILES: c1ccc(-c2ccc3c(c2)Oc2c4c(cc5ccccc25)N(c2c(-c5ccccc5)cccc2-c2ccccc2)c2cc5c6c(c2B34)Oc2ccc(-c3ccccc3)cc2B6c2cc(-c3ccccc3)ccc2N5c2ccccc2-c2ccccc2)cc1]

### Synthesis of Intermediate Compound 9-(1)

In an Ar atmosphere, 3-bromonaphthalen-1-ol (4.11 g, 17.63 mmol), 3-fluoro-1,1′-biphenyl (3.64 g, 21.16 mmol), and K₂CO₃ (10.97 g, 79.35 mmol) were added to 41 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 9-(1) (5.16 g, yield: 78%). The molecular weight of Intermediate Compound 9-(1) was about 375 as measured by FAB MS.

### Synthesis of Intermediate Compound 9-(2)

In an Ar atmosphere, Intermediate Compound 9-(1) (4.88 g, 13 mmol), [1,1′:3′,1″-terphenyl]-2′-amine (3.83 g, 15.6 mmol), Pd(dba)₂ (0.75 g, 1.3 mmol), P(tBu)₃·HBF₄ (0.75 g, 2.6 mmol), and tBuONa (2.87 g, 29.91 mmol) were added to 65 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 9-(2) (5.97 g, yield: 85%). The molecular weight of Intermediate Compound 9-(2) was about 540 as measured by FAB MS.

### Synthesis of Intermediate Compound 9-(3)

A small amount of toluene (about 10 mL) was added to Intermediate Compound 9-(2) (5.56 g, 10.3 mmol), Intermediate Compound 1-(2) (33.21 g, 51.51 mmol), CuI (4.12 g, 21.64 mmol), and K₂CO₃ (14.24 g, 103.02 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 9-(3) (8.75 g, yield: 77%). The molecular weight of Intermediate Compound 9-(3) was about 1103 as measured by FAB MS.

### Synthesis of Compound 9

In an Ar atmosphere, Intermediate Compound 9-(3) (8.58 g, 7.78 mmol) was dissolved in ODCB (78 mL), BBr₃ (3.9 g, 15.55 mmol) was added thereto, and the resulting mixture was heated and stirred at about 170° C. for about 10 hours. The mixture was then cooled to room temperature, DIPEA (12.04 g, 93.31 mmol) was added thereto, water was added thereto, and the resulting mixture was filtered through Celite and subjected to liquid separation to concentrate an organic layer. The organic layer was purified by silica gel column chromatography to afford Compound 9 (2.09 g, yield: 24%). The molecular weight of Compound 9 was about 1119 as measured by FAB MS measurement.

The purification by sublimation was further performed (340° C., 2.7×10⁻³ Pa) for device evaluation.

### (5) Synthesis of Fused Polycyclic Compound 13

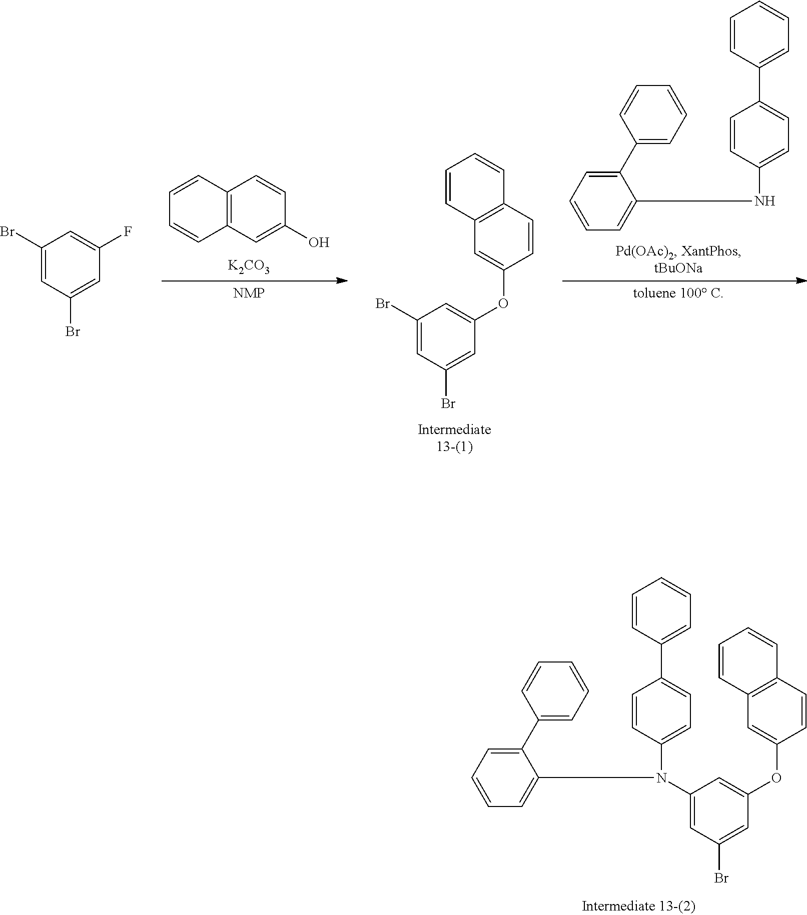

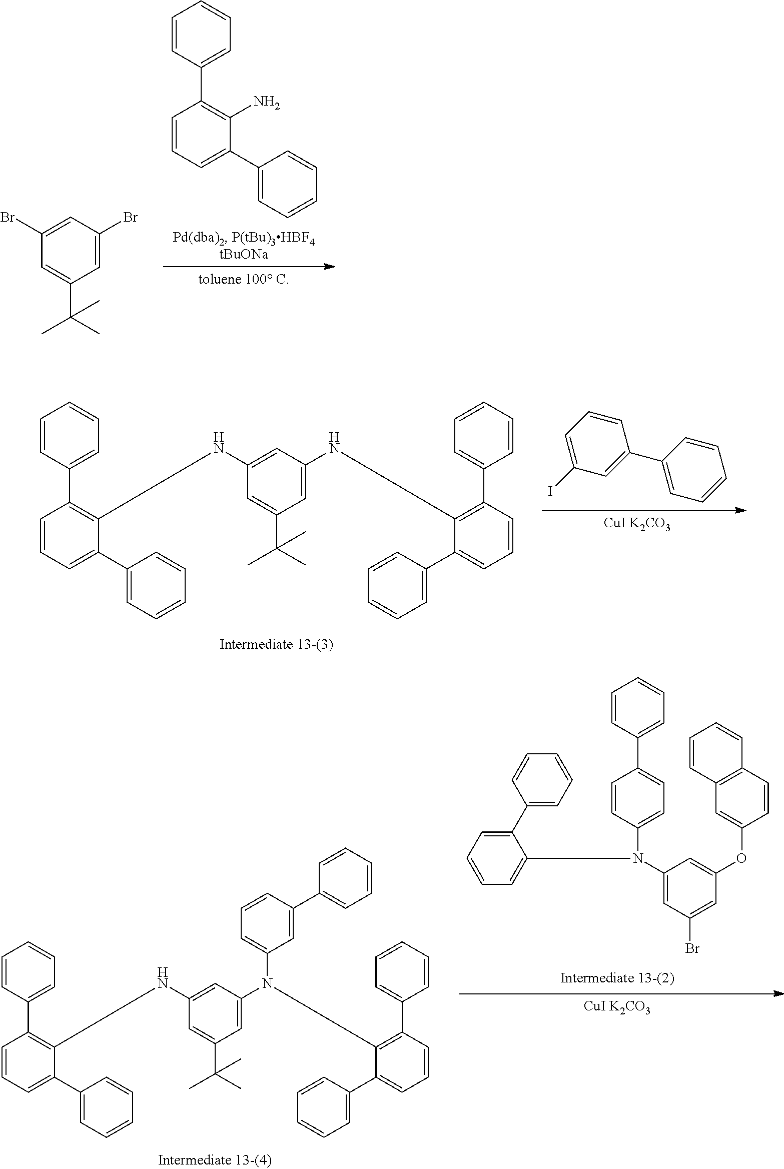

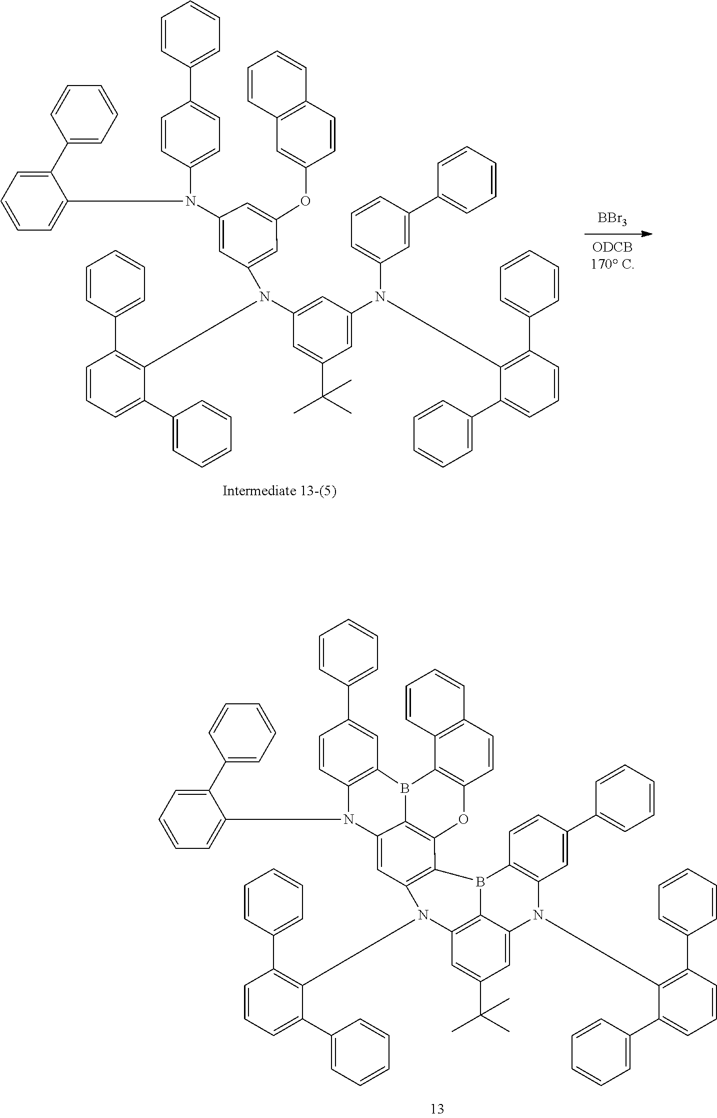 [SMILES: CC(C)(C)c1cc(N(c2cccc(-c3ccccc3)c2)c2c(-c3ccccc3)cccc2-c2ccccc2)cc(N(c2cc(Oc3ccc4ccccc4c3)cc(N(c3ccc(-c4ccccc4)cc3)c3ccccc3-c3ccccc3)c2)c2c(-c3ccccc3)cccc2-c2ccccc2)c1 ; "BBr3" ; "ODCB170° C." ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccc2ccccc2c1B5c1cc(-c2ccccc2)ccc1N4c1ccccc1-c1ccccc1]

### Synthesis of Intermediate Compound 13-(1)

In an Ar atmosphere, 1,3-dibromo-5-fluorobenzene (5.02 g, 19.77 mmol), naphthalen-2-ol (3.42 g, 23.73 mmol), and K₂CO₃ (12.3 g, 88.97 mmol) were added to 50 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 13-(1) (5.83 g, yield: 78%). The molecular weight of Intermediate Compound 13-(1) was about 378 as measured by FAB MS.

### Synthesis of Intermediate Compound 13-(2)

In an Ar atmosphere, Intermediate Compound 13-(1) (5.66 g, 14.97 mmol), N-([1,1′-biphenyl]-4-yl)-[1,1′-biphenyl]-2-amine (5.29 g, 16.47 mmol), Pd(OAc)₂ (0.1 g, 0.45 mmol), XantPhos (0.52 g, 0.9 mmol), and tBuONa (1.73 g, 17.97 mmol) were added to 74 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 13-(2) (8.06 g, yield: 87%). The molecular weight of Intermediate Compound 13-(2) was about 619 as measured by FAB MS.

### Synthesis of Intermediate Compound 13-(3)

In an Ar atmosphere, 1,3-dibromo-5-(tert-butyl)benzene (6.04 g, 20.68 mmol), [1,1′:3′,1″-terphenyl]-2′-amine (12.69 g, 51.71 mmol), Pd(dba)₂ (1.19 g, 2.07 mmol), P(t-Bu)₃HBF₄ (1.2 g, 4.14 mmol), and tBuONa (4.57 g, 47.57 mmol) were added to 103 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 13-(3) (11.43 g, yield: 89%). The molecular weight of Intermediate Compound 13-(3) was about 621 as measured by FAB MS.

### Synthesis of Intermediate Compound 13-(4)

A small amount of toluene (about 10 mL) was added to Intermediate Compound 13-(3) (11.03 g, 20.44 mmol), 3-iodo-1,1′-biphenyl (28.62 g, 102.19 mmol), CuI (8.17 g, 42.92 mmol), and K₂CO₃ (28.25 g, 204.38 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 13-(4) (7.58 g, yield: 48%). The molecular weight of Intermediate Compound 13-(4) was about 773 as measured by FAB MS.

### Synthesis of Intermediate Compound 13-(5)

A small amount of toluene (about 10 mL) was added to Intermediate Compound 13-(4) (2.88 g, 3.73 mmol), Intermediate Compound 13-(2) (11.52 g, 18.63 mmol), CuI (1.49 g, 7.82 mmol), and K₂CO₃ (5.15 g, 37.26 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 13-(5) (3.61 g, yield: 74%). The molecular weight of Intermediate Compound 13-(5) was about 1311 as measured by FAB MS.

### Synthesis of Synthesis of Compound 13

In an Ar atmosphere, Intermediate Compound 13-(5) (3.22 g, 2.46 mmol) was dissolved in ODCB (25 mL), BBr₃ (1.23 g, 4.91 mmol) was added thereto, and the resulting mixture was heated and stirred at about 170° C. for about 10 hours. The mixture was then cooled to room temperature, DIPEA (3.8 g, 29.48 mmol) was added thereto, water was added thereto, and the resulting mixture was filtered through Celite and subjected to liquid separation to concentrate an organic layer. The organic layer was purified by silica gel column chromatography to afford Compound 13 (1.82 g, yield: 56%). The molecular weight of Compound 13 was about 1326 as measured by FAB MS.

The purification by sublimation was further performed (350° C., 2.4×10⁻³ Pa) for device evaluation.

### (6) Synthesis of Fused Polycyclic Compound 23

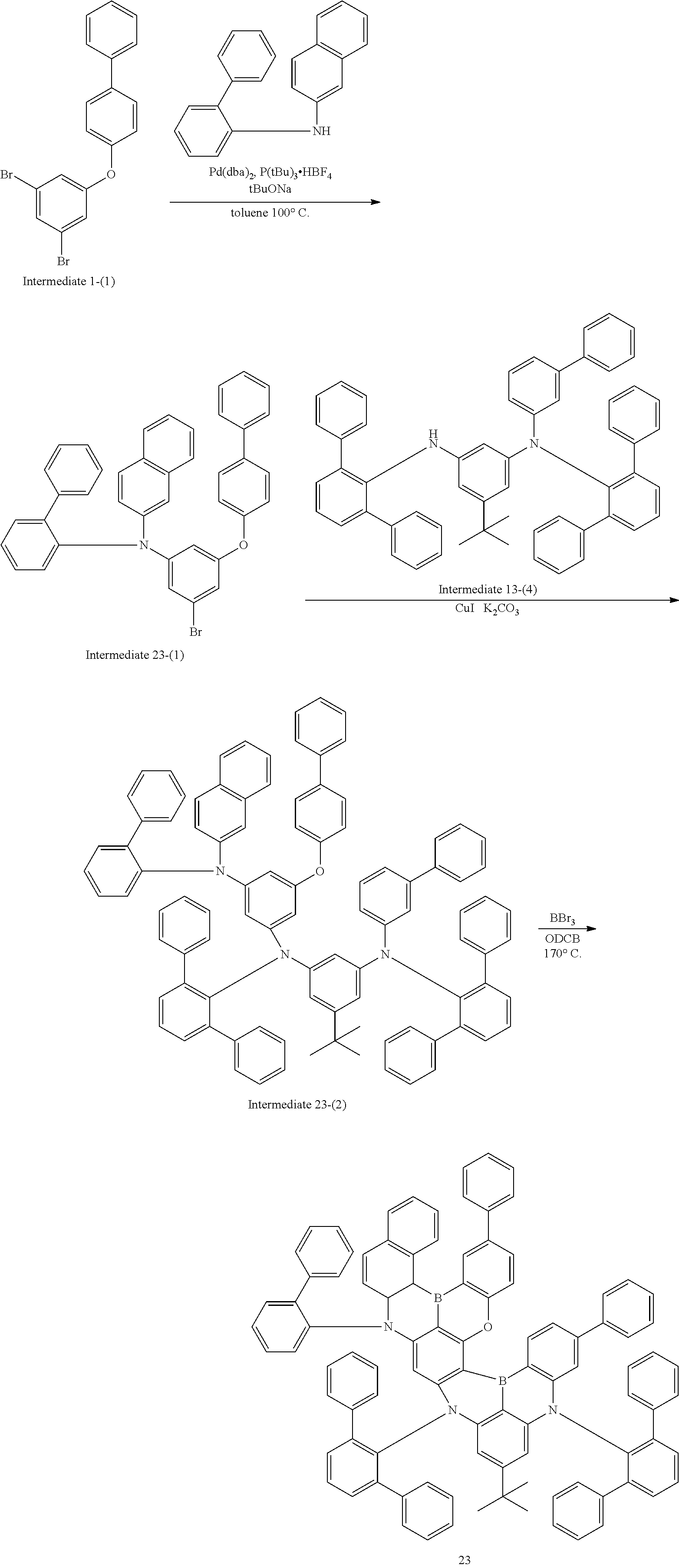

### Synthesis of Intermediate Compound 23-(1)

In an Ar atmosphere, Intermediate Compound 1-(1) (5.23 g, 12.94 mmol), N-([1,1′-biphenyl]-2-yl)naphthalen-2-amine (4.21 g, 14.24 mmol), Pd(OAc)₂ (0.09 g, 0.39 mmol), XantPhos (0.45 g, 0.78 mmol), and tBuONa (1.49 g, 15.53 mmol) were added to 64 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 23-(1) (6.00 g, yield: 75%). The molecular weight of Intermediate Compound 23-(1) was about 619 as measured by FAB MS.

### Synthesis of Intermediate Compound 23-(2)

A small amount of toluene (about 10 mL) was added to Intermediate Compound 23-(1) (5.89 g, 9.52 mmol), Intermediate Compound 13-(4) (36.8 g, 47.61 mmol), CuI (3.81 g, 20 mmol), and K₂CO₃ (13.16 g, 95.22 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 23-(2) (8.86 g, yield: 71%). The molecular weight of Intermediate Compound 23-(2) was about 1311 as measured by FAB MS.

### Synthesis of Compound 23

In an Ar atmosphere, Intermediate Compound 23-(2) (8.55 g, 6.52 mmol) was dissolved in ODCB (65 mL), BBr₃ (3.27 g, 13.05 mmol) was added thereto, and the resulting mixture was heated and stirred at about 170° C. for about 10 hours. The mixture was then cooled to room temperature, DIPEA (10.1 g, 78.28 mmol) was added thereto, water was added thereto, and the resulting mixture was filtered through Celite and subjected to liquid separation to concentrate an organic layer. The organic layer was purified by silica gel column chromatography to afford Compound 23 (3.89 g, yield: 45%). The molecular weight of Compound 23 was about 1326 as measured by FAB MS.

The purification by sublimation was further performed (360° C., 2.8×10⁻³ Pa) for device evaluation.

### (7) Synthesis of Fused Polycyclic Compound 33

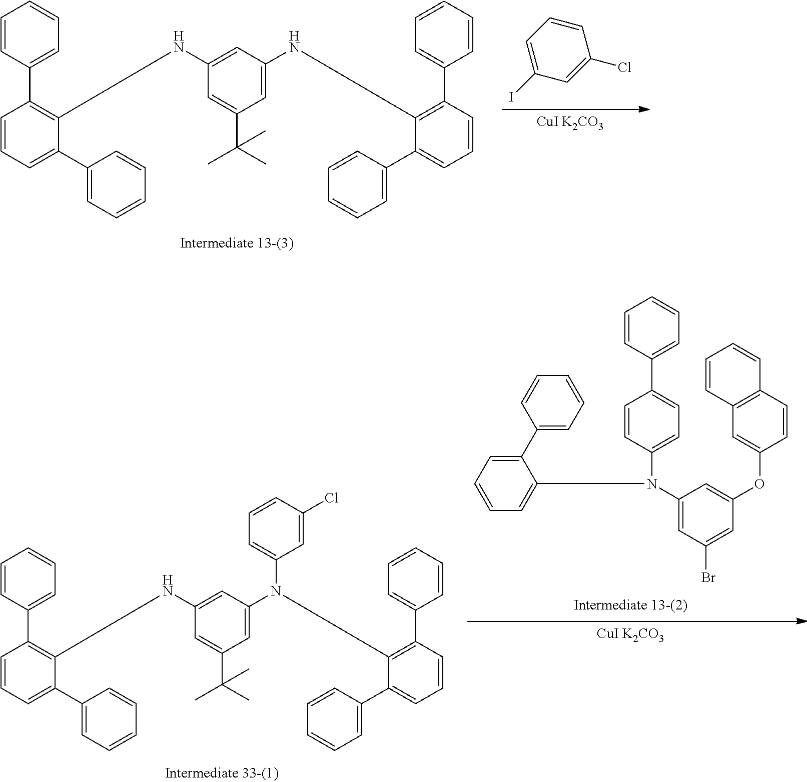

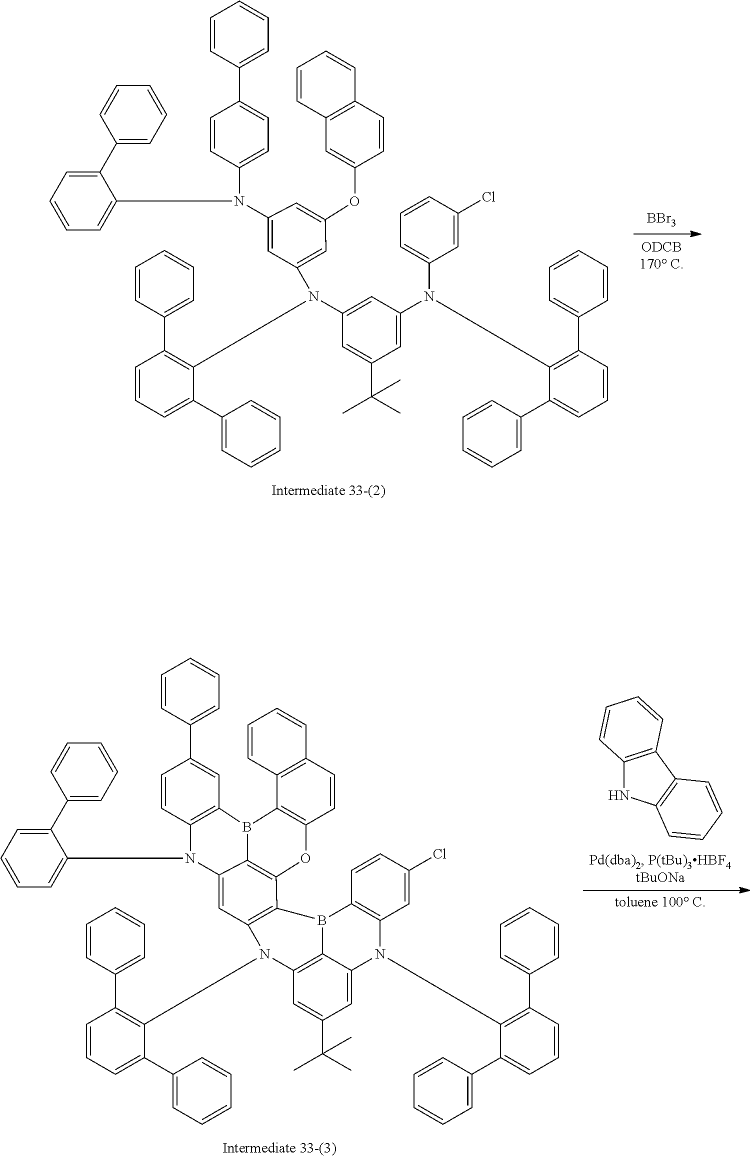

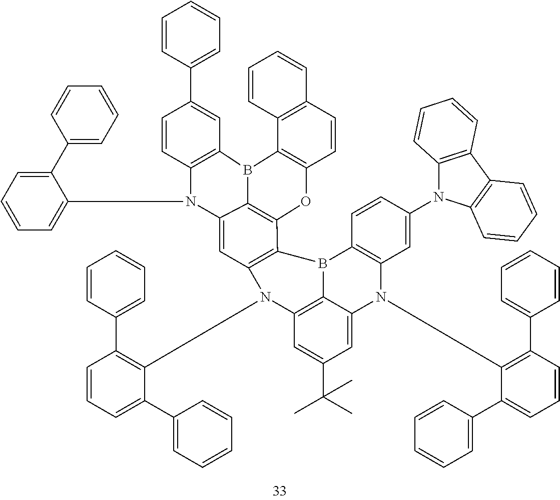 [SMILES: CC(C)(C)c1cc2c3c(c1)N(c1c(-c4ccccc4)cccc1-c1ccccc1)c1cc4c5c(c1B3c1ccc(-n3c6ccccc6c6ccccc63)cc1N2c1c(-c2ccccc2)cccc1-c1ccccc1)Oc1ccc2ccccc2c1B5c1cc(-c2ccccc2)ccc1N4c1ccccc1-c1ccccc1]

### Synthesis of Intermediate Compound 33-(1)

A small amount of toluene (about 10 mL) was added to Intermediate Compound 13-(3) (8.36 g, 13.47 mmol), 1-chloro-3-iodobenzene (16.05 g, 67.33 mmol), CuI (5.39 g, 28.28 mmol), and K₂CO₃ (18.61 g, 134.66 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 33-(1) (4.04 g, yield: 41%). The molecular weight of Intermediate Compound 33-(1) was about 731 as measured by FAB MS.

### Synthesis of Intermediate Compound 33-(2)

A small amount of toluene (about 10 mL) was added to Intermediate Compound 33-(1) (2.33 g, 3.19 mmol), Intermediate Compound 13-(2) (9.85 g, 15.93 mmol), CuI (1.27 g, 6.69 mmol), and K₂CO₃ (4.4 g, 31.86 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 33-(2) (2.51 g, yield: 62%). The molecular weight of Intermediate Compound 33-(2) was about 1269 as measured by FAB MS.

### Synthesis of Intermediate Compound 33-(3)

In an Ar atmosphere, Intermediate Compound 33-(2) (2.41 g, 1.9 mmol) was dissolved in ODCB (19 mL), BBr₃ (0.95 g, 3.8 mmol) was added thereto, and the resulting mixture was heated and stirred at about 170° C. for about 10 hours. The mixture was then cooled to room temperature, DIPEA (2.94 g, 22.79 mmol) was added thereto, water was added thereto, and the resulting mixture was filtered through Celite and subjected to liquid separation to concentrate an organic layer. The organic layer was purified by silica gel column chromatography to afford Intermediate Compound 33-(3) (1.34 g, yield: 55%). The molecular weight of Intermediate Compound 33-(3) was about 1285 as measured by FAB MS.

### Synthesis of Compound 33

In an Ar atmosphere, Intermediate Compound 33-(3) (1.22 g, 0.95 mmol), 9H-carbazole (0.19 g, 1.14 mmol), Pd(dba)₂ (0.05 g, 0.09 mmol), P(tBu)₃·HBF₄ (0.06 g, 0.19 mmol), and tBuONa (0.21 g, 2.18 mmol) were added to 4 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Compound 33 (1.14 g, yield: 85%). The molecular weight of Compound 33 was about 1415 as measured by FAB MS.

The purification by sublimation was further performed (370° C., 2.8×10⁻³ Pa) for device evaluation.

### (8) Synthesis of Fused Polycyclic Compound 49

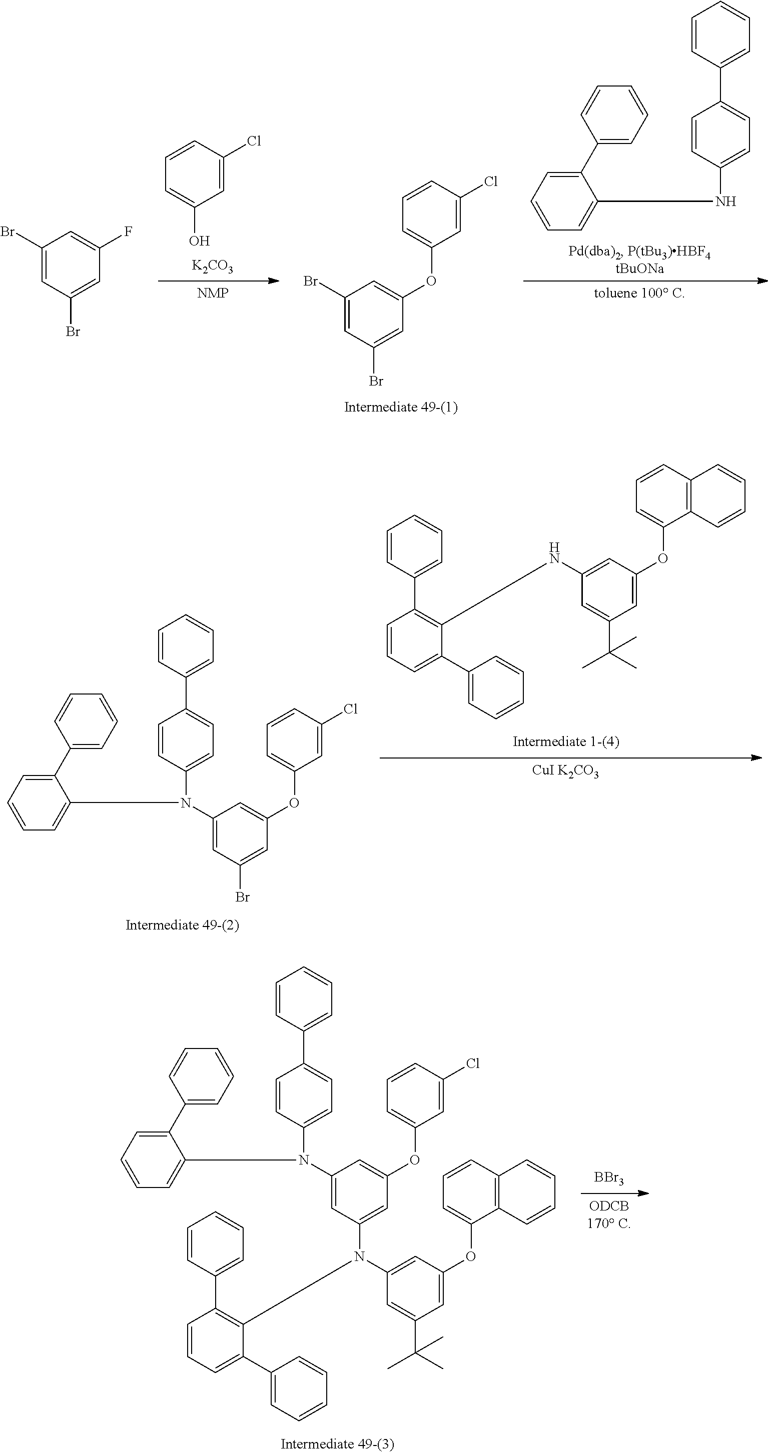

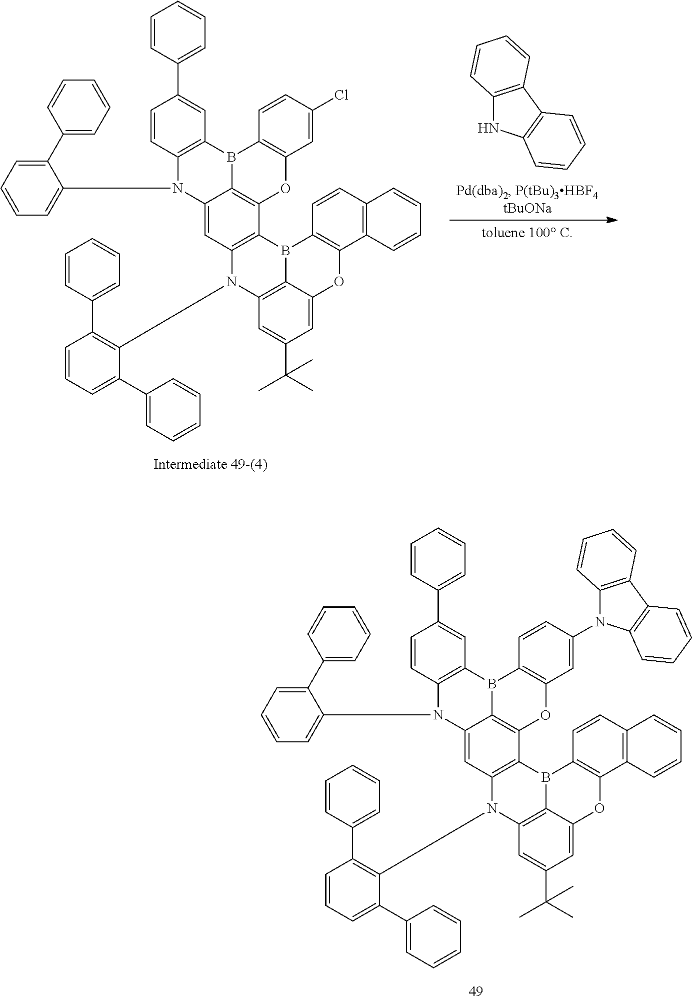

### Synthesis of Intermediate Compound 49-(1)

In an Ar atmosphere, 1,3-dibromo-5-fluorobenzene (4.58 g, 18.04 mmol) and 3-chlorophenol (2.78 g, 21.65 mmol), and K₂CO₃ (11.22 g, 81.17 mmol) were added to 45 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 49-(1) (5.75 g, yield: 88%). The molecular weight of Intermediate Compound 49-(1) was about 362 as measured by FAB MS.

### Synthesis of Intermediate Compound 49-(2)

In an Ar atmosphere, Intermediate Compound 49-(1) (5.44 g, 13.46 mmol), N-([1,1′-biphenyl]-4-yl)-[1,1′-biphenyl]-2-amine (4.76 g, 14.81 mmol), Pd(OAc)₂ (0.09 g, 0.4 mmol), XantPhos (0.47 g, 0.81 mmol), and tBuONa (1.55 g, 16.15 mmol) were added to 67 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 49-(2) (7.22 g, yield: 89%). The molecular weight of Intermediate Compound 49-(2) was about 603 as measured by FAB MS.

### Synthesis of Intermediate Compound 49-(3)

A small amount of toluene (about 10 mL) was added to Intermediate Compound 1-(4) (1.21 g, 2.33 mmol), Intermediate Compound 49-(2) (7.02 g, 11.64 mmol), CuI (0.93 g, 4.89 mmol), and K₂CO₃ (3.22 g, 23.28 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 49-(3) (1.89 g, yield: 78%). The molecular weight of Intermediate Compound 49-(3) was about 1042 as measured by FAB MS.

### Synthesis of Intermediate Compound 49-(4)

In an Ar atmosphere, Intermediate Compound 49-(3) (1.54 g, 1.48 mmol) was dissolved in ODCB (15 mL), BBr₃ (0.74 g, 2.96 mmol) was added thereto, and the resulting mixture was heated and stirred at about 170° C. for about 10 hours. The mixture was then cooled to room temperature, DIPEA (2.29 g, 17.74 mmol) was added thereto, water was added thereto, and the resulting mixture was filtered through Celite and subjected to liquid separation to concentrate an organic layer. The organic layer was purified by silica gel column chromatography to afford Intermediate Compound 49-(4) (0.97 g, yield: 62%). The molecular weight of Intermediate Compound 49-(4) was about 1057 as measured by FAB MS.

### Synthesis of Compound 49

In an Ar atmosphere, Intermediate Compound 49-(4) (0.88 g, 0.83 mmol), 9H-carbazole (0.17 g, 1 mmol), Pd(dba)₂ (0.05 g, 0.08 mmol), P(tBu)₃·HBF₄ (0.05 g, 0.17 mmol), and tBuONa (0.18 g, 1.91 mmol) were added to 4 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Compound 49 (0.81 g, yield: 82%). The molecular weight of Compound 49 was about 1188 as measured by FAB MS.

The purification by sublimation was further performed (360° C., 2.6×10⁻³ Pa) for device evaluation.

### (9) Synthesis of Fused Polycyclic Compound 67

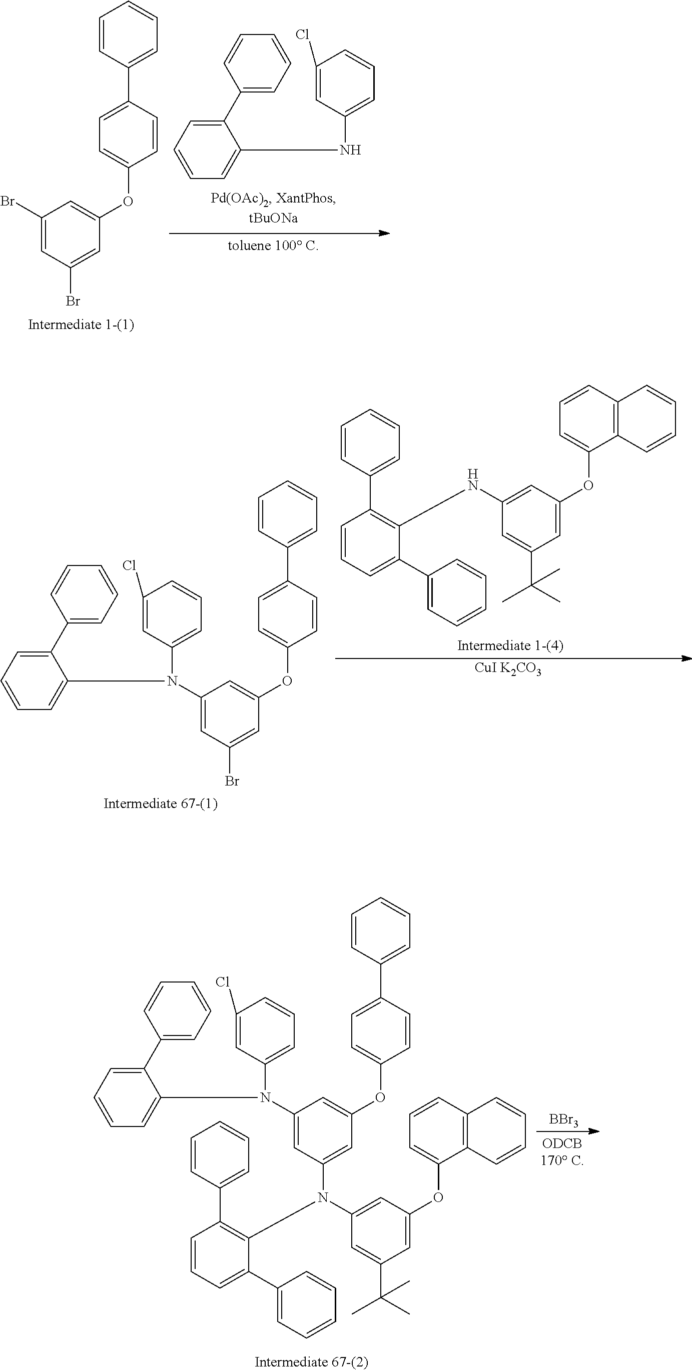

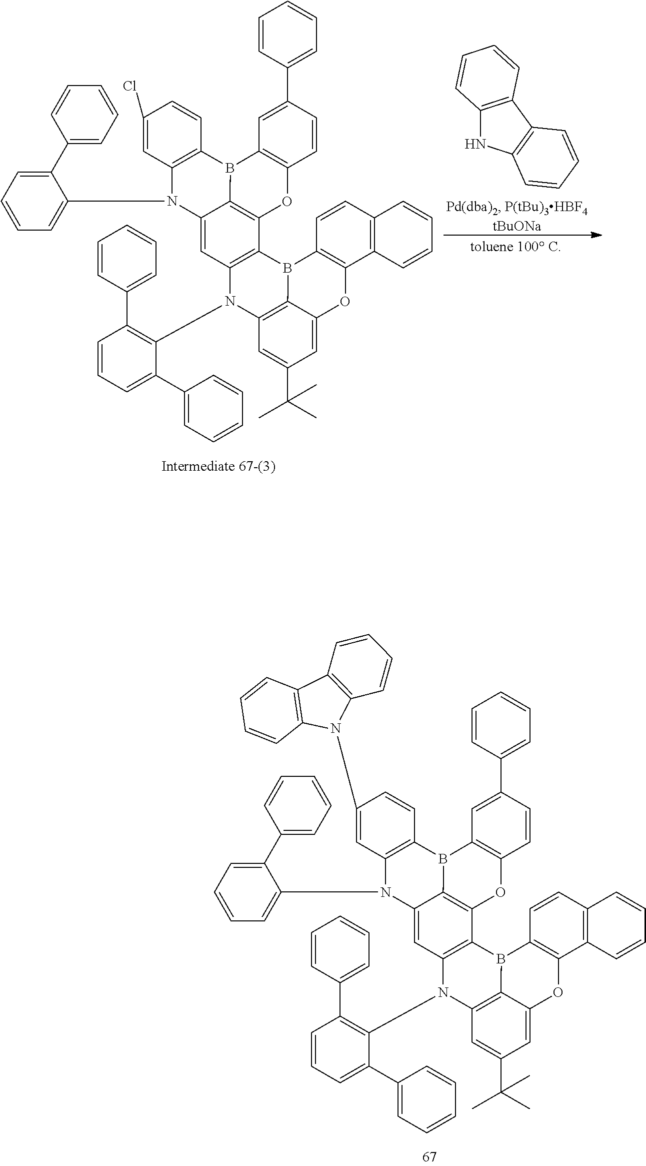

### Synthesis of Intermediate Compound 67-(1)

In an Ar atmosphere, Intermediate Compound 1-(1) (12.53 g, 31.01 mmol), N-(3-chlorophenyl)-[1,1′-biphenyl]-2-amine (9.54 g, 34.11 mmol), Pd(OAc)₂ (0.21 g, 0.93 mmol), XantPhos (1.08 g, 1.86 mmol), and tBuONa (3.58 g, 37.21 mmol) were added to 55 mL of toluene, and the resulting mixture was heated and stirred at about at 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 67-(1) (14.02 g, yield: 75%). The molecular weight of Intermediate Compound 67-(1) was about 603 as measured by FAB MS.

### Synthesis of Intermediate Compound 67-(2)

A small amount of toluene (about 10 mL) was added to Intermediate Compound 1-(4) (2.26 g, 4.35 mmol), Intermediate Compound 67-(1) (13.11 g, 21.74 mmol), CuI (1.74 g, 9.13 mmol), and K₂CO₃ (6.01 g, 43.49 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 67-(2) (3.22 g, yield: 71%). The molecular weight of Intermediate Compound 67-(2) was about 1042 as measured by FAB MS.

### Synthesis of Intermediate Compound 67-(3)

In an Ar atmosphere, Intermediate Compound 67-(2) (3.02 g, 2.9 mmol) was dissolved in ODCB (29 mL), BBr₃ (1.45 g, 5.8 mmol) was added thereto, and the resulting mixture was heated and stirred at about 170° C. for about 10 hours. The mixture was then cooled to room temperature, DIPEA (4.49 g, 34.79 mmol) was added thereto, water was added thereto, and the resulting mixture was filtered through Celite and subjected to liquid separation to concentrate an organic layer. The organic layer was purified by silica gel column chromatography to afford Intermediate Compound 67-(3) (1.99 g, yield: 65%). The molecular weight of Intermediate Compound 67-(3) was about 1057 as measured by FAB MS.

### Synthesis of Compound 67

In an Ar atmosphere, Intermediate Compound 67-(3) (1.84 g, 1.74 mmol), 9H-carbazole (0.35 g, 2.09 mmol), Pd(dba)₂ (0.10 g, 0.17 mmol), P(tBu)₃·HBF₄ (0.10 g, 0.35 mmol), and tBuONa (0.38 g, 4 mmol) were added to 8 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Compound 67 (1.53 g, yield: 74%). The molecular weight of Compound 67 was about 1188 as measured by FAB MS.

The purification by sublimation was further performed (360° C., 2.6×10⁻³ Pa) for device evaluation.

### (10) Synthesis of Fused Polycyclic Compound 93

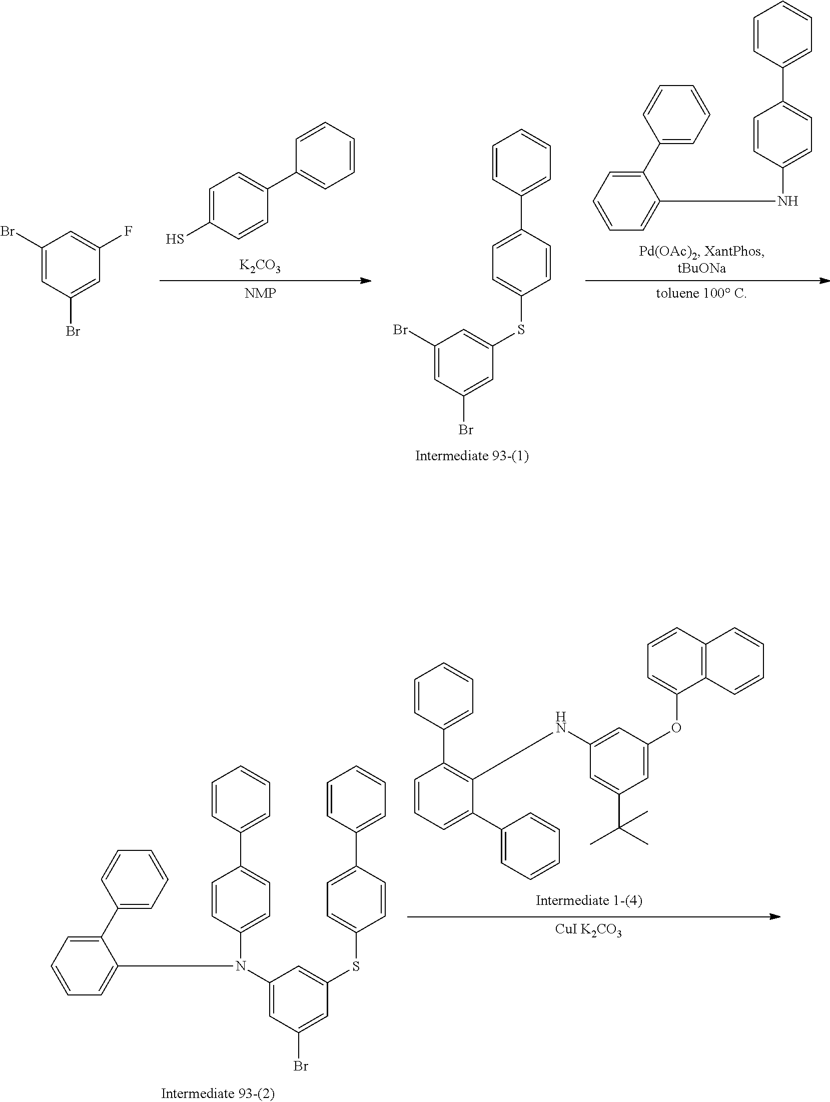

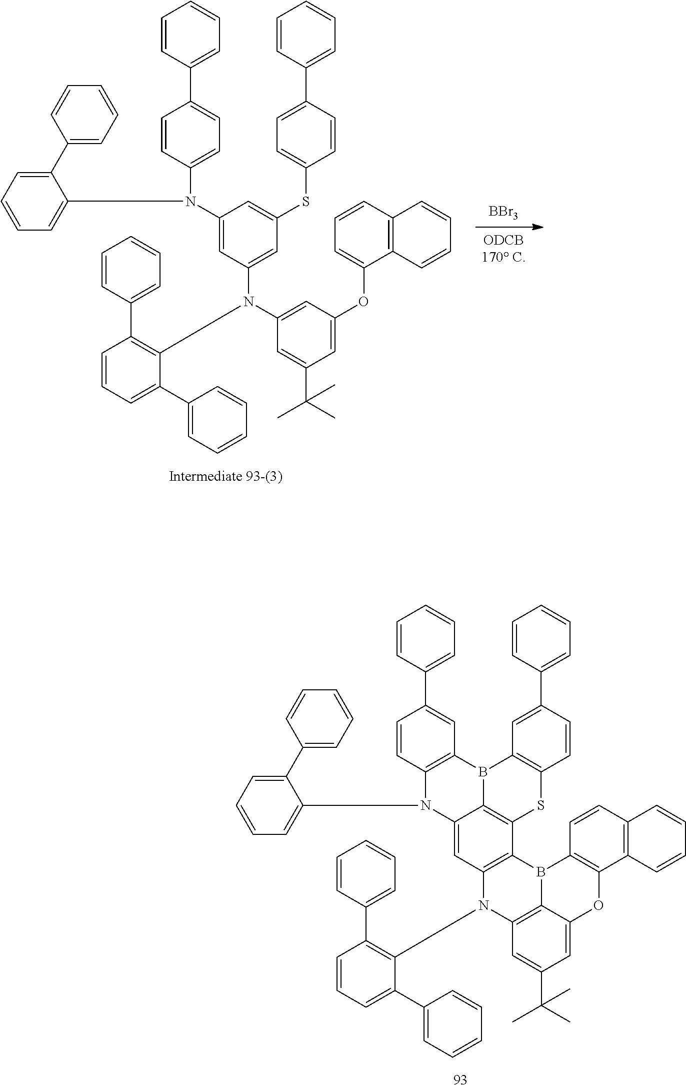

### Synthesis of Intermediate Compound 93-(1)

In an Ar atmosphere, 1,3-dibromo-5-fluorobenzene (4.11 g, 16.19 mmol) and [1,1′-biphenyl]-4-thiol (3.62 g, 19.42 mmol), and K₂CO₃ (10.07 g, 72.84 mmol) were added to 41 mL of NMP, and the resulting mixture was heated for about 24 hours while maintaining the ambient temperature at about 140° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 93-(1) (6.26 g, yield: 92%). The molecular weight of Intermediate Compound 93-(1) was about 420 as measured by FAB MS.

### Synthesis of Intermediate Compound 93-(2)

In an Ar atmosphere, Intermediate Compound 93-(1) (6.03 g, 14.35 mmol), N-([1,1′-biphenyl]-4-yl)-[1,1′-biphenyl]-2-amine (5.07 g, 15.79 mmol), Pd(OAc)₂ (0.1 g, 0.43 mmol), XantPhos (0.5 g, 0.86 mmol), and tBuONa (1.66 g, 17.22 mmol) were added to 71 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 93-(2) (6.83 g, yield: 72%). The molecular weight of Intermediate Compound 93-(2) was about 661 as measured by FAB MS.

### Synthesis of Intermediate Compound 93-(3)

A small amount of toluene (about 10 mL) was added to Intermediate Compound 1-(4) (1.01 g, 1.94 mmol), Intermediate Compound 93-(2) (6.42 g, 9.72 mmol), CuI (0.78 g, 4.08 mmol), and K₂CO₃ (2.69 g, 19.43 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 93-(3) (1.47 g, yield: 69%). The molecular weight of Intermediate Compound 93-(3) was about 1099 as measured by FAB MS.

### Synthesis of Compound 93

In an Ar atmosphere, Intermediate Compound 93-(3) (3.02 g, 2.75 mmol) was dissolved in ODCB (27 mL), BBr₃ (1.38 g, 5.49 mmol) was added thereto, and the resulting mixture was heated and stirred at about 170° C. for about 10 hours. The mixture was then cooled to room temperature, DIPEA (4.25 g, 32.96 mmol) was added thereto, water was added thereto, and the resulting mixture was filtered through Celite and subjected to liquid separation to concentrate an organic layer. The organic layer was purified by silica gel column chromatography to afford Compound 93 (2.21 g, yield: 72%). The molecular weight of Compound 93 was about 1115 as measured by FAB MS measurement.

The purification by sublimation was further performed (370° C., 2.4×10⁻³ Pa) for device evaluation.

### (11) Synthesis of Fused Polycyclic Compound 131

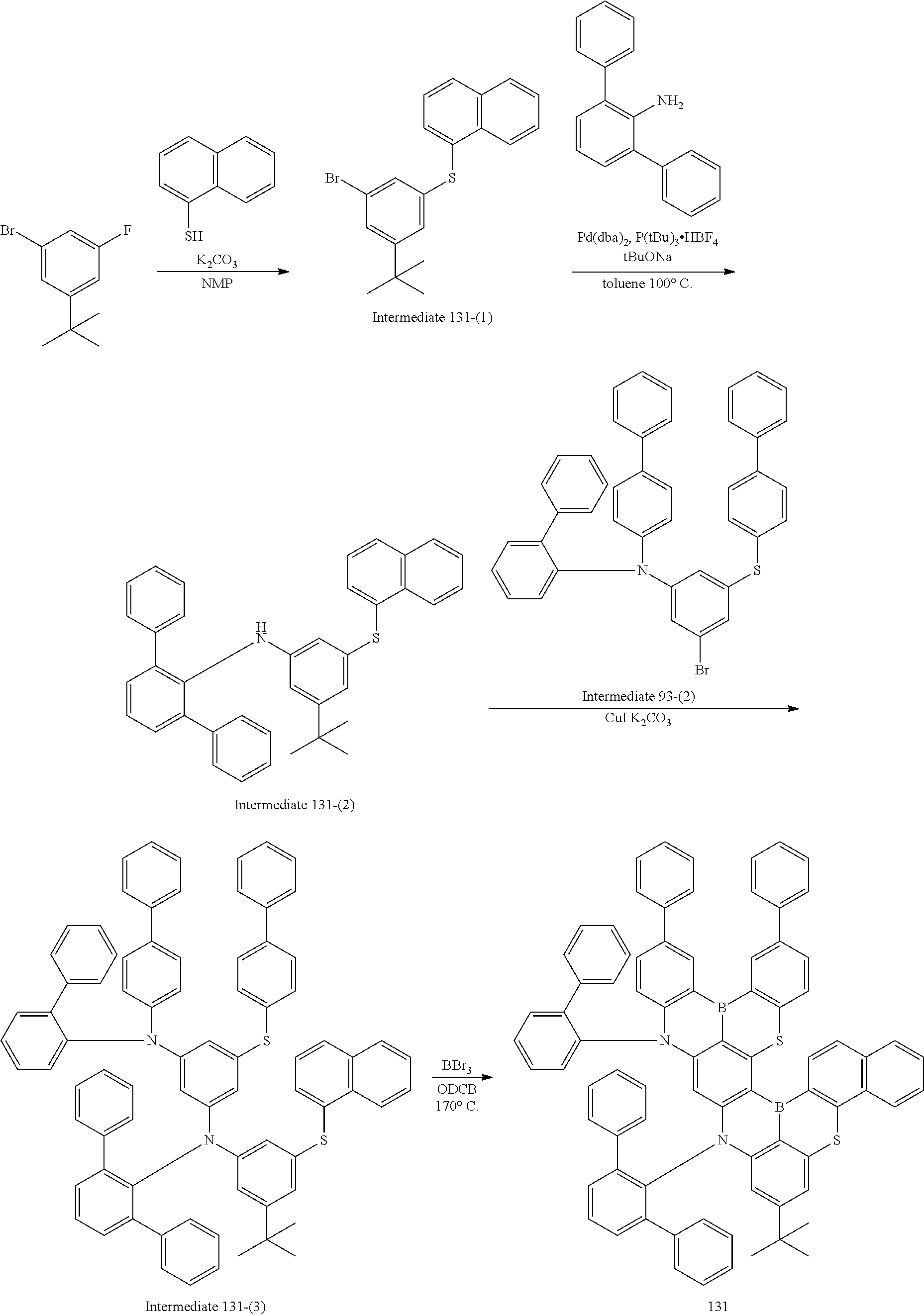

### Synthesis of Intermediate Compound 131-(1)

In an Ar atmosphere, 1-bromo-3-(tert-butyl)-5-fluorobenzene (2.51 g, 10.86 mmol), naphthalene-1-thiol (2.09 g, 13.03 mmol), and K₂CO₃ (6.75 g, 48.87 mmol) were added to 25 mL of NMP, and the resulting mixture was heated for about 24 hours while maintaining the ambient temperature at about 140° C. The mixture was then cooled and diluted with CH₂C12, water was added thereto, and the resultant mixture was filtered through Celite and subjected to liquid separation to concentrate an organic layer. The organic layer was purified by silica gel column chromatography to afford Intermediate Compound 131-(1) (3.51 g, yield: 87%). The molecular weight of Intermediate Compound 131-(1) was about 371 as measured by FAB MS.

### Synthesis of Intermediate Compound 131-(2)

In an Ar atmosphere, Intermediate Compound 131-(3) (1.84 g, 4.96 mmol), [1,1′:3′,1″-terphenyl]-2′-amine (1.46 g, 5.95 mmol), Pd(dba)₂ (0.28 g, 0.5 mmol), P(tBu)₃·HBF₄ (0.29 g, 0.99 mmol), and tBuONa (1.1 g, 11.4 mmol) were added to 24 mL of toluene, and the resulting mixture was heated and stirred at about 100° C. for about 8 hours. After cooling, water was added thereto, and the resultant mixture was filtered through Celite and subjected to liquid separation to concentrate an organic layer. The organic layer was purified by silica gel column chromatography to afford Intermediate Compound 131-(2) (2.28 g, yield: 86%). The molecular weight of Intermediate Compound 131-(2) was about 536 as measured by FAB MS.

### Synthesis of Intermediate Compound 131-(3)

A small amount of toluene (about 10 mL) was added to Intermediate Compound 131-(2) (1.01 g, 1.89 mmol), Intermediate Compound 93-(2) (6.23 g, 9.43 mmol), CuI (0.75 g, 3.96 mmol), and K₂CO₃ (2.61 g, 18.85 mmol), and the resulting mixture was heated for about 24 hours while maintaining the ambient temperature at about 215° C. The mixture was then cooled and diluted with CH₂Cl₂, water was added thereto, and the resultant mixture was filtered through Celite and subjected to liquid separation to concentrate an organic layer. The organic layer was purified by silica gel column chromatography to afford Intermediate Compound 131-(3) (1.30 g, yield: 62%). The molecular weight of Intermediate Compound 131-(3) was about 1116 as measured by FAB MS.

### Synthesis of Compound 131

In an Ar atmosphere, Intermediate Compound 131-(3) (1.24 g, 1.11 mmol) was dissolved in ODCB (11 mL), BBr₃ (0.56 g, 2.22 mmol) was added thereto, and the resulting mixture was heated and stirred at about 170° C. for about 10 hours. The mixture was then cooled to room temperature, DIPEA (1.72 g, 13.34 mmol) was added thereto, water was added thereto, and the resulting mixture was filtered through Celite and subjected to liquid separation to concentrate an organic layer. The organic layer was purified by silica gel column chromatography to afford Compound 131 (0.85 g, yield: 68%). The molecular weight of Compound 131 was about 1131 as measured by FAB MS.

The purification by sublimation was further performed (380° C., 2.5×10⁻³ Pa) for device evaluation.

### 1. Manufacture and Evaluation of Light Emitting Elements

The light emitting element of an example including the fused polycyclic compound of an example in an emission layer was manufactured as follows. Fused polycyclic compounds of Compounds 1, 3, 4, 9, 13, 23, 33, 49, 67, 93, and 131, which are Example Compounds as described above, were used as dopant materials for the emission layers to manufacture the light emitting elements of Examples 1 to 11, respectively. Comparative Examples 1 to 9 correspond to the light emitting elements manufactured by using Comparative Example Compounds X1 to X9 as dopant materials for the emission layers, respectively.

### EXAMPLE COMPOUNDS

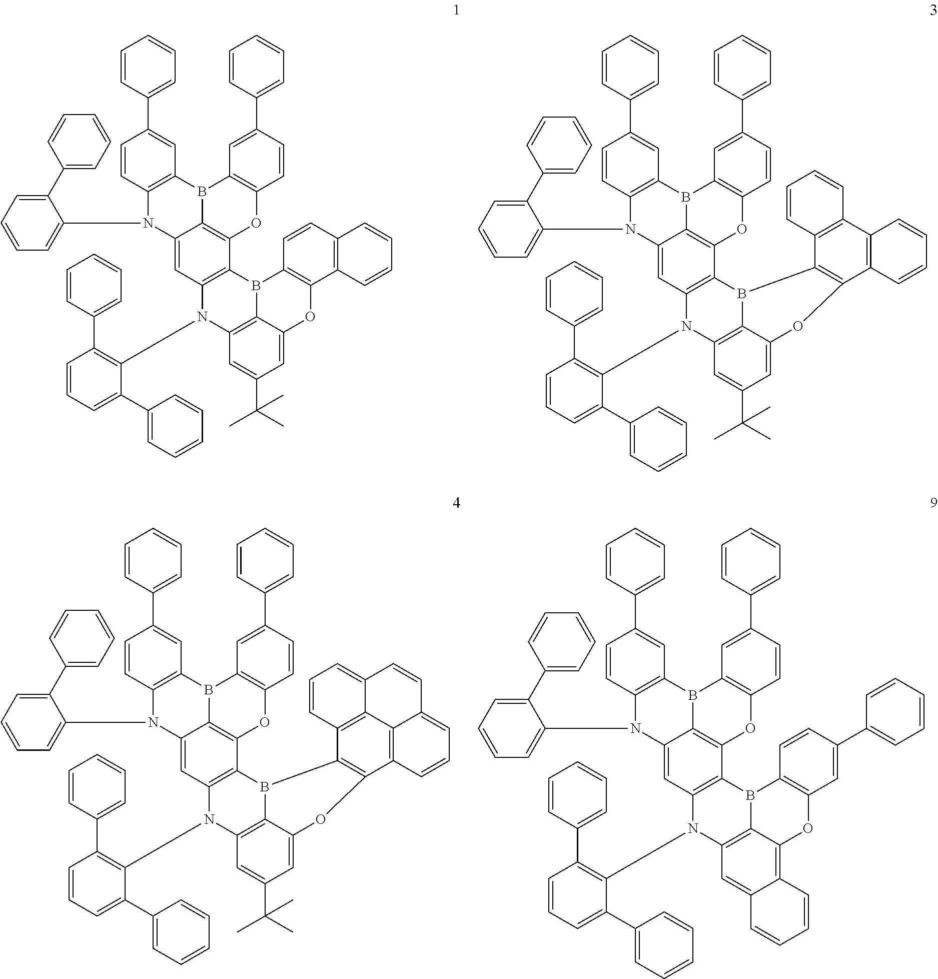

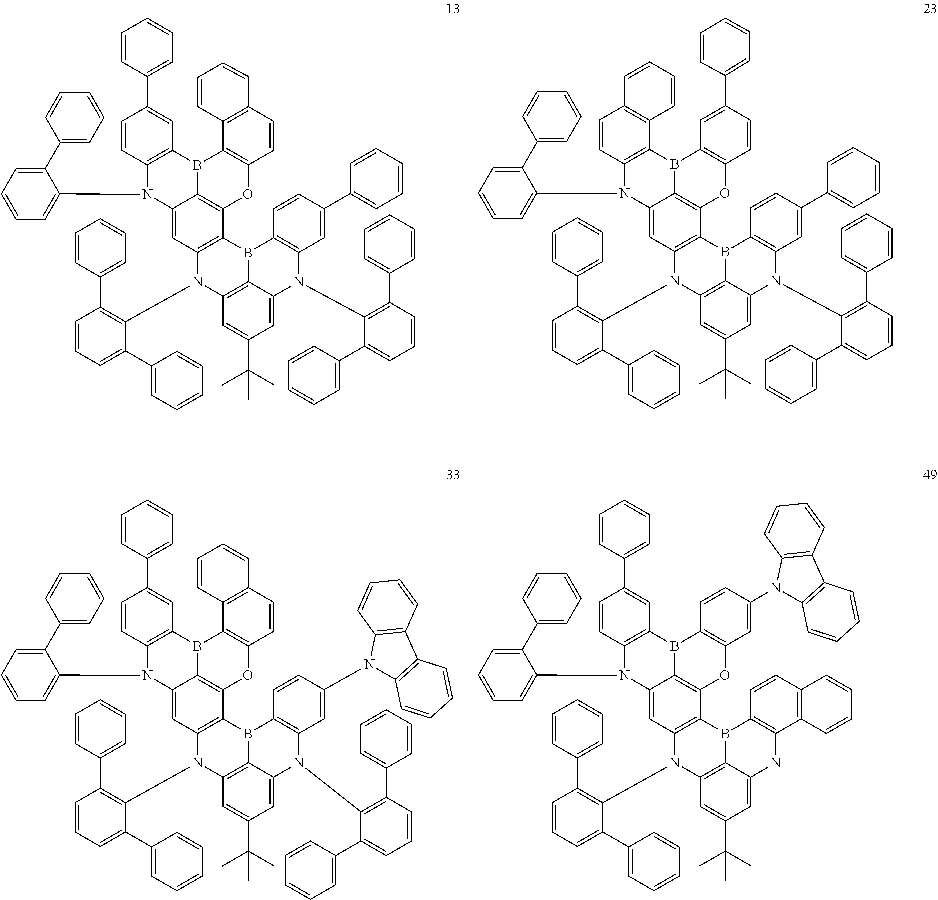

### Comparative Example Compounds

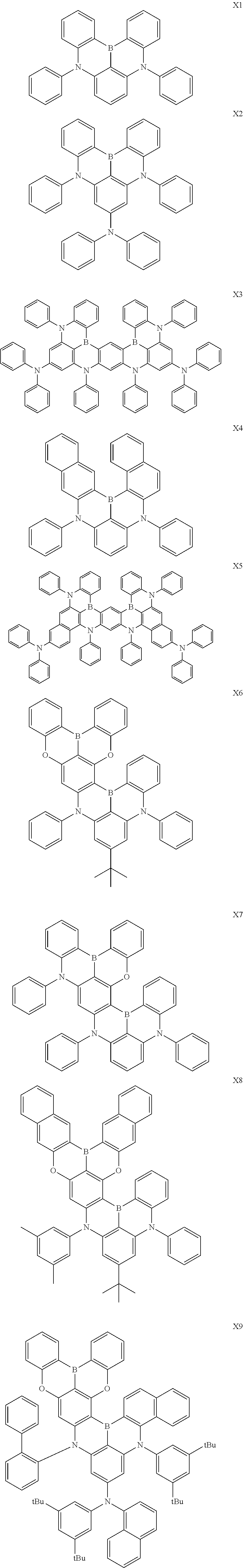

### Manufacture of Light Emitting Elements

ITO was used to form a 150-nm thick first electrode, dipyrazino[2,3-f: 2′,3′-h]quinoxaline-2,3,6,7,10,11-hexacarbonitrile (HATCN) was used to form a 10-nm thick hole injection layer on the first electrode, N,N-bis(naphthalen-1-yl)-N,N′-bis(phenyl)-2,2′-dimethylbenzidine (α-NPD) was used to form a 80-nm thick hole transport layer on the hole injection layer, 1,3-bis(N-carbazolyl)benzene (mCP) was used to form a 5-nm thick emission-auxiliary layer on the hole transport layer, Example Compound or Comparative Example Compound was doped by 1% to 3,3′-di(9H-carbazol-9-yl)-1,1′-biphenyl (mCBP) to form a 20-nm thick emission layer on the emission-auxiliary layer, 2,2′,2″-(1,3,5-benzinetriyl)-tris(1-phenyl-1-H-benzimidazole) (TPBi) was used to form a 30-nm thick electron transport layer on the emission layer, LiF was used to form a 0.5-nm thick electron injection layer on the electron transport layer, and Al was used to form a 100-nm thick second electrode on the electron injection layer. Each layer was formed by a deposition method in a vacuum atmosphere.

Compounds used for manufacturing the light emitting elements of Examples and Comparative Examples are disclosed herein. The compounds are suitable materials, and commercial products were subjected to sublimation purification and used to manufacture the devices.

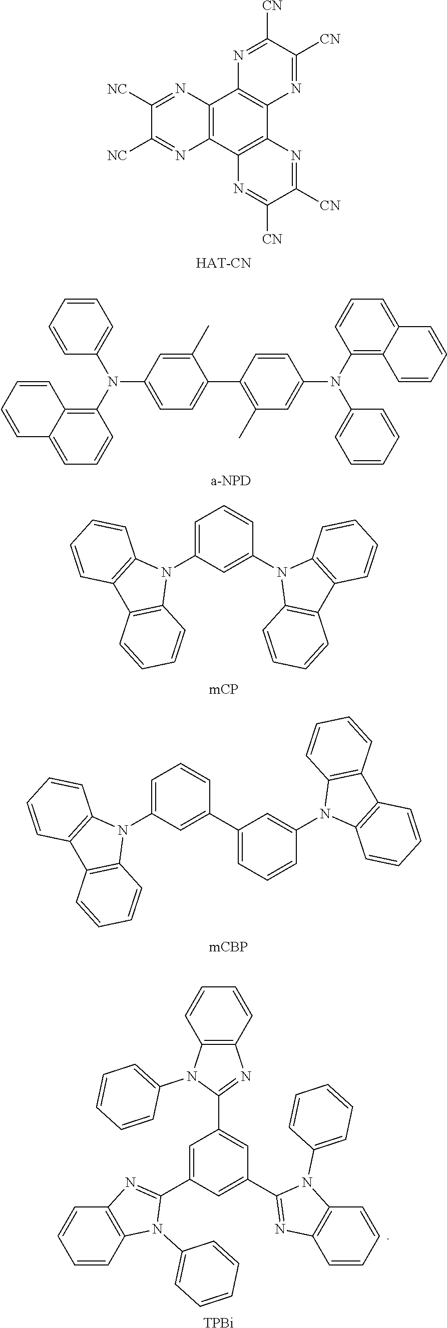

### Evaluation of Light Emitting Element Characteristics

Evaluation results of each of the light emitting elements in Examples 1 to 11 and Comparative Examples 1 to 9 are listed in Table 1. A maximum emission wavelength (Amax), roll-off value (%), and a relative service life (LT50) of each of the manufactured light emitting elements are listed in comparison in Table 1.

The maximum emission wavelength (λₘₐₓ), the roll-off value (%), and the relative service life (LT50) in the characteristic evaluation results of each of Examples and Comparative Examples shown in Table 1 were measured using an external quantum efficiency measurement apparatus, C9920-12 manufactured by Hamamatsu Photonics, co., Japan. The maximum emission wavelength (λₘₐₓ) represents the wavelength showing the maximum value of emission intensity in the emission spectrum. The roll-off represents the efficiency reduction ratio at high luminance, and was evaluated on the basis of the luminance of 1 cd/m² and the luminance of 1,000 cd/m². In addition, the relative service life (LT50) is represented by evaluating a luminance half-reduction time at an initial luminance of 800 cd/m². The relative service life is shown relatively based on setting the result of Comparative Example 3 as 1.

TABLE 1

| Element | | | | |
|---|---|---|---|---|
| Manufacture | | λₘₐₓ | Roll-off | |
| Examples | Dopant | (nm) | (%) | LT50 |
| Example 1 | Compound 1 | 461 | 9.8 | 4.5 |
| Example 2 | Compound 3 | 462 | 10.2 | 4.6 |
| Example 3 | Compound 4 | 463 | 10.5 | 4.5 |
| Example 4 | Compound 9 | 465 | 12.1 | 3.9 |
| Example 2 | Compound 13 | 463 | 13.1 | 3.1 |
| Example 3 | Compound 23 | 460 | 11.9 | 3.5 |
| Example 4 | Compound 33 | 461 | 9.5 | 4.7 |
| Example 5 | Compound 49 | 462 | 12.3 | 3.8 |
| Example 6 | Compound 67 | 458 | 10.1 | 4.2 |
| Example 10 | Compound 93 | 464 | 11.2 | 3.8 |
| Example 11 | Compound 131 | 468 | 12.5 | 3.5 |
| Comparative | Comparative Example | 457 | 33.2 | 0.3 |
| Example 1 | Compound X1 | | | |
| Comparative | Comparative Example | 446 | 30.5 | 0.2 |
| Example 2 | Compound X2 | | | |
| Comparative | Comparative Example | 467 | 13.5 | 1.0 |
| Example 3 | Compound X3 | | | |
| Comparative | Comparative Example | 475 | 37.2 | 0.4 |
| Example 4 | Compound X4 | | | |
| Comparative | Comparative Example | 480 | 25.4 | 0.7 |
| Example 5 | Compound X5 | | | |
| Comparative | Comparative Example | 455 | 20.0 | 0.8 |
| Example 6 | Compound X6 | | | |
| Comparative | Comparative Example | 452 | 25.0 | 0.7 |
| Example 7 | Compound X7 | | | |
| Comparative | Comparative Example | 468 | 30.0 | 0.3 |
| Example 8 | Compound X8 | | | |
| Comparative | Comparative Example | 467 | 26.0 | 0.5 |
| Example 9 | Compound X9 | | | |

Referring to the results of Table 1, it may be confirmed that Examples of the light emitting elements, in each of which the fused polycyclic compound according to examples of the disclosure is used as a luminescent material, each have roll-off values lower than those of Comparative Examples, and thus a decrease in efficiency is prevented or reduced even at high luminance, and the service life characteristics are improved. The fused polycyclic compound of one or more embodiments includes the core including the first fused ring structure and the second fused ring structure described above, thereby achieving high efficiency and long service life. In particular, there is the effect of improving the stability of a fused polycyclic compound by increasing the steric properties of the fused polycyclic compound by including a first fused ring structure including a boron atom, one nitrogen atom, and one heteroatom instead of a structure in which a boron atom and two oxygen atoms of a fused polycyclic compound included in the emission layer of a general organic electroluminescent element are concurrently (e.g., simultaneously) fused, thereby reducing the interaction between fused polycyclic compound molecules. In addition, in the fused polycyclic compound of one or more embodiments, a biphenyl group and/or a terphenyl group substituted at the nitrogen atom are located on different planes, due to steric hindrance, with the first fused ring structure and the second fused ring structure, and thus there is the effect of further enhancing the steric properties of the fused polycyclic compound. In addition, the first fused ring structure or the second fused ring structure may include at least one of naphthalene, phenanthrene, or pyrene to lower the lowest triplet excitation energy level (T1) of the fused polycyclic compound, and thus the fused polycyclic compound may exhibit high thermal and chemical stability.

In other words, the fused polycyclic compound described in this present disclosure includes a core with two fused ring structures, enhancing efficiency and longevity. By incorporating a boron atom, one nitrogen atom, and one heteroatom in the first fused ring structure, the compound's stability is improved due to increased steric properties, reducing molecular interactions. Additionally, biphenyl or terphenyl groups attached to the nitrogen atom are positioned on different planes, further enhancing steric properties. The inclusion of naphthalene, phenanthrene, or pyrene in the ring structures lowers the triplet excitation energy level, resulting in high thermal and chemical stability. When Examples 1 to 11 and Comparative Examples 1 to 9 are compared, the long service life of the element has been achieved in each of Examples, and efficiency deterioration is prevented or reduced even at high luminance. For example, the half-lives of Examples 1 to 11 are improved from 3.1 times to 23.5 times. Example Compounds included in Examples 1 to 11 may each include the core including the first fused ring structure and the second fused ring structure as described above, thereby achieving high efficiency and long service life.

Comparative Examples 1, 2, and 4 each have the deterioration in both (e.g., simultaneously) roll-off characteristics and service life compared to Examples. Comparative Example Compounds X1, X2, and X4 included in Comparative Examples 1, 2, and 4, respectively, may have the deterioration in material stability by including only one boron atom compared to Example Compounds. Accordingly, compared to the light emitting elements of Examples, the service lives of the light emitting elements of Comparative Examples 1, 2, and 4 may be reduced, and the roll-off characteristics may be deteriorated.

Comparative Example Compounds X3 and X5 included in Comparative Example 3 and 5, respectively, each include a structure in which two fused ring structures are linked, but differs from Example Compounds in terms of a structure in which two fused rings are linked to each other, and does not include a fused ring structure containing a boron atom, one nitrogen atom, and one heteroatom (O or S), and thus may have low planarity and deteriorated stability. Accordingly, compared to the light emitting elements of Examples, the service life of each of the light emitting element of Comparative Examples 3 and 5 may be reduced and the roll-off characteristics may be deteriorated.

Comparative Example Compound X6 included in Comparative Example 6 includes a structure in which two fused ring structures are linked like Example Compounds, but does not include a fused ring structure including a boron atom, one nitrogen atom, and one heteroatom (O or S), and thus may have low planarity and deteriorated stability. Accordingly, compared to the light emitting elements of Examples, the service life of the light emitting element of Comparative Example 6 may be reduced and the roll-off characteristics may be deteriorated.

Comparative Example Compound X7 included in Comparative Example 7 includes a fused ring structure in which two fused ring structures are linked and which contains a boron atom, one nitrogen atom, and one heteroatom (O or S) like Example Compounds, but does not include at least one of naphthalene, phenanthrene, or pyrene, and thus may not lower the lowest triplet excitation energy level (T1) of the fused polycyclic compound, and does not include a biphenyl group or a terphenyl group and thus the planarity of the molecule is high so that the intermolecular interaction is relatively stronger than those of Example Compounds, and thus the material stability may be deteriorated. Accordingly, compared to the light emitting elements of Examples, the service life of the light emitting element of Comparative Example 7 may be reduced and the roll-off characteristics may be deteriorated.

Comparative Example Compound X8 included in Comparative Example 8 includes a structure in which two fused ring structures are linked like Example Compounds, but includes a fused ring structure containing a boron atom and two oxygen atoms, so that it may be easily decomposed in the post-synthesis purification process. In addition, Comparative Example Compound X8 does not include a biphenyl group or a terphenyl group, and thus have high planarity of the molecule, and the intermolecular interaction is relatively stronger than those of Example Compounds. Therefore, the material stability may be deteriorated. Accordingly, compared to the light emitting elements of Examples, the service life of the light emitting element of Comparative Example 8 may be reduced and the roll-off characteristics may be deteriorated.

Comparative Example Compound X9 included in Comparative Example 9 includes a structure in which two fused ring structures are linked like Example Compounds, but includes a fused ring structure containing a boron atom and two oxygen atoms, so that it may be easily decomposed in the post-synthesis purification process. In addition, the fused ring structure containing a boron atom and two oxygen atoms has higher planarity than a fused ring structure containing a boron atom, one nitrogen atom, and one heteroatom (O or S), and thus the intermolecular interaction is strong, thereby deteriorating the stability. Accordingly, compared to the light emitting elements of Examples, the service life of the light emitting element of Comparative Example 9 may be reduced and the roll-off characteristics may be deteriorated.

The light emitting element of one or more embodiments of the present disclosure may exhibit improved element characteristics with high efficiency and a long service life by including the fused polycyclic compound of one or more embodiments.

The fused polycyclic compound of one or more embodiments may be included in the emission layer of the light emitting element to contribute to high efficiency and a long service life of the light emitting element.

The display apparatus/device of one or more embodiments may exhibit excellent or suitable display quality by including the light emitting element of one or more embodiments.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display apparatus/device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although the disclosure has been described with reference to example embodiments of the disclosure, it will be understood that the disclosure should not be limited to these embodiments but one or more suitable changes and modifications can be made by those skilled in the art without departing from the spirit and scope of the disclosure.

Accordingly, the technical scope of the disclosure is not intended to be limited to the contents set forth in the detailed description of the disclosure, but is intended to be defined by the appended claims and equivalents thereof.

What is claimed is:

1. A light emitting element comprising:
a first electrode;
a second electrode opposite to the first electrode; and
an emission layer between the first electrode and the second electrode,
wherein the emission layer comprises a first compound represented by Formula 1: 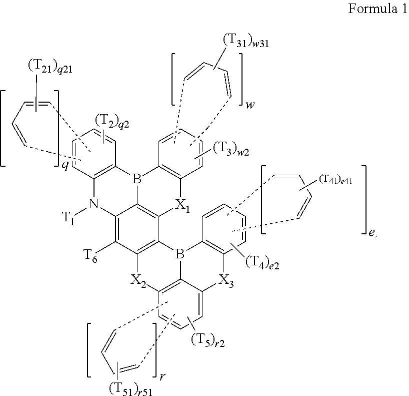
and
wherein, in Formula 1,
q, w, and e are each independently an integer of 0 to 3,
r is an integer of 0 to 2,
q21, w31, e41, and r51 are each independently an integer of 0 to 4,
the sum of q, w, e, and r is 1 or greater,
q2 is an integer of 0 to 4 when q is 0, q2 is an integer of 0 to 2 when q is 1, and q2 is 0 when q is 2 or 3,
w2 is an integer of 0 to 4 when w is 0, w2 is an integer of 0 to 2 when w is 1, and w2 is 0 when w is 2 or 3,
e2 is an integer of 0 to 4 when e is 0, e2 is an integer of 0 to 2 when e is 1, and e2 is 0 when e is 2 or 3,
r2 is an integer of 0 to 3 when r is 0, r2 is 0 or 1 when r is 1, and r2 is 0 when r is 2,
X₁ is O, or S,
X₂ is O, S, or NT₂₀,
X₃ is O, S, or NT₃₀,
T₁ is a substituted or unsubstituted aryl group having 6 to 30 ring-forming carbon atoms or a substituted or unsubstituted heteroaryl group having 2 to 30 ring-forming carbon atoms,
T₂₀, T₃₀, T₂, T₃, T₄, T₅, and T₆ are each independently hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
T₂₁, T₃₁, T₄₁, and T₅₁ are each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

2. The light emitting element of claim 1, wherein the first compound represented by Formula 1 is represented by Formula 2-1 or Formula 2-2: 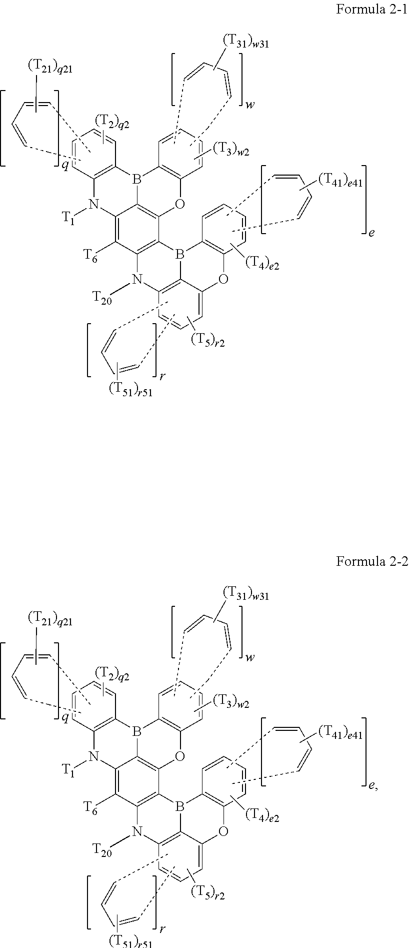
in Formula 2-1 and Formula 2-2,
q, w, e, r, q21, w31, e41, r51, q2, w2, e2, r2, T₁, T₂₀, T₃₀, T₂, T₃, T₄, T₅, T₆, T₂₁, T₃₁, T₄₁, and T₅₁ each being the same as defined in Formula 1.

3. The light emitting element of claim 1, wherein in Formula 1, T₁ is a substituted or unsubstituted biphenyl group.

4. The light emitting element of claim 3, wherein in Formula 1, T₁ is an unsubstituted o-biphenyl group.

5. The light emitting element of claim 1, wherein in Formula 1, each of T₂₀ and T₃₀ is a substituted or unsubstituted terphenyl group.

6. The light emitting element of claim 5, wherein in Formula 1, each of T₂₀ and T₃₀ is an unsubstituted m-terphenyl group.

7. The light emitting element of claim 1, wherein the first compound represented by Formula 1 is represented by any one selected from among Formula 3-1 to Formula 3-7: 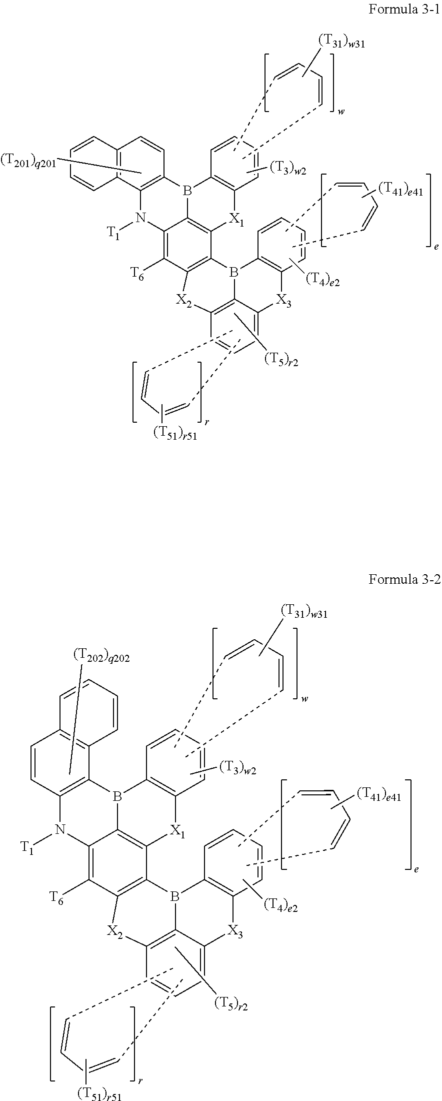 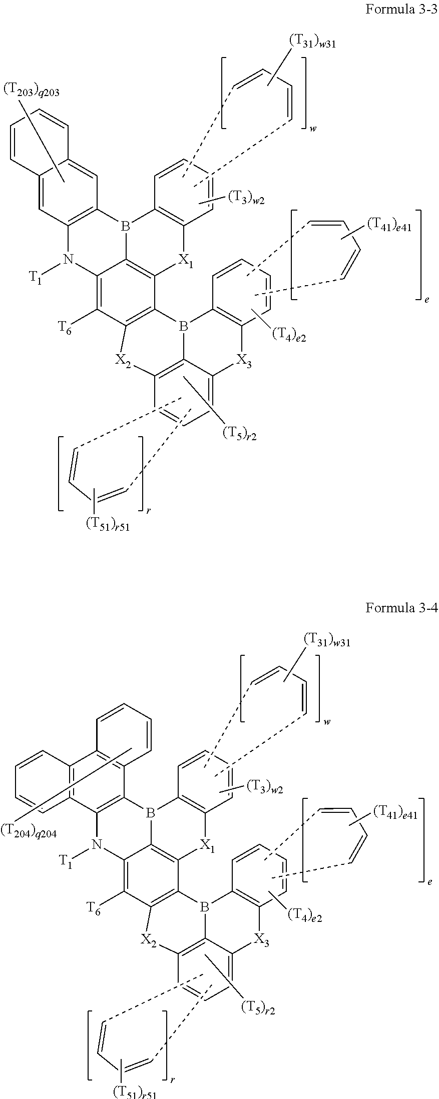 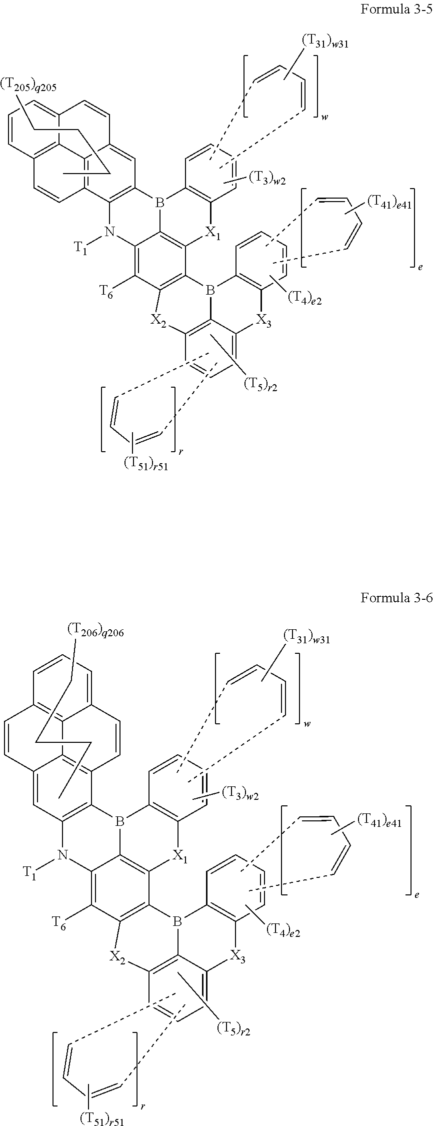 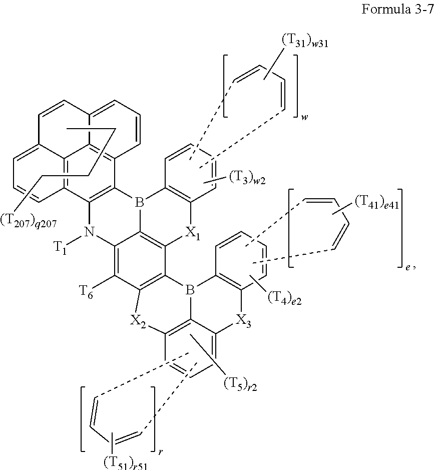
in Formula 3-1 to Formula 3-7,
T₂₀₁, T₂₀₂, T₂₀₃, T₂₀₄, T₂₀₅, T₂₀₆, and T₂₀₇ being each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
q201, q202, and q203 being each independently an integer of 0 to 6,
q204, q205, q206, and q207 being each independently an integer of 0 to 8, and
w, e, r, w31, e41, r51, w2, e2, r2, X₁, X₂, X₃, T₁, T₂₀, T₃₀, T₃, T₄, T₅, T₆, T₃₁, T₄₁, and T₅₁ each being the same as defined in Formula 1.

8. The light emitting element of claim 1, wherein the first compound represented by Formula 1 is represented by any one selected from among Formula 4-1 to Formula 4-7: 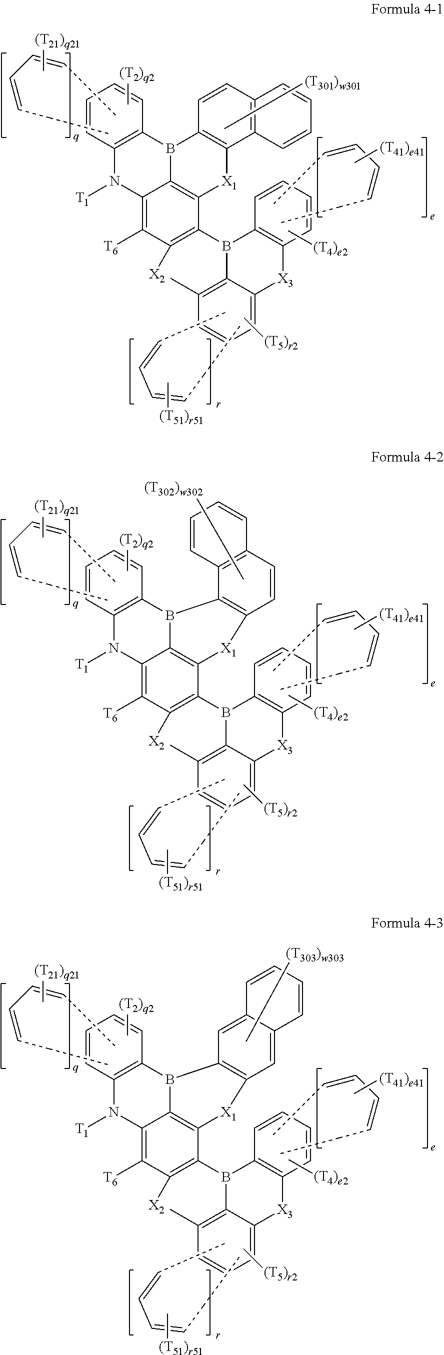 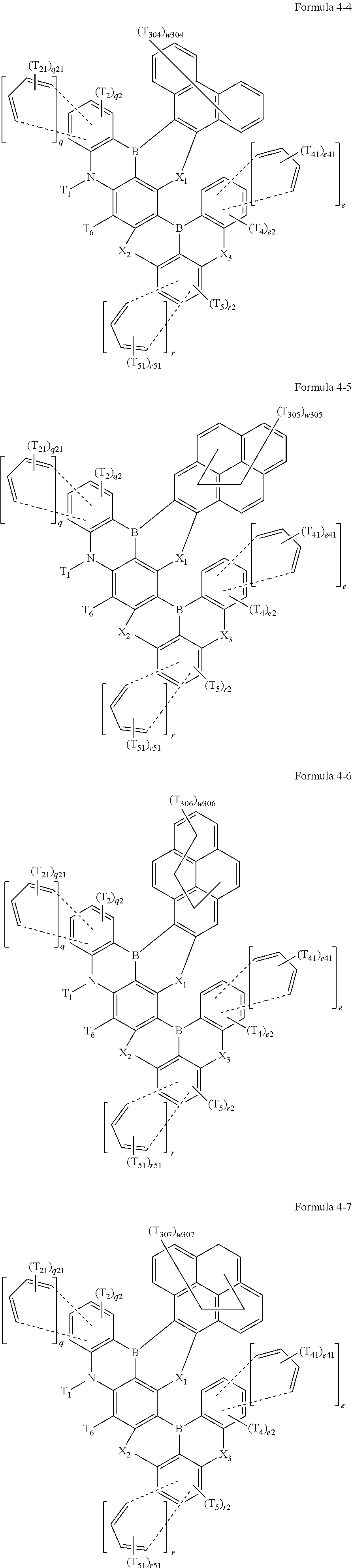
in Formula 4-1 to Formula 4-7,
T₃₀₁, T₃₀₂, T₃₀₃, T₃₀₄, T₃₀₅, T₃₀₆, and T₃₀₇ being each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
w301, w302, and w303 being each independently an integer of 0 to 6,
w304, w305, w306, and w307 being each independently an integer of 0 to 8, and
q, e, r, q21, e41, r51, q2, e2, r2, X₁, X₂, X₃, T₁, T₂₀, T₃₀, T₂, T₄, T₅, T₆, T₂₁, T₄₁, and T₅₁ each being the same as defined in Formula 1.

9. The light emitting element of claim 1, wherein the first compound represented by Formula 1 is represented by any one selected from among Formula 5-1 to Formula 5-7: 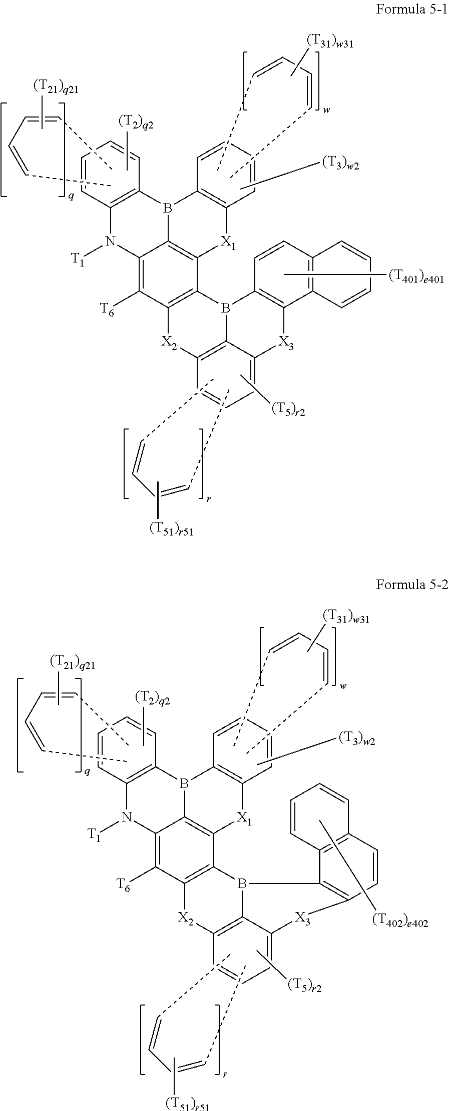 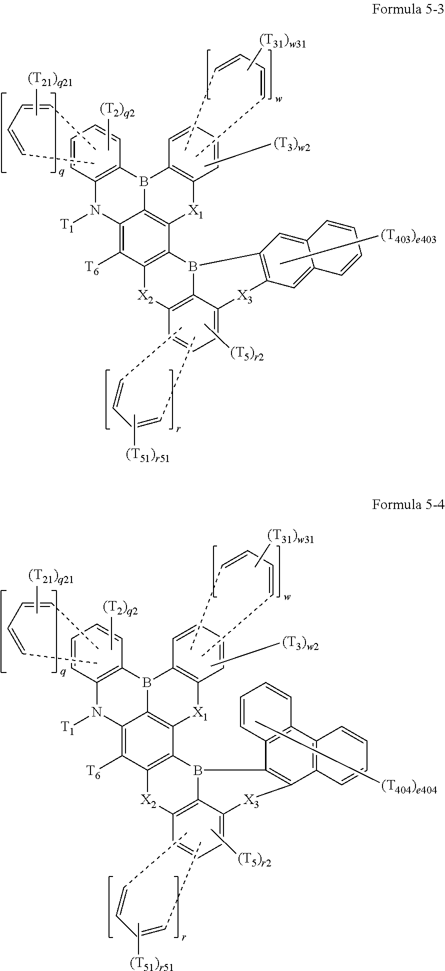 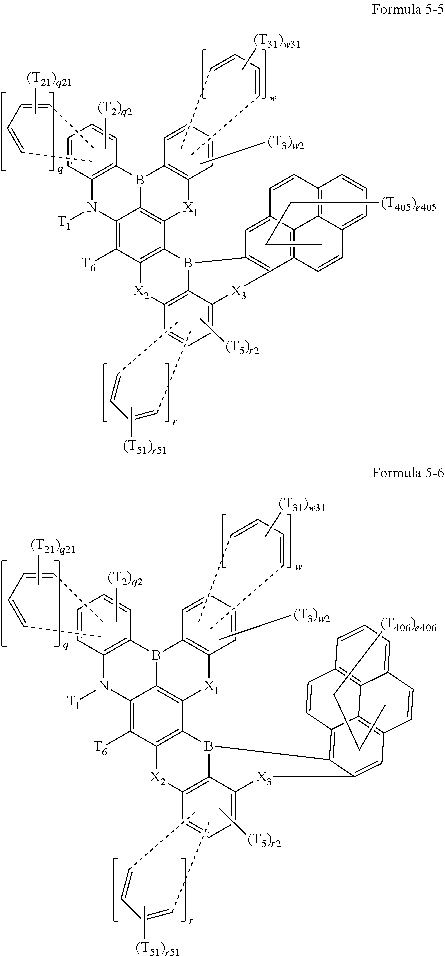 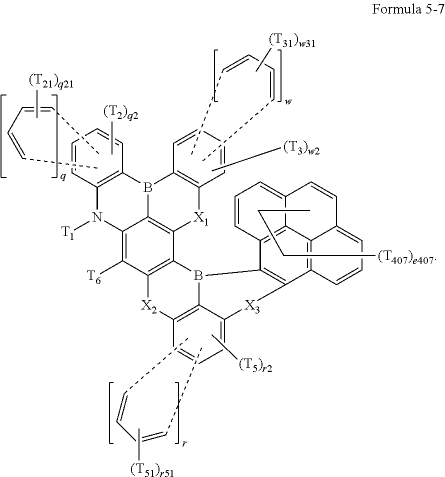
in Formula 5-1 to Formula 5-7,
T₄₀₁, T₄₀₂, T₄₀₃, T₄₀₄, T₄₀₅, T₄₀₆, and T₄₀₇ being each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
e401, e402, and e403 being each independently an integer of 0 to 6,
e404, e405, e406, and e407 being each independently an integer of 0 to 8, and
q, w, r, q21, w31, r51, q2, w2, r2, X₁, X₂, X₃, T₁, T₂₀, T₃₀, T₂, T₃, T₅, T₆, T₂₁, T₃₁, and T₅₁ each being the same as defined in Formula 1.

10. The light emitting element of claim 1, wherein the first compound represented by Formula 1 is represented by any one selected from among Formula 6-1 to Formula 6-3: 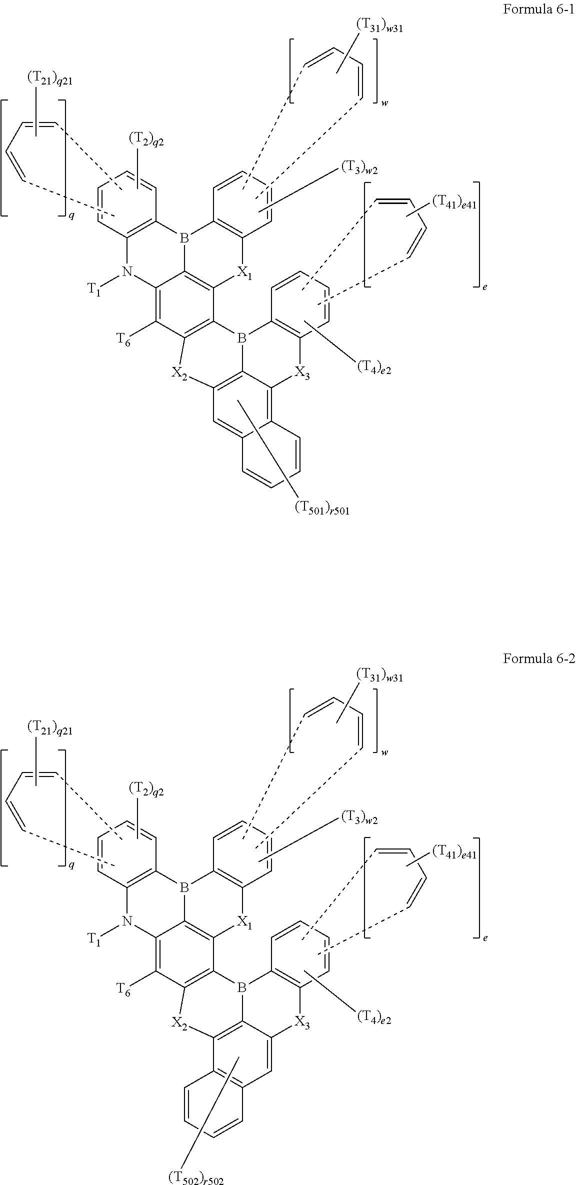 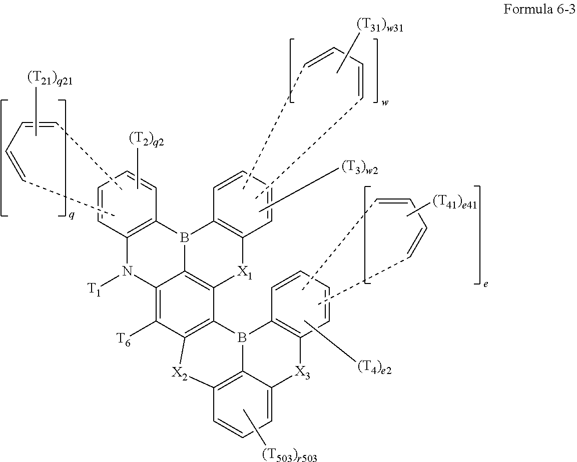
in Formula 6-1 to Formula 6-3,
T₅₀₁ to T₅₀₃ being each independently hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
r501 and r502 being each independently an integer of 0 to 5,
r503 being an integer of 0 to 3, and
q, w, e, q21, w31, e41, q2, w2, e2, X₁, X₂, X₃, T₁, T₂₀, T₃₀, T₂, T₃, T₄, T₆, T₂₁, T₃₁, and T₄₁ each being the same as defined in Formula 1.

11. The light emitting element of claim 1, wherein the emission layer further comprises at least one of a second compound represented by Formula HT-1, a third compound represented by Formula ET-1, or a fourth compound represented by Formula D-1: 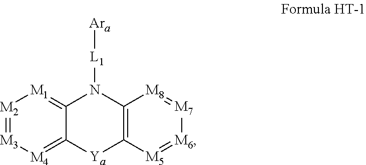
wherein, in Formula HT-1,
M₁ to M₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Arₐ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring; 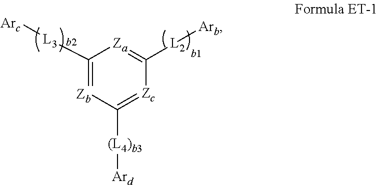
wherein, in Formula ET-1,
at least one selected from among Zₐ to Z_{c} is N, and the rest are CR₅₆,
R₅₆ is hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
b1 to b3 are each independently an integer of 0 to 10,
Ar_{b} to Ar_{d} are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; and 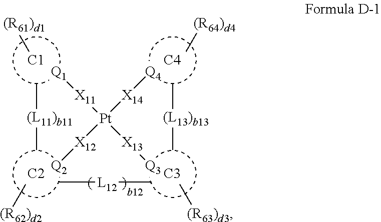
wherein, in Formula D-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
X₁₁ to X₁₄ are each independently a direct linkage or *—O—*,
L₁₁ to L₁₃ are each independently a direct linkage, *—O—*, *—S—*, 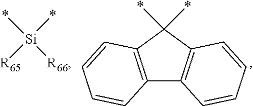
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

12. The light emitting element of claim 1, wherein the first compound represented by Formula 1 is any one from selected from among compounds in Compound Group 1:

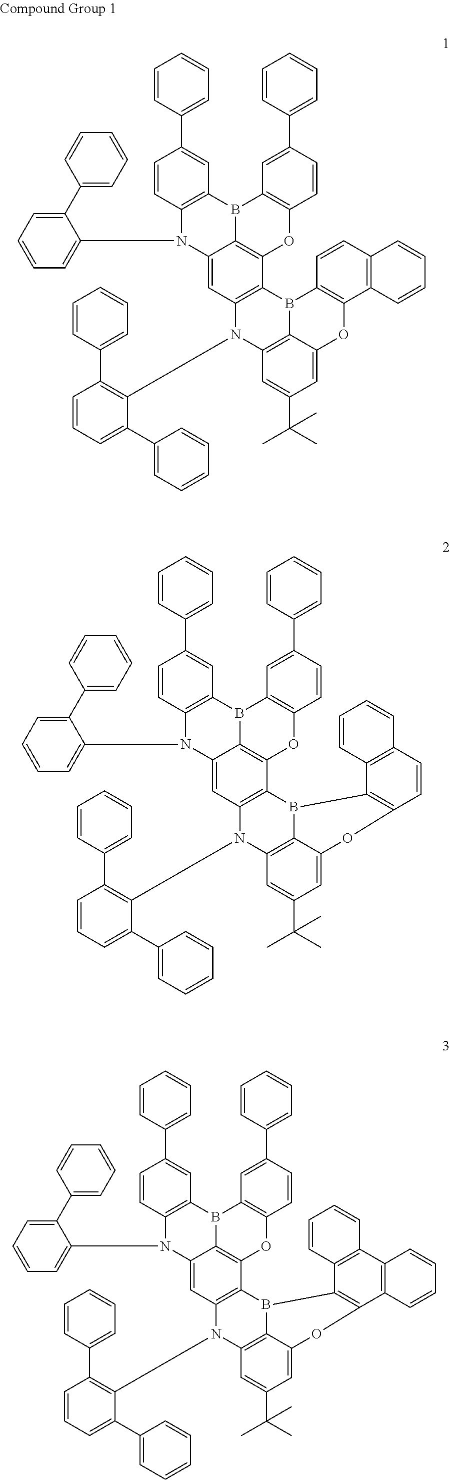 [SMILES: CC(C)(C)c1cc2c3c(c1)N(c1c(-c4ccccc4)cccc1-c1ccccc1)c1cc4c5c(c1B3c1ccc3ccccc3c1O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Oc1ccc(-c2ccccc2)cc1B5c1cc(-c2ccccc2)ccc1N4c1ccccc1-c1ccccc1]

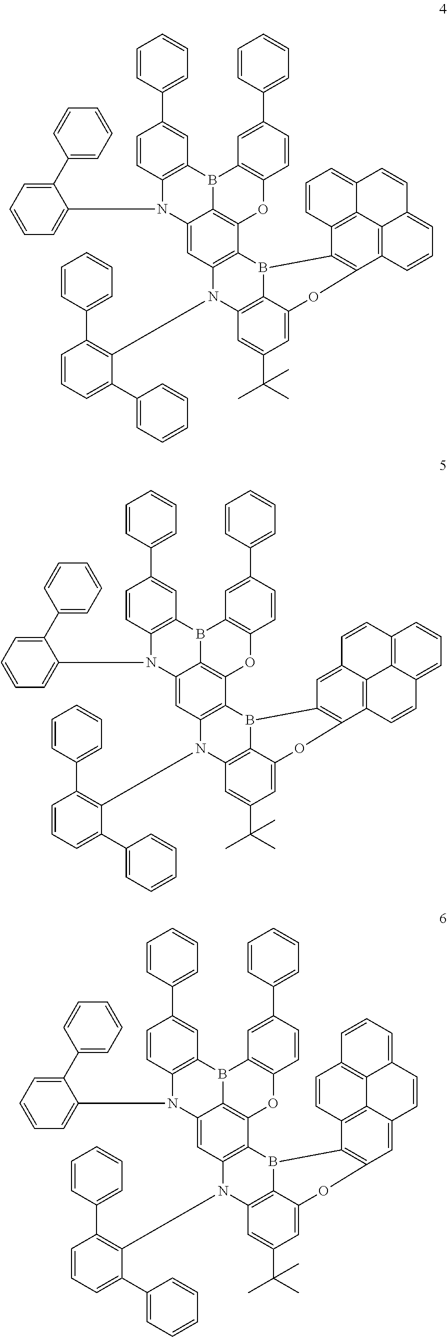 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1ccc(-c2ccccc2)cc1B5c1cc(-c2ccccc2)ccc1N4c1ccccc1-c1ccccc1]

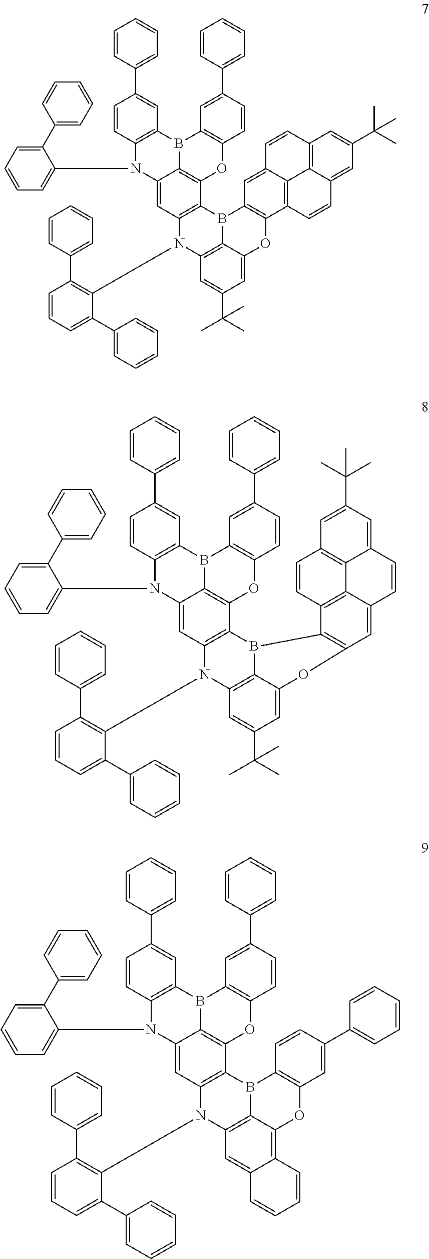 [SMILES: CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1O2)c3c67)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Oc1ccc(-c2ccccc2)cc1B5c1cc(-c2ccccc2)ccc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Oc2ccc(-c3ccccc3)cc2B6c2cc(-c3ccccc3)ccc2N5c2ccccc2-c2ccccc2)cc1]

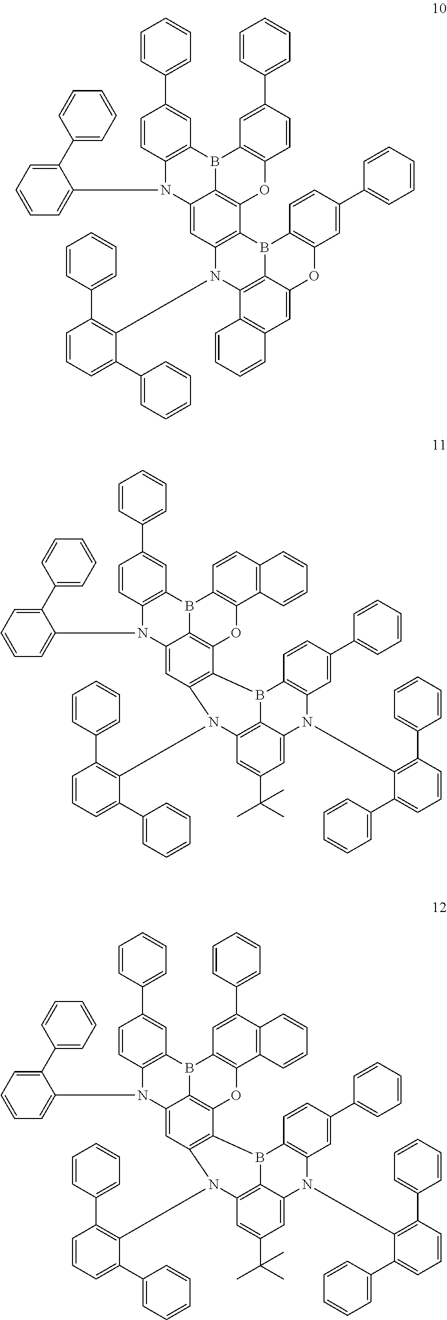

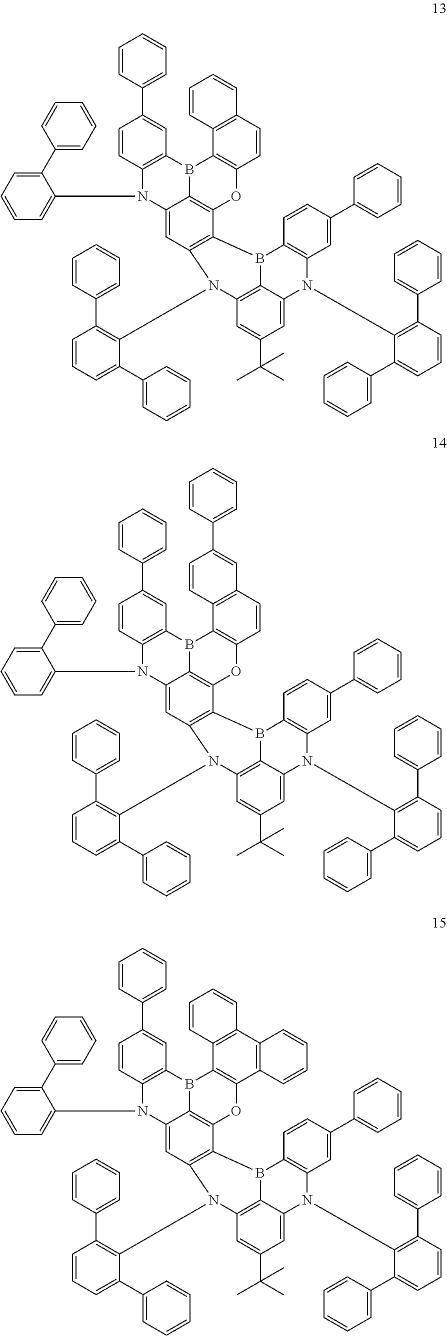

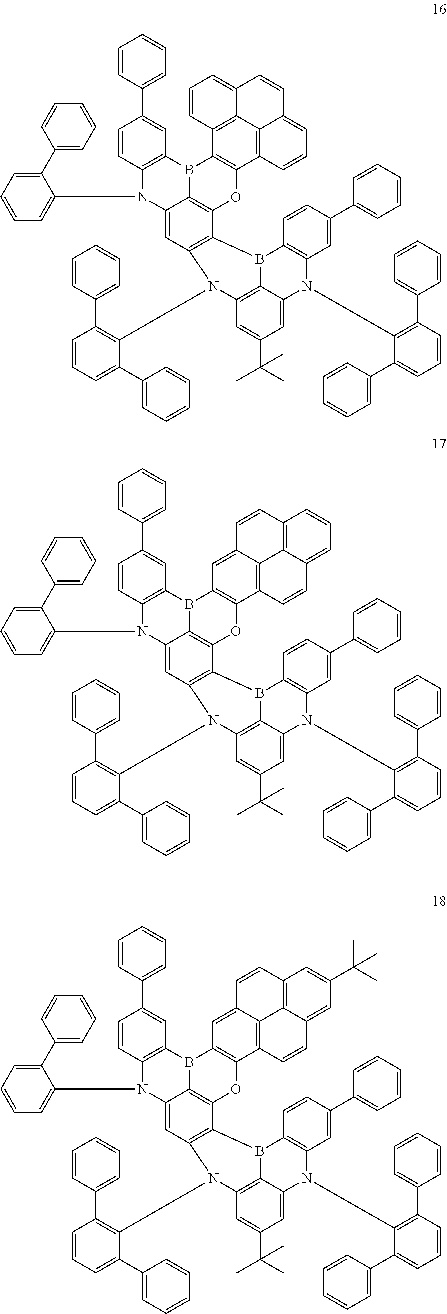

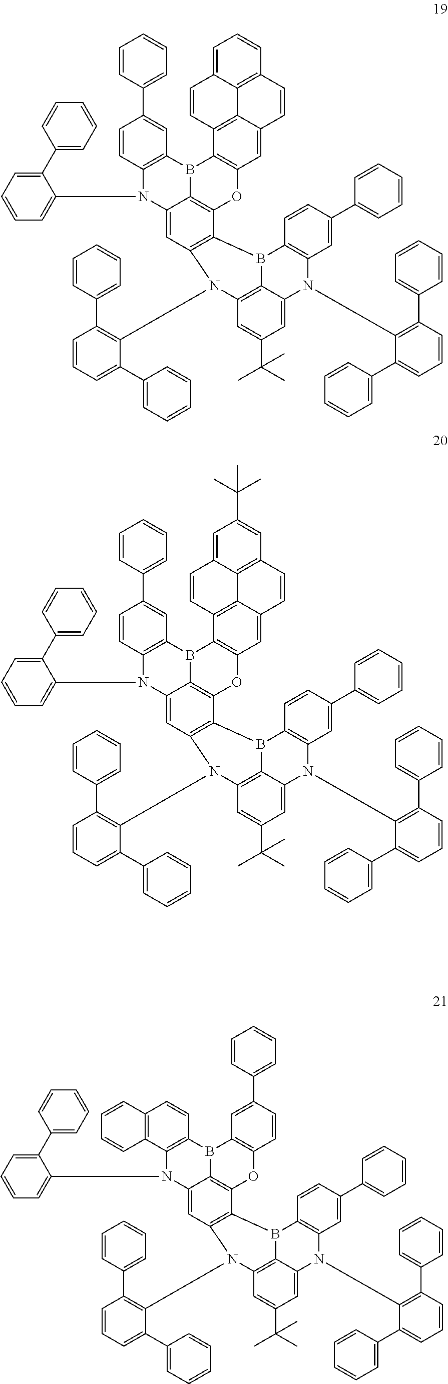

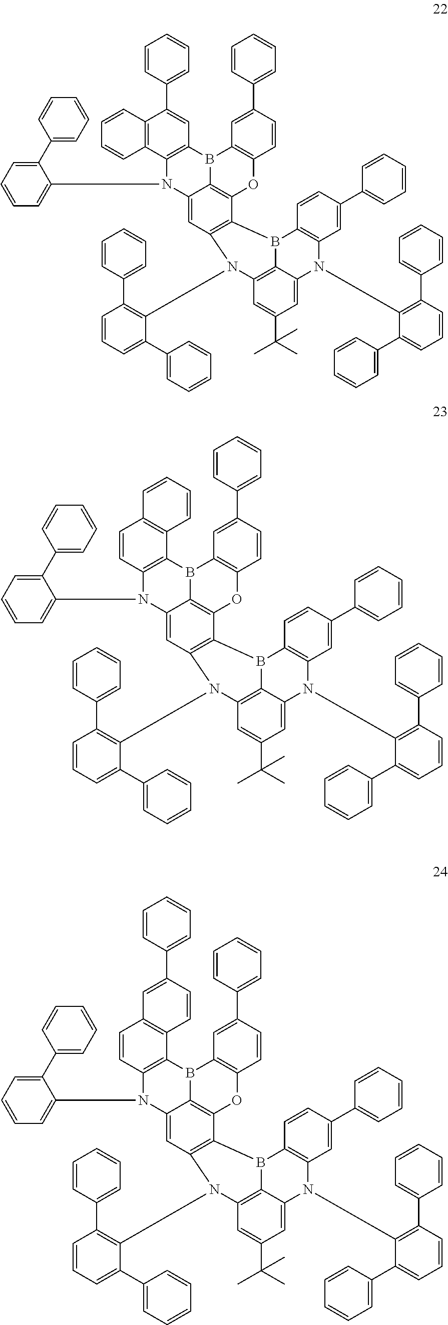

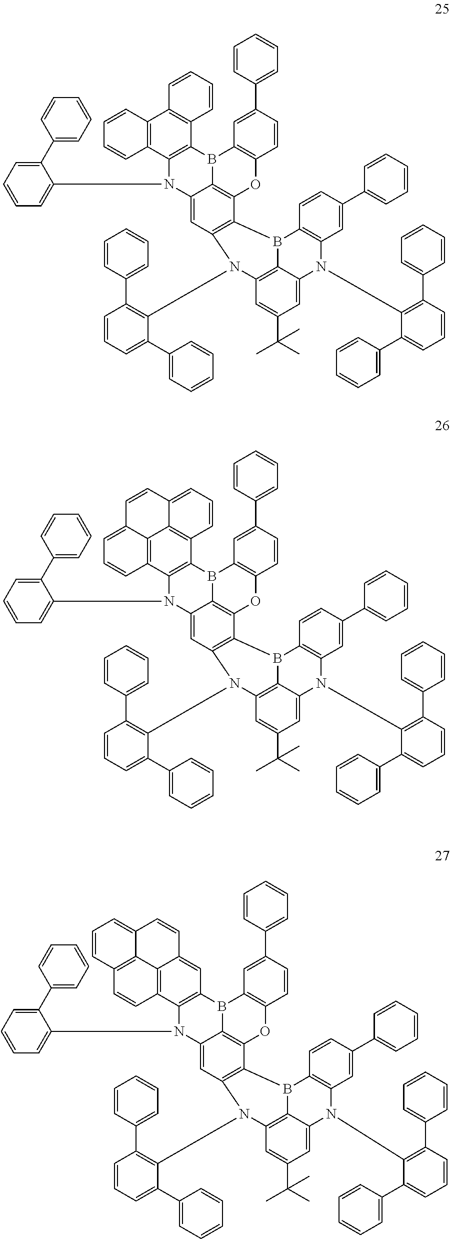

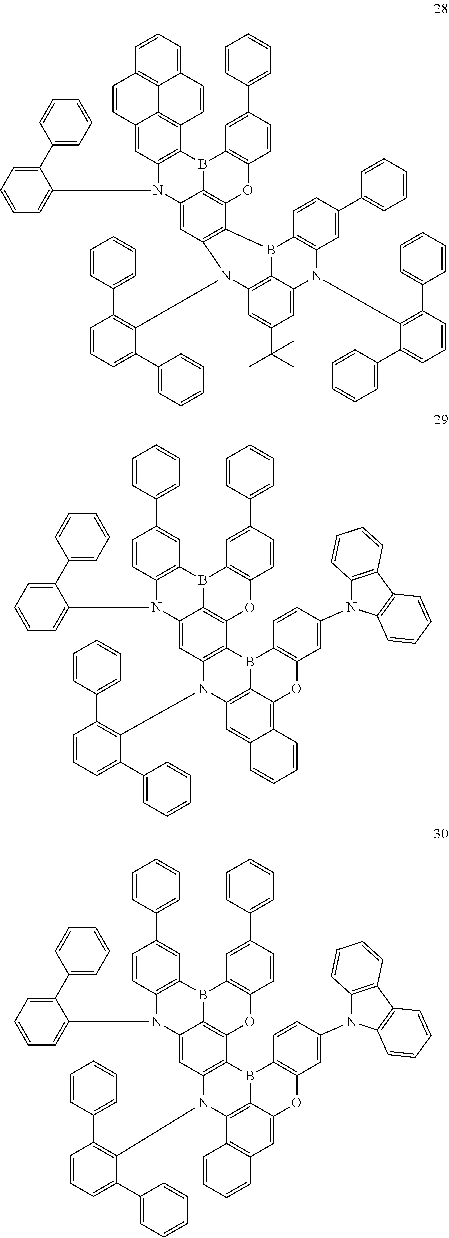

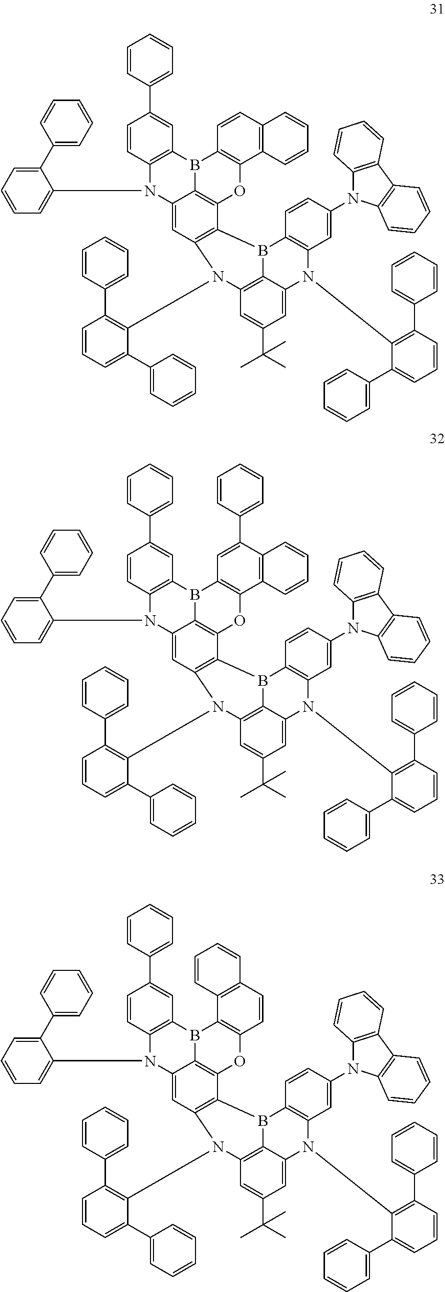

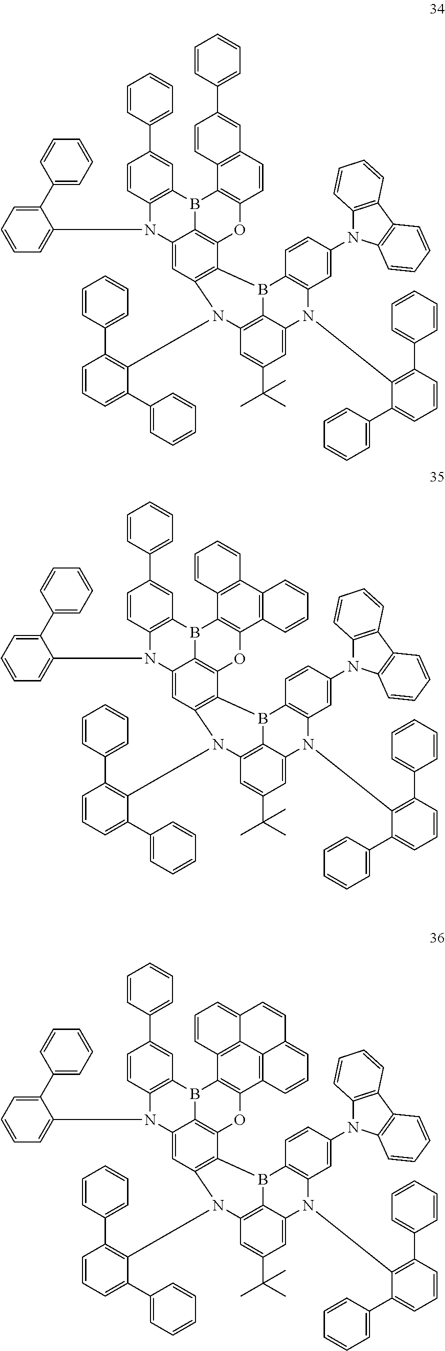

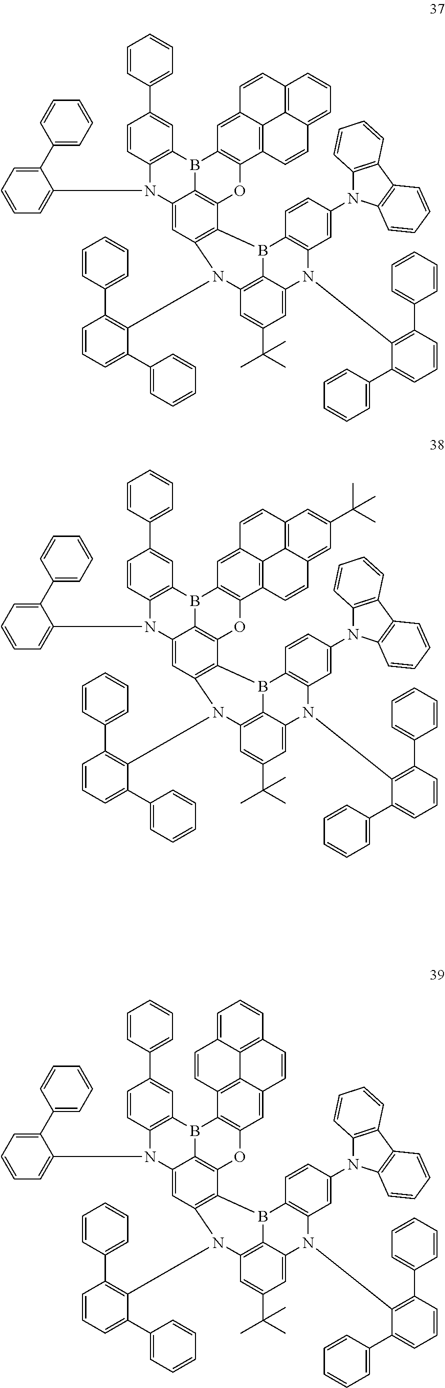

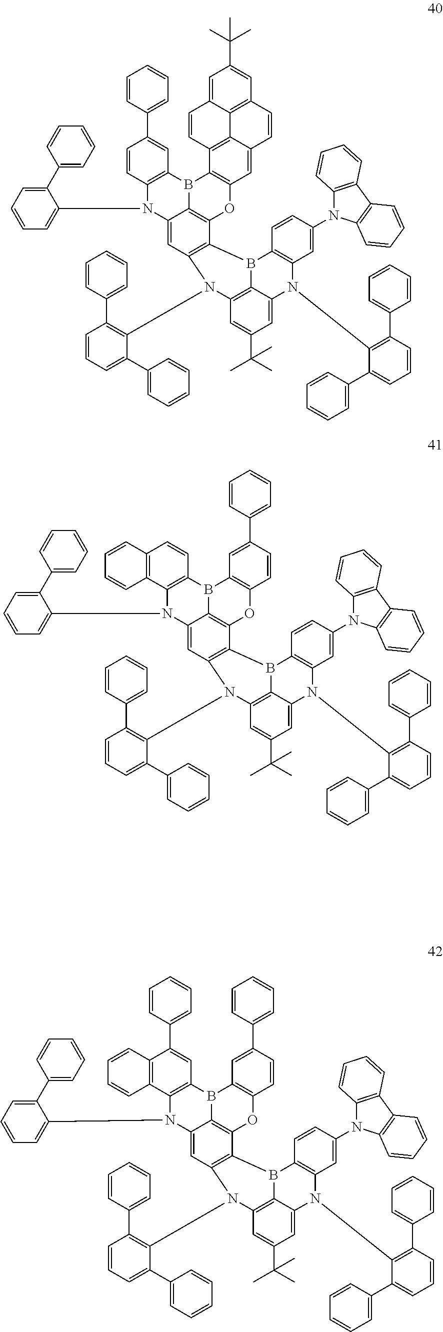

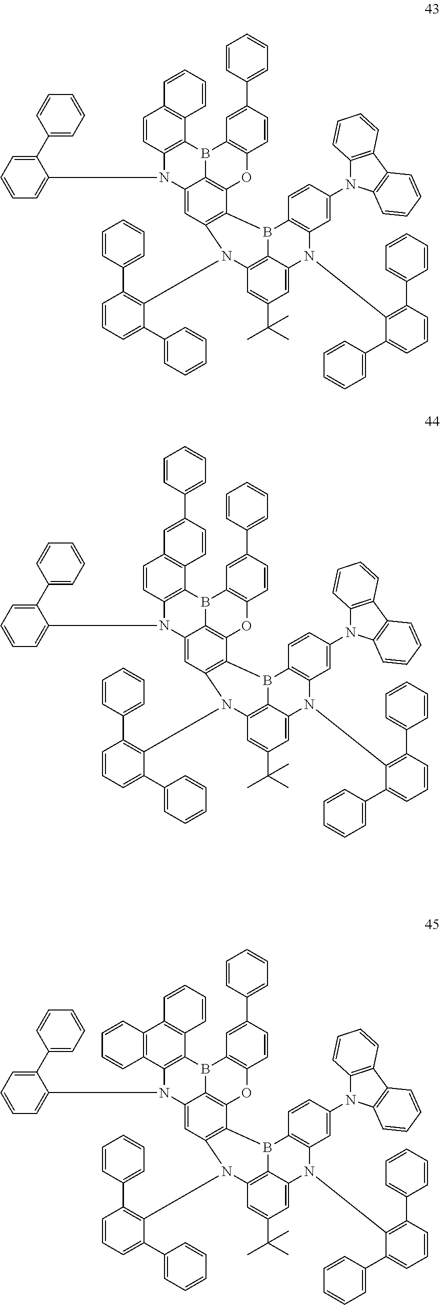

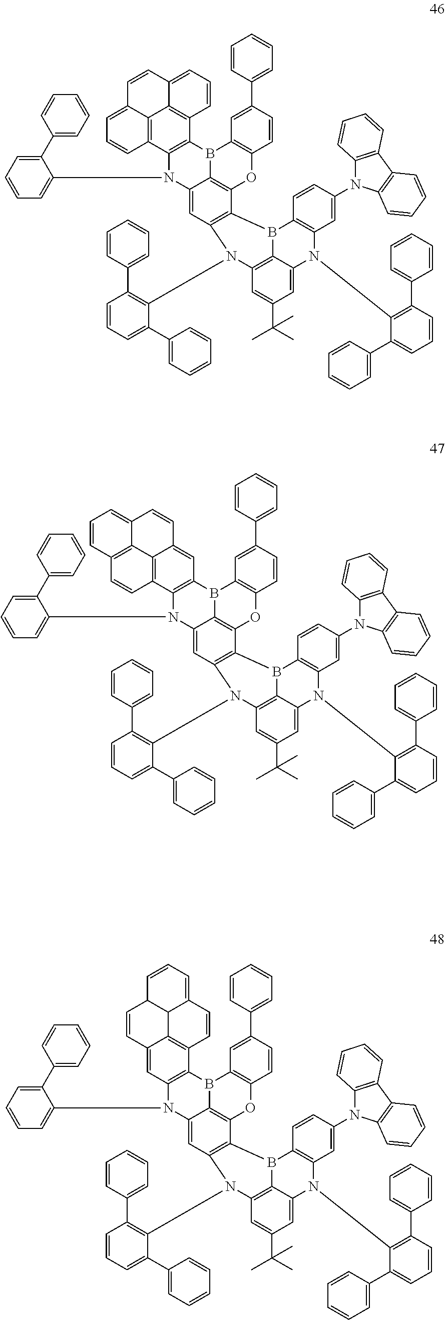

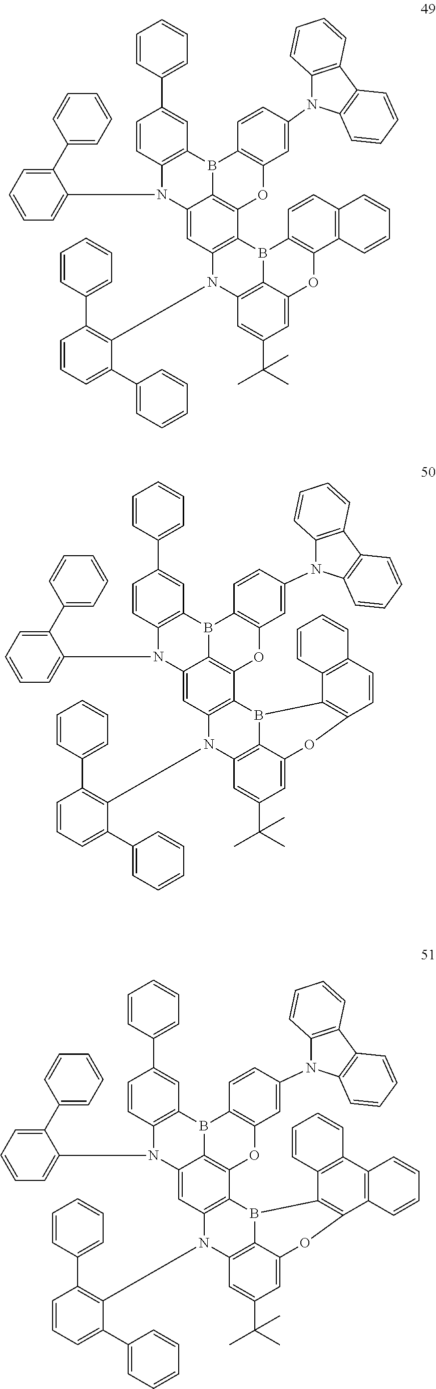 [SMILES: CC(C)(C)c1cc2c3c(c1)N(c1c(-c4ccccc4)cccc1-c1ccccc1)c1cc4c5c(c1B3c1ccc3ccccc3c1O2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(ccc3ccccc13)O2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Oc1cc(-n2c3ccccc3c3ccccc32)ccc1B5c1cc(-c2ccccc2)ccc1N4c1ccccc1-c1ccccc1]

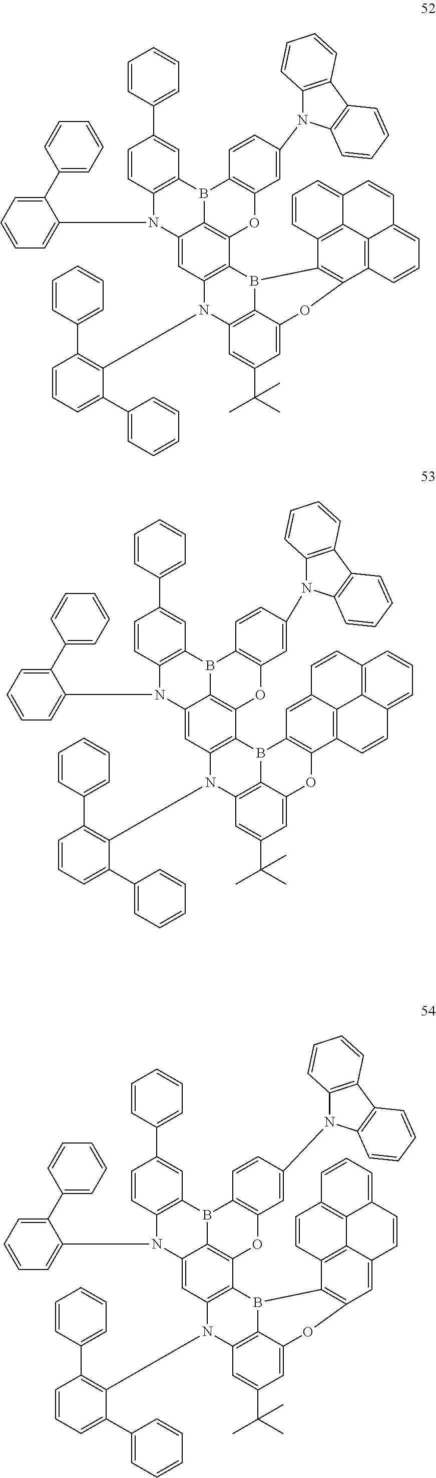 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1cc(-n2c3ccccc3c3ccccc32)ccc1B5c1cc(-c2ccccc2)ccc1N4c1ccccc1-c1ccccc1]

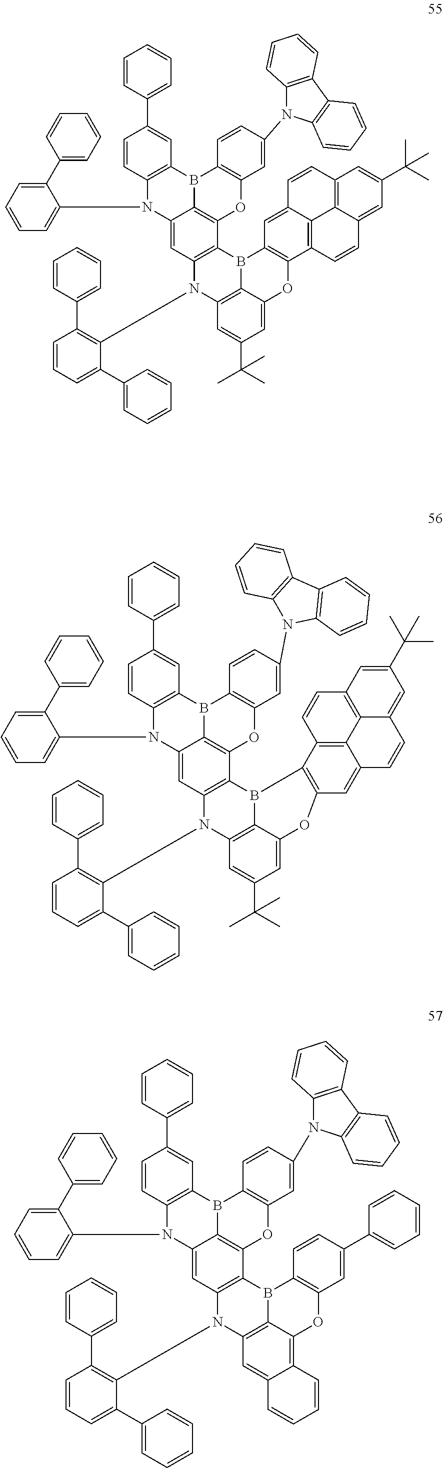

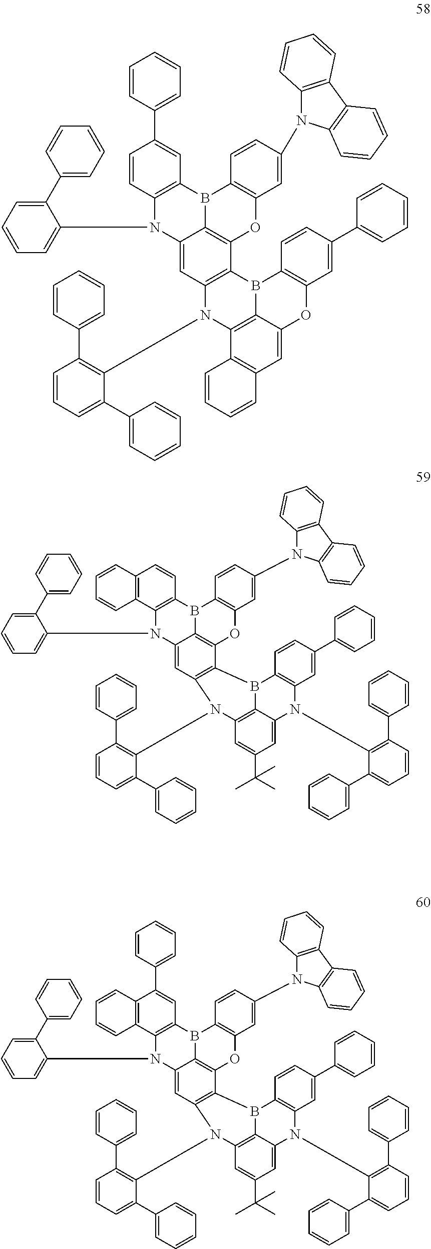

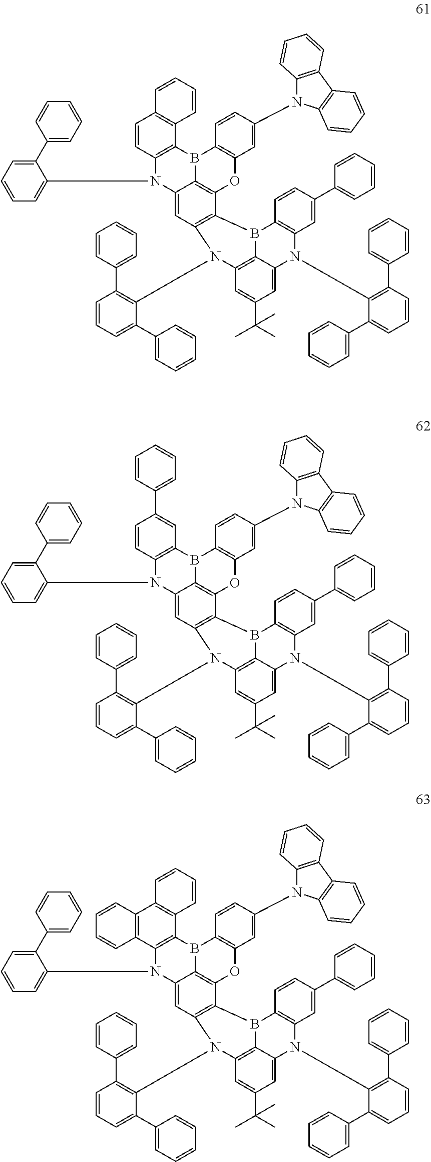

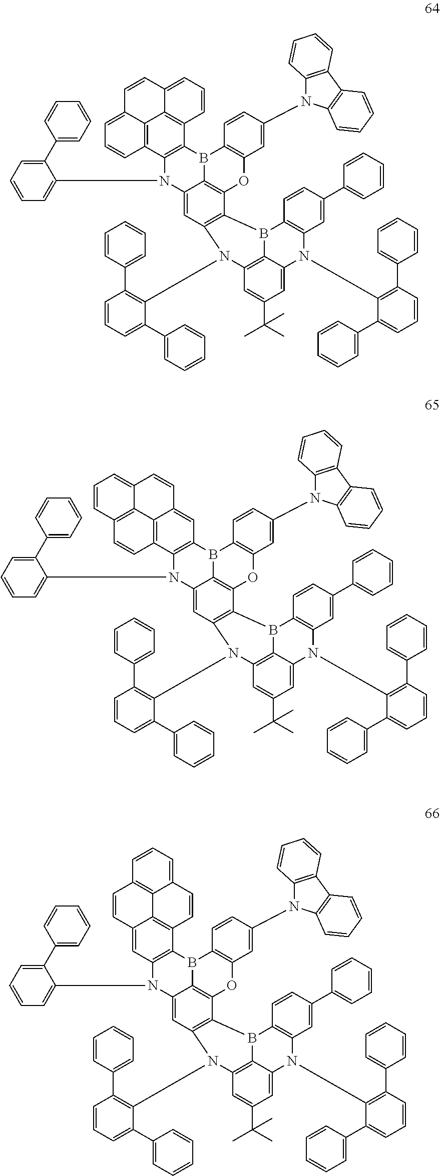

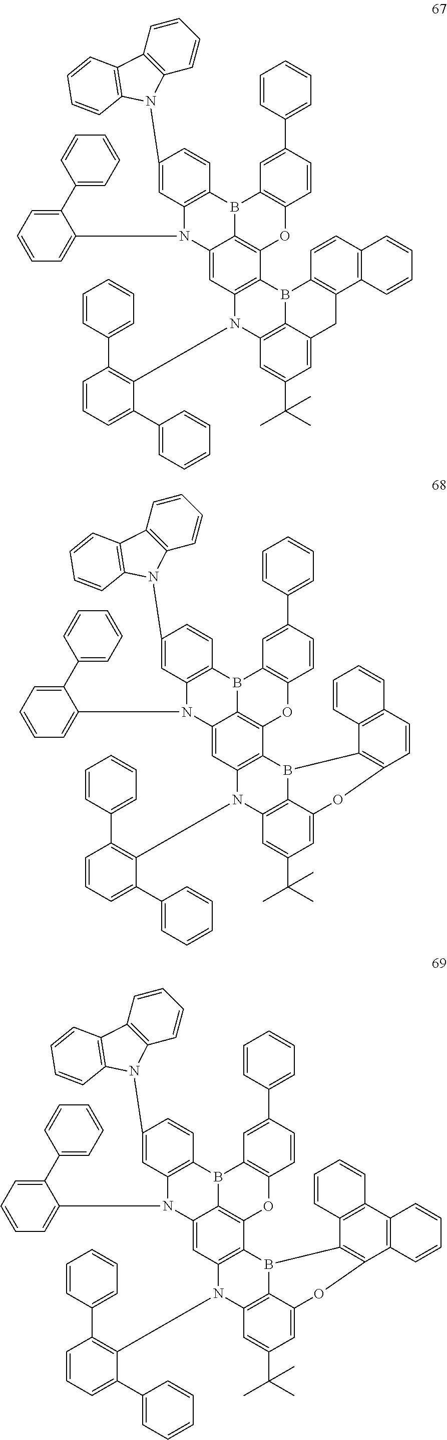

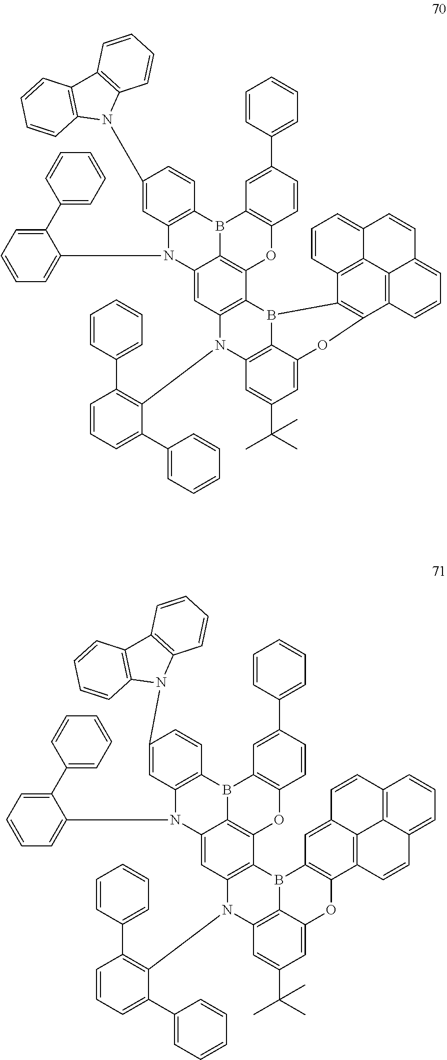 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Oc1ccc(-c2ccccc2)cc1B5c1ccc(-n2c3ccccc3c3ccccc32)cc1N4c1ccccc1-c1ccccc1]

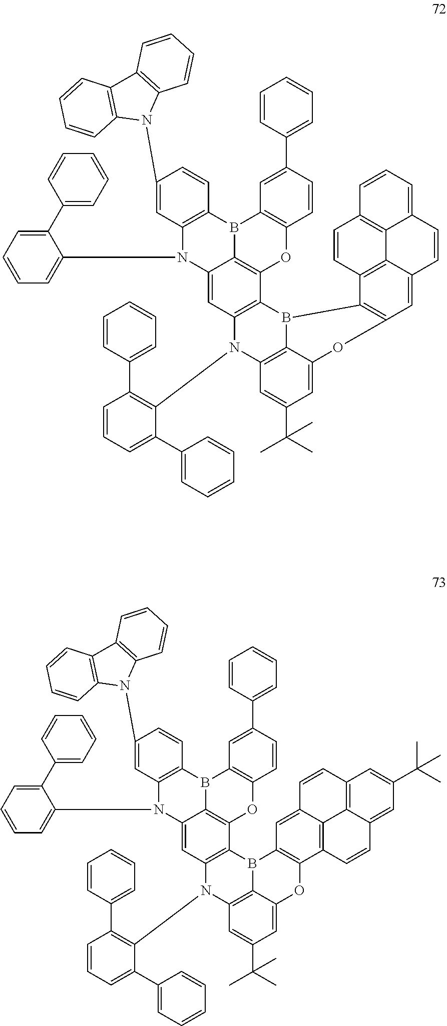 [SMILES: CC(C)(C)c1cc2c3c(c1)N(c1c(-c4ccccc4)cccc1-c1ccccc1)c1cc4c5c(c1B3c1c(cc3ccc6cccc7ccc1c3c67)O2)Oc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1O2)c3c67)Oc1ccc(-c2ccccc2)cc1B5c1ccc(-n2c3ccccc3c3ccccc32)cc1N4c1ccccc1-c1ccccc1]

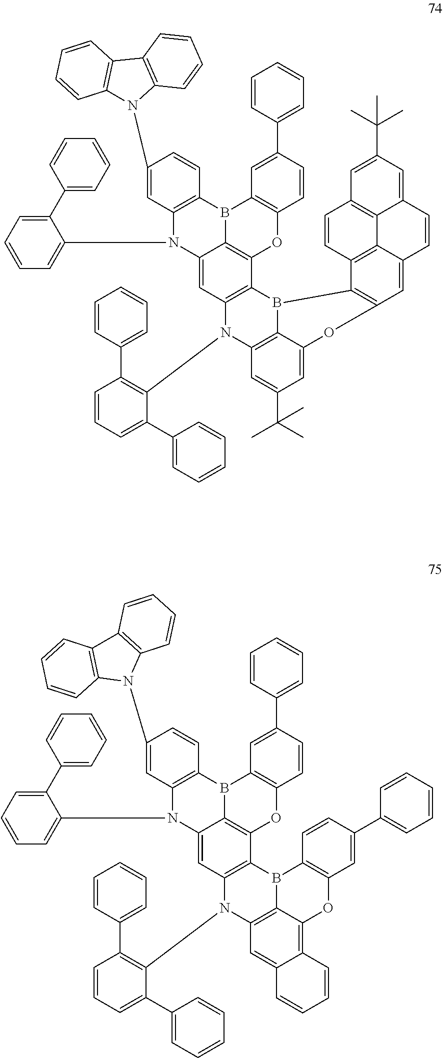 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Oc1ccc(-c2ccccc2)cc1B5c1ccc(-n2c3ccccc3c3ccccc32)cc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Oc2ccc(-c3ccccc3)cc2B6c2ccc(-n3c4ccccc4c4ccccc43)cc2N5c2ccccc2-c2ccccc2)cc1]

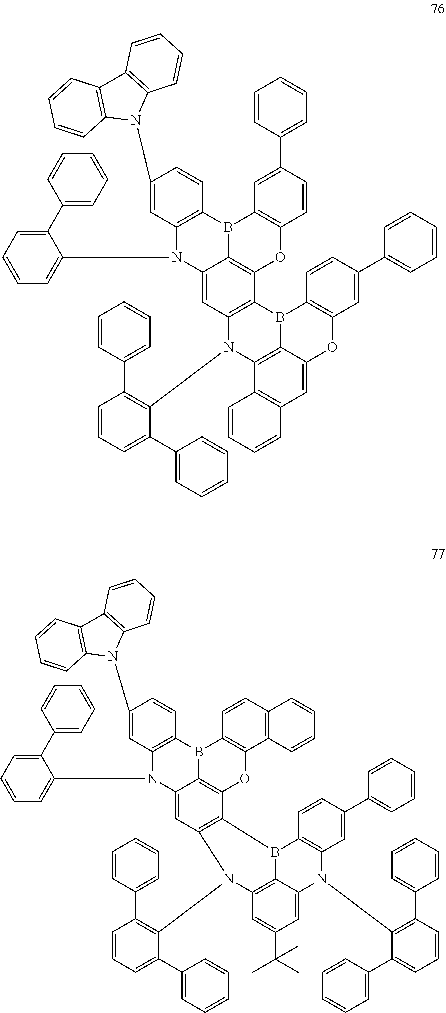 [SMILES: c1ccc(-c2ccc3c(c2)Oc2cc4ccccc4c4c2B3c2c(cc3c5c2Oc2ccc(-c6ccccc6)cc2B5c2ccc(-n5c6ccccc6c6ccccc65)cc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(ccc2ccccc12)B5c1ccc(-n2c3ccccc3c3ccccc32)cc1N4c1ccccc1-c1ccccc1]

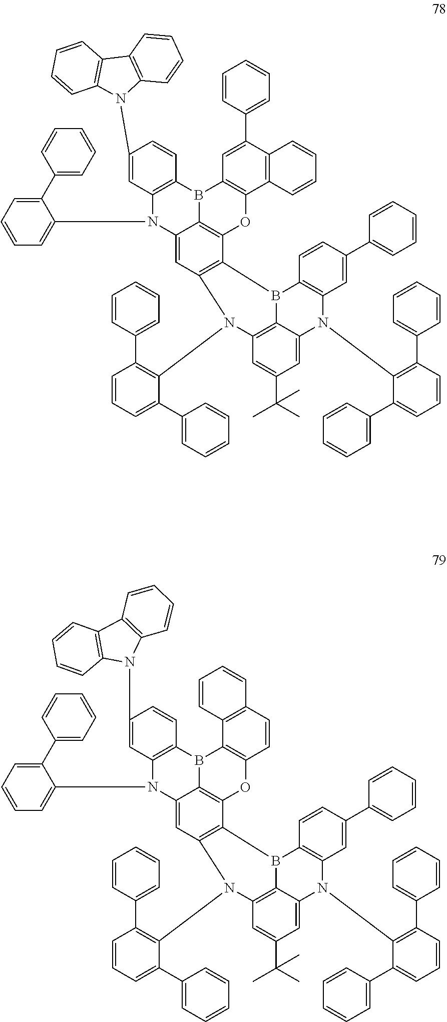 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(cc(-c2ccccc2)c2ccccc12)B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccc2ccccc2c1B5c1ccc(-n2c3ccccc3c3ccccc32)cc1N4c1ccccc1-c1ccccc1]

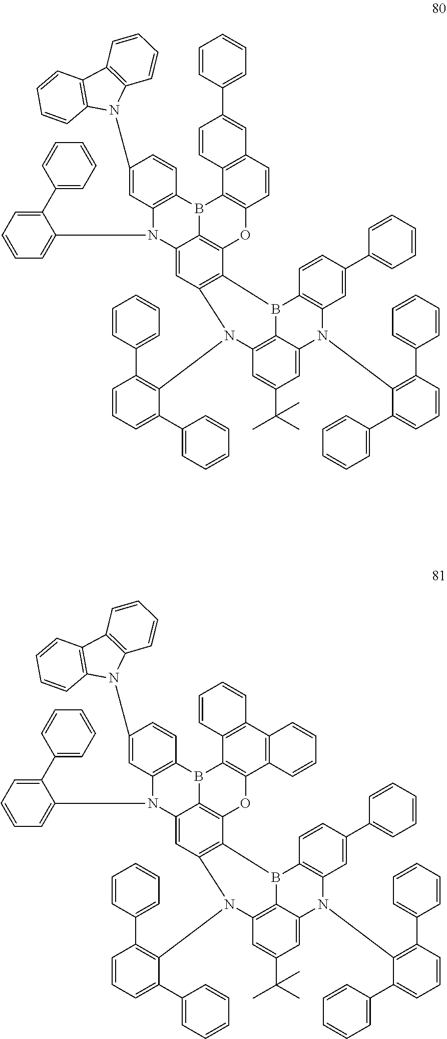 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1ccc2cc(-c3ccccc3)ccc2c1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(c2ccccc2c2ccccc12)B5c1ccc(-n2c3ccccc3c3ccccc32)cc1N4c1ccccc1-c1ccccc1]

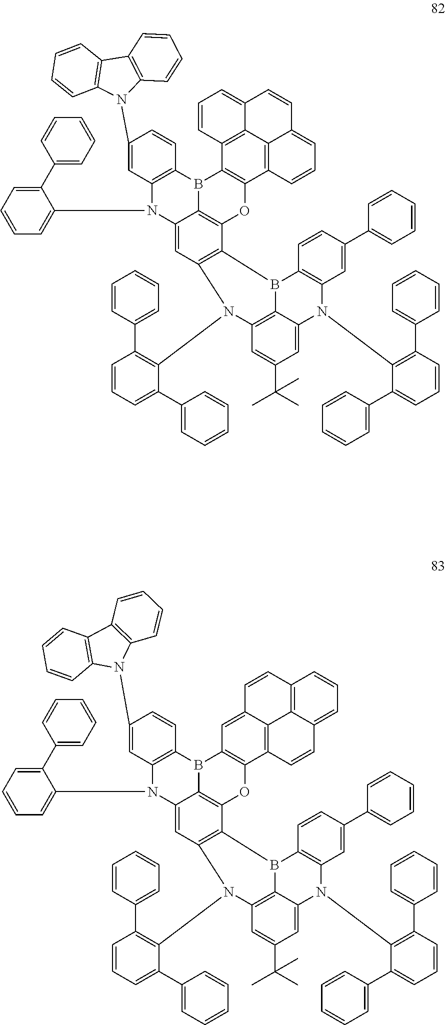 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(c2cccc3ccc6cccc1c6c32)B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(cc2ccc3cccc6ccc1c2c36)B5c1ccc(-n2c3ccccc3c3ccccc32)cc1N4c1ccccc1-c1ccccc1]

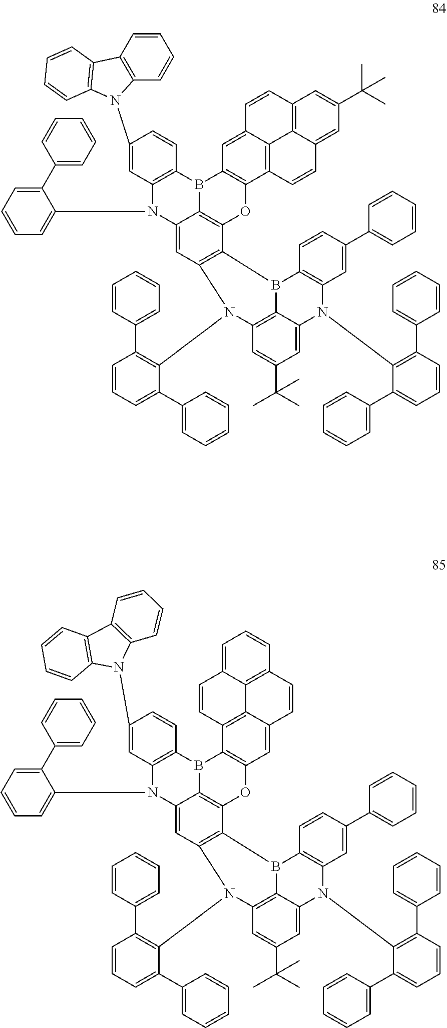 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1c(cc2ccc3cc(C(C)(C)C)cc6ccc1c2c36)B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc2ccc3cccc6ccc(c1B5c1ccc(-n5c7ccccc7c7ccccc75)cc1N4c1ccccc1-c1ccccc1)c2c36]

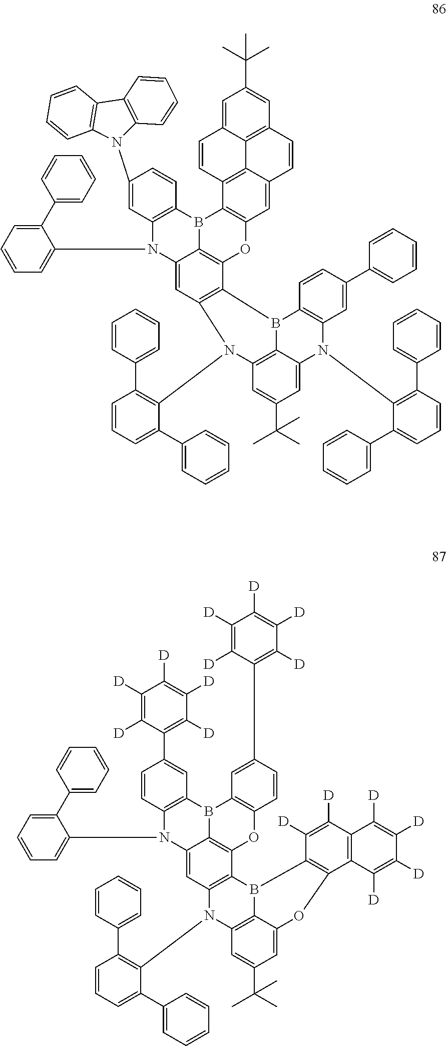 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc2ccc3cc(C(C)(C)C)cc6ccc(c1B5c1ccc(-n5c7ccccc7c7ccccc75)cc1N4c1ccccc1-c1ccccc1)c2c36 ; [2H]c1c([2H])c([2H])c(-c2ccc3c(c2)B2c4cc(-c5c([2H])c([2H])c([2H])c([2H])c5[2H])ccc4N(c4ccccc4-c4ccccc4)c4cc5c(c(c42)O3)B2c3c(cc(C(C)(C)C)cc3N5c3c(-c4ccccc4)cccc3-c3ccccc3)Oc3c2c([2H])c([2H])c2c([2H])c([2H])c([2H])c([2H])c32)c([2H])c1[2H]]

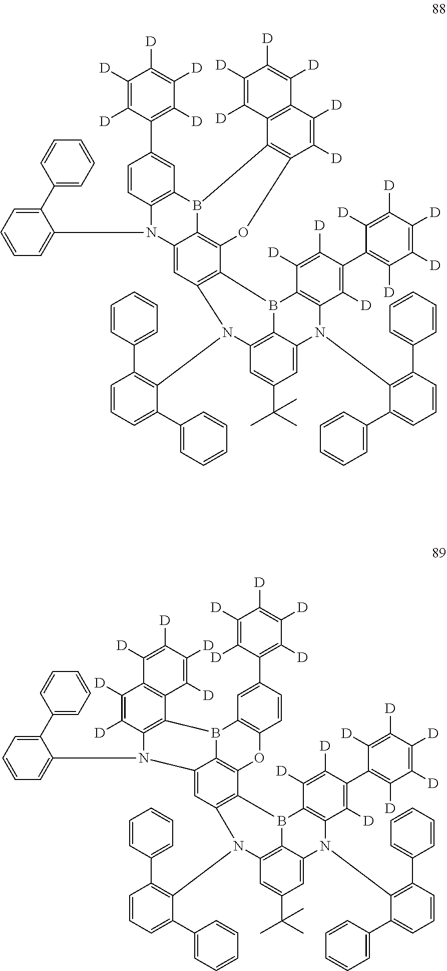

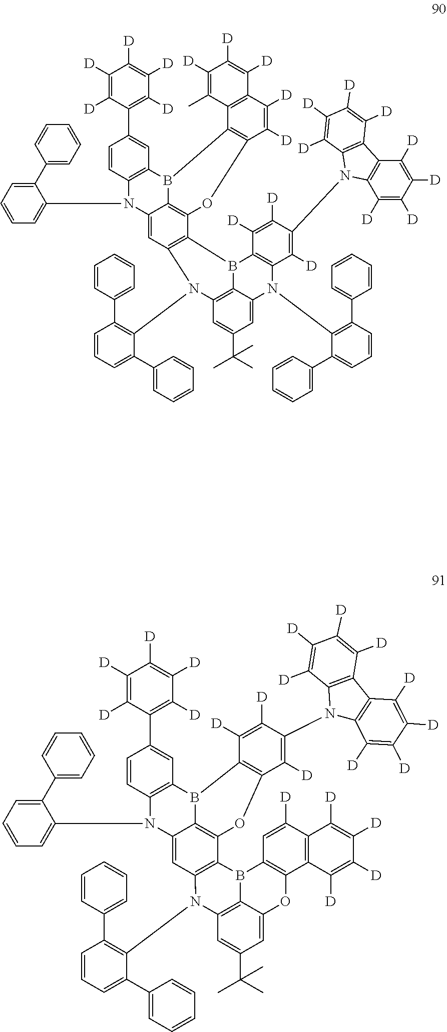

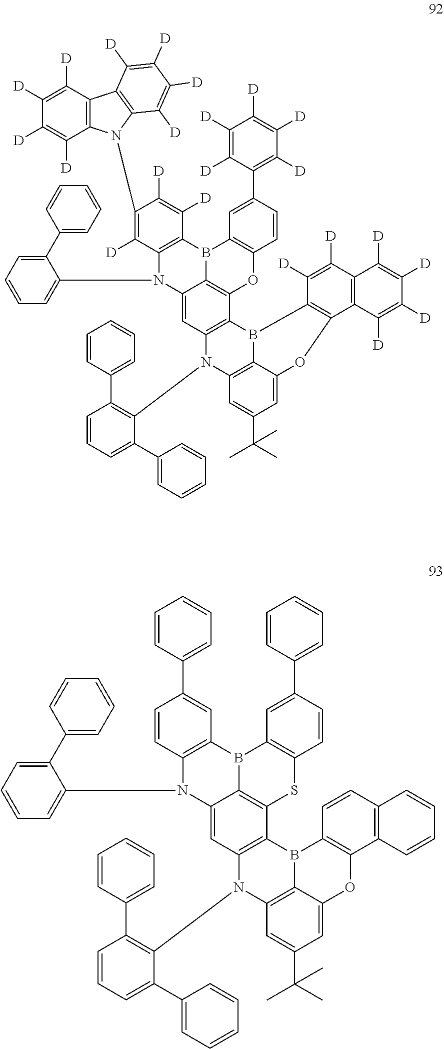 [SMILES: [2H]c1c([2H])c([2H])c(-c2ccc3c(c2)B2c4c(cc5c(c4O3)B3c4c(cc(C(C)(C)C)cc4N5c4c(-c5ccccc5)cccc4-c4ccccc4)Oc4c3c([2H])c([2H])c3c([2H])c([2H])c([2H])c([2H])c43)N(c3ccccc3-c3ccccc3)c3c([2H])c(-n4c5c([2H])c([2H])c([2H])c([2H])c5c5c([2H])c([2H])c([2H])c([2H])c54)c([2H])c([2H])c32)c([2H])c1[2H] ; CC(C)(C)c1cc2c3c(c1)N(c1c(-c4ccccc4)cccc1-c1ccccc1)c1cc4c5c(c1B3c1ccc3ccccc3c1O2)Sc1ccc(-c2ccccc2)cc1B5c1cc(-c2ccccc2)ccc1N4c1ccccc1-c1ccccc1]

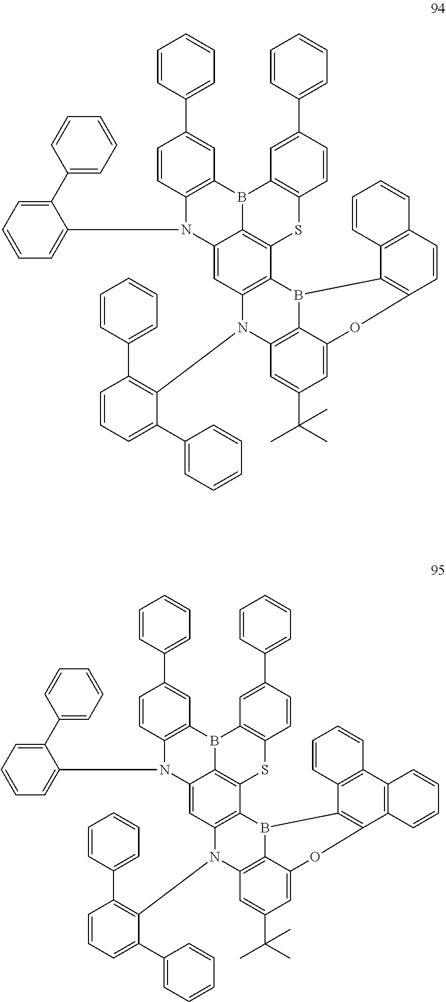 [SMILES: CC(C)(C)c1cc2c3c(c1)N(c1c(-c4ccccc4)cccc1-c1ccccc1)c1cc4c5c(c1B3c1c(ccc3ccccc13)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Sc1ccc(-c2ccccc2)cc1B5c1cc(-c2ccccc2)ccc1N4c1ccccc1-c1ccccc1]

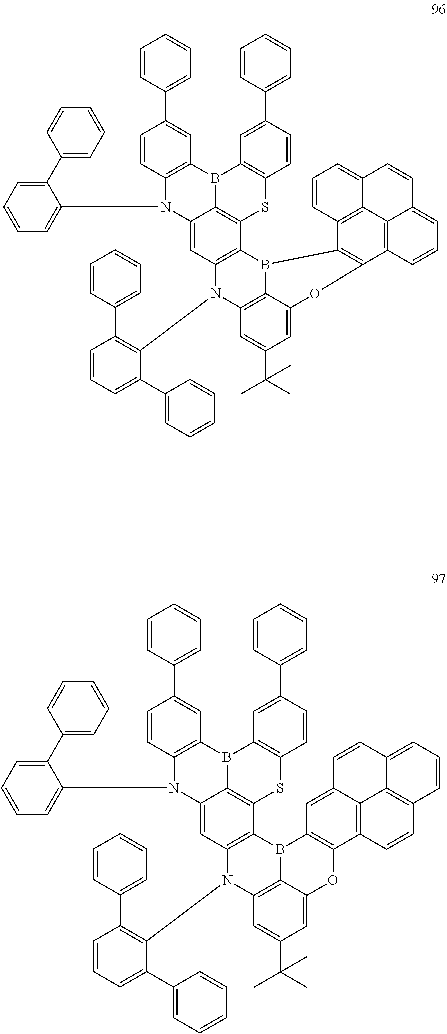 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1O2)c3c67)Sc1ccc(-c2ccccc2)cc1B5c1cc(-c2ccccc2)ccc1N4c1ccccc1-c1ccccc1]

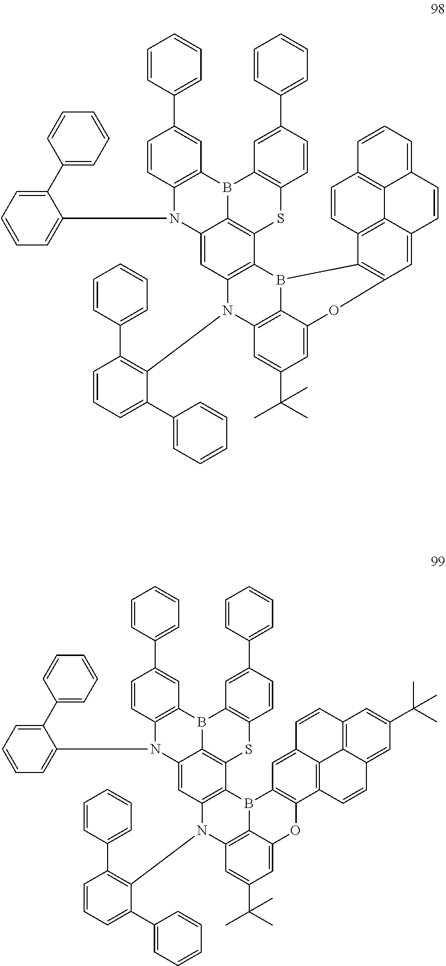 [SMILES: CC(C)(C)c1cc2c3c(c1)N(c1c(-c4ccccc4)cccc1-c1ccccc1)c1cc4c5c(c1B3c1c(cc3ccc6cccc7ccc1c3c67)O2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1O2)c3c67)Sc1ccc(-c2ccccc2)cc1B5c1cc(-c2ccccc2)ccc1N4c1ccccc1-c1ccccc1]

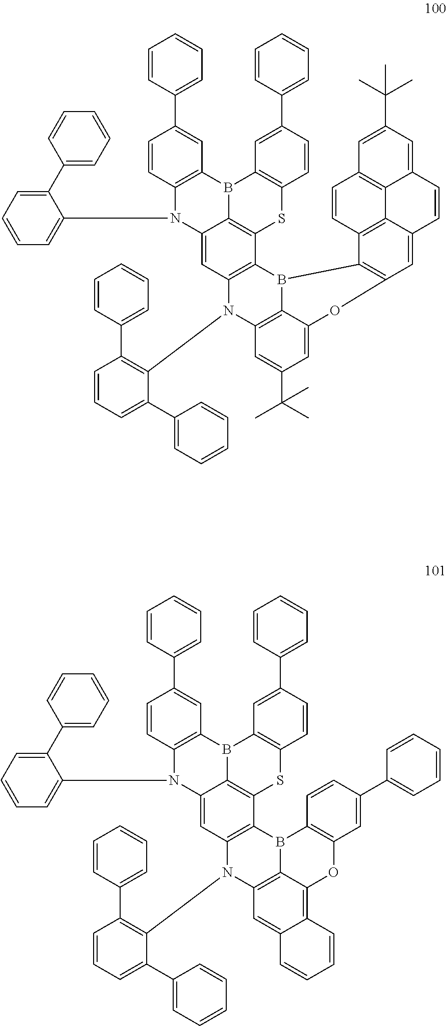 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Sc1ccc(-c2ccccc2)cc1B5c1cc(-c2ccccc2)ccc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Sc2ccc(-c3ccccc3)cc2B6c2cc(-c3ccccc3)ccc2N5c2ccccc2-c2ccccc2)cc1]

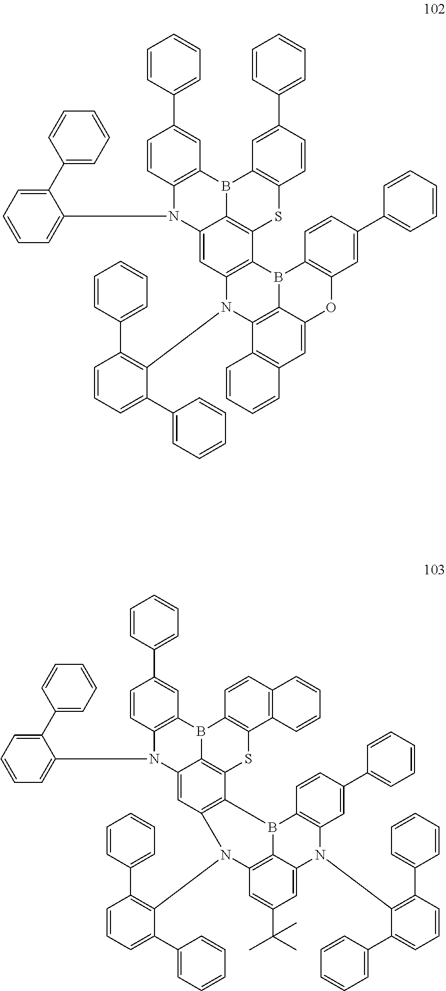 [SMILES: c1ccc(-c2ccc3c(c2)Oc2cc4ccccc4c4c2B3c2c(cc3c5c2Sc2ccc(-c6ccccc6)cc2B5c2cc(-c5ccccc5)ccc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1c(ccc2ccccc12)B5c1cc(-c2ccccc2)ccc1N4c1ccccc1-c1ccccc1]

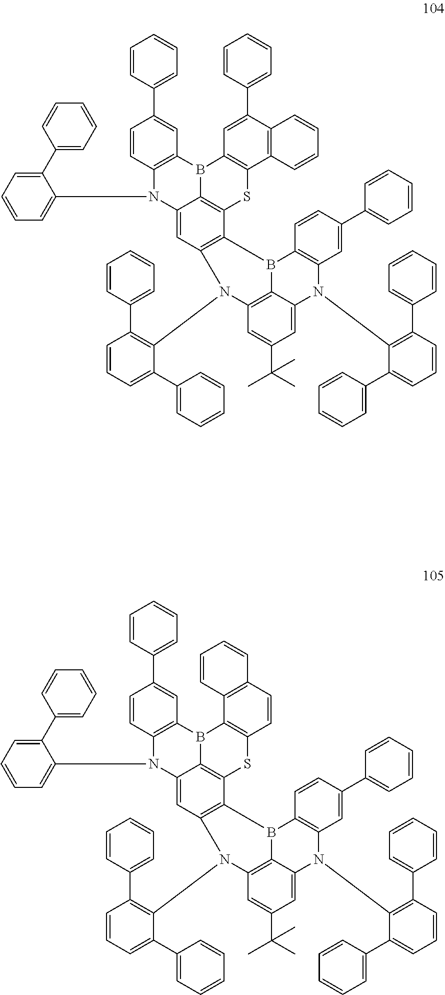 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1c(cc(-c2ccccc2)c2ccccc12)B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc2ccccc2c1B5c1cc(-c2ccccc2)ccc1N4c1ccccc1-c1ccccc1]

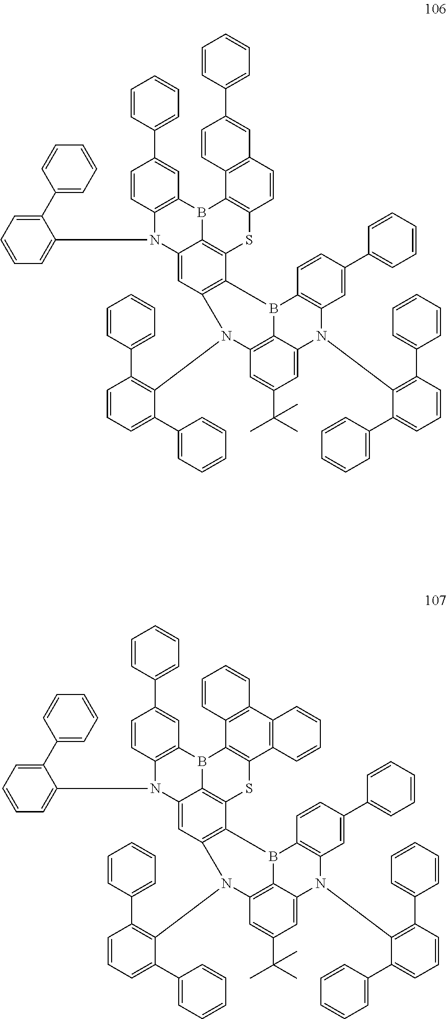 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc2cc(-c3ccccc3)ccc2c1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1c(c2ccccc2c2ccccc12)B5c1cc(-c2ccccc2)ccc1N4c1ccccc1-c1ccccc1]

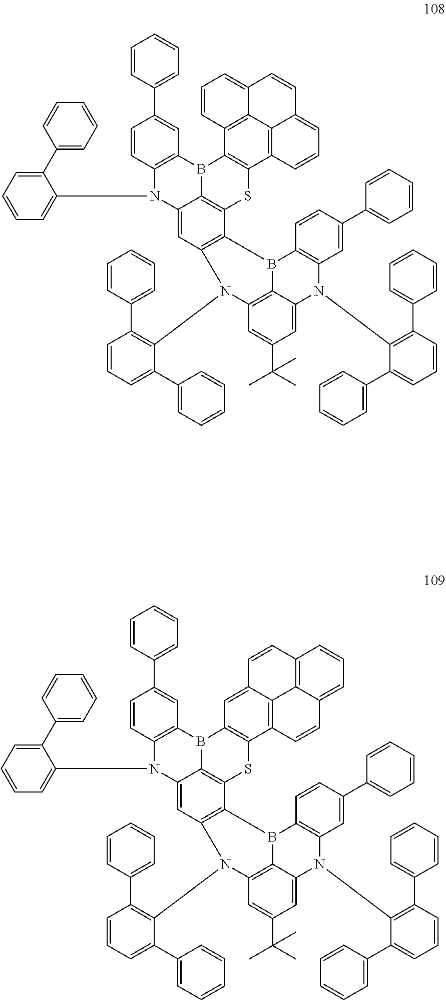 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1c(c2cccc3ccc6cccc1c6c32)B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1c(cc2ccc3cccc6ccc1c2c36)B5c1cc(-c2ccccc2)ccc1N4c1ccccc1-c1ccccc1]

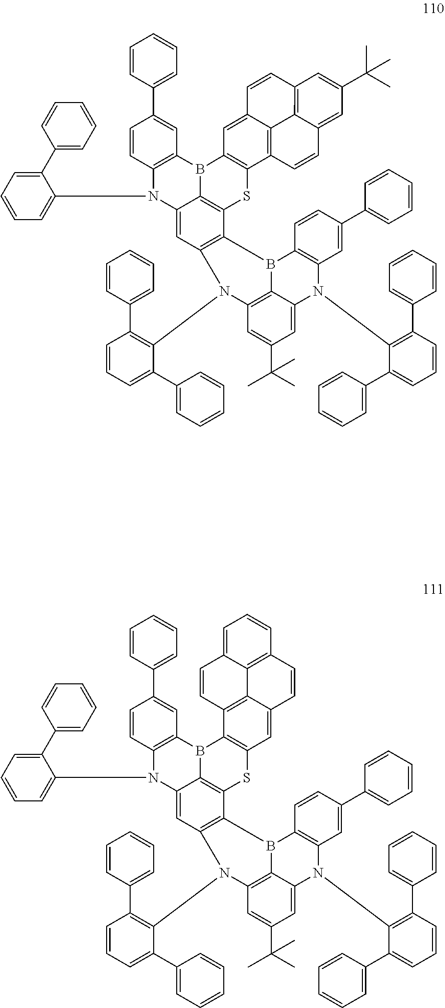 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1c(cc2ccc3cc(C(C)(C)C)cc6ccc1c2c36)B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1cc2ccc3cccc6ccc(c1B5c1cc(-c5ccccc5)ccc1N4c1ccccc1-c1ccccc1)c2c36]

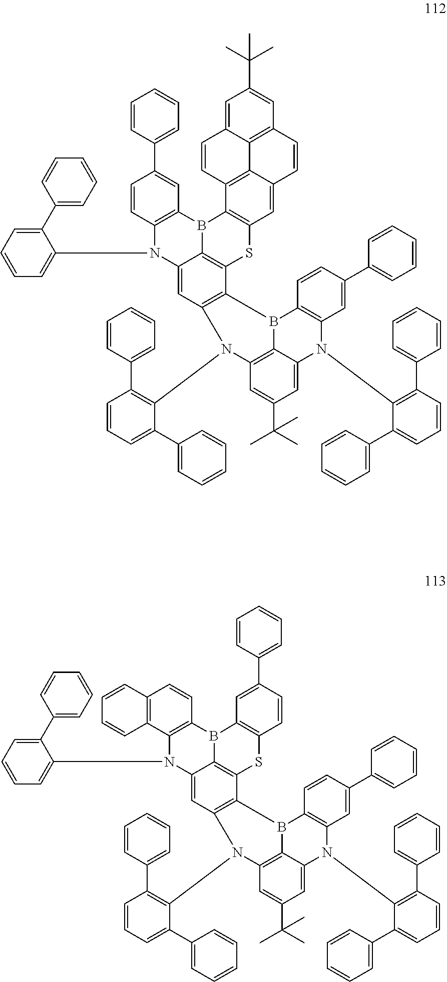 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1cc2ccc3cc(C(C)(C)C)cc6ccc(c1B5c1cc(-c5ccccc5)ccc1N4c1ccccc1-c1ccccc1)c2c36 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1ccc2ccccc2c1N4c1ccccc1-c1ccccc1]

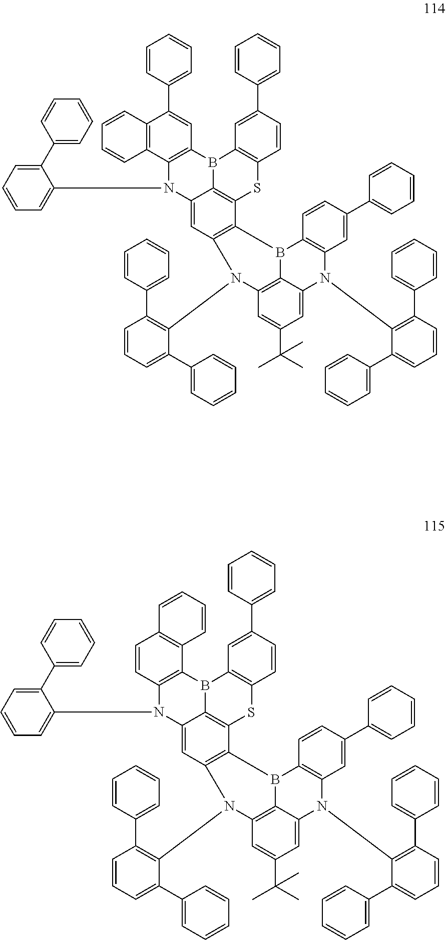 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1cc(-c2ccccc2)c2ccccc2c1N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1c(ccc2ccccc12)N4c1ccccc1-c1ccccc1]

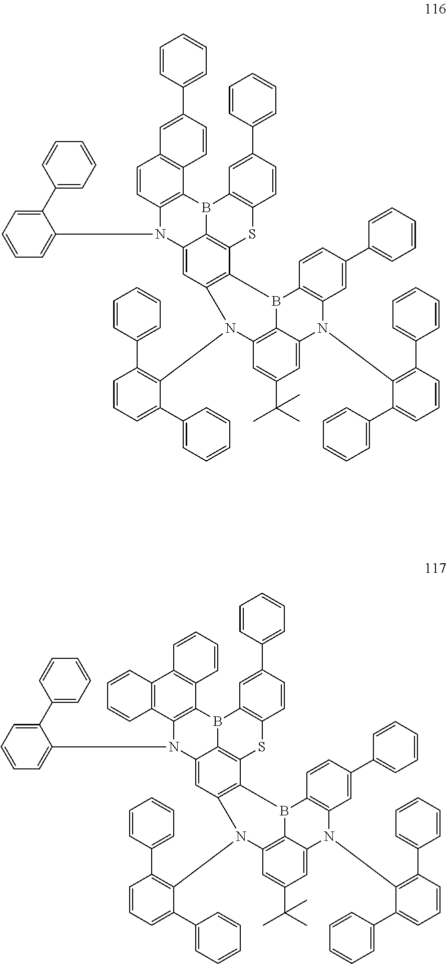 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1c(ccc2cc(-c3ccccc3)ccc12)N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1c(c2ccccc2c2ccccc12)N4c1ccccc1-c1ccccc1]

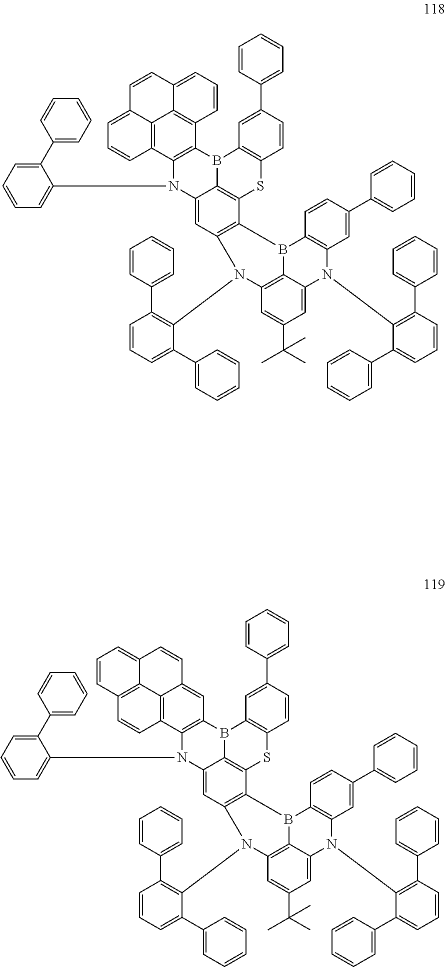 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1c(c2cccc3ccc5cccc1c5c32)N4c1ccccc1-c1ccccc1 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1cc2ccc3cccc5ccc(c1N4c1ccccc1-c1ccccc1)c2c35]

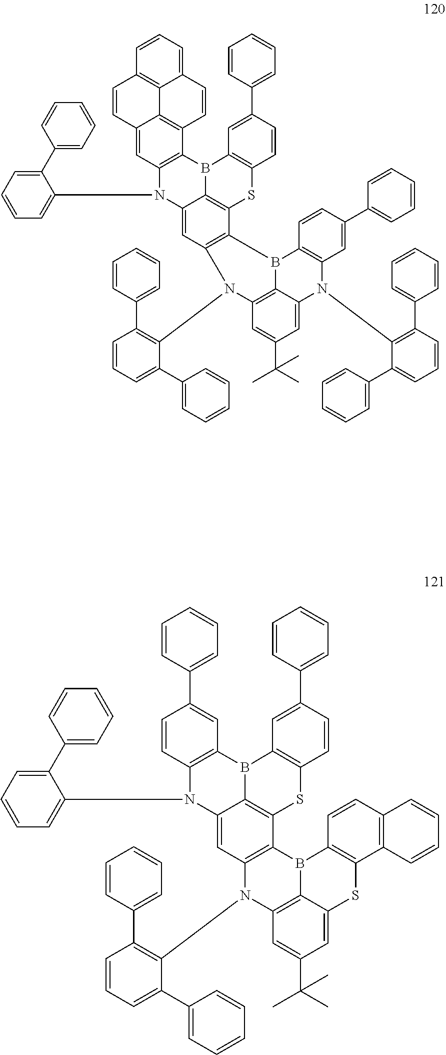 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Sc1ccc(-c2ccccc2)cc1B5c1c(cc2ccc3cccc5ccc1c2c35)N4c1ccccc1-c1ccccc1 ; CC(C)(C)c1cc2c3c(c1)N(c1c(-c4ccccc4)cccc1-c1ccccc1)c1cc4c5c(c1B3c1ccc3ccccc3c1S2)Sc1ccc(-c2ccccc2)cc1B5c1cc(-c2ccccc2)ccc1N4c1ccccc1-c1ccccc1]

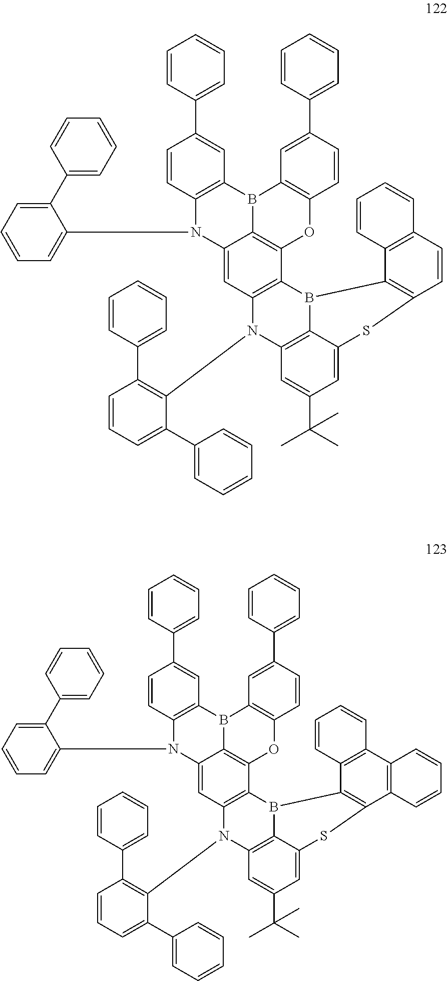 [SMILES: CC(C)(C)c1cc2c3c(c1)N(c1c(-c4ccccc4)cccc1-c1ccccc1)c1cc4c5c(c1B3c1c(ccc3ccccc13)S2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)S2)Oc1ccc(-c2ccccc2)cc1B5c1cc(-c2ccccc2)ccc1N4c1ccccc1-c1ccccc1]

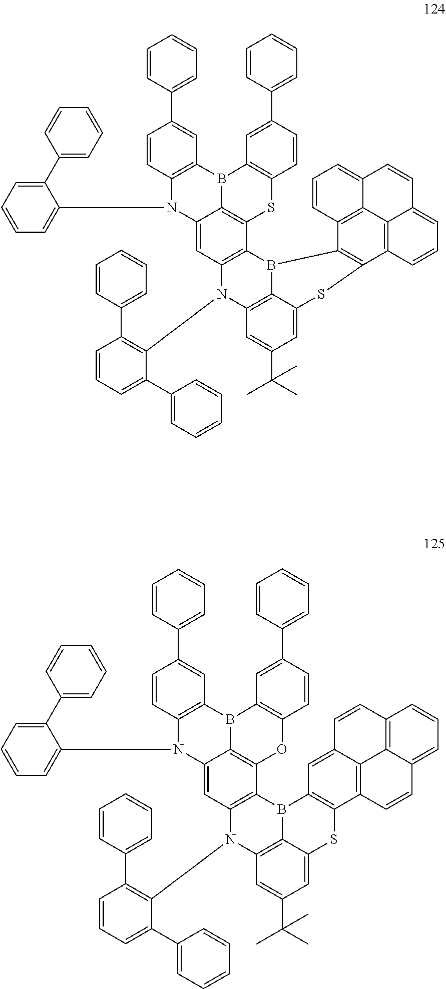 [SMILES: CC(C)(C)c1cc2c3c(c1)N(c1c(-c4ccccc4)cccc1-c1ccccc1)c1cc4c5c(c1B3c1c(c3cccc6ccc7cccc1c7c63)S2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cccc7ccc(c1S2)c3c67)Oc1ccc(-c2ccccc2)cc1B5c1cc(-c2ccccc2)ccc1N4c1ccccc1-c1ccccc1]

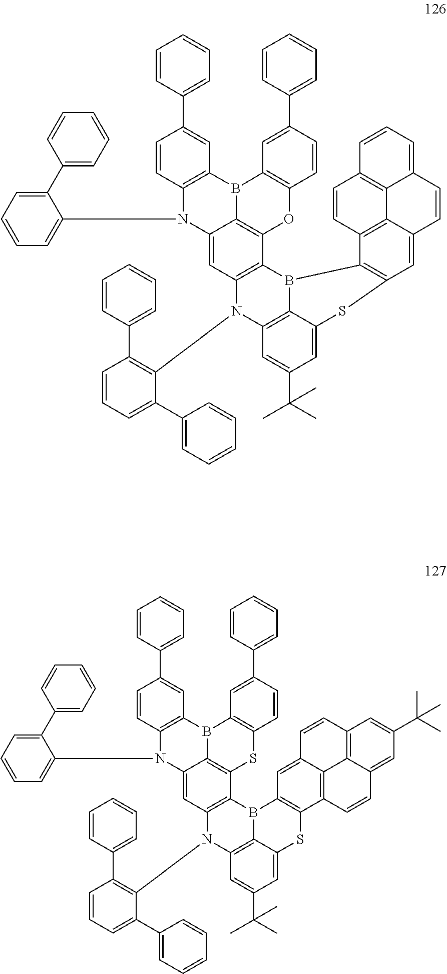 [SMILES: CC(C)(C)c1cc2c3c(c1)N(c1c(-c4ccccc4)cccc1-c1ccccc1)c1cc4c5c(c1B3c1c(cc3ccc6cccc7ccc1c3c67)S2)Oc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1S2)c3c67)Sc1ccc(-c2ccccc2)cc1B5c1cc(-c2ccccc2)ccc1N4c1ccccc1-c1ccccc1]

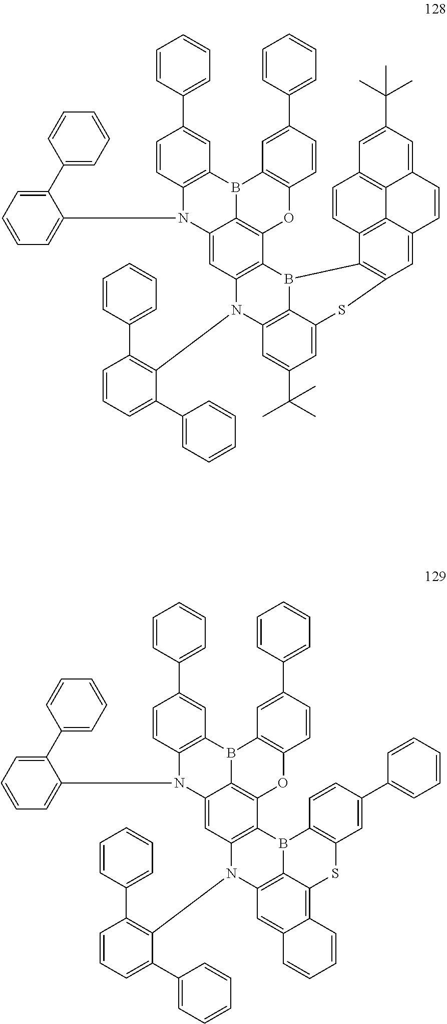 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)S2)Oc1ccc(-c2ccccc2)cc1B5c1cc(-c2ccccc2)ccc1N4c1ccccc1-c1ccccc1 ; c1ccc(-c2ccc3c(c2)Sc2c4c(cc5ccccc25)N(c2c(-c5ccccc5)cccc2-c2ccccc2)c2cc5c6c(c2B34)Oc2ccc(-c3ccccc3)cc2B6c2cc(-c3ccccc3)ccc2N5c2ccccc2-c2ccccc2)cc1]

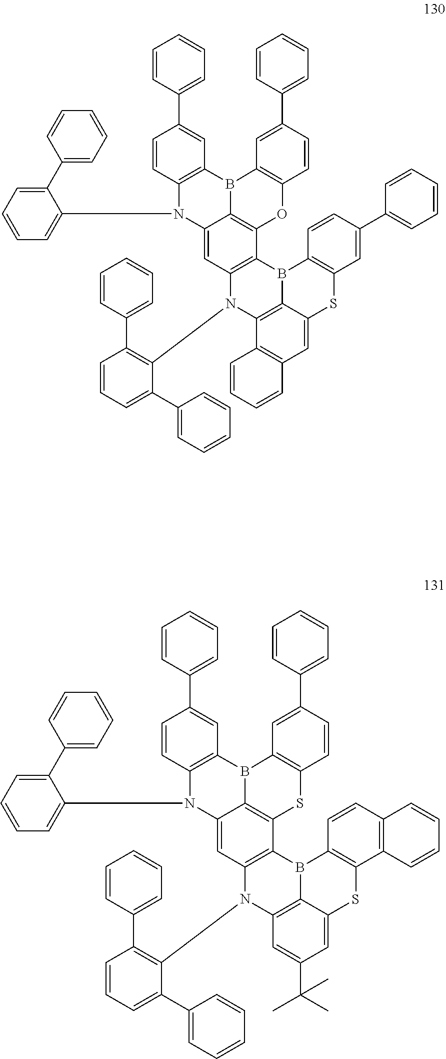 [SMILES: c1ccc(-c2ccc3c(c2)Sc2cc4ccccc4c4c2B3c2c(cc3c5c2Oc2ccc(-c6ccccc6)cc2B5c2cc(-c5ccccc5)ccc2N3c2ccccc2-c2ccccc2)N4c2c(-c3ccccc3)cccc2-c2ccccc2)cc1 ; CC(C)(C)c1cc2c3c(c1)N(c1c(-c4ccccc4)cccc1-c1ccccc1)c1cc4c5c(c1B3c1ccc3ccccc3c1S2)Sc1ccc(-c2ccccc2)cc1B5c1cc(-c2ccccc2)ccc1N4c1ccccc1-c1ccccc1]

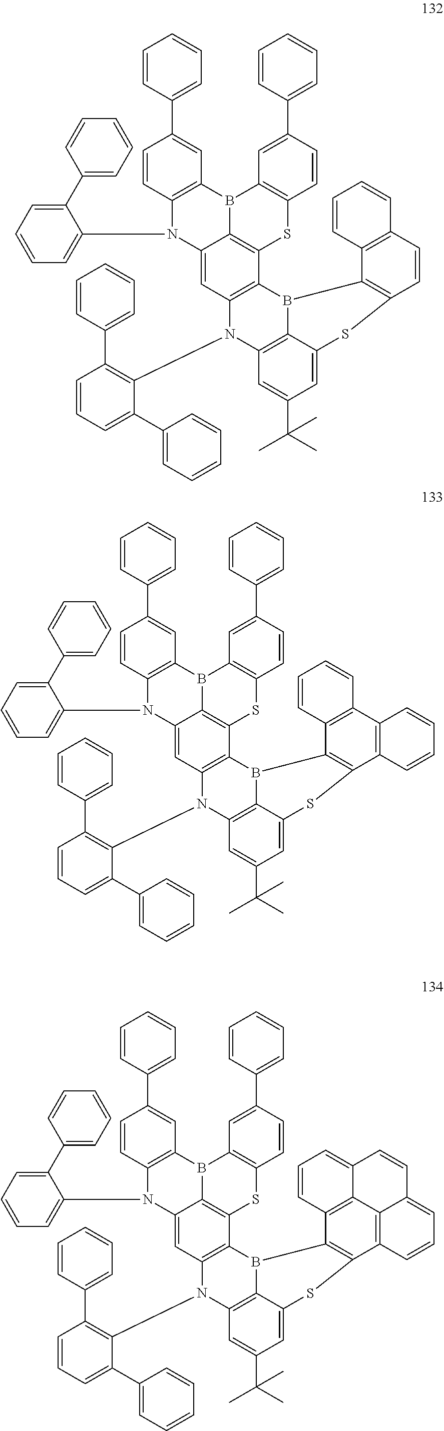 [SMILES: CC(C)(C)c1cc2c3c(c1)N(c1c(-c4ccccc4)cccc1-c1ccccc1)c1cc4c5c(c1B3c1c(ccc3ccccc13)S2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)S2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)S2)Sc1ccc(-c2ccccc2)cc1B5c1cc(-c2ccccc2)ccc1N4c1ccccc1-c1ccccc1]

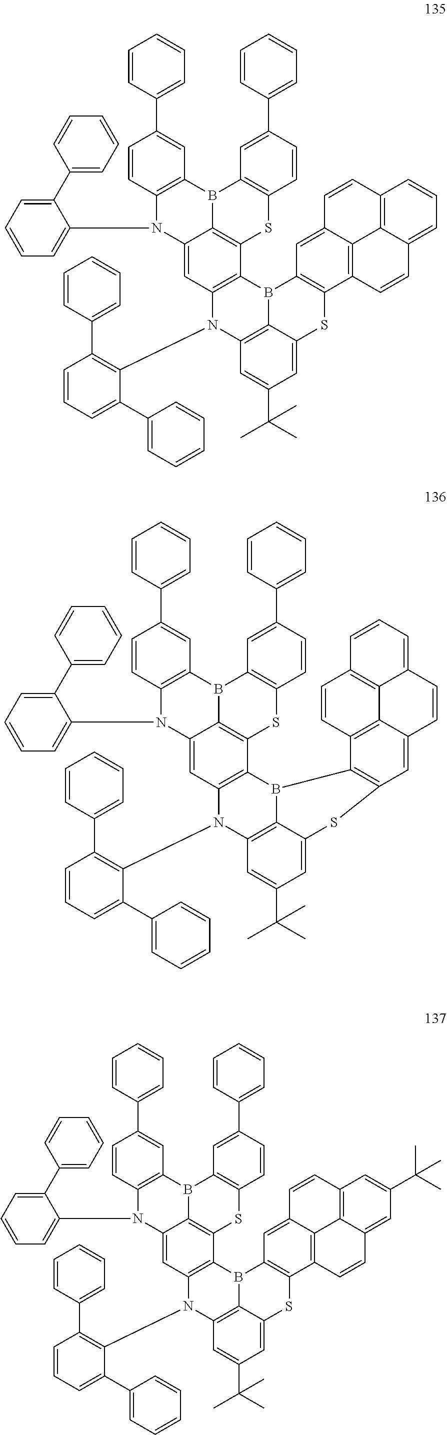 [SMILES: CC(C)(C)c1cc2c3c(c1)N(c1c(-c4ccccc4)cccc1-c1ccccc1)c1cc4c5c(c1B3c1cc3ccc6cccc7ccc(c1S2)c3c67)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(cc3ccc6cccc7ccc1c3c67)S2)Sc1ccc(-c2ccccc2)cc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1cc3ccc6cc(C(C)(C)C)cc7ccc(c1S2)c3c67)Sc1ccc(-c2ccccc2)cc1B5c1cc(-c2ccccc2)ccc1N4c1ccccc1-c1ccccc1]

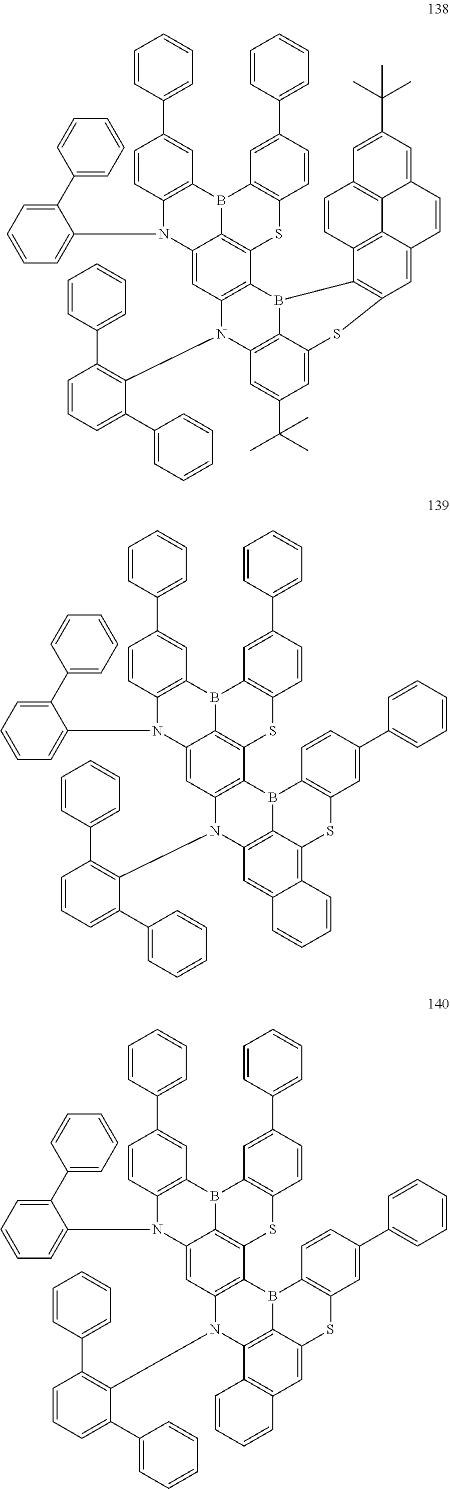 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)S2)Sc1ccc(-c2ccccc2)cc1B5c1cc(-c2ccccc2)ccc1N4c1ccccc1-c1ccccc1 ; c1ccc(-c2ccc3c(c2)Sc2c4c(cc5ccccc25)N(c2c(-c5ccccc5)cccc2-c2ccccc2)c2cc5c6c(c2B34)Sc2ccc(-c3ccccc3)cc2B6c2cc(-c3ccccc3)ccc2N5c2ccccc2-c2ccccc2)cc1 ; c1ccc(-c2ccc3c(c2)Sc2cc4ccccc4c4c2B3c2c(cc3c5c2Sc2ccc(-c6ccccc6)cc2B5c2cc(-c5ccccc5)ccc2N3c2ccccc2-c2ccccc2)N4c2c(-c3ccccc3)cccc2-c2ccccc2)cc1]

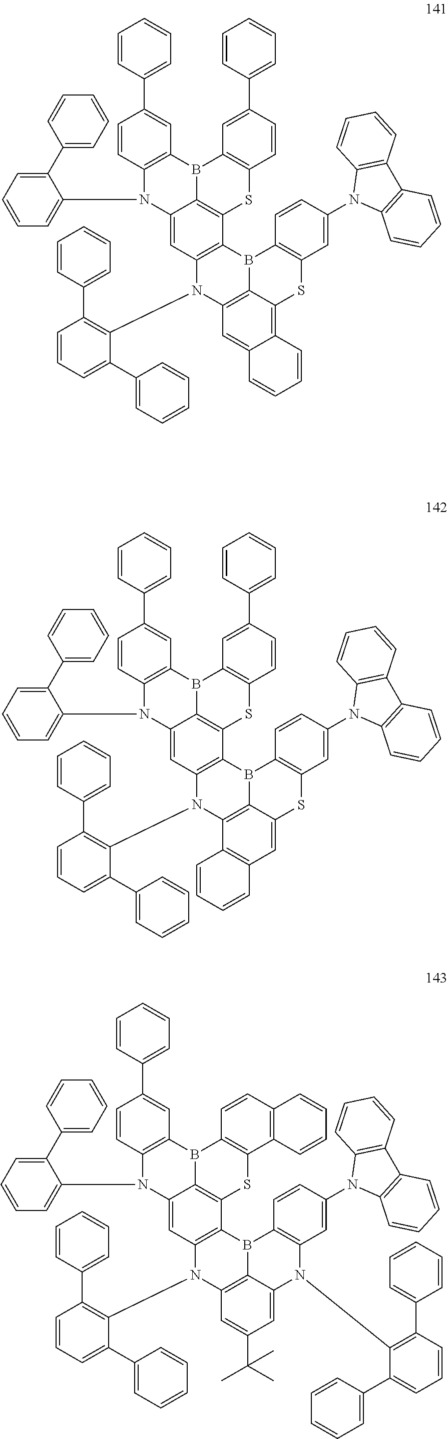

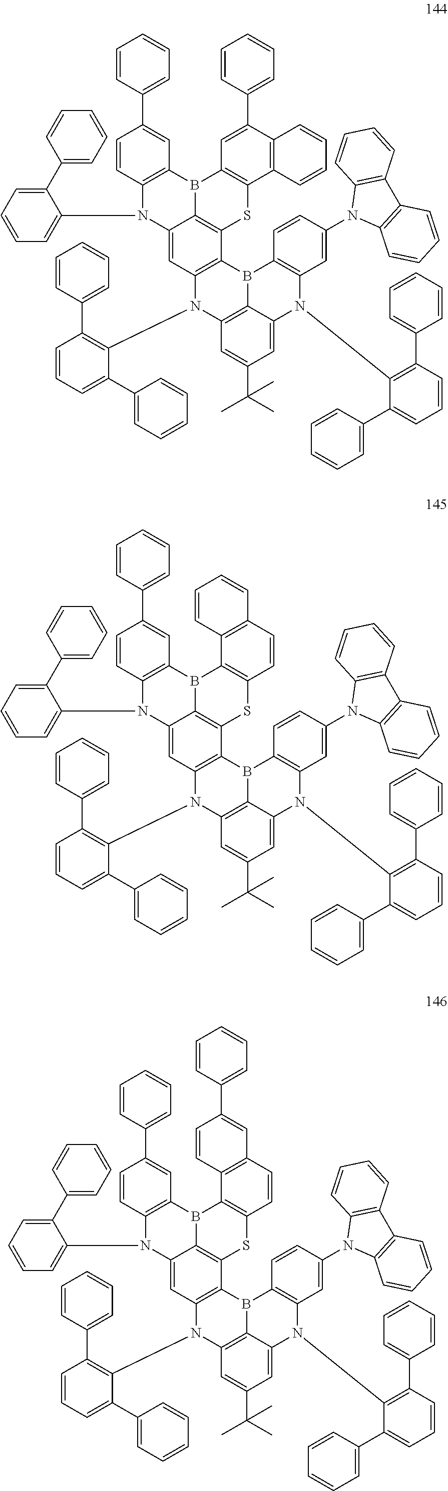

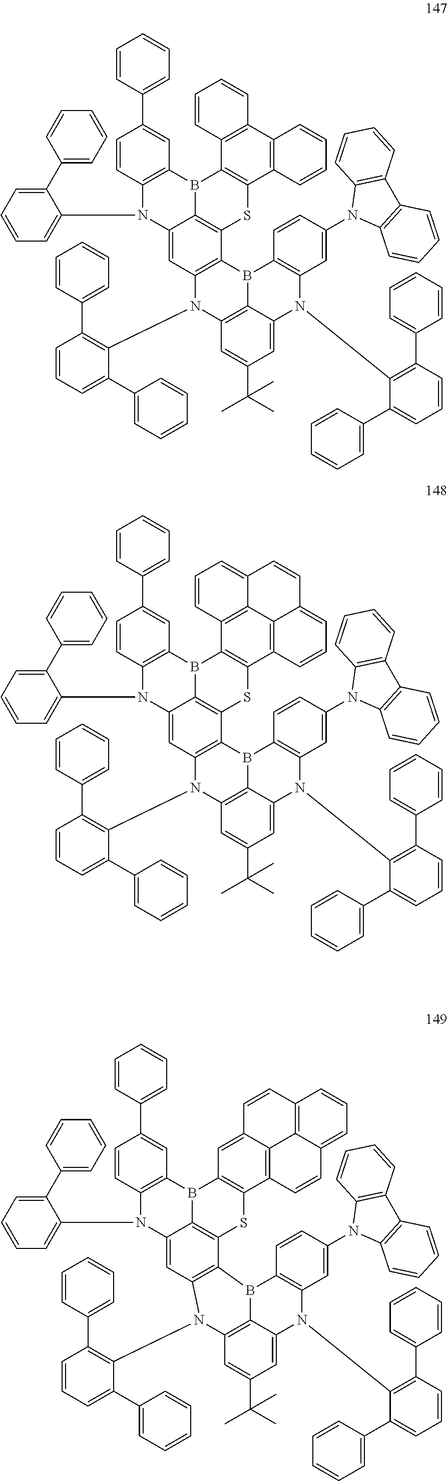

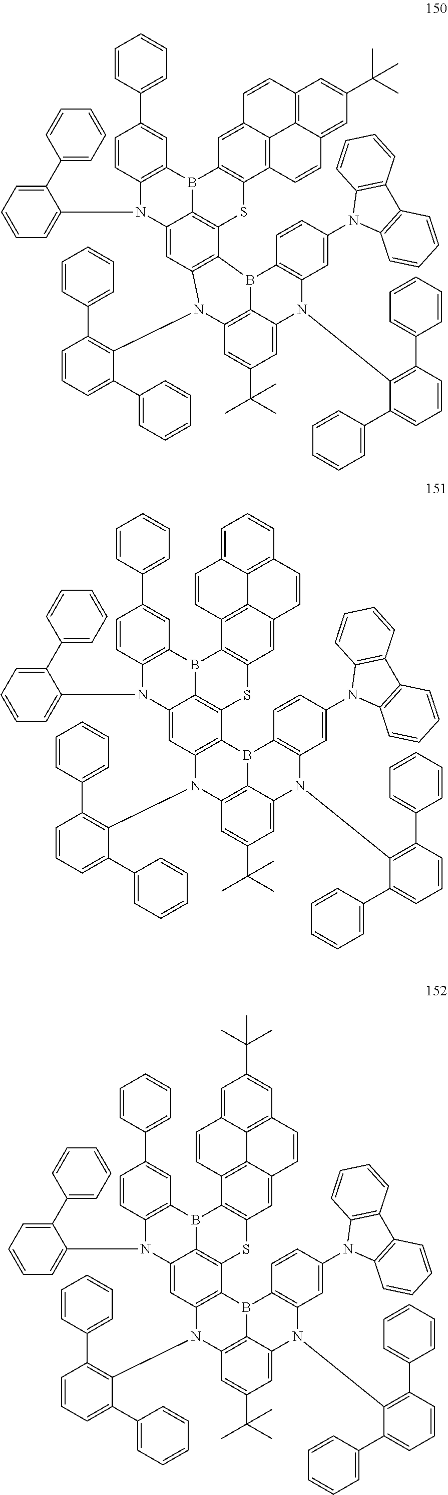

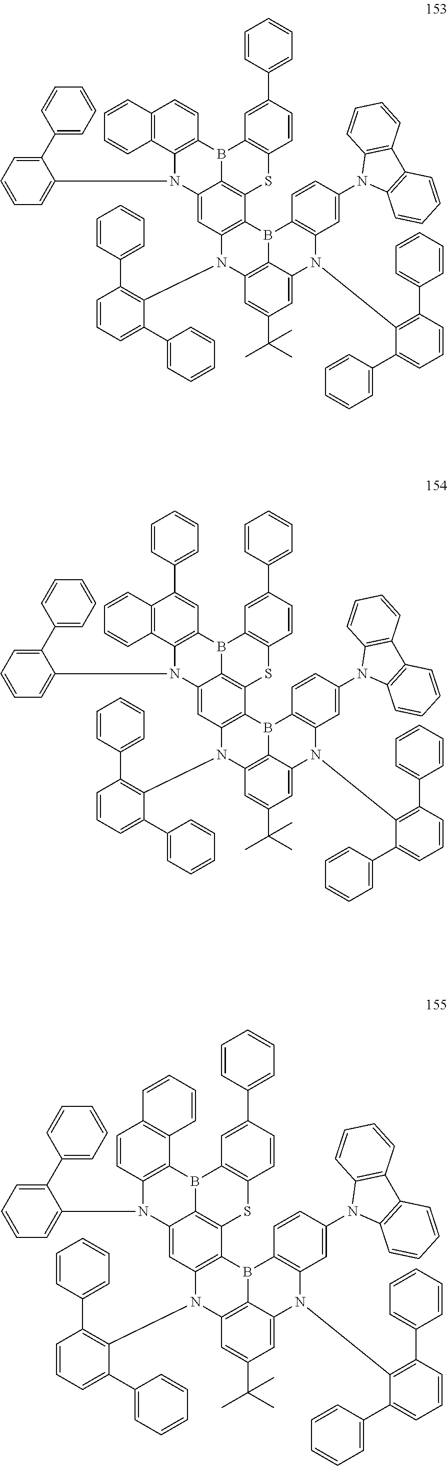

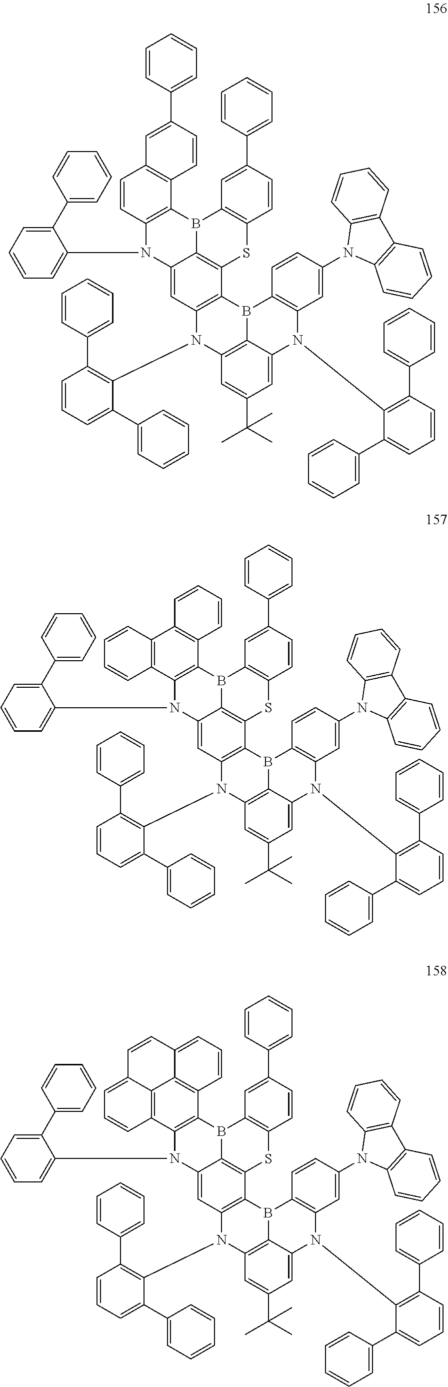

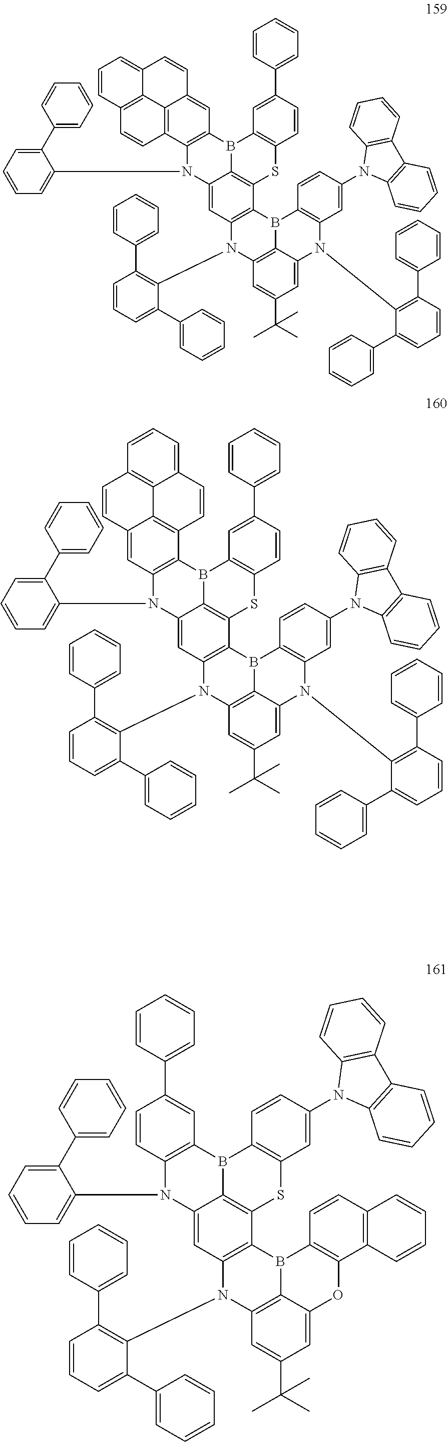

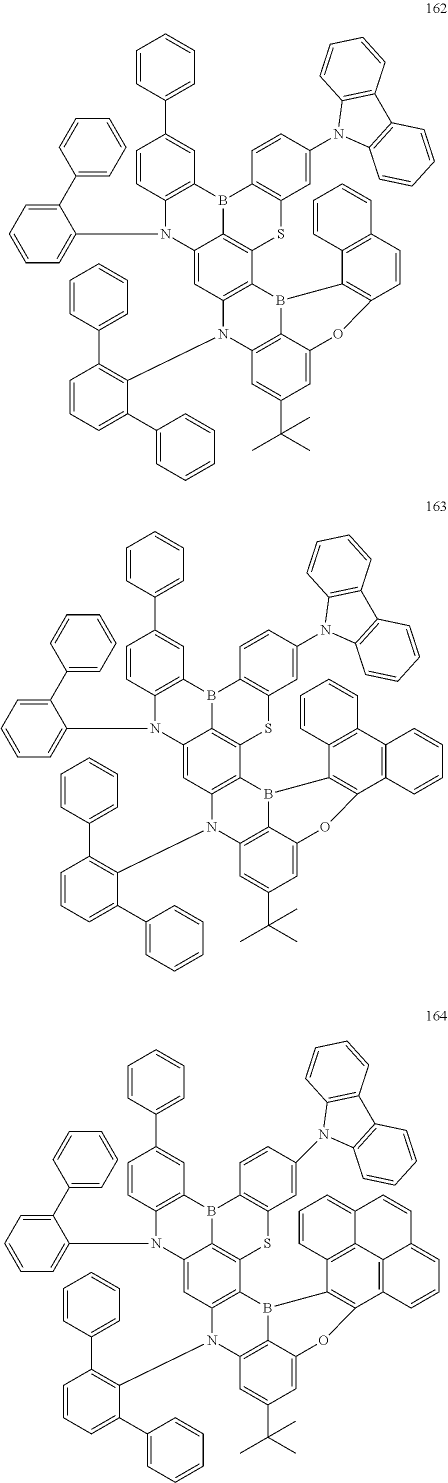 [SMILES: CC(C)(C)c1cc2c3c(c1)N(c1c(-c4ccccc4)cccc1-c1ccccc1)c1cc4c5c(c1B3c1c(ccc3ccccc13)O2)Sc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Sc1cc(-n2c3ccccc3c3ccccc32)ccc1B5c1cc(-c2ccccc2)ccc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)O2)Sc1cc(-n2c3ccccc3c3ccccc32)ccc1B5c1cc(-c2ccccc2)ccc1N4c1ccccc1-c1ccccc1]

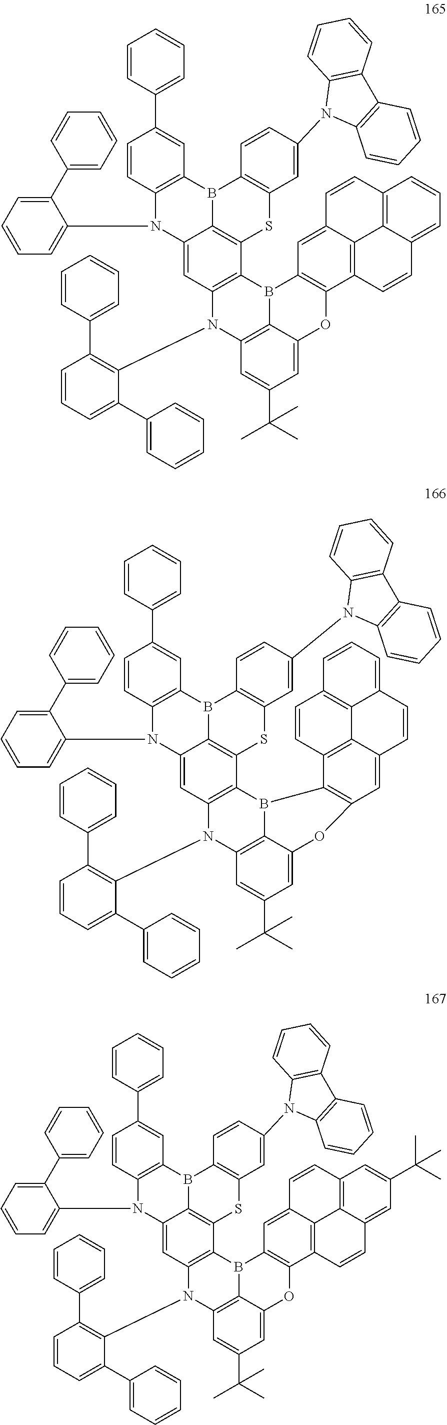

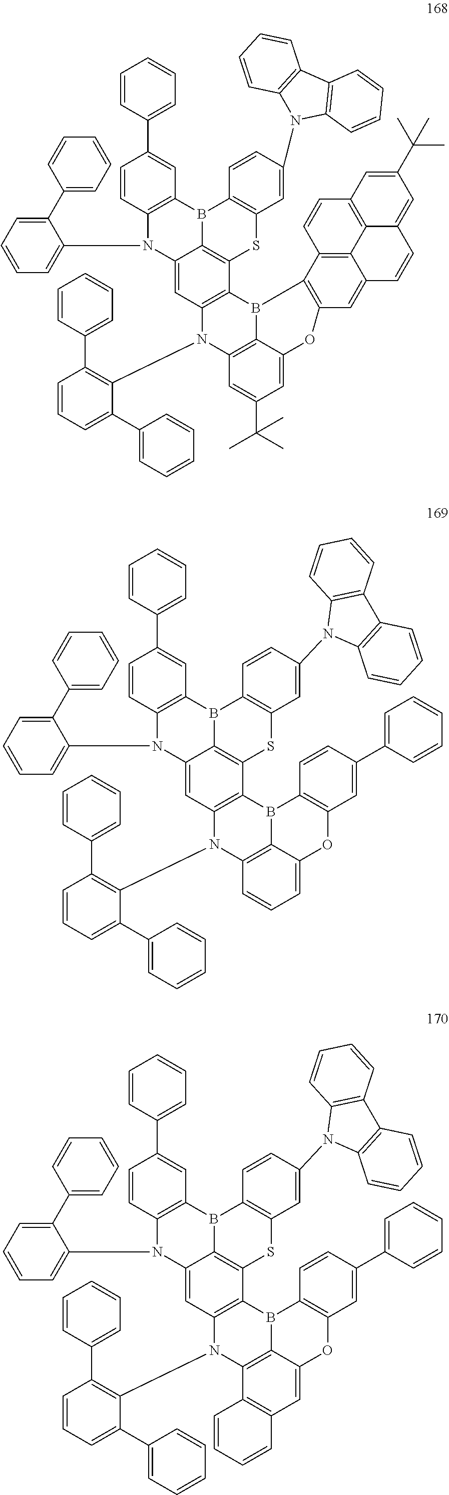 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Sc1cc(-n2c3ccccc3c3ccccc32)ccc1B5c1cc(-c2ccccc2)ccc1N4c1ccccc1-c1ccccc1 ; c1ccc(-c2ccc3c(c2)Oc2cccc4c2B3c2c(cc3c5c2Sc2cc(-n6c7ccccc7c7ccccc76)ccc2B5c2cc(-c5ccccc5)ccc2N3c2ccccc2-c2ccccc2)N4c2c(-c3ccccc3)cccc2-c2ccccc2)cc1 ; c1ccc(-c2ccc3c(c2)Oc2cc4ccccc4c4c2B3c2c(cc3c5c2Sc2cc(-n6c7ccccc7c7ccccc76)ccc2B5c2cc(-c5ccccc5)ccc2N3c2ccccc2-c2ccccc2)N4c2c(-c3ccccc3)cccc2-c2ccccc2)cc1]

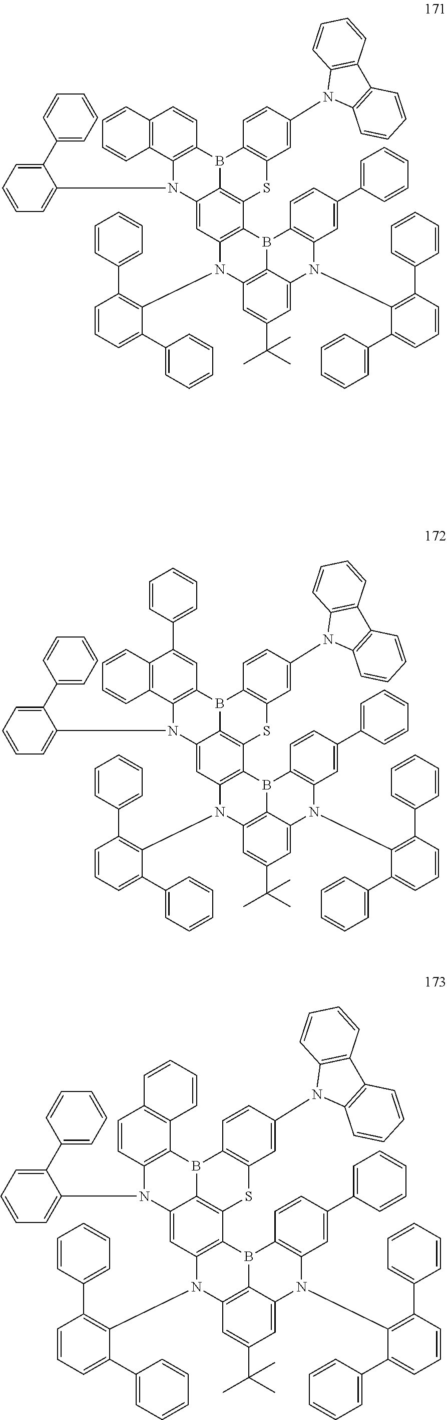

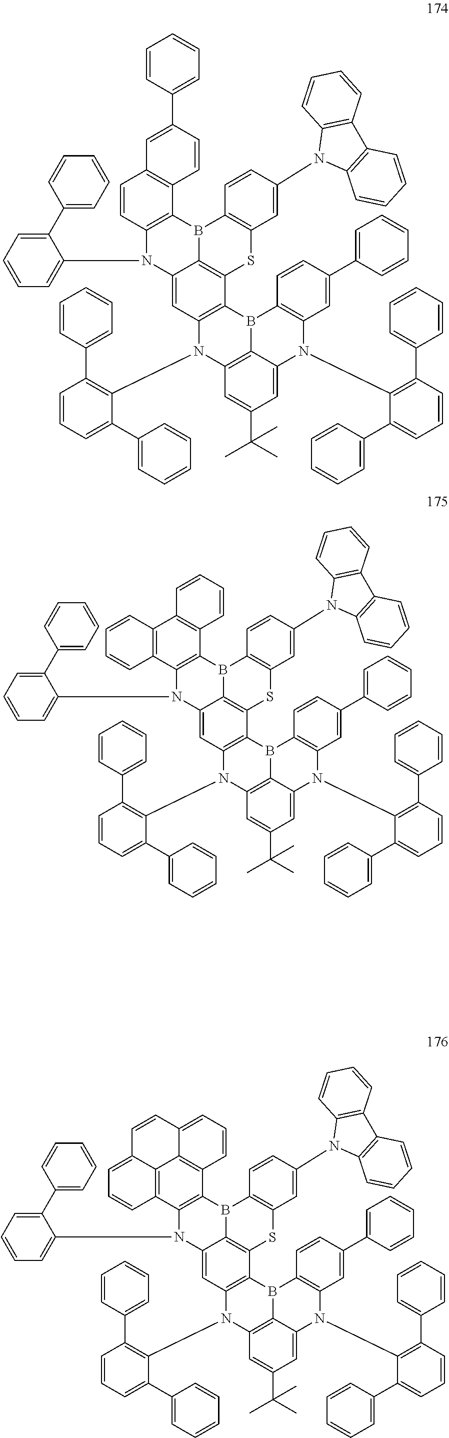

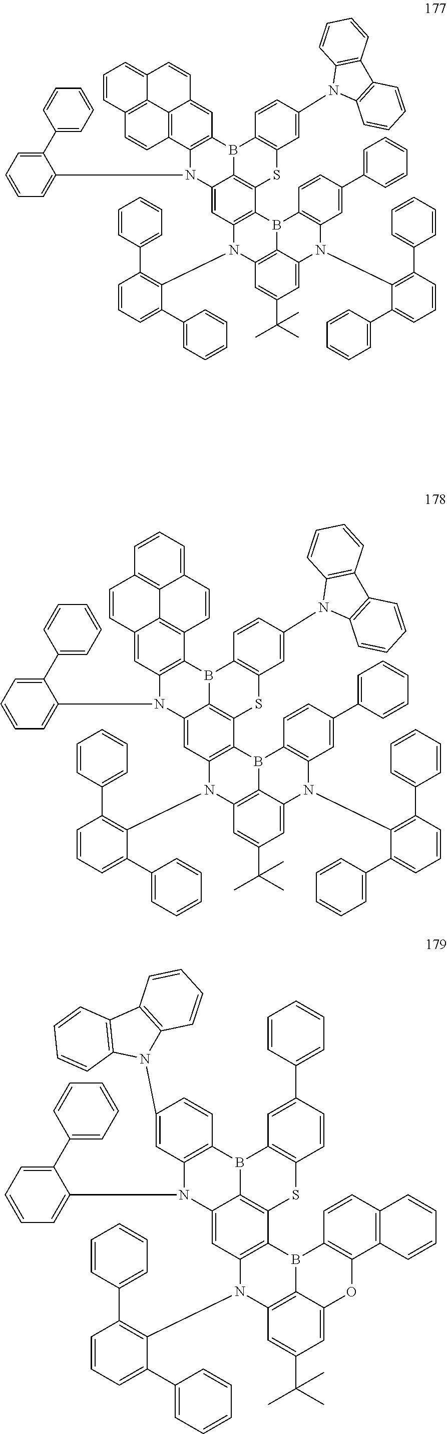

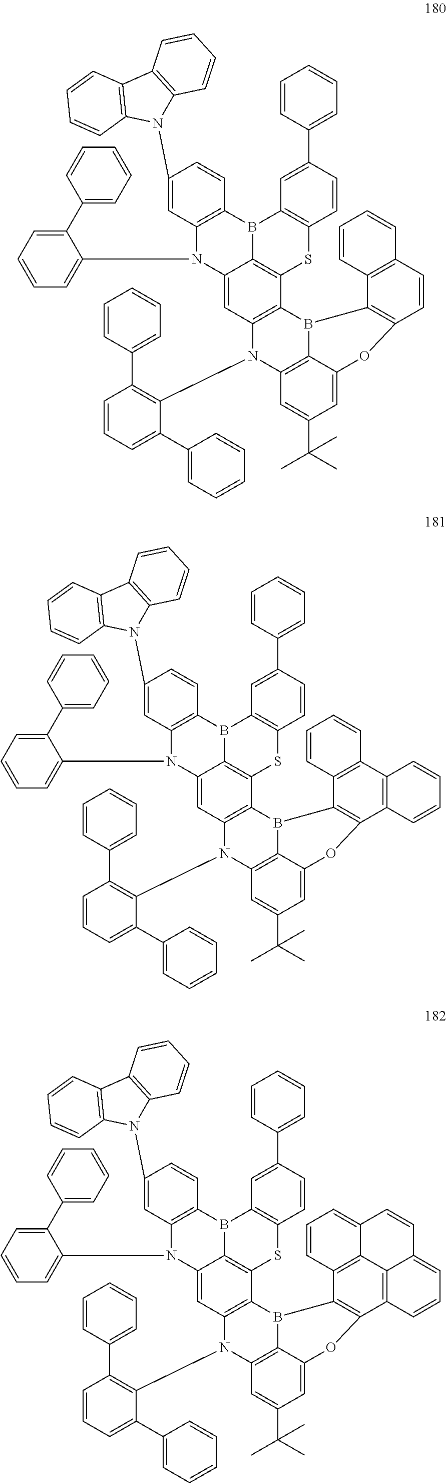 [SMILES: CC(C)(C)c1cc2c3c(c1)N(c1c(-c4ccccc4)cccc1-c1ccccc1)c1cc4c5c(c1B3c1c(ccc3ccccc13)O2)Sc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3ccccc3c3ccccc13)O2)Sc1ccc(-c2ccccc2)cc1B5c1ccc(-n2c3ccccc3c3ccccc32)cc1N4c1ccccc1-c1ccccc1 ; CC(C)(C)c1cc2c3c(c1)N(c1c(-c4ccccc4)cccc1-c1ccccc1)c1cc4c5c(c1B3c1c(c3cccc6ccc7cccc1c7c63)O2)Sc1ccc(-c2ccccc2)cc1B5c1ccc(-n2c3ccccc3c3ccccc32)cc1N4c1ccccc1-c1ccccc1]

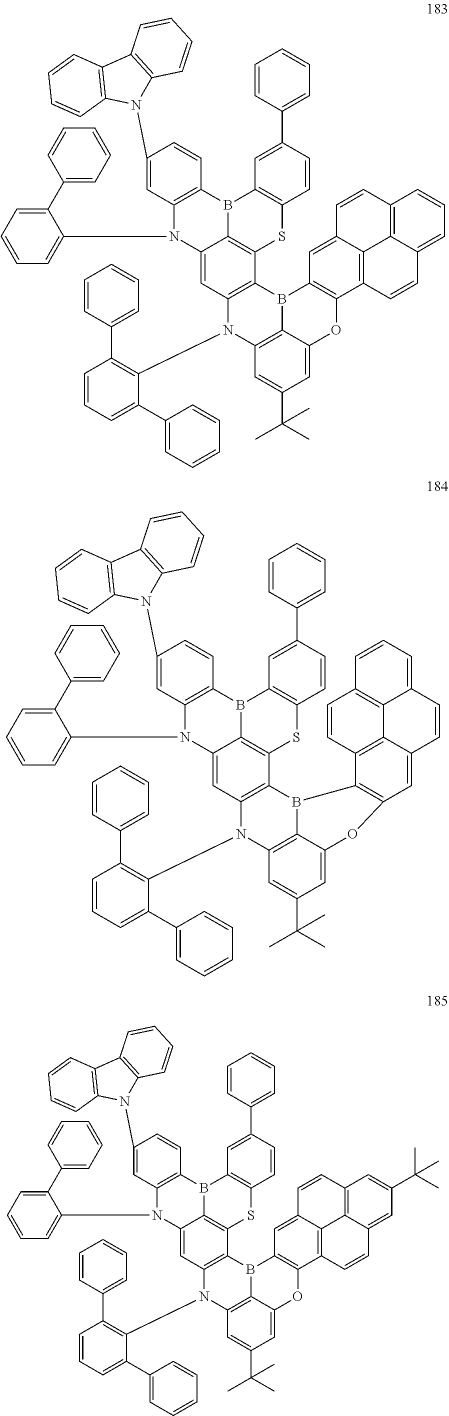

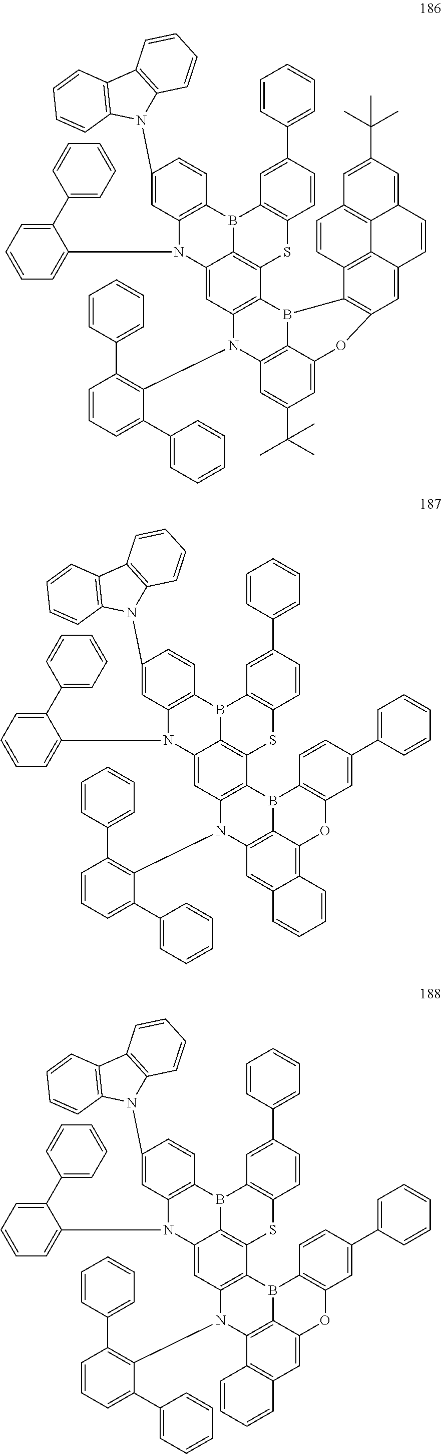 [SMILES: CC(C)(C)c1cc2c3c(c1)N(c1c(-c4ccccc4)cccc1-c1ccccc1)c1cc4c5c(c1B3c1c(cc3ccc6cc(C(C)(C)C)cc7ccc1c3c67)O2)Sc1ccc(-c2ccccc2)cc1B5c1ccc(-n2c3ccccc3c3ccccc32)cc1N4c1ccccc1-c1ccccc1 ; c1ccc(-c2ccc3c(c2)Oc2c4c(cc5ccccc25)N(c2c(-c5ccccc5)cccc2-c2ccccc2)c2cc5c6c(c2B34)Sc2ccc(-c3ccccc3)cc2B6c2ccc(-n3c4ccccc4c4ccccc43)cc2N5c2ccccc2-c2ccccc2)cc1 ; c1ccc(-c2ccc3c(c2)Oc2cc4ccccc4c4c2B3c2c(cc3c5c2Sc2ccc(-c6ccccc6)cc2B5c2ccc(-n5c6ccccc6c6ccccc65)cc2N3c2ccccc2-c2ccccc2)N4c2c(-c3ccccc3)cccc2-c2ccccc2)cc1]

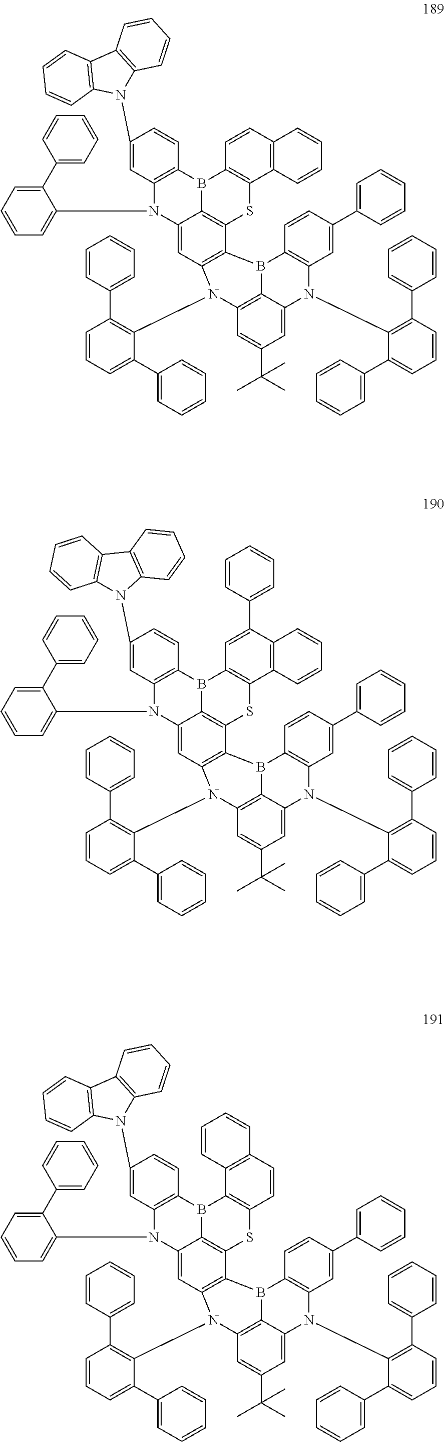

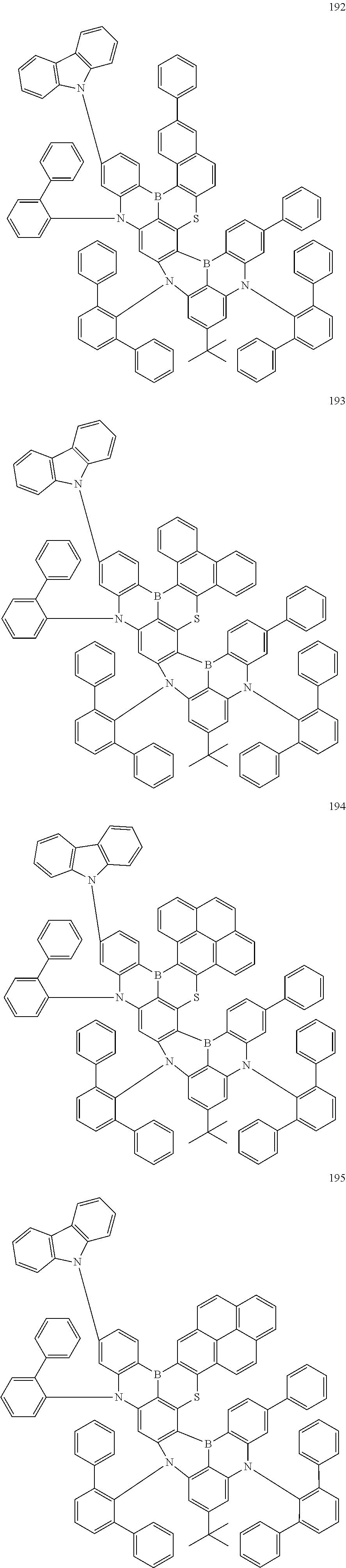

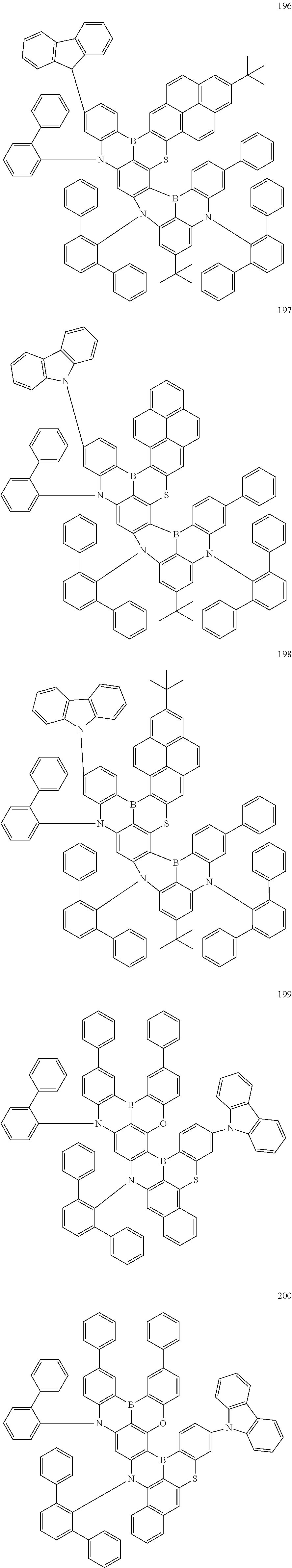

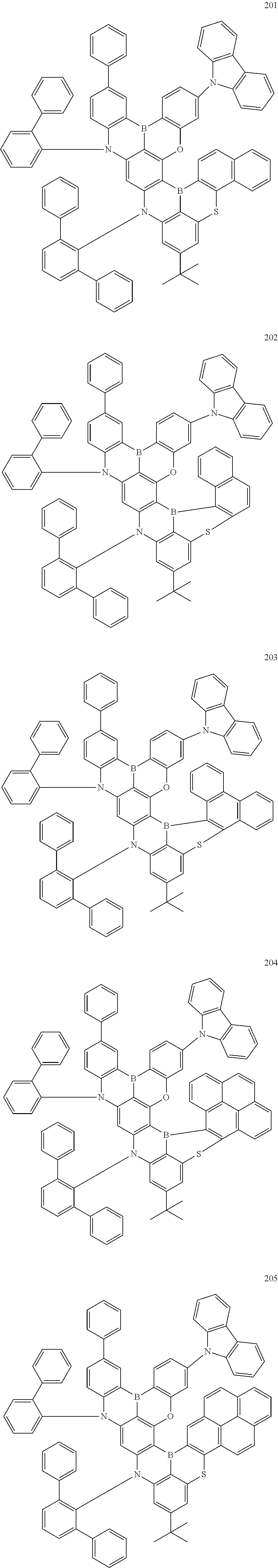

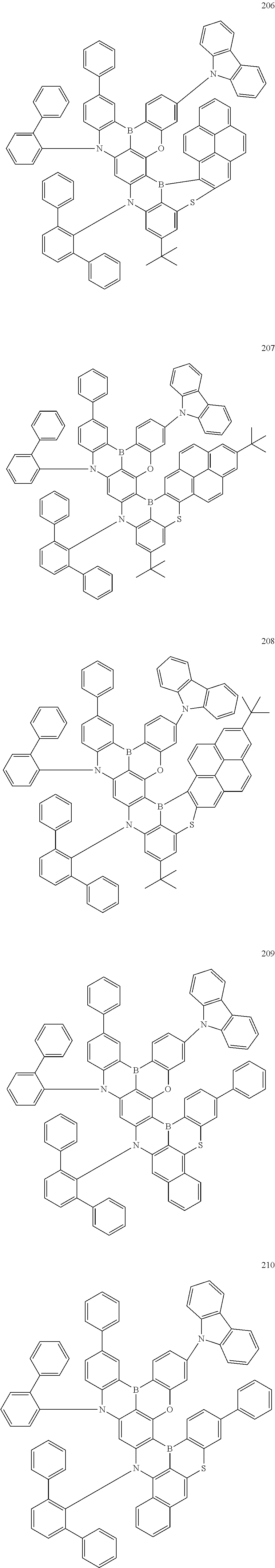

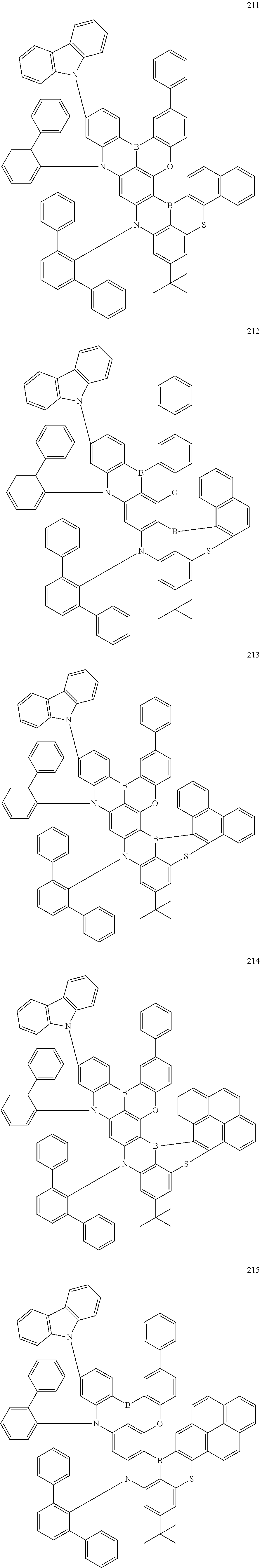

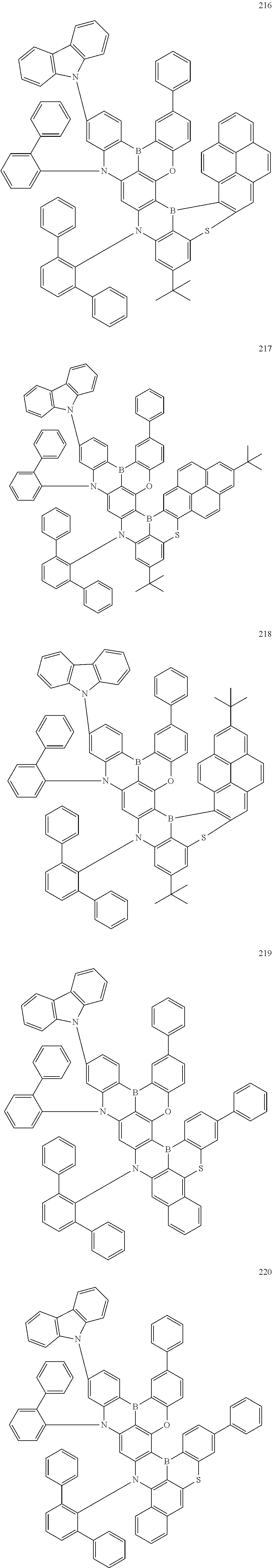

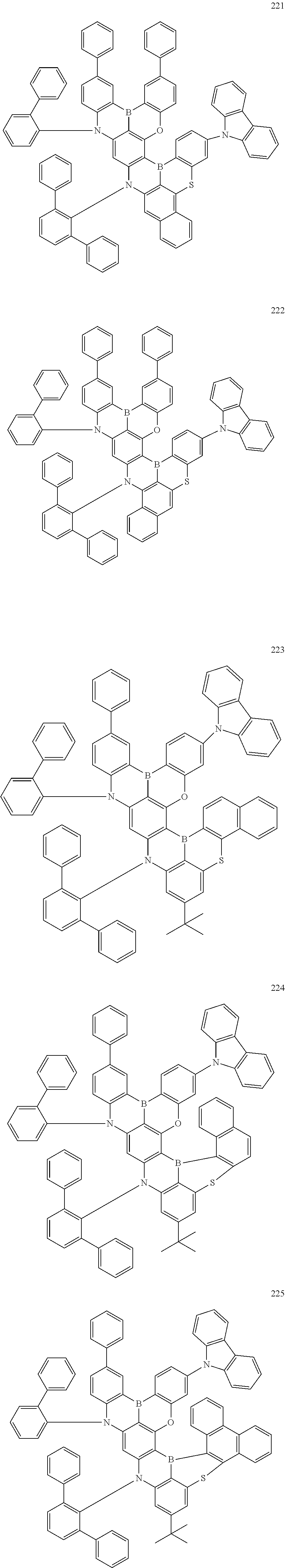

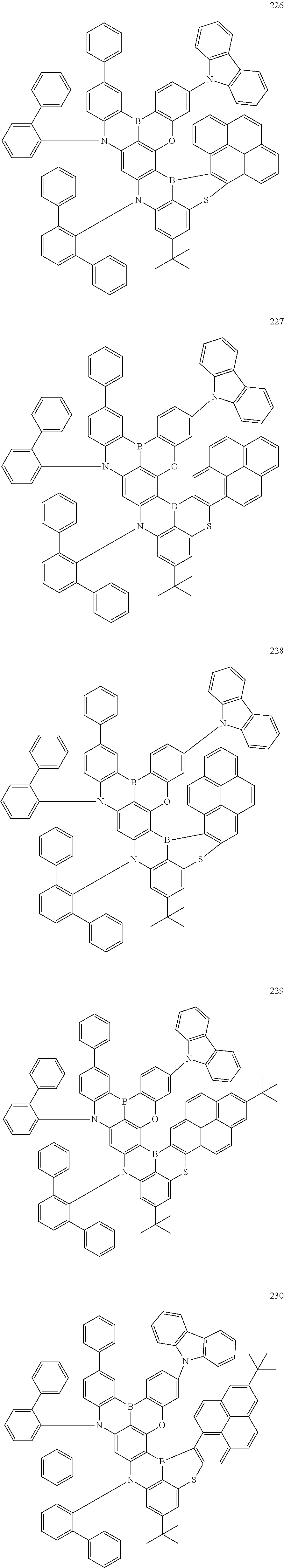

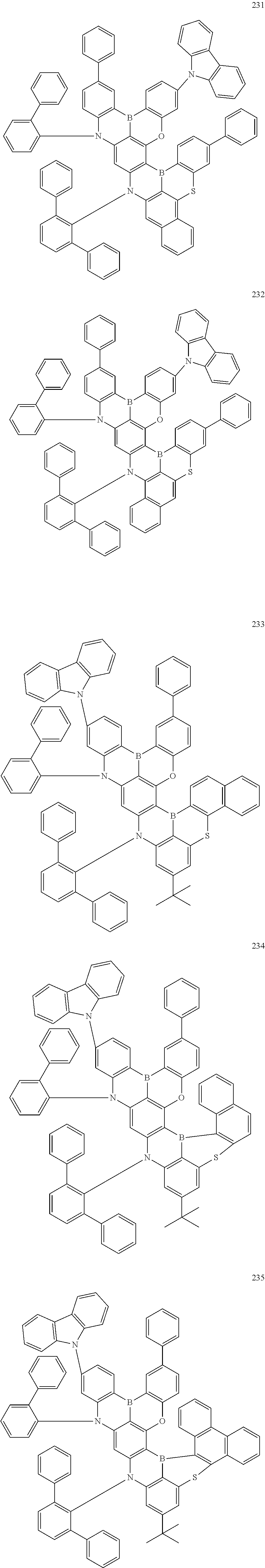

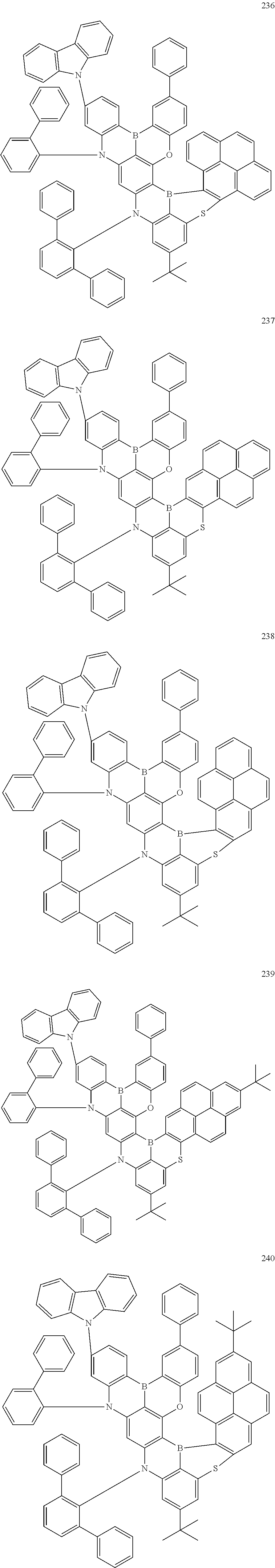

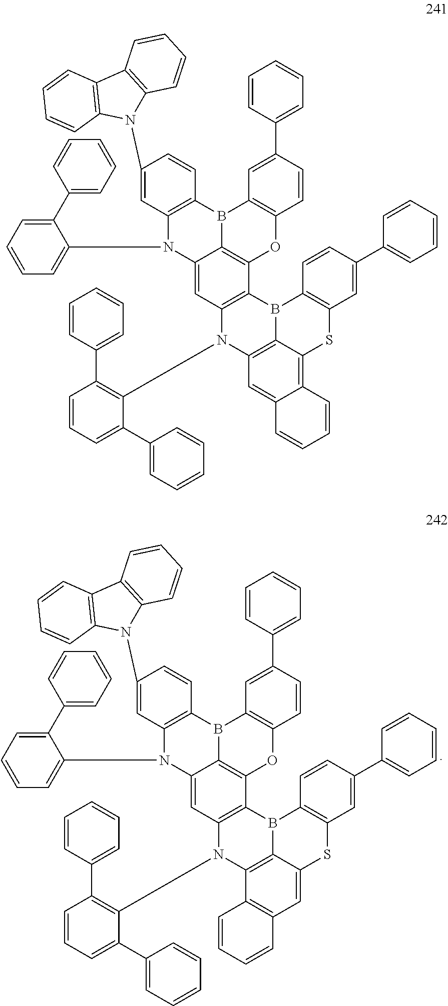 [SMILES: c1ccc(-c2ccc3c(c2)Sc2c4c(cc5ccccc25)N(c2c(-c5ccccc5)cccc2-c2ccccc2)c2cc5c6c(c2B34)Oc2ccc(-c3ccccc3)cc2B6c2ccc(-n3c4ccccc4c4ccccc43)cc2N5c2ccccc2-c2ccccc2)cc1 ; c1ccc(-c2ccc3c(c2)Sc2cc4ccccc4c4c2B3c2c(cc3c5c2Oc2ccc(-c6ccccc6)cc2B5c2ccc(-n5c6ccccc6c6ccccc65)cc2N3c2ccccc2-c2ccccc2)N4c2c(-c3ccccc3)cccc2-c2ccccc2)cc1]

13. An electronic apparatus comprising:
a base layer;
a circuit layer on the base layer; and
a display element layer on the circuit layer and comprising a light emitting element,
wherein the light emitting element comprises a first electrode, a second electrode on the first electrode, and an emission layer between the first electrode and the second electrode and comprising a first compound represented by Formula 1: 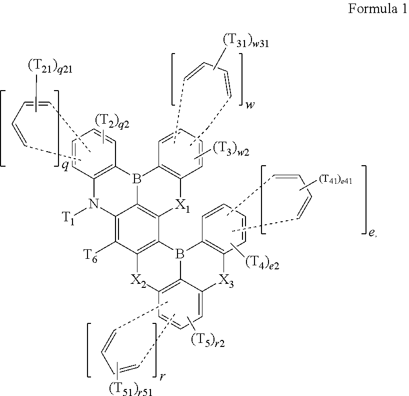
and
wherein, in Formula 1,
q, w, and e are each independently an integer of 0 to 3,
r is an integer of 0 to 2,
q21, w31, e41, and r51 are each independently an integer of 0 to 4,
the sum of q, w, e, and r is 1 or greater,
q2 is an integer of 0 to 4 when q is 0, q2 is an integer of 0 to 2 when q is 1, and q2 is 0 when q is 2 or 3,
w2 is an integer of 0 to 4 when w is 0, w2 is an integer of 0 to 2 when w is 1, and w2 is 0 when w is 2 or 3,
e2 is an integer of 0 to 4 when e is 0, e2 is an integer of 0 to 2 when e is 1, and e2 is 0 when e is 2 or 3,
r2 is an integer of 0 to 3 when r is 0, r2 is 0 or 1 when r is 1, and r2 is 0 when r is 2,
X₁ is O, or S,
X₂ is O, S, or NT₂₀,
X₃ is O, S, or NT₃₀,
T₁ is a substituted or unsubstituted aryl group having 6 to 30 ring-forming carbon atoms or a substituted or unsubstituted heteroaryl group having 2 to 30 ring-forming carbon atoms,
T₂₀, T₃₀, T₂, T₃, T₄, T₅, and T₆ are each independently hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
T₂₁, T₃₁, T₄₁, and T₅₁ are each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

14. The electronic apparatus of claim 13, wherein the light emitting element further comprises a capping layer on the second electrode, and
the capping layer has a refractive index of about 1.6 or more with respect to light in a wavelength range of about 550 nm to about 660 nm.

15. The electronic apparatus of claim 13, further comprising a light control layer that is on the display element layer and comprises quantum dots,
wherein the light emitting element is to emit first color light, and
the light control layer comprises:
a first light control part comprising a first quantum dot configured to convert the first color light into second color light in a longer wavelength region than the first color light;
a second light control part comprising a second quantum dot configured to convert the first color light into third color light in a longer wavelength region than each of the first color light and the second color light; and
a third light control part configured to transmit the first color light.

16. The electronic apparatus of claim 15, further comprising a color filter layer on the light control layer,
wherein the color filter layer comprises:
a first filter configured to transmit the second color light;
a second filter configured to transmit the third color light; and
a third filter configured to transmit the first color light.

17. A fused polycyclic compound represented by Formula 1: 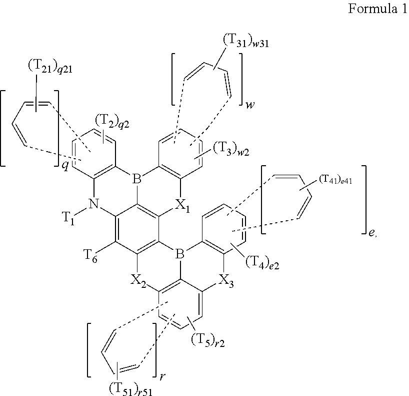
wherein, in Formula 1,
q, w, and e are each independently an integer of 0 to 3,
r is an integer of 0 to 2,
q21, w31, e41, and r51 are each independently an integer of 0 to 4,
the sum of q, w, e, and r is 1 or greater,
q2 is an integer of 0 to 4 when q is 0, q2 is an integer of 0 to 2 when q is 1, and q2 is 0 when q is 2 or 3,
w2 is an integer of 0 to 4 when w is 0, w2 is an integer of 0 to 2 when w is 1, and w2 is 0 when w is 2 or 3,
e2 is an integer of 0 to 4 when e is 0, e2 is an integer of 0 to 2 when e is 1, and e2 is 0 when e is 2 or 3,
r2 is an integer of 0 to 3 when r is 0, r2 is 0 or 1 when r is 1, and r2 is 0 when r is 2,
X₁ is O, or S,
X₂ is O, S, or NT₂₀,
X₃ is O, S, or NT₃₀,
T₁ is a substituted or unsubstituted aryl group having 6 to 30 ring-forming carbon atoms or a substituted or unsubstituted heteroaryl group having 2 to 30 ring-forming carbon atoms,
T₂₀, T₃₀, T₂, T₃, T₄, T₅, and T₆ are each independently hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
T₂₁, T₃₁, T₄₁, and T₅₁ are each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

18. The fused polycyclic compound of claim 17, wherein the fused polycyclic compound represented by Formula 1 is represented by Formula 1-1: 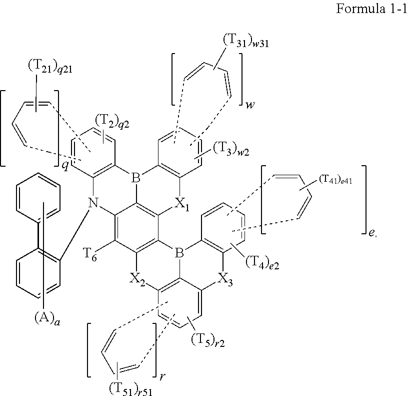
in Formula 1-1,
A being hydrogen, deuterium, a halogen, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a being an integer of 0 to 9, and
q, w, e, r, q21, w31, e41, r51, q2, w2, e2, r2, X₁, X₂, X₃, T₂₀, T₃₀, T₂, T₃, T₄, T₅, T₆, T₂₁, T₃₁, T₄₁, and T₅₁ each being the same as defined in Formula 1.

19. The fused polycyclic compound of claim 17, wherein the fused polycyclic compound represented by Formula 1 is represented by Formula 2-1 or Formula 2-2: 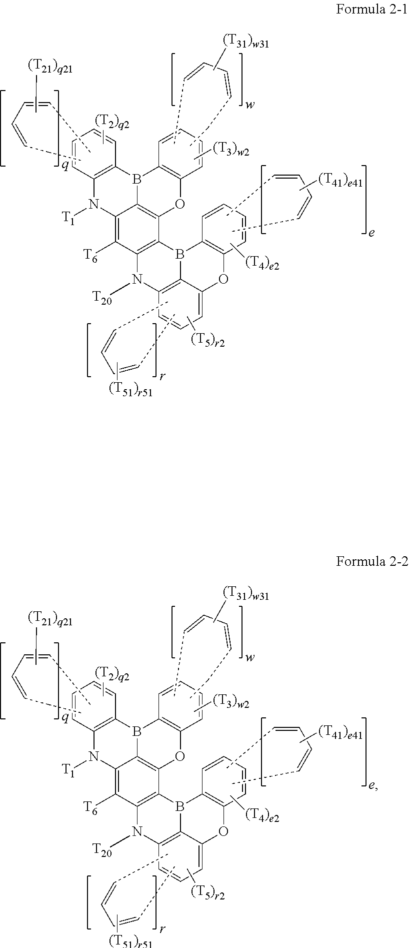
in Formula 2-1 and Formula 2-2,
q, w, e, r, q21, w31, e41, r51, q2, w2, e2, r2, T₁, T₂₀, T₃₀, T₂, T₃, T₄, T₅, T₆, T₂₁, T₃₁, T₄₁, and T₅₁ each being the same as defined in Formula 1.

20. The fused polycyclic compound of claim 17, wherein the fused polycyclic compound represented by Formula 1 is represented by any one selected from among Formula 3-1 to Formula 3-7: 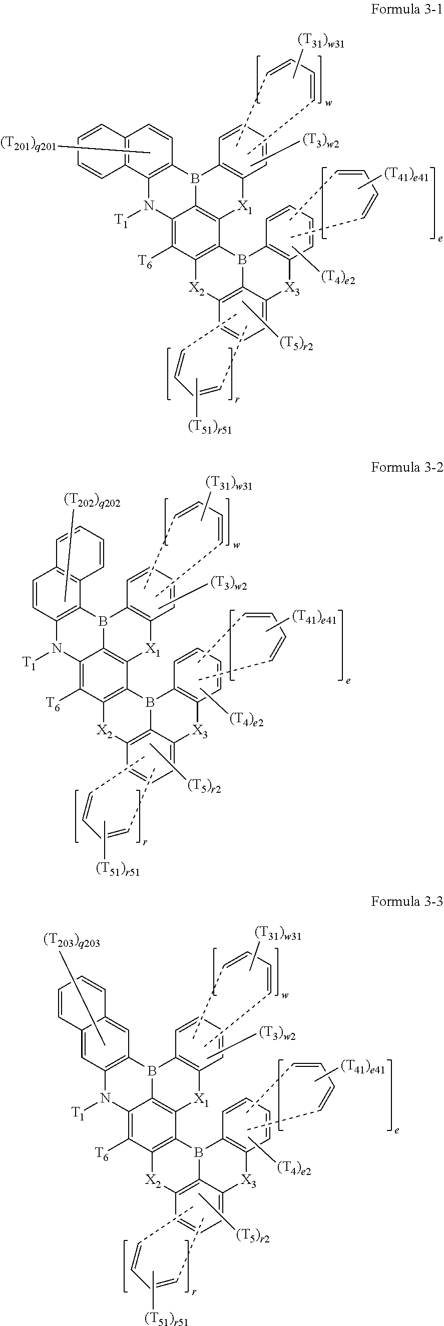 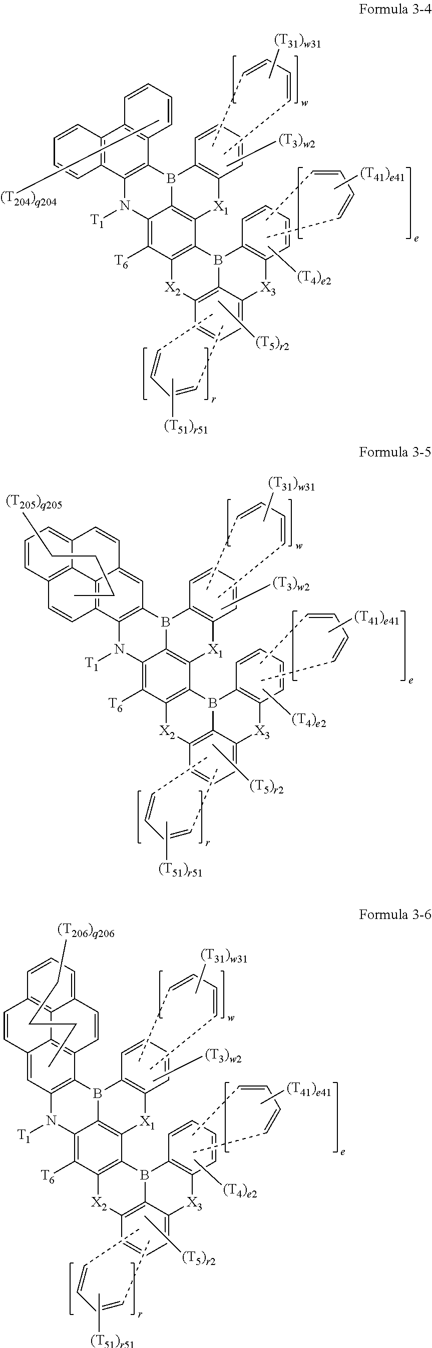 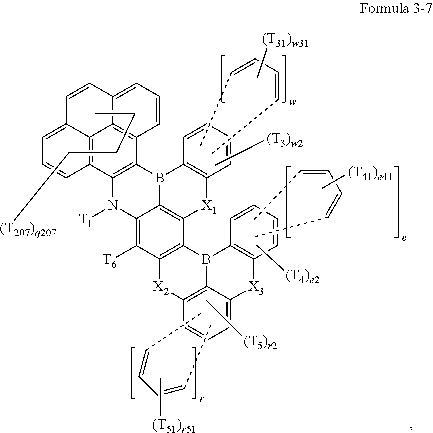
in Formula 3-1 to Formula 3-7,
T₂₀₁, T₂₀₂, T₂₀₃, T₂₀₄, T₂₀₅, T₂₀₆, and T₂₀₇ being each independently hydrogen, deuterium, a halogen, a substituted or unsubstituted amino group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
q201, q202, and q203 being each independently an integer of 0 to 6,
q204, q205, q206, and q207 being each independently an integer of 0 to 8, and
w, e, r, w31, e41, r51, w2, e2, r2, X₁, X₂, X₃, T₁, T₂₀, T₃₀, T₃, T₄, T₅, T₆, T₃₁, T₄₁, and T₅₁ each being the same as defined in Formula 1.
